(19) United States
(12) Patent Application Publication
(10) Pub. No.: US 2025/0048928 A1
(43) Pub. Date: Feb. 6, 2025

(54) LIGHT EMITTING ELEMENT, FUSED POLYCYCLIC COMPOUND FOR THE SAME, AND ELECTRONIC DEVICE INCLUDING THE SAME

(71) Applicant: Samsung Display Co., Ltd., Yongin-si (KR)

(72) Inventors: CHANSEOK OH, Yongin-si (KR); SUN YOUNG PAK, Yongin-si (KR); MinJae SUNG, Yongin-si (KR); MUN-KI SIM, Yongin-si (KR); Giwoong HAN, Yongin-si (KR)

(21) Appl. No.: 18/653,624

(22) Filed: May 2, 2024

(30) Foreign Application Priority Data
Jul. 4, 2023 (KR) 10-2023-0086648
Jul. 21, 2023 (KR) 10-2023-0095037

(51) Int. Cl. H10K 85/60; C07F 5/02; C09K 11/06; H10K 50/12; H10K 59/38; H10K 101/00; H10K 101/25

(52) U.S. Cl. CPC H10K 85/658; C07F 5/027; C09K 11/06; C07B 2200/05; C09K 2211/1018; H10K 50/12; H10K 59/38; H10K 2101/25; H10K 2101/90

(57) ABSTRACT

A light emitting element includes a first electrode, a second electrode on the first electrode, and an emission layer between the first electrode and the second electrode and including a first compound represented by Formula 1.

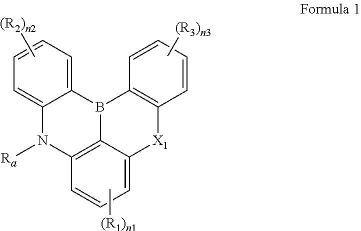

### CROSS-REFERENCE TO RELATED APPLICATIONS

The present application claims priority to and the benefit of Korean Patent Application Nos. 10-2023-0086648, filed on Jul. 4, 2023, and 10-2023-0095037, filed on Jul. 21, 2023, in the Korean Intellectual Property Office, the entire content of each of the two applications is incorporated herein by reference.

### BACKGROUND

### 1. Field

One or more embodiments of the present disclosure relate to a light emitting element, a fused polycyclic compound utilized therein, and an electronic device including the light emitting element.

### 2. Description of Related Art

As image display devices, organic electroluminescence display devices and/or the like have been actively developed currently. Unlike liquid crystal display devices, and/or the like, the organic electroluminescence display devices are self-luminescent display devices in which holes and electrons respectively (e.g., separately) injected from a first electrode and a second electrode recombine in an emission layer of the organic electroluminescence display device, and thus a light emitting material including an organic compound in the emission layer emits light to accomplish display (e.g., of an image).

For application of organic electroluminescence elements to display devices, it is desirable that organic electroluminescence elements have a relatively low driving voltage, a relatively high luminous efficiency, and a relatively long life (e.g., a relatively long lifespan), and thus the development of materials, for organic electroluminescence elements, capable of stably attaining such characteristics is being continuously required and/or pursued.

In recent years, in order to obtain a highly efficient organic electroluminescence element, technologies pertaining to phosphorescence emission utilizing triplet state energy or fluorescence emission utilizing triplet-triplet annihilation (TTA) in which singlet excitons are generated through collision of triplet excitons are being particularly developed, and thermally activated delayed fluorescence (TADF) materials utilizing a delayed fluorescence phenomenon are under development.

### SUMMARY

One or more aspects of embodiments of the present disclosure are directed toward a light emitting element having increased luminous efficiency and longer element service life.

One or more aspects of embodiments of the present disclosure are directed toward a fused polycyclic compound capable of improving luminous efficiency and element service life.

One or more aspects of embodiments of the present disclosure are directed toward an electronic device, having high display quality, including a light emitting element having improved luminous efficiency and service life.

Additional aspects will be set forth in part in the description which follows and, in part, will be apparent from the description, or may be learned by practice of the presented embodiments.

One or more embodiments of the present disclosure provide a light emitting element including a first electrode, a second electrode on the first electrode, and an emission layer between the first electrode and the second electrode and including a first compound represented by Formula 1.

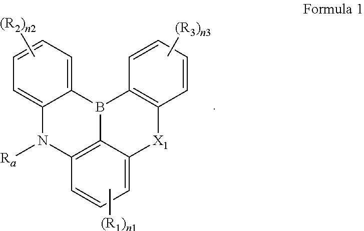

In Formula 1, X₁ may be O, S, NR₄, CR₅R₆, or SiR₇R₈, R₁ to R₈ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, Rₐ may be represented by Formula S, n1 may be an integer of 0 to 3, and n2 and n3 may each independently be an integer of 0 to 4.

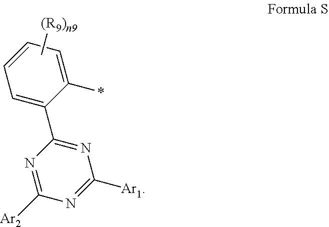

In Formula S, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms, R₉ may be hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, n9 may be an integer of 0 to 4, and [symbol] is a site linked to Formula 1.

In one or more embodiments, the first compound represented by Formula 1 may be represented by Formula 2.

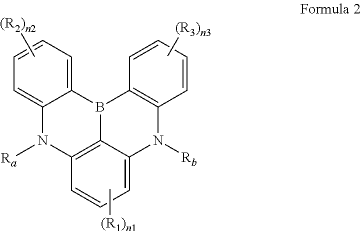

In Formula 2, Rb may be represented by any one selected from among Formulas A-1 to A-3.

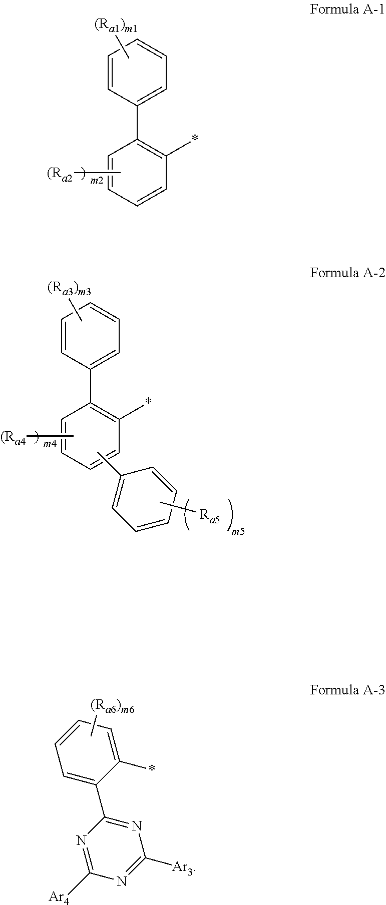

In Formulas A-1 to A-3, Rₐ₁ to Rₐ₆ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, Ar₃ and Ar₄ may each independently be a substituted or unsubstituted aryl group having 6 to 30 ring-forming carbon atoms or a substituted or unsubstituted heteroaryl group having 2 to 30 ring-forming carbon atoms, m1, m3, and m5 may each independently be an integer of 0 to 5, m2 and m6 may each independently be an integer of 0 to 4, m4 may be an integer of 0 to 3, and [symbol] is a site linked to Formula 2.

In Formula 2, R₁ to R₃, Rₐ, and n1 to n3 may each independently be the same as defined in Formula 1.

In one or more embodiments, the first compound represented by Formula 1 may be represented by Formula 3.

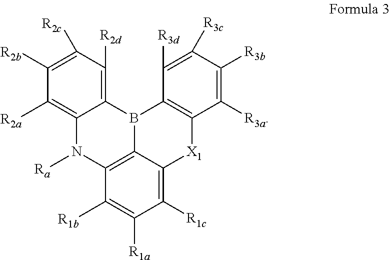

In Formula 3, R₁ₐ to R_{1c}, R₂ₐ to R_{2d}, and R₃ₐ to R_{3d} may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and at least one selected from among R₁ₐ to R_{1c}, R₂ₐ to R_{2d}, and R₃ₐ to R_{3d} may be a substituted or unsubstituted alkyl group having 1 to 10 carbon atoms, or may be represented by any one selected from among Formulas B-1 to B-4.

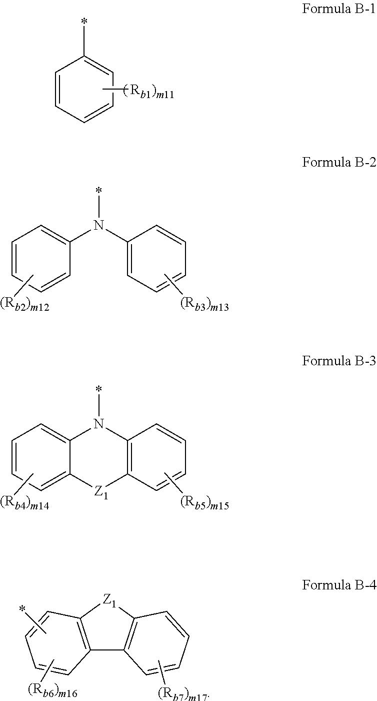

In Formulas B-1 to B-4, Z₁ may be a direct linkage, O, S, or CR_{b8}R_{b9}, Z₂ may be O, S, NR_{b10}, or CR_{b11}R_{b12}, R_{b1} to R_{b12} may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, m11 to m13 may each independently be an integer of 0 to 5, m14, m15, and m17 may each independently be an integer of 0 to 4, and m16 may be an integer of 0 to 3.

In Formula 3, X₁ and Rₐ may each independently be the same as defined in Formula 1.

In one or more embodiments, the first compound represented by Formula 3 may be represented by any one selected from among Formulas 4-1 to 4-4.

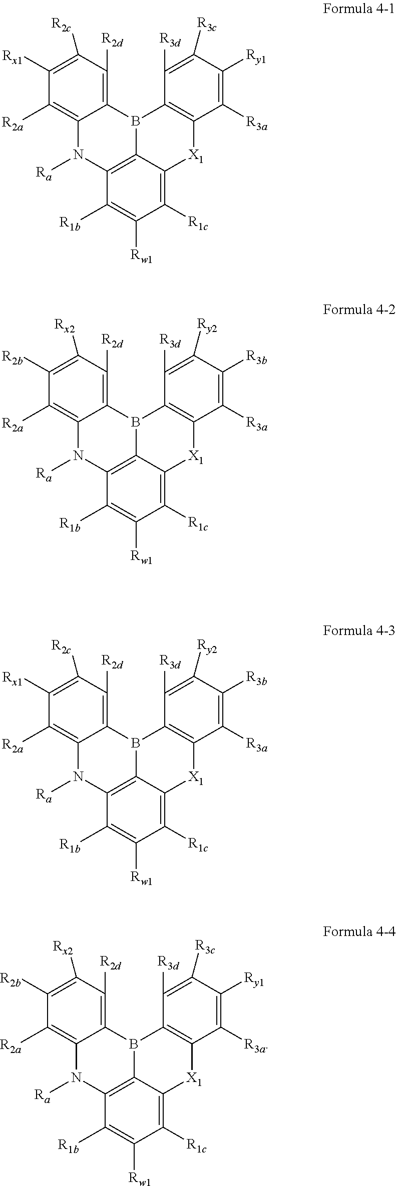

In Formulas 4-1 to 4-4, R_{w1} may be hydrogen or a substituted or unsubstituted alkyl group having 1 to 10 carbon atoms, or may be represented by any one selected from among Formulas B-1 to B-4, and Rₓ₁, Rₓ₂, R_{y1}, and R_{y2} may each independently be represented by any one selected from among Formulas B-1 to B-4.

In Formulas 4-1 to 4-4, X₁, R₁ₐ, R_{1b}, R_{1c}, R₂ₐ to R_{2d}, and R₃ₐ to R_{3d} may each independently be the same as defined in Formula 1 and Formula 3.

In one or more embodiments, the first compound represented by Formula 1 may be represented by any one selected from among Formulas 5-1 to 5-3.

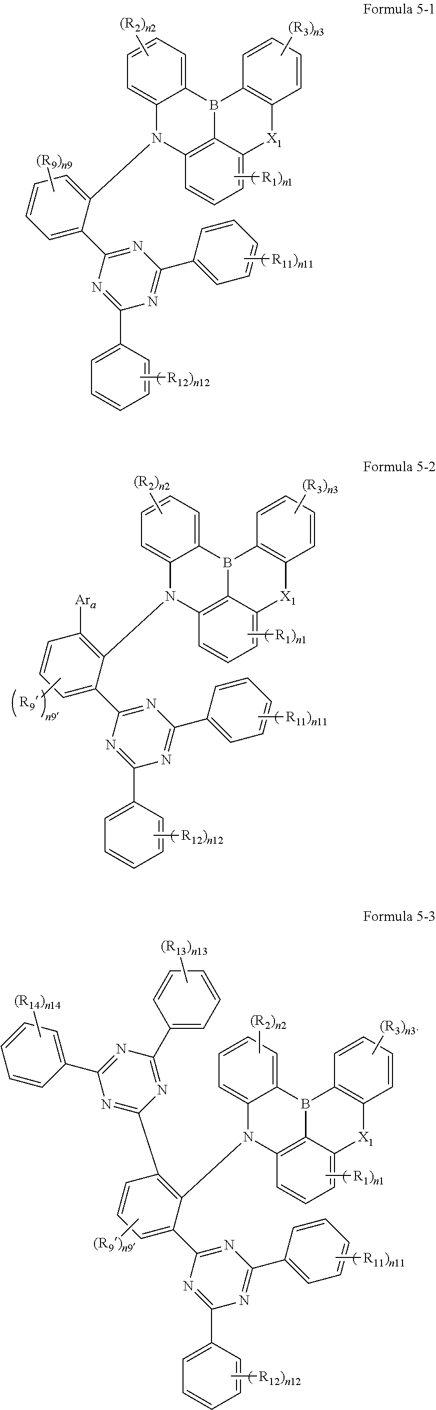

In Formulas 5-1 to 5-3, Ara may be a substituted or unsubstituted aryl group having 6 to 30 ring-forming carbon atoms or a substituted or unsubstituted heteroaryl group having 2 to 30 ring-forming carbon atoms, and R₉′ and R₁₁ to R₁₄ may each independently be hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, n9′ may be an integer of 0 to 3, and n11 to n14 may each independently be an integer of 0 to 5.

In Formulas 5-1 to 5-3, X₁, R₁ to R₃, R₉, n1 to n3, and n9 may each independently be the same as defined in Formula 1 and Formula S.

In one or more embodiments, the first compound represented by Formula 1 may be represented by any one selected from among Formulas 6-1 to 6-3.

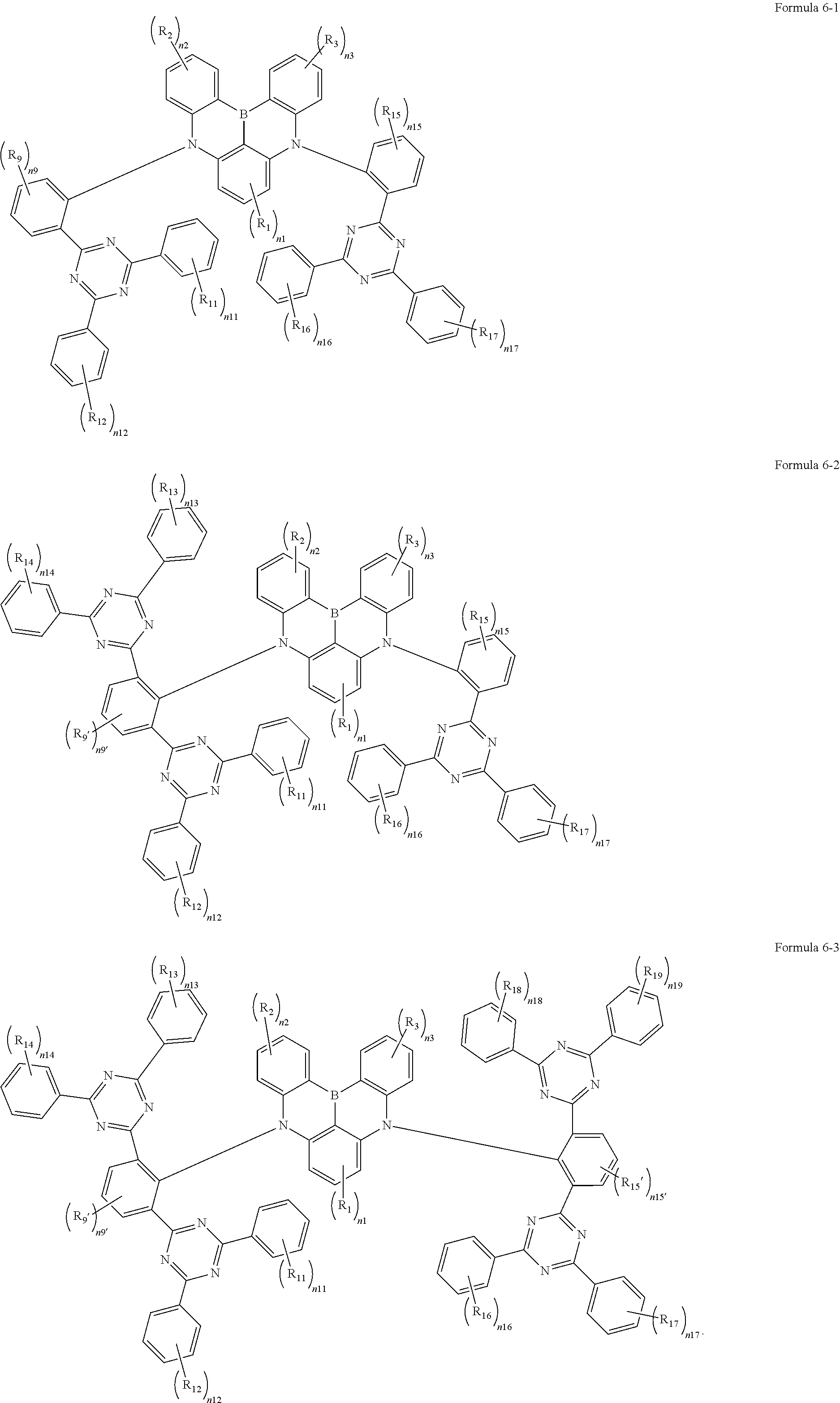

In Formulas 6-1 to 6-3, R₉′, R₁₅′, and R₁₁ to R₁₉ may each independently be hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, n9′ and n15′ may each independently be an integer of 0 to 3, n11 to n14 and n16 to n19 may each independently be an integer of 0 to 5, and n15 may be an integer of 0 to 4.

In Formulas 6-1 to 6-3, R₁ to R₃, R₉, n1 to n3, and n9 may each independently be the same as defined in Formula 1 and Formula S.

In one or more embodiments, the first compound represented by Formula 1 may be represented by any one selected from among Formulas 7-1 to 7-4.

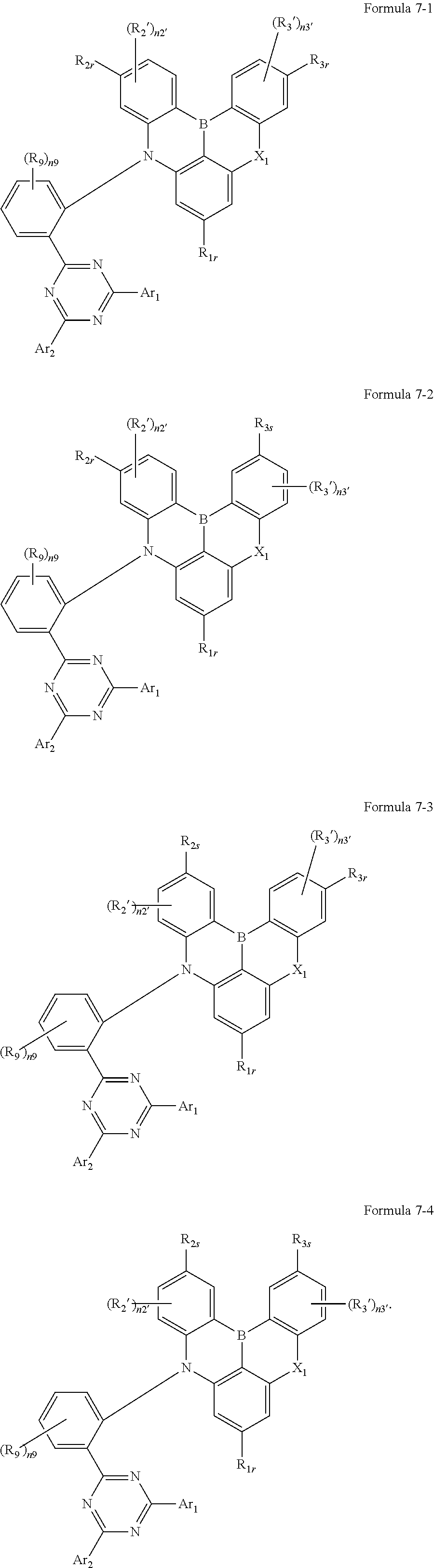

In Formulas 7-1 to 7-4, R₂′ and R₃′ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₂ᵣ, R₂ₛ, R₃ᵣ, and R₃ₛ may each independently be a substituted or unsubstituted amine group, a substituted or unsubstituted phenyl group, a substituted or unsubstituted carbazole group, a substituted or unsubstituted dibenzofuran group, or a substituted or unsubstituted dibenzothiophene group, and R₁ᵣ may be hydrogen, deuterium, a substituted or unsubstituted amine group, a substituted or unsubstituted alkyl group having 1 to 10 carbon atoms, a substituted or unsubstituted phenyl group, a substituted or unsubstituted carbazole group, a substituted or unsubstituted dibenzofuran group, or a substituted or unsubstituted dibenzothiophene group.

In Formulas 7-1 to 7-4, X₁, Ar₁, Ar₂, R₉, and n9 may each independently be the same as defined in Formula 1 and Formula S.

In one or more embodiments, the first compound represented by Formula 1 may be represented by Formula 8-1 or Formula 8-2.

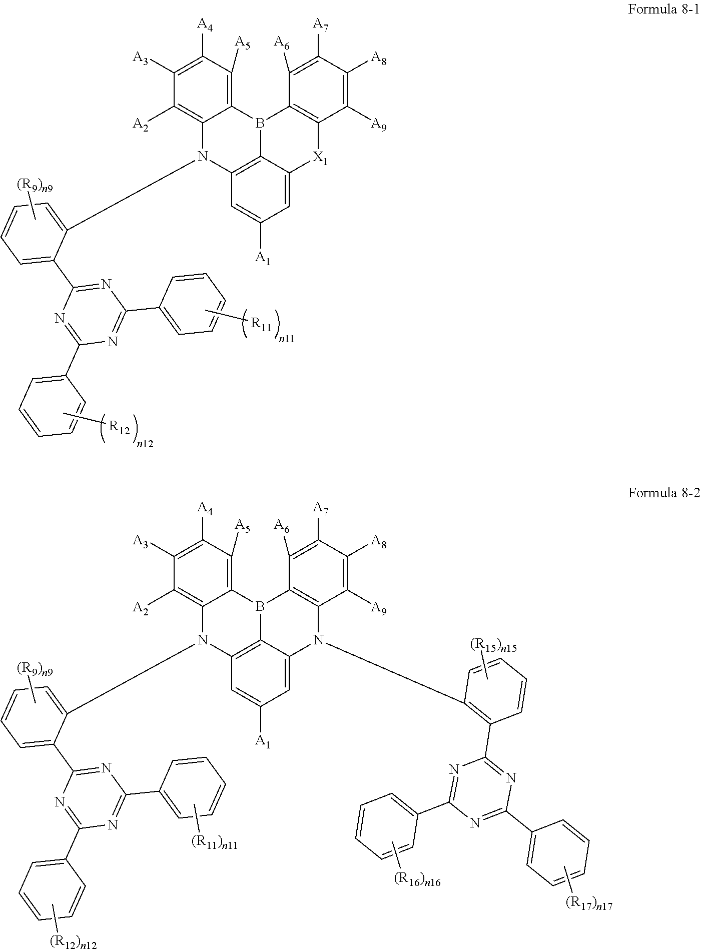

In Formulas 8-1 and 8-2, R₁₁, R₁₂, R₁₅ to R₁₇, and A₁ to A₉ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least one selected from among A₁ to A₉ may be selected from Substituent Group 1, n11, n12, n16, and n17 may each independently be an integer of 0 to 5, and n15 may be an integer of 0 to 4.

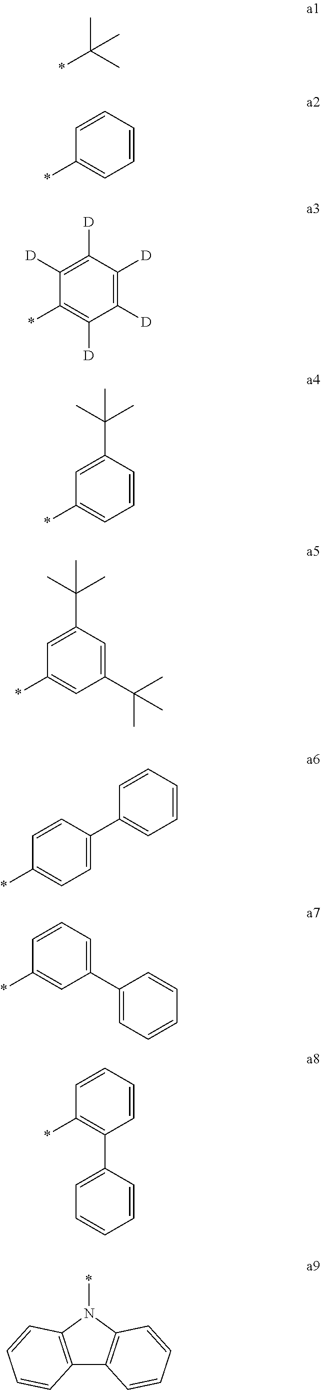

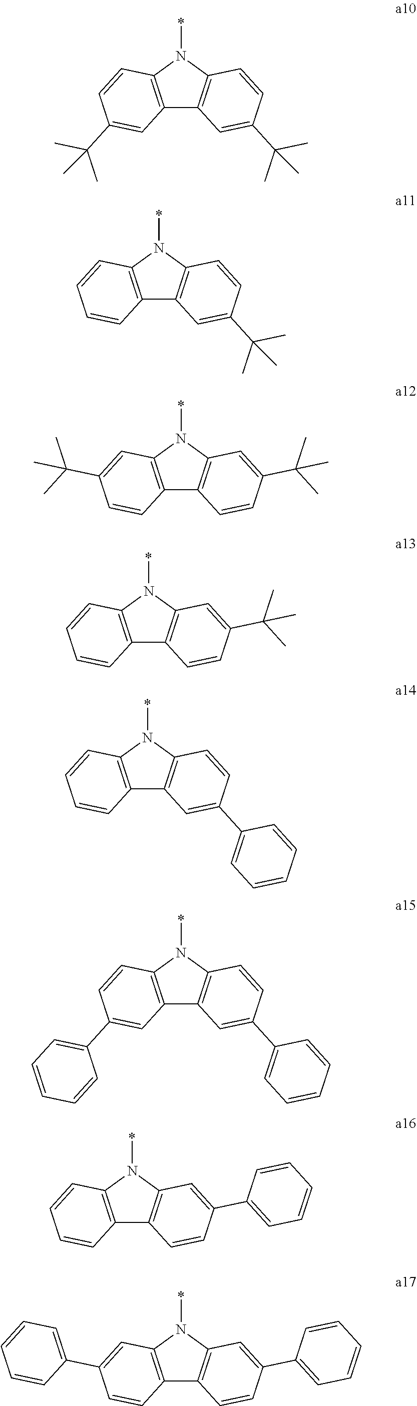

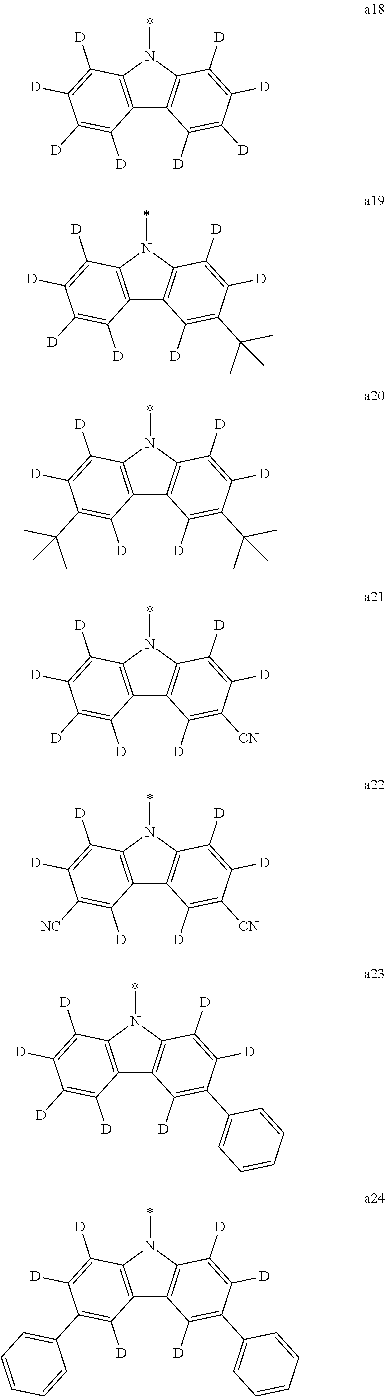

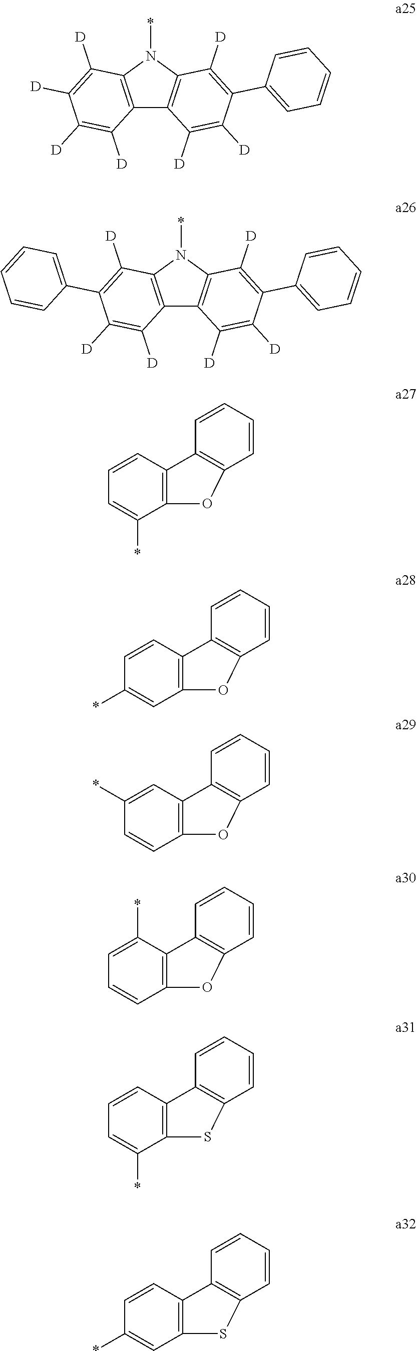

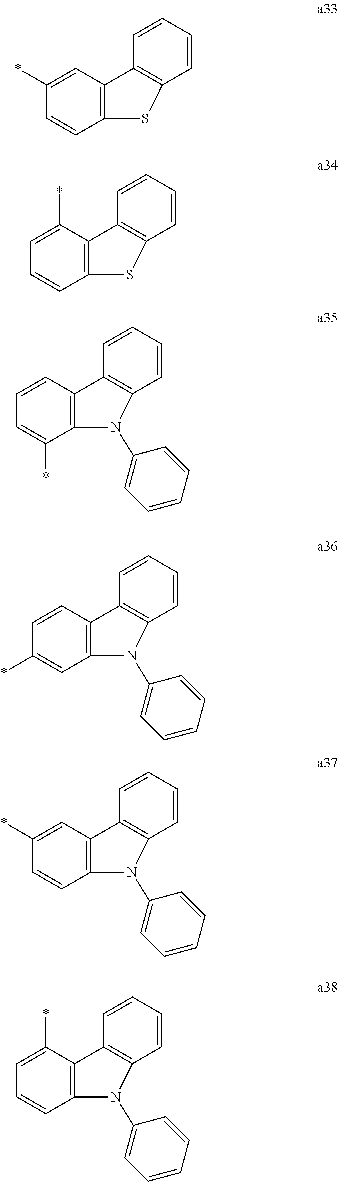

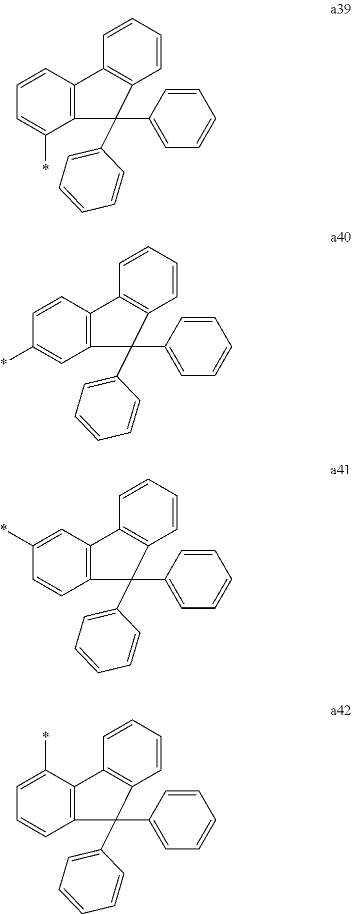 [SMILES: *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

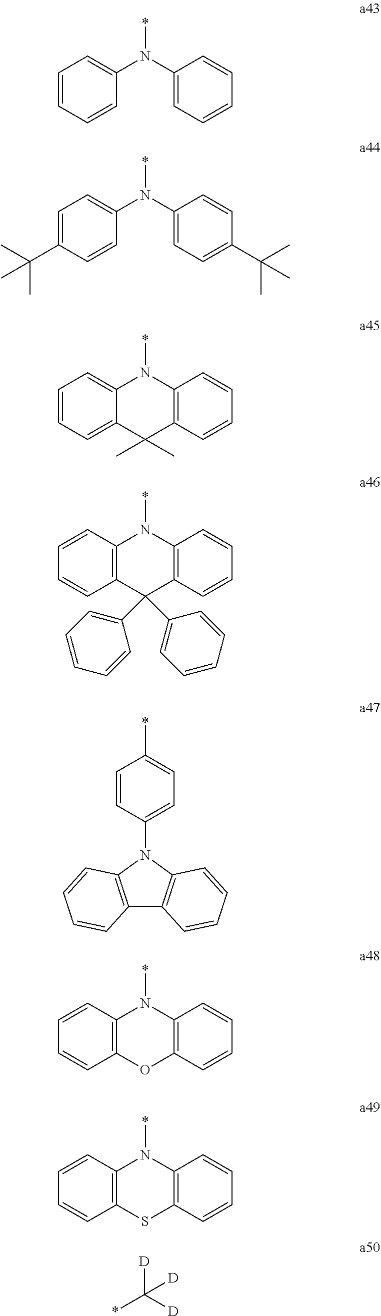

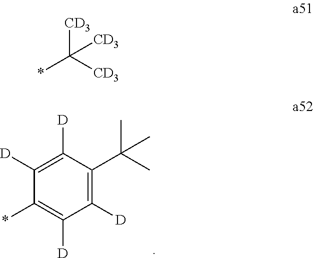 [SMILES: *C(C([2H])([2H])[2H])(C([2H])([2H])[2H])C([2H])([2H])[2H] ; *c1c([2H])c([2H])c(C(C)(C)C)c([2H])c1[2H]]

In Formulas 8-1 and 8-2, X₁, R₉, and n9 may be each independently the same as defined in Formula 1 and Formula S.

In one or more embodiments, the emission layer may further include at least one of a second compound represented by Formula HT-1, a third compound represented by Formula ET-1, or a fourth compound represented by Formula D-1.

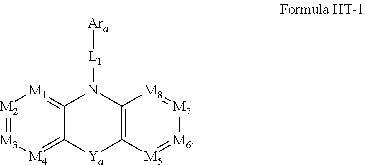

In Formula HT-1, M₁ to M₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SiR₅₄R₅₅, Ara may be a substituted or unsubstituted aryl group having 6 to 30 ring-forming carbon atoms or a substituted or unsubstituted heteroaryl group having 2 to 30 ring-forming carbon atoms, and R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

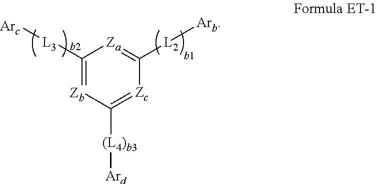

In Formula ET-1, at least one selected from among Zₐ to Z_{c} is N and the remainder may be CR₅₆, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, b1 to b3 may each independently be an integer of 0 to 10, Ar_{b} to Ar_{d} may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

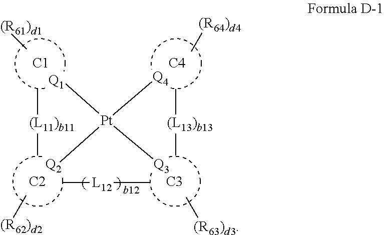

In Formula D-1, Q₁ to Q₄ may each independently be C or N, C1 to C4 may each independently be a substituted or unsubstituted hydrocarbon ring having 5 to 30 ring-forming carbon atoms or a substituted or unsubstituted heterocycle having 2 to 30 ring-forming carbon atoms, L₁₁ to L₁₃ may each independently be a direct linkage,

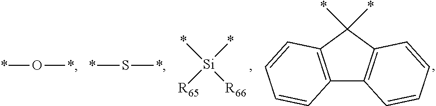

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b11 to b13 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments of the present disclosure, an electronic device includes at least one light emitting element, the electronic device being at least one selected from large-sized display devices such as televisions, monitors, and outdoor billboards, and small- and medium-sized display devices such as personal computers, laptop computers, personal digital terminals, vehicle display devices, game consoles, portable electronic devices, and cameras, wherein the light emitting element includes a fused polycyclic compound represented by Formula 1.

In one or more embodiments, the electronic device may include a base layer, a circuit layer on the base layer, and a display element layer on the circuit layer and including a light emitting element and an encapsulation layer on the light emitting element, wherein the light emitting element may include a first electrode, a second electrode on the first electrode, and an emission layer between the first electrode and the second electrode and including a fused polycyclic compound represented by Formula 1.

In one or more embodiments, the light emitting element may further include a capping layer on the second electrode, wherein the capping layer may have a refractive index of about 1.6 or greater in a wavelength range of about 550 nm to about 660 nm.

In one or more embodiments, the electronic device may further include a light control layer on the encapsulation layer and including quantum dots, wherein the light emitting element may be to emit first color light, and the light control layer may include a first light control portion including a first quantum dot that converts the first color light into second color light having a longer wavelength than the first color light, a second light control portion including a second quantum dot that converts the first color light into third color light having a longer wavelength than the first color light and the second color light, and a third light control portion that transmits the first color light.

In one or more embodiments, the electronic device may further include a color filter layer on the light control layer, wherein the color filter layer may include a first filter that transmits the second color light, a second filter that transmits the third color light, and a third filter that transmits the first color light.

In one or more embodiments of the present disclosure, a fused polycyclic compound is represented by Formula 1.

### BRIEF DESCRIPTION OF THE DRAWINGS

The accompanying drawings are included to provide a further understanding of the present disclosure, and are incorporated in and constitute a part of this disclosure. The drawings illustrate example embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically showing a light emitting element according to one or more embodiments of the present disclosure;

FIG. 4 is a cross-sectional view schematically showing a light emitting element according to one or more embodiments of the present disclosure;

FIG. 5 is a cross-sectional view schematically showing a light emitting element according to one or more embodiments of the present disclosure;

FIG. 6 is a cross-sectional view schematically showing a light emitting element according to one or more embodiments of the present disclosure;

FIG. 7 and FIG. 8 are each a cross-sectional view of a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure;

FIG. 11 is a view showing a vehicle in which display devices are disposed according to one or more embodiments of the present disclosure;

FIG. 12A is a view showing a three-dimensional molecular model of an Example compound; and

FIG. 12B is a view showing a three-dimensional molecular model of a Comparative Example compound.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure may be exaggeratingly illustrated for clarity of the present disclosure. It will be understood that, although the terms “first,” “second,” etc., may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

In the present disclosure, it will be understood that the terms “comprise(s),” “include(s),” “have/has” and/or the like specify the presence of features, numbers, steps, operations, component, parts, or combinations thereof disclosed in the disclosure, but do not exclude the possibility of presence or addition of one or more other features, numbers, steps, operations, component, parts, or combinations thereof. As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, when a layer, a film, a region, or a plate is referred to as being “on” or “in an upper portion of” another layer, film, region, or plate, it may be not only “directly on” the layer, film, region, or plate, but one or more intervening layers, films, regions, or plates may also be present. Opposite this, when a layer, a film, a region, or a plate is referred to as being “below”, “in a lower portion of” another layer, film, region, or plate, it can be not only directly under the layer, film, region, or plate, but one or more intervening layers, films, regions, or plates may also be present. In some embodiments, it will be understood that when a part is referred to as being “on” another part, it can be disposed above the other part, or disposed under the other part as well. In one or more embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In some embodiments, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 50, 6 to 40, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

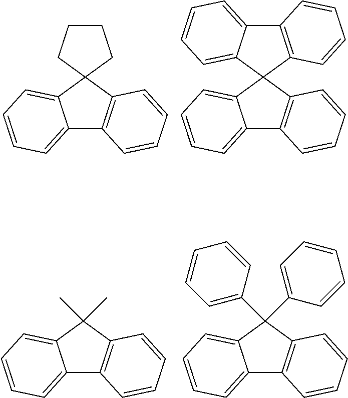

A heterocyclic group utilized herein may refer to any functional group or substituent derived from a ring containing at least one of B, O, N, P, Si, or Se as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, a heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 60, 2 to 50, 2 to 40, 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited thereto.

In the present disclosure, a heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 50, 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, the silyl group includes an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the present disclosure, the number of ring-forming carbon atoms in a carbonyl group is not specifically limited, for example, may be 1 to 40, 1 to 30, or 1 to 20. For example, the carbonyl group may have the following structures, but embodiments of the present disclosure are not limited thereto.

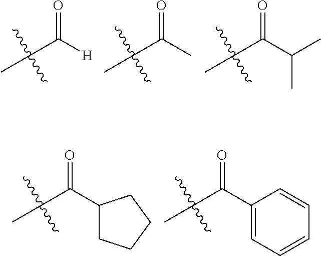

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

A boron group utilized herein may refer to that a boron atom is bonded to the alkyl group or the aryl group defined above. The boron group may include an alkyl boron group and/or an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, etc., but embodiments of the present disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond.

In the present disclosure,

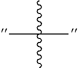

and “ [symbol] ” refer to a position to be connected.

Hereinafter, embodiments of the present disclosure will be described in more detail with reference to the accompanying drawings. In the present disclosure, term “light emitting device” may be utilized interchangeably with the term “light emitting element.”

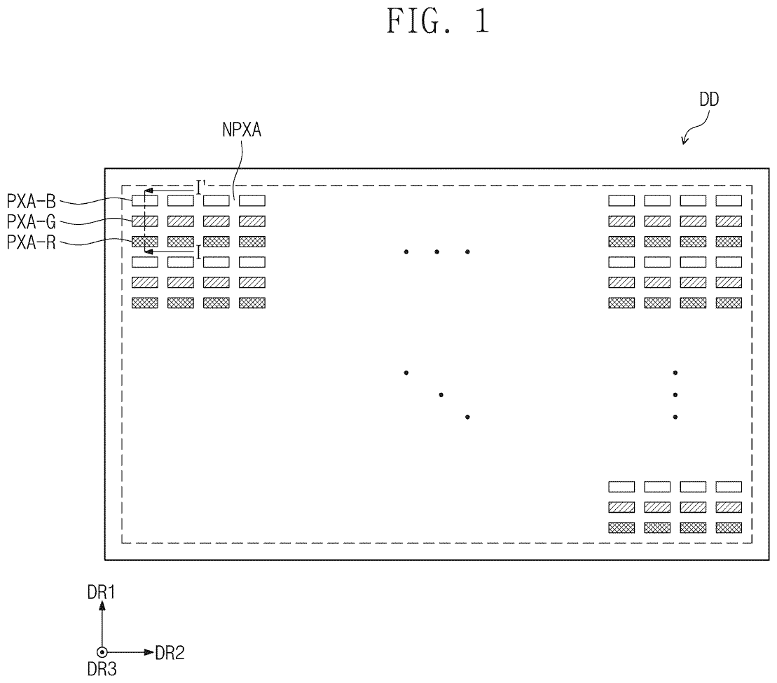

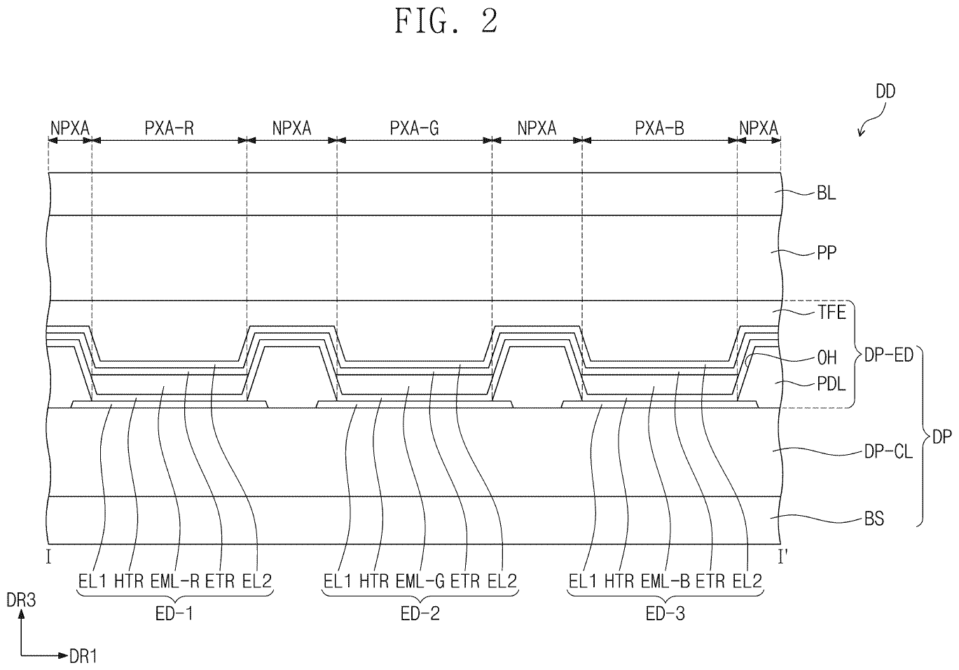

FIG. 1 is a plan view illustrating a display apparatus DD according to one or more embodiments of the present disclosure. FIG. 2 is a cross-sectional view of the display apparatus DD according to one or more embodiments. FIG. 2 is a cross-sectional view illustrating a part taken along line I-I′ of FIG. 1.

The display apparatus DD may include a display panel DP and an optical layer PP disposed on the display panel DP. The display panel DP may include light emitting devices ED-1, ED-2, and ED-3. The display apparatus DD may include a plurality of light emitting devices ED-1, ED-2, and ED-3. The optical layer PP may be disposed on the display panel DP to control reflected light in the display panel DP due to external light. The optical layer PP may include, for example, a polarization layer and/or a color filter layer. In some embodiments, the optical layer PP may not be provided from the display apparatus DD.

A base substrate BL may be disposed or provided on the optical layer PP. The base substrate BL may be a member which provides a base surface on which the optical layer PP disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

The display apparatus DD according to one or more embodiments may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light emitting devices ED-1, ED-2, and ED-3 disposed between respective portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. Each of the transistors may include a control electrode, an input electrode, and an output electrode. For example, in some embodiments, the circuit layer DP-CL may include switching transistor(s) and driving transistor(s) for driving the light emitting devices ED-1, ED-2, and ED-3 of the display device layer DP-ED.

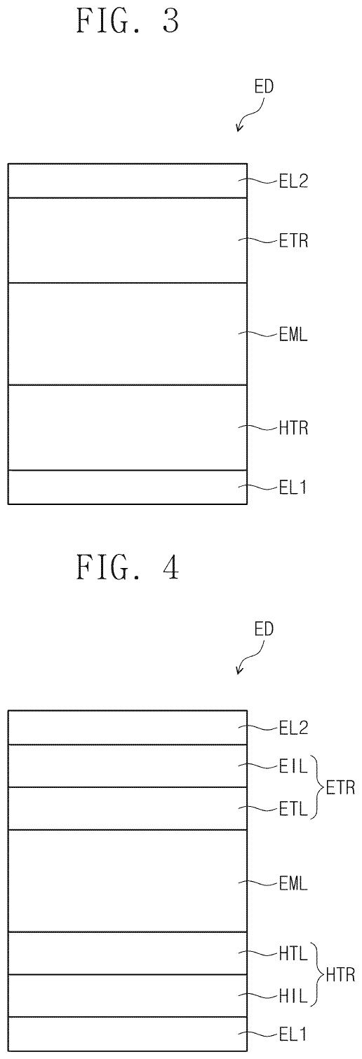

Each of the light emitting devices ED-1, ED-2, and ED-3 may have a structure of one of light emitting devices ED of embodiments according to FIGS. 3 to 6, which will be described later. Each of the light emitting devices ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates an embodiment in which the respective emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, embodiments of the present disclosure are not limited thereto, for example, in one or more embodiments, the hole transport region HTR and the electron transport region ETR may be provided by being patterned inside the openings OH defined in the pixel defining film PDL. For example, in some embodiments, the hole transport region HTR, the respective emission layers EML-R, EML-G, and EML-B, and the electron transport region ETR of the light emitting devices ED-1, ED-2, and ED-3 may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. In some embodiments, the encapsulation layer TFE may include at least one inorganic film (hereinafter, an encapsulation-inorganic film). In some embodiments, the encapsulation layer TFE may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. In some embodiments, the encapsulation-organic film may include an acrylic-based compound, an epoxy-based compound, and/or the like. In some embodiments, the encapsulation-organic film may include a photopolymerizable organic material, but embodiments of the present disclosure are not particularly limited thereto.

The encapsulation layer TFE may be disposed on the second electrode EL2 and may be disposed filling the opening OH.

Referring to FIG. 1 and FIG. 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced and/or apart (e.g., spaced) from each other on a plane.

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting devices ED-1, ED-2, and ED-3. The respective emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of one or more embodiments illustrated in FIG. 1 and FIG. 2, three light emitting regions PXA-R, PXA-G, and PXA-B, which emit red light, green light, and blue light, respectively, are exemplarily illustrated. For example, in one or more embodiments, the display device DD may include a red light emitting region PXA-R, a green light emitting region PXA-G, and a blue light emitting region PXA-B that are separated from each other.

In the display apparatus DD according to one or more embodiments, the plurality of light emitting devices ED-1, ED-2 and ED-3 may be to emit light beams having wavelengths different from each other. For example, in some embodiments, the display apparatus DD may include a first light emitting device ED-1 that emits red light, a second light emitting device ED-2 that emits green light, and a third light emitting device ED-3 that emits blue light. For example, in some embodiments, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, embodiments of the present disclosure are not limited thereto, and the first to third light emitting devices ED-1, ED-2, and ED-3 may be to emit light beams in substantially the same wavelength range or at least one light emitting device may be to emit a light beam in a wavelength range different from the others. For example, in some embodiments, the first to third light emitting devices ED-1, ED-2, and ED-3 may all emit blue light.

The light emitting regions PXA-R, PXA-G, and PXA-B in the display apparatus DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In some embodiments, the red light emitting region PXA-R, the green light emitting region PXA-G, and the blue light emitting region PXA-B may be alternately arranged in the stated order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas when viewed on a plane defined by the first direction axis DR1 and the second direction axis DR2. (e.g., the areas in a plan view)

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, in one or more embodiments, the arrangement form of the light emitting regions PXA-R, PXA-G, and PXA-B may be a pentile (PENTILE©) arrangement form (for example, an RGBG matrix, an RGBG structure, or an RGBG matrix structure), or a diamond (Diamond Pixel™) arrangement form (e.g., a display (e.g., an OLED display) containing red, blue, and green (RGB) light-emitting regions arranged in the shape of diamonds). PENTILE© is a duly registered trademark of Samsung Display Co., Ltd. Diamond Pixel™ is a trademark of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIG. 3 to FIG. 6 are cross-sectional views schematically showing light emitting elements according to one or more embodiments of the present disclosure. The light emitting element ED according to one or more embodiments may include a first electrode EL1, a second electrode EL2 facing the first electrode EL1, and at least one functional layer between the first electrode EL1 and the second electrode EL2. The light emitting element ED of one or more embodiments may include a fused polycyclic compound of one or more embodiments, which will be explained later, in the at least one functional layer.

The light emitting element ED may include a hole transport region HTR, an emission layer EML, an electron transport region ETR, and/or the like, stacked in order (e.g., in the stated order), as the at least one functional layer. Referring to FIG. 3, in one or more embodiments, the light emitting element ED may include a first electrode EL1, a hole transport region HTR, an emission layer EML, an electron transport region ETR, and a second electrode EL2, stacked in order (e.g., in the stated order).

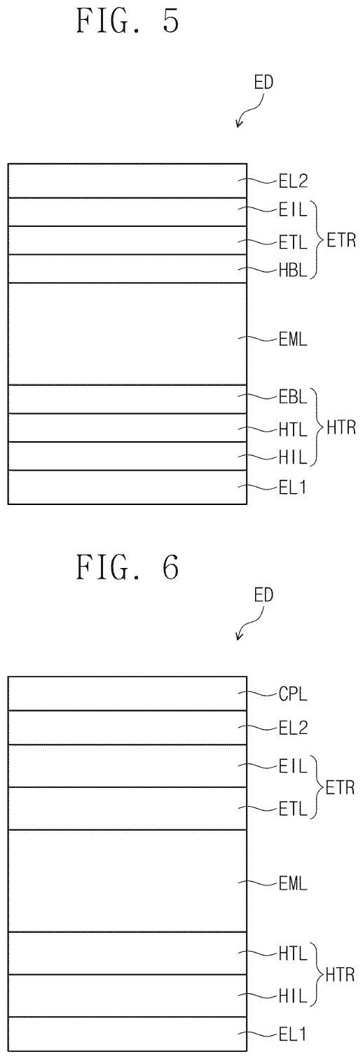

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. Compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of one or more embodiments including a capping layer CPL disposed on a second electrode EL2.

The light emitting element ED of one or more embodiments may include a fused polycyclic compound of one or more embodiments, which will be explained later, in the at least one functional layer. In the light emitting element ED of one or more embodiments, at least one selected from among the hole transport region HTR, the emission layer EML, and the electron transport region ETR may include the fused polycyclic compound of one or more embodiments. For example, in the light emitting element ED of one or more embodiments, the emission layer EML may include the fused polycyclic compound of one or more embodiments.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), one or more compounds each being of two or more selected therefrom, one or more mixtures each being of two or more selected therefrom, and/or one or more oxides thereof.

When the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, any compound thereof, or any mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, in some embodiments, the first electrode EL1 may have a three-layer structure of ITO/Ag/ITO, but embodiments of the present disclosure are not limited thereto. The first electrode EL1 may include one of the above-described metal materials, any combination of at least two metal materials of the above-described metal materials, any oxide of the above-described metal materials, and/or the like. A thickness of the first electrode EL1 may be from about 700 Å to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

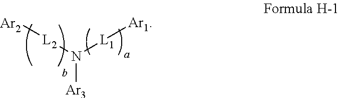

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ may include an amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

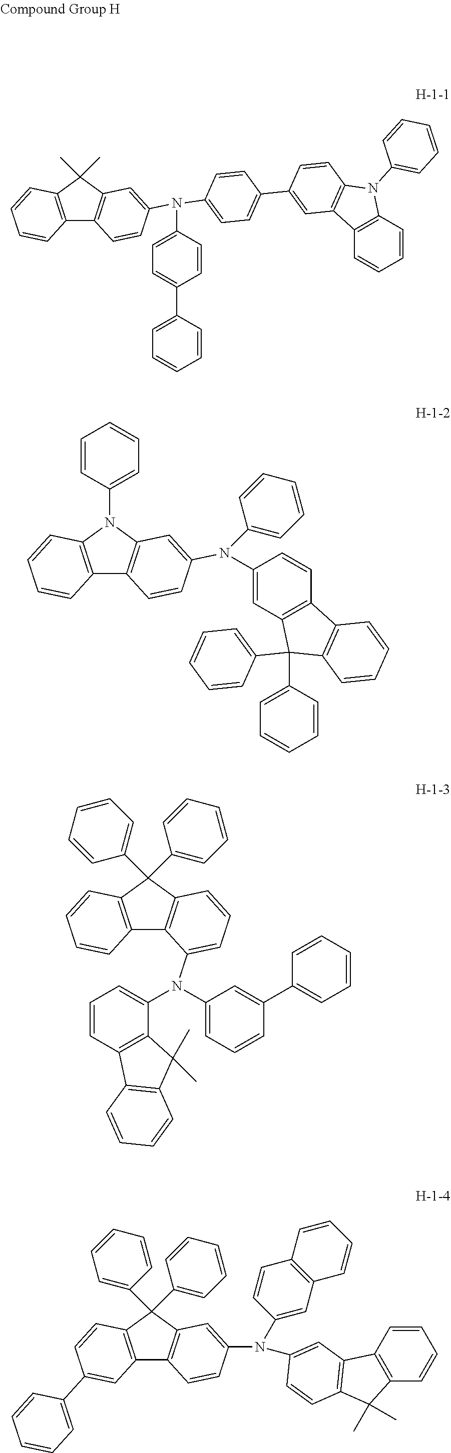 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

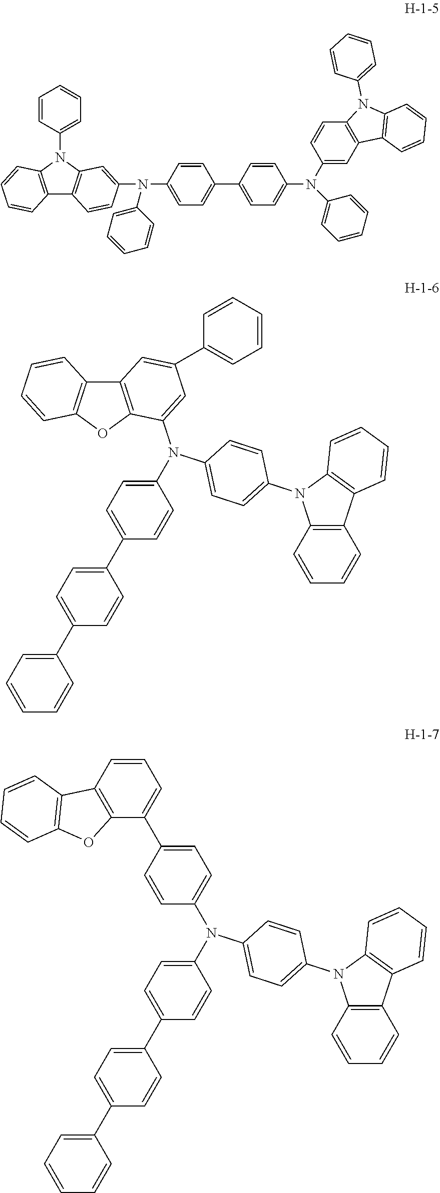 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

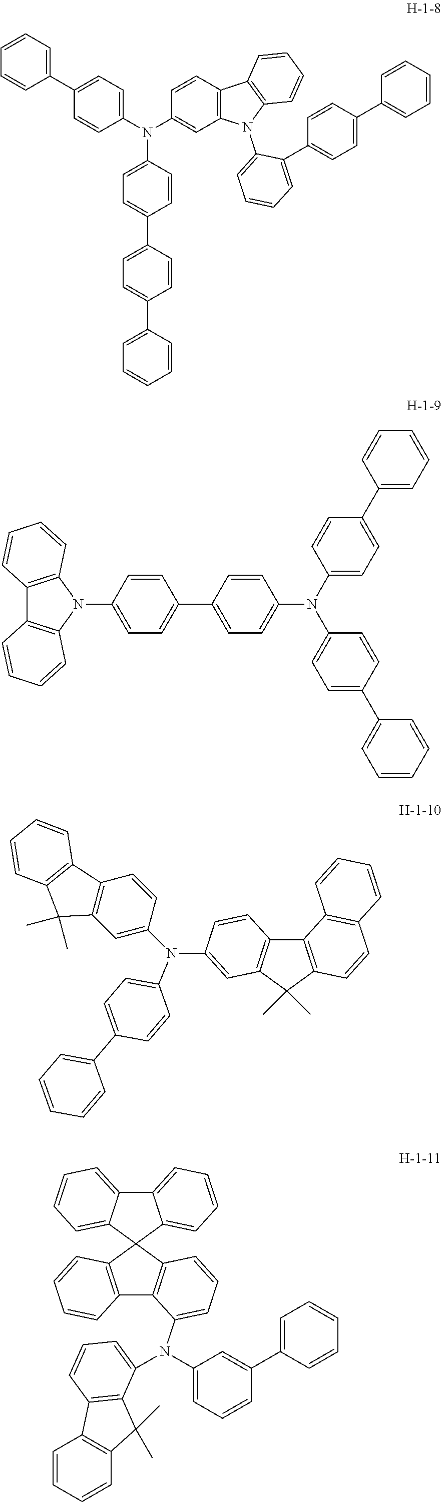 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

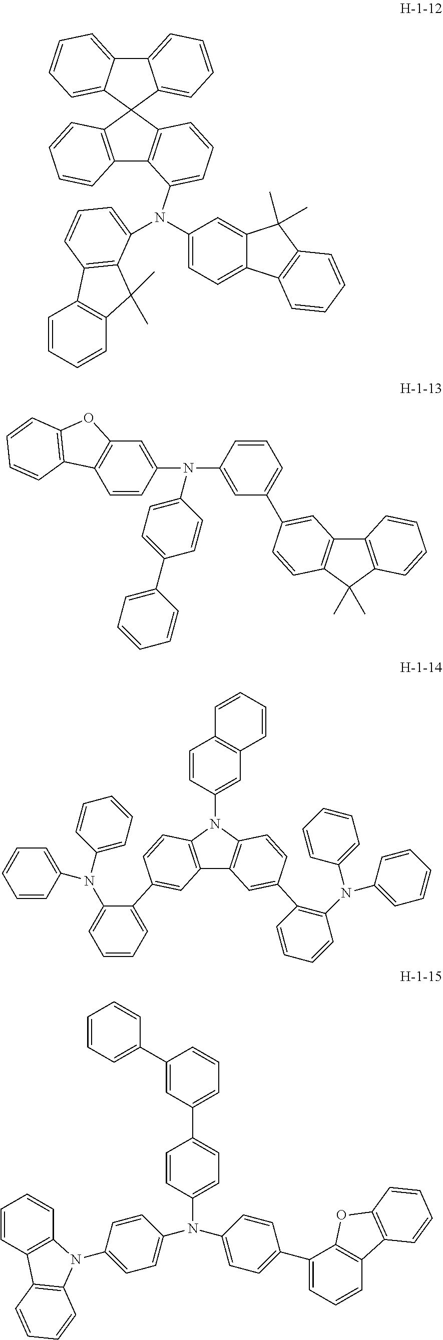 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

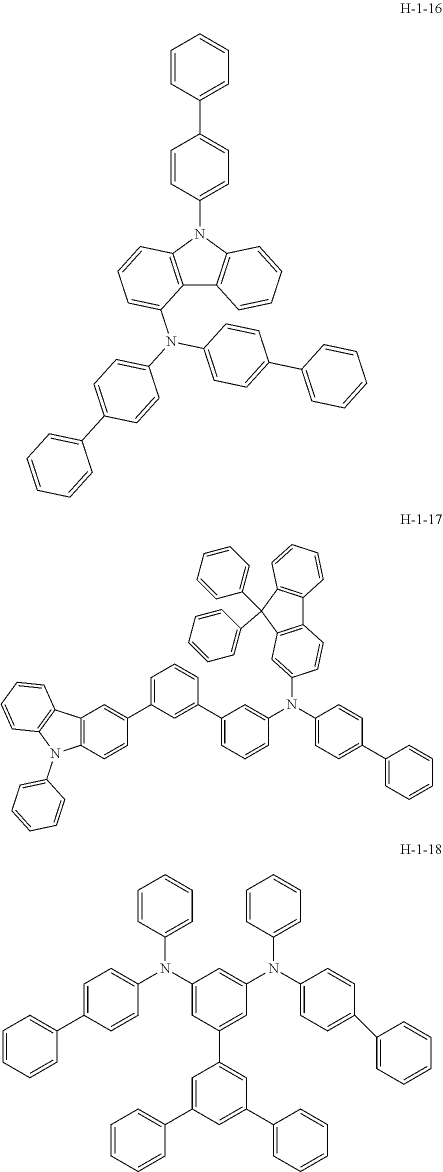 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

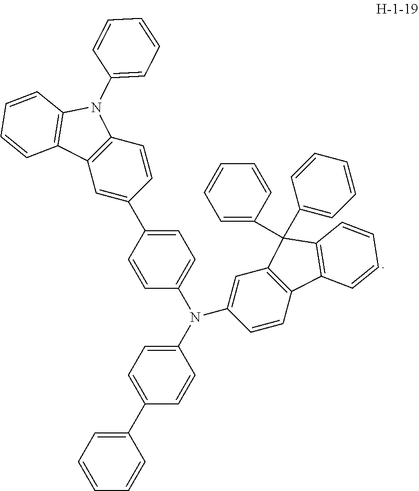 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include at least one selected from a phthalocyanine compound such as copper phthalocyanine; N¹,N¹′—([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′, 3′-h]quinoxaline-2,3,6,7,10,11-hexacarbonitrile (HATCN), etc.

In one or more embodiments, the hole transport region HTR may include at least one selected from a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include at least one of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. When the hole transport region HTR includes a hole injection layer HIL, the hole injection layer HIL may have, for example, a thickness of about 30 Å to about 1,000 Å. When the hole transport region HTR includes a hole transport layer HTL, the hole transport layer HTL may have a thickness of about 250 Å to about 1,000 Å. For example, when the hole transport region HTR includes an electron blocking layer EBL, the electron blocking layer EBL may have a thickness of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, in some embodiments, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML may be provided on the hole transport region HTR. The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The light emitting element ED of one or more embodiments may include a fused polycyclic compound represented by Formula 1 in the at least one functional layer disposed between the first electrode EL1 and the second electrode EL2. In the light emitting element ED according to one or more embodiments, the emission layer EML may include the fused polycyclic compound of one or more embodiments. In one or more embodiments, the emission layer EML may include the fused polycyclic compound of one or more embodiments as a dopant. The fused polycyclic compound of one or more embodiments may be a dopant material of the emission layer EML. In the present disclosure, the fused polycyclic compound of one or more embodiments may be referred to as a first compound.

The fused polycyclic compound of one or more embodiments may include a structure in which a plurality of aromatic rings are fused through at least one boron atom and at least two hetero atoms. The fused polycyclic compound of one or more embodiments may include a structure in which a plurality of aromatic rings are fused through a first boron atom, a first nitrogen atom, and a first hetero atom. For example, the fused polycyclic compound of one or more embodiments may include a fused ring formed as a plurality of aromatic rings are fused through one boron atom, the first nitrogen atom, and the first hetero atom.

The fused polycyclic compound of one or more embodiments may include a structure in which first to third aromatic rings (i.e., first aromatic ring, second aromatic ring, and third aromatic ring) are fused through the first boron atom, the first nitrogen atom, and the first hetero atom. The first to third aromatic rings may each be linked to the first boron atom, the first aromatic ring and the second aromatic ring may be linked through the first nitrogen atom, and the first aromatic ring and the third aromatic ring may be linked through the first hetero atom. Herein, the first boron atom, the first nitrogen atom, and the first hetero atom, and the fused structure formed by condensing the first to third aromatic rings through the first boron atom, the first nitrogen atom, and the first hetero atom may be referred to as a “fused ring core”.

In one or more embodiments, the first to third aromatic rings may each independently be a substituted or unsubstituted monocyclic aromatic hydrocarbon ring having 6 to 30 ring-forming carbon atoms or a substituted or unsubstituted monocyclic aromatic heterocycle having 2 to 30 ring-forming carbon atoms. The first to third aromatic rings may each independently be a 6-membered aromatic hydrocarbon ring. For example, in one or more embodiments, the first to third aromatic rings may each independently be benzene rings. In one or more embodiments, the first heteroatom may be oxygen (O), sulfur (S), carbon (C), silicon (Si), or nitrogen (N).

The fused polycyclic compound of one or more embodiments may include a first substituent linked to the fused ring core. The first substituent may be linked to the first nitrogen atom of the fused ring core. The first substituent may include a phenyl moiety and/or a heterocyclic moiety. The heterocyclic moiety may be a substituted pyridine group, a substituted pyrimidine group, or a substituted 1,3,5-triazine group. For example, in one or more embodiments, the heterocyclic moiety may be a substituted 1,3,5-triazine group.

The phenyl moiety may be linked to any one of carbon 2, carbon 4, and carbon 6 of the heterocyclic moiety, and a substituted or unsubstituted aromatic moiety may be linked to the other two carbons. For example, when the phenyl moiety is linked to carbon 2 of the heterocyclic moiety, a substituted or unsubstituted aromatic moiety may be linked to carbon 4 or carbon 6 of the heterocyclic moiety. In some embodiments, when the phenyl moiety is linked to carbon 4 of the heterocyclic moiety, a substituted or unsubstituted aromatic moiety may be linked to carbon 2 or carbon 6 of the heterocyclic moiety. In some embodiments, when the phenyl moiety is linked to carbon 6 of the heterocyclic moiety, a substituted or unsubstituted aromatic moiety may be linked to carbon 2 or carbon 4 of the heterocyclic moiety. In some embodiments, herein, the term “substituted or unsubstituted aromatic moiety” may be a substituted or unsubstituted aryl group having 6 to 30 carbon atoms or a substituted or unsubstituted heteroaryl group having 2 to 30 carbon atoms.

Herein, the carbons number of the heterocyclic moiety are numbered as indicated in the following structures H1 to H3.

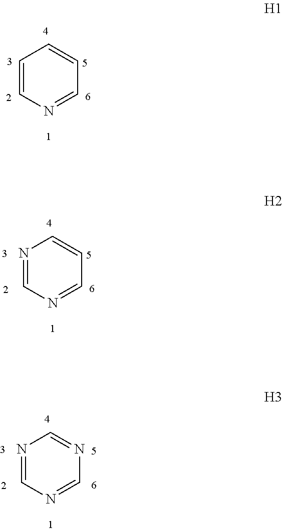 [SMILES: c1ccncc1 ; c1cncnc1 ; c1ncncn1]

In one or more embodiments, the first substituent may be linked to the first nitrogen atom of the fused ring core. The phenyl moiety of the first substituent may be linked to the first nitrogen atom of the fused ring core. Any one of six carbon atoms constituting the phenyl moiety may be linked to the heterocyclic moiety, and among the other five carbons, the carbon positioned ortho to the carbon atom to which the heterocyclic moiety is linked may be linked to the first nitrogen atom. For example, in one or more embodiments, the heterocyclic moiety and the first nitrogen atom may be linked to the phenyl moiety to be positioned ortho.

In one or more embodiments, the first substituent may include a phenyl moiety and a heterocyclic moiety linked to the phenyl moiety. The first substituent may be represented by Formula X1.

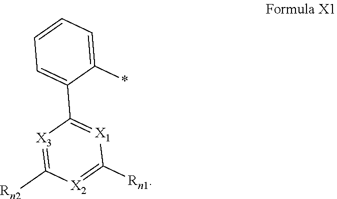

In Formula X1, at least one selected from among X₁ to X₃ may be N and the remainder may (e.g., may each) be CRₙ₃Rₙ₄. For example, one selected from among X₁ to X₃ may be N, and the other two may be CRₙ₃Rₙ₄. In some embodiments, two of X₁ to X₃ may be N, and the other one may be CRₙ₃Rₙ₄. In some embodiments, X₁ to X₃ may all be N.

In Formula X1, Rₙ₁ and Rₙ₂ may each independently be a substituted or unsubstituted aryl group having 6 to 30 ring-forming carbon atoms or a substituted or unsubstituted heteroaryl group having 2 to 30 ring-forming carbon atoms. For example, in some embodiments, Rₙ₁ and Rₙ₂ may each independently be a substituted or unsubstituted phenyl group. Herein, Rₙ₁ and Rₙ₂ may each correspond to the “aromatic moiety” described above.

In Formula X1, Rₙ₃ and Rₙ₄ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula X1, [symbol] is a site linked to the fused ring core.

However, for convenience of description, a substituent linked to the phenyl moiety is not provided in Formula X1. Unlike what is shown in Formula X1, the phenyl moiety included in the first substituent may have at least one substituent in addition to hydrogen atoms.

The fused polycyclic compound of one or more embodiments may be represented by Formula 1.

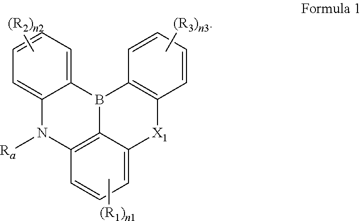

The fused polycyclic compound of one or more embodiments represented by Formula 1 may include a structure in which three aromatic rings are fused via a first boron atom, a first nitrogen atom, and a first hetero atom. Herein, a benzene ring substituted with a substituent represented by R₁ in Formula 1 may correspond to the first aromatic ring described above, a benzene ring substituted with a substituent represented by R₂ may correspond to the second aromatic ring described above, and a benzene ring substituted with a substituent represented by R₃ may correspond to the third aromatic ring described above.

In Formula 1, X₁ may be O, S, NR₄, CR₅R₆, or SiR₇R₈.

In Formula 1, R₁ to R₈ may each independently be hydrogen, deuterium, a halogen, a cyano group, a nitro group, a substituted or unsubstituted amine group, a substituted or unsubstituted silyl group, a substituted or unsubstituted oxy group, a substituted or unsubstituted thio group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 30 ring-forming carbon atoms, or a substituted or unsubstituted heteroaryl group having 2 to 30 ring-forming carbon atoms. In some embodiments, R₁ to R₈ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among R₁ to R₈ may each independently be bonded to an adjacent group to form a ring. For example, in one or more embodiments, R₁ to R₈ may each independently be hydrogen, an unsubstituted t-butyl group, a substituted or unsubstituted phenyl group, a substituted or unsubstituted biphenyl group, a substituted or unsubstituted terphenyl group, or a substituted or unsubstituted carbazole group.

In one or more embodiments, when X₁ is NR₄, a substituent represented by R₄ may be a substituted or unsubstituted aryl group having 6 to 30 ring-forming carbon atoms or a substituted or unsubstituted heteroaryl group having 2 to 30 ring-forming carbon atoms, or may be represented by Formula S. In one or more embodiments, when X₁ is NR₄, the substituent represented by R₄ may be a substituted or unsubstituted biphenyl group or a substituted or unsubstituted terphenyl group, or may be represented by Formula S.

In one or more embodiments, when X₁ is NR₄, the substituent represented by R₄ may be represented by Formula B or Formula S.

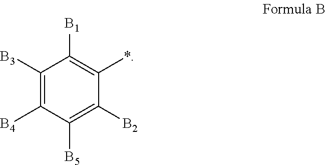

In Formula B, B₁ to B₅ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, B₁ to B₅ may each independently be hydrogen, deuterium, a substituted or unsubstituted t-butyl group, or a substituted or unsubstituted phenyl group.

In Formula B, at least one of B₁ or B₂ may each independently be a substituted or unsubstituted aryl group having 6 to 30 ring-forming carbon atoms or a substituted or unsubstituted heteroaryl group having 2 to 30 ring-forming carbon atoms. In some embodiments, at least one of B₁ or B₂ may be a substituted or unsubstituted phenyl group. For example, in Formula B, any one of B₁ and B₂ may be a substituted or unsubstituted phenyl group, and the other one may be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, in Formula B, B₁ and B₂ may each be a substituted or unsubstituted phenyl group.

In Formula 1, Rₐ may be represented by Formula S. Herein, a substituent represented by Formula S may correspond to the first substituent described above.

In Formula 1, n1 may be an integer of 0 to 3. In Formula 1, when n1 is 0, the fused polycyclic compound of one or more embodiments may not be substituted with R₁. In Formula 1, When n1 is 3, and R₁'s are each hydrogen, the embodiment may be the same as when n1 is 0 in Formula 1. When n1 is an integer of 2 or greater, R₁ provided in plurality may all be the same, or at least one of (e.g., at least one selected from among) the plurality of R₁'s may be different.

In Formula 1, n2 and n3 may each independently be an integer of 0 to 4. In Formula 1, when n2 and n3 are each 0, the fused polycyclic compound of one or more embodiments may not be substituted with each of R₂ and R₃. When n2 and n3 are each 4 and R₂'s and R₃'s are each hydrogen, the embodiment may be the same as when n2 and n3 are each 0. When n2 and n3 are each an integer of 2 or greater, R₂ and R₃ each provided in plurality may each be the same, or at least one of R₂ or R₃ each provided in plurality may be different.

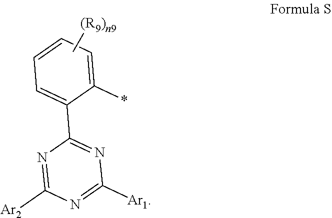

In Formula S, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, Ar₁ and Ar₂ may each independently be a substituted or unsubstituted phenyl group.

In Formula S, R₉ may be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, R₉ may be bonded to an adjacent group to form a ring. For example, in one or more embodiments, R₉ may be hydrogen, an unsubstituted t-butyl group, or a substituted or unsubstituted phenyl group.

In Formula S, n9 is an integer of 0 to 4. In Formula S, when n9 is 0, the fused polycyclic compound of one or more embodiments may not be substituted with R₉. In Formula S, when n9 is 4, and R₉'s are each hydrogen, the embodiment may be the same as when n9 is 0. When n9 is an integer of 2 or greater, R₉ provided in plurality may all be the same, or at least one of (e.g., at least one selected from among) the plurality of R₉'s may be different.

In Formula S, [symbol] is a site linked to Formula 1.

In one or more embodiments, the substituent represented by Formula S may be represented by Formula S1.

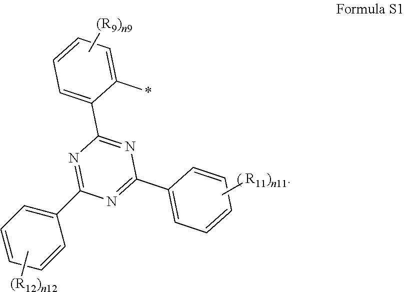

In Formula S1, R₁₁ and R₁₂ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₁₁ and R₁₂ may each independently be hydrogen.

In Formula S1, n11 and n12 may each independently be an integer of 0 to 5. In Formula S1, when n11 and n12 are each 0, the fused polycyclic compound of one or more embodiments may not be substituted with each of R₁₁ and R₁₂. When n11 and n12 are each 5 and R₁₁'s and R₁₂'s are each hydrogen, the embodiment may be the same as when n11 and n12 are each 0. When n11 and n12 are each an integer of 2 or greater, R₁₁ and R₁₂ each provided in plurality may each be the same, or at least one of R₁₁ or R₁₂ each provided in plurality may be different.

In Formula S1, the same descriptions as in Formula S may also apply to R₉ and n9.

In one or more embodiments, the first compound represented by Formula 1 may be represented by Formula 2.

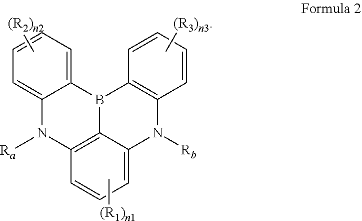

In Formula 2, Rb may be represented by any one selected from among Formulas A-1 to A-3.

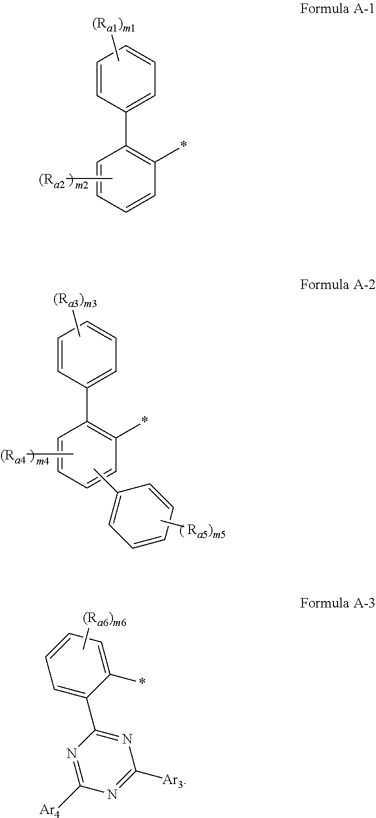

In Formulas A-1 to A-3, Rₐ₁ to Rₐ₆ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among Rₐ₁ to Rₐ₆ may each independently be bonded to an adjacent group to form a ring. For example, in some embodiments, Rₐ₁ to Rₐ₆ may each independently be hydrogen, an unsubstituted t-butyl group, or a substituted or unsubstituted phenyl group.

In Formula A-3, Ar₃ and Ar₄ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, Ar₃ and Ar₄ may each independently be a substituted or unsubstituted phenyl group.

In Formulas A-1 and A-2, m1, m3, and m5 may each independently be an integer of 0 to 5. In Formulas A-1 and A-2, when m1, m3, and m5 are each 0, the fused polycyclic compound of one or more embodiments may not be substituted with each of Rₐ₁, Rₐ₃, and Rₐ₅. When m1, m3, and m5 are each 5 and Rₐ₁'s, Rₐ₃'s, and Rₐ₅'s are each hydrogen, the embodiment may be the same as when m1, m3, and m5 are each 0. When m1, m3, and m5 are each an integer of 2 or greater, Rₐ₁, Rₐ₃, and Rₐ₅ each provided in plurality may each be the same, or at least one of Rₐ₁, Rₐ₃, or Rₐ₅ each provided in plurality may be different.

In Formulas A-1 and A-3, m2 and m6 may each independently be an integer of 0 to 4. In Formulas A-1 and A-3, when m2 and m6 are each 0, the fused polycyclic compound of one or more embodiments may not be substituted with each of Rₐ₂ and Rₐ₆. When m2 and m6 are each 4 and Rₐ₂'s and Rₐ₆'s are each hydrogen, the embodiment may be the same as when m2 and m6 are each 0. When m2 and m6 are each an integer of 2 or greater, Rₐ₂ and Rₐ₆ each provided in plurality may each be the same, or at least one of Rₐ₂ or Rₐ₆ each provided in plurality may be different.

In Formula A-2, m4 is an integer of 0 to 3. In Formula A-2, when m4 is 0, the fused polycyclic compound of one or more embodiments may not be substituted with Rₐ₄. In Formula A-2, when m4 is 3 and Rₐ₄'s are each hydrogen, the embodiment may be the same when m4 is 0 in Formula A-2. When m4 is an integer of 2 or greater, Rₐ₄ provided in plurality may all be the same, or at least one of (e.g., at least one selected from among) the plurality of Rₐ₄'s may be different.

In Formulas A-1 to A-3, [symbol] is a site linked to Formula 2.

In Formula 2, the same descriptions as those described in Formula 1 may apply to R₁ to R₃, Rₐ, and n1 to n3.

In one or more embodiments, a group represented by Formula A-2 may be represented by Formula A-2-1 or Formula A-2-2.

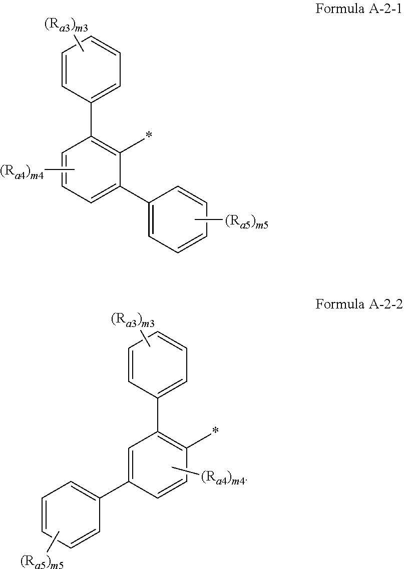

In Formulas A-2-1 and A-2-2, the same descriptions as those described in Formula A-2 may apply to Rₐ₃ to Rₐ₅, and m3 to m5.

The fused polycyclic compound of one or more embodiments may include a second substituent. The second substituent may be linked to at least one selected from among the first to third aromatic rings of the fused ring core. In one or more embodiments, the second substituent may be provided in plurality. The second substituent may be linked to the fused ring core and may serve to improve material stability. In one or more embodiments, the second substituent may each independently be a substituted or unsubstituted amine group, a substituted or unsubstituted aryl group having 6 to 30 ring-forming carbon atoms, or a substituted or unsubstituted heteroaryl group having 2 to 30 ring-forming carbon atoms. For example, in one or more embodiments, the second substituent may be a substituted or unsubstituted diphenylamine group, a substituted or unsubstituted phenyl group, a substituted or unsubstituted carbazole group, a substituted or unsubstituted fluorenyl group, a substituted or unsubstituted dibenzofuran group, a substituted or unsubstituted dibenzothiophene group, a substituted or unsubstituted phenoxazine group, a substituted or unsubstituted acridine group, or a substituted or unsubstituted phenothiazine group.

In one or more embodiments, the first compound represented by Formula 1 may be represented by Formula 3.

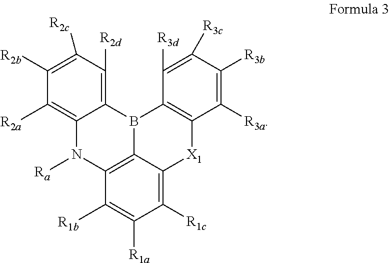

In Formula 3, R₁ₐ to R_{1c}, R₂ₐ to R_{2d}, and R₃ₐ to R_{3d} may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among R₁ₐ to R_{1c}, R₂ₐ to R_{2d}, and R₃ₐ to R_{3d} may each independently be bonded to an adjacent group to form a ring. For example, in some embodiments, R₁ₐ to R_{1c}, R₂ₐ to R_{2d}, and R₃ₐ to R_{3d} may each independently be hydrogen, an unsubstituted t-butyl group, a substituted or unsubstituted phenyl group, or a substituted or unsubstituted carbazole group.

In one or more embodiments, in Formula 3, at least one selected from among R₁ₐ to R_{1c}, R₂ₐ to R_{2d}, and R₃ₐ to R_{3d} may be a substituted or unsubstituted alkyl group having 1 to 10 carbon atoms, or may be represented by any one selected from among Formulas B-1 to B-4. In some embodiments, in Formula 3, at least one selected from among R₁ₐ to R_{1c}, R₂ₐ to R_{2d}, and R₃ₐ to R_{3d} may be selected from Substituent Group 1, which will be described later.

In one or more embodiments, at least two selected from among R₁ₐ to R_{1c}, R₂ₐ to R_{2d}, and R₃ₐ to R_{3d} may be represented by any one selected from among Formulas B-1 to B-4, and the remainder may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, among R₁ₐ to R_{1c}, R₂ₐ to R_{2d}, and R₃ₐ to R_{3d}, R_{2b} and R_{3b} may each independently be represented by any one selected from among Formulas B-1 to B-4, and the remainder may be hydrogens. In some embodiments, among R₁ₐ to R_{1c}, R₂ₐ to R_{2d}, and R₃ₐ to R_{3d}, R_{2c} and R_{3c} may each independently be represented by any one selected from among Formulas B-1 to B-4, and the remainder may be hydrogens. In some embodiments, among R₁ₐ to R_{1c}, R₂ₐ to R_{2d}, and R₃ₐ to R_{3d}, R_{2b} and R_{3c} may each independently be represented by any one selected from among Formulas B-1 to B-4, and the remainder may be hydrogens. In some embodiments, among R₁ₐ to R_{1c}, R₂ₐ to R_{2d}, and R₃ₐ to R_{3d}, R_{2c} and R_{3b} may each independently be represented by any one selected from among Formulas B-1 to B-4, and the remainder may be hydrogens.

In one or more embodiments, at least three selected from among R₁ₐ to R_{1c}, R₂ₐ to R_{2d}, and R₃ₐ to R_{3d} may be represented by any one selected from among Formulas B-1 to B-4, and the remainder may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in some embodiments, among R₁ₐ to R_{1c}, R₂ₐ to R_{2d}, and R₃ₐ to R_{3d}, R₁ₐ, R_{2b} and R_{3b} may each independently be represented by any one selected from among Formulas B-1 to B-4, and the remainder may be hydrogens. In some embodiments, among R₁ₐ to R_{1c}, R₂ₐ to R_{2d}, and R₃ₐ to R_{3d}, R₁ₐ, R_{2c} and R_{3c} may each independently be represented by any one selected from among Formulas B-1 to B-4, and the remainder may be hydrogens. In some embodiments, among R₁ₐ to R_{1c}, R₂ₐ to R_{2d}, and R₃ₐ to R_{3d}, R₁ₐ, R_{2b} and R_{3c} may each independently be represented by any one selected from among Formulas B-1 to B-4, and the remainder may be hydrogens. In some embodiments, among R₁ₐ to R_{1c}, R₂ₐ to R₂ₐ, and R₃ₐ to R_{3d}, R₁ₐ, R_{2c} and R_{3b} may each independently be represented by any one selected from among Formulas B-1 to B-4, and the remainder may be hydrogens.

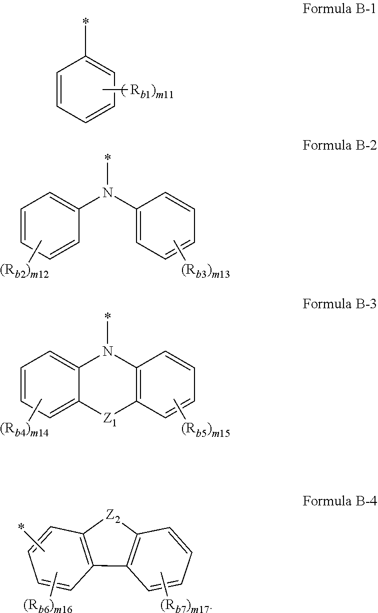

In Formula B-3, Z₁ may be a direct linkage, O, S, or CR_{b8}R_{b9}.

In Formula B-4, Z₂ may be O, S, NR_{b10}, or CR_{b11}R_{b12}.

In Formulas B-1 to B-4, R_{b1} to R_{b12} may each independently be hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among R_{b1} to R_{b12} may each independently be bonded to an adjacent group to form a ring. For example, in some embodiments, R_{b1} to R_{b12} may each independently be hydrogen, deuterium, an unsubstituted t-butyl group, or a substituted or unsubstituted phenyl group. In some embodiments, when R_{b11} and R_{b12} are bonded to form a ring, the substituent represented by Formula B-4 may have a spiro structure.

In Formulas B-1 and B-2, m11 to m13 may each independently be an integer of 0 to 5. In Formulas B-1 and B-2, when m11 to m13 are each 0, the fused polycyclic compound of one or more embodiments may not be substituted with each of R_{b1} to R_{b3}. When m11 to m13 are each 5 and R_{b1}'s to R_{b3}'s are each hydrogen, the embodiment may be the same as when m11 to m13 are each 0. When m11 to m13 are each an integer of 2 or greater, R_{b1} to R_{b3} each provided in plurality may each be the same, or at least one selected from among R_{b1} to R_{b3} each provided in plurality may be different.

In Formulas B-3 and B-4, m14, m15, and m17 may each independently be an integer of 0 to 4. In Formulas B-3 and B-4, when m14, m15, and m17 are each 0, the fused polycyclic compound of one or more embodiments may not be substituted with each of R_{b4}, R_{b5}, and R_{b7}. When m14, m15, and m17 are each 4 and R_{b4}'s, R_{b5}'s, and R_{b7}'s are each hydrogen, the embodiment may be the same as when m14, m15, and m17 are each 0. When m14, m15, and m17 are each an integer of 2 or greater, R_{b4}, R_{b5}, and R_{b7} each provided in plurality may each be the same, or at least one of R_{b4}, R_{b5}, or R_{b7} each provided in plurality may be different.

In Formula B-4, m16 is an integer of 0 to 3. In Formula B-4, when m16 is 0, the fused polycyclic compound of one or more embodiments may not be substituted with R_{b6}. In Formula B-4, when m16 is 3 and R_{b6}'s are each hydrogen, the embodiment may be the same when m16 is 0 in Formula B-4. When m16 is an integer of 2 or greater, R_{b6} provided in plurality may all be the same, or at least one of (e.g., at least one selected from among) the plurality of R_{b6}'s may be different.

In Formula 3, the same descriptions as those described in Formula 1 may apply to X₁ and Rₐ.

In one or more embodiments, the first compound represented by Formula 3 may be represented by any one selected from among Formulas 4-1 to 4-4.

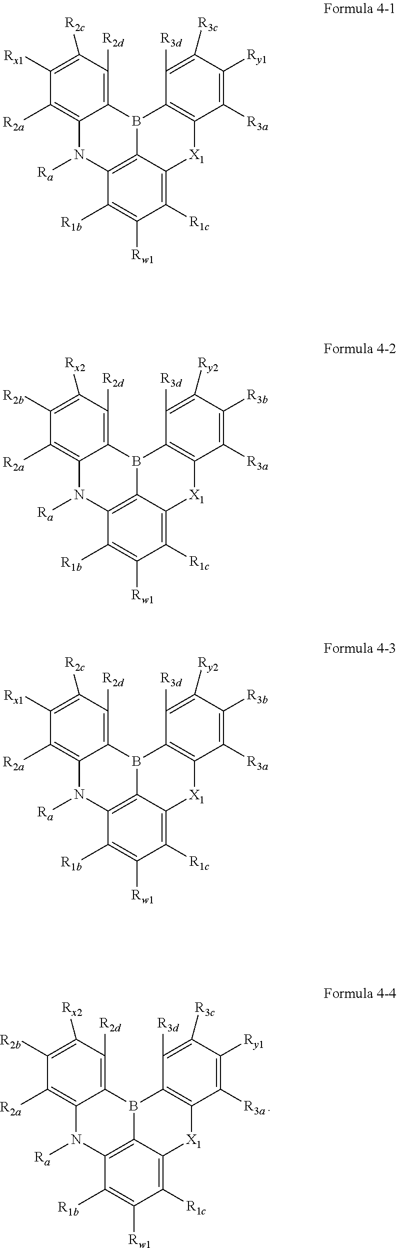

In Formulas 4-1 to 4-4, R_{w1} may be hydrogen or a substituted or unsubstituted alkyl group having 1 to 10 carbon atoms, or may be represented by any one selected from among Formulas B-1 to B-4. For example, in one or more embodiments, R_{w1} may be hydrogen, an unsubstituted t-butyl group, a substituted or unsubstituted phenyl group, or a substituted or unsubstituted carbazole group.

In Formulas 4-1 to 4-4, Rₓ₁, Rₓ₂, R_{y1}, and R_{y2} may each independently be represented by any one selected from among Formulas B-1 to B-4. For example, in one or more embodiments, Rₓ₁, Rₓ₂, R_{y1}, and R_{y2} may each independently be a substituted or unsubstituted phenyl group or a substituted or unsubstituted carbazole group. In some embodiments, in Formulas 4-1 to 4-4, Rₓ₁, Rₓ₂, R_{y1}, and R_{y2} may each be selected from Substituent Group 1, which will be described later.

In Formulas 4-1 to 4-4, the same descriptions as those described above in Formulas 1 and 3 may apply to X₁, Rₐ, R_{1b}, R_{1c}, R₂ₐ to R_{2d}, and R₃ₐ to R_{3d}.

In one or more embodiments, the first compound represented by Formula 1 may be represented by any one selected from among Formulas 5-1 to 5-3.

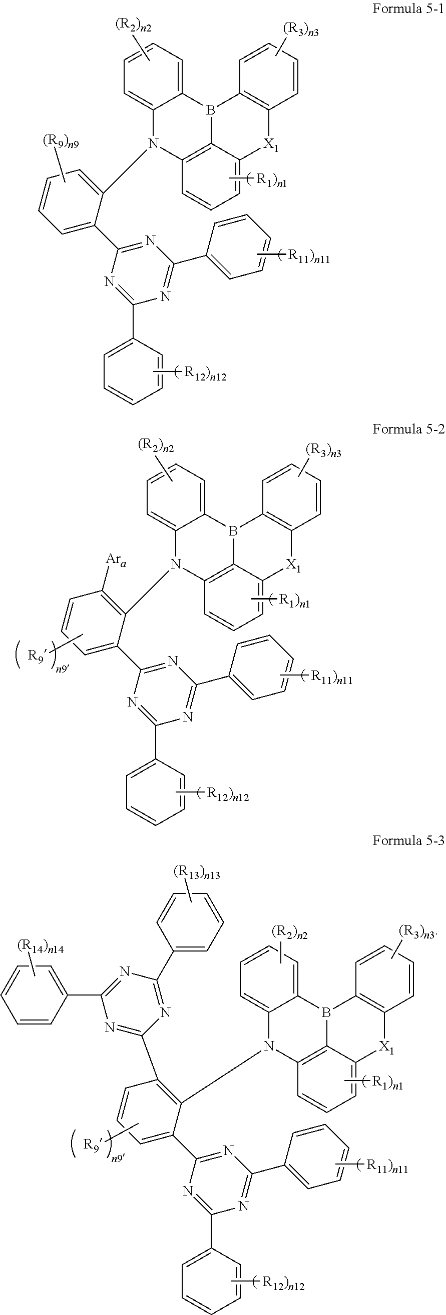

In Formulas 5-1 to 5-3, Arₐ may be a substituted or unsubstituted aryl group having 6 to 30 ring-forming carbon atoms or a substituted or unsubstituted heteroaryl group having 2 to 30 ring-forming carbon atoms. For example, in one or more embodiments, Arₐ may be a substituted or unsubstituted phenyl group.

In Formulas 5-1 to 5-3, R₉′ and R₁₁ to R₁₄ may each independently be deuterium, hydrogen, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among R₉′ and R₁₁ to R₁₄ may each independently be bonded to an adjacent group to form a ring.

In Formulas 5-2 and 5-3, n9′ is an integer of 0 to 3. In Formulas 5-2 and 5-3, when n9′ is 0, the fused polycyclic compound of one or more embodiments may not be substituted with R₉′. In Formulas 5-2 and 5-3, when n9′ is 3 and R₉″s are each hydrogen, the embodiment may be the same when n9′ is 0 in Formulas 5-2 and 5-3. When n9′ is an integer of 2 or greater, R₉′ provided in plurality may all be the same, or at least one of (e.g., at least one selected from among) the plurality of R₉″s may be different.

In Formulas 5-2 and 5-3, n11 to n14 may each independently be an integer of 0 to 5. In Formulas 5-2 and 5-3, when n11 to n14 are each 0, the fused polycyclic compound of one or more embodiments may not be substituted with each of R₁₁ to R₁₄. When n11 to n14 are each 5 and R₁₁'s to R₁₄'s are each hydrogen, the embodiment may be the same as when n11 to n14 are each 0. When n11 to n14 are each an integer of 2 or greater, R₁₁ to R₁₄ each provided in plurality may each be the same, or at least one of (e.g., at least one selected from among) the plurality of R₁₁'s to R₁₄'s may be different.

In Formulas 5-1 to 5-3, the same descriptions as those described above in Formula 1 and Formula S may apply to X₁, R₁ to R₃, R₉, n1 to n3, and n9.

In one or more embodiments, the first compound represented by Formula 1 may be represented by any one selected from among Formulas 6-1 to 6-3.

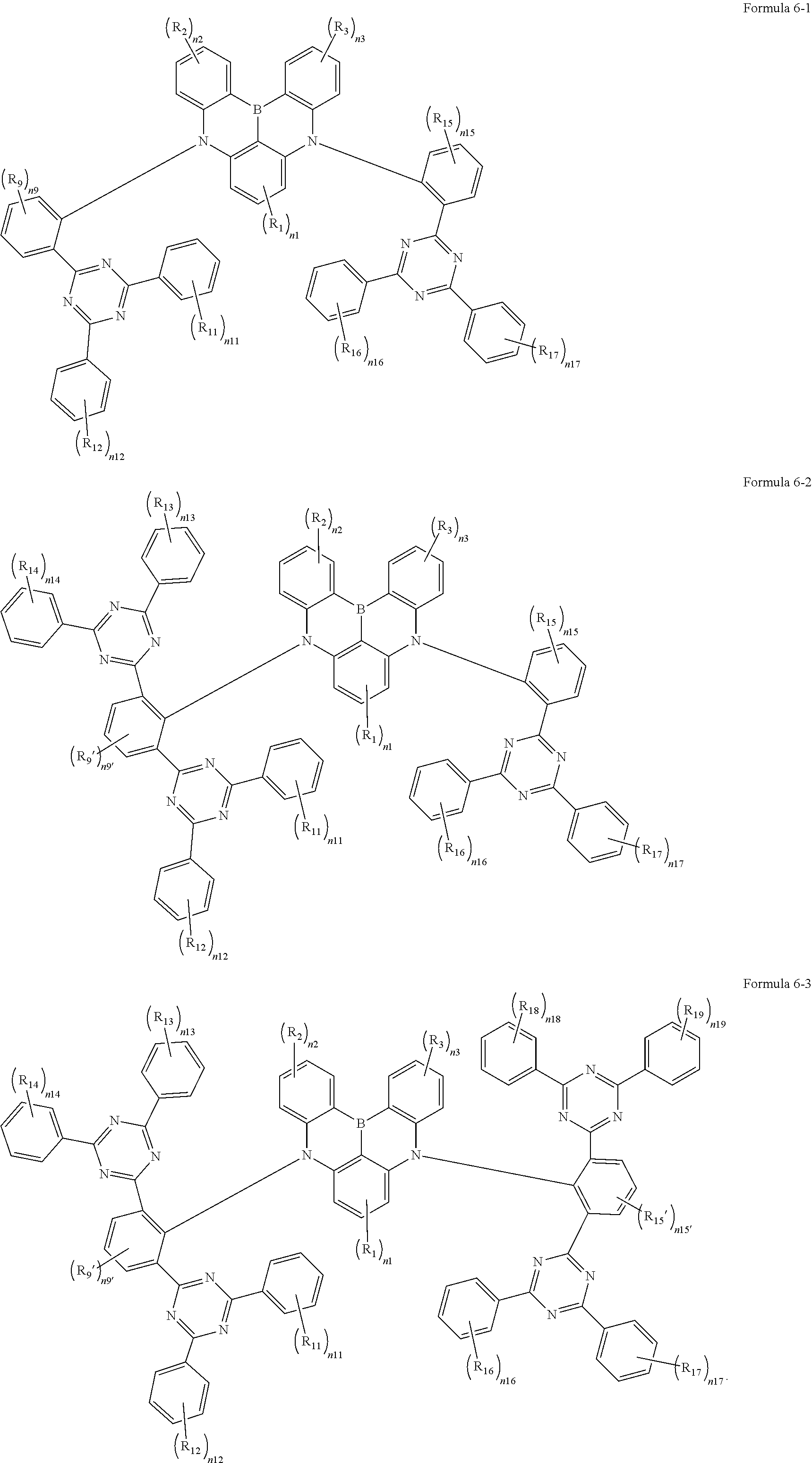

In Formulas 6-1 to 6-3, R₉′, R₁₅′, and R₁₁ to R₁₉ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more selected from among R₉′, R₁₅′, and R₁₁ to R₁₉ may each independently be bonded to an adjacent group to form a ring. For example, in one or more embodiments, R₉′, R₁₅′, and R₁₁ to R₁₉ may each independently be hydrogen, an unsubstituted t-butyl group, or a substituted or unsubstituted phenyl group.

In Formulas 6-2 and 6-3, n9′ and n15′ may each independently be an integer of 0 to 3. In Formulas 6-2 and 6-3, when n9′ and n15′ are each 0, the fused polycyclic compound of one or more embodiments may not be substituted with each of R₉′ and R₁₅′. When n9′ and n15′ are each 3 and R₉″s and R₁₅″s are each hydrogen, the embodiment may be the same as when n9′ and n15′ are each 0. When n9′ and n15′ are each an integer of 2 or greater, R₉′ and R₁₅′ each provided in plurality may each be the same, or at least one of R₉′ or R₁₅′ each provided in plurality may be different.

In Formulas 6-1 to 6-3, n11 to n14 and n16 to n19 may each independently be an integer of 0 to 5. In Formulas 6-1 to 6-3, when n11 to n14 and n16 to n19 are each 0, the fused polycyclic compound of one or more embodiments may not be substituted with each of R₁₁ to R₁₄ and R₁₆ to R₁₉. When n11 to n14, and n16 to n19 are each 5 and R₁₁'s to R₁₄'s and R₁₆'s to R₁₉'s are each hydrogen, the embodiment may be the same as when n11 to n14 and n16 to n19 are each 0. When n11 to n14 and n16 to n19 are each an integer of 2 or greater, R₁₁ to R₁₄ and R₁₆ to R₁₉ each provided in plurality may each be the same, or at least one selected from among R₁₁ to R₁₄ and R₁₆ to R₁₉ each provided in plurality may be different.

In Formulas 6-1 and 6-2, n15 is an integer of 0 to 4. In Formulas 6-1 and 6-2, when n15 is 0, the fused polycyclic compound of one or more embodiments may not be substituted with R₁₅. In Formulas 6-1 and 6-2, when n15 is 4 and R₁₅'s are each hydrogen, the embodiment may be the same when n15 is 0 in Formulas 6-1 and 6-2. When n15 is an integer of 2 or greater, R₁₅ provided in plurality may all be the same, or at least one of (e.g., at least one selected from among) the plurality of R₁₅'s may be different.

In Formulas 6-1 to 6-3, the same descriptions as those described above in Formula 1 and Formula S may apply to R₁ to R₃, R₉, n1 to n3, and n9.

In one or more embodiments, the first compound represented by Formula 1 may be represented by any one selected from among Formulas 7-a to 7-d.

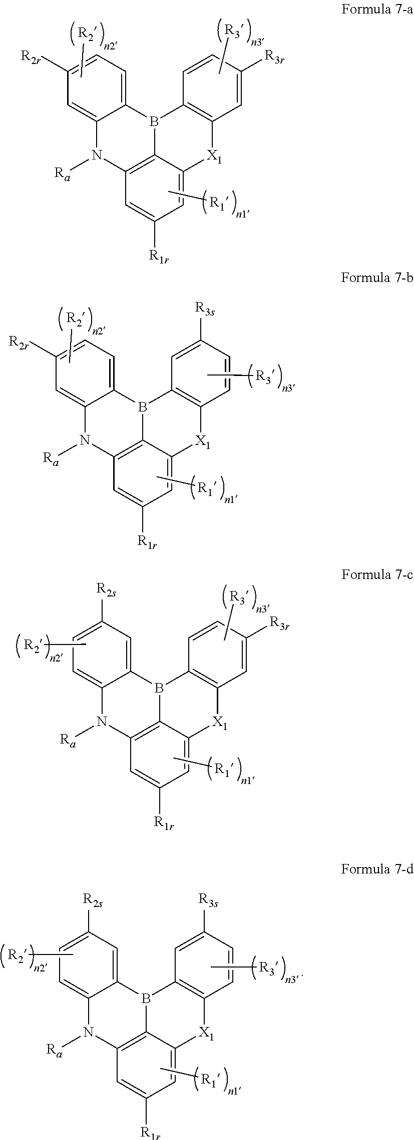

In Formulas 7-a to 7-d, R₁′, R₂′, and R₃′ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₁′, R₂′, and R₃′ may each independently be a hydrogen atom.

In Formulas 7-a to 7-d, R₂ᵣ, R₂ₛ, R₃ᵣ, and R₃ₛ may each independently be represented by any one selected from among Formulas B-1 to B-4. For example, in one or more embodiments, R₂ᵣ, R₂ₛ, R₃ᵣ, and R₃ₛ may each independently be a substituted or unsubstituted amine group, a substituted or unsubstituted phenyl group, a substituted or unsubstituted carbazole group, a substituted or unsubstituted dibenzofuran group, or a substituted or unsubstituted dibenzothiophene group, In some embodiments, in Formulas 7-a to 7-d, R₂ᵣ, R₂ₛ, R₃ᵣ, and R₃ₛ may each independently be selected from Substituent Group 1, which will be described later.

In Formulas 7-a to 7-d, R₁ᵣ may be hydrogen, deuterium, or a substituted or unsubstituted alkyl group having 1 to 10 carbon atoms, or may be represented by any one selected from among Formulas B-1 to B-4. For example, in one or more embodiments, R₁ᵣ may be hydrogen, an unsubstituted t-butyl group, a substituted or unsubstituted amine group, a substituted or unsubstituted alkyl group having 1 to 10 carbon atoms, a substituted or unsubstituted phenyl group, a substituted or unsubstituted carbazole group, a substituted or unsubstituted dibenzofuran group, or a substituted or unsubstituted dibenzothiophene group.

In Formulas 7-a to 7-d, the same descriptions as those described above in Formula 1 may apply to X₁ and Rₐ.

In one or more embodiments, the first compound represented by Formula 1 may be represented by any one selected from among Formulas 7-1 to 7-4.

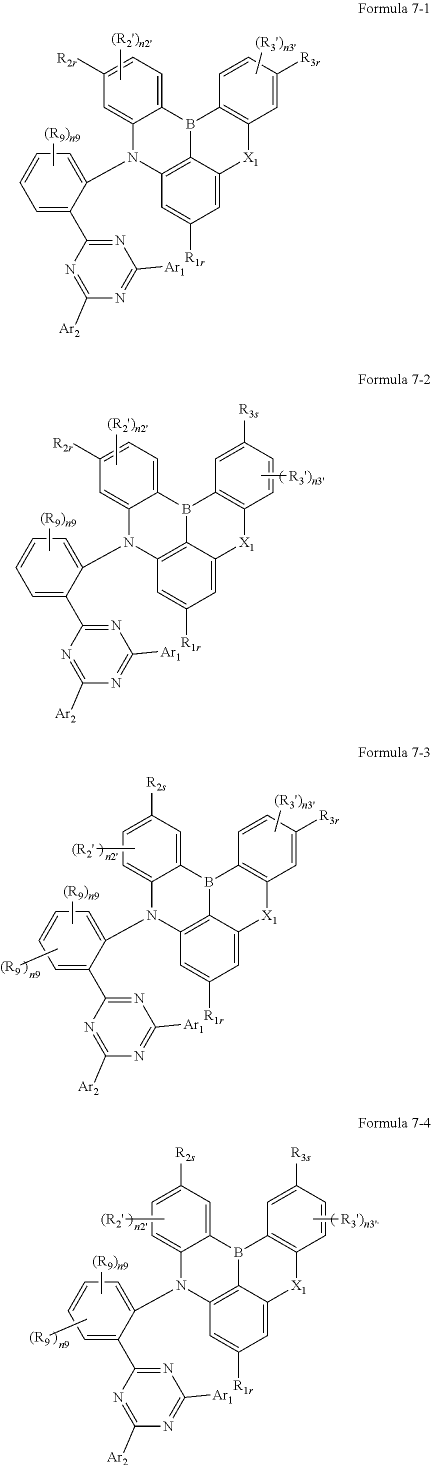

In Formulas 7-1 to 7-4, R₂′ and R₃′ may each independently be hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₂′ and R₃′ may each independently be hydrogen.

In Formulas 7-1 to 7-4, the same descriptions as those described above in Formulas 7-a to 7-d may apply to R₂ᵣ, R₂ₛ, R₃ᵣ, and R₃ₛ. For example, in one or more embodiments, R₂ᵣ, R₂ₛ, R₃ᵣ, and R₃ₛ may each independently be a substituted or unsubstituted amine group, a substituted or unsubstituted phenyl group, a substituted or unsubstituted carbazole group, a substituted or unsubstituted dibenzofuran group, or a substituted or unsubstituted dibenzothiophene group,

In Formulas 7-1 to 7-4, the same descriptions as those described above in Formulas 7-a to 7-d may apply to R₁ᵣ. For example, in one or more embodiments, R₁ᵣ may be hydrogen, deuterium, a substituted or unsubstituted amine group, a substituted or unsubstituted alkyl group having 1 to 10 carbon atoms, a substituted or unsubstituted phenyl group, a substituted or unsubstituted carbazole group, a substituted or unsubstituted dibenzofuran group, or a substituted or unsubstituted dibenzothiophene group.

In Formulas 7-1 to 7-4, the same descriptions as those described above in Formula 1 and Formula S may apply to X₁, Ar₁, Ar₂, R₉, and n9.

In one or more embodiments, the first compound represented by Formula 1 may be represented by Formula 8-1 or Formula 8-2.

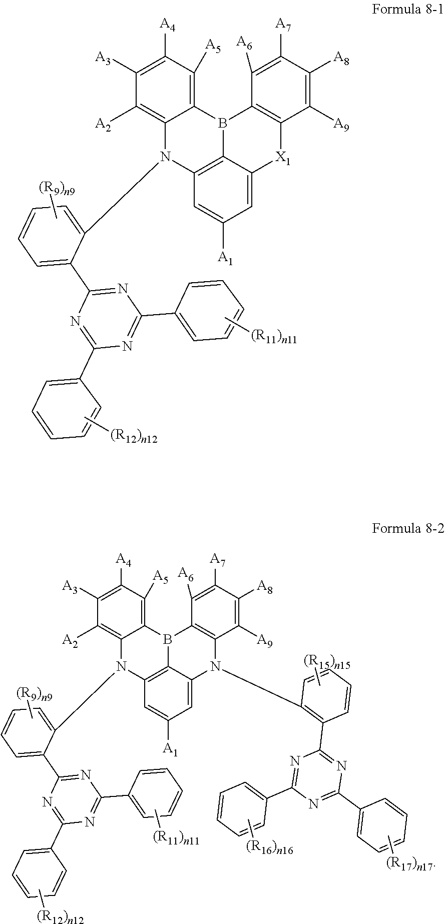

In Formulas 8-1 and 8-2, R₁₁, R₁₂, R₁₅ to R₁₇, and A₁ to A₉ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₁₁, R₁₂, and R₁₅ to R₁₇ may each independently be hydrogen, an unsubstituted t-butyl group, or a substituted or unsubstituted phenyl group. Additionally, A₁ to A₉ may each independently be hydrogen, a substituted or unsubstituted phenyl group, or a substituted or unsubstituted carbazole group.

In Formulas 8-1 and 8-2, at least one selected from among A₁ to A₉ may be selected from Substituent Group 1.

In Formulas 8-1 and 8-2, n11, n12, n16, and n17 may each independently be an integer of 0 to 5.

In Formulas 8-1 and 8-2, when n11, n12, n16, and n17 are each 0, the fused polycyclic compound of one or more embodiments may not be substituted with each of R₁₁, R₁₂, R₁₆, and R₁₇. When n11, n12, n16, and n17 are each 5 and R₁₁'s, R₁₂'s, R₁₆'s, and R₁₇'s are each hydrogen, the embodiment may be the same as when n11, n12, n16, and n17 are each 0. When n11, n12, n16, and n17 are each an integer of 2 or greater, R₁₁, R₁₂, R₁₆, and R₁₇ each provided in plurality may each be the same, or at least one selected from among R₁₁, R₁₂, R₁₆, or R₁₇ each provided in plurality may be different.

In Formula 8-2, n15 is an integer of 0 to 4. In Formula 8-2, when n15 is 0, the fused polycyclic compound of one or more embodiments may not be substituted with R₁₅. In Formula 8-2, When n15 is 4, and R₁₅'s are each hydrogens, the embodiment may be the same as when n15 is 0 in Formula 8-2. When n15 is an integer of 2 or greater, R₁₅ each provided in plurality may all be the same, or at least one of (e.g., at least one selected from among) the plurality of R₁₅'s may be different.

In Formulas 8-1 and 8-2, the same descriptions as those described above in Formula 1 and Formula S may apply to X₁, R₉, and n9.

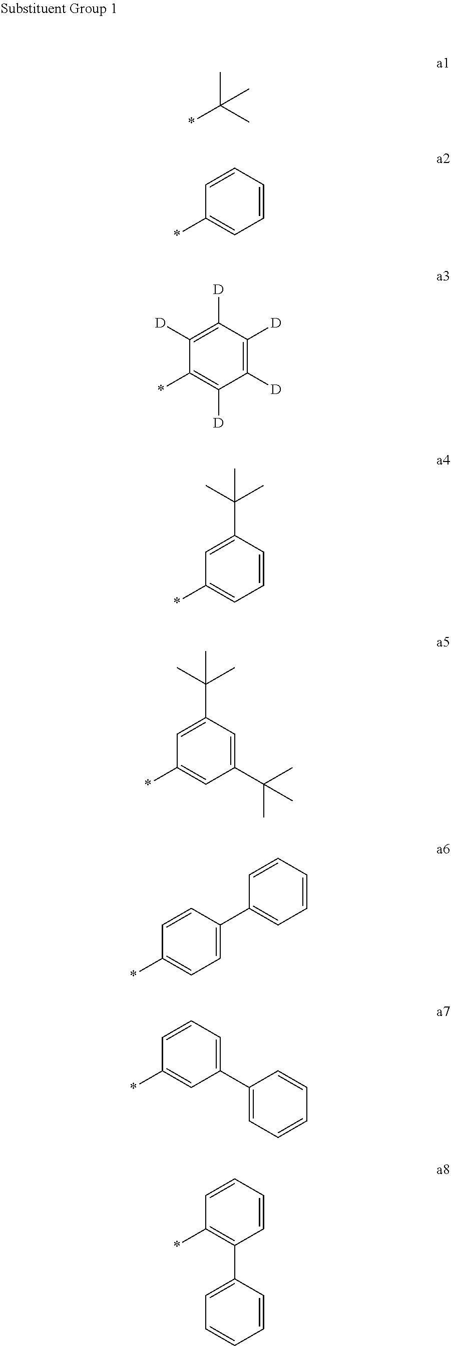

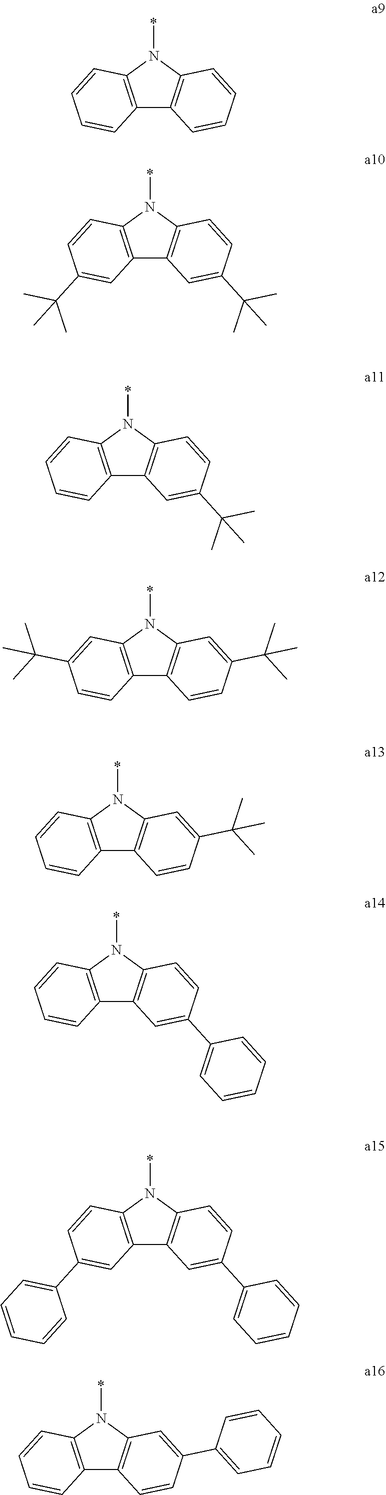

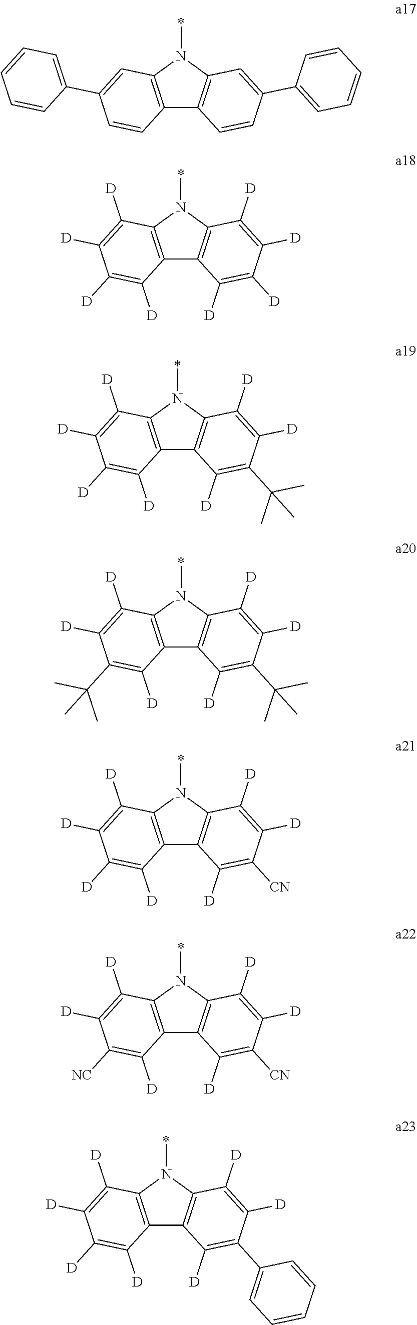

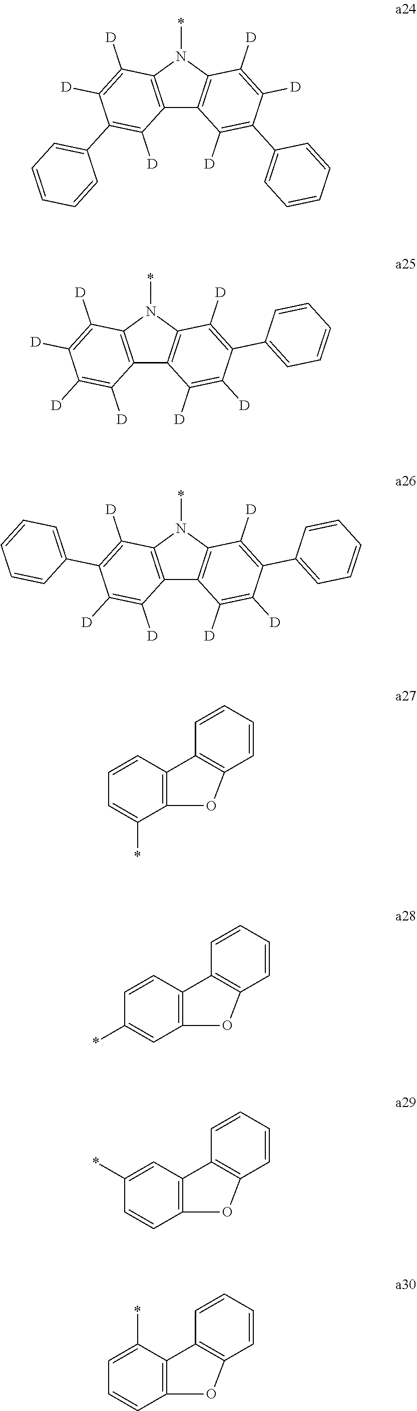

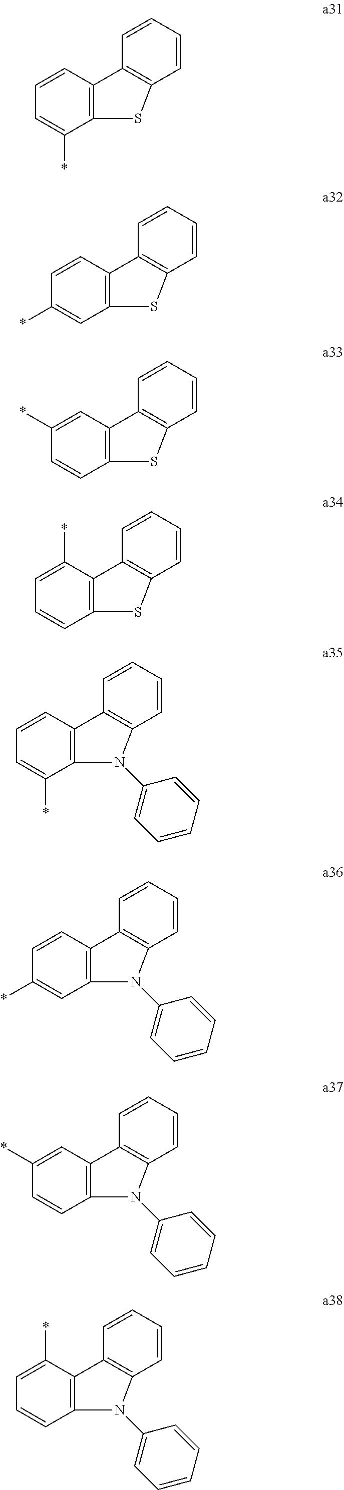

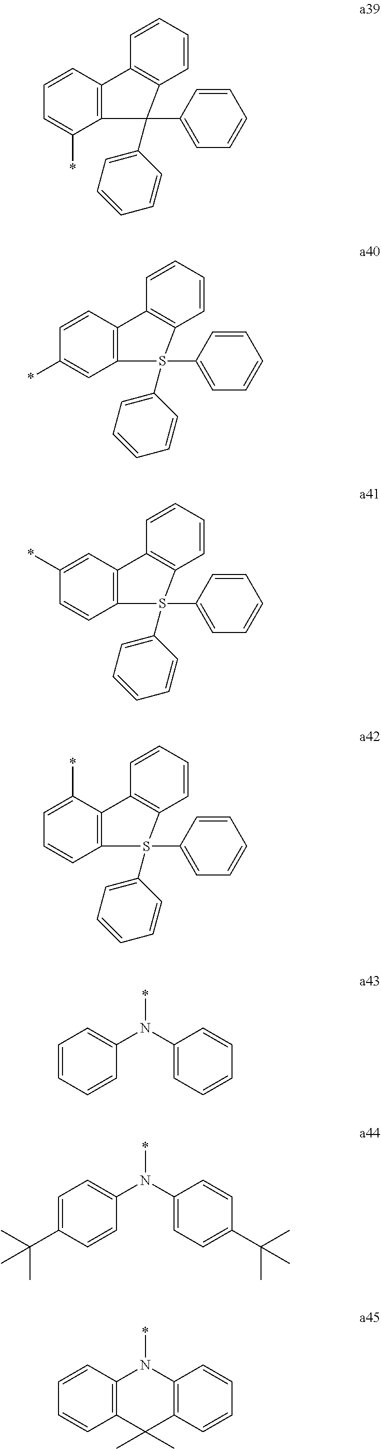

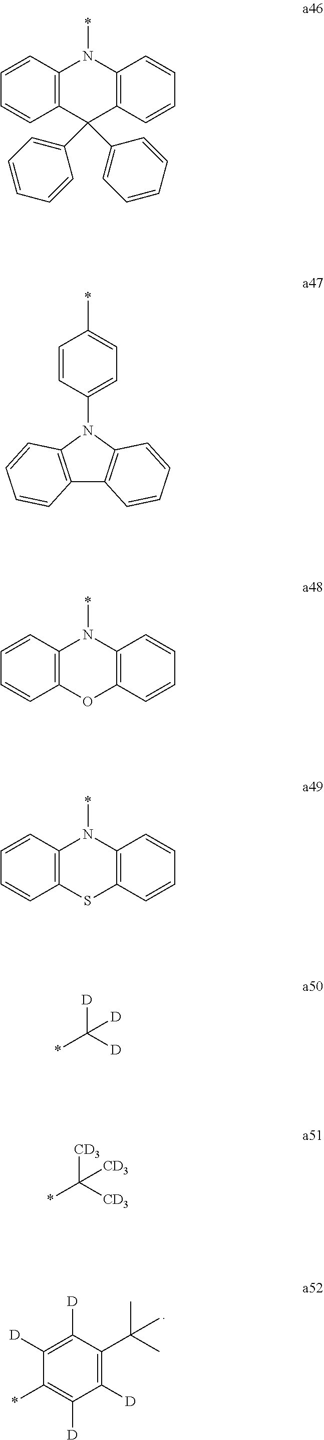

In Substituent Group 1, [symbol] is a site linked to a corresponding structure part of the fused polycyclic compound other than the part represented by a substituent of Substituent Group 1.

In one or more embodiments, the fused polycyclic compound represented by Formula 1 may include at least one deuterium as a substituent. The fused polycyclic compound of one or more embodiments represented by Formula 1 may include a structure in which at least one hydrogen is substituted with deuterium.

The fused polycyclic compound of one or more embodiments may be any one selected from among compounds shown in Compound Group 1. The at least one functional layer included in the light emitting element ED of one or more embodiments may include at least one fused polycyclic compound selected from among the compounds shown in Compound Group 1. The light emitting element ED of one or more embodiments may include at least one fused polycyclic compound selected from among the compounds shown in Compound Group 1 in the emission layer EML.

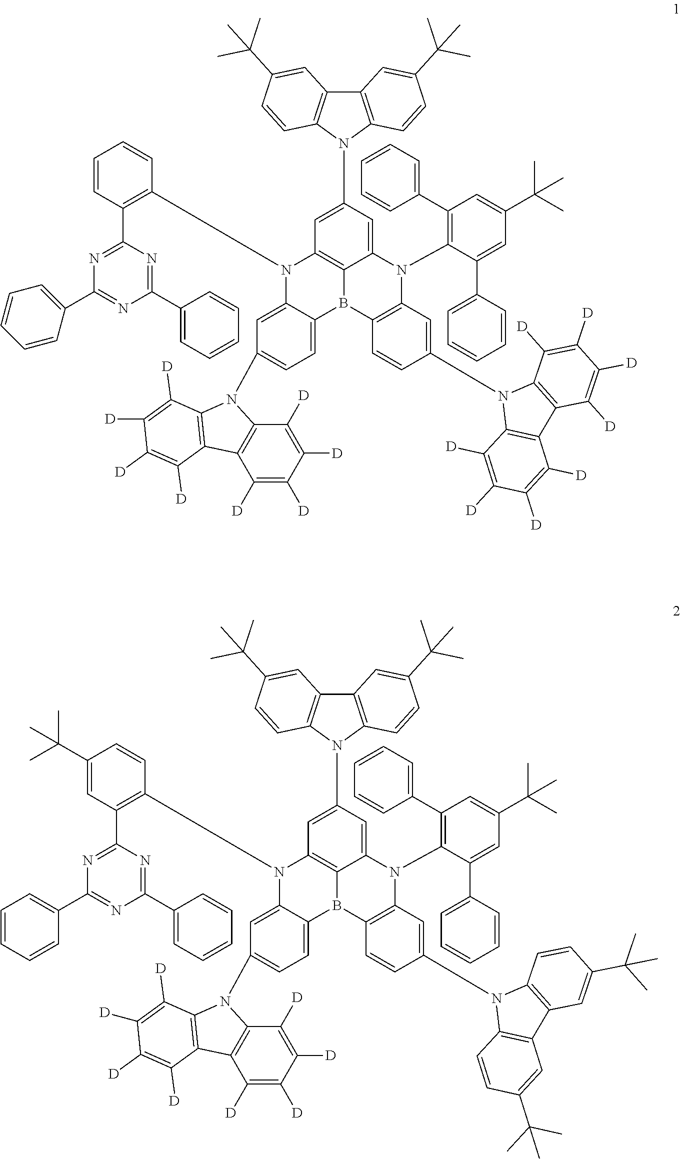

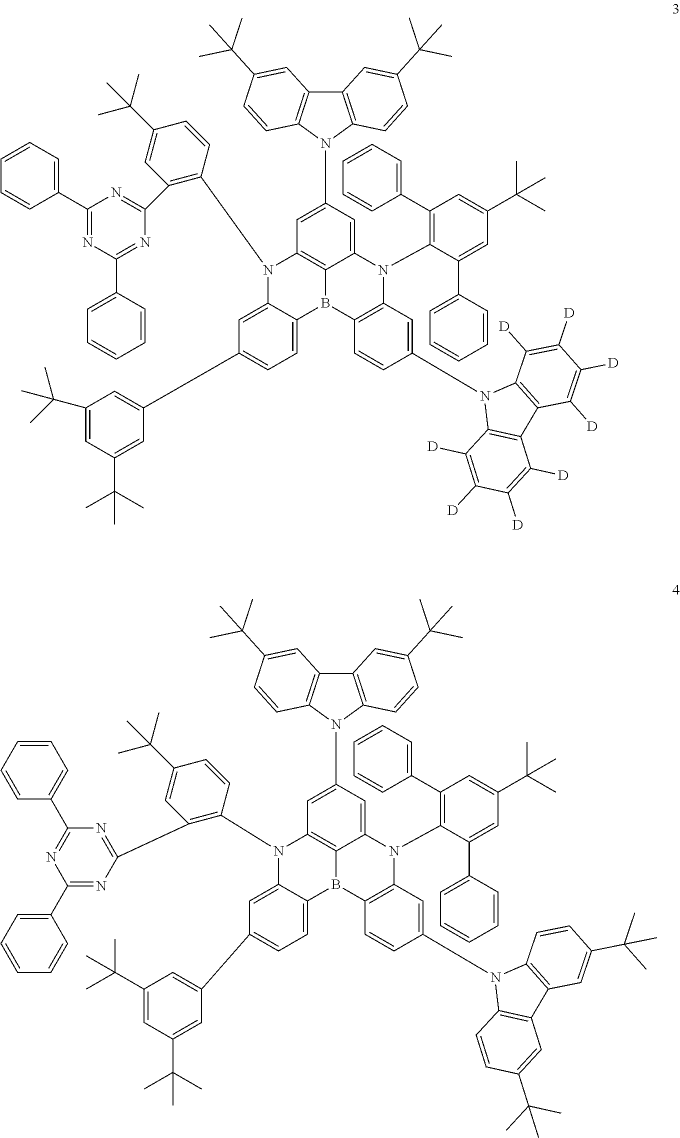 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4ccc(C(C)(C)C)cc4c4cc(C(C)(C)C)ccc43)cc3c1B2c1ccc(-c2cc(C(C)(C)C)cc(C(C)(C)C)c2)cc1N3c1ccc(C(C)(C)C)cc1-c1nc(-c2ccccc2)nc(-c2ccccc2)n1 ; CC(C)(C)c1cc(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc(C(C)(C)C)c1]

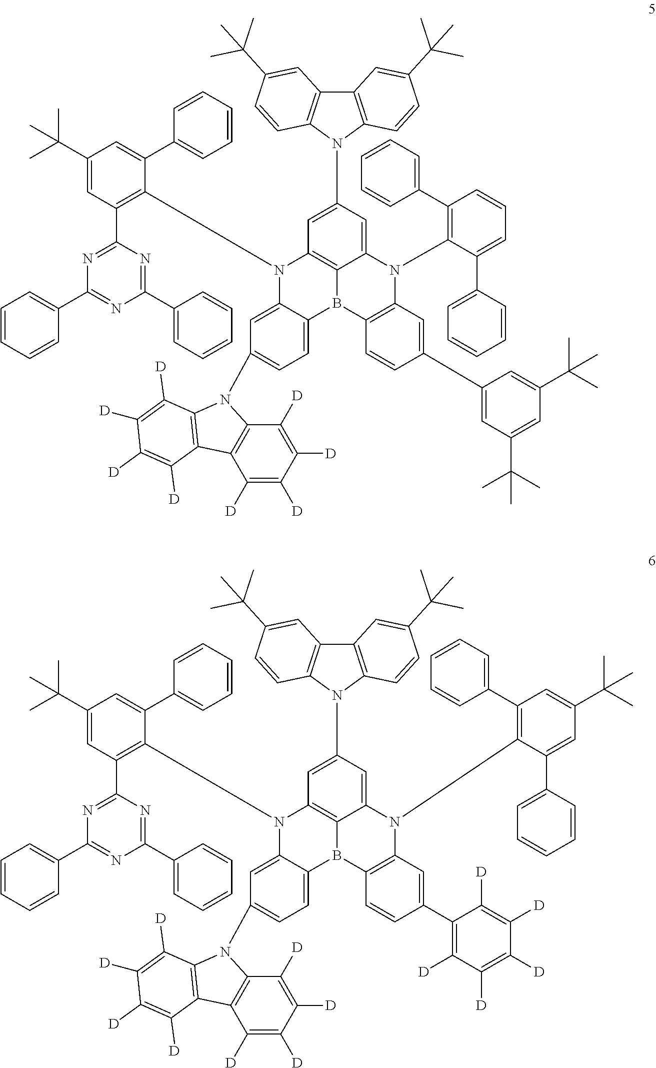

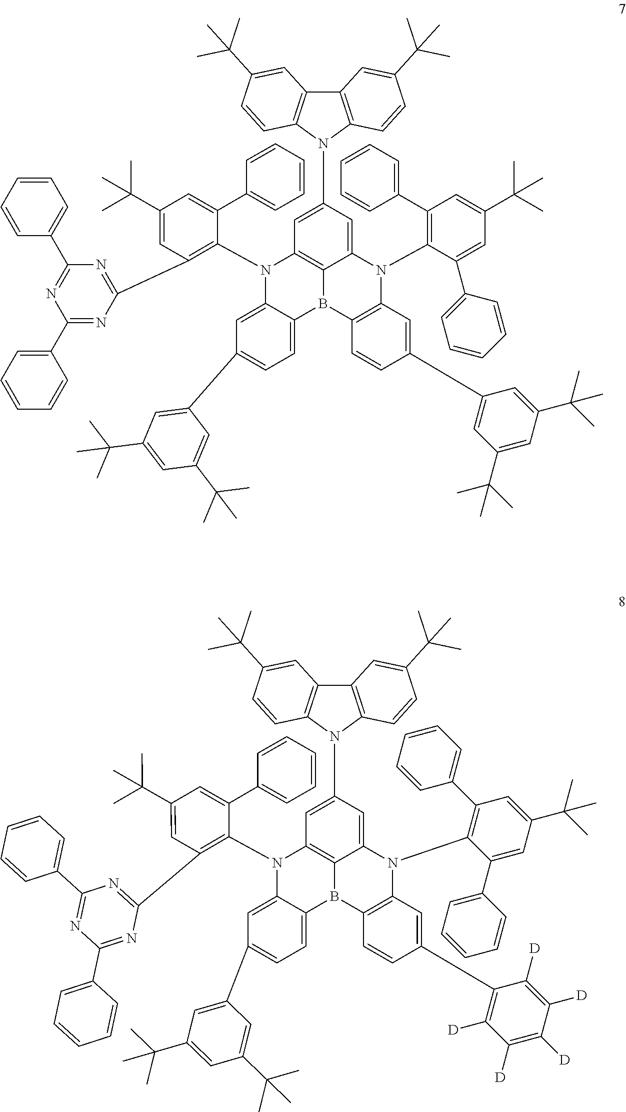 [SMILES: CC(C)(C)c1cc(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)c([2H])c1[2H]]

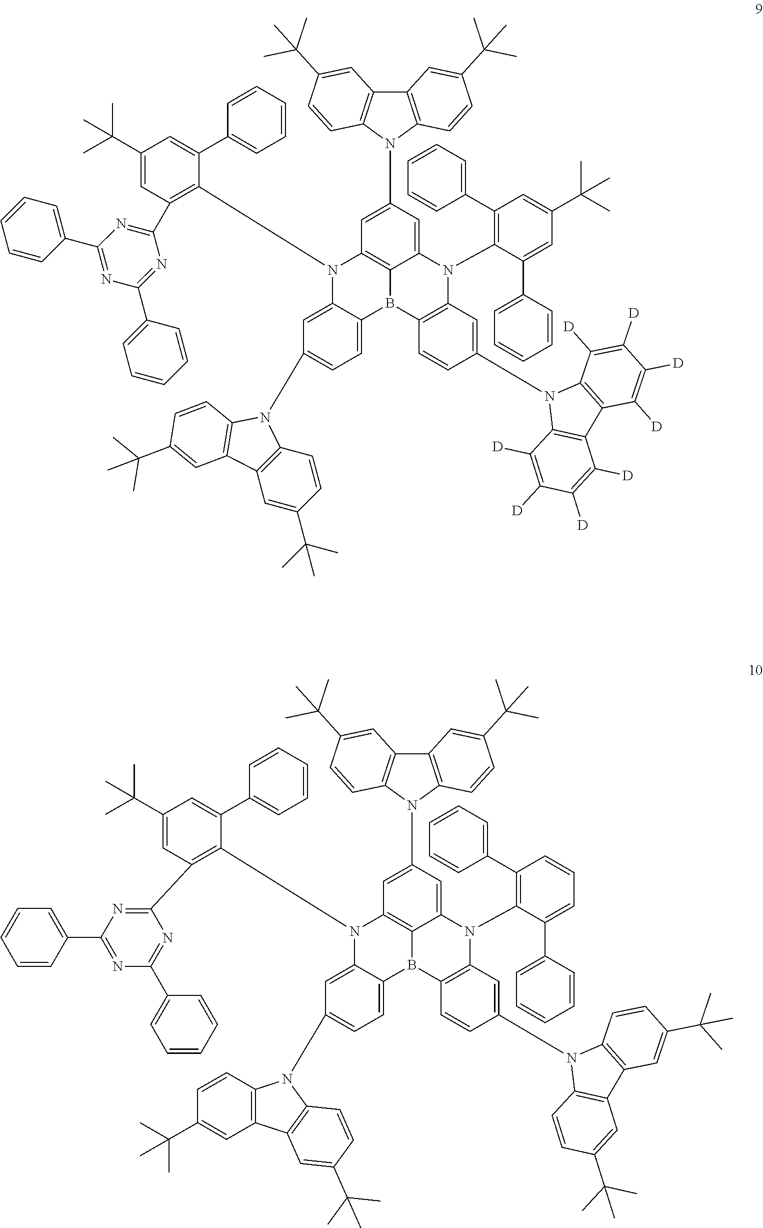

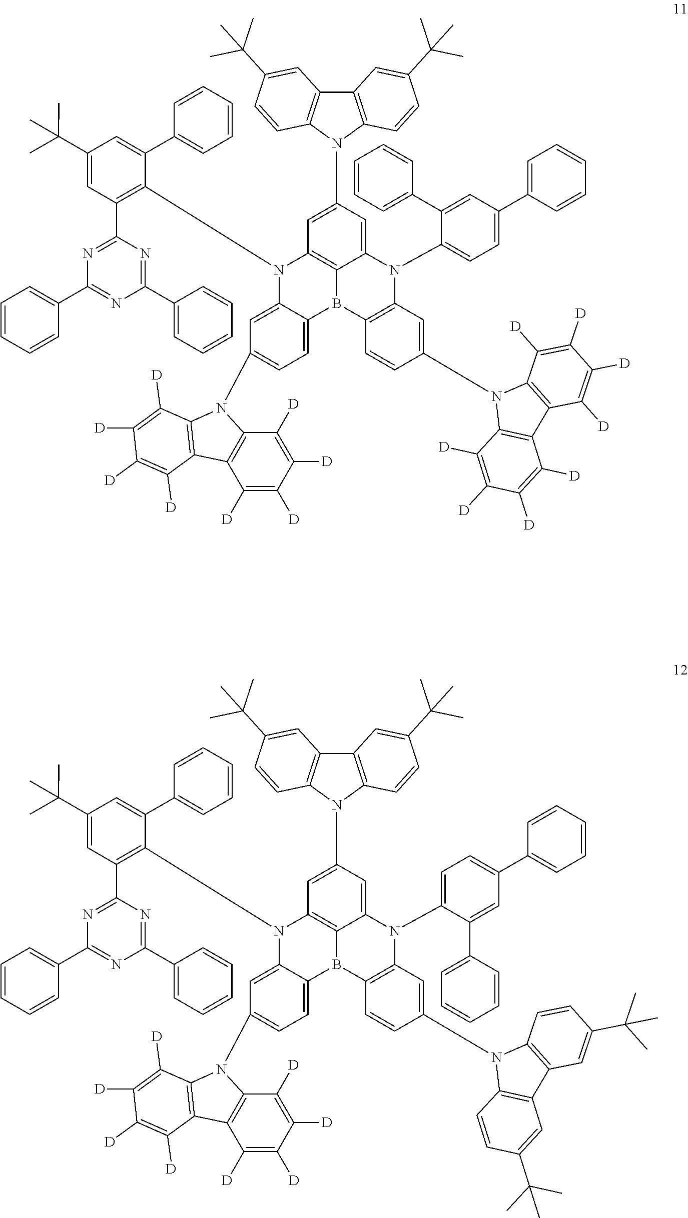

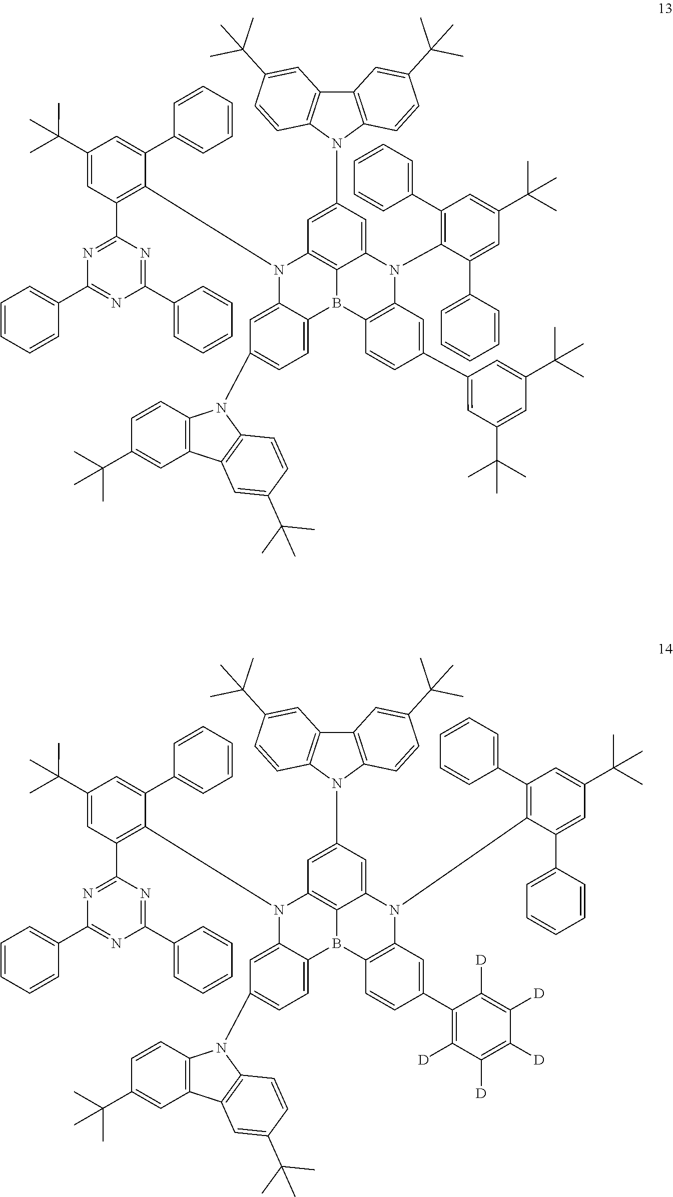

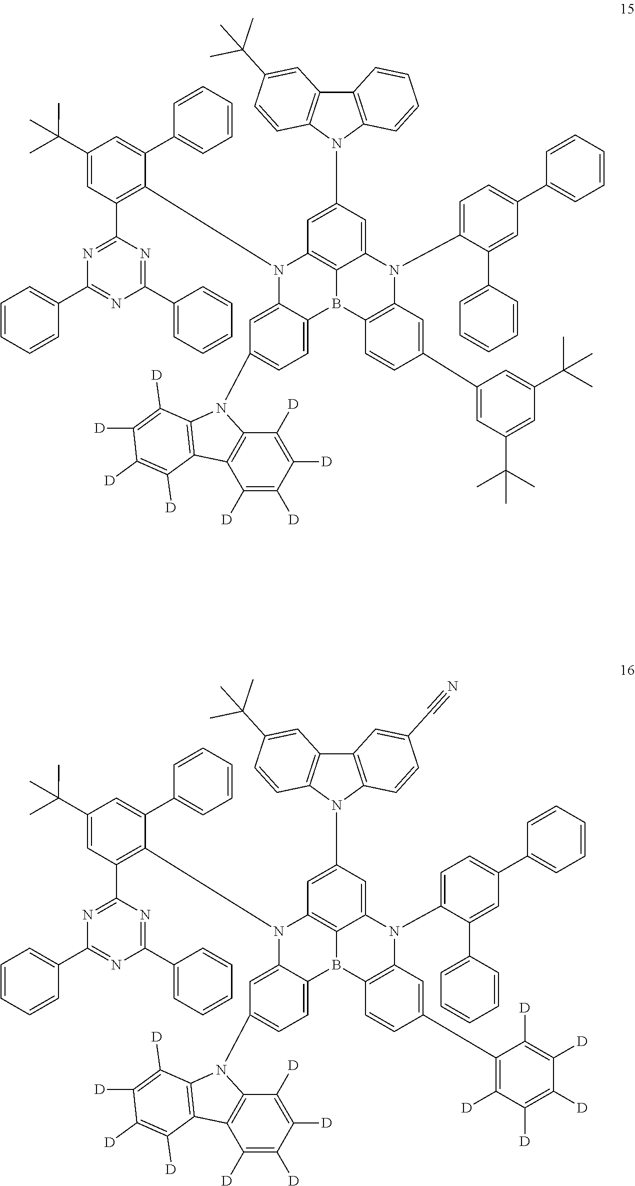

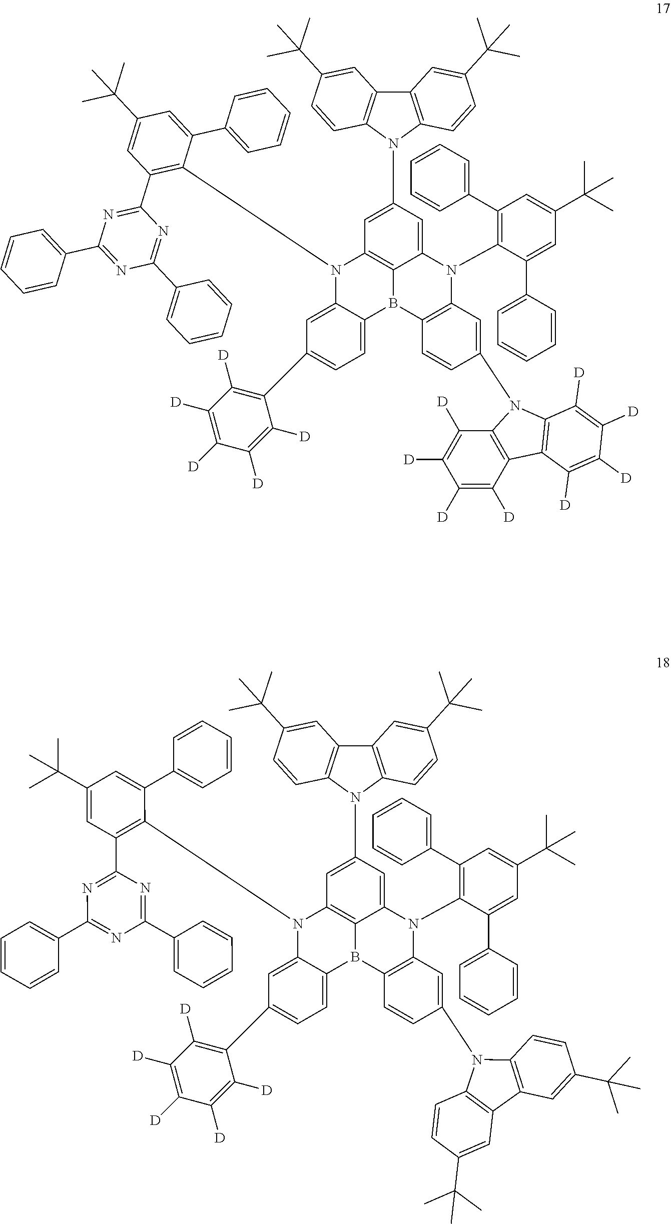

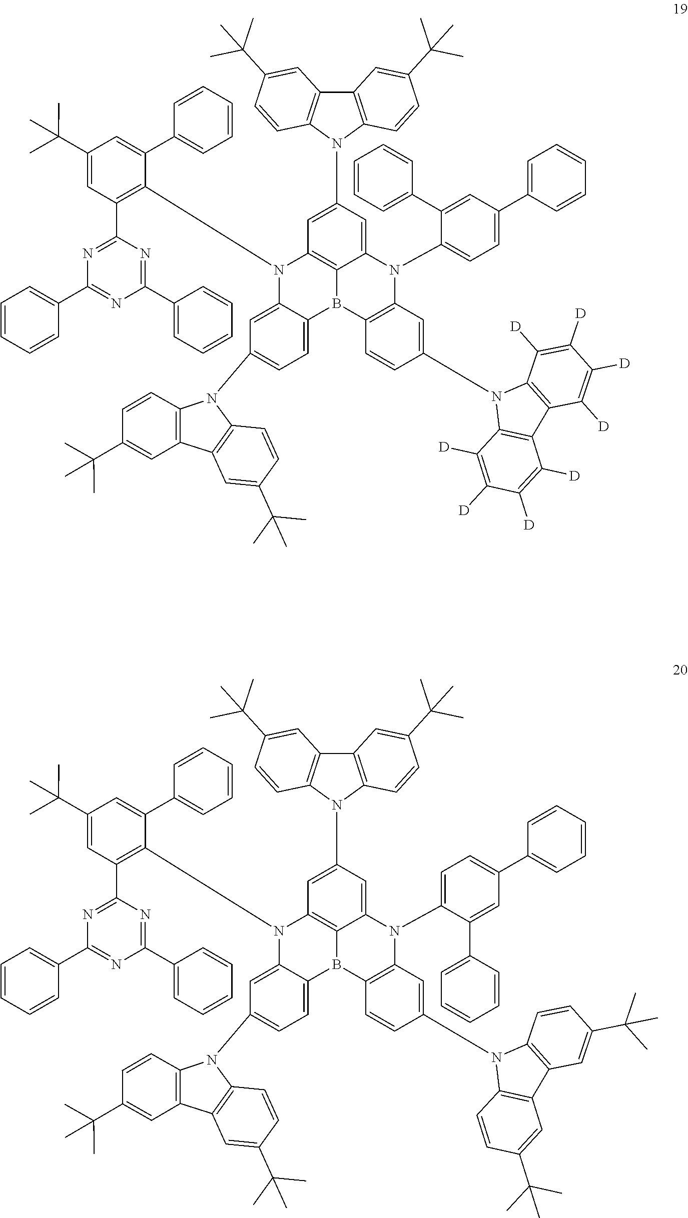

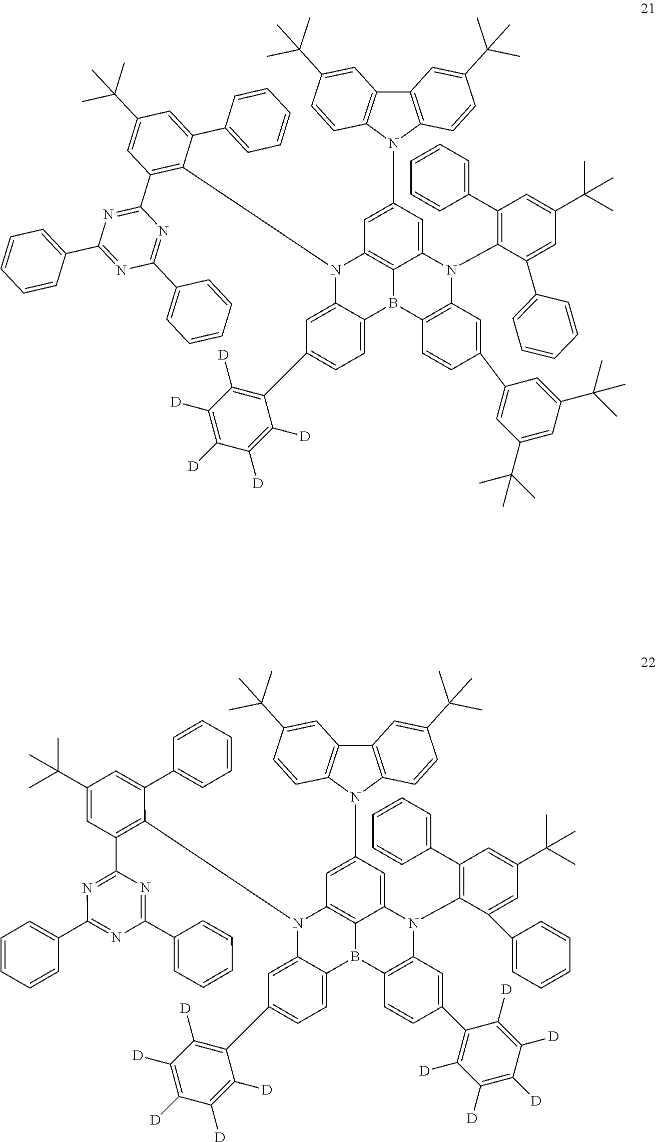 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2ccccc2)c([2H])c1[2H] ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H]]

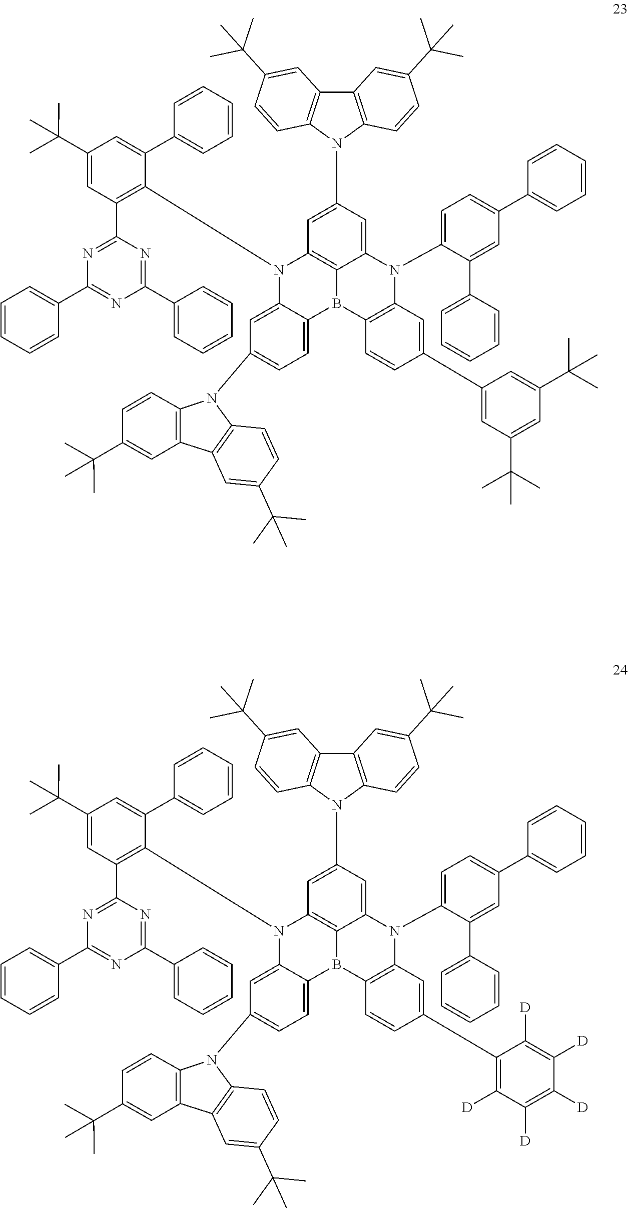 [SMILES: CC(C)(C)c1cc(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)c([2H])c1[2H]]

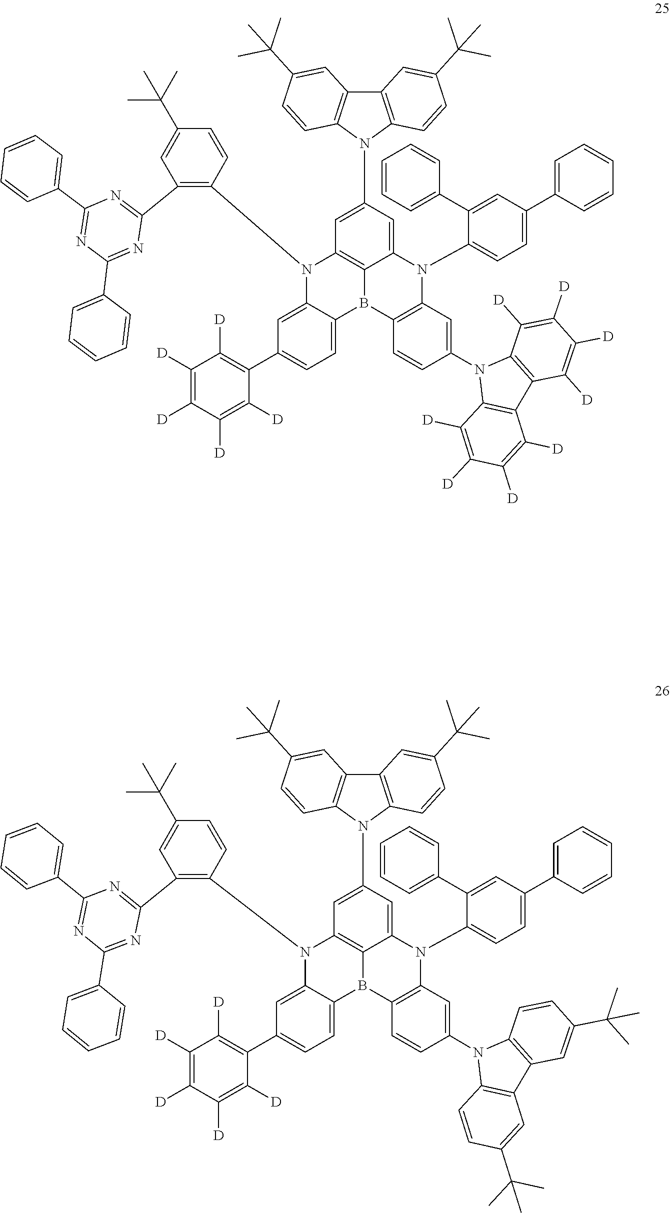 [SMILES: [2H]c1c([2H])c([2H])c(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5c([2H])c([2H])c([2H])c([2H])c5c5c([2H])c([2H])c([2H])c([2H])c53)cc2N4c2ccc(-c3ccccc3)cc2-c2ccccc2)c([2H])c1[2H] ; [2H]c1c([2H])c([2H])c(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(-c3ccccc3)cc2-c2ccccc2)c([2H])c1[2H]]

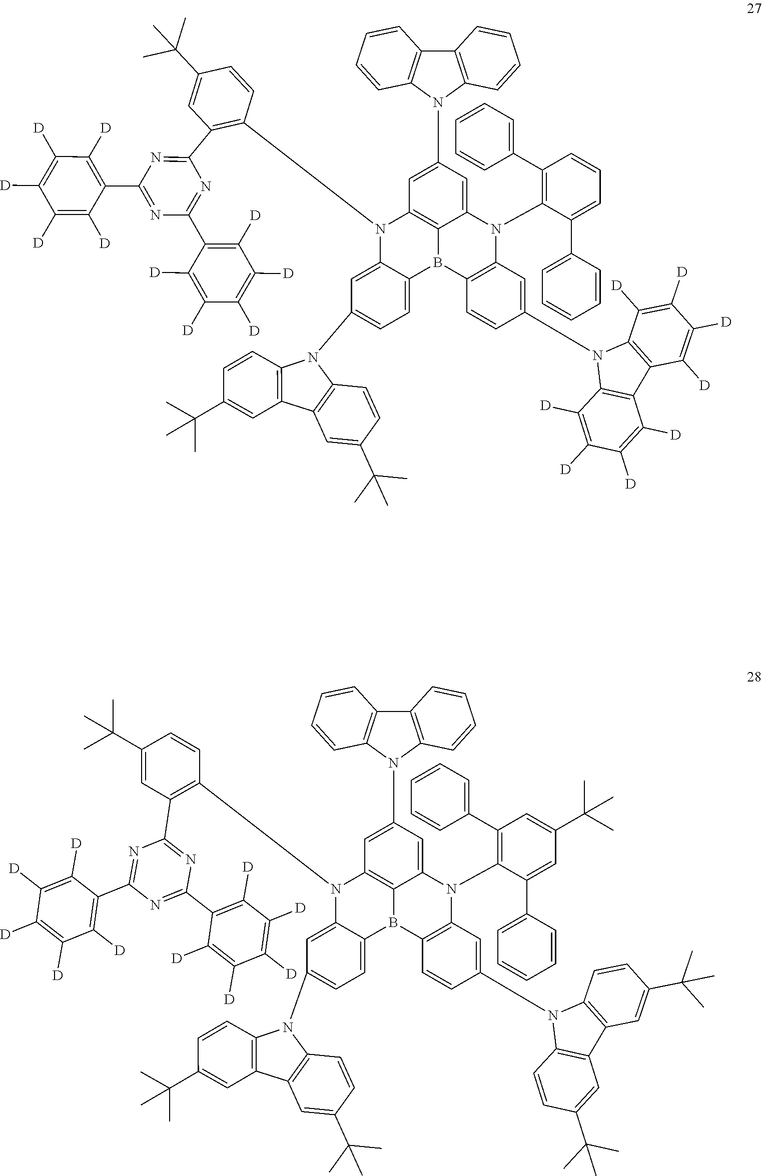

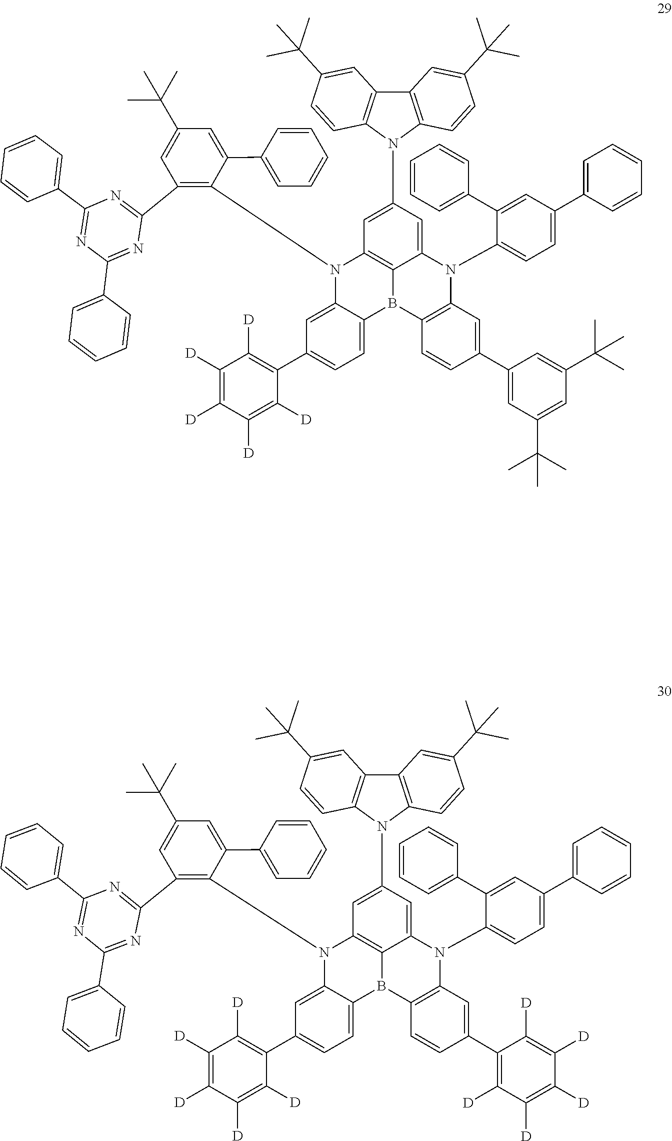 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2ccc(-c3ccccc3)cc2-c2ccccc2)c([2H])c1[2H] ; [2H]c1c([2H])c([2H])c(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H]]

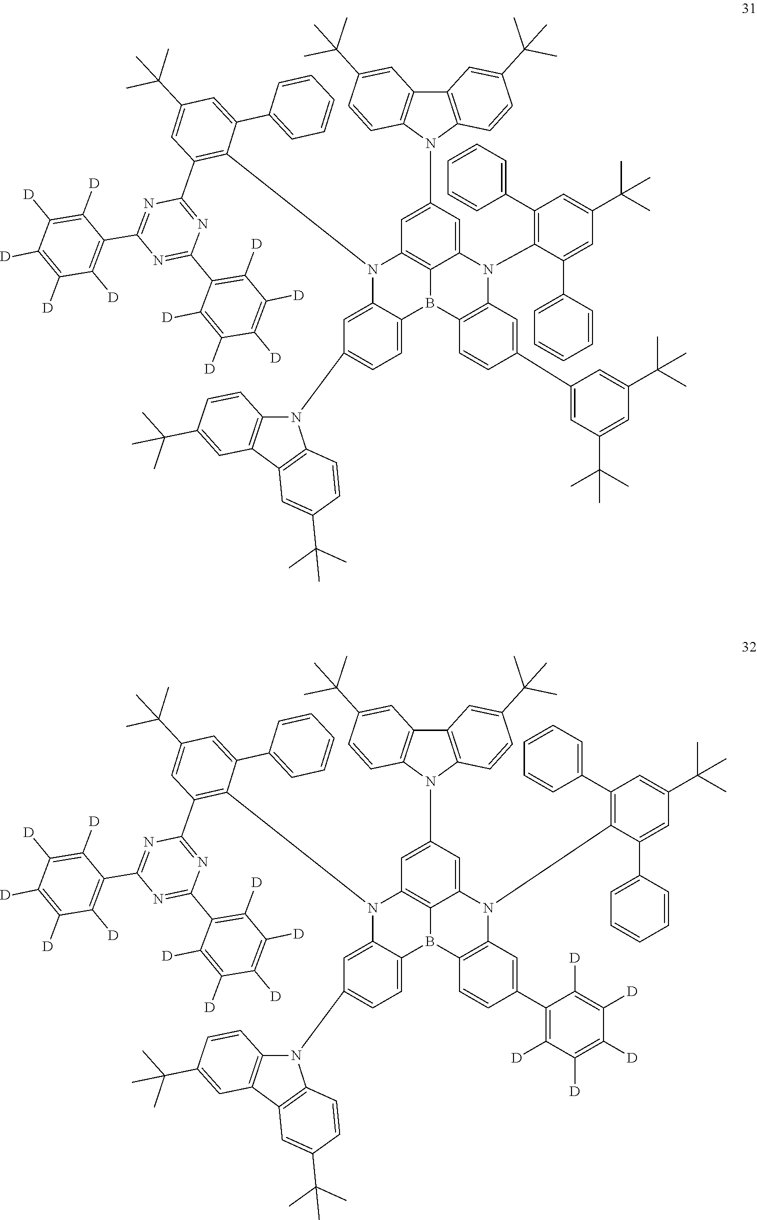

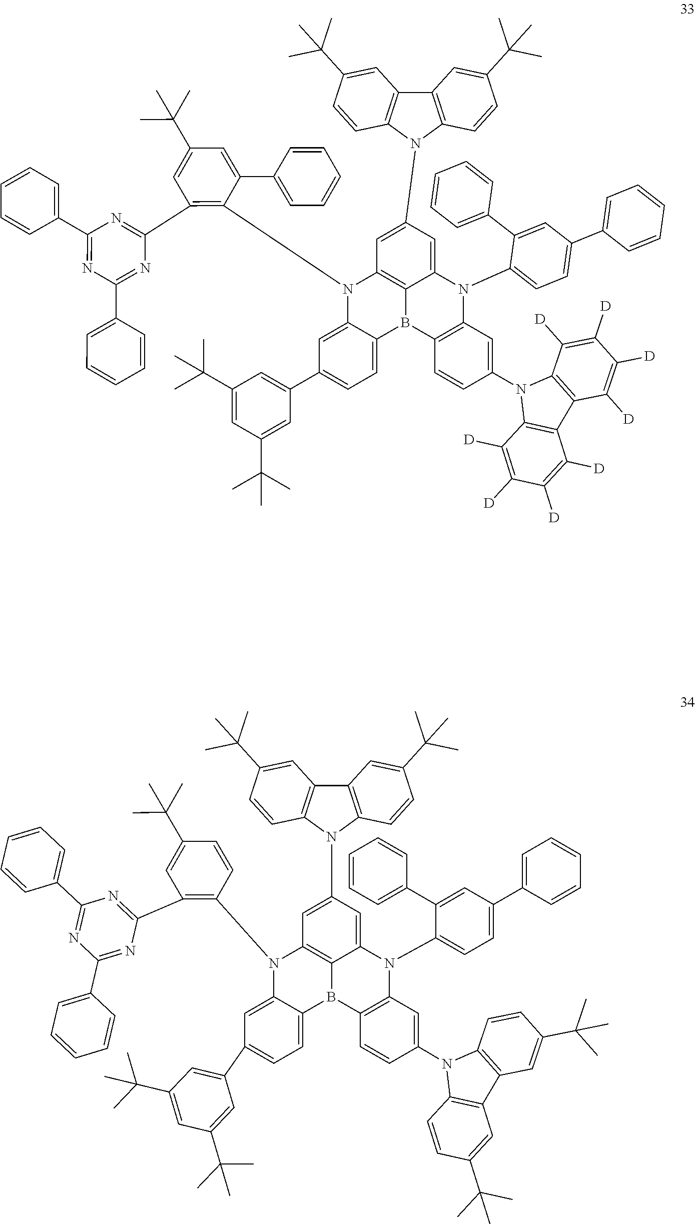 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(-n3c4ccc(C(C)(C)C)cc4c4cc(C(C)(C)C)ccc43)cc3c1B2c1ccc(-c2cc(C(C)(C)C)cc(C(C)(C)C)c2)cc1N3c1c(-c2ccccc2)cc(C(C)(C)C)cc1-c1nc(-c2ccccc2)nc(-c2ccccc2)n1 ; CC(C)(C)c1cc(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(-c3ccccc3)cc2-c2ccccc2)cc(C(C)(C)C)c1]

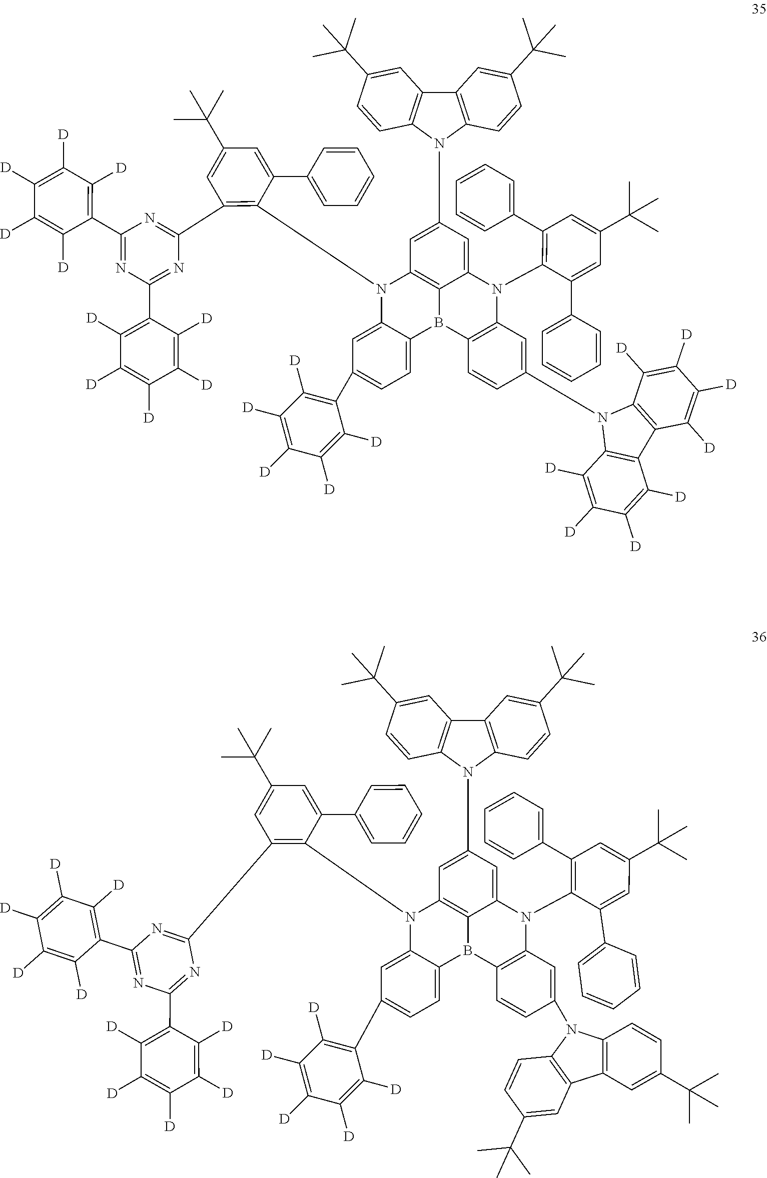

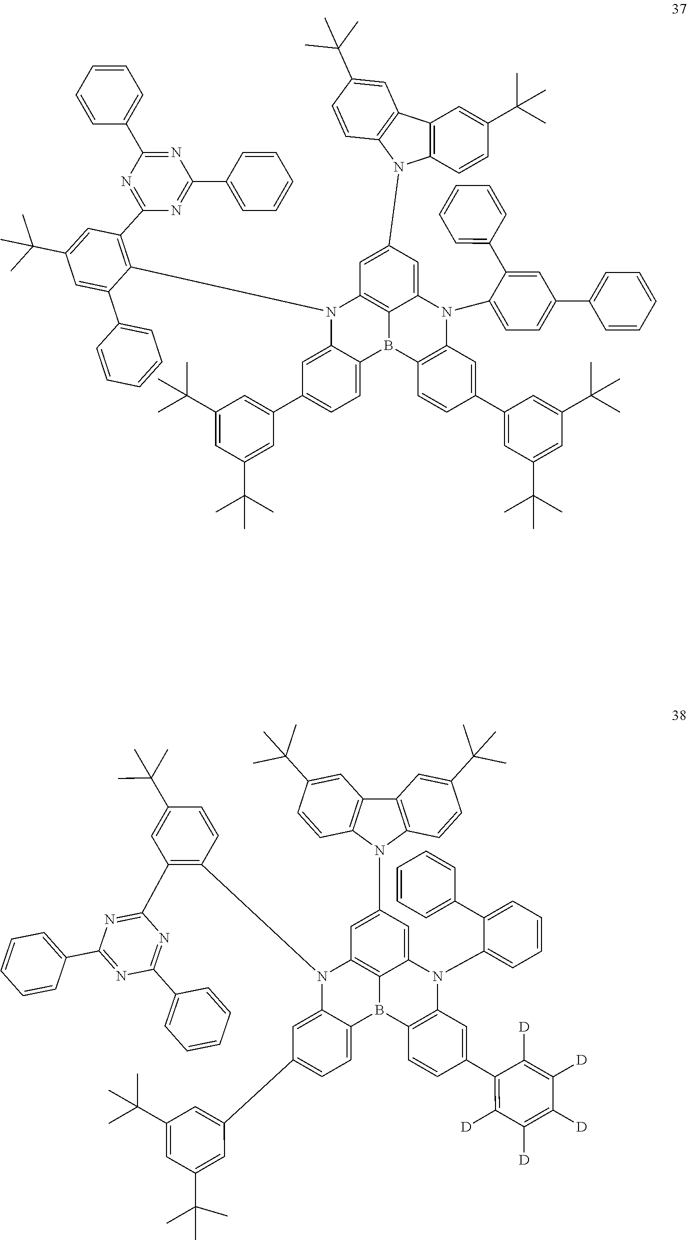 [SMILES: CC(C)(C)c1cc(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccccc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2ccc(C(C)(C)C)cc2-c2nc(-c3ccccc3)nc(-c3ccccc3)n2)c([2H])c1[2H]]

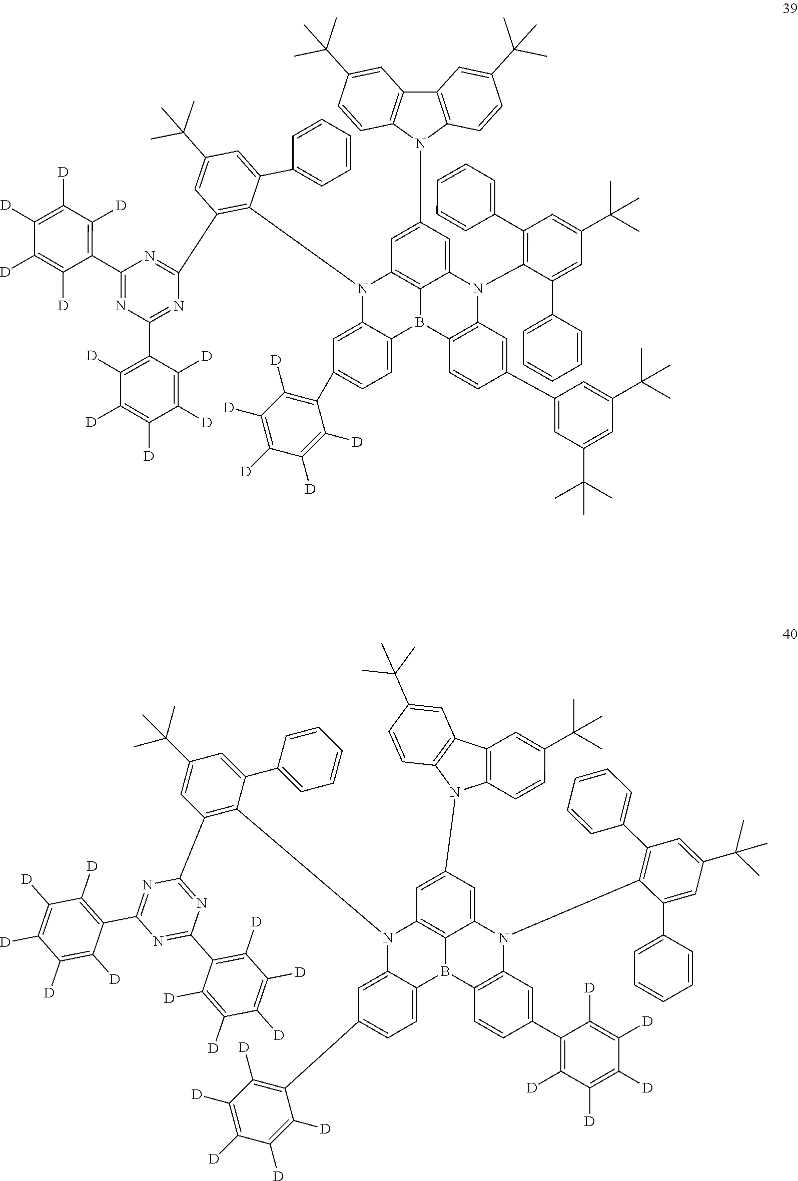

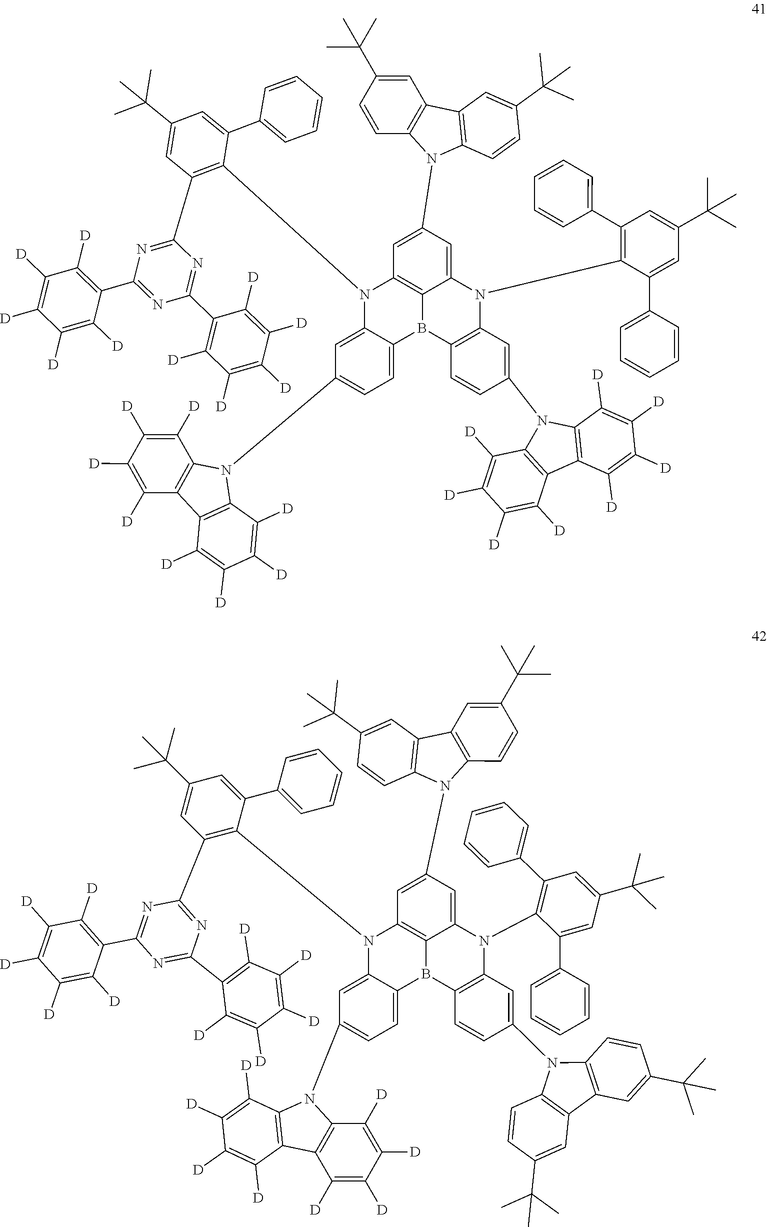

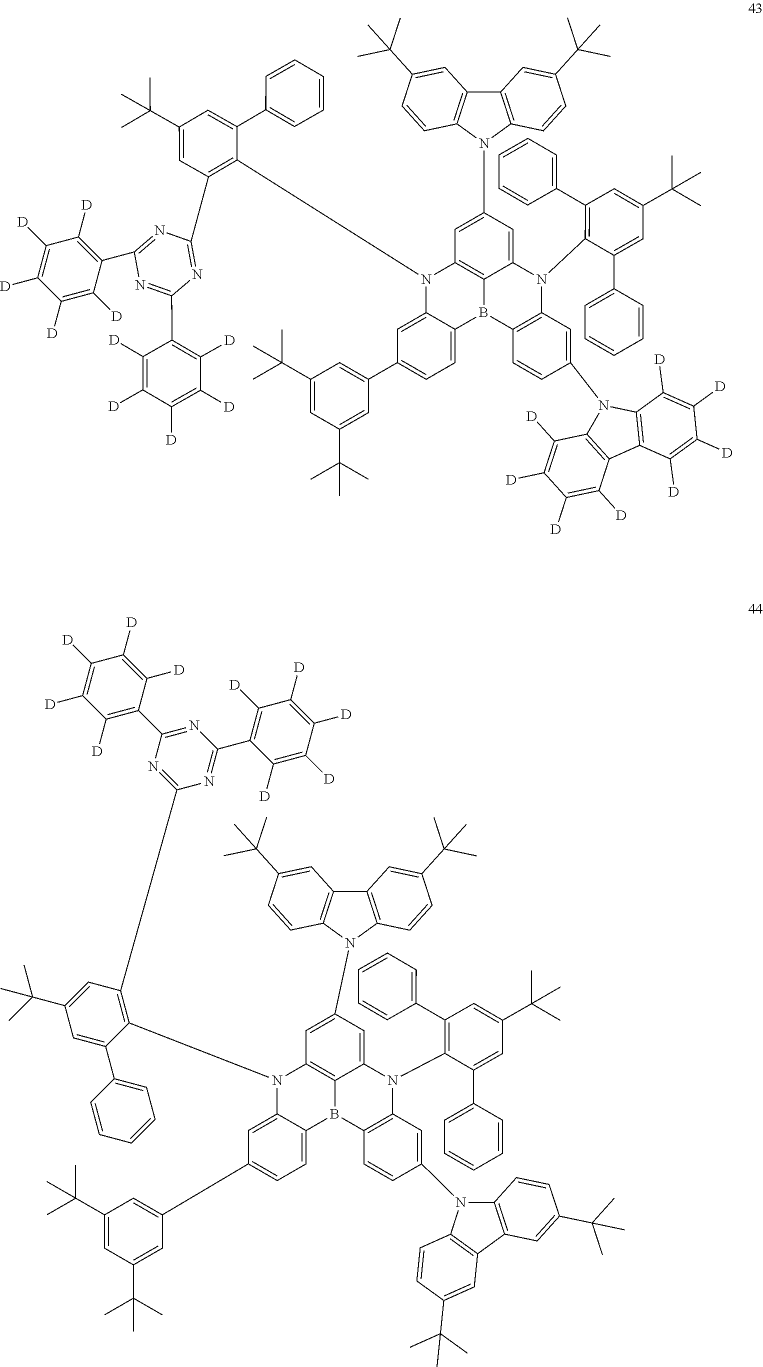

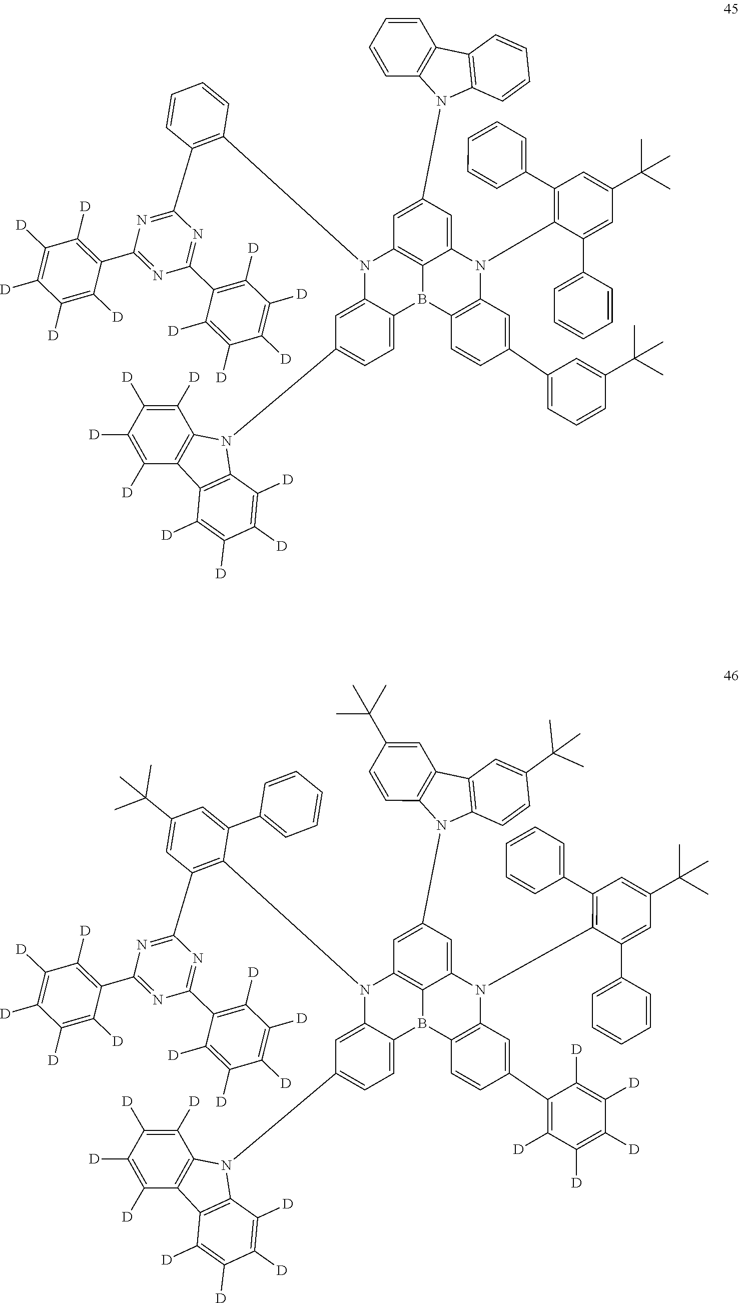

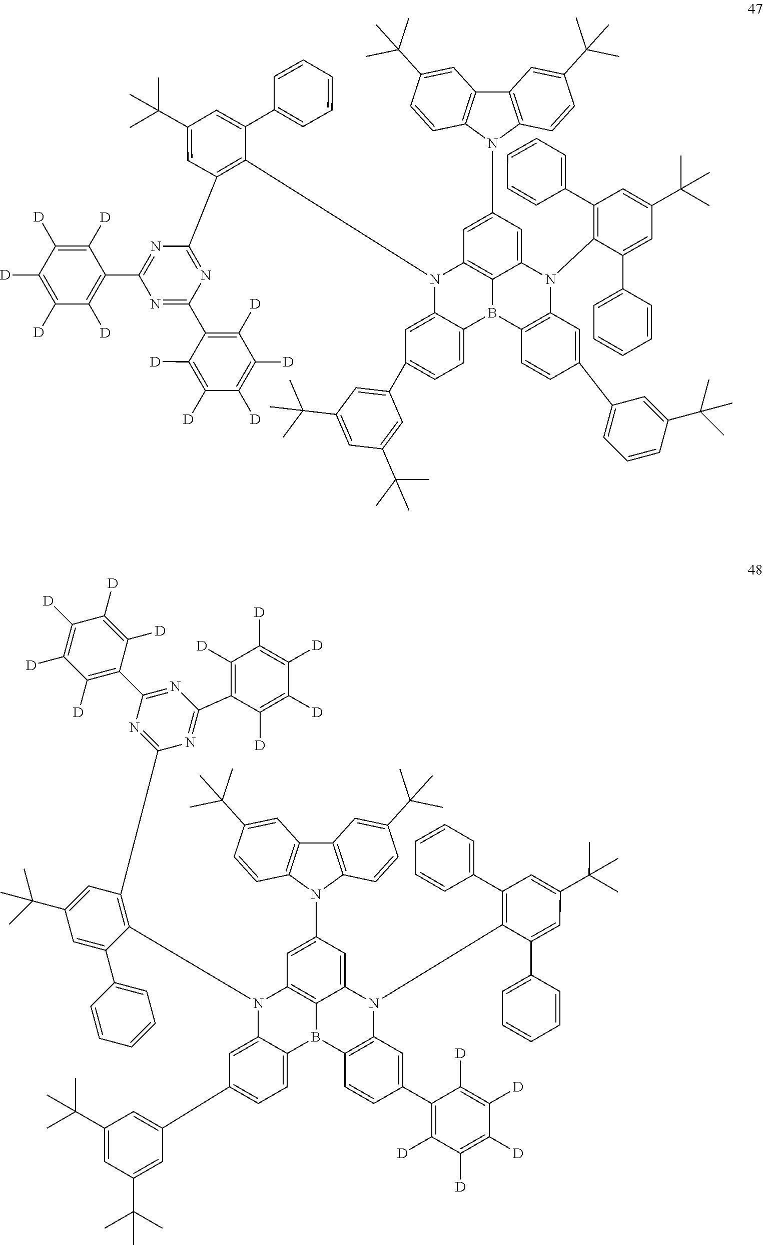

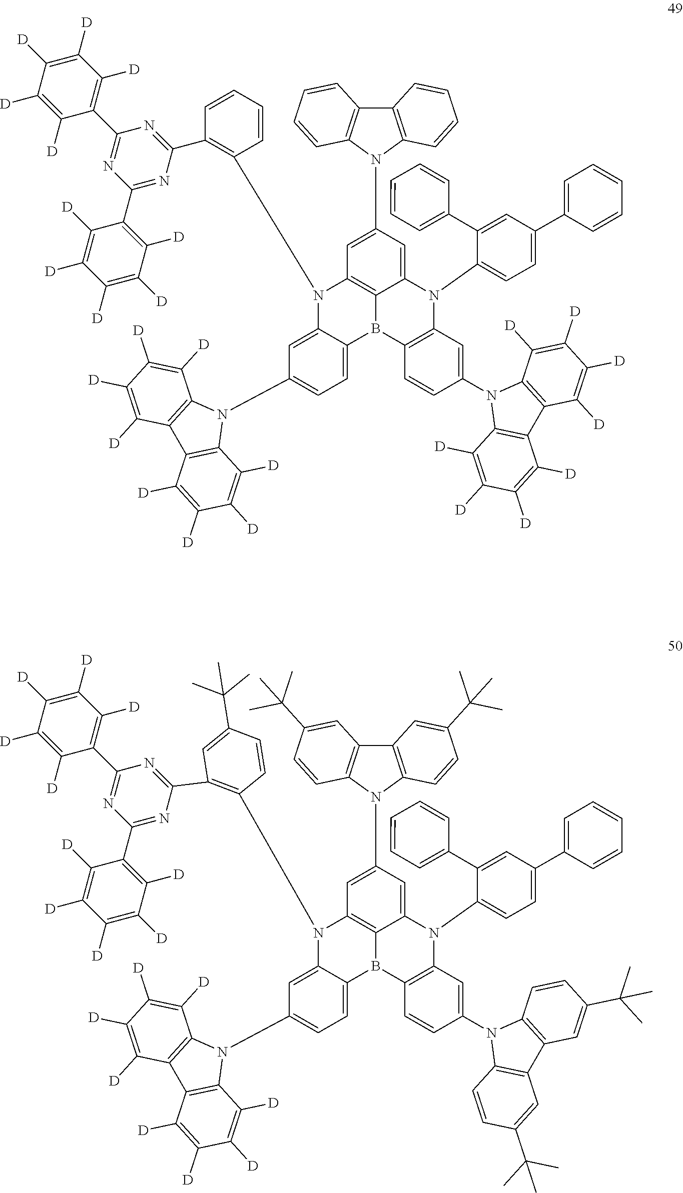

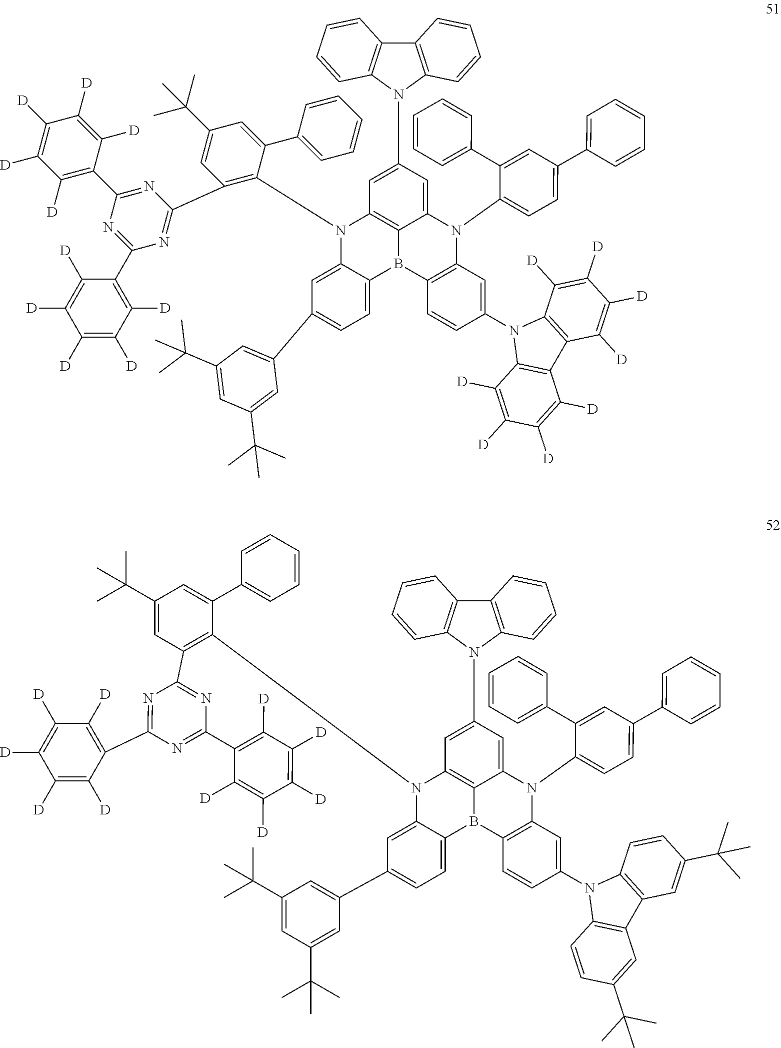

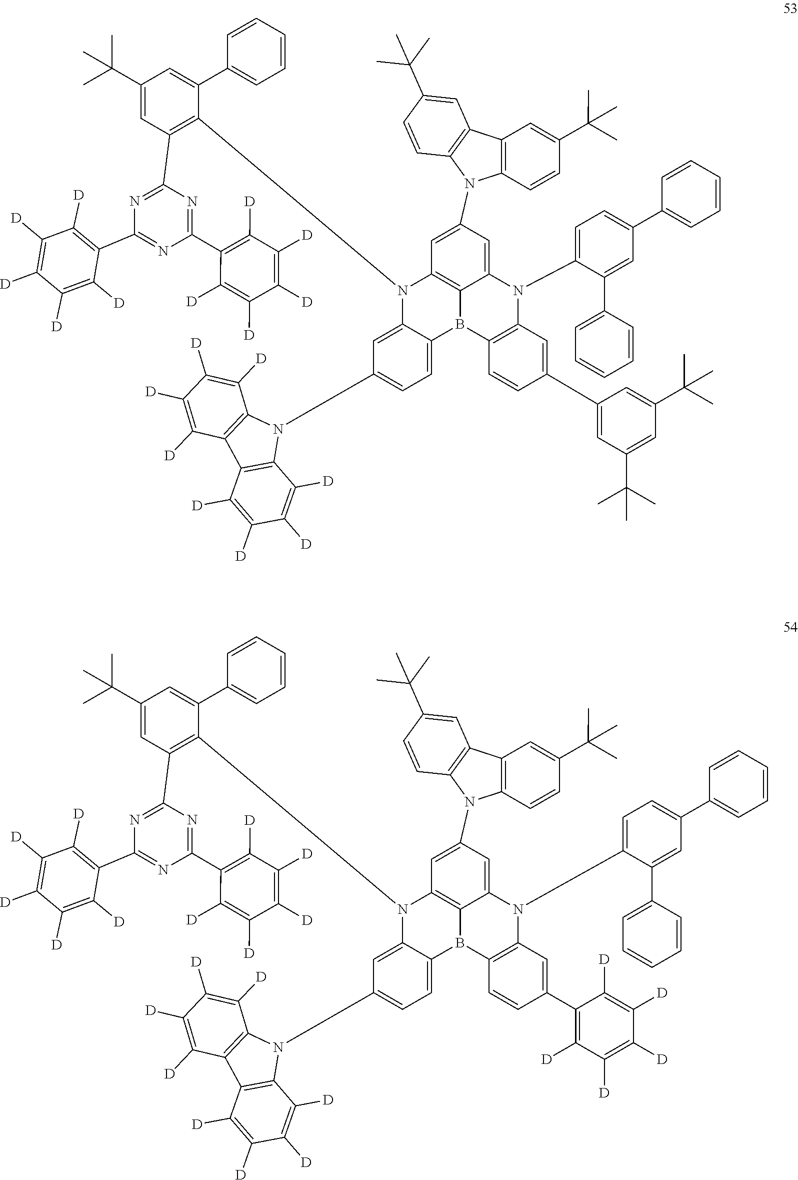

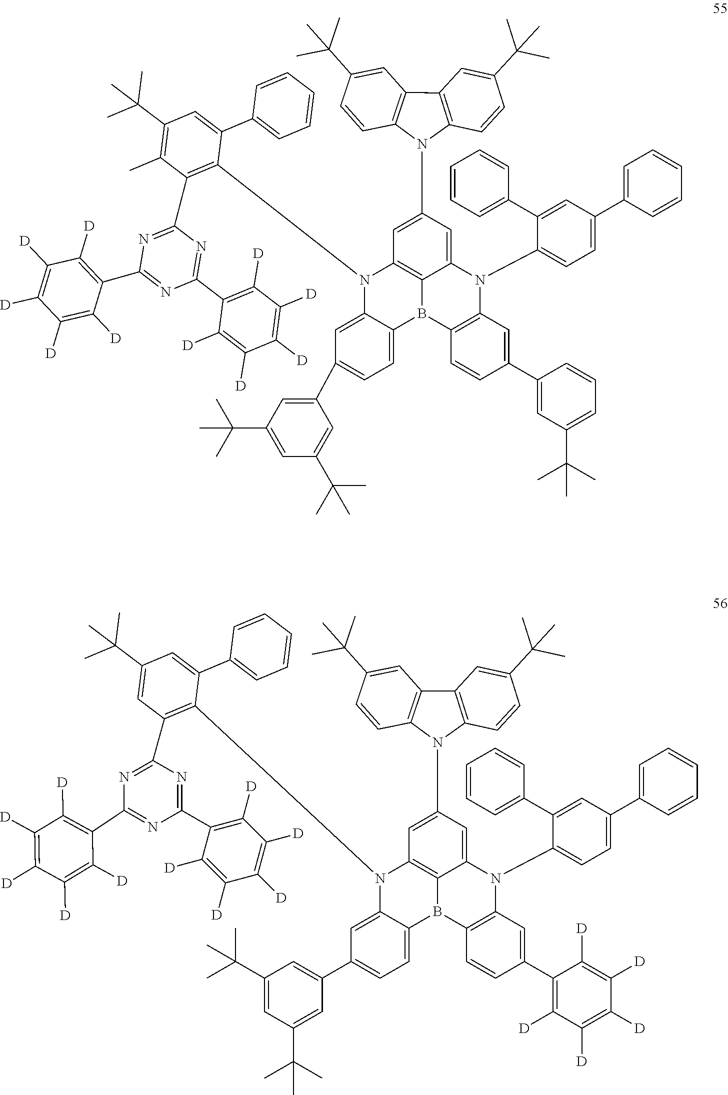

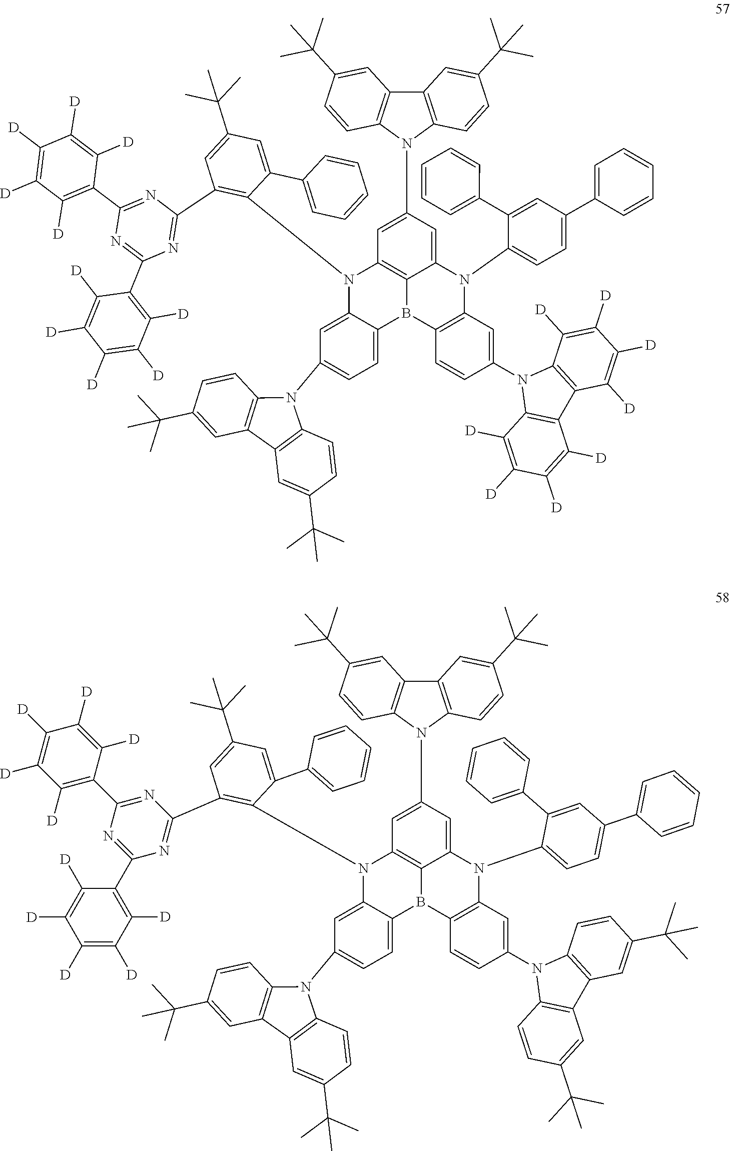

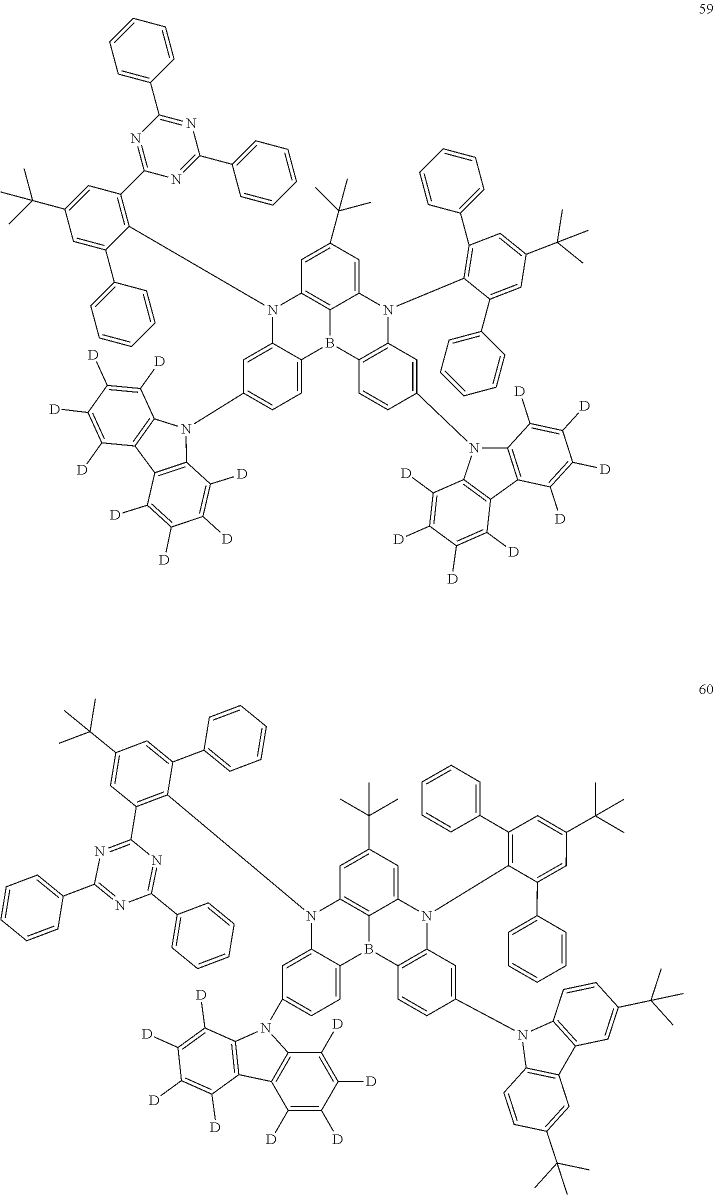

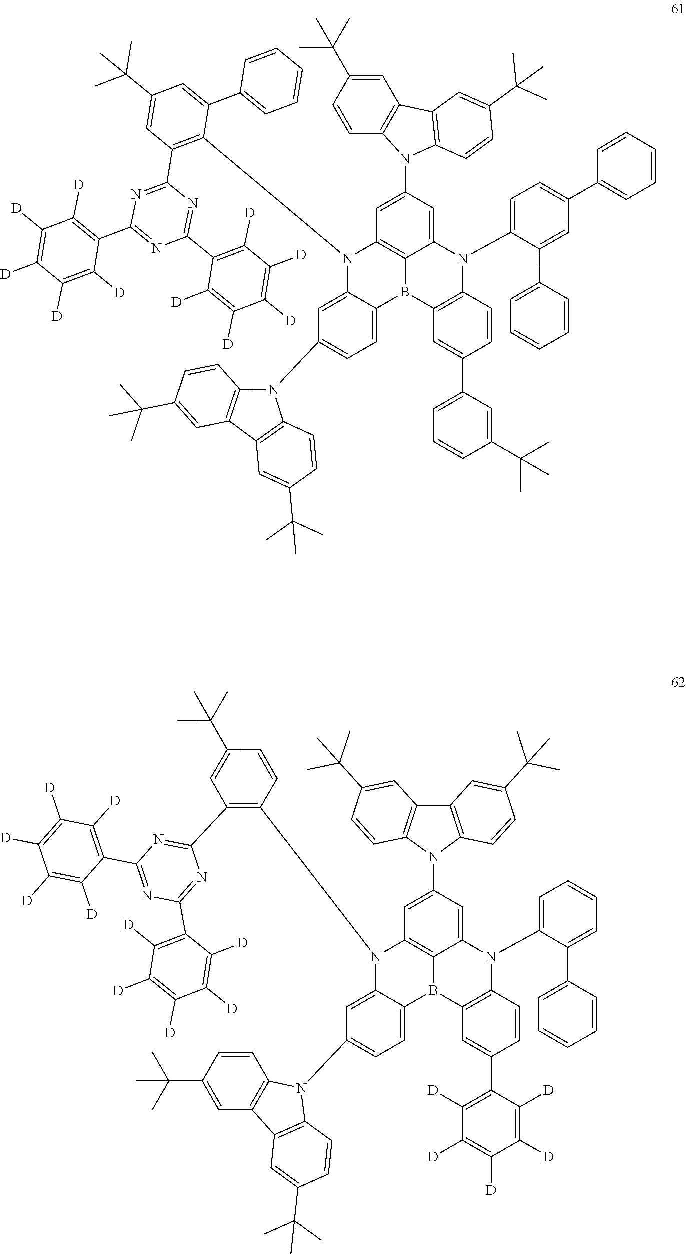

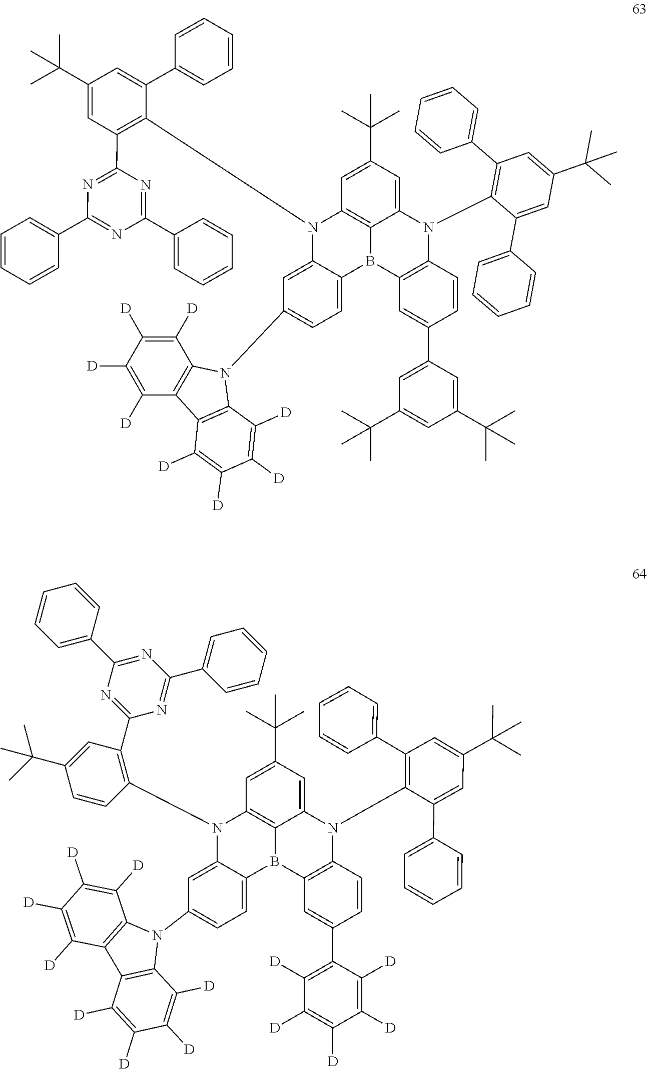

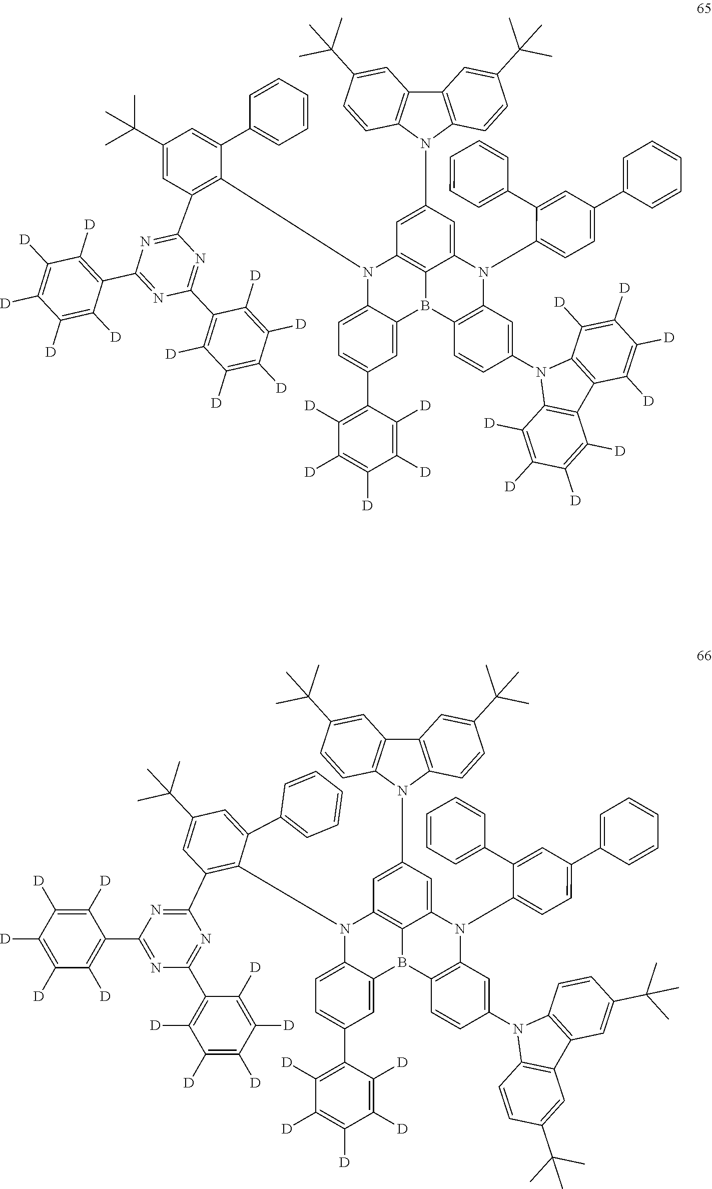

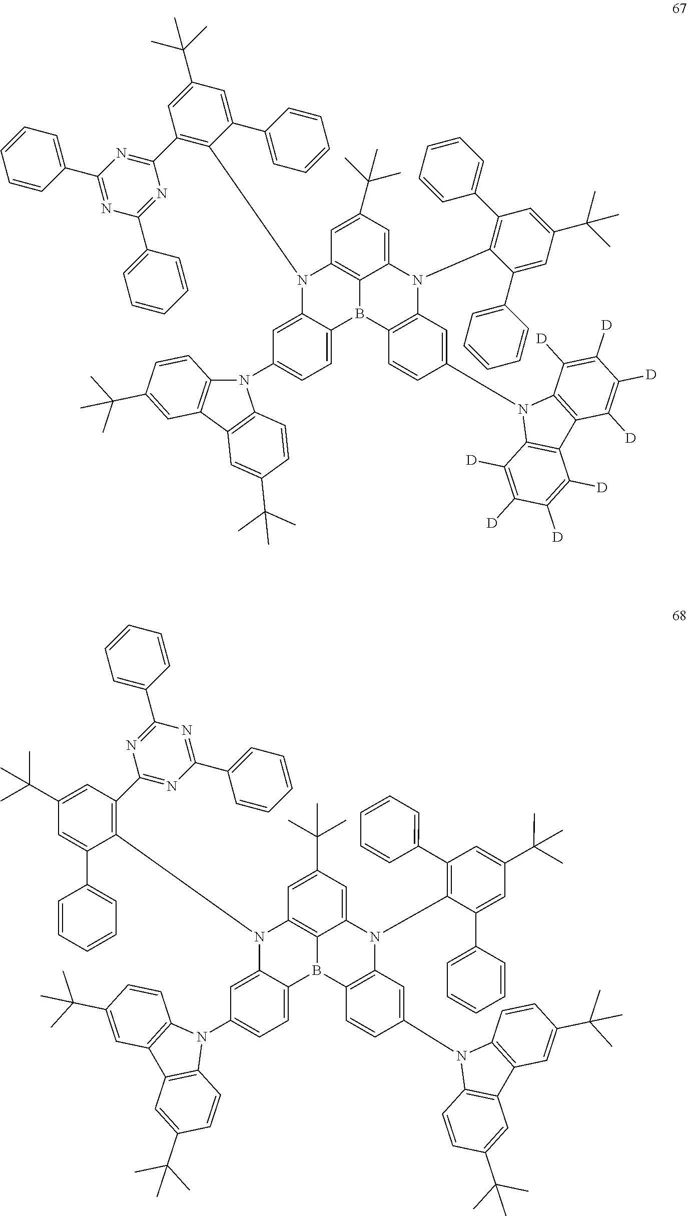 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccc(C(C)(C)C)cc4c4cc(C(C)(C)C)ccc42)cc1N3c1c(-c2ccccc2)cc(C(C)(C)C)cc1-c1nc(-c2ccccc2)nc(-c2ccccc2)n1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4nc(-c5ccccc5)nc(-c5ccccc5)n4)c4cc(C(C)(C)C)cc2c43)c(-c2ccccc2)c1]

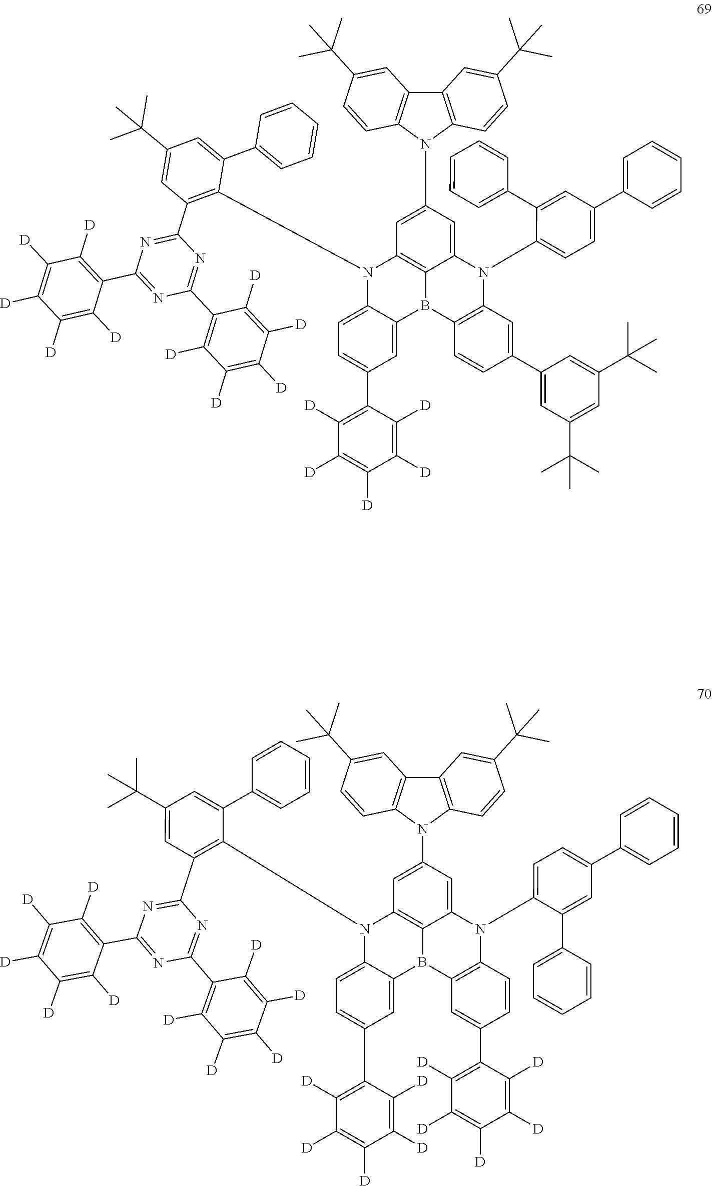

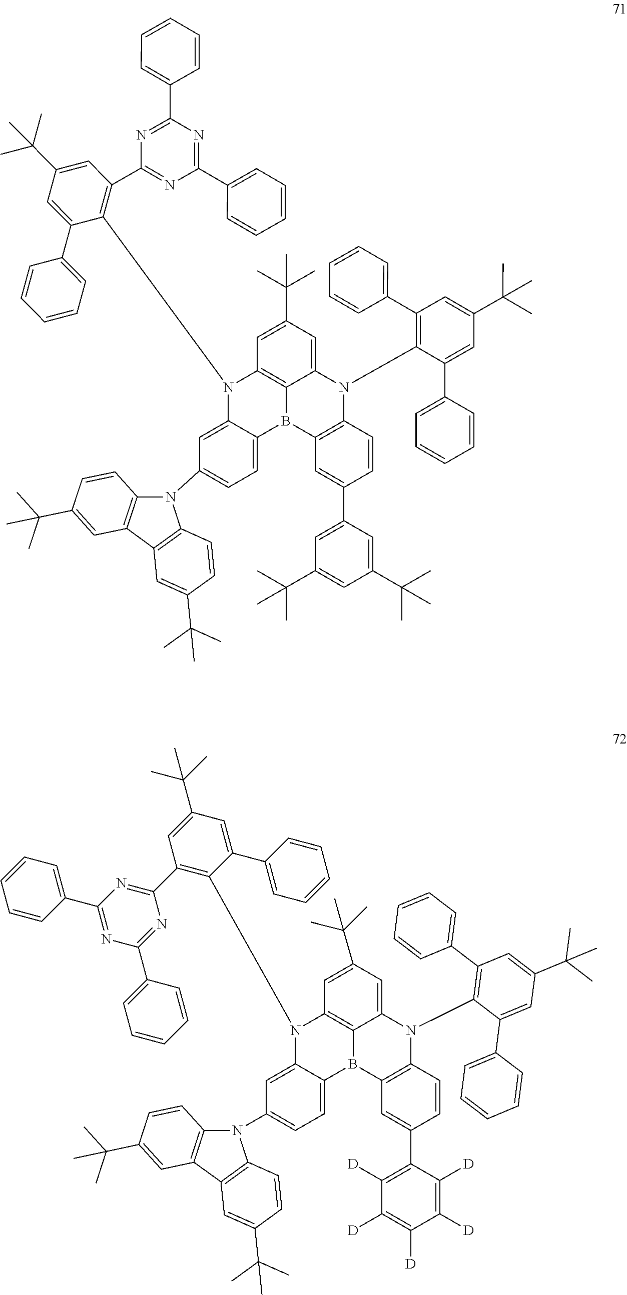 [SMILES: CC(C)(C)c1cc(-c2ccc3c(c2)B2c4ccc(-n5c6ccc(C(C)(C)C)cc6c6cc(C(C)(C)C)ccc65)cc4N(c4c(-c5ccccc5)cc(C(C)(C)C)cc4-c4nc(-c5ccccc5)nc(-c5ccccc5)n4)c4cc(C(C)(C)C)cc(c42)N3c2c(-c3ccccc3)cc(C(C)(C)C)cc2-c2ccccc2)cc(C(C)(C)C)c1 ; [2H]c1c([2H])c([2H])c(-c2ccc3c(c2)B2c4ccc(-n5c6ccc(C(C)(C)C)cc6c6cc(C(C)(C)C)ccc65)cc4N(c4c(-c5ccccc5)cc(C(C)(C)C)cc4-c4nc(-c5ccccc5)nc(-c5ccccc5)n4)c4cc(C(C)(C)C)cc(c42)N3c2c(-c3ccccc3)cc(C(C)(C)C)cc2-c2ccccc2)c([2H])c1[2H]]

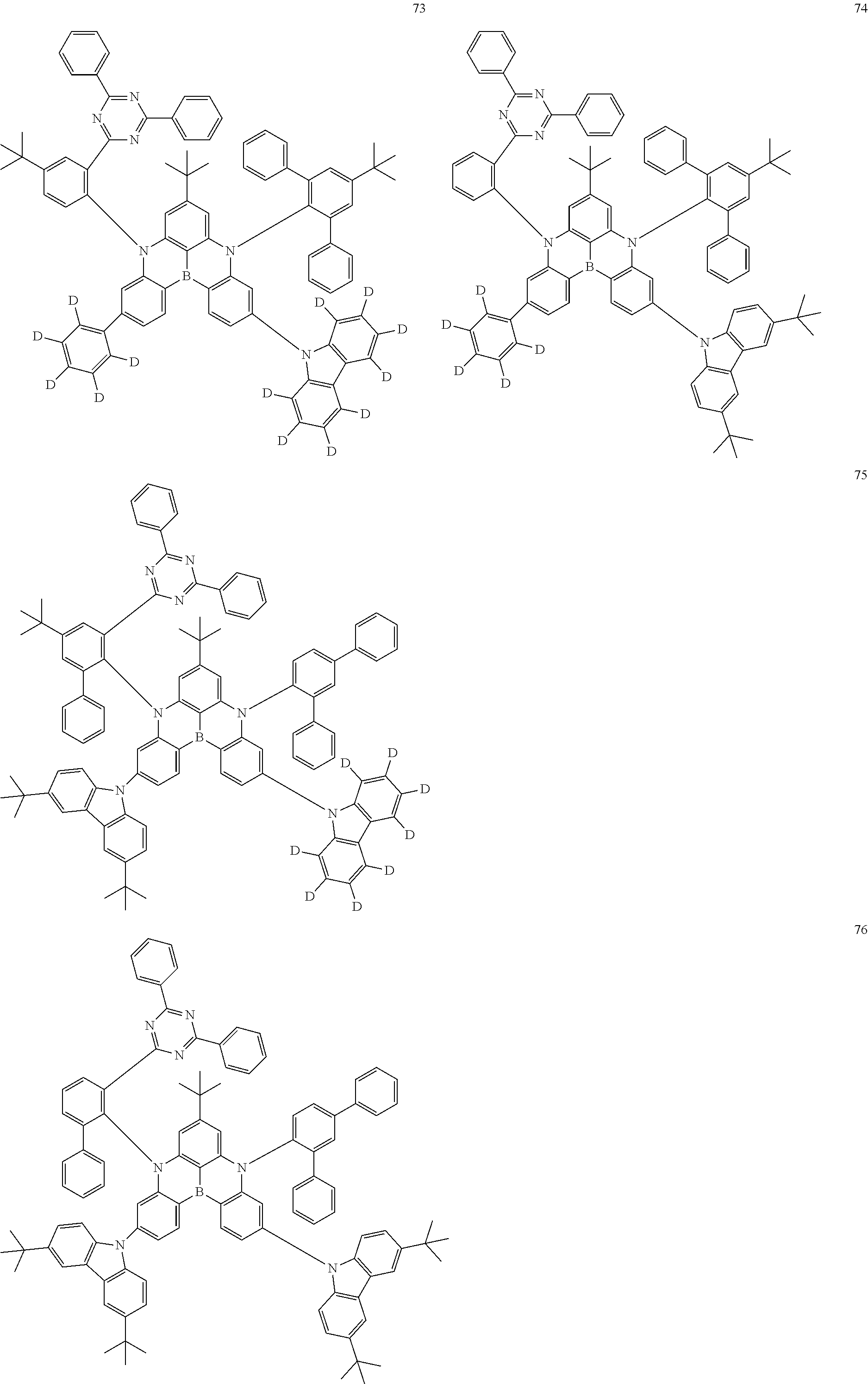

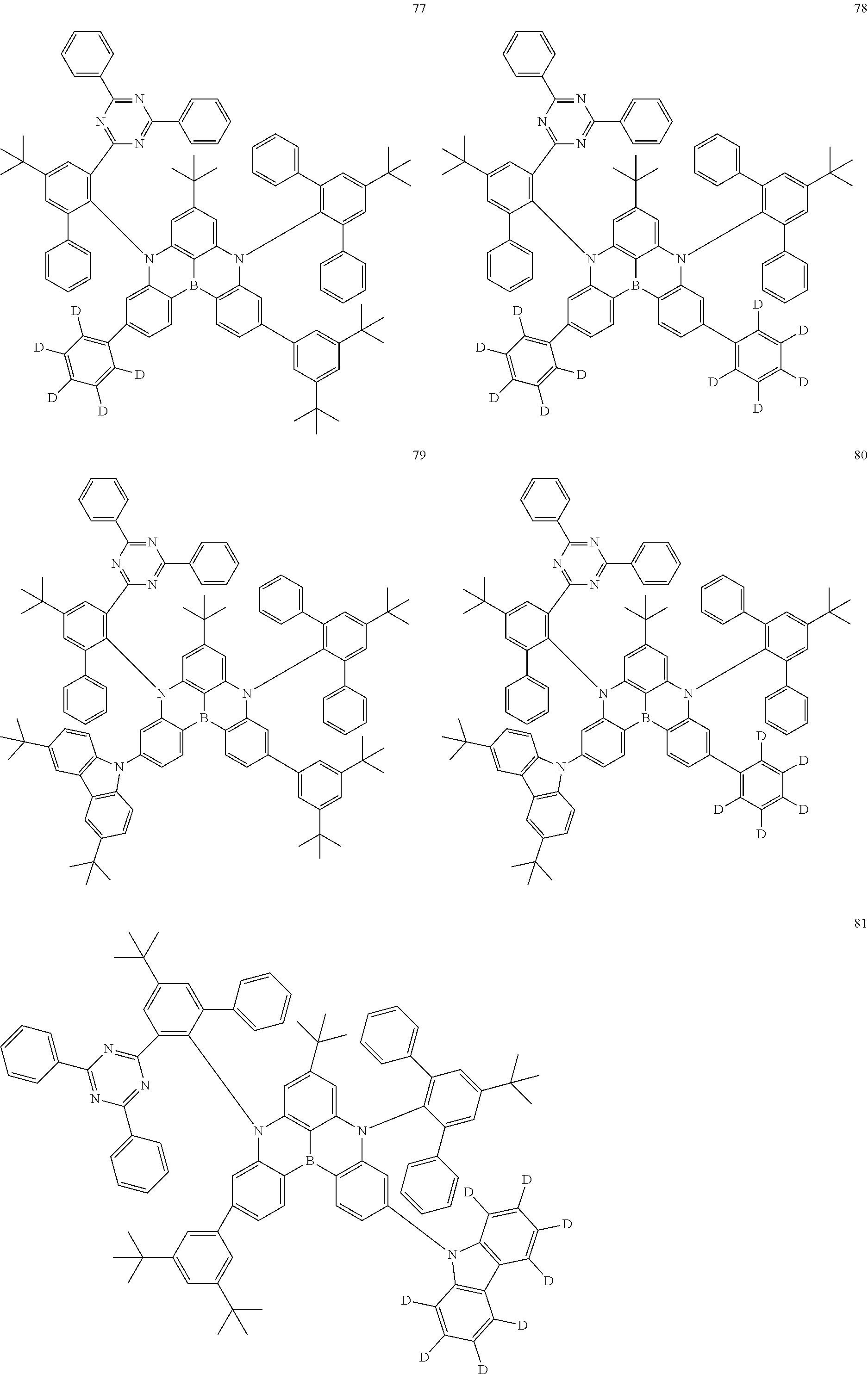

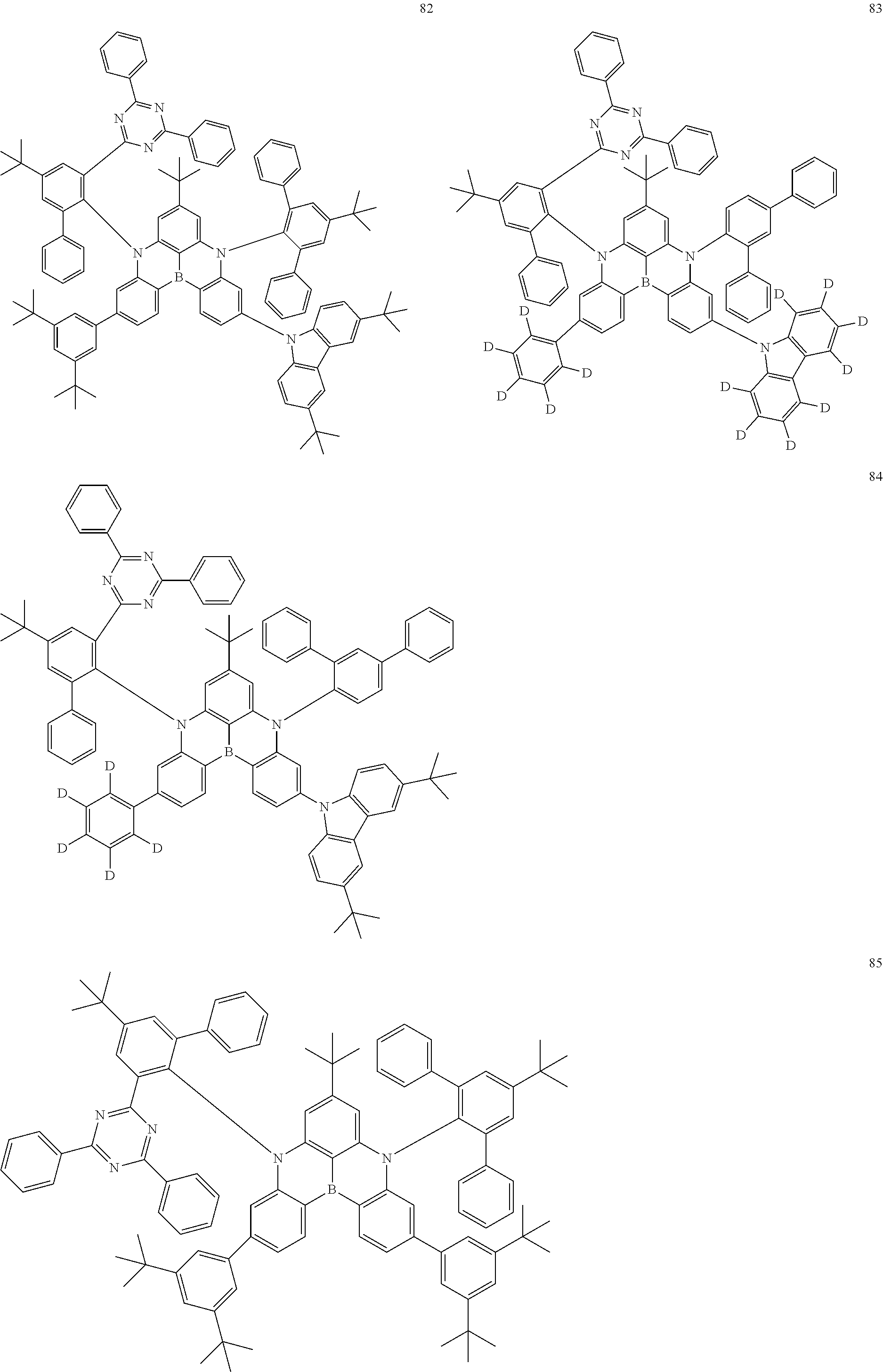

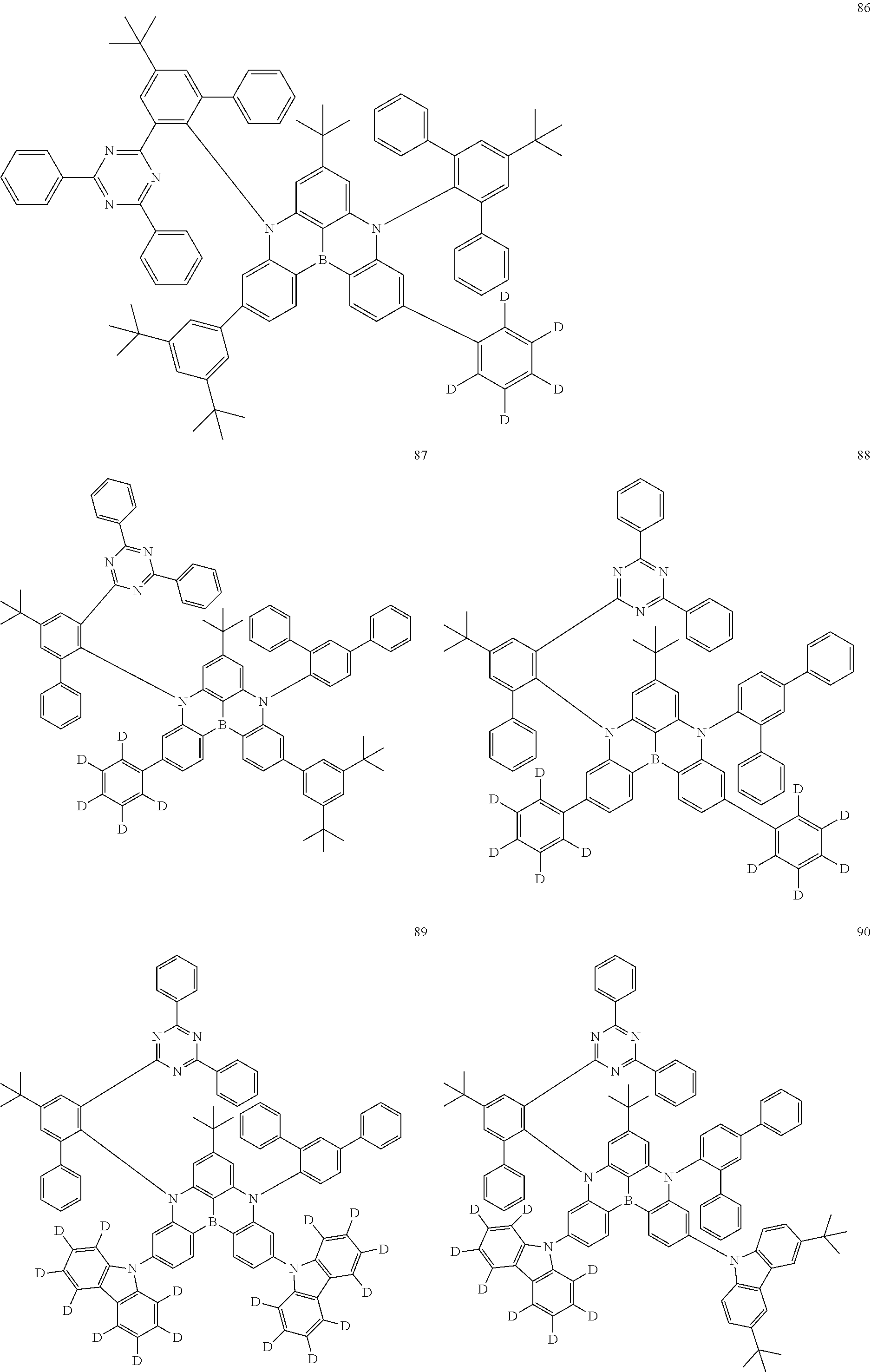

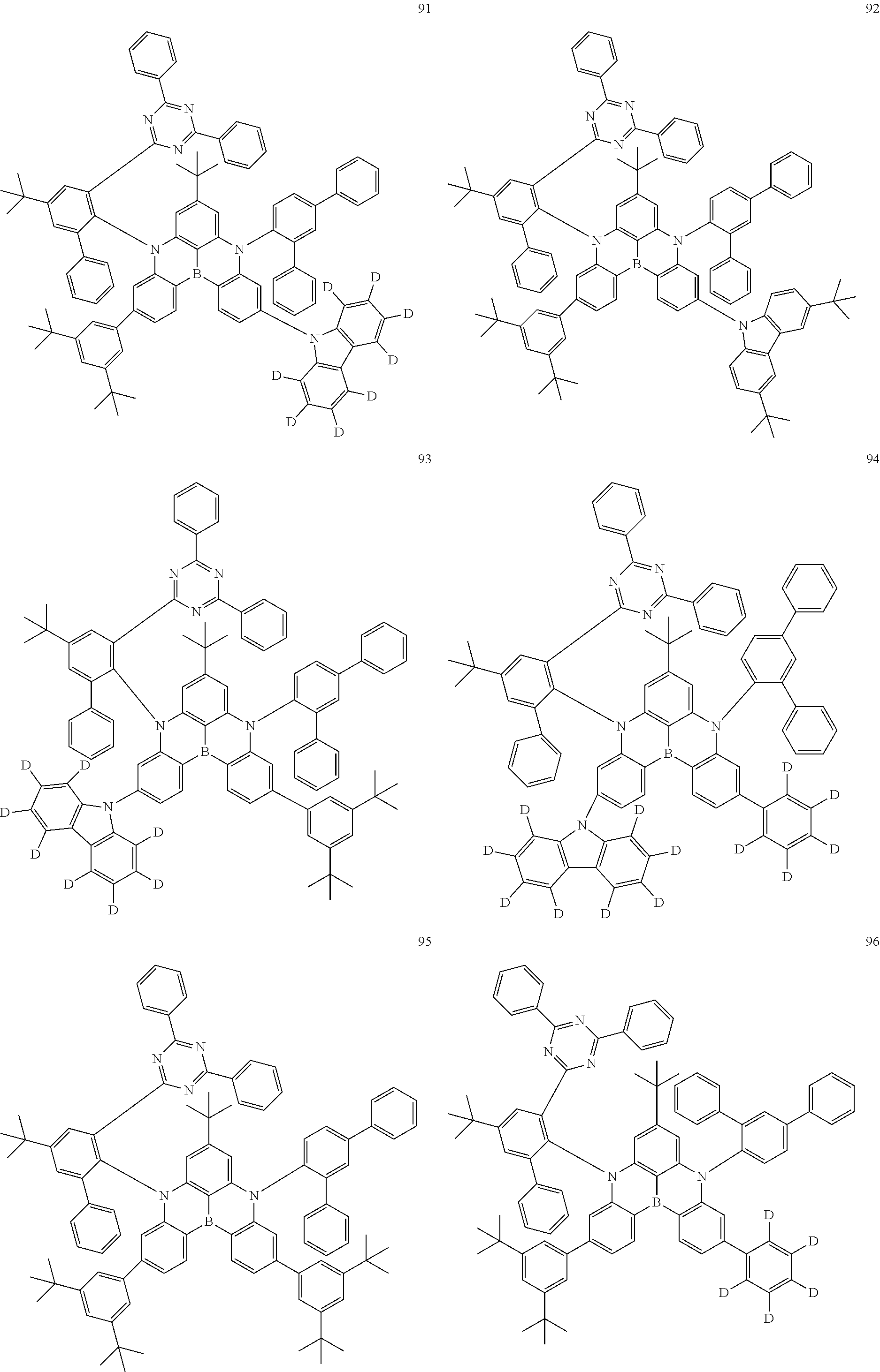

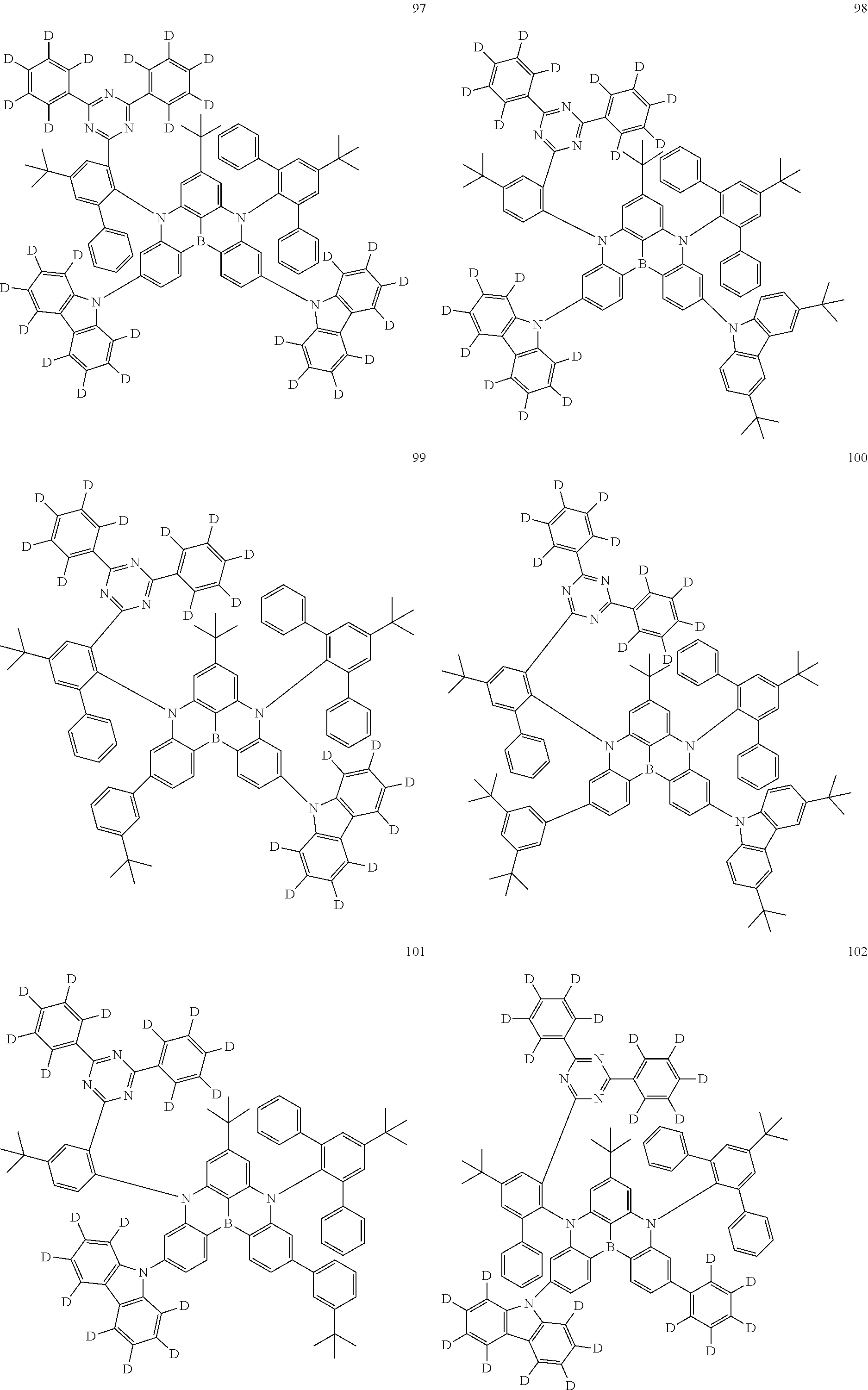

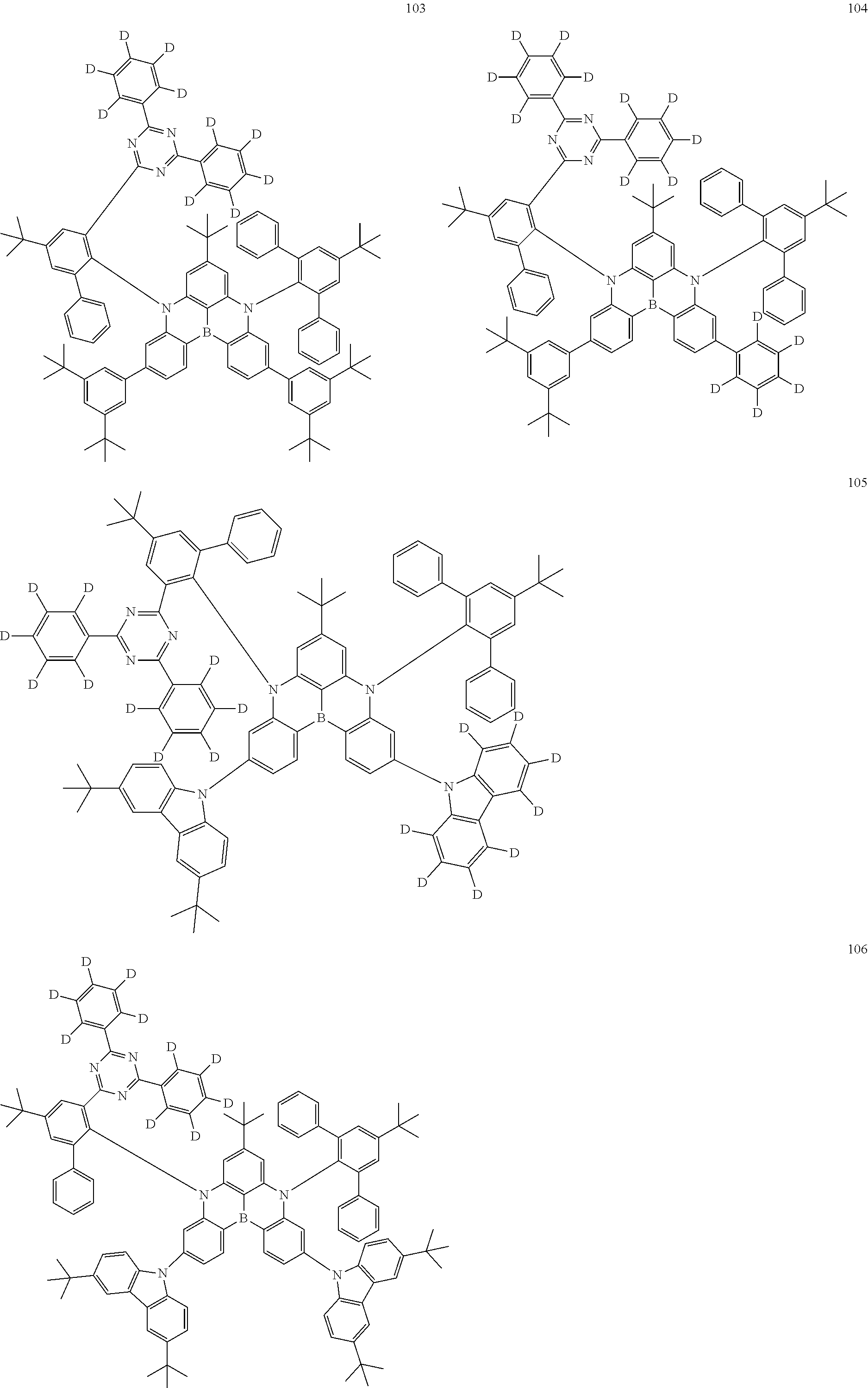

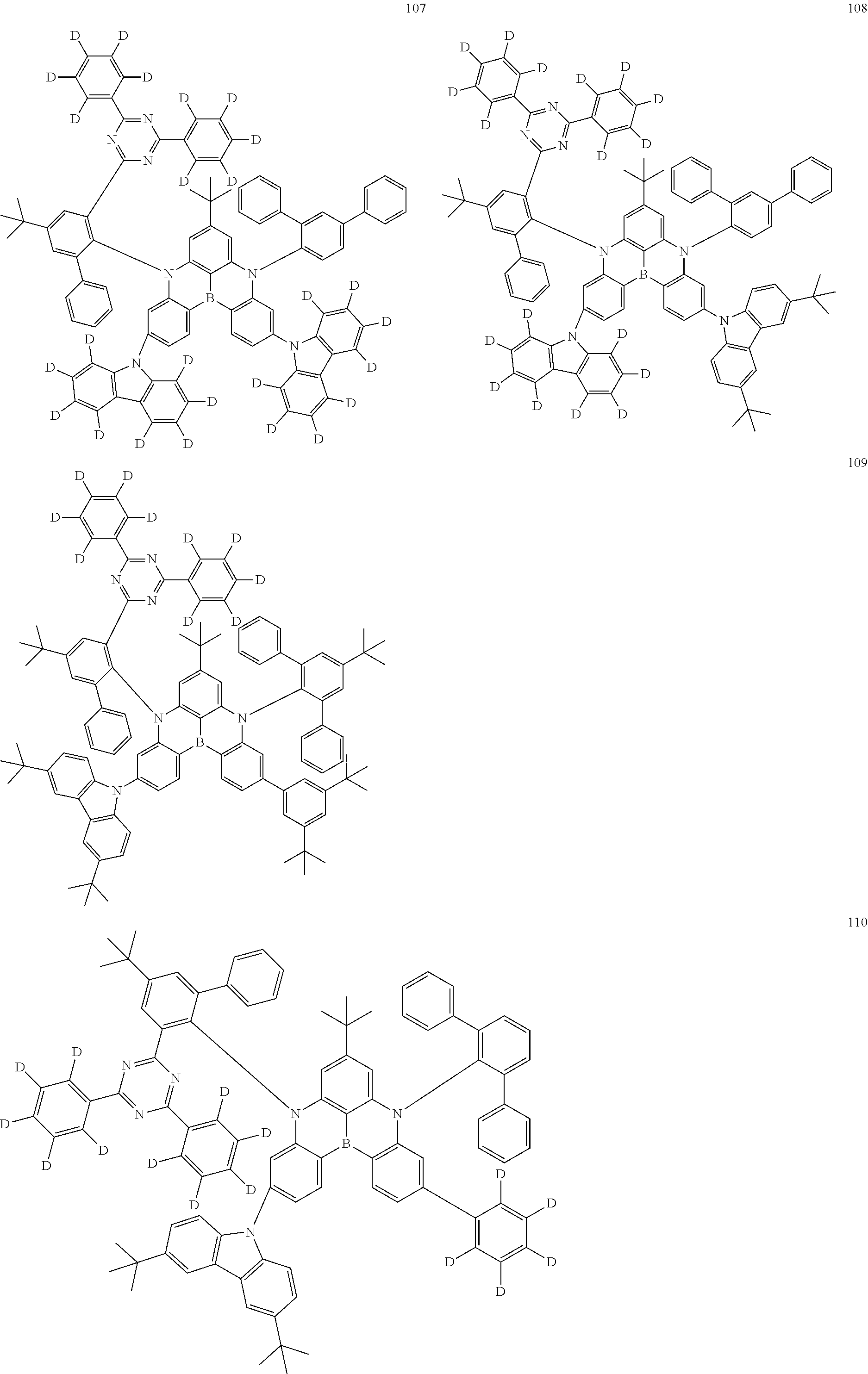

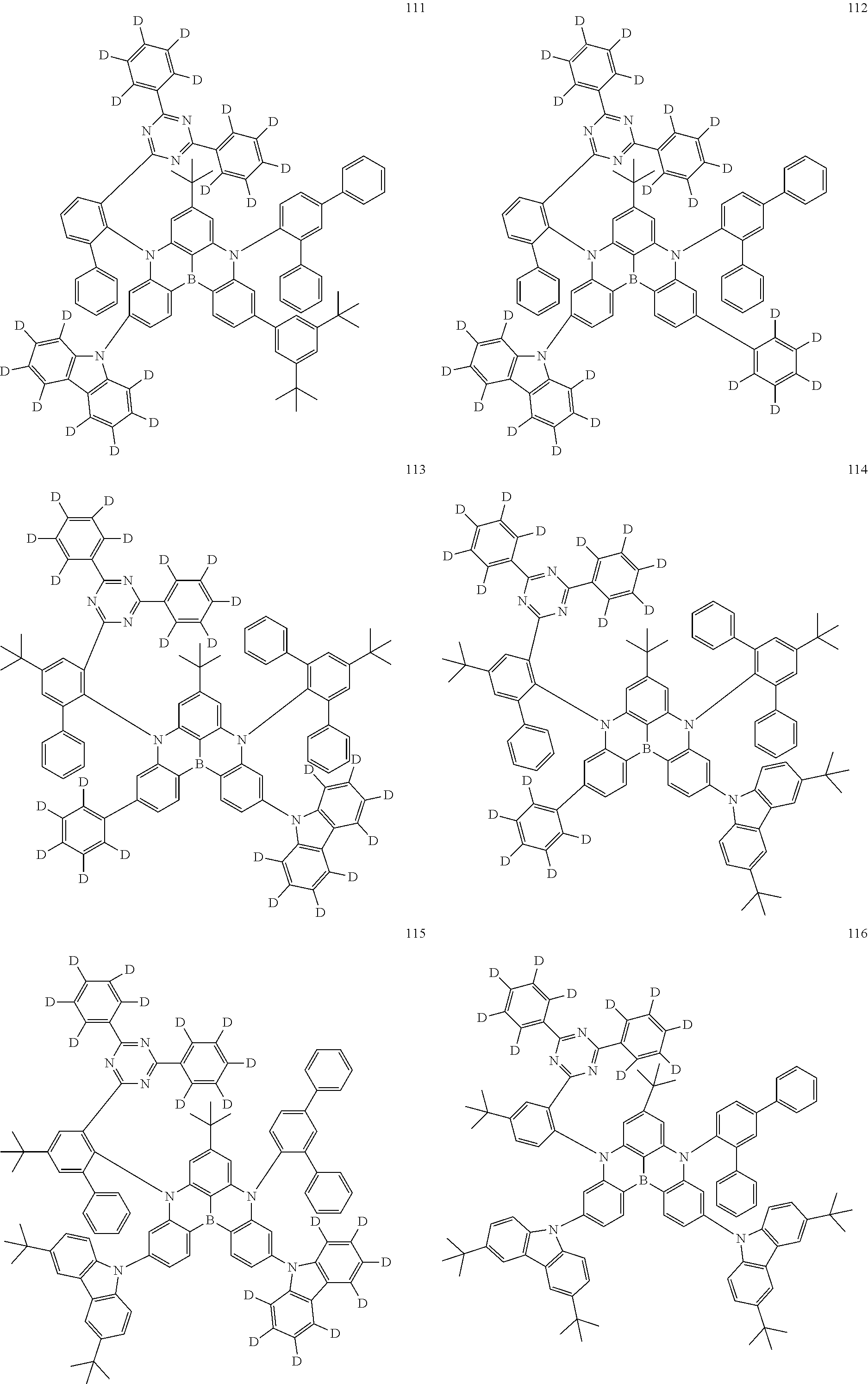

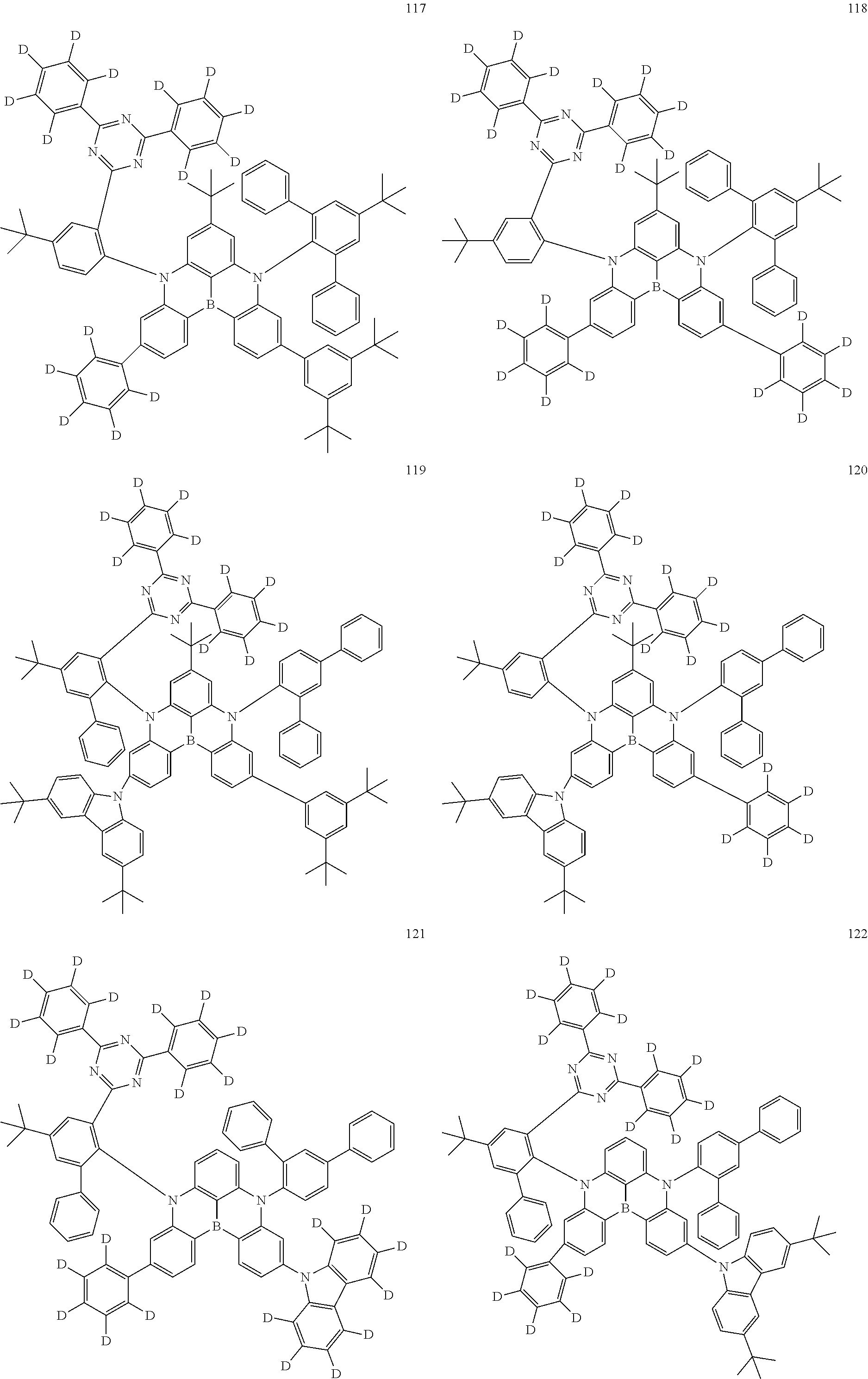

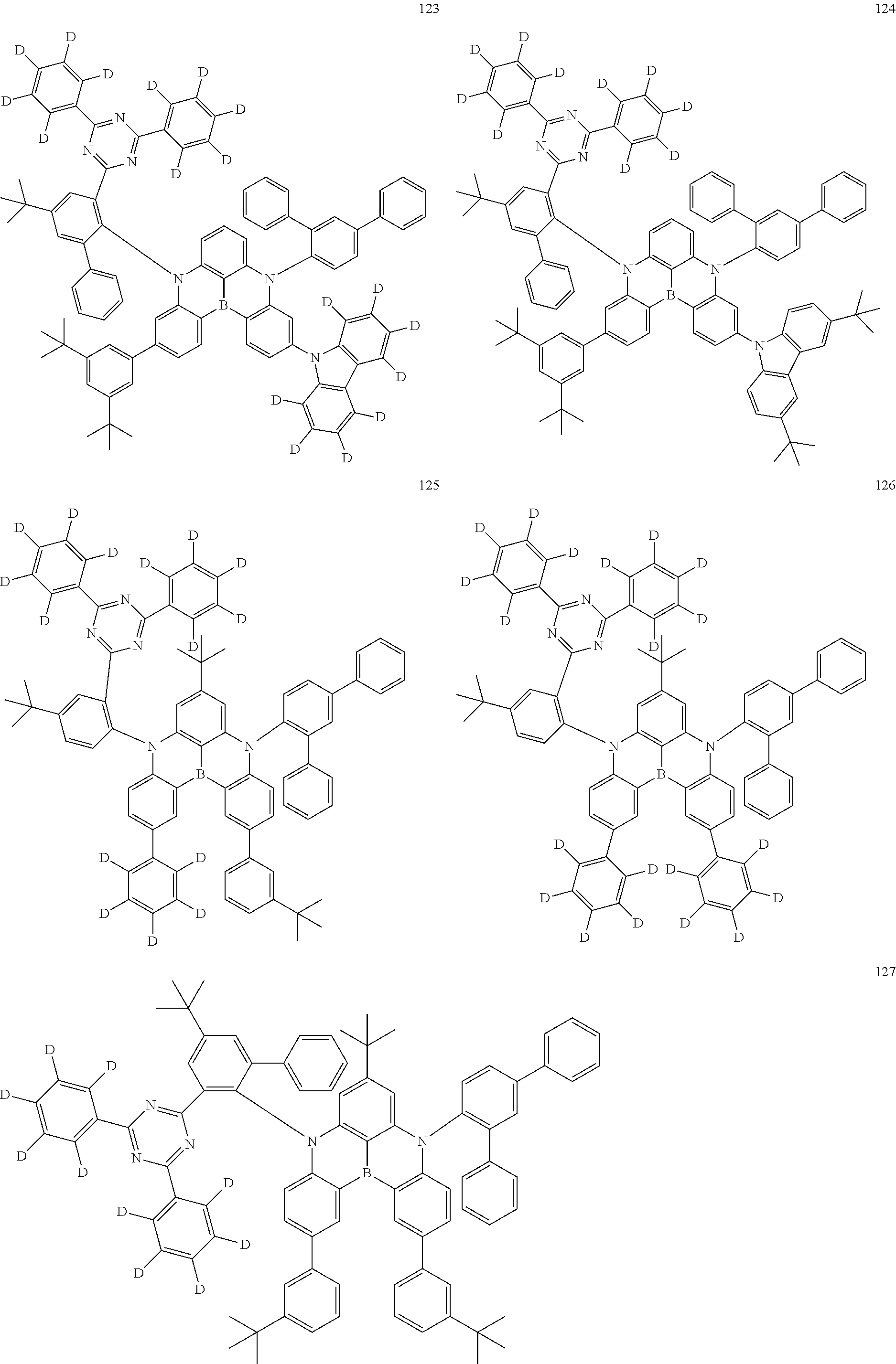

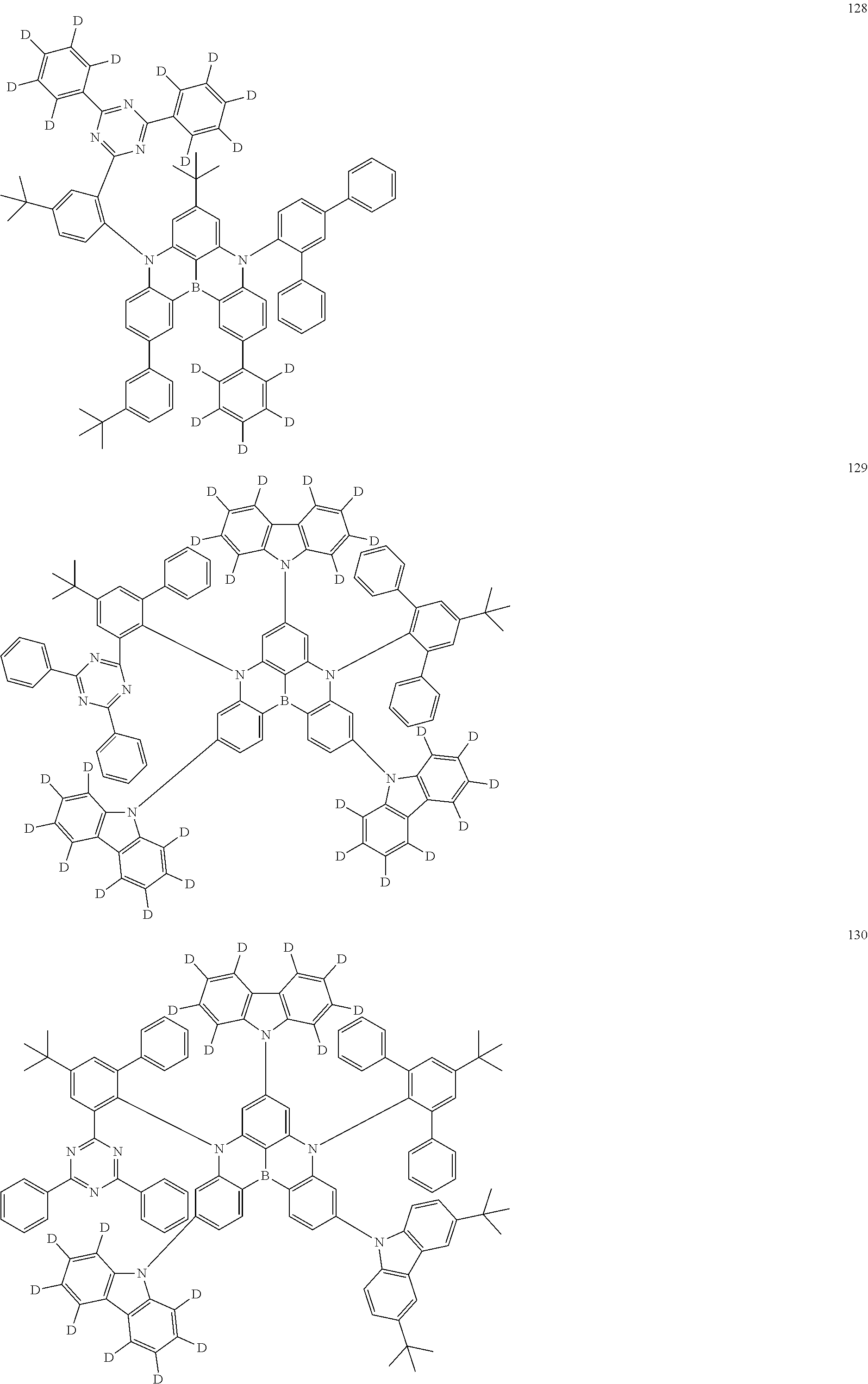

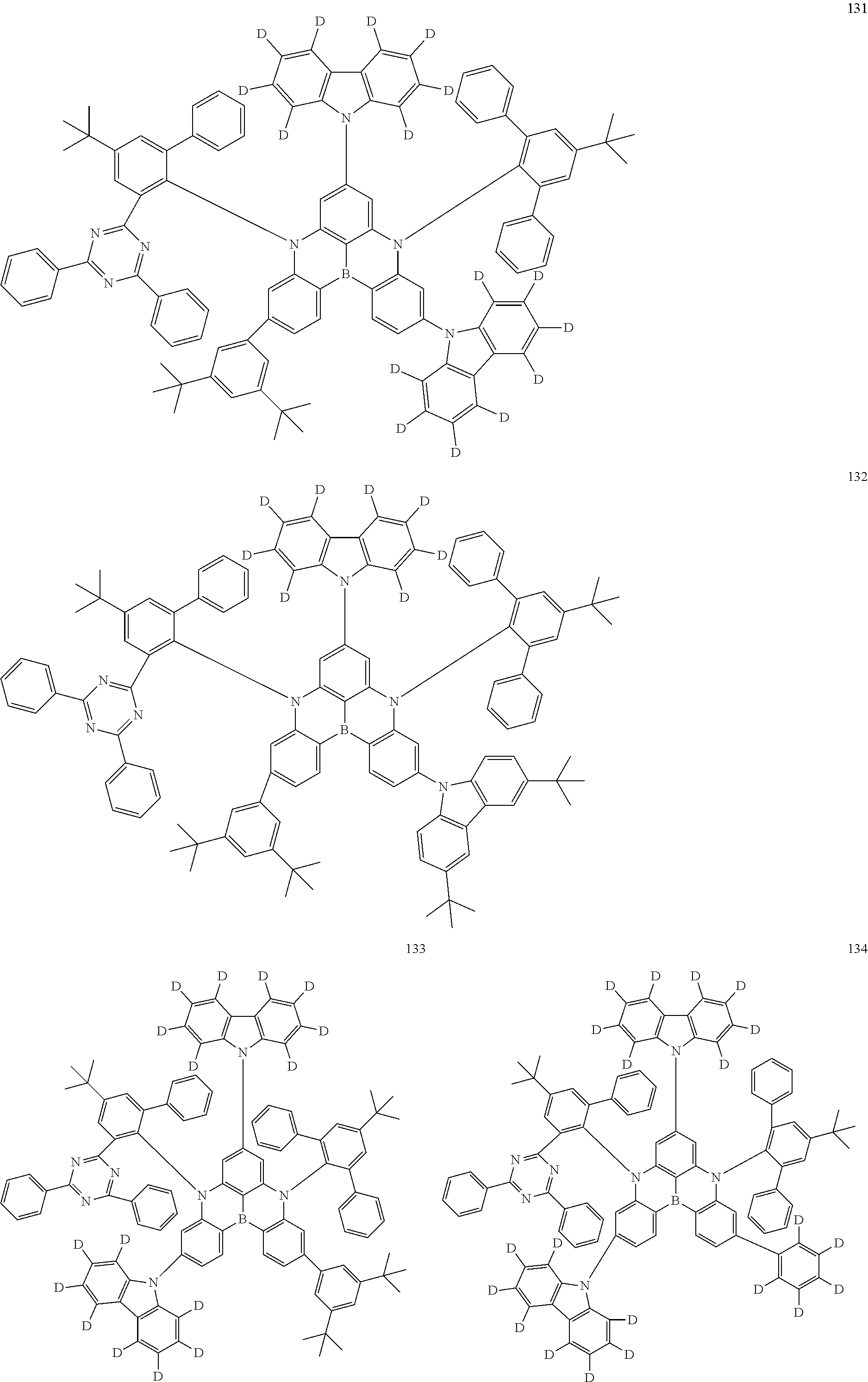

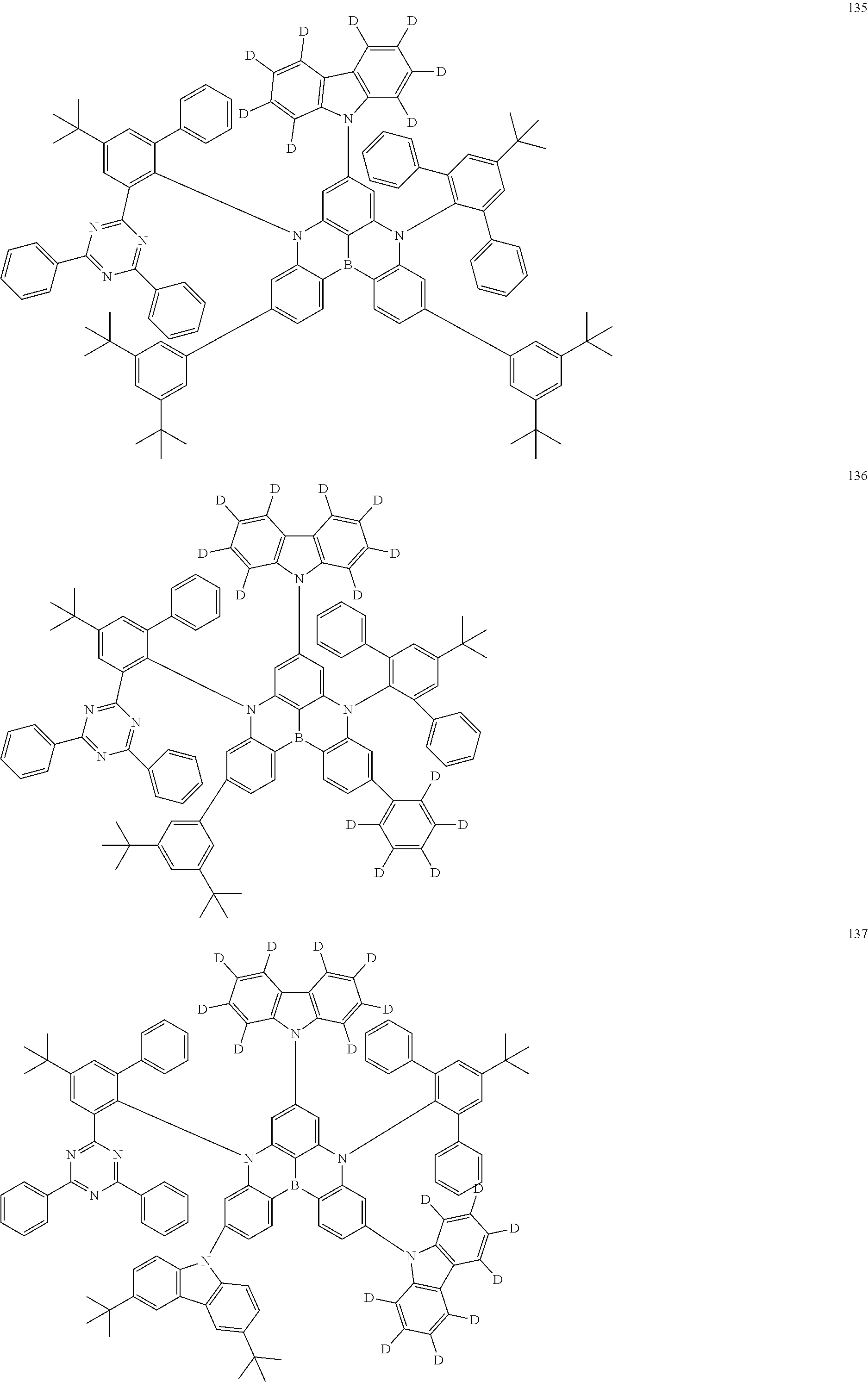

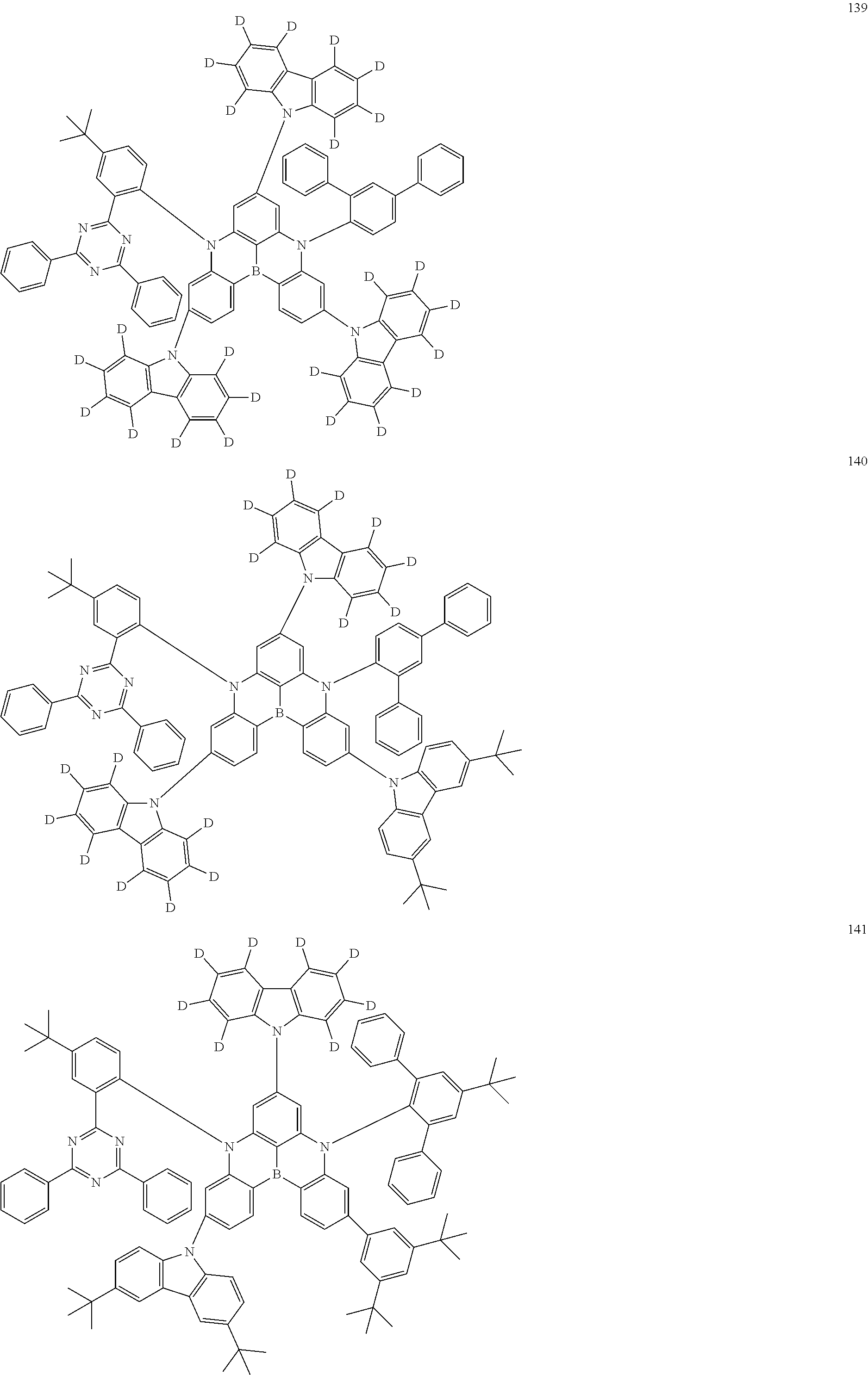

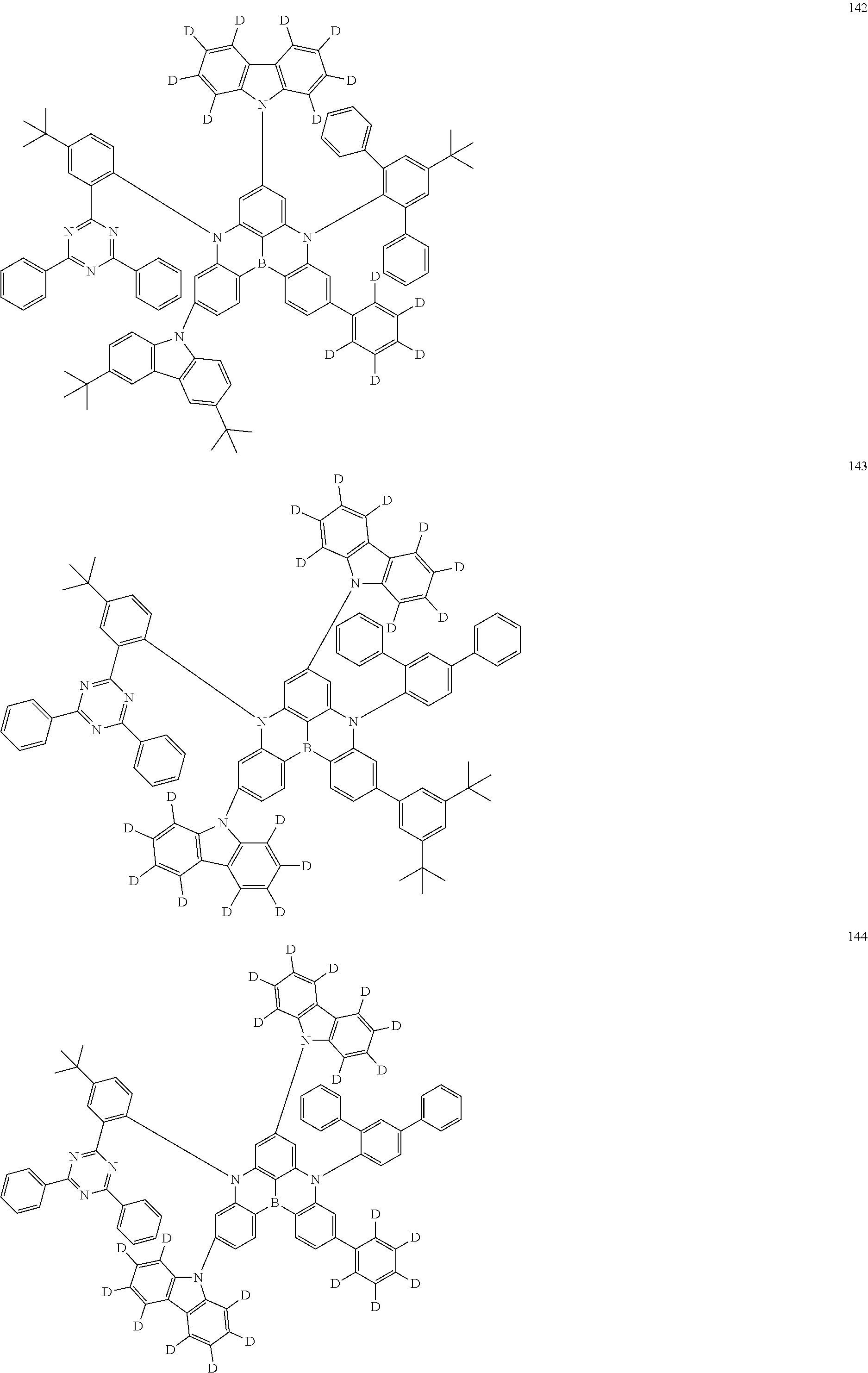

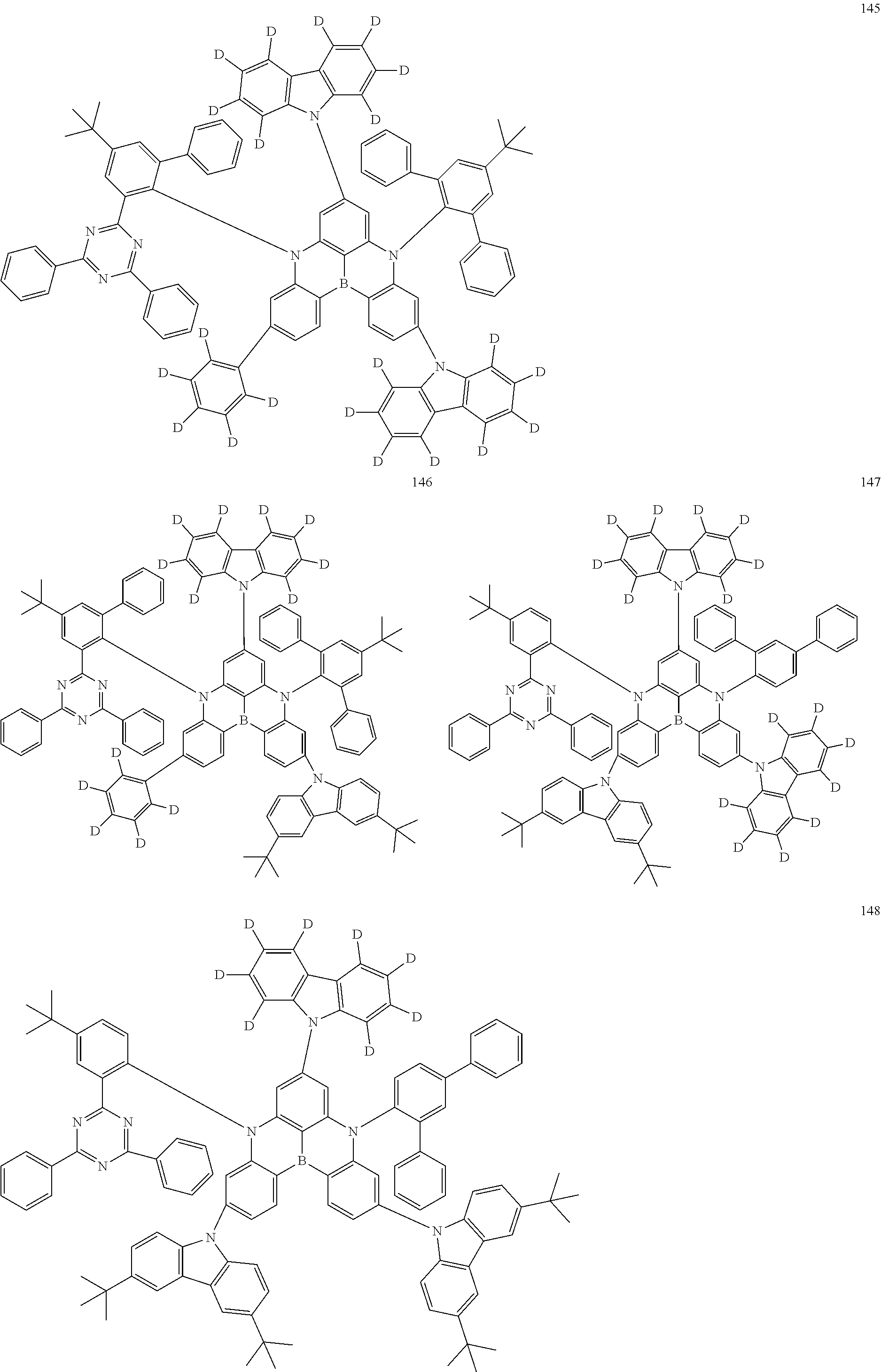

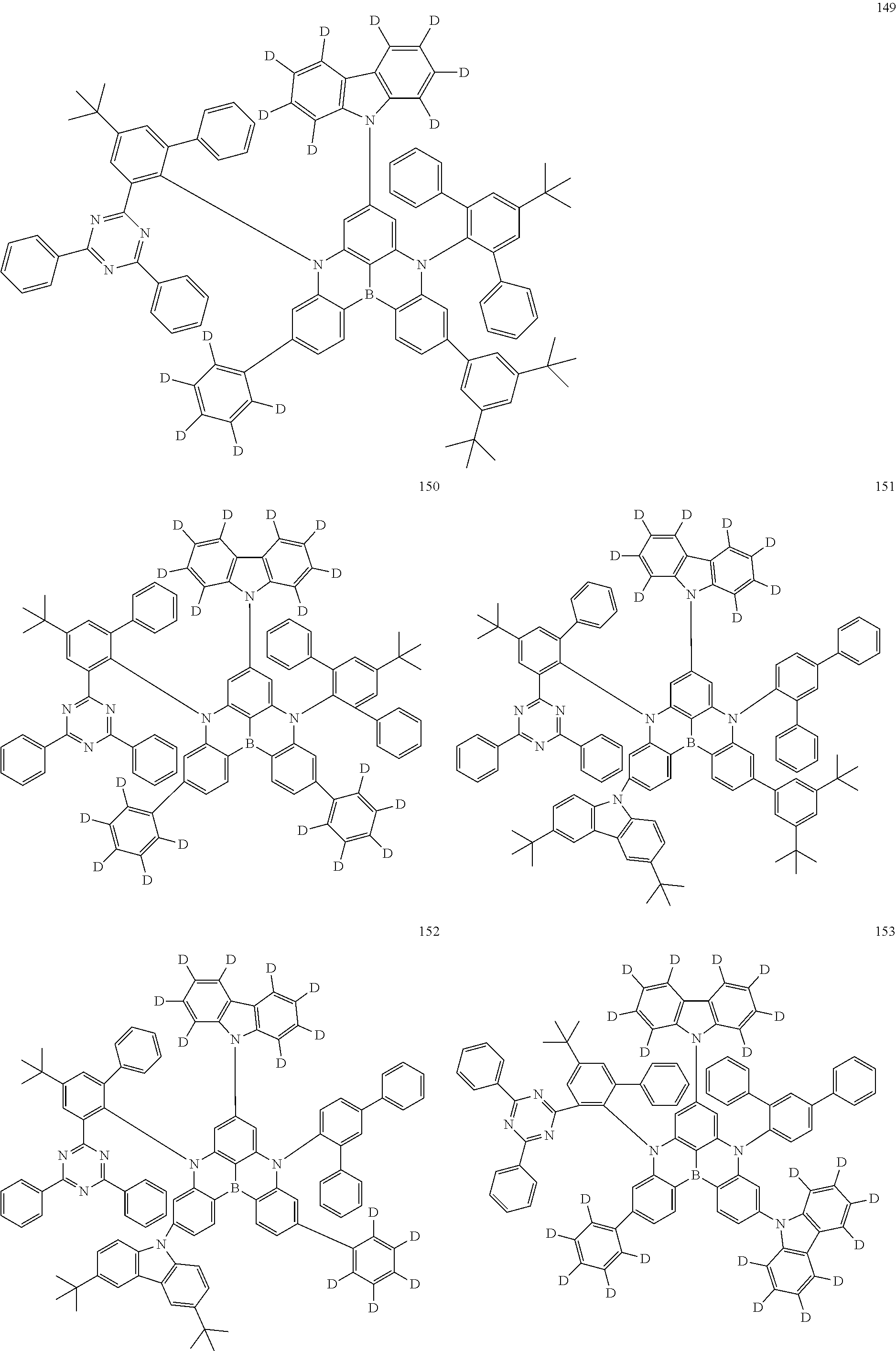

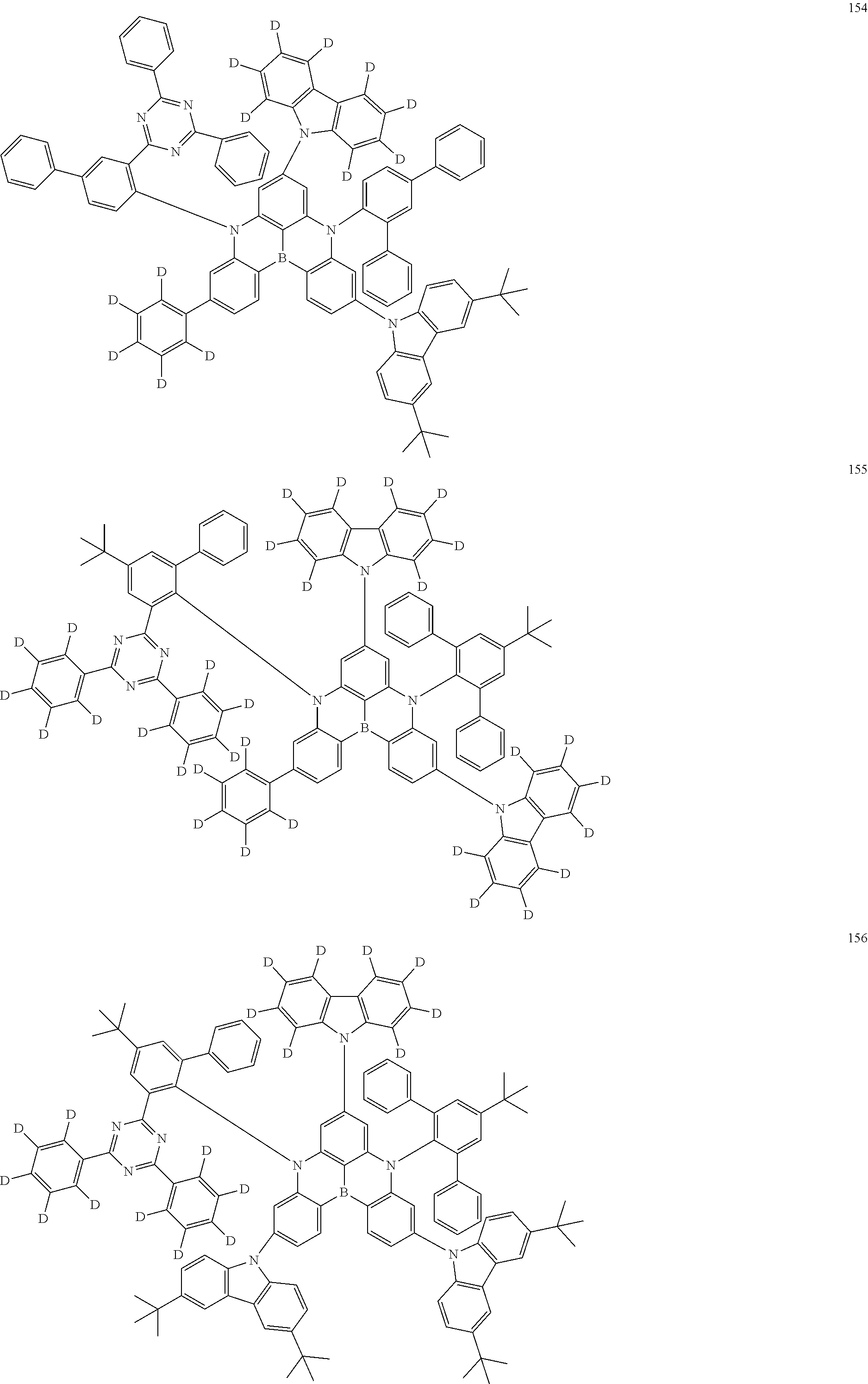

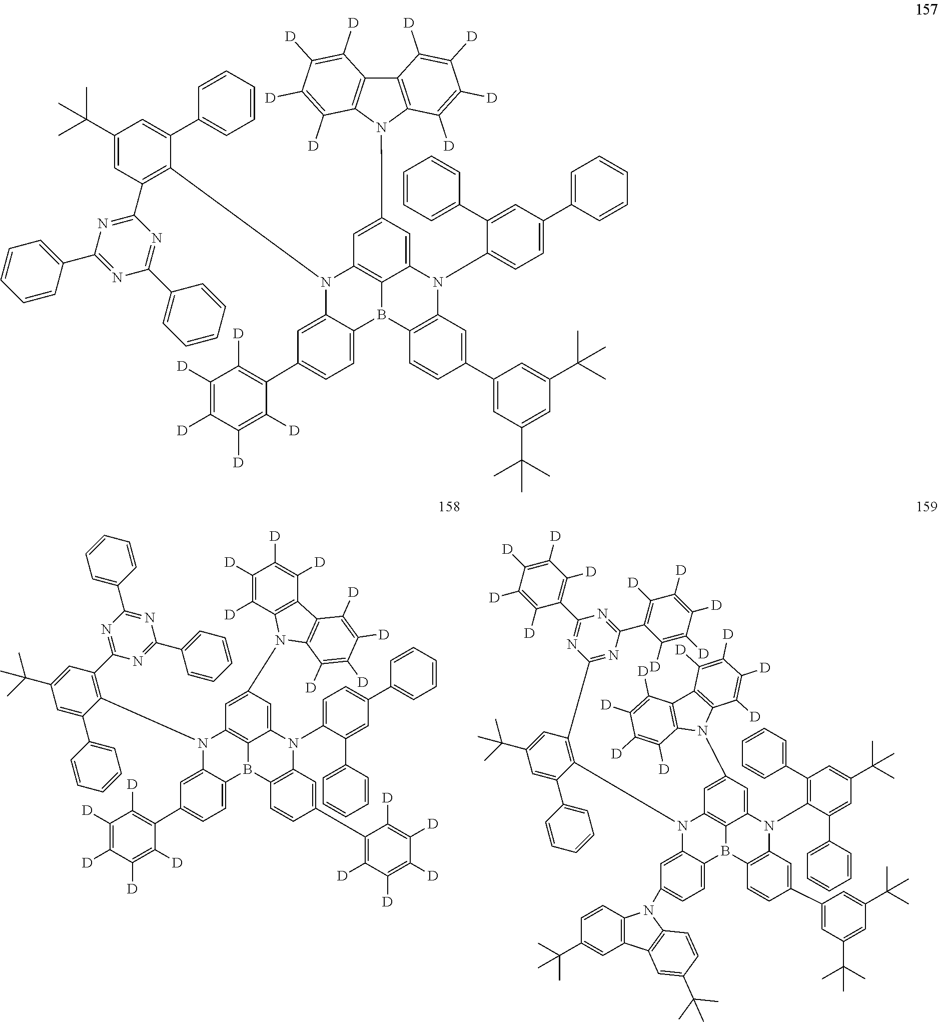

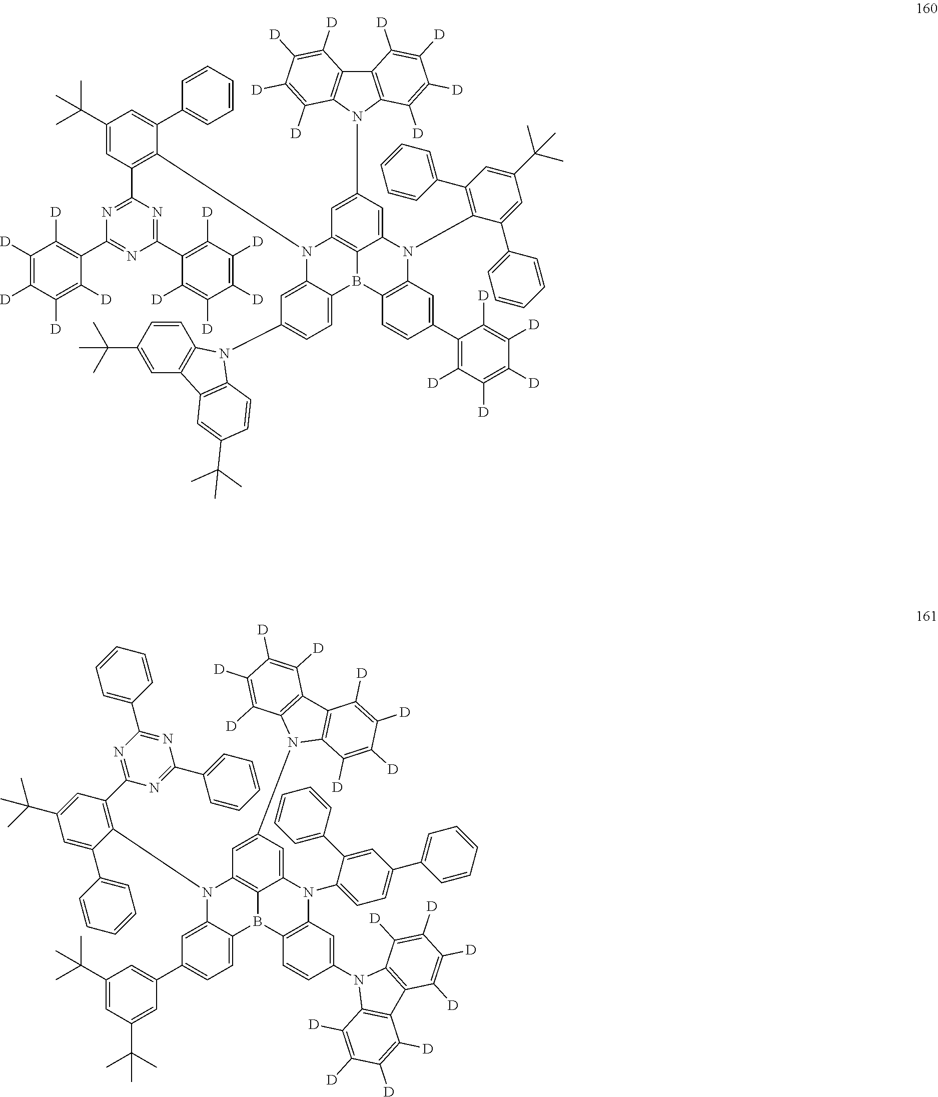

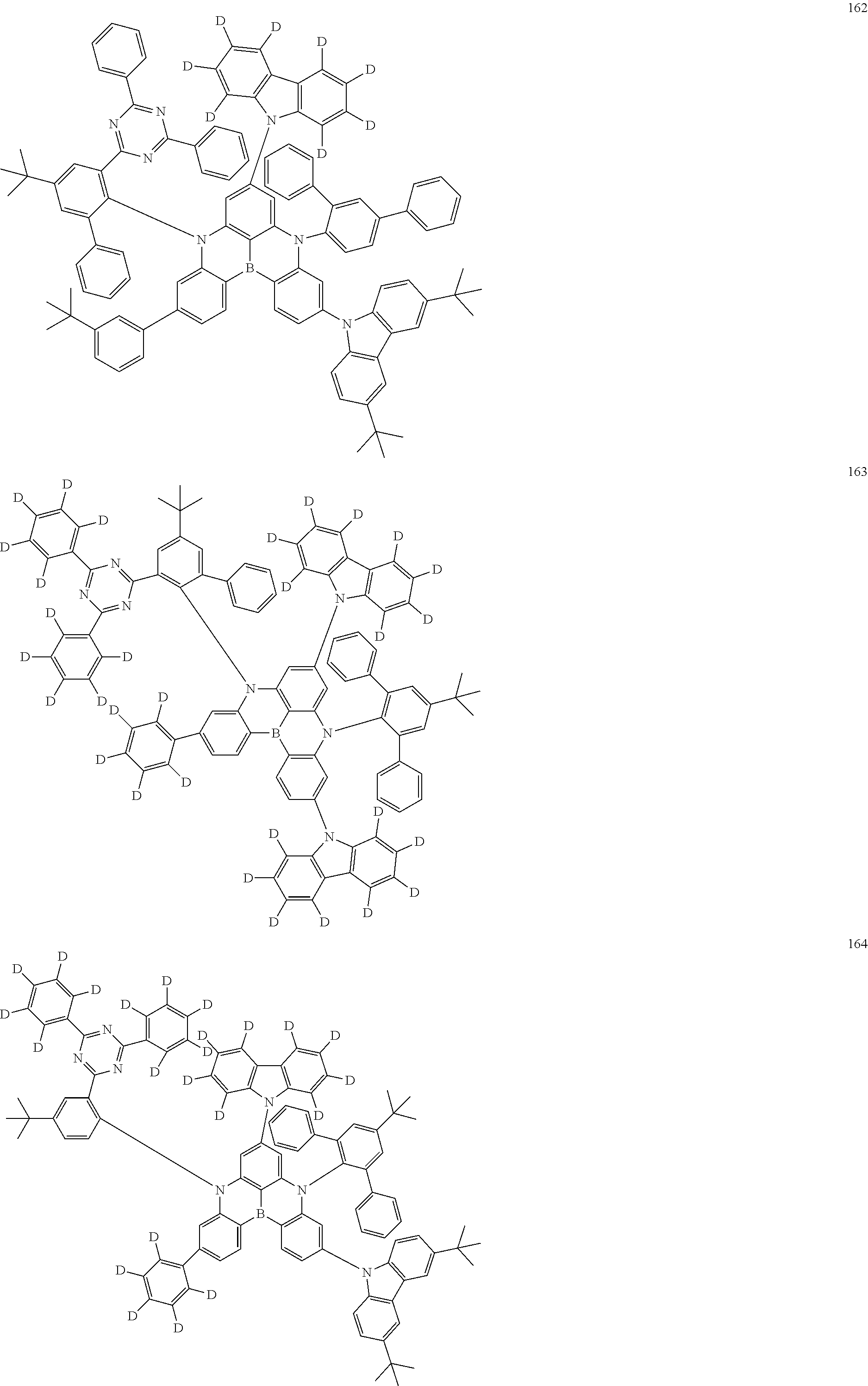

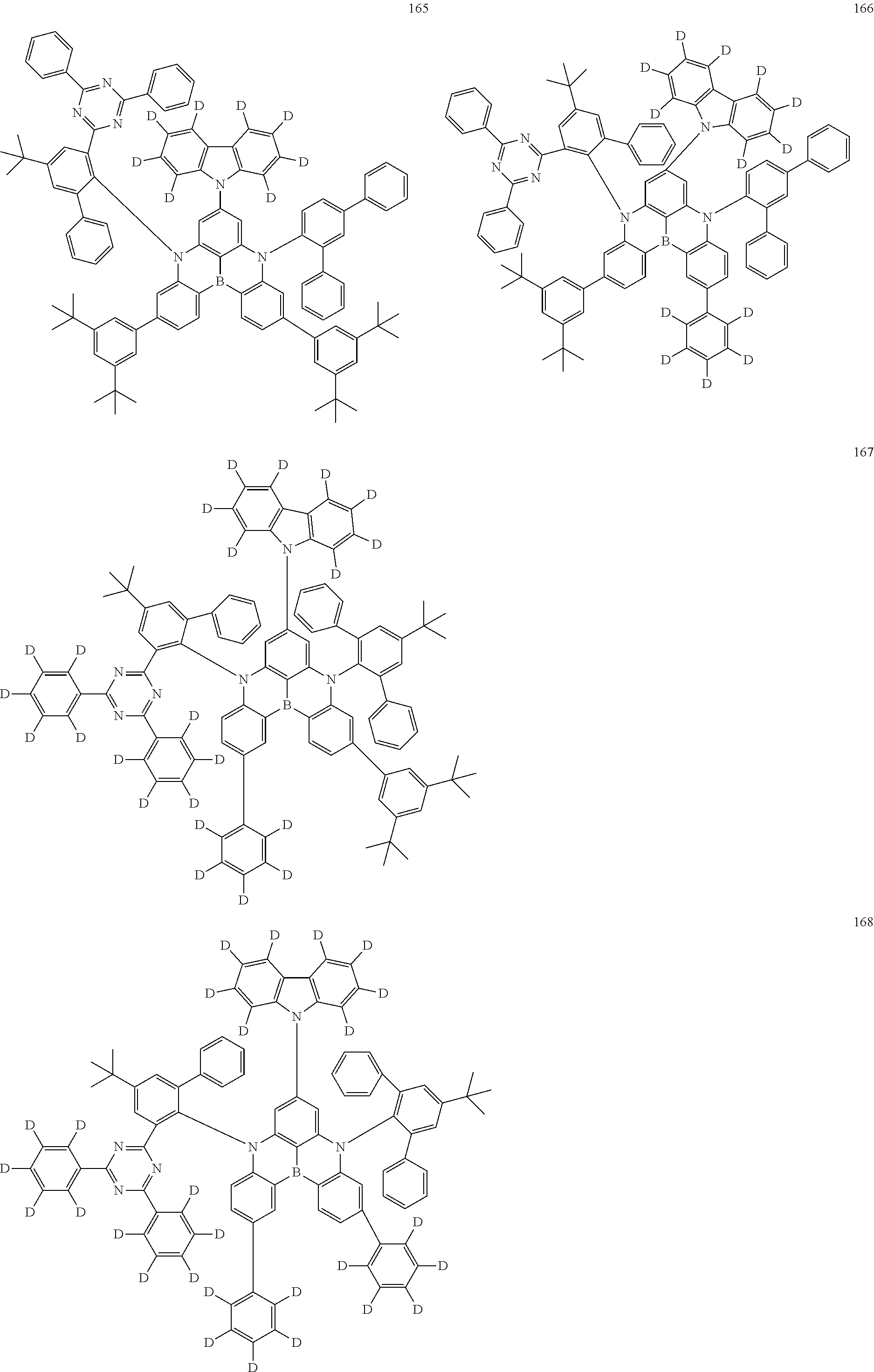

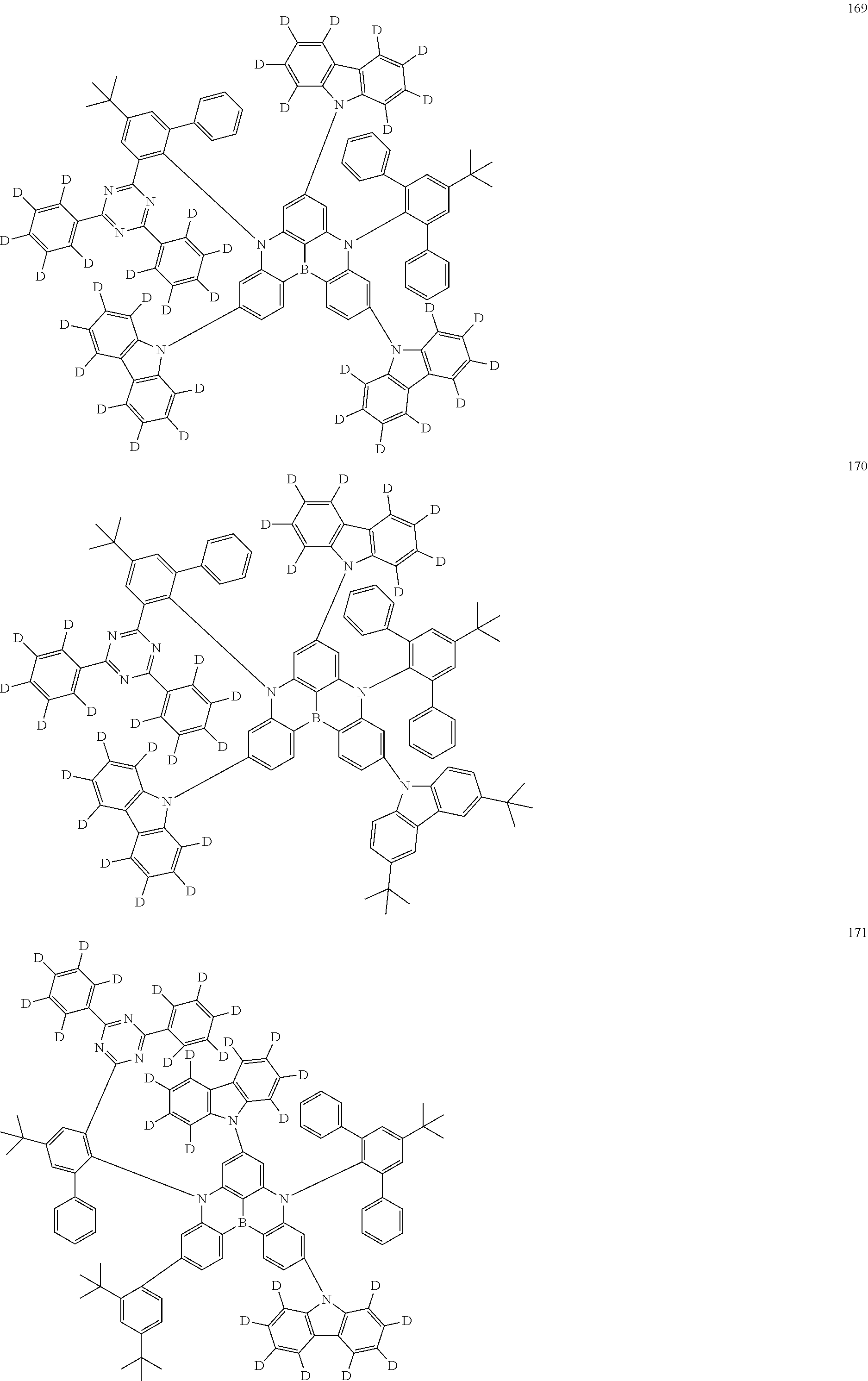

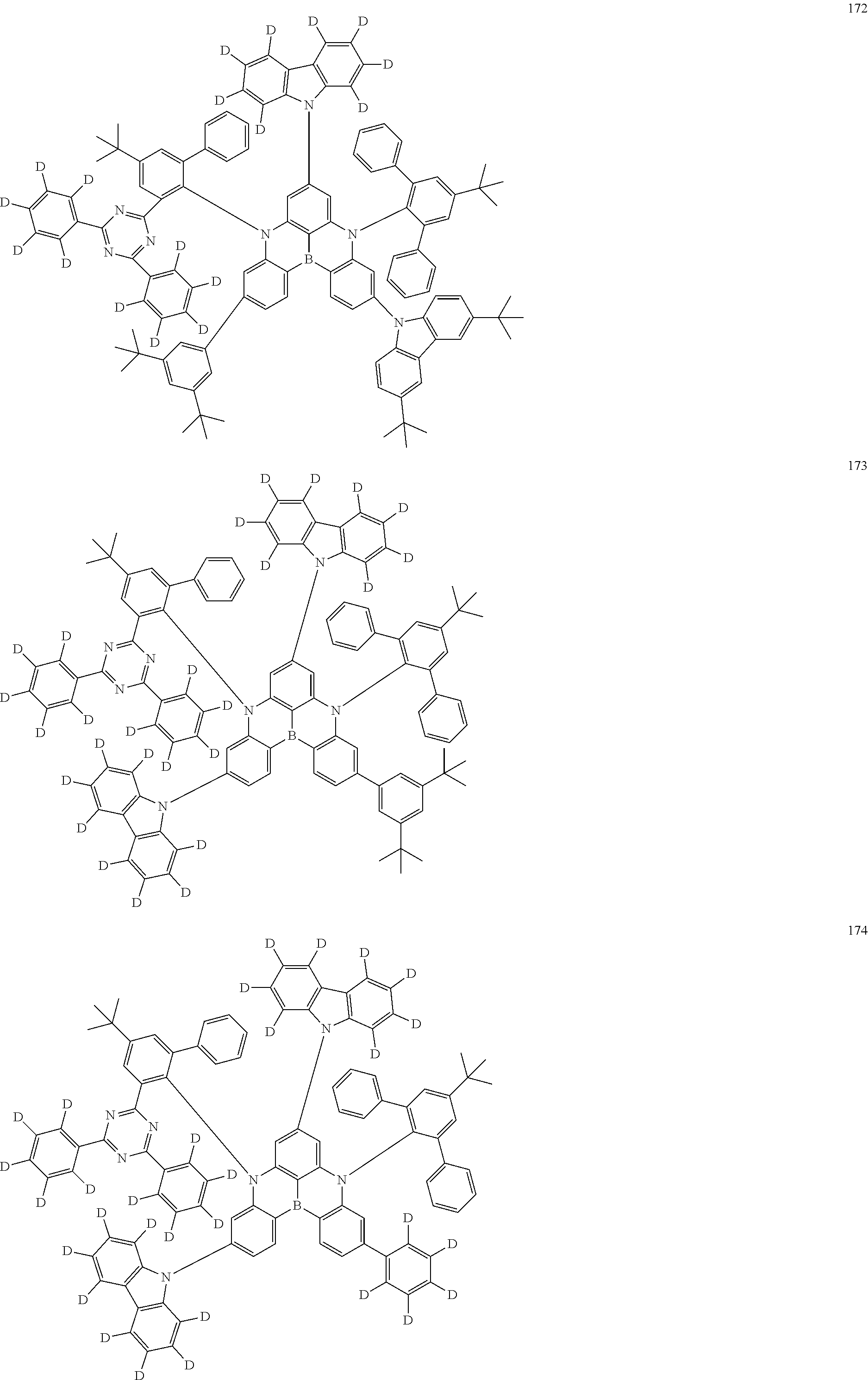

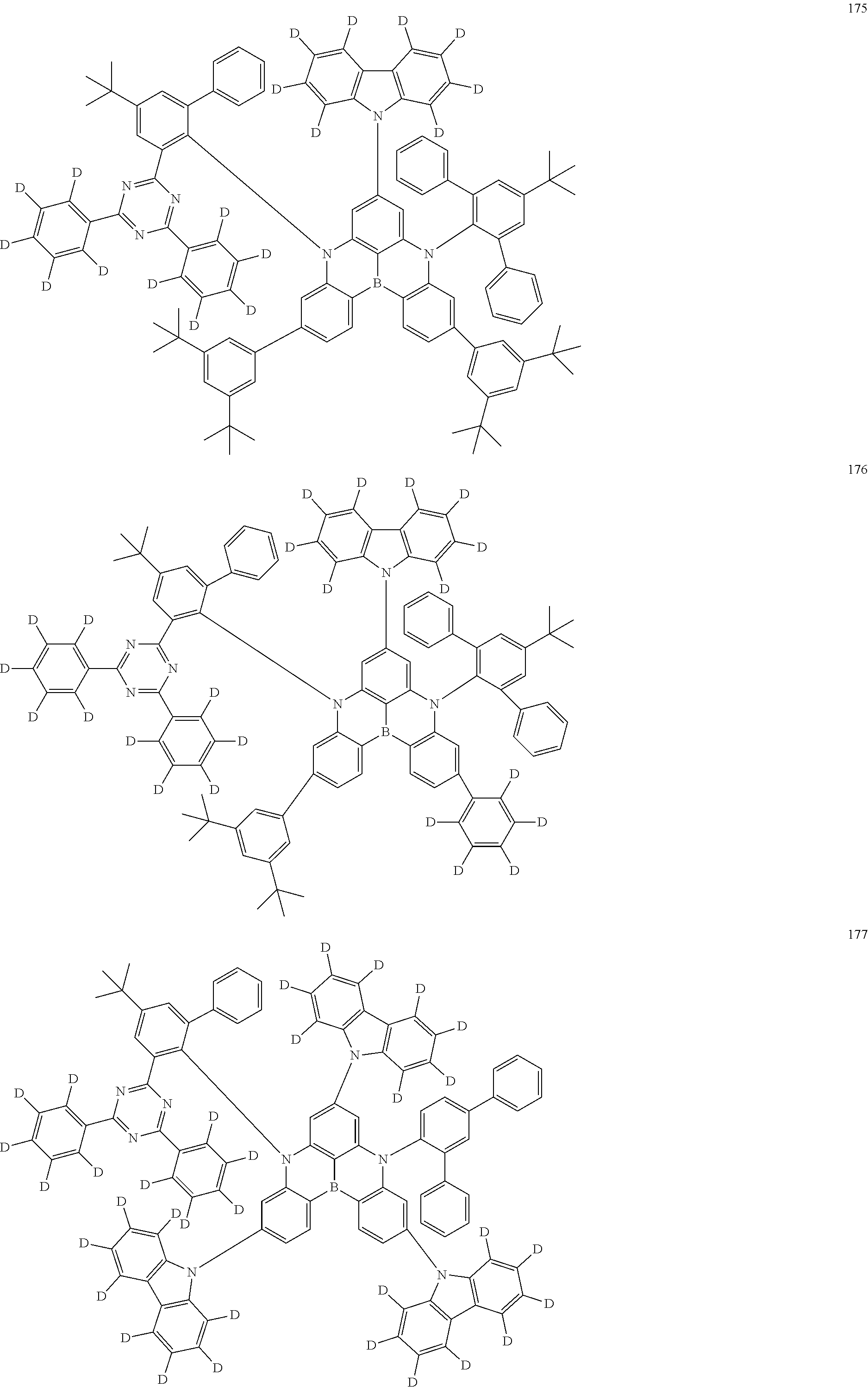

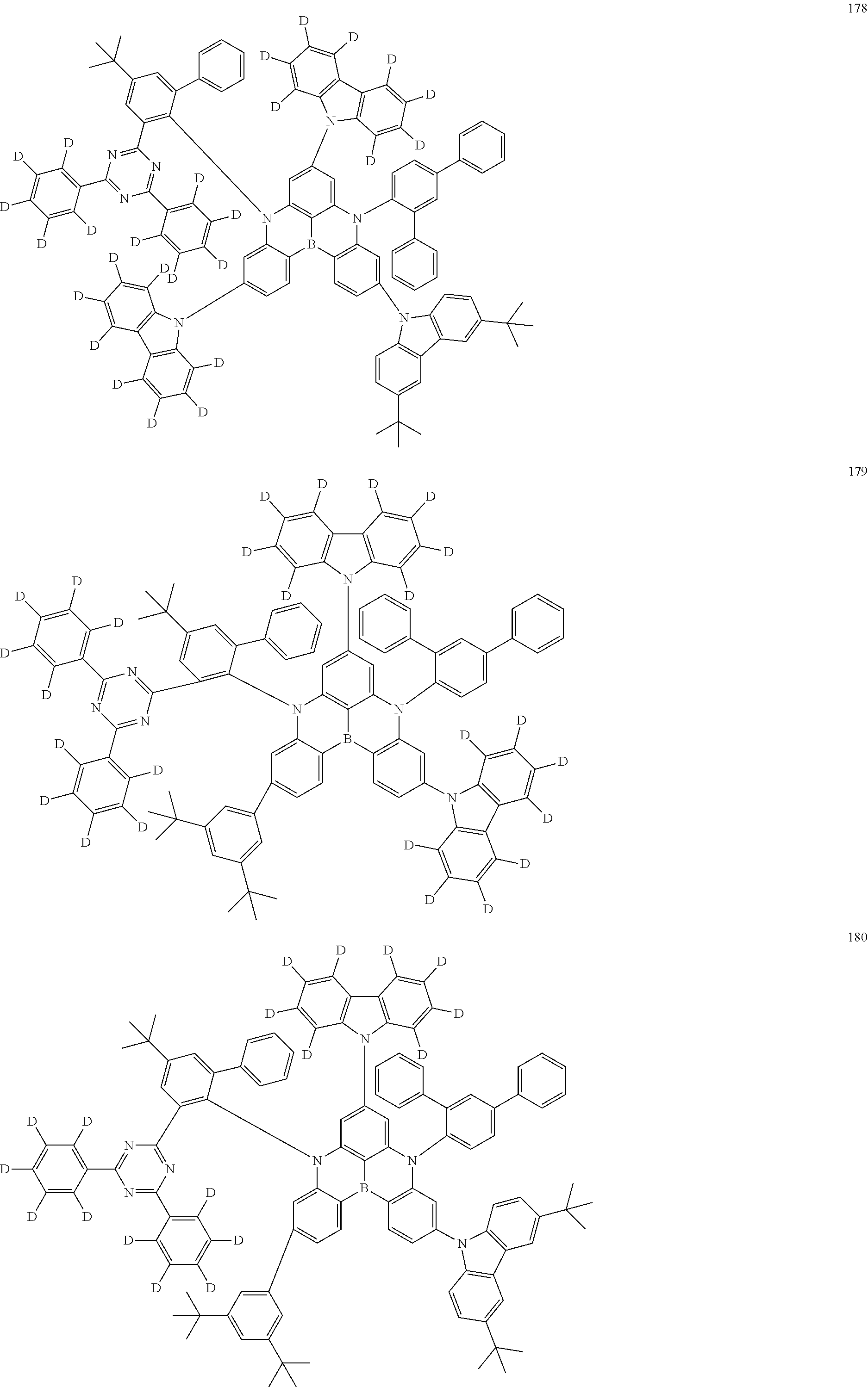

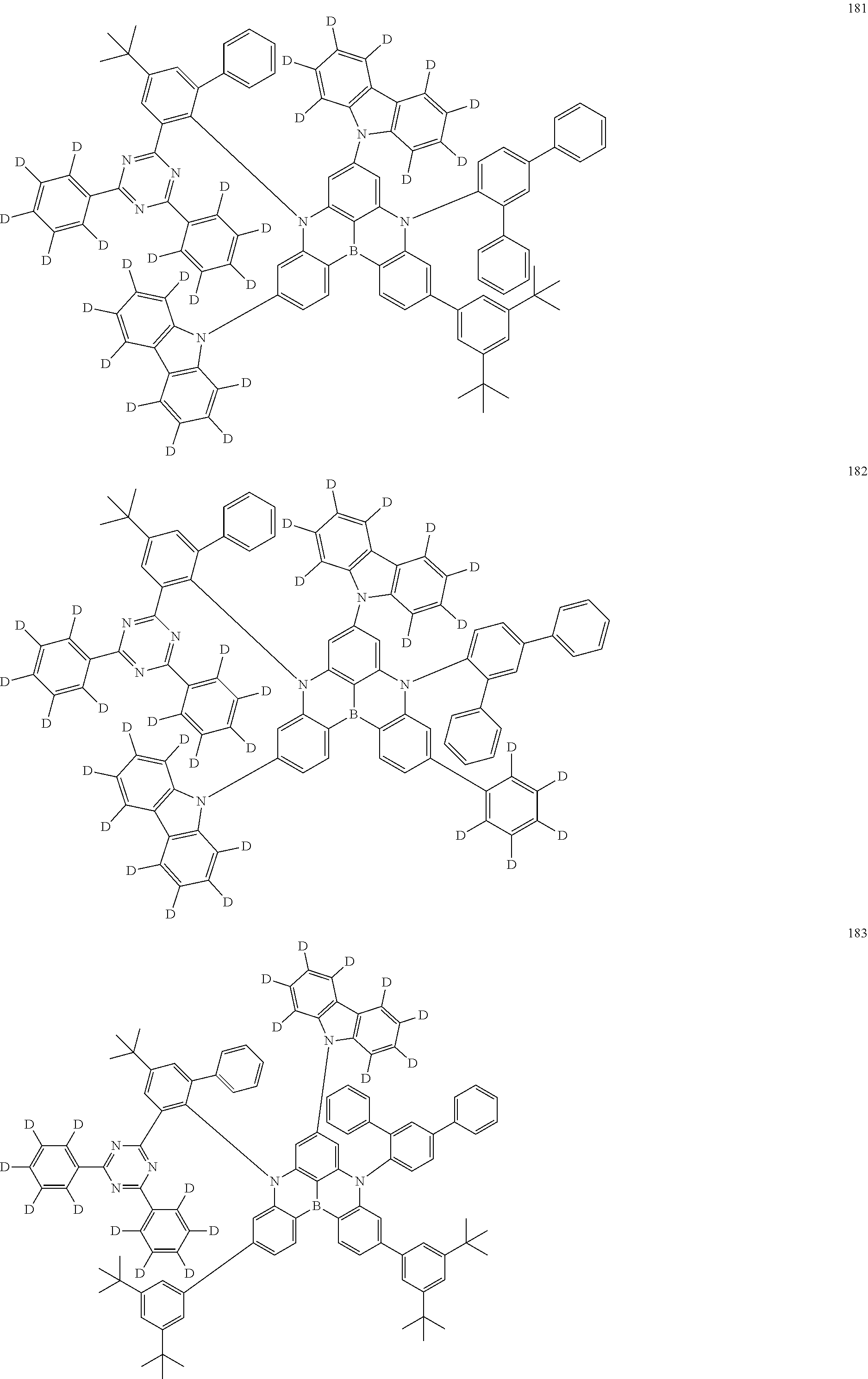

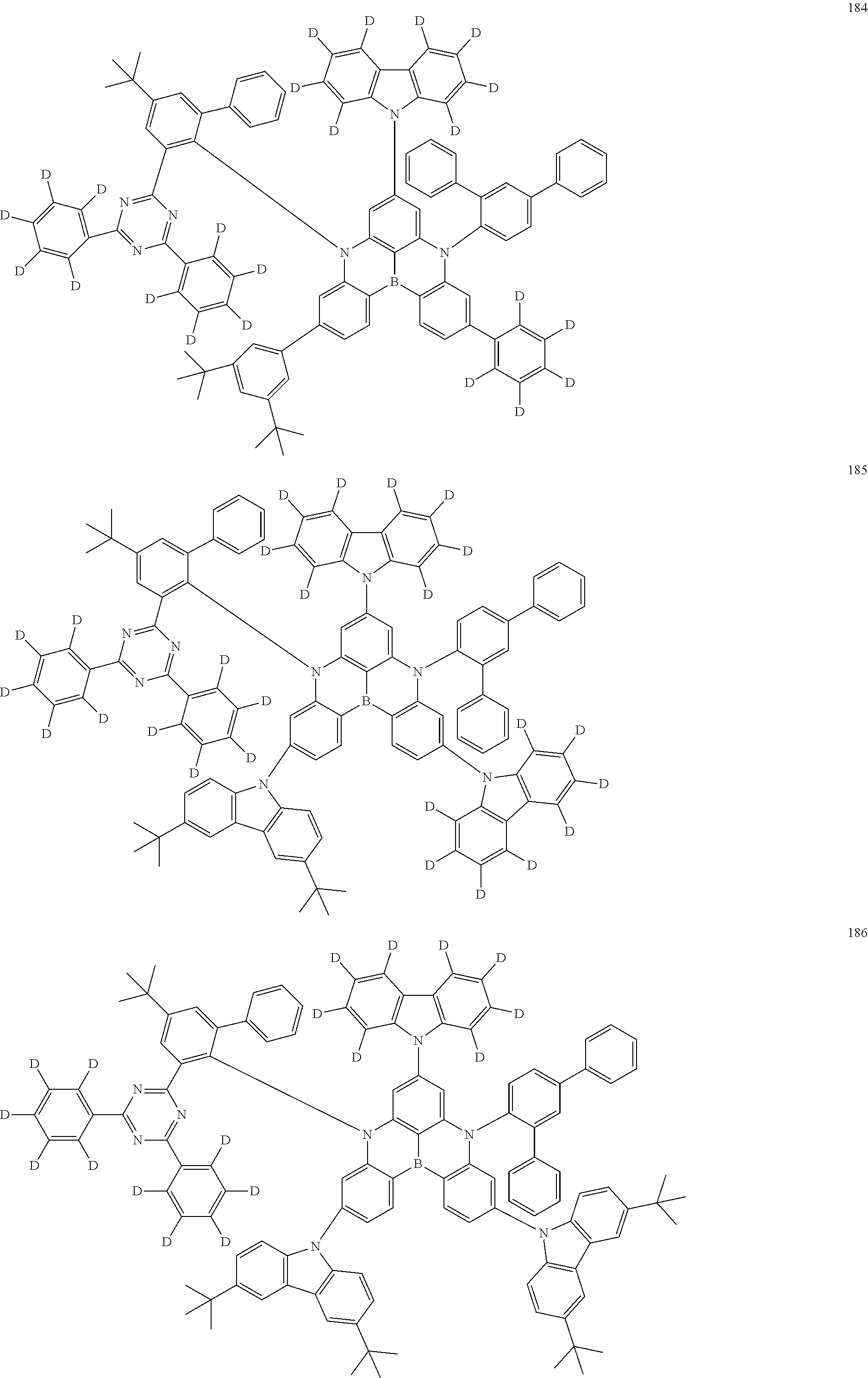

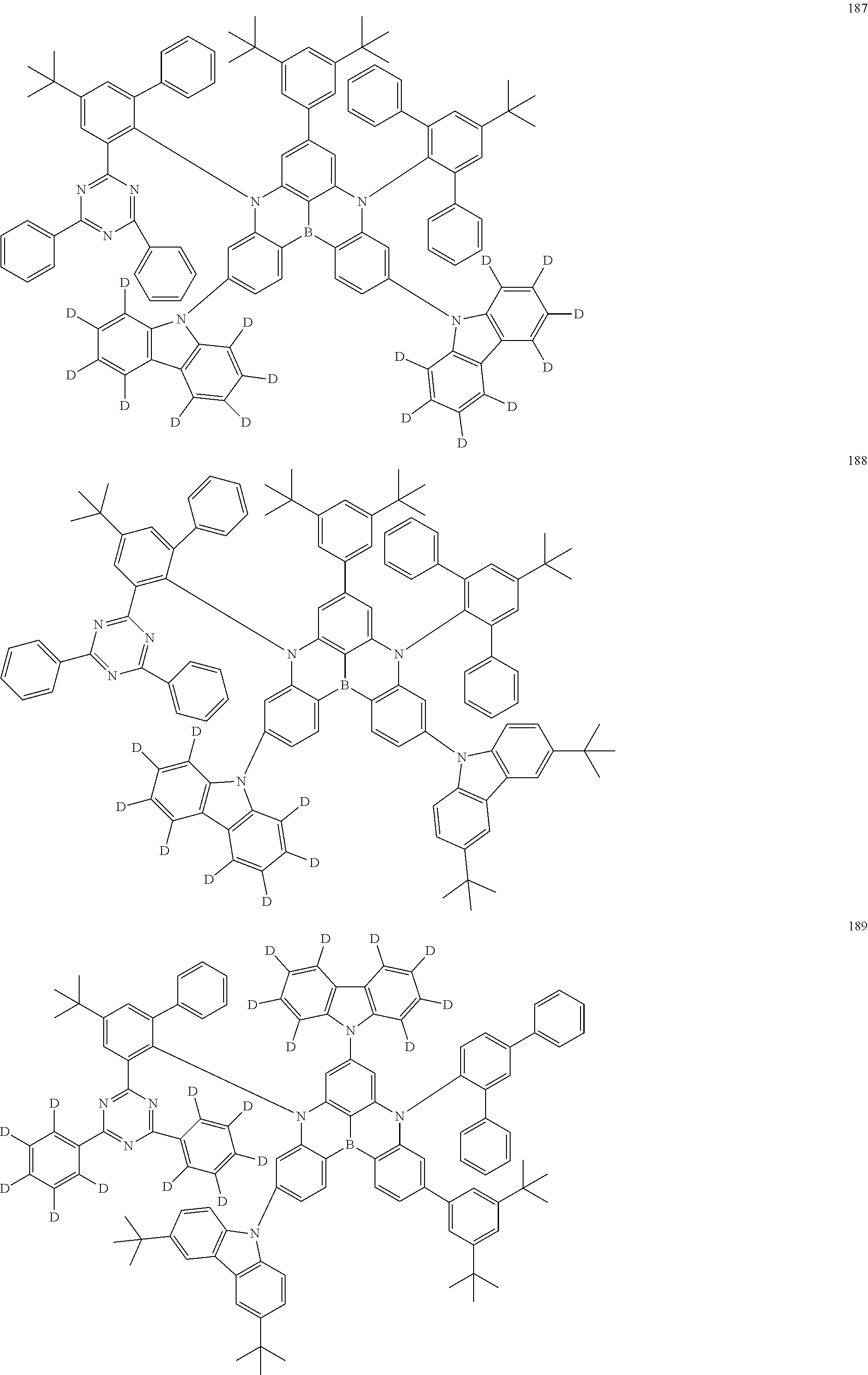

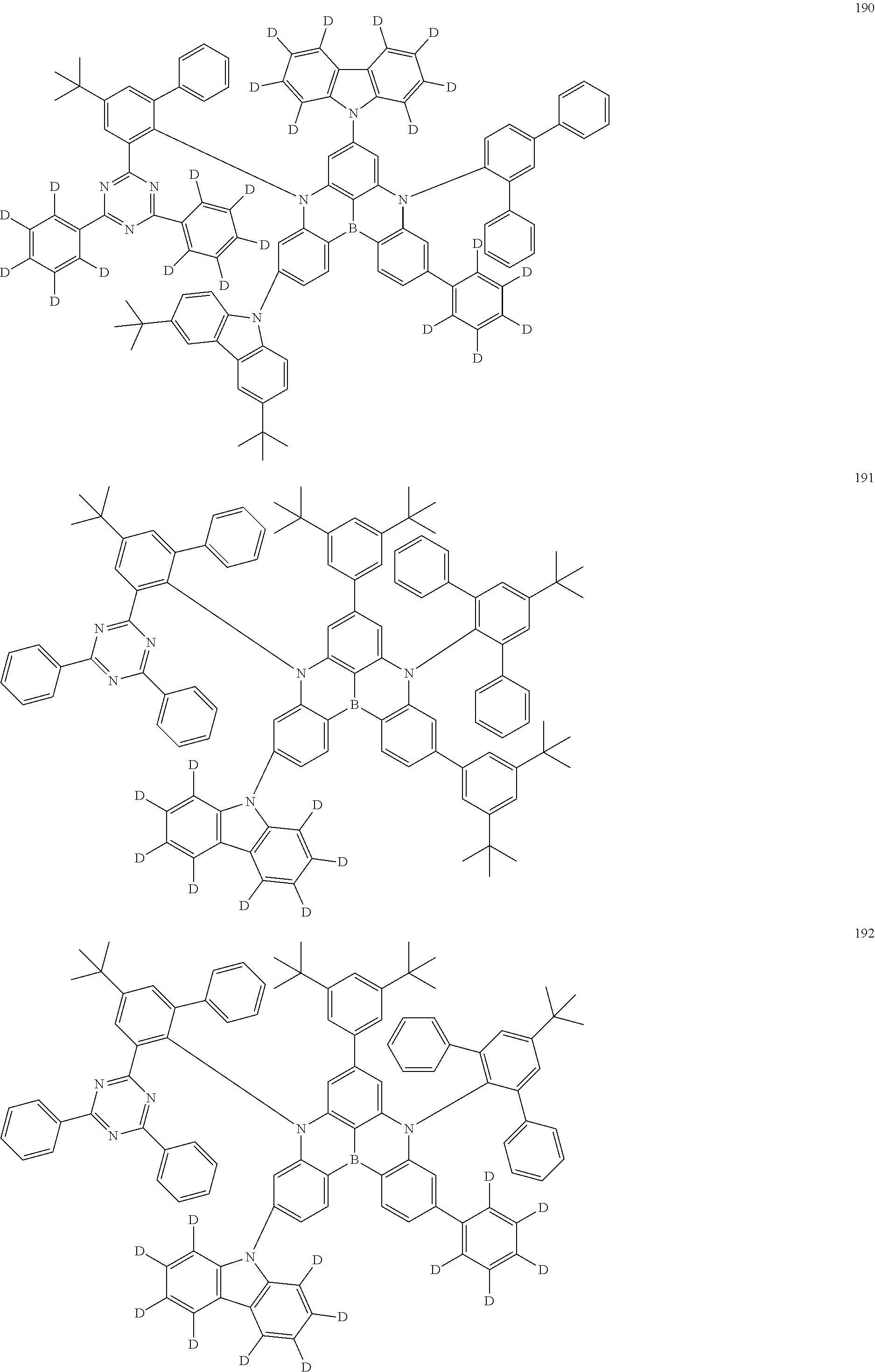

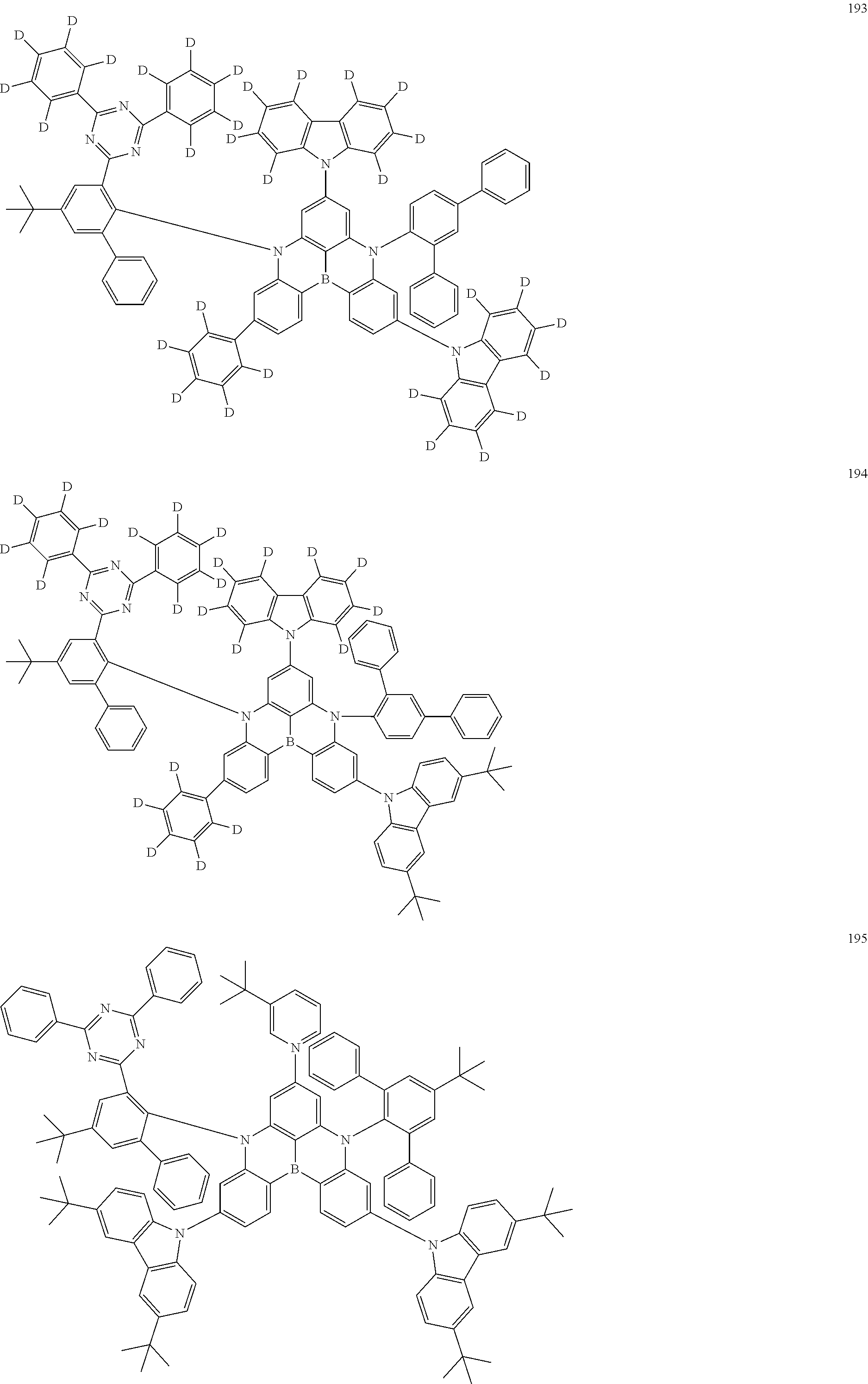

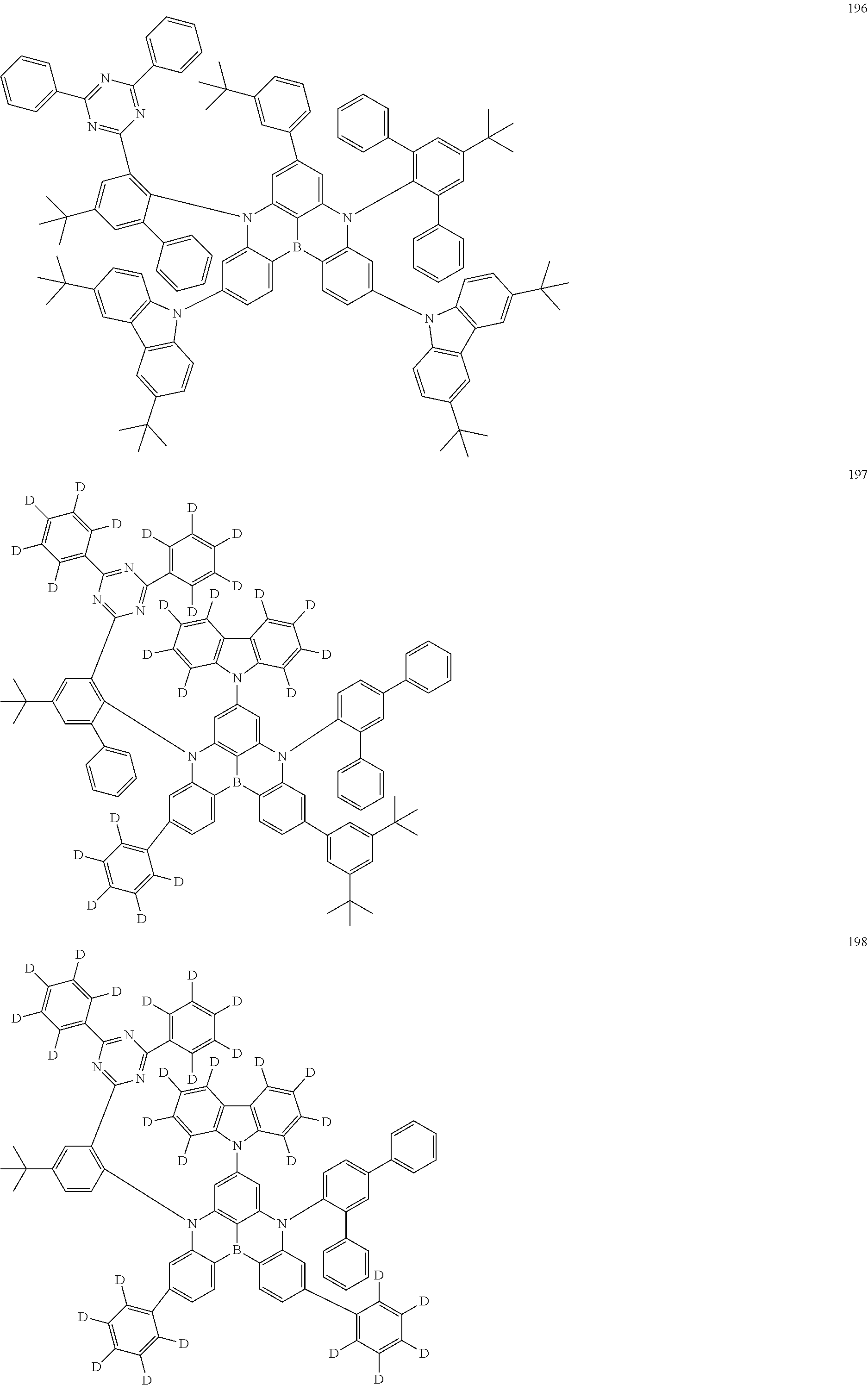

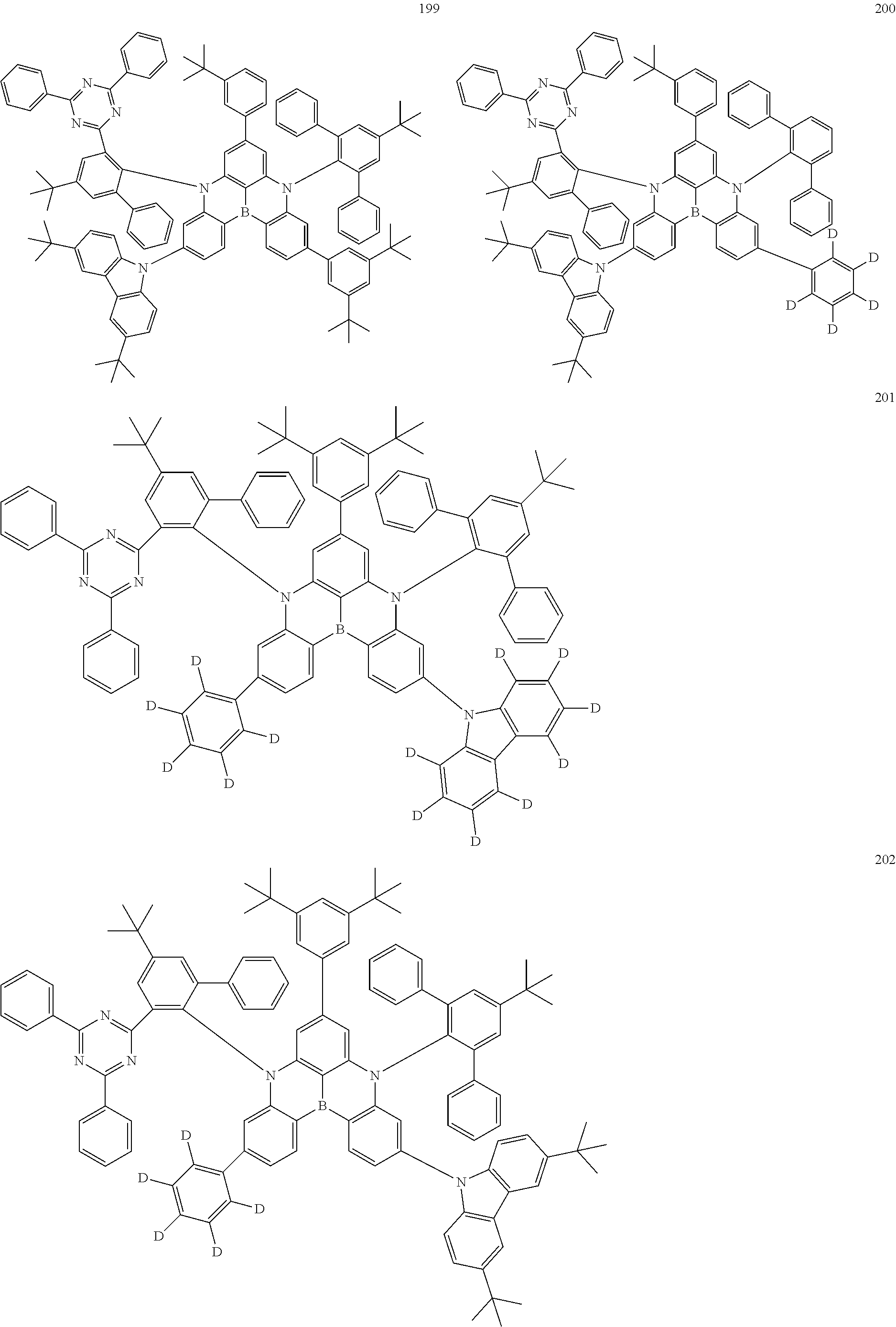

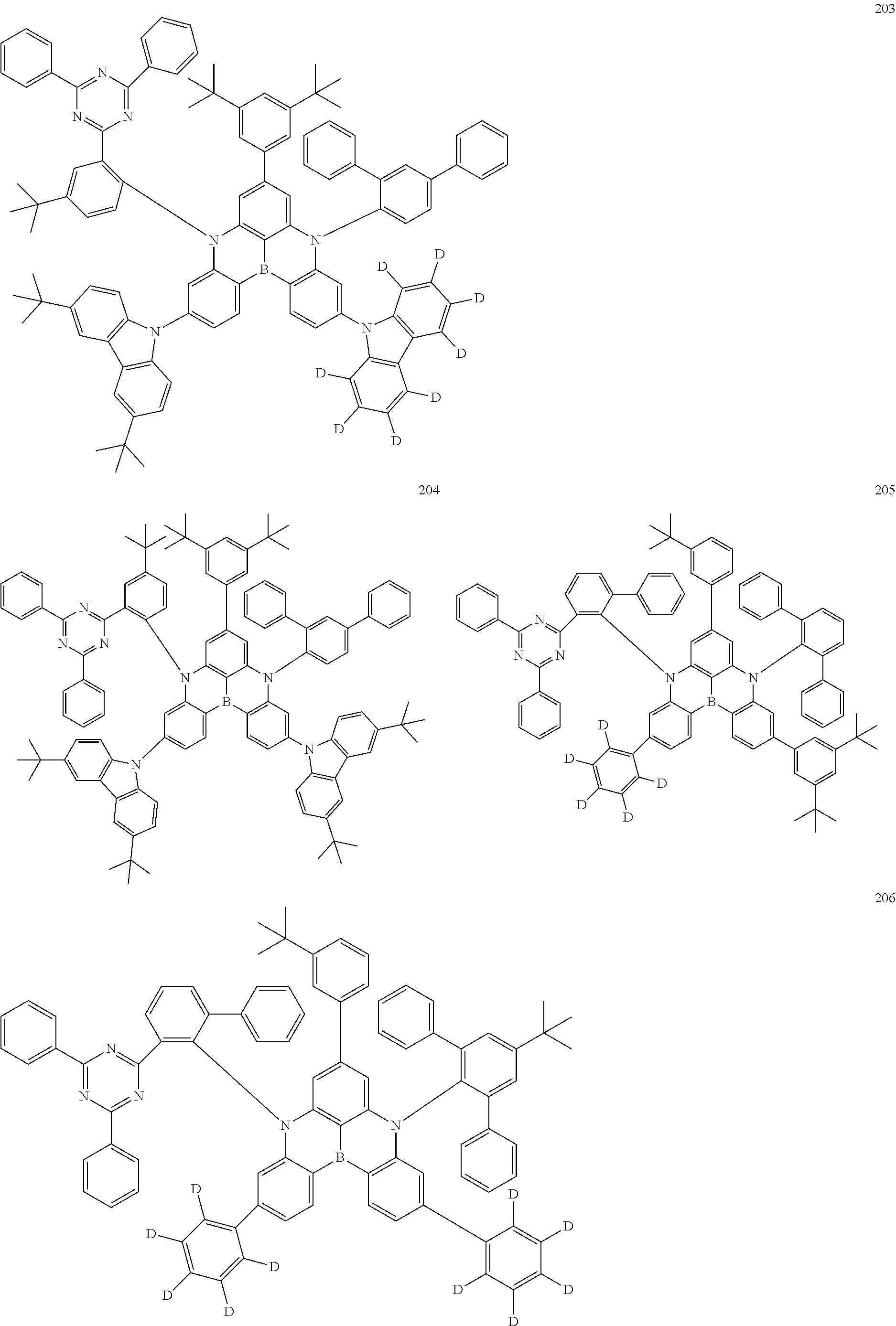

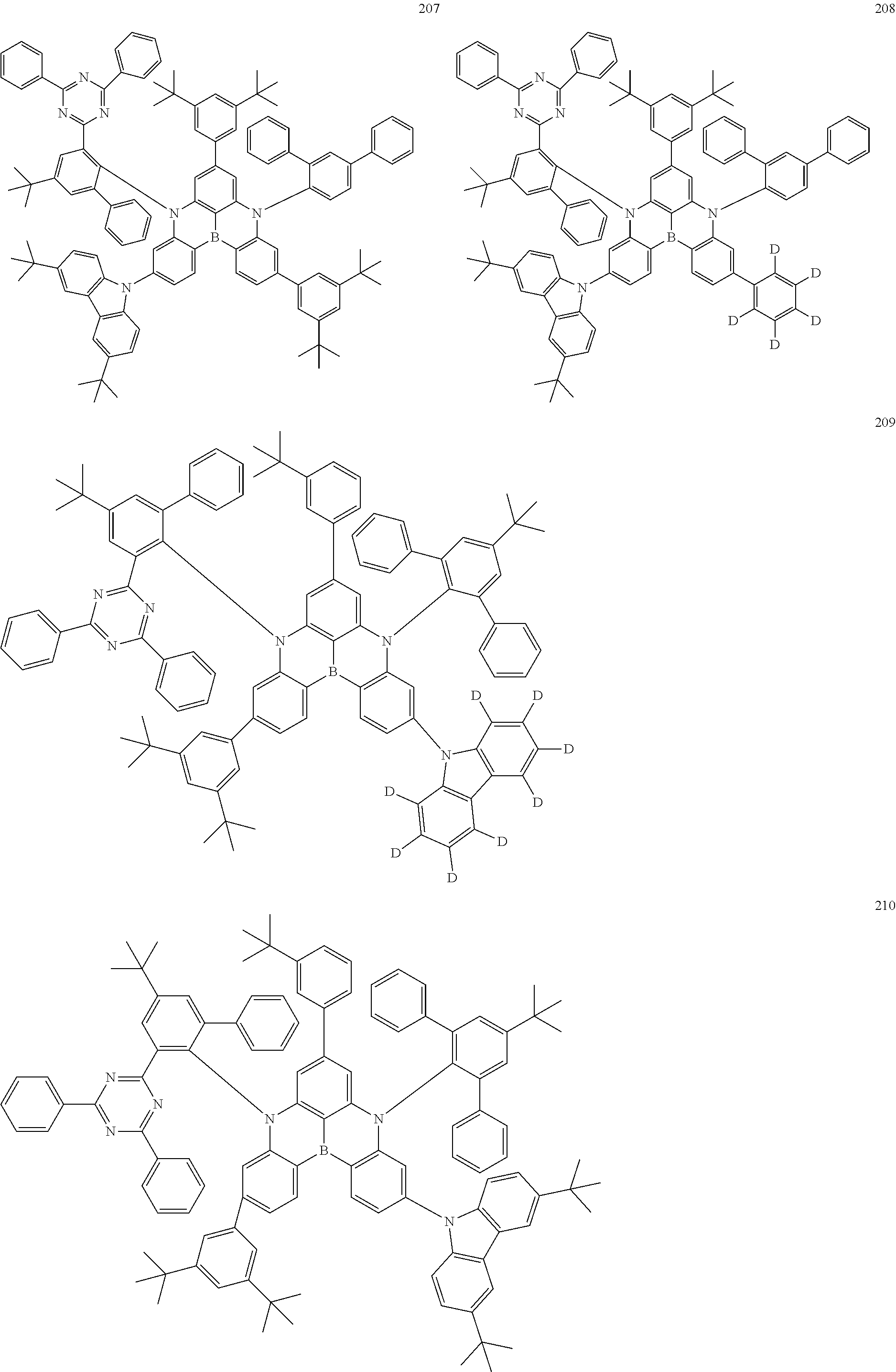

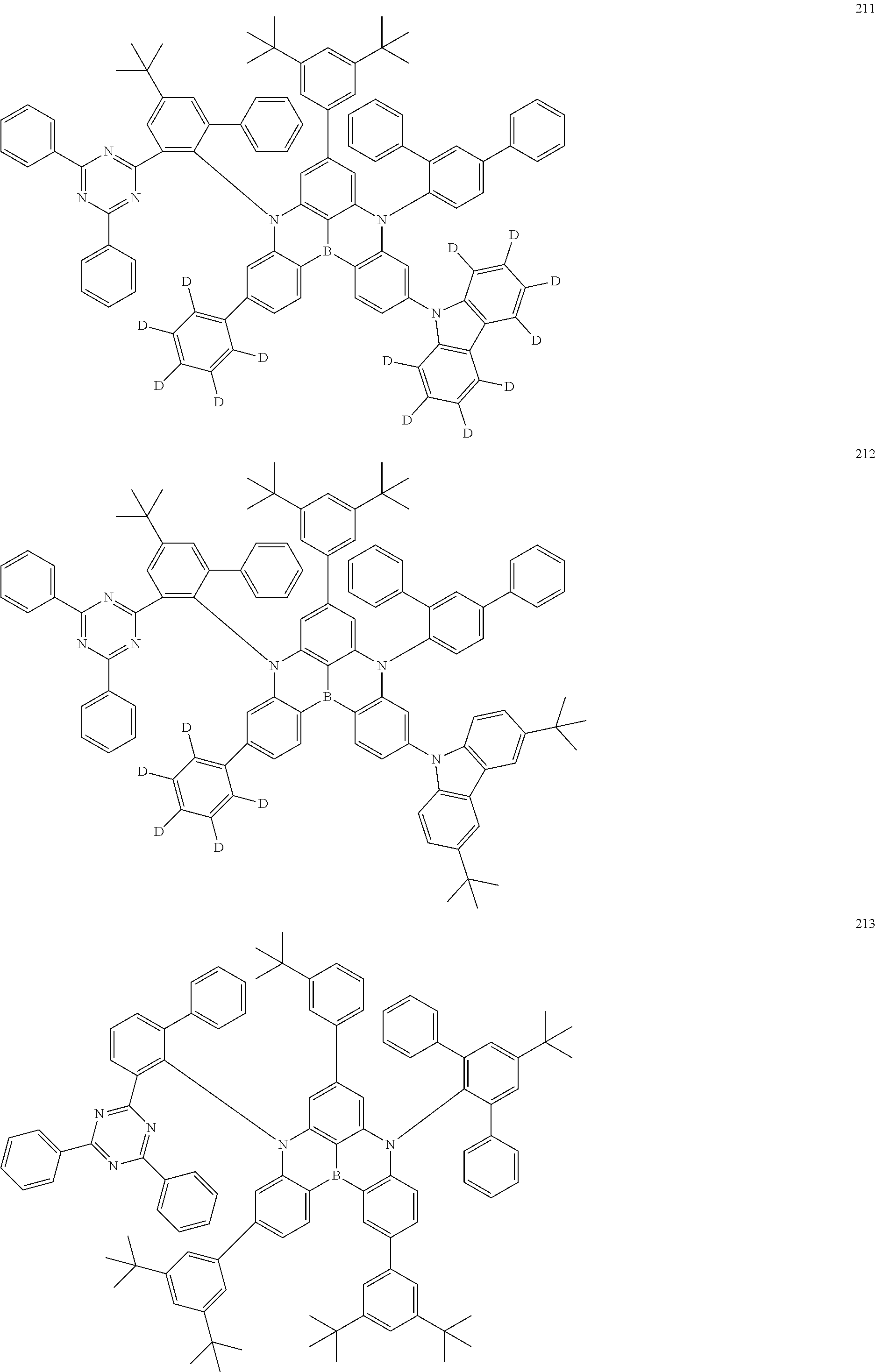

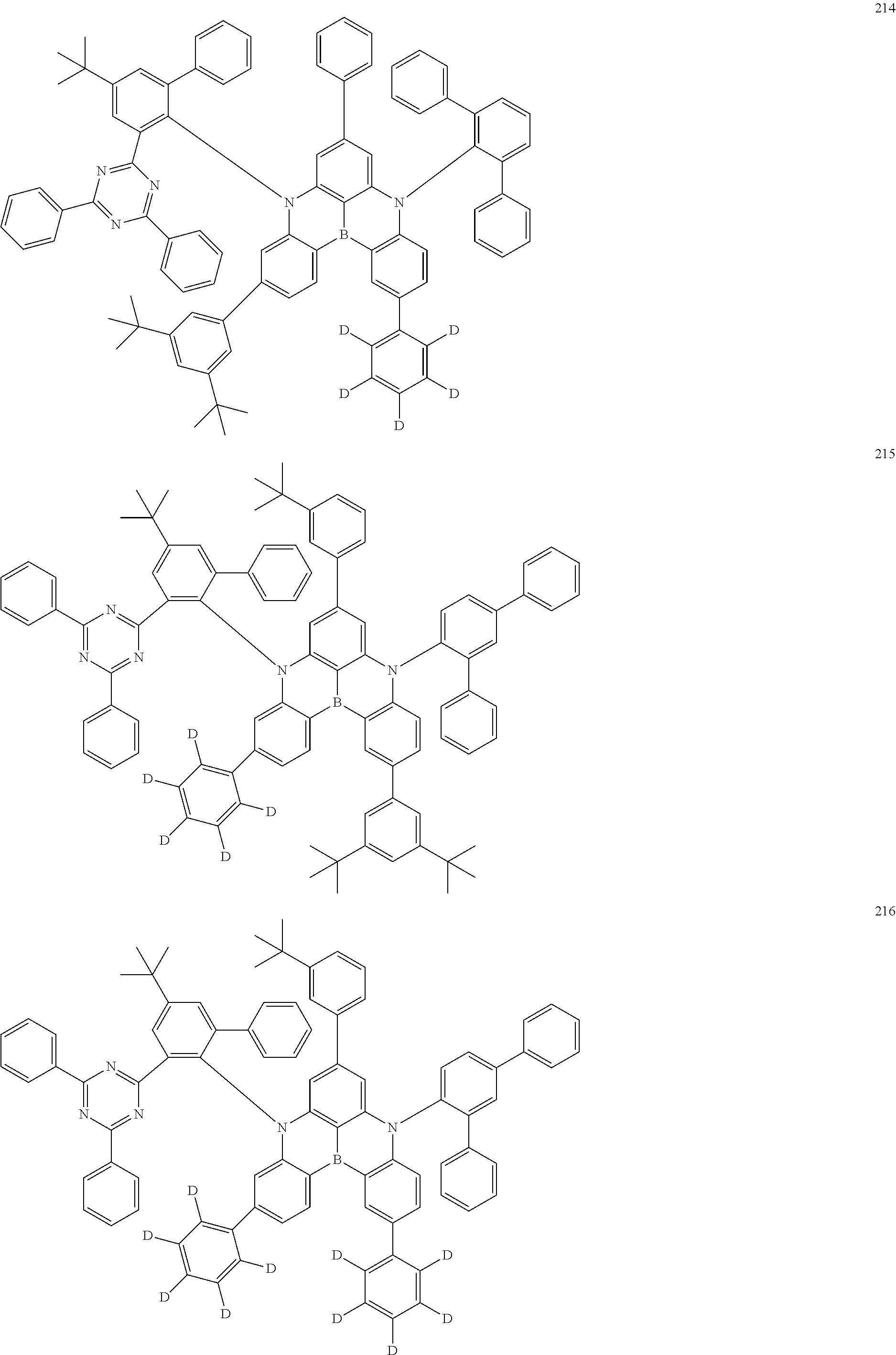

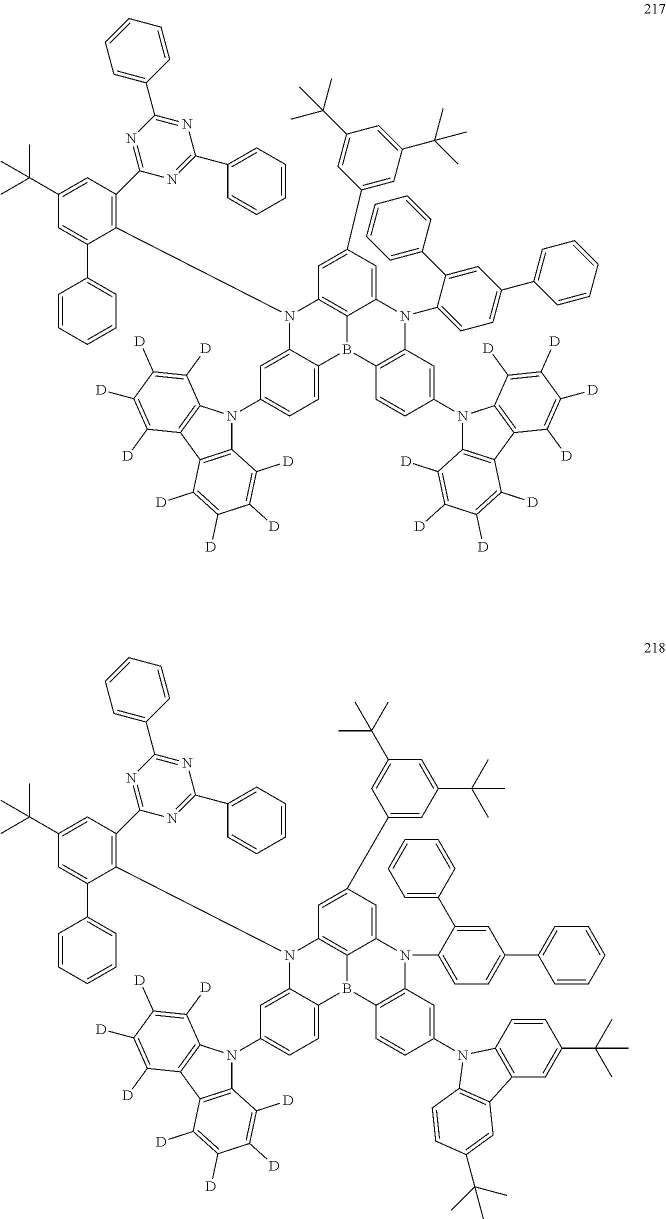

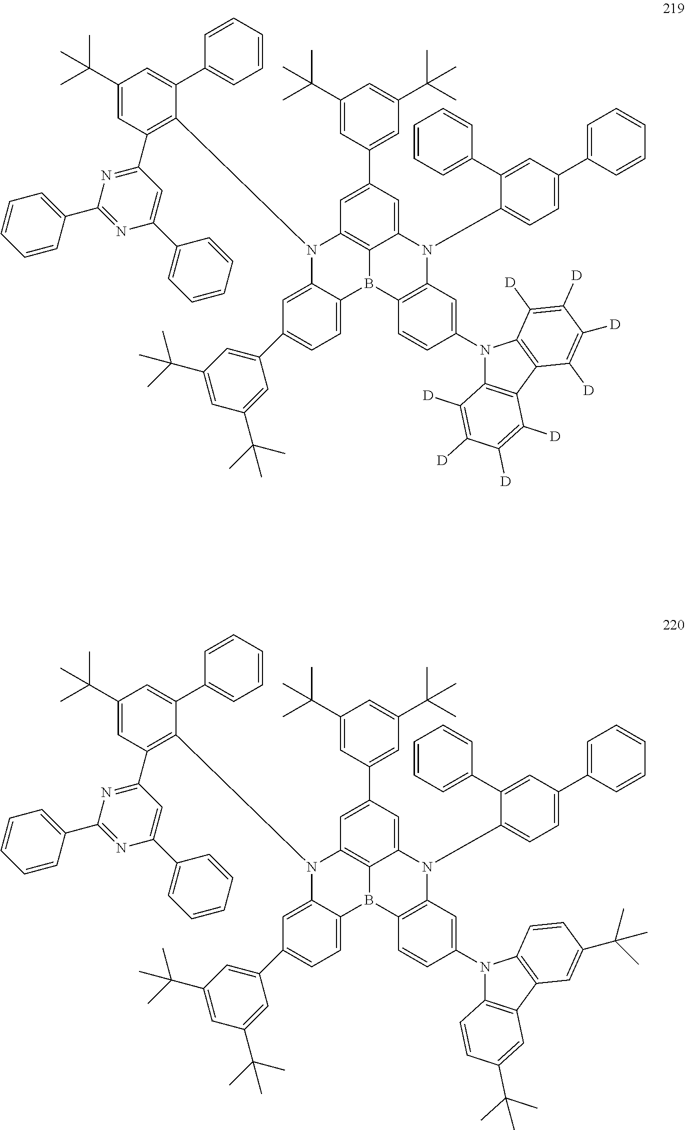 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(-c3cc(C(C)(C)C)cc(C(C)(C)C)c3)cc3c1B2c1ccc(-c2cc(C(C)(C)C)cc(C(C)(C)C)c2)cc1N3c1c(-c2ccccc2)cc(C(C)(C)C)cc1-c1cc(-c2ccccc2)nc(-c2ccccc2)n1 ; CC(C)(C)c1cc(-c2ccc3c(c2)N(c2c(-c4ccccc4)cc(C(C)(C)C)cc2-c2cc(-c4ccccc4)nc(-c4ccccc4)n2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2ccc(-c3ccccc3)cc2-c2ccccc2)cc(C(C)(C)C)c1]

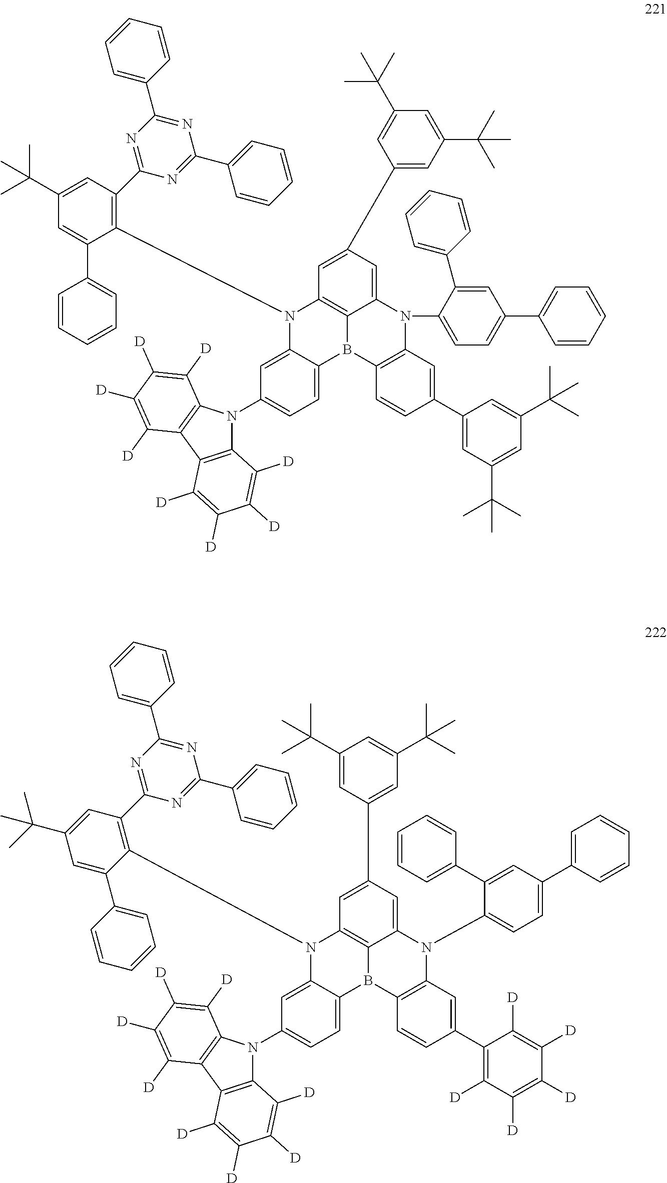

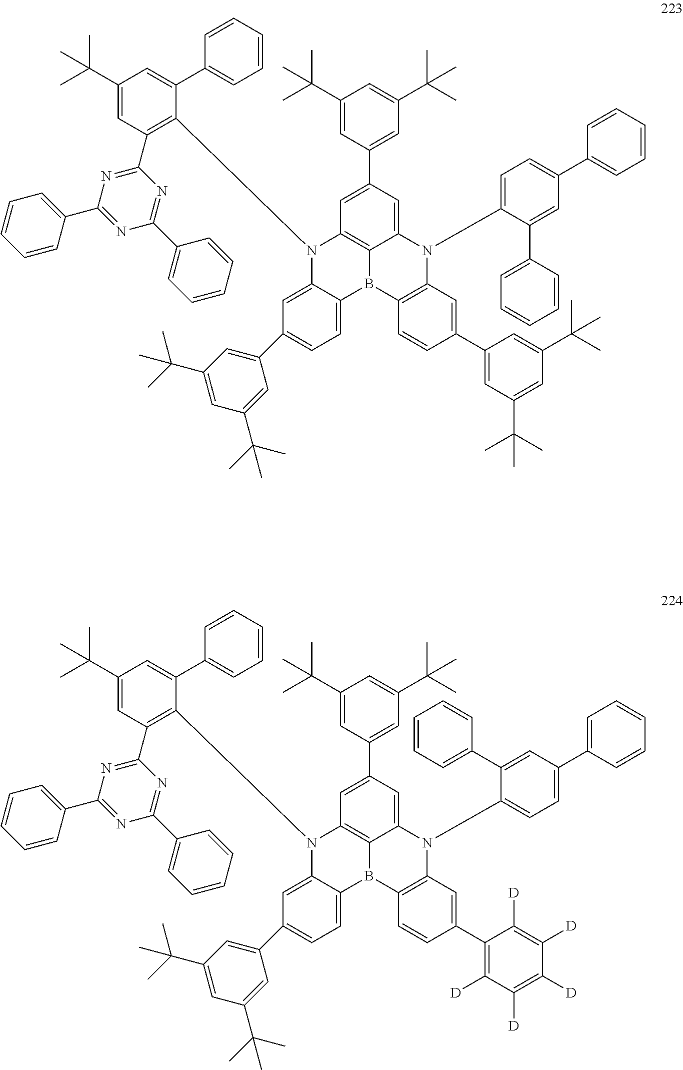 [SMILES: CC(C)(C)c1cc(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)c([2H])c1[2H]]

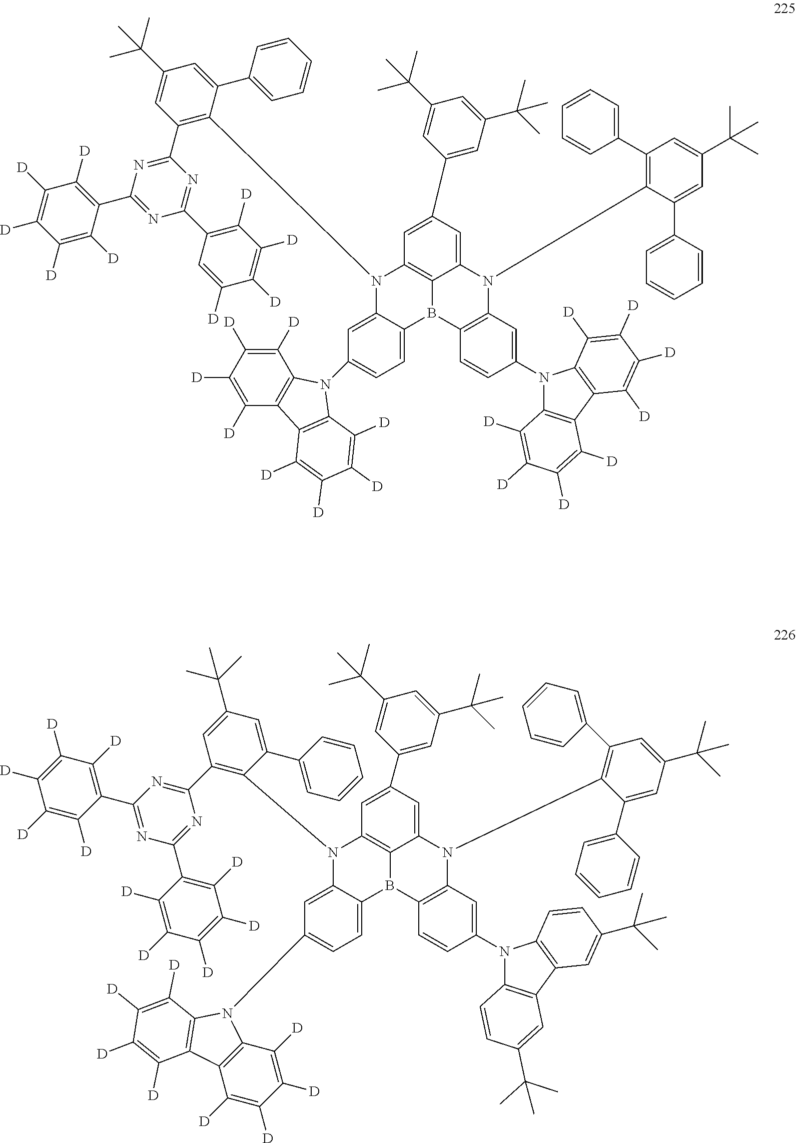

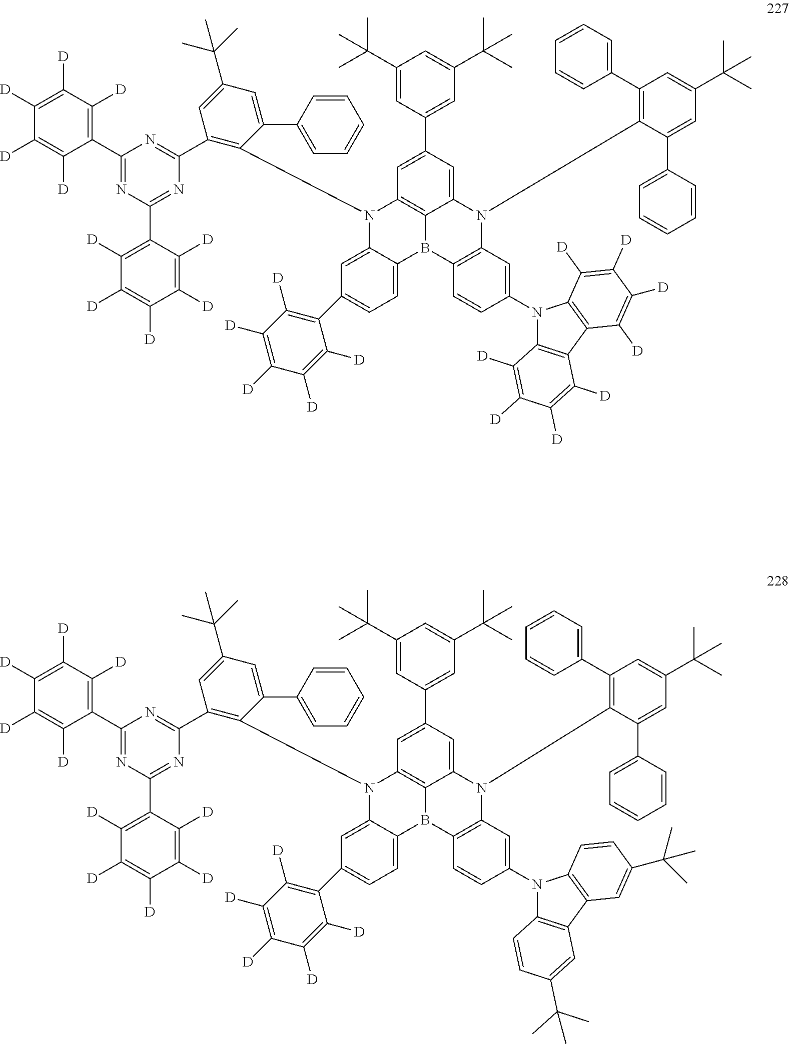

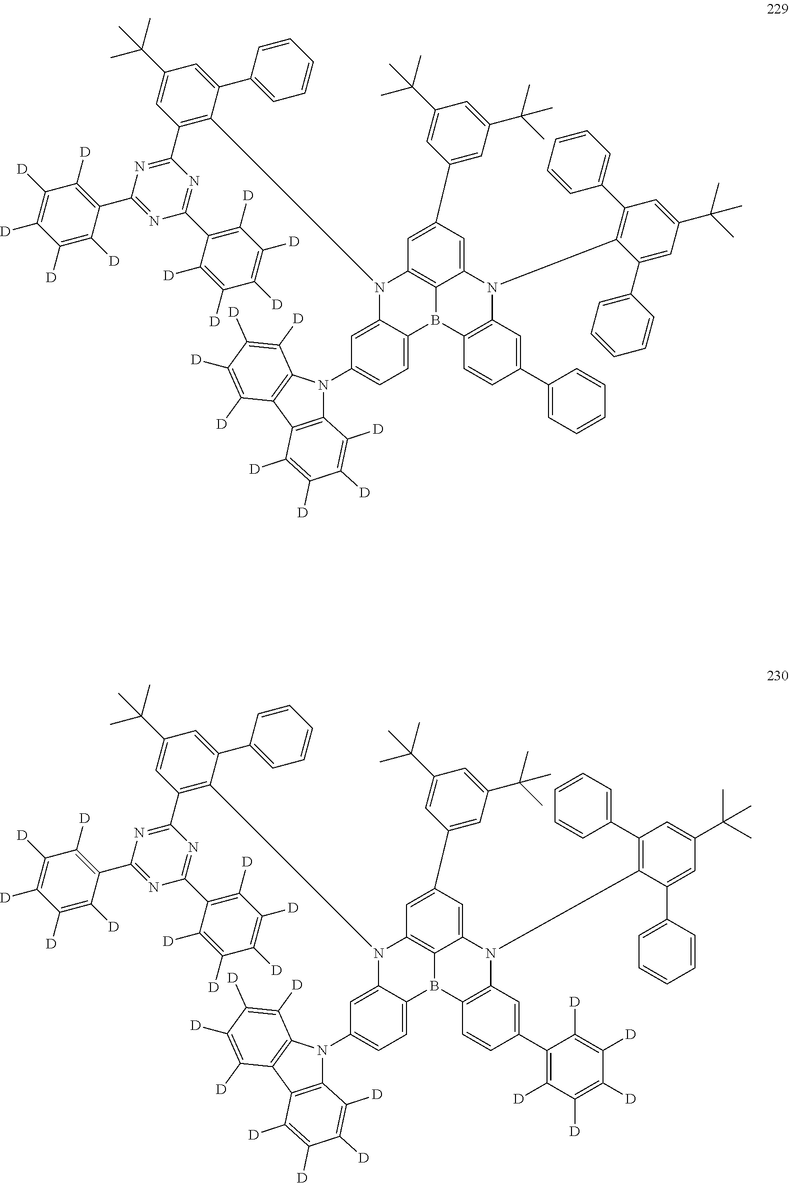

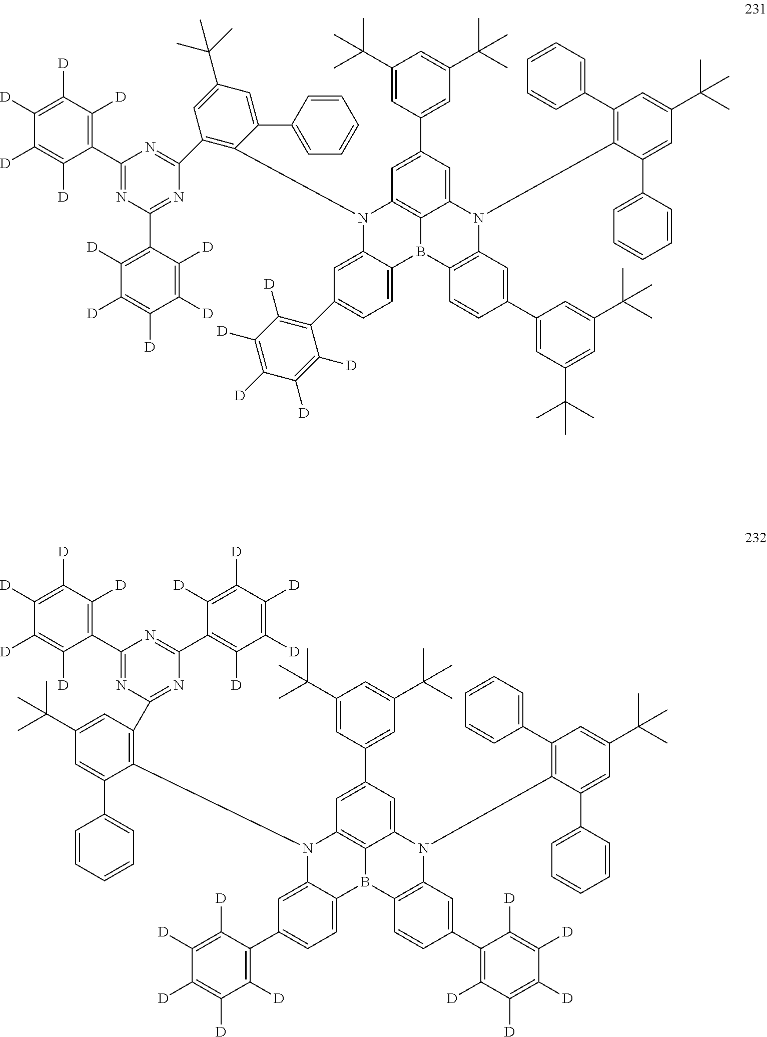

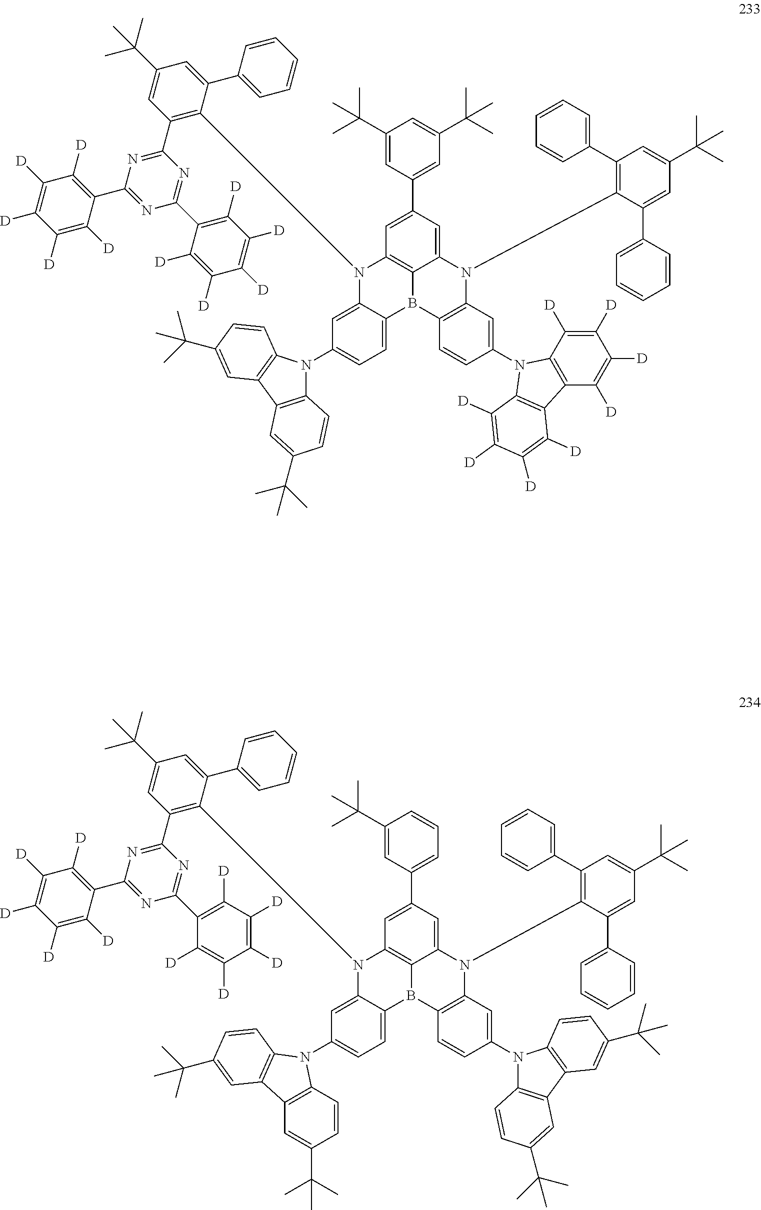

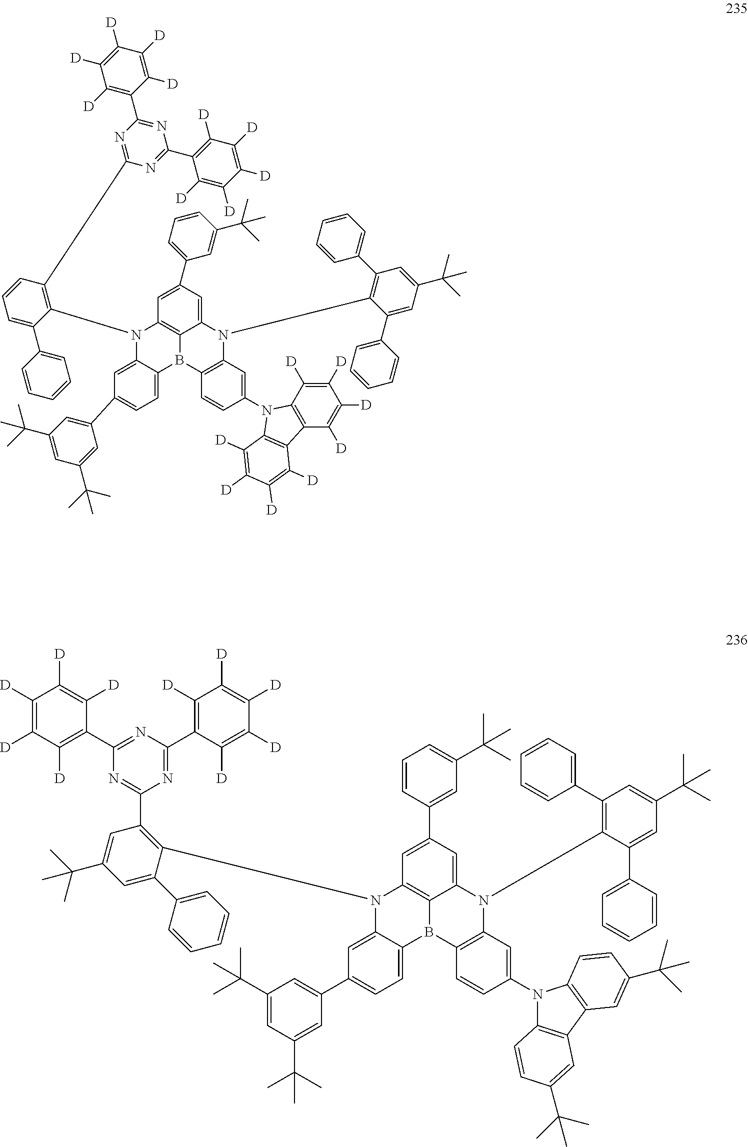

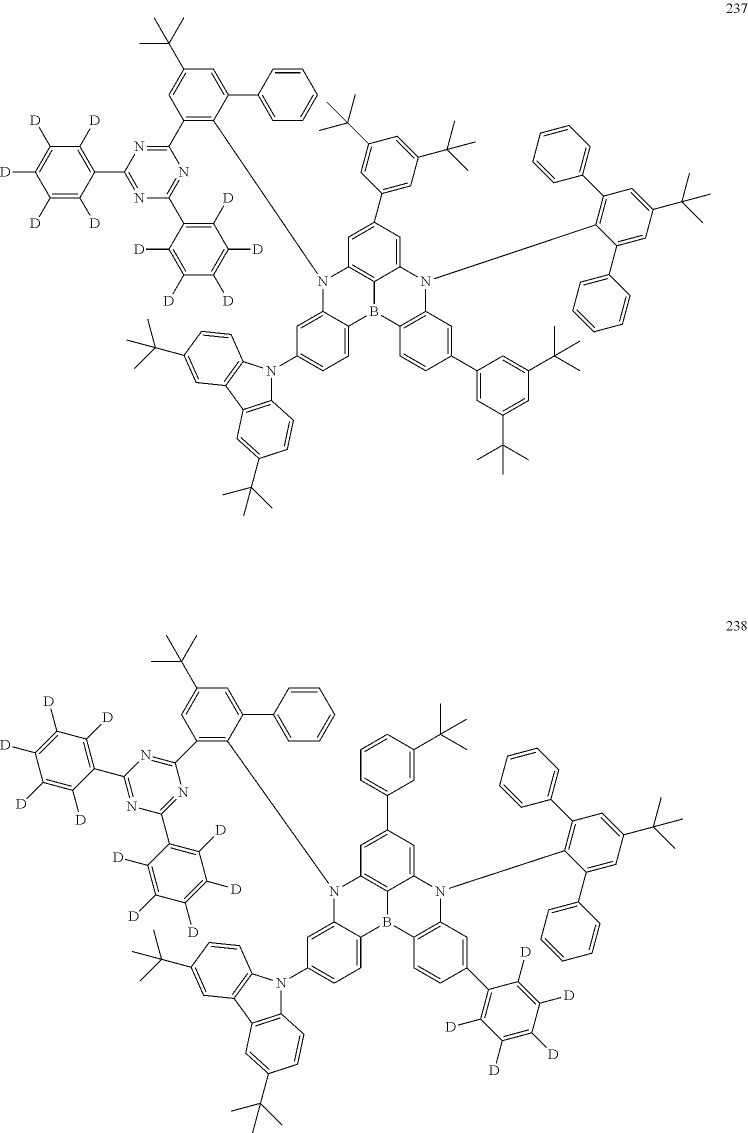

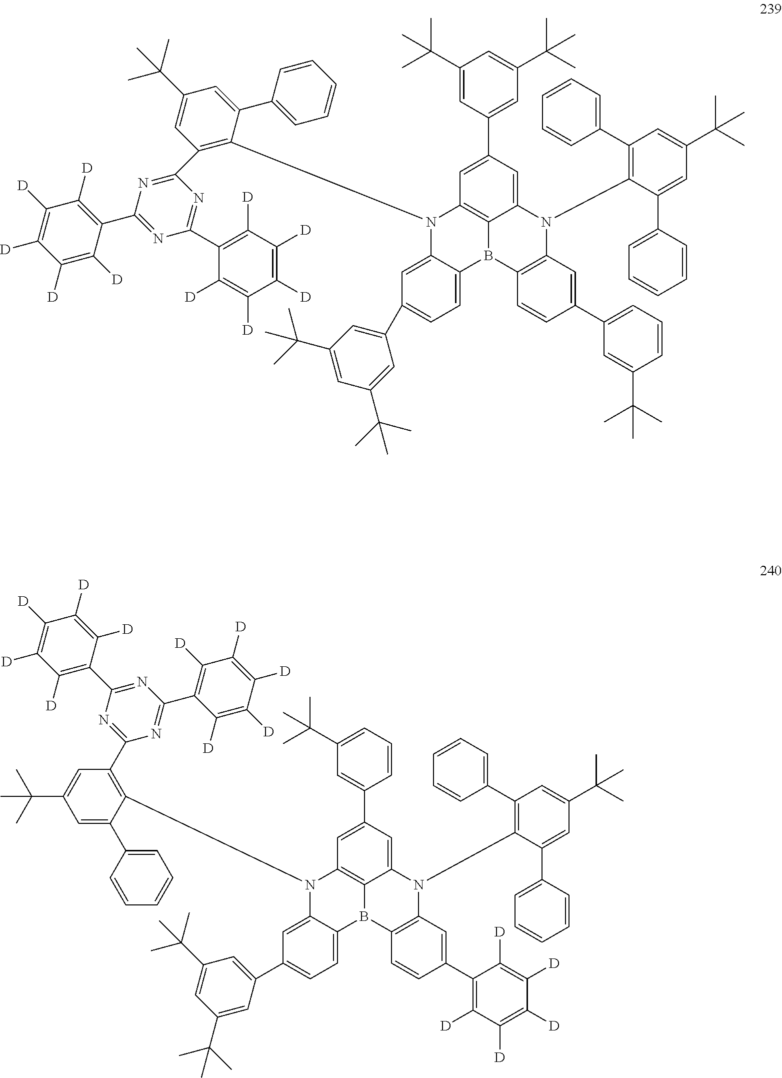

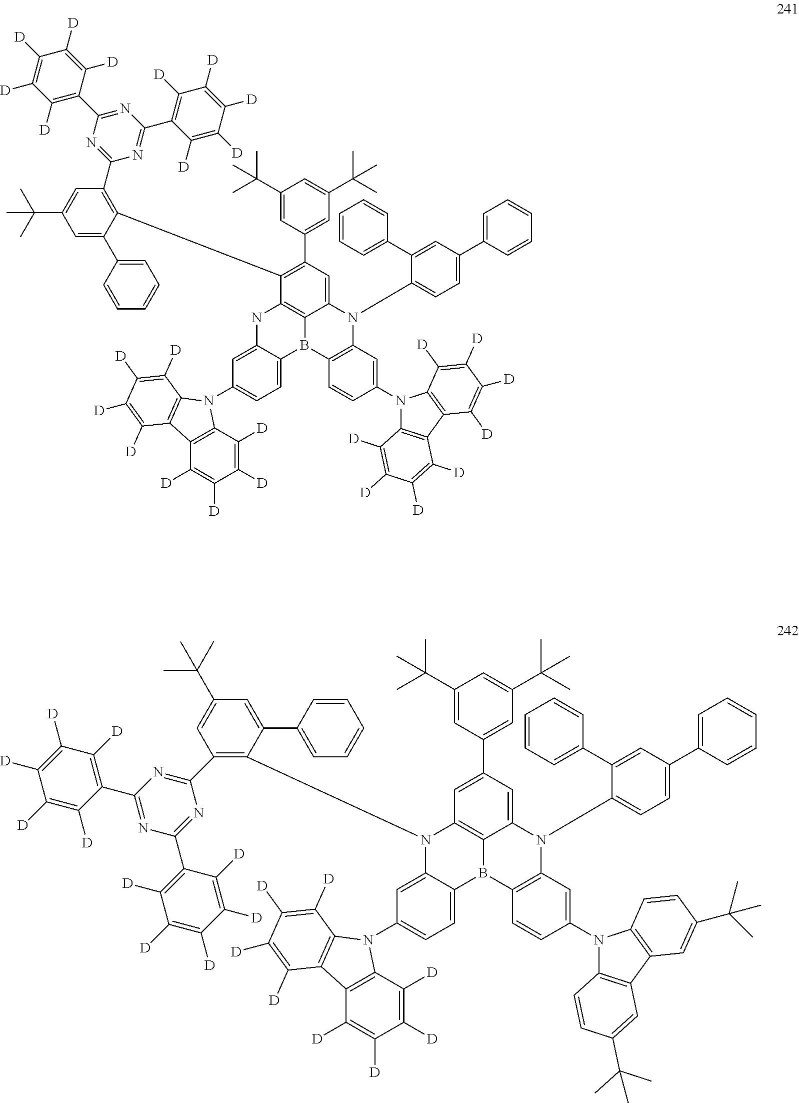

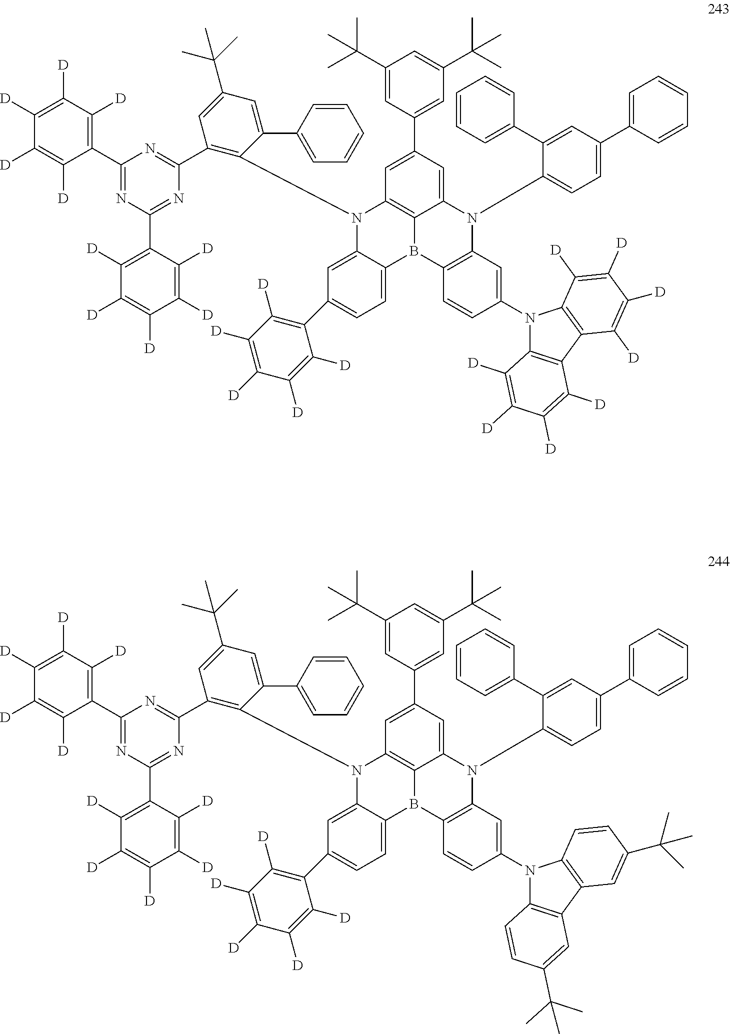

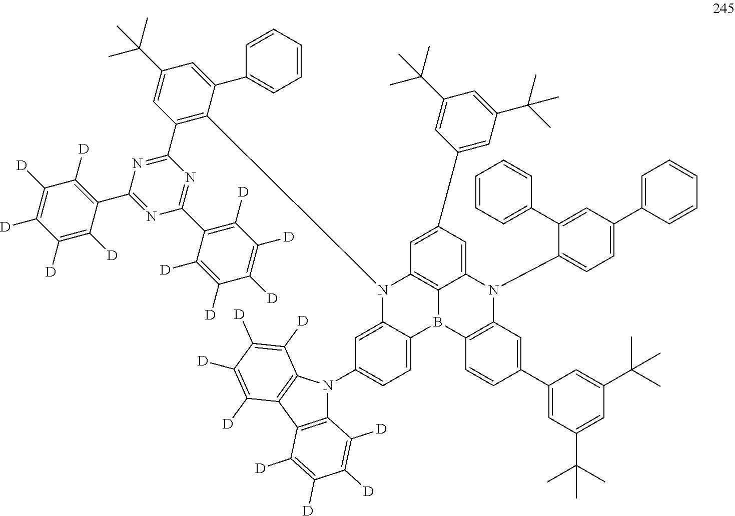 [SMILES: [2H]c1c([2H])c([2H])c(-c2nc(-c3cc(C(C)(C)C)cc(-c4ccccc4)c3N3c4cc(-n5c6c([2H])c([2H])c([2H])c([2H])c6c6c([2H])c([2H])c([2H])c([2H])c65)ccc4B4c5ccc(-c6cc(C(C)(C)C)cc(C(C)(C)C)c6)cc5N(c5ccc(-c6ccccc6)cc5-c5ccccc5)c5cc(-c6cc(C(C)(C)C)cc(C(C)(C)C)c6)cc3c54)nc(-c3c([2H])c([2H])c([2H])c([2H])c3[2H])n2)c([2H])c1[2H]]

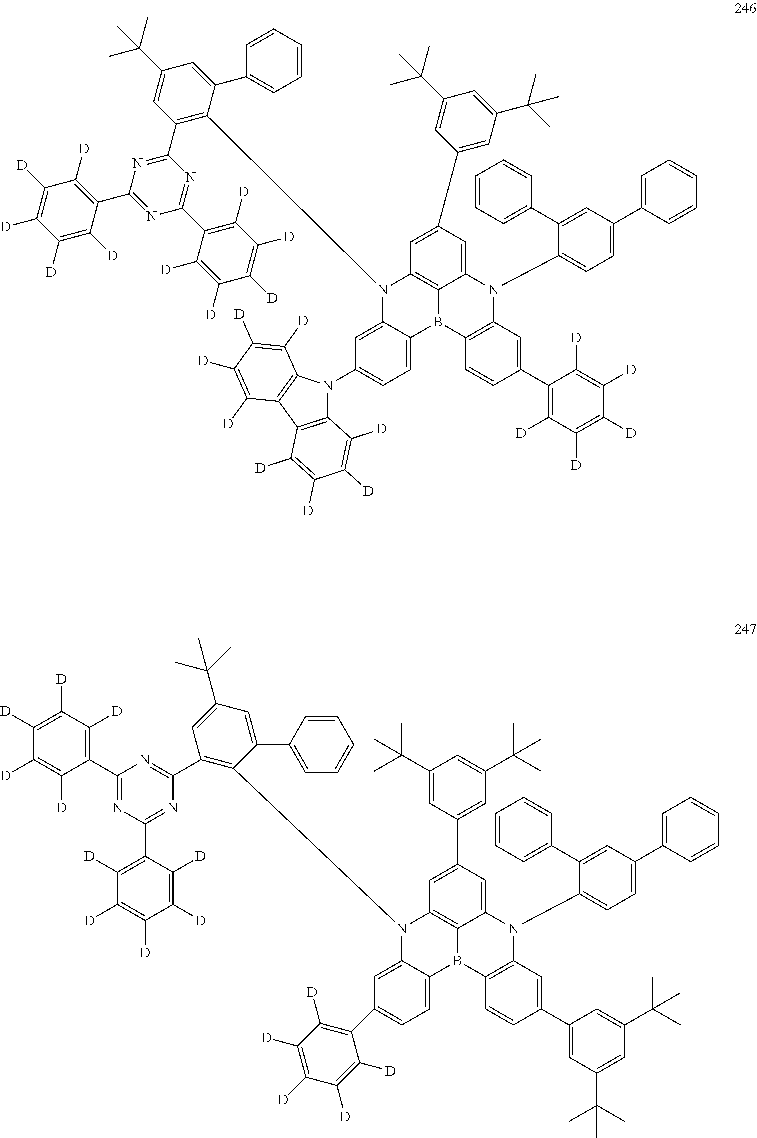

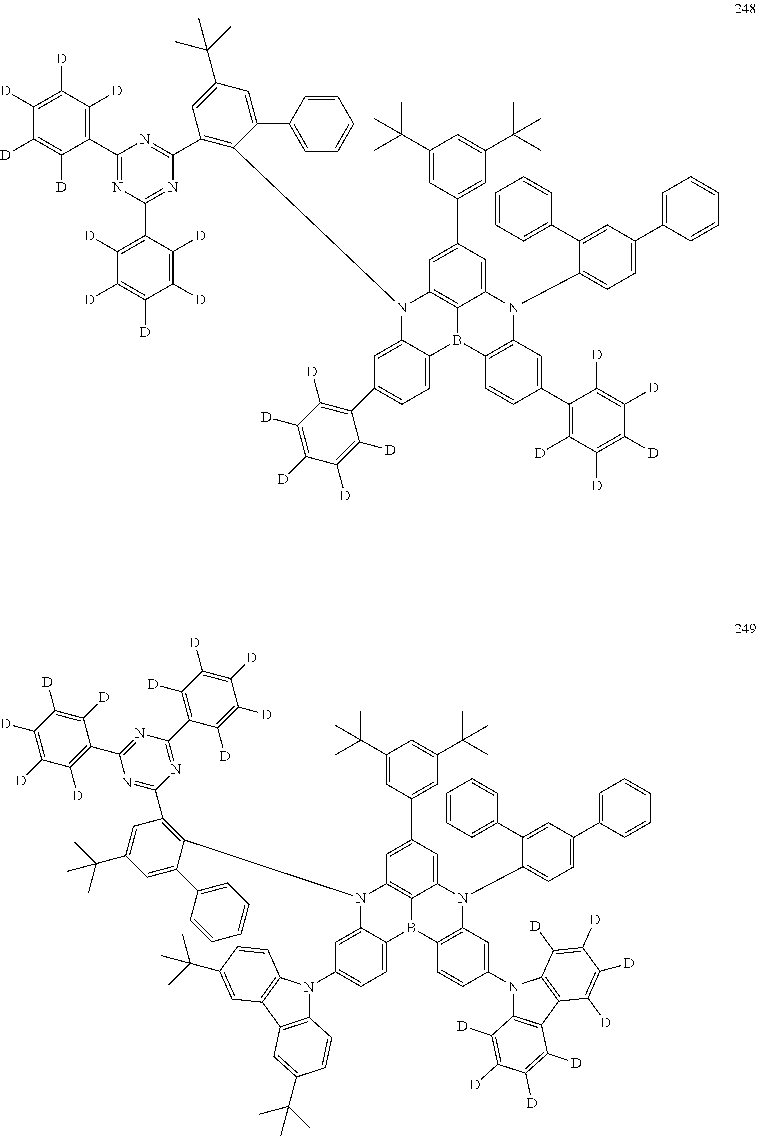

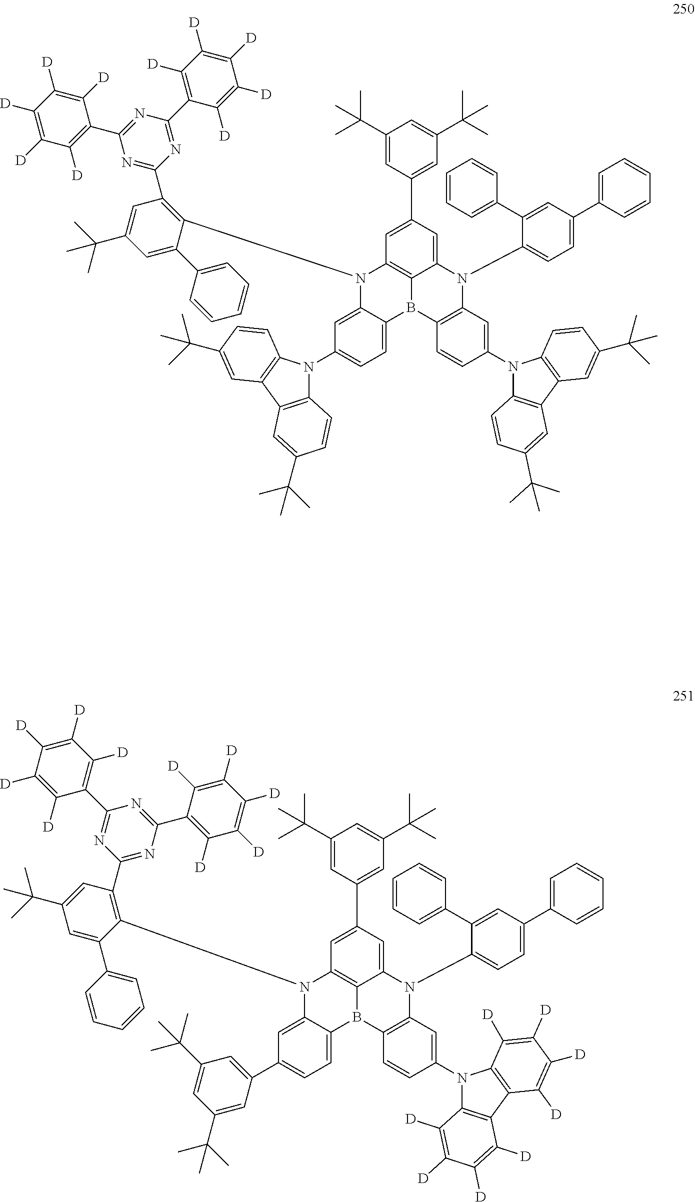

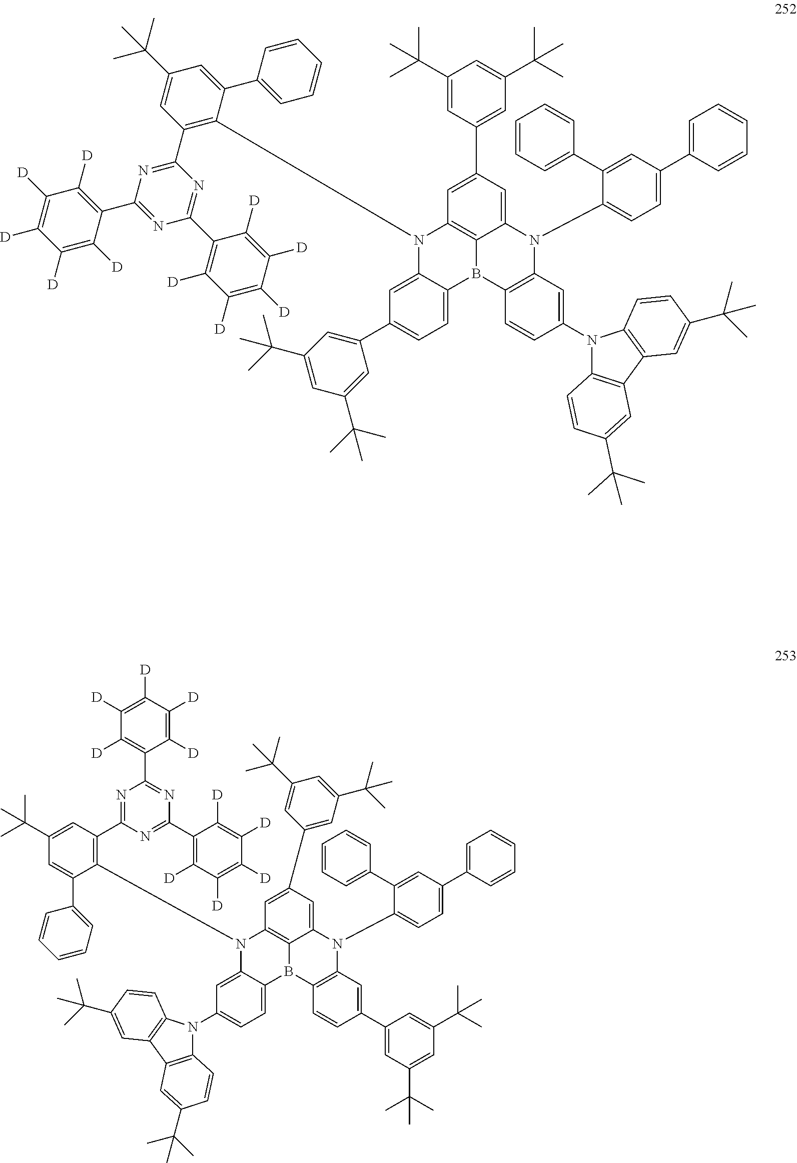

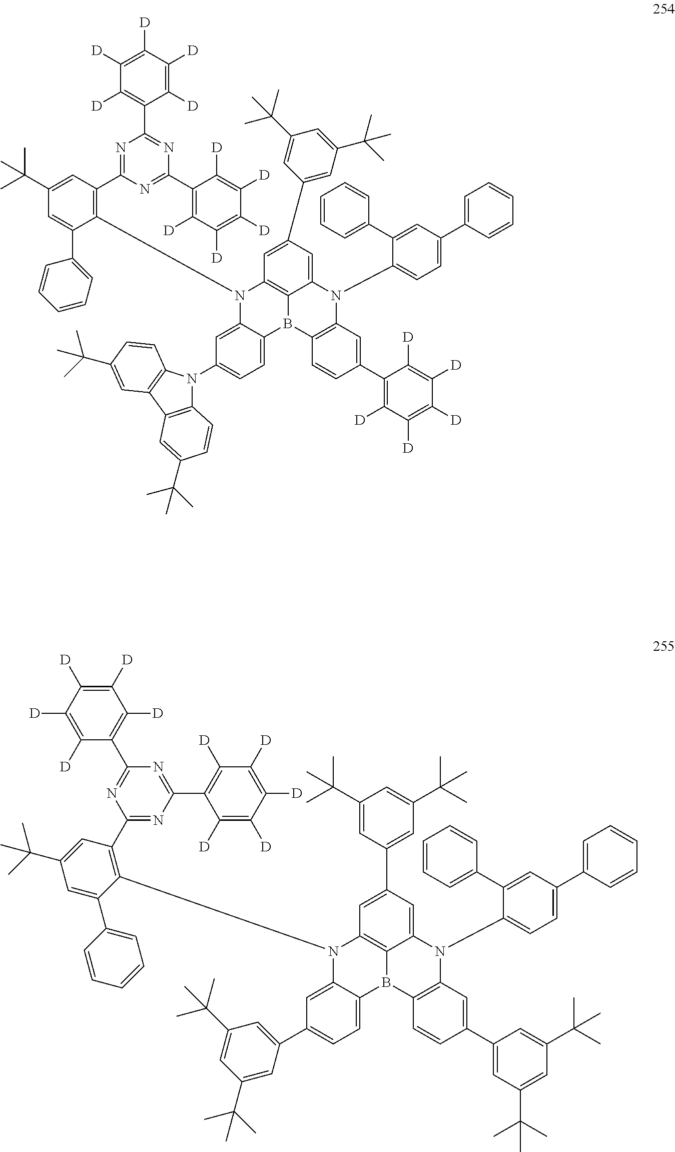

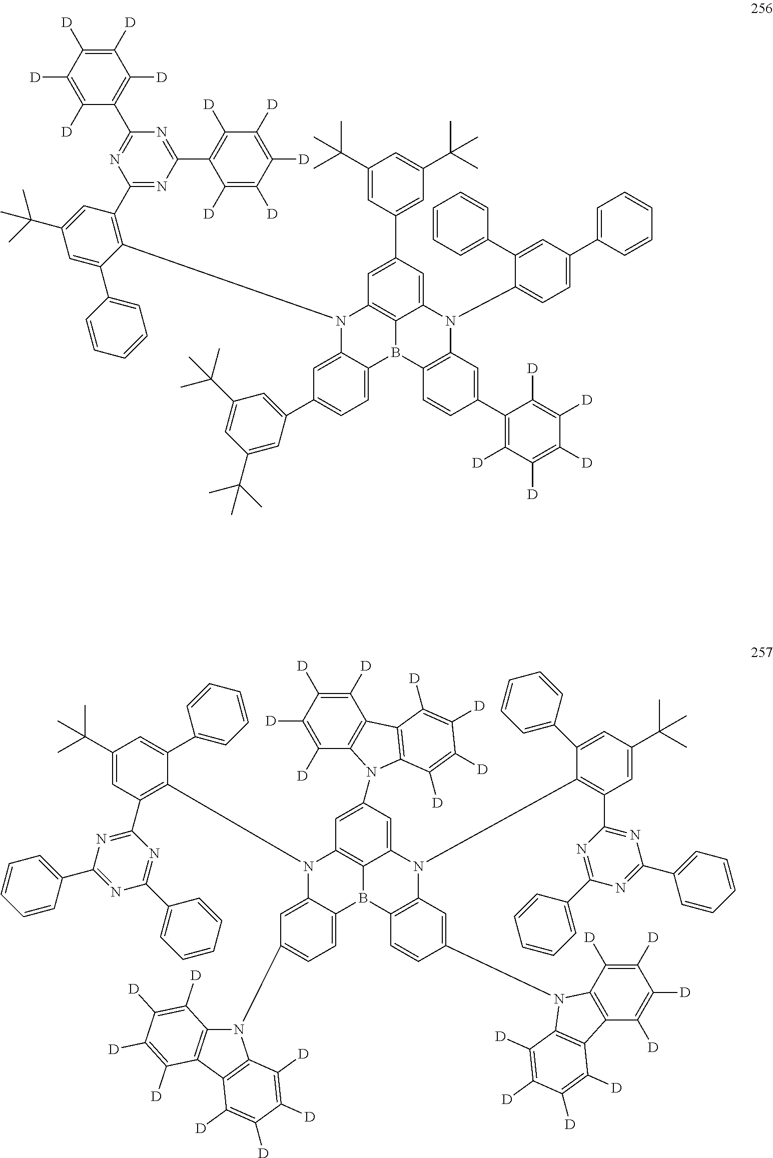

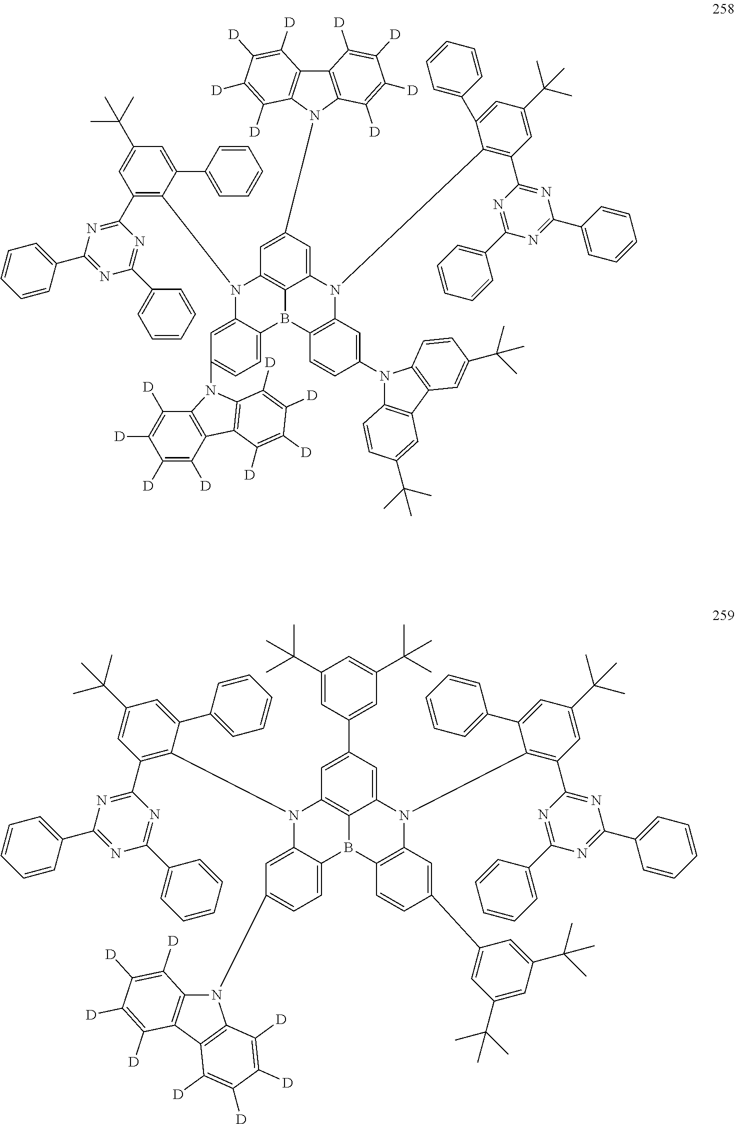

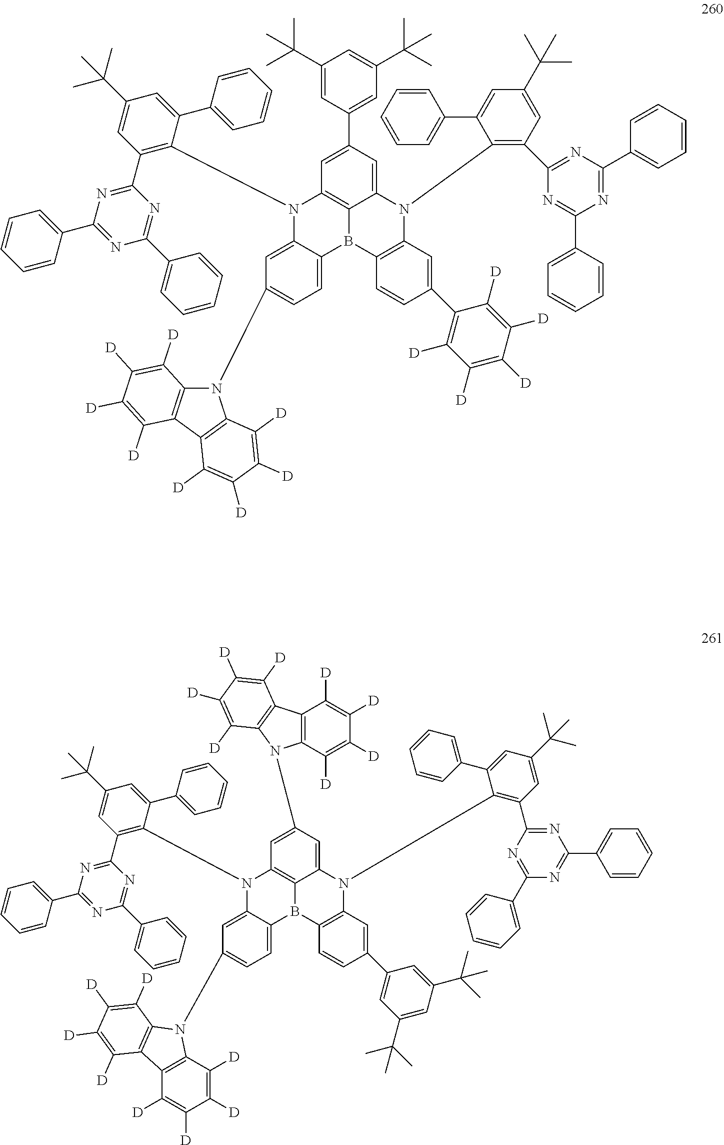

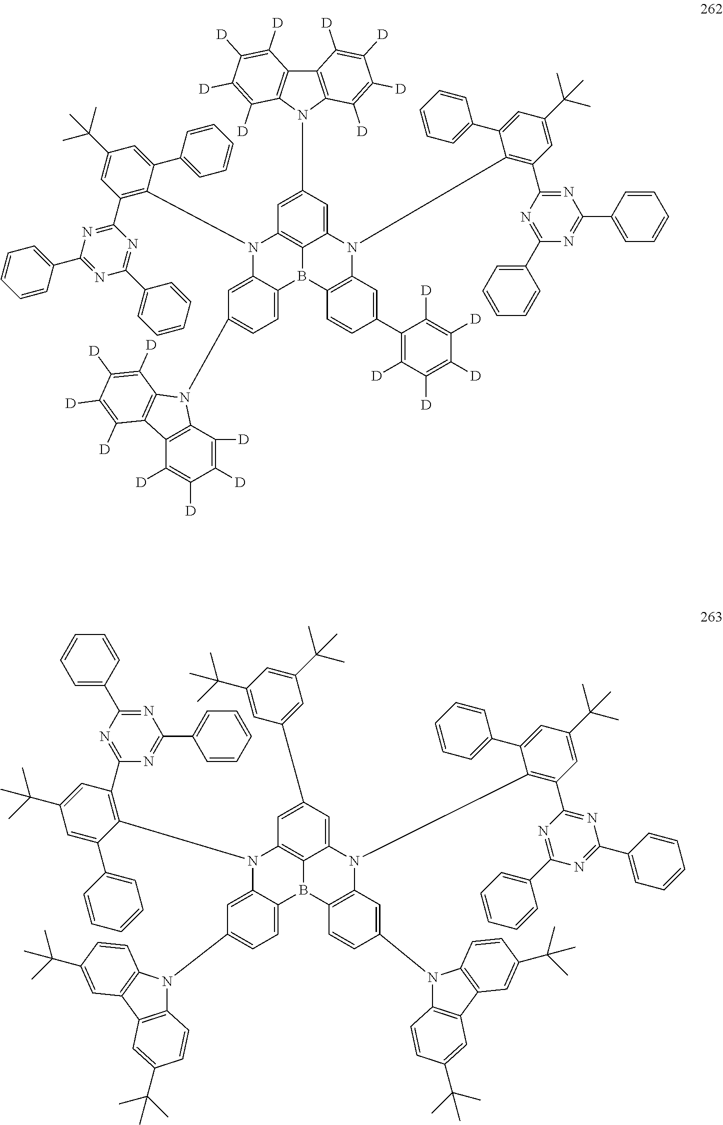

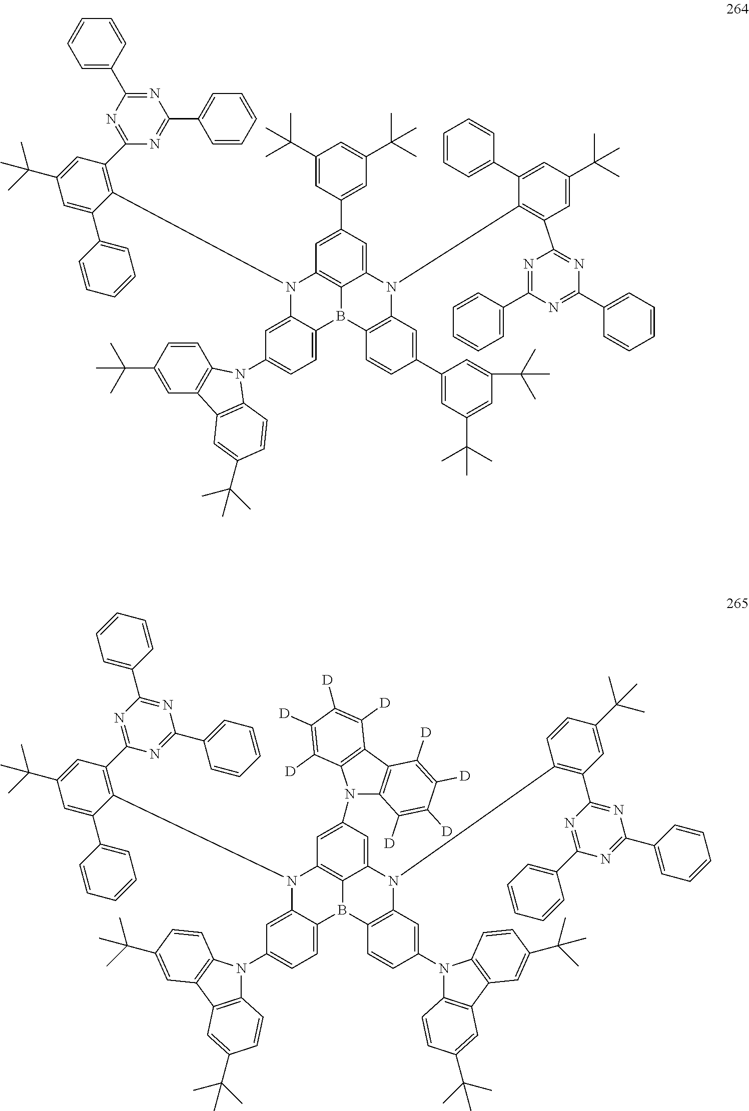

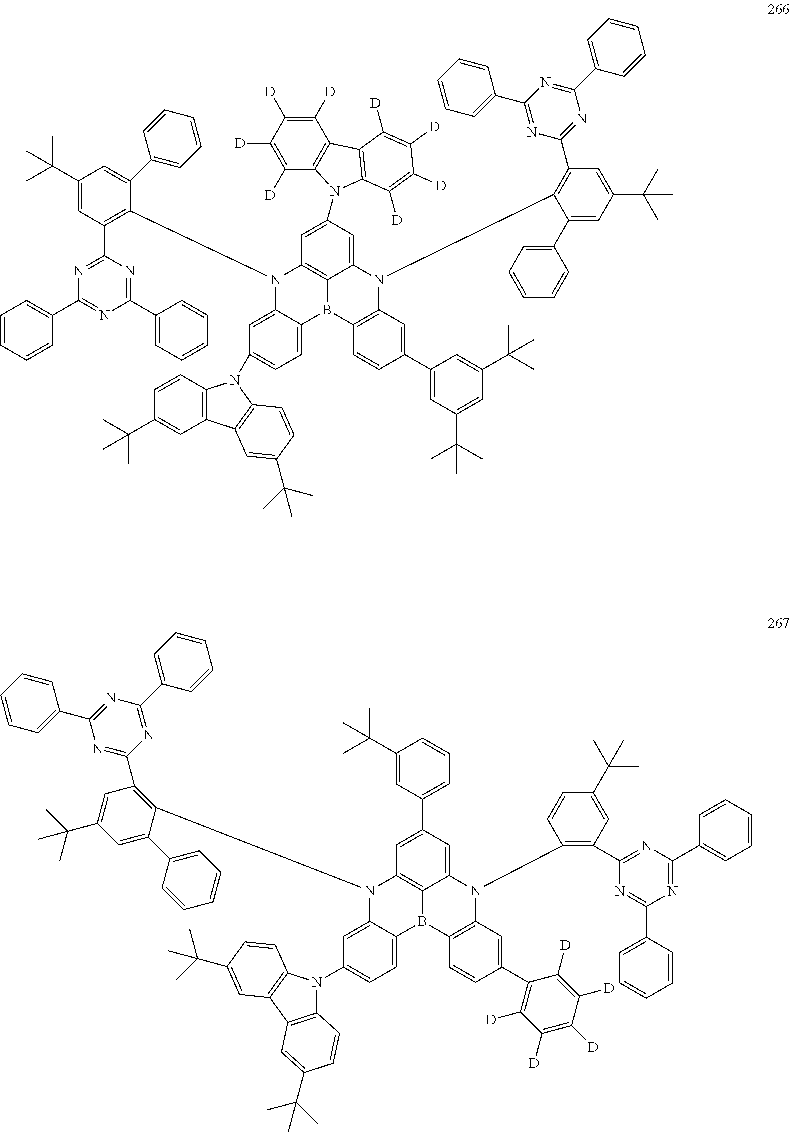

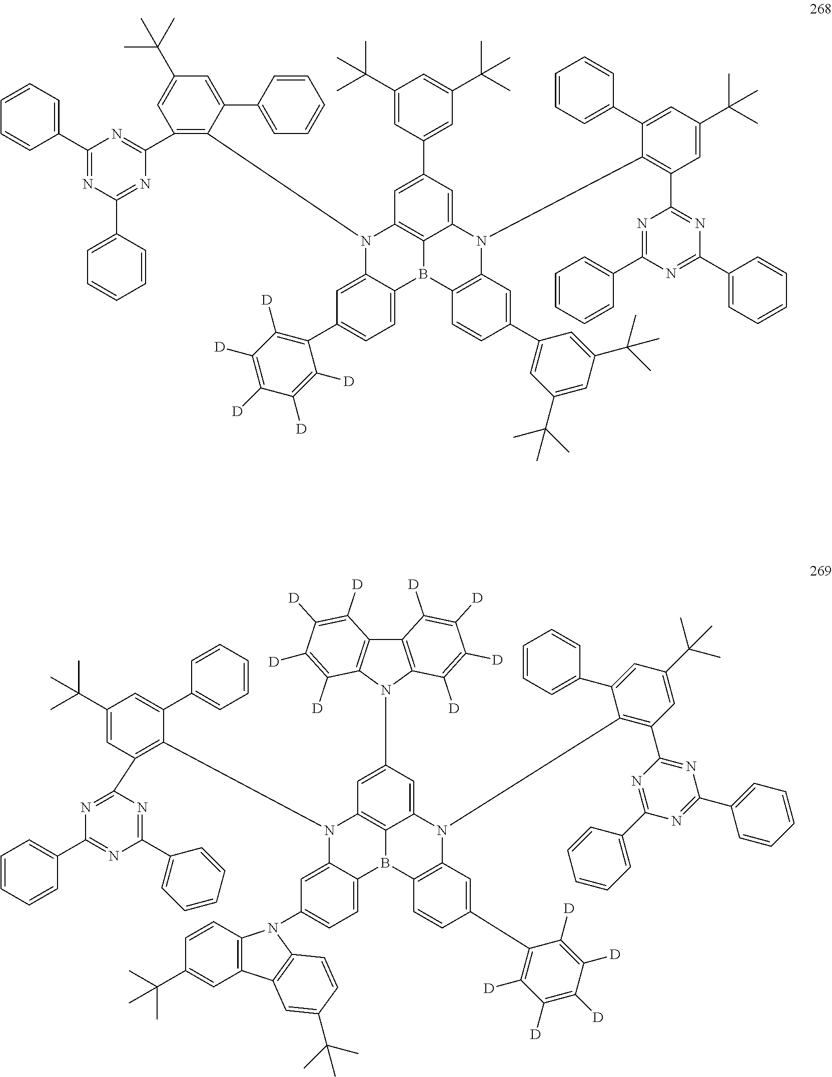

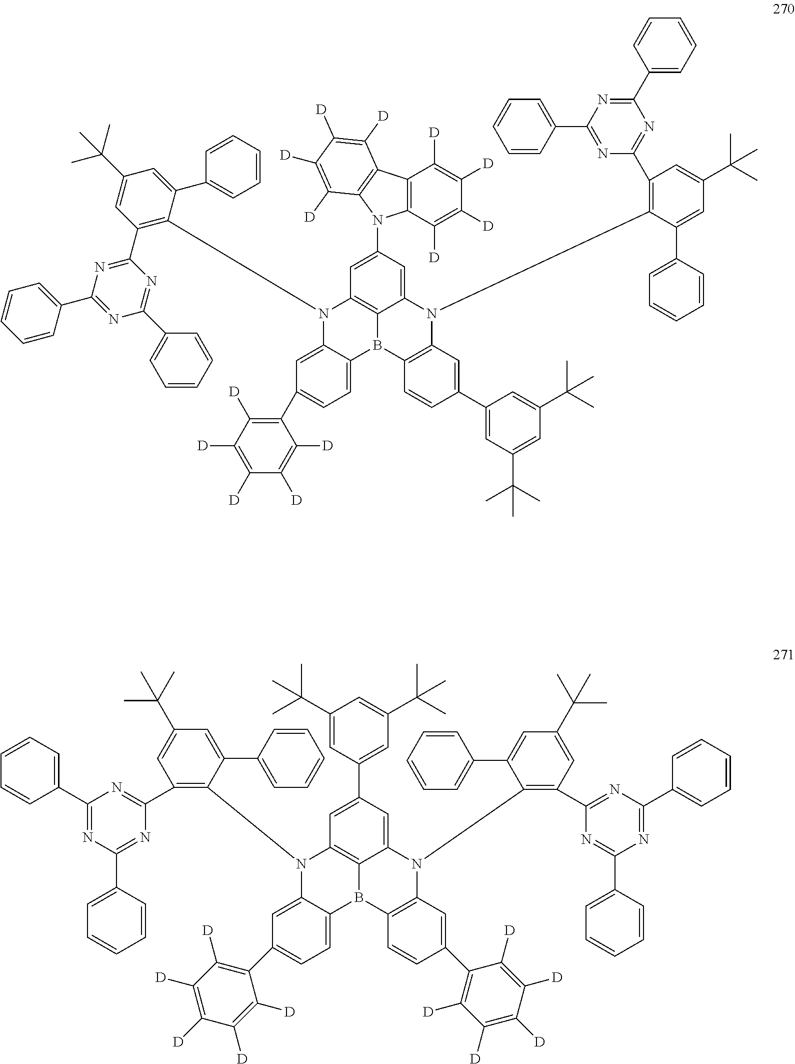

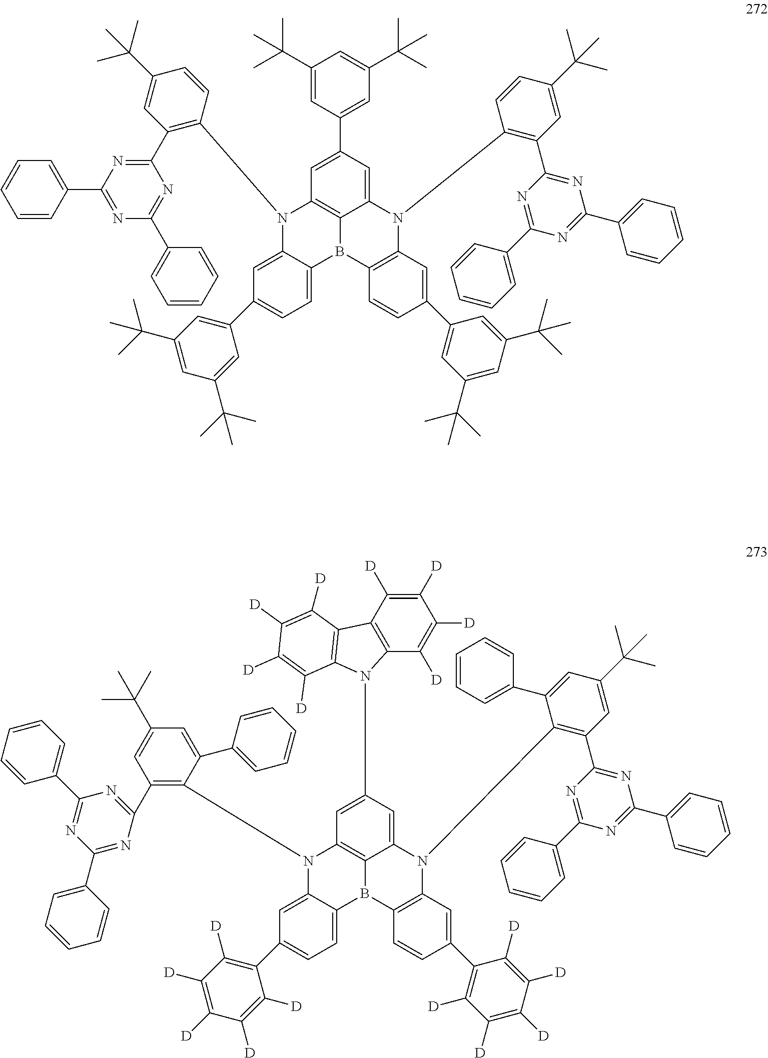

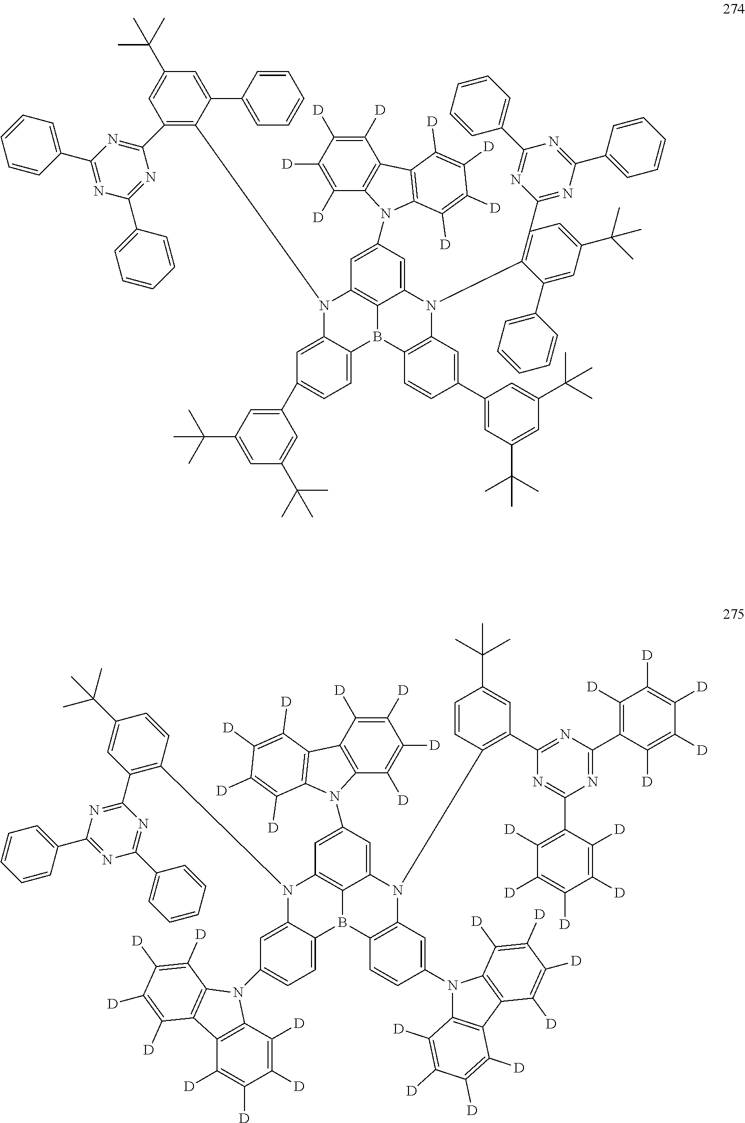

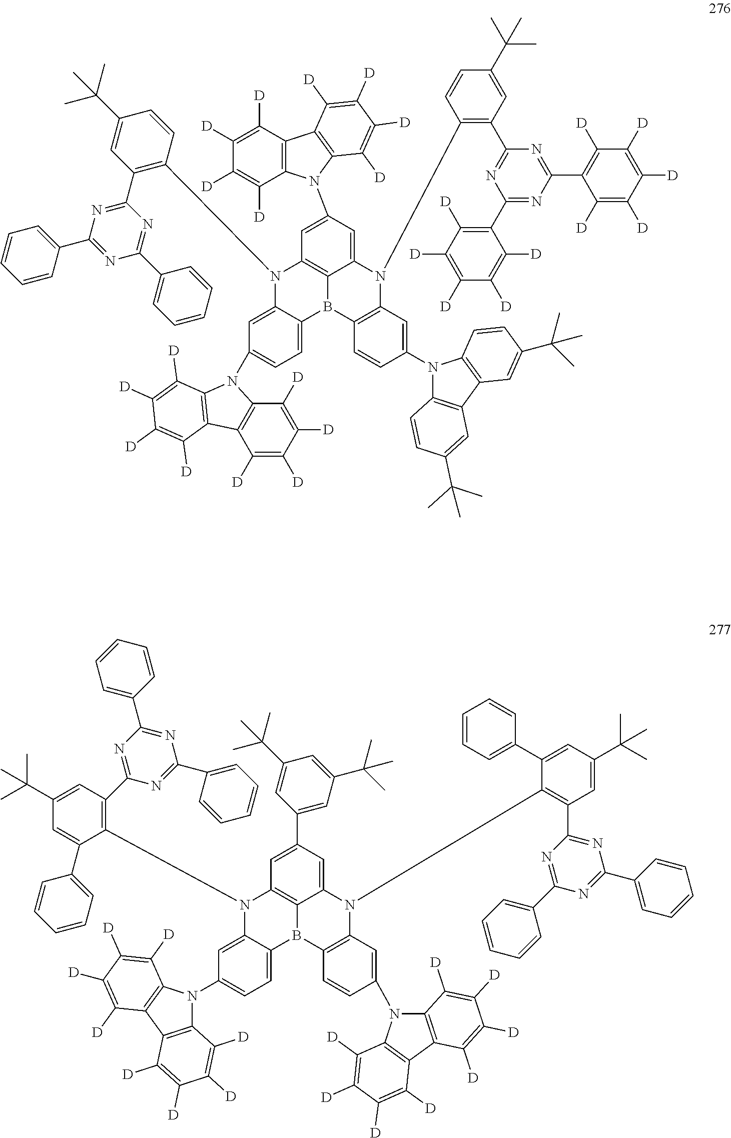

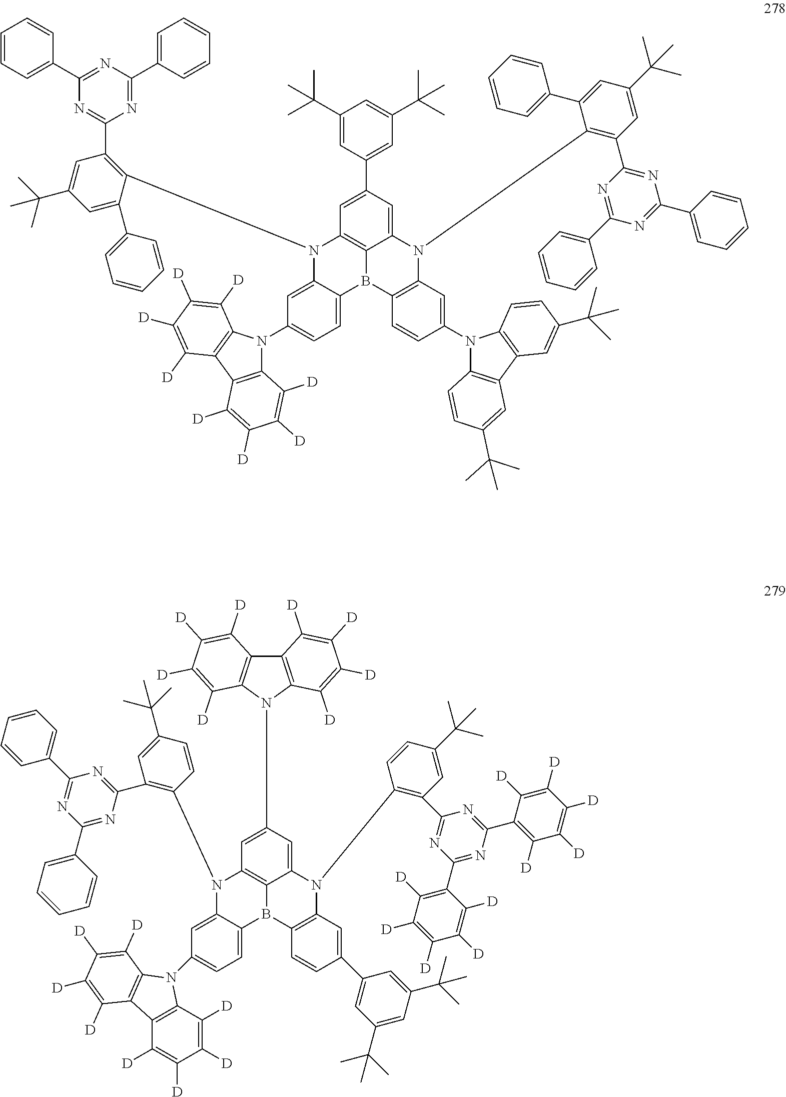

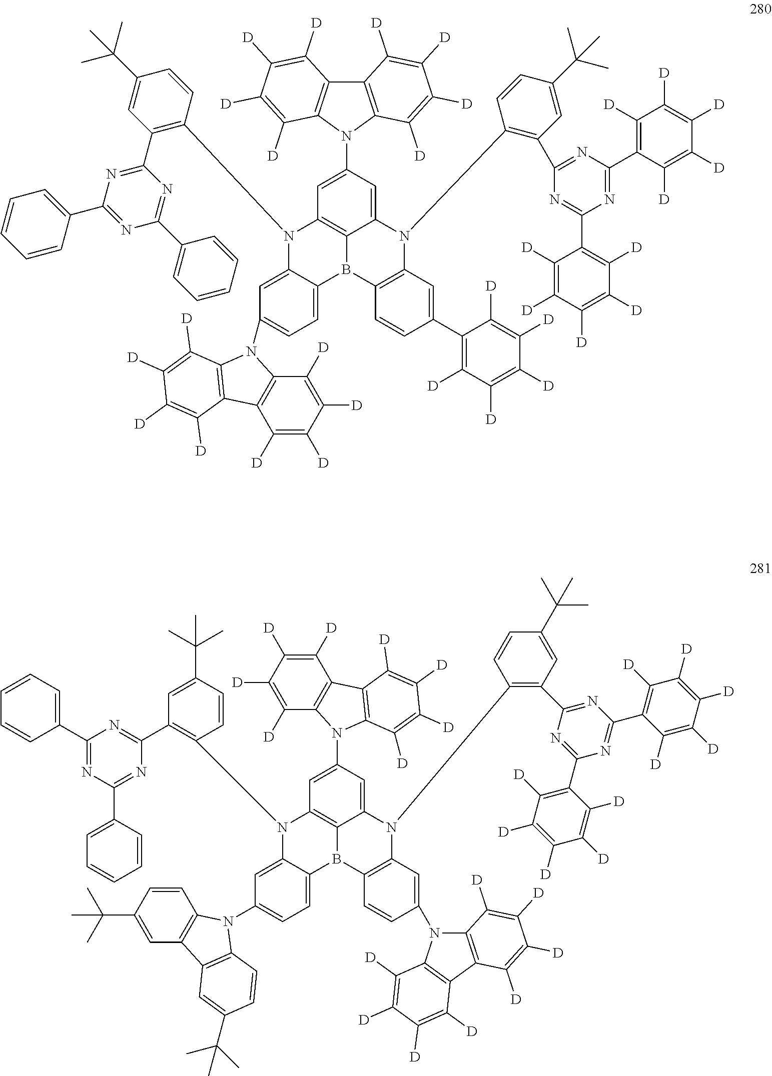

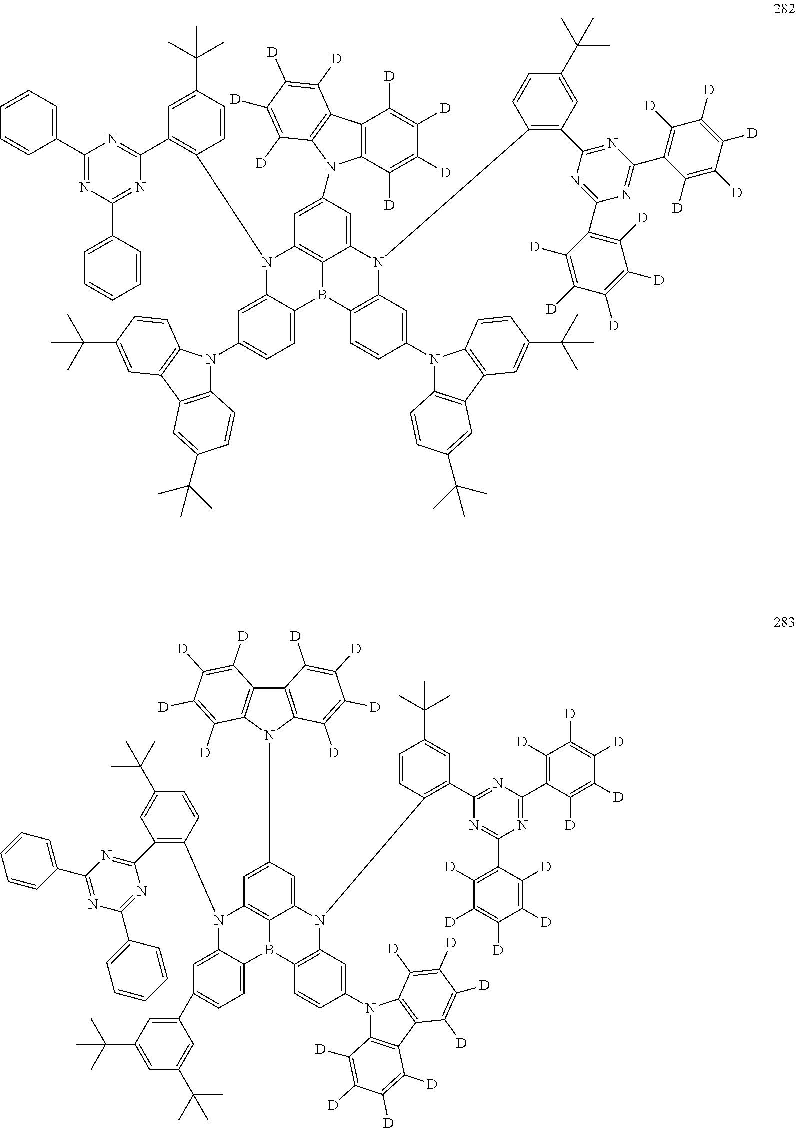

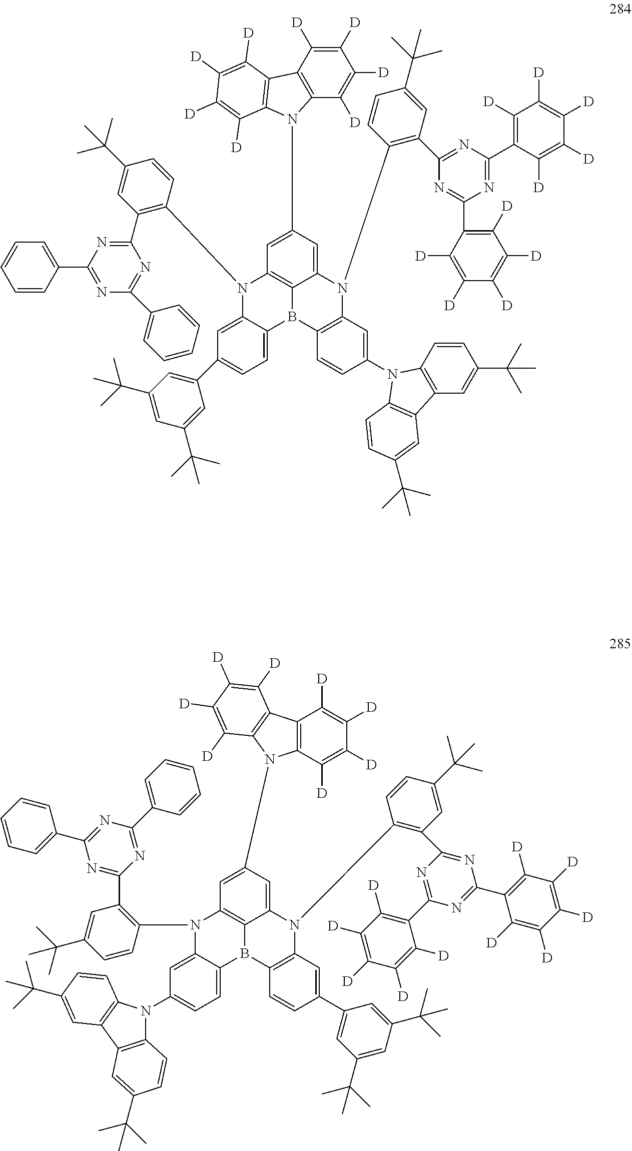

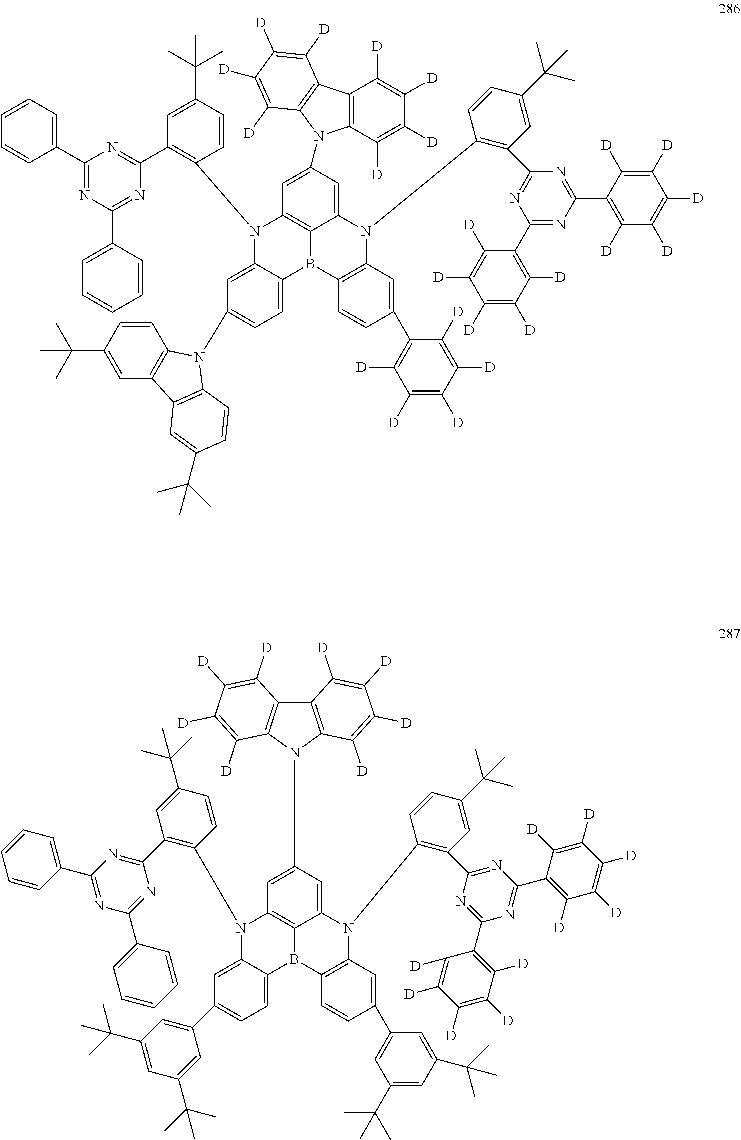

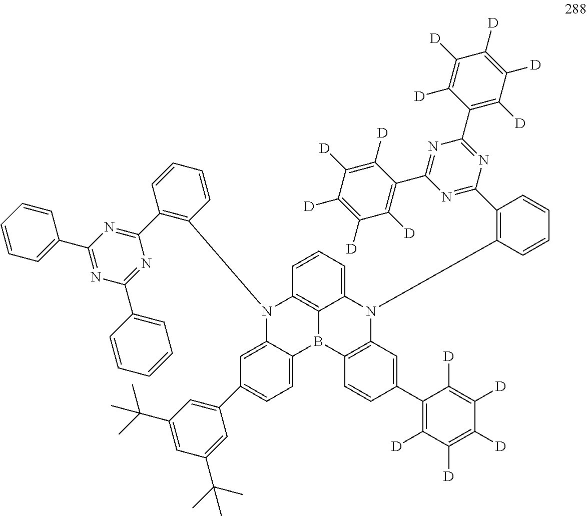 [SMILES: [2H]c1c([2H])c([2H])c(-c2ccc3c(c2)N(c2ccccc2-c2nc(-c4c([2H])c([2H])c([2H])c([2H])c4[2H])nc(-c4c([2H])c([2H])c([2H])c([2H])c4[2H])n2)c2cccc4c2B3c2ccc(-c3cc(C(C)(C)C)cc(C(C)(C)C)c3)cc2N4c2ccccc2-c2nc(-c3ccccc3)nc(-c3ccccc3)n2)c([2H])c1[2H]]

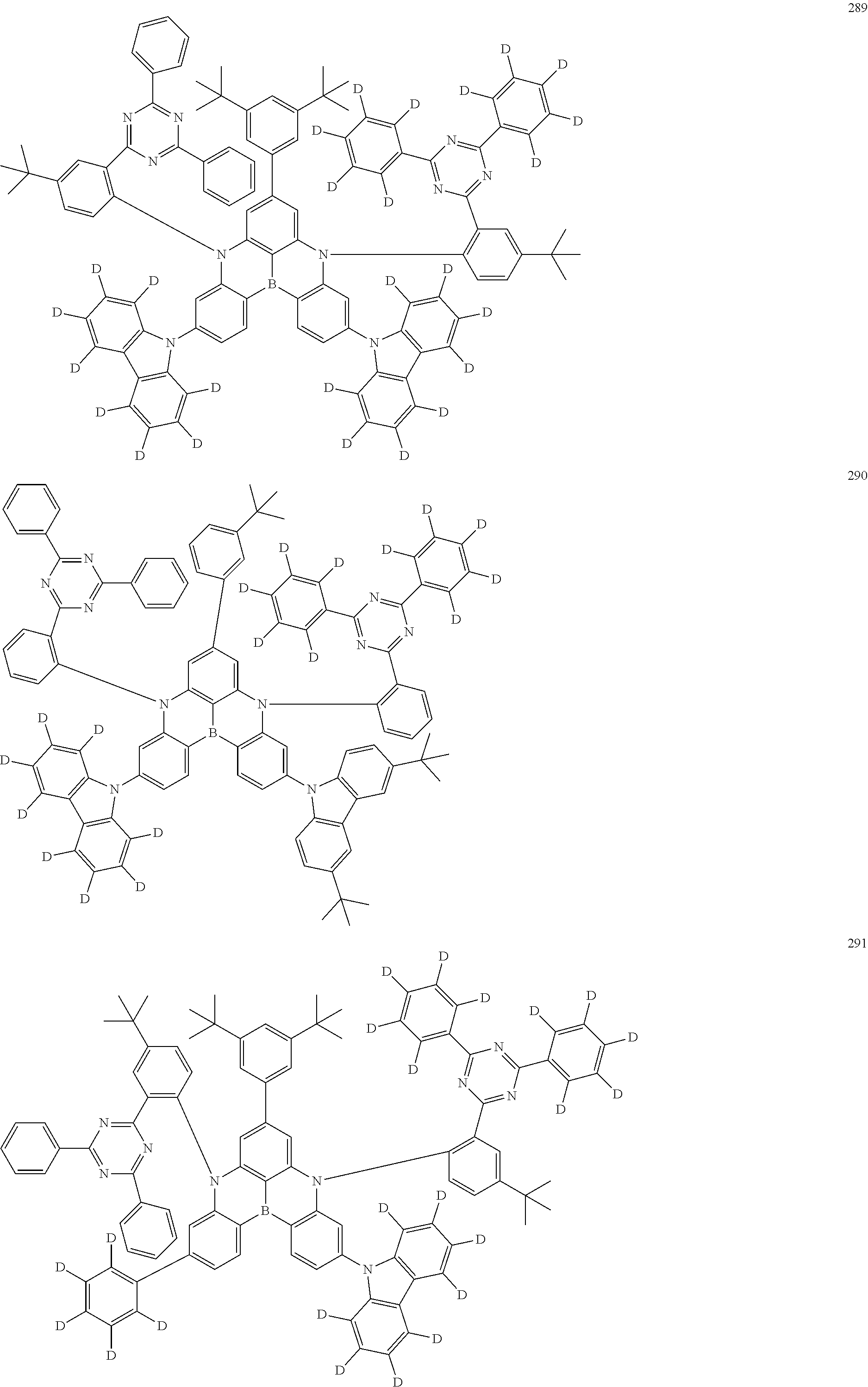

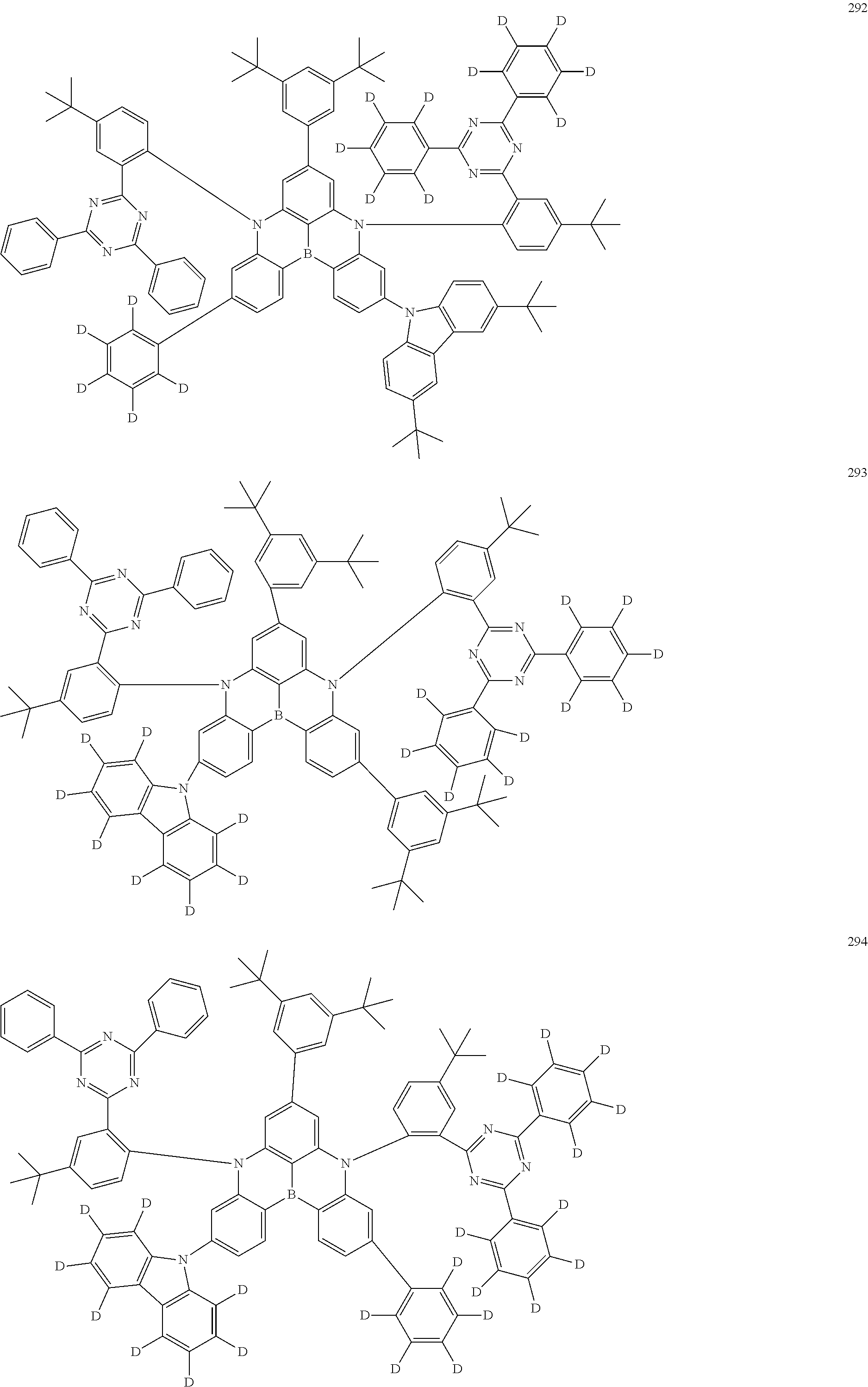

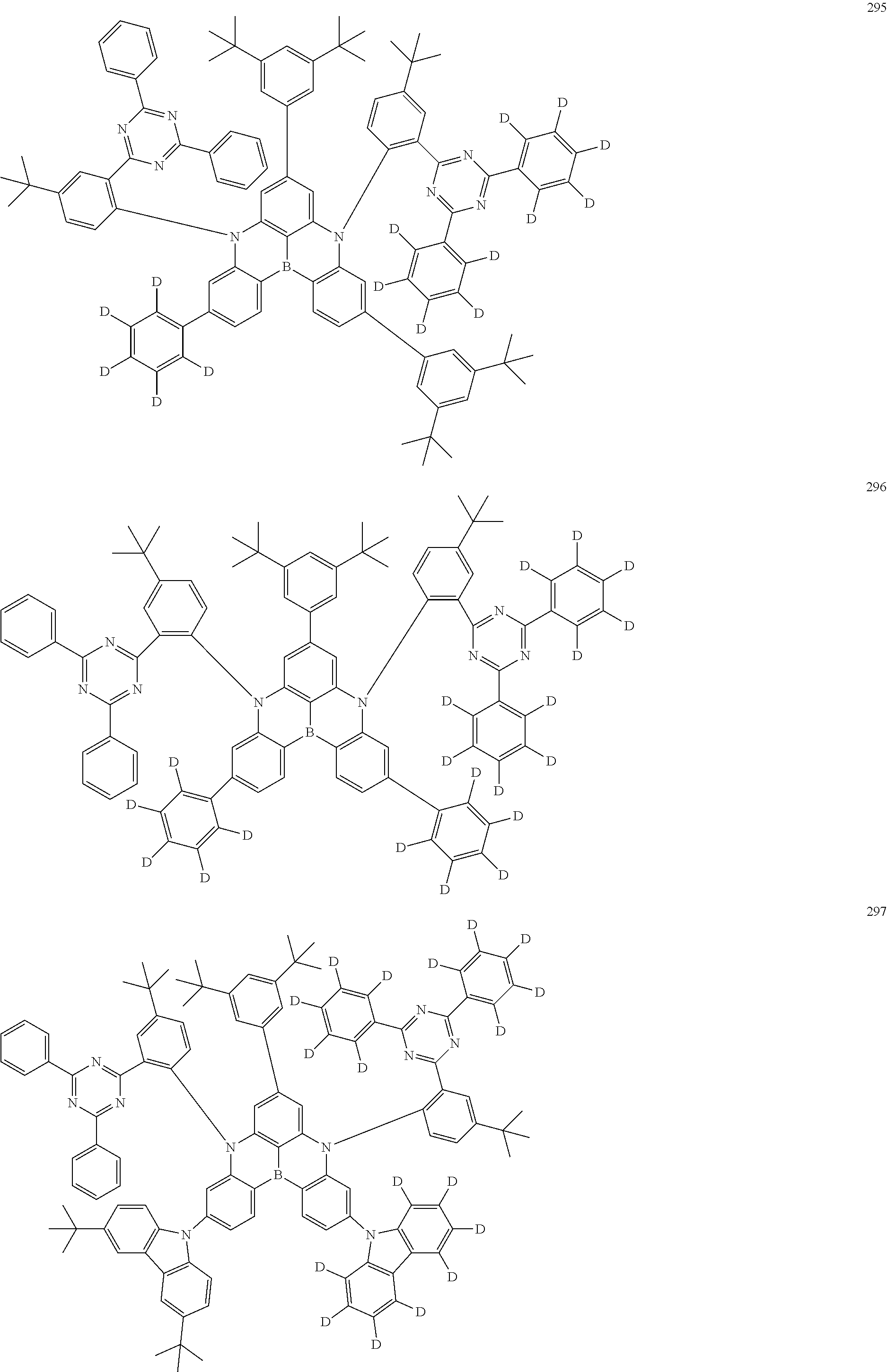

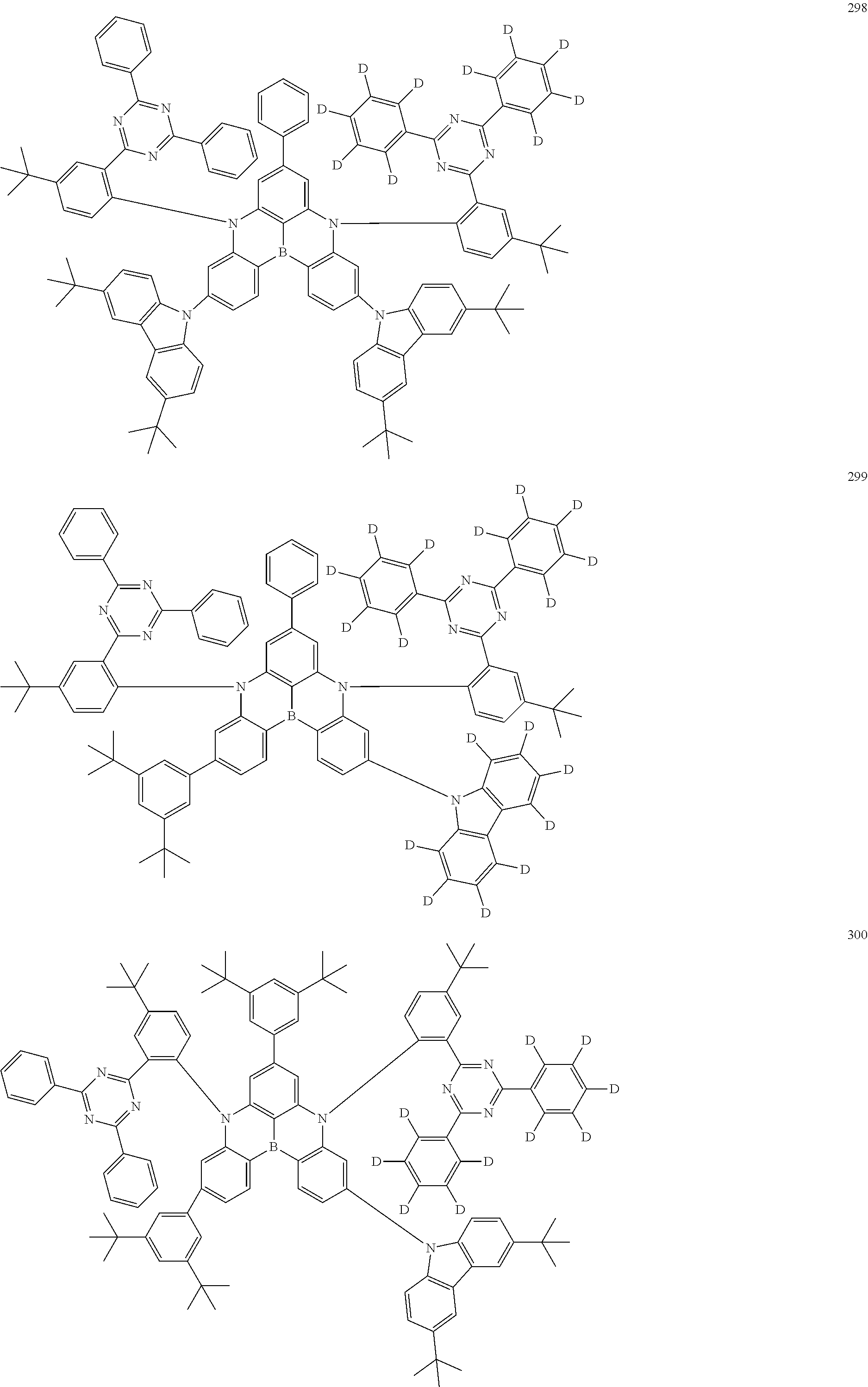

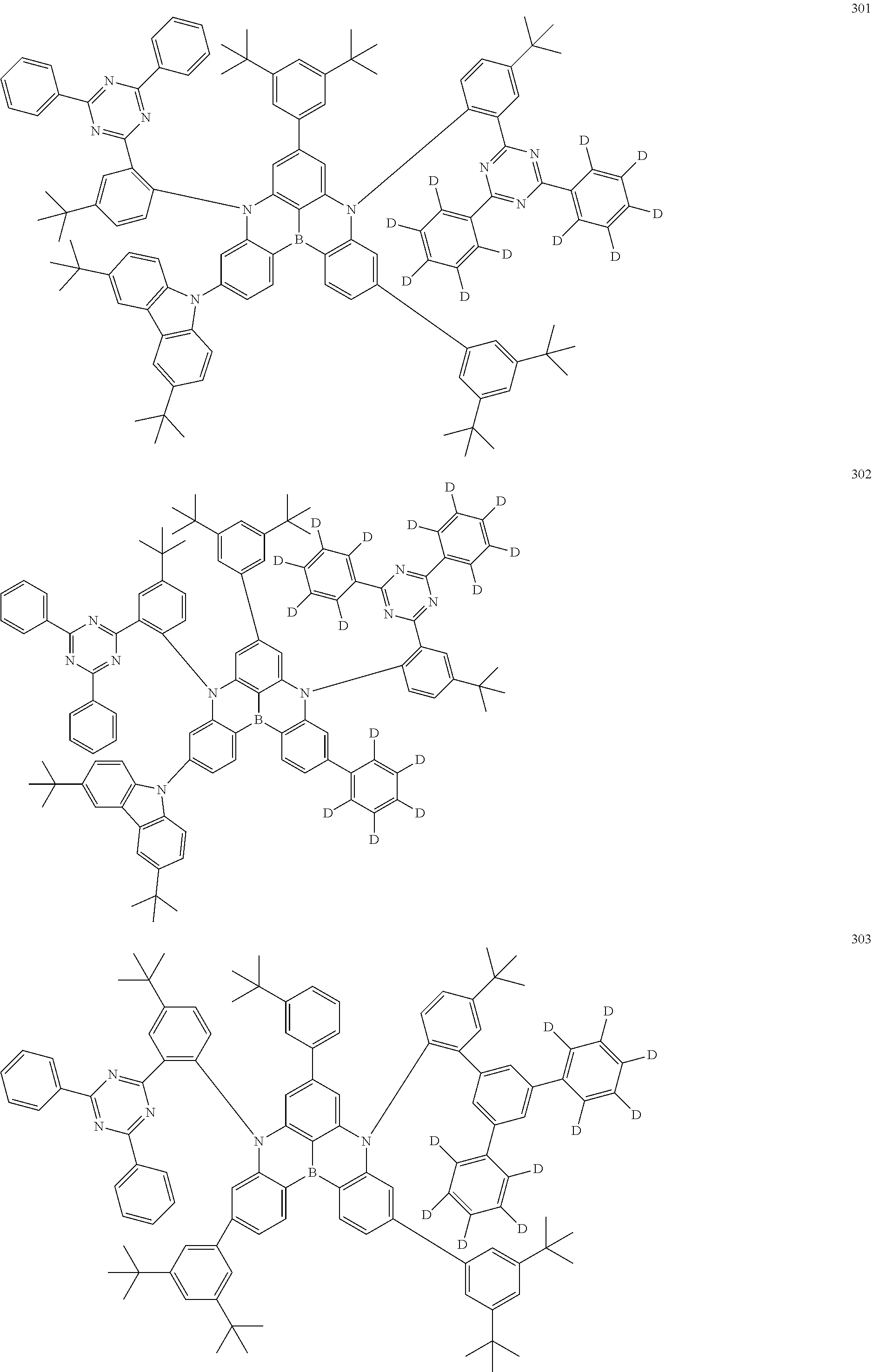

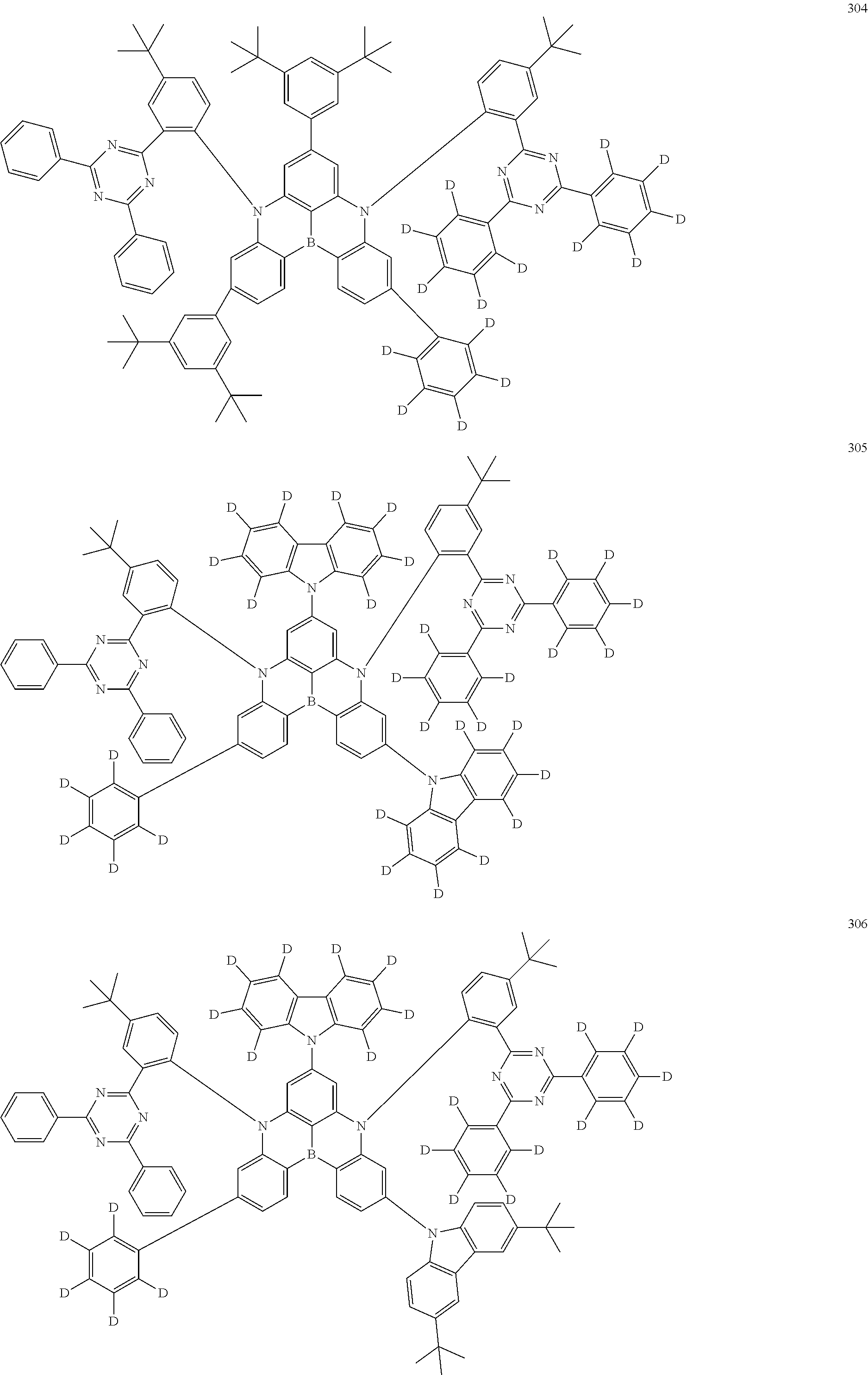

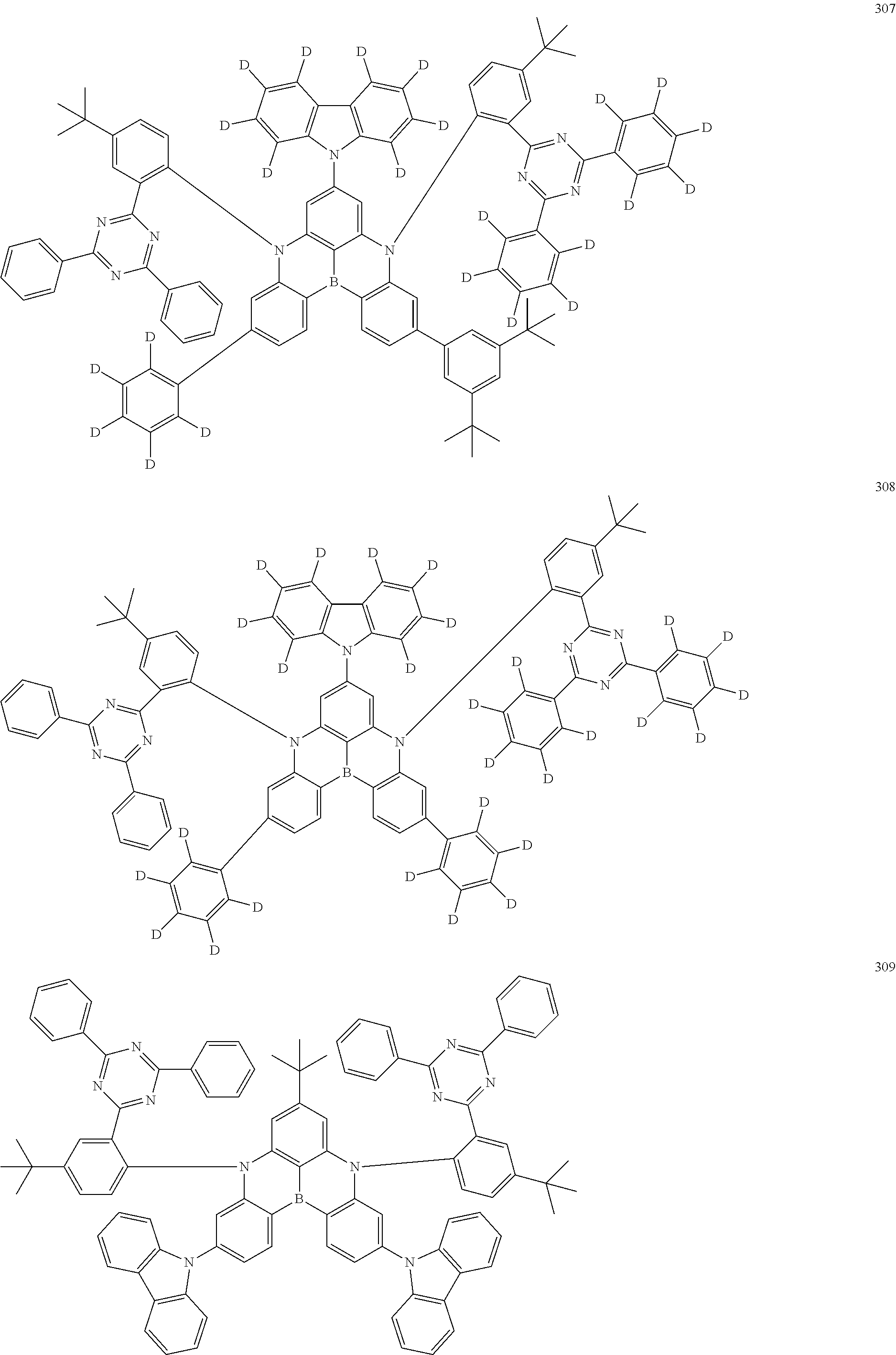

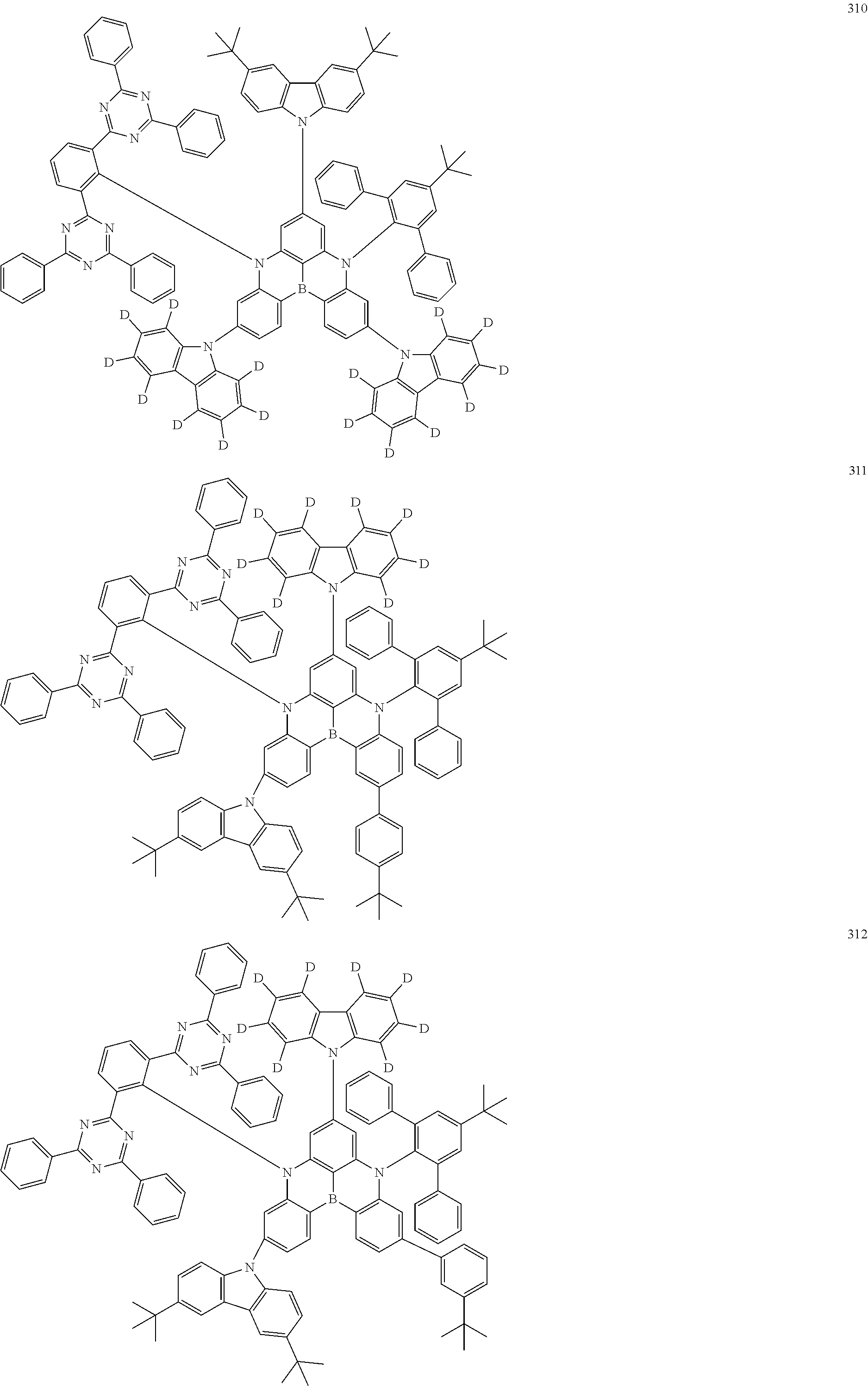

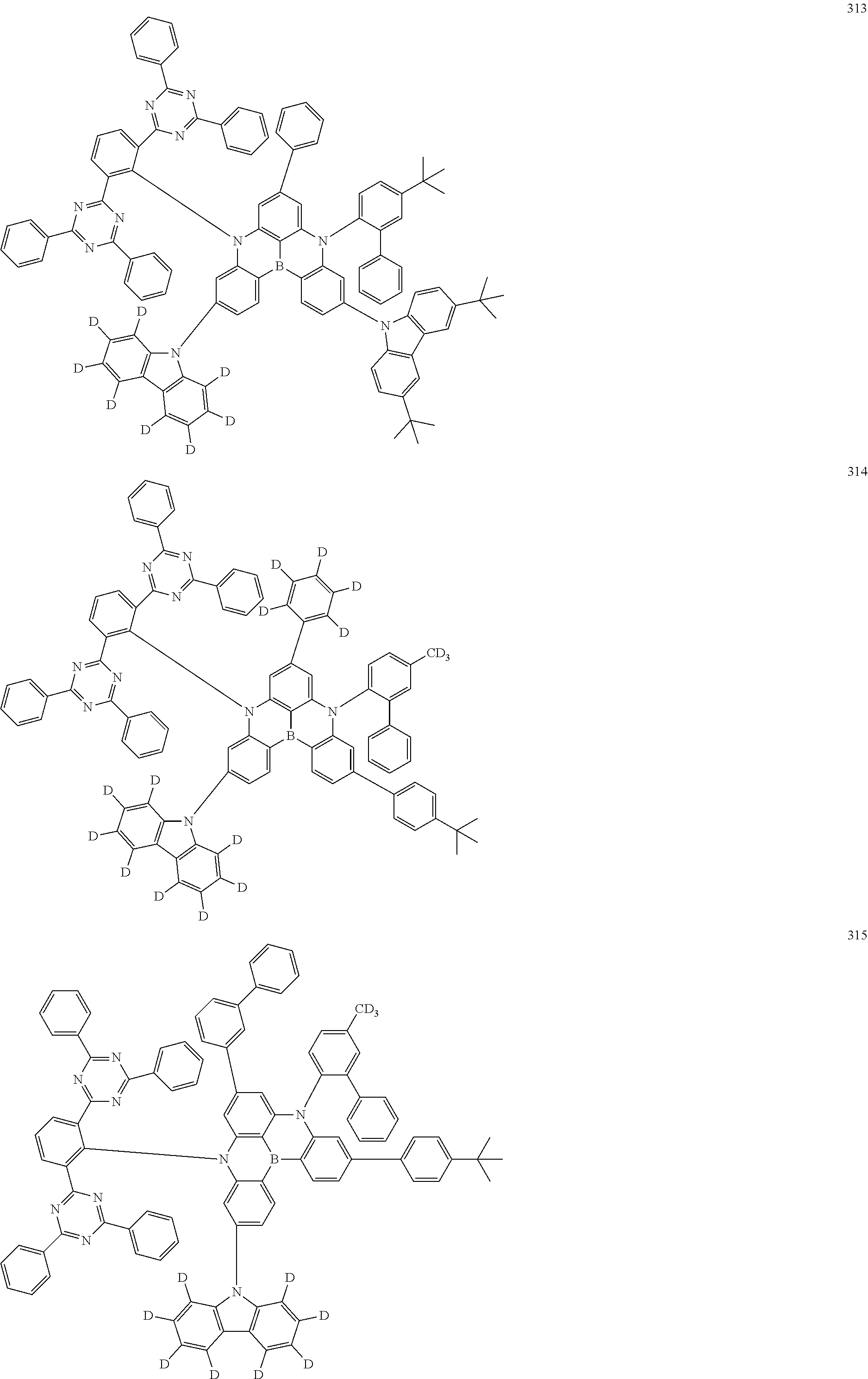

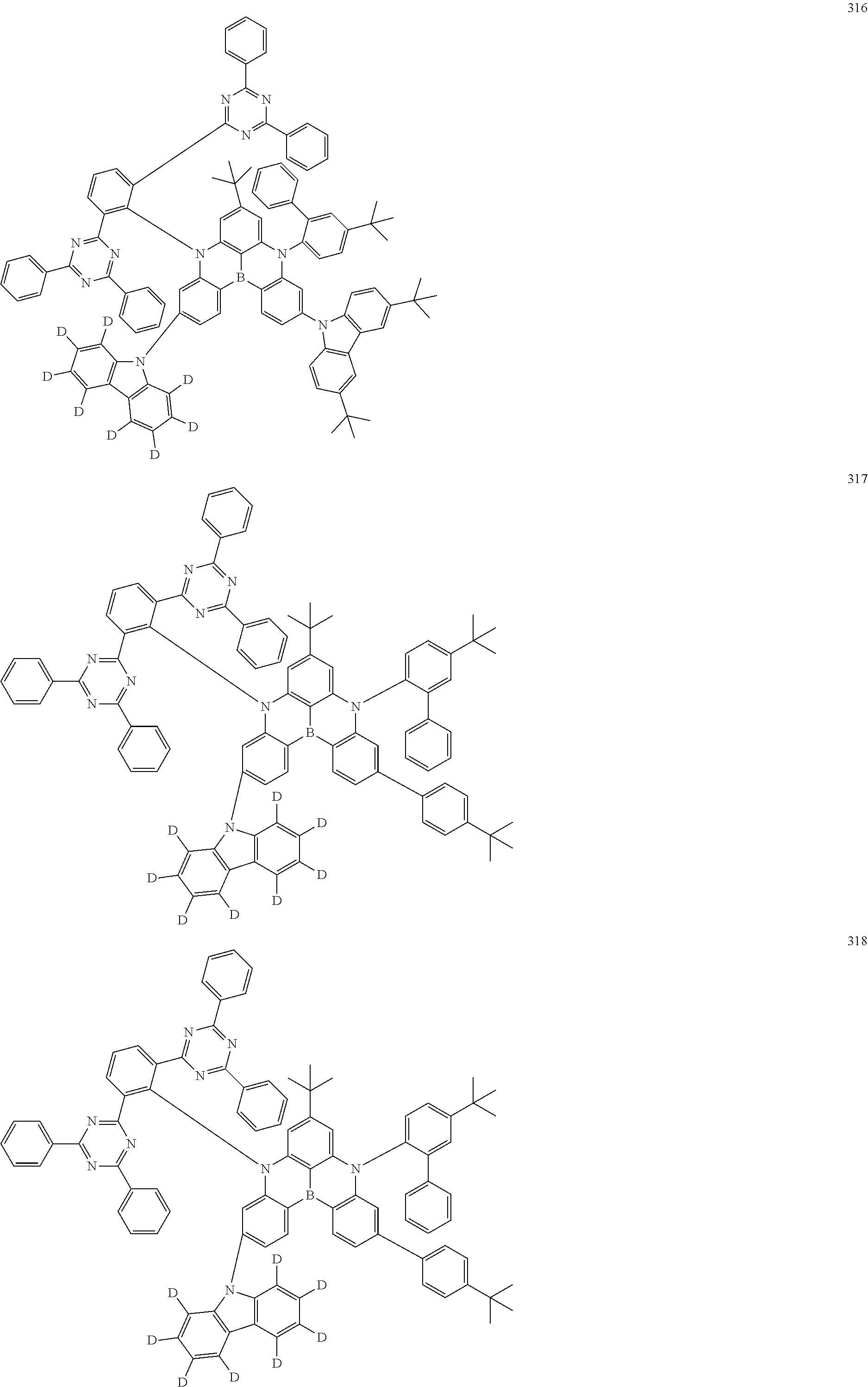

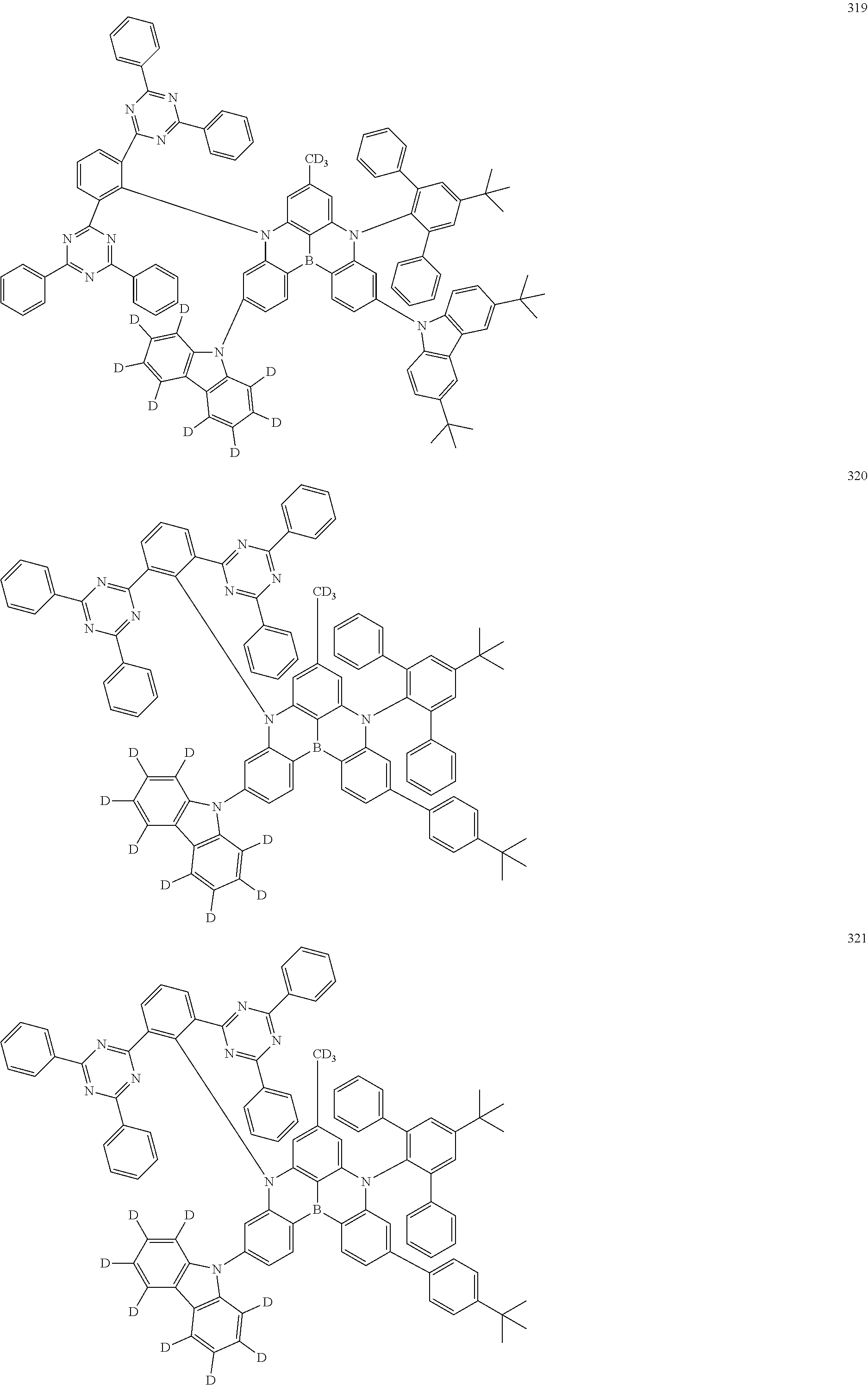

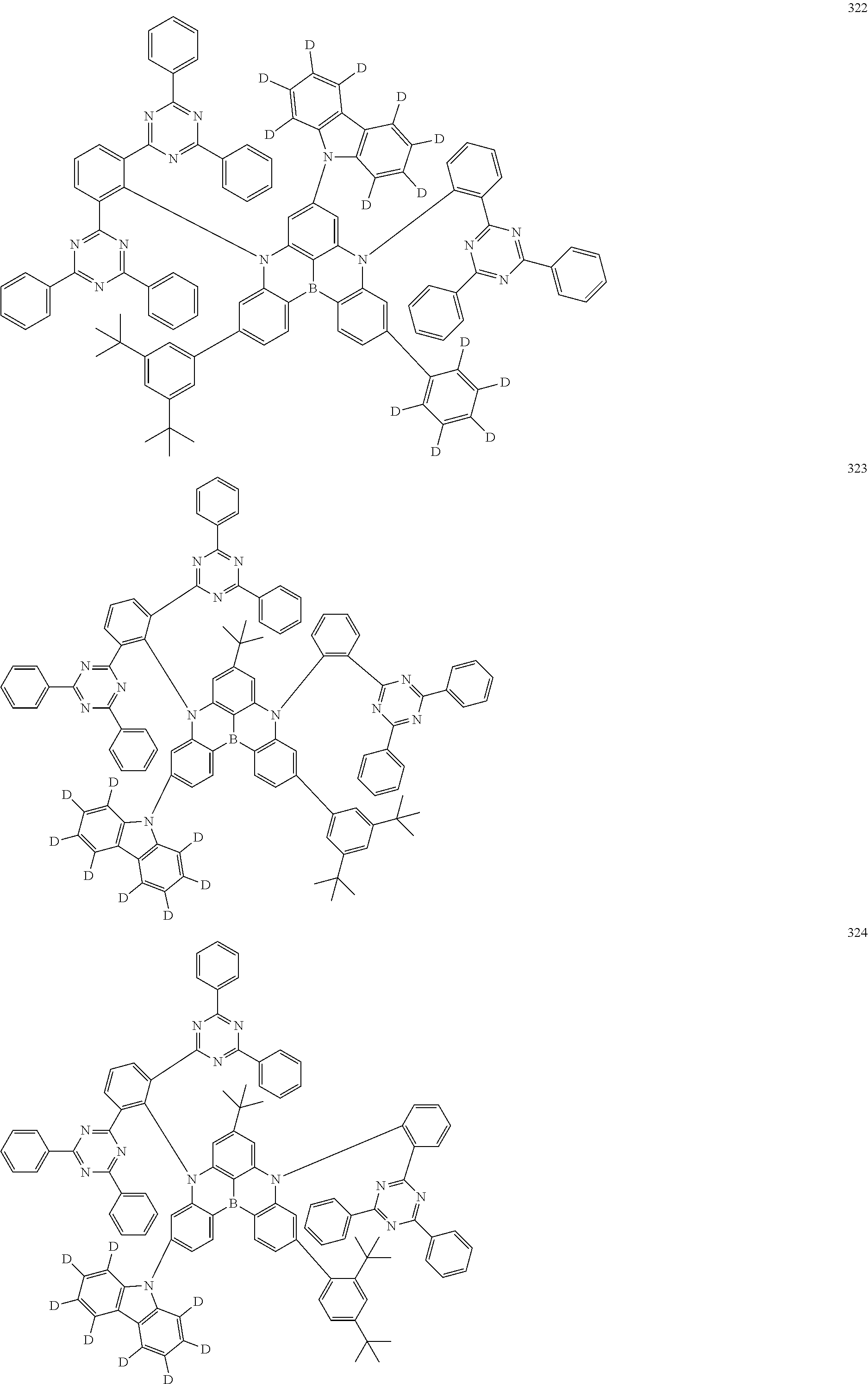

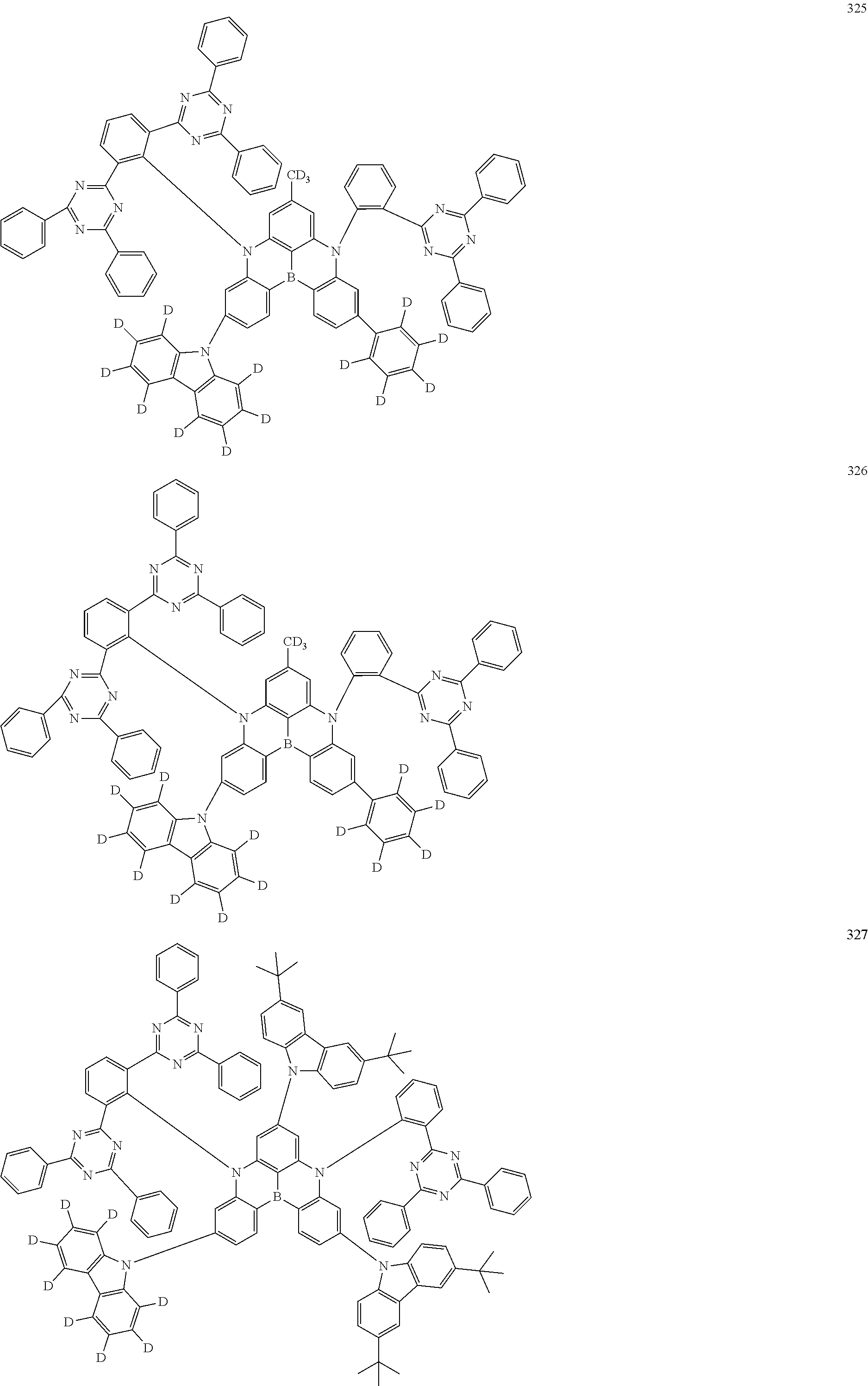

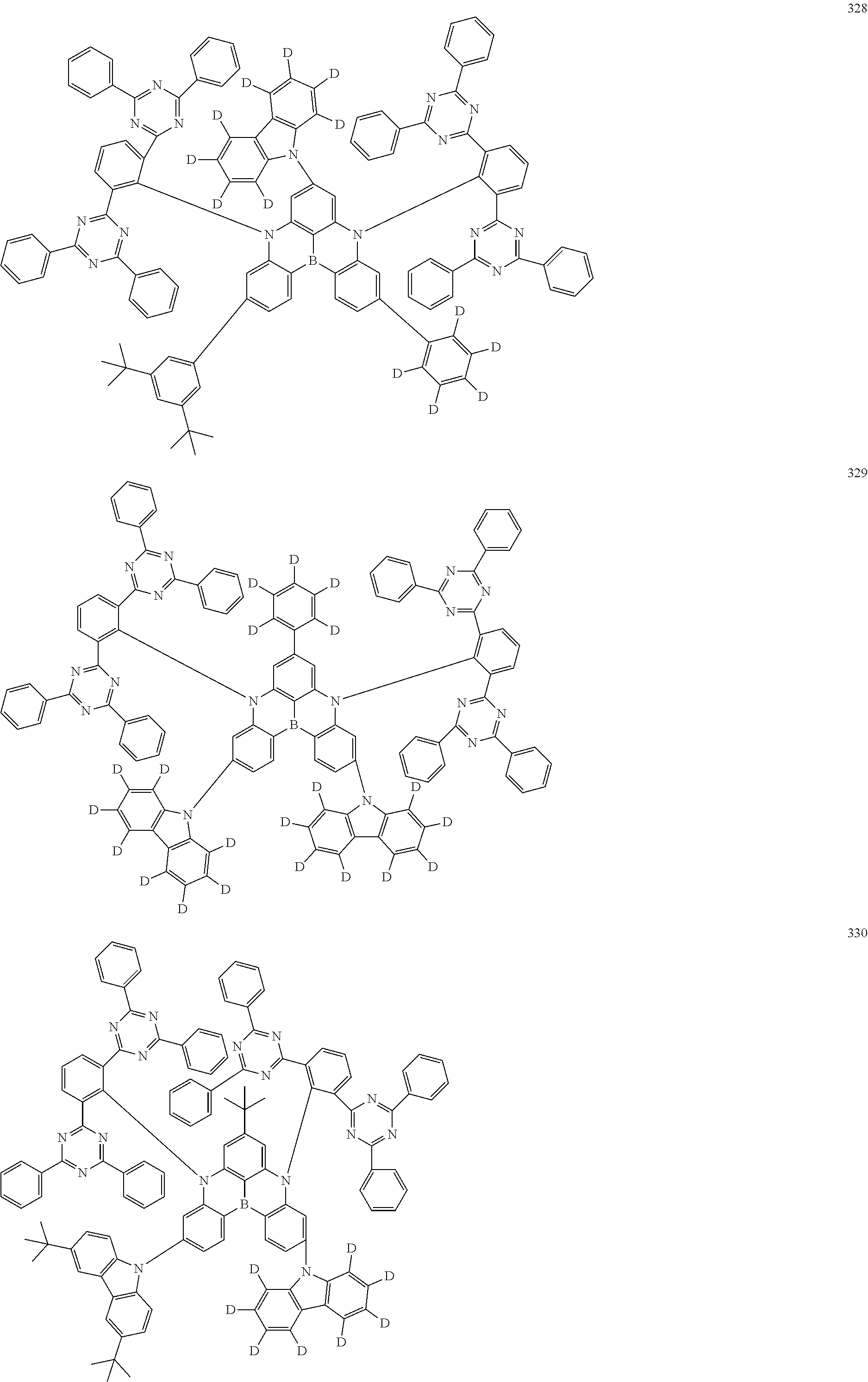

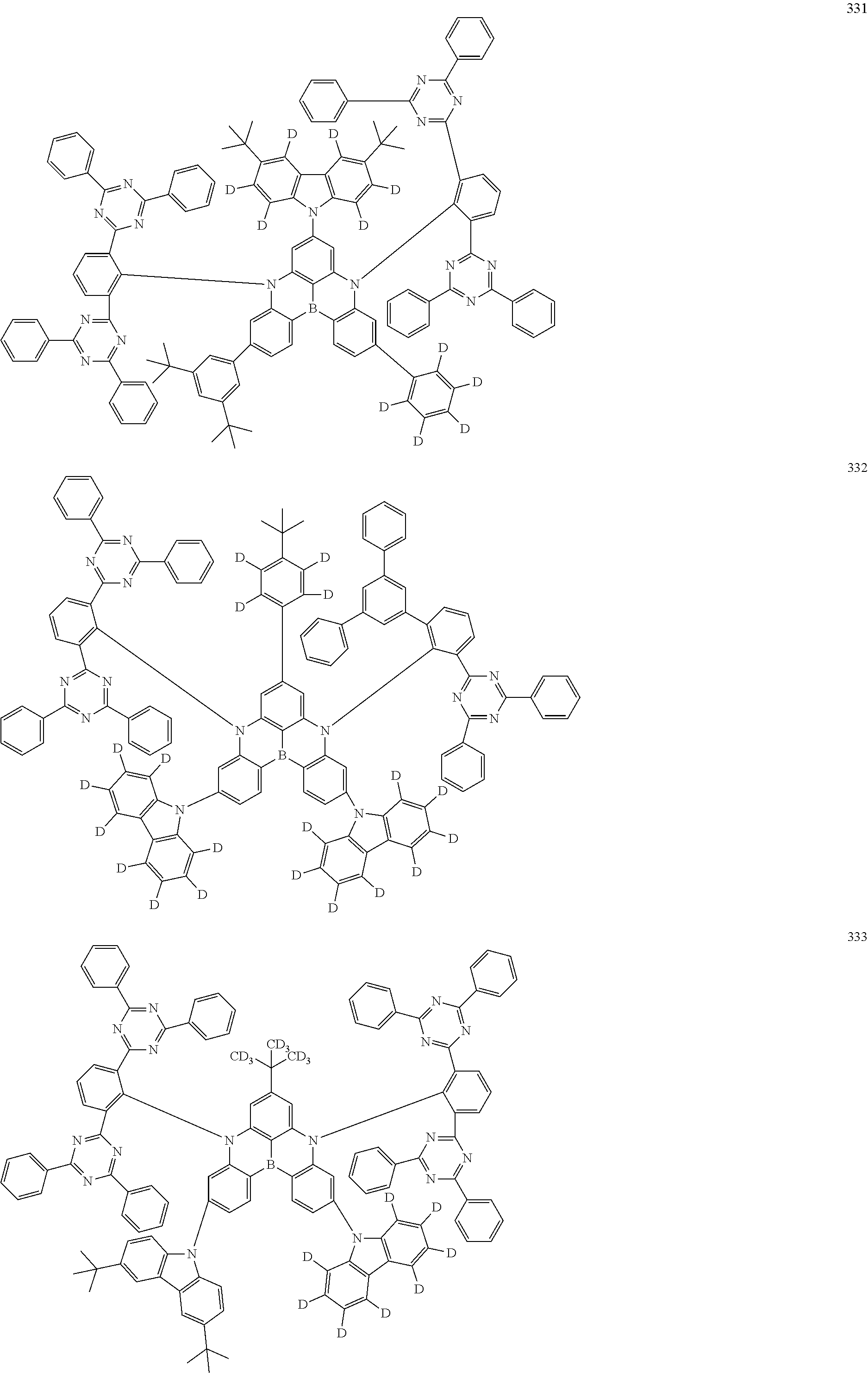

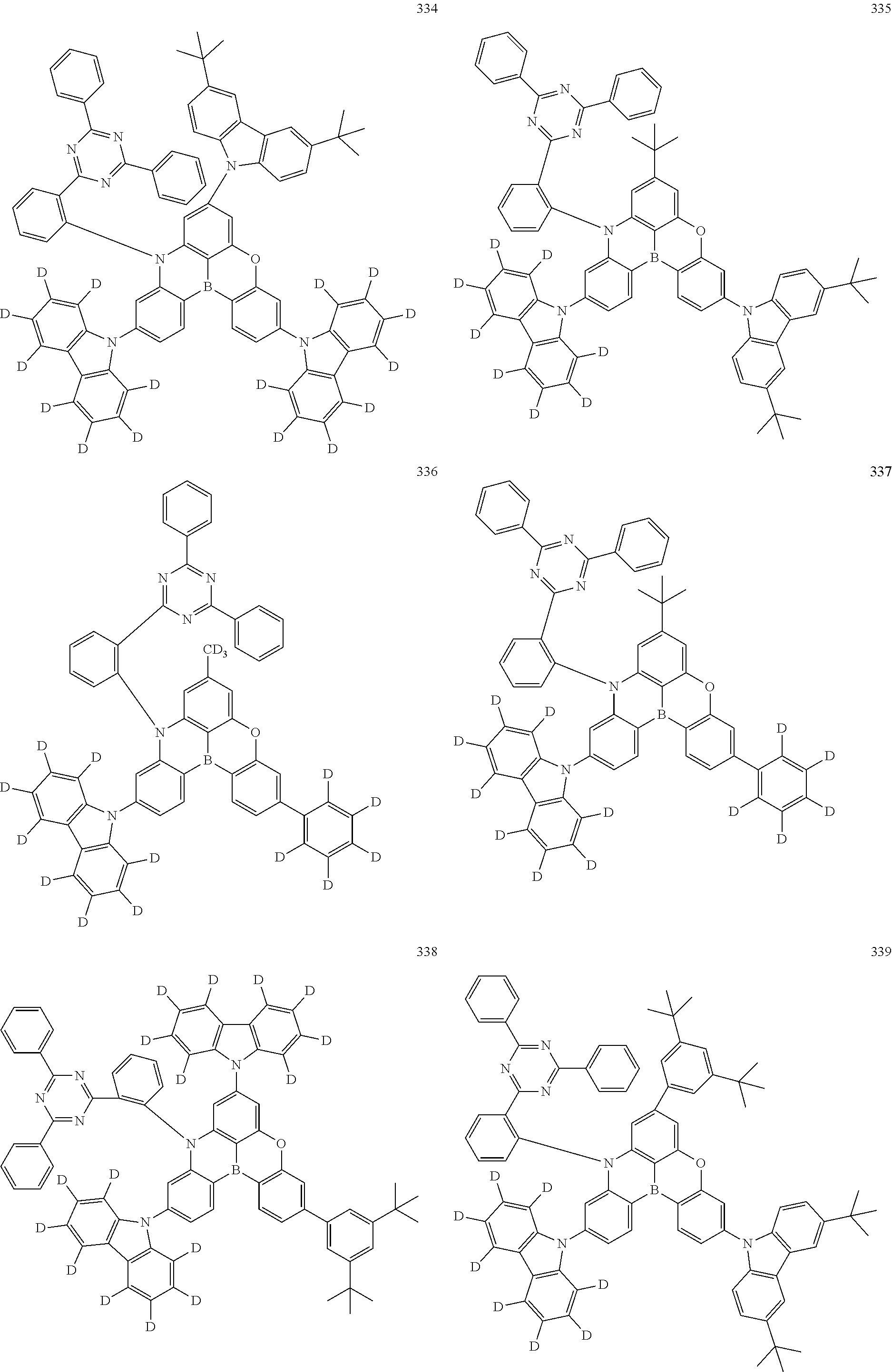

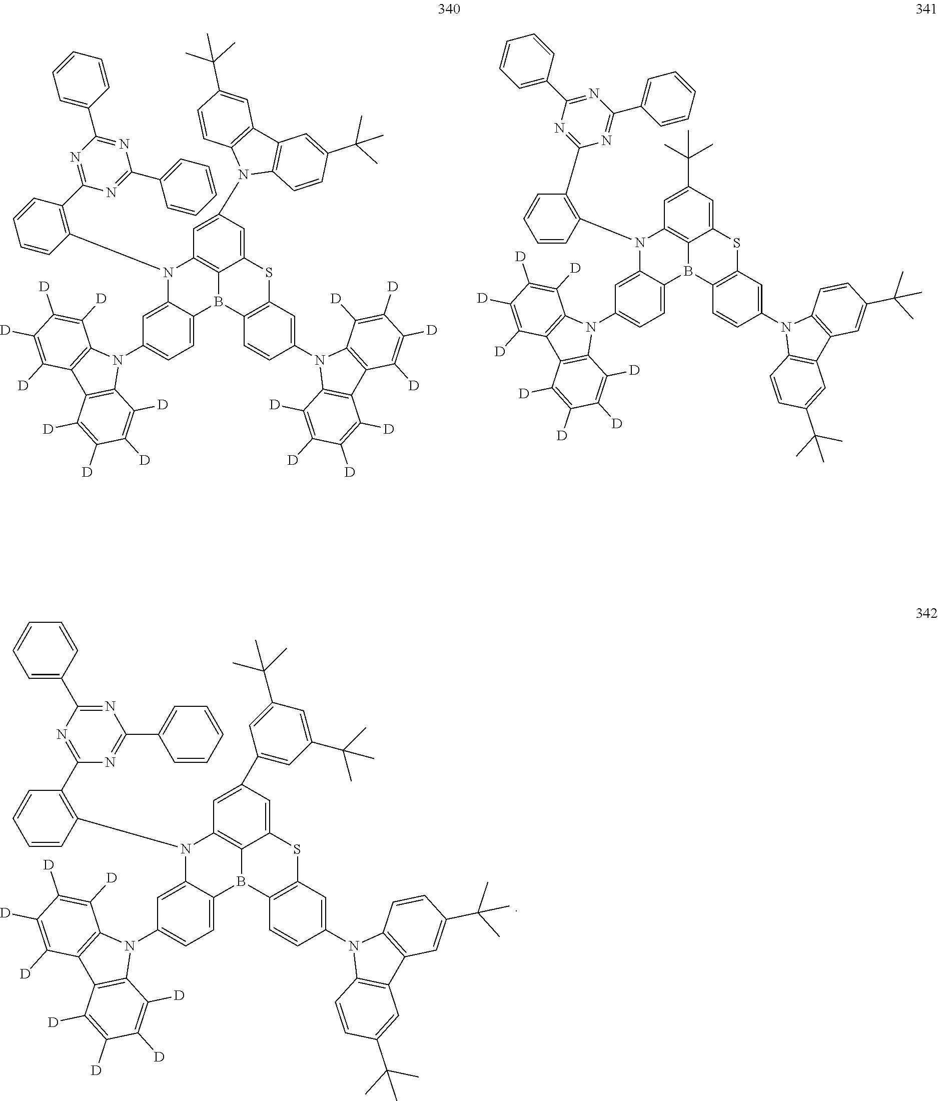

In the example compounds presented in Compound Group 1, “D” indicates deuterium.

The fused polycyclic compound of one or more embodiments represented by Formula 1 may include a structure in which a plurality of aromatic rings are fused through a boron atom, a first nitrogen atom, and a first hetero atom, and may have a structure in which the first substituent is linked to the first nitrogen atom.

The fused polycyclic compound of one or more embodiments may effectively maintain a trigonal planar structure of the boron atom through the steric hindrance effect caused by the first substituent. The boron atom may have electron-deficient properties due to vacant p-orbital, and may thus be bonded to other nucleophiles and be modified into a tetrahedral structure, which may result in deterioration of a light-emitting element. According to one or more embodiments of the present disclosure, in the fused polycyclic compound of one or more embodiments, as the first substituent is introduced into the fused ring core, the vacant p-orbital of the boron atom may be effectively protected, and accordingly, the deterioration caused by the structural deformation may be prevented or reduced.

In one or more embodiments, in the fused polycyclic compound, the steric hindrance effect caused by the first substituent may suppress or reduce intermolecular interactions to control aggregation, excimer formation, or exciplex formation, which may cause greater luminous efficiency. The fused polycyclic compound of one or more embodiments represented by Formula 1 has a bulky structure and thus widens the intermolecular distance to reduce Dexter energy transfer, and accordingly, an increase in the concentration of triplet exciton in the fused polycyclic compound may be prevented or reduced. The triplet exciton at a high concentration remains in an excited state for a long period of time and may thus cause compound decomposition, and may induce hot exciton having high energy generated through triplet-triplet annihilation (TTA) to cause surrounding compound structures to collapse. In addition, the triplet-triplet annihilation is a bimolecular reaction that fast-quenches the triplet exciton utilized for light emission, and may thus cause a decrease in luminous efficiency as a non-radiative transition. In one or more embodiments, in the fused polycyclic compound, the intermolecular distance is increased by the first substituent, and accordingly, the Dexter energy transfer may be suppressed or reduced to prevent or reduce service life deterioration caused by an increase in triplet concentration. Accordingly, when the fused polycyclic compound of one or more embodiments is applied to an emission layer EML of the light emitting element ED, the luminous efficiency may be increased and the element service life may also be improved.

According to one or more embodiments, the first substituent may include a phenyl moiety and a triazine moiety linked to the phenyl moiety. The triazine moiety of one or more embodiments may have s TZ structure. The carbon at the position of “a” in the triazine moiety may have electron withdrawing properties. The triazine moiety in one or more embodiments may be linked to the first nitrogen atom of the first compound through the carbon at the position of “a”. The same descriptions as in Formula S may apply to Ar₁ and Ar₂ in the TZ structure.

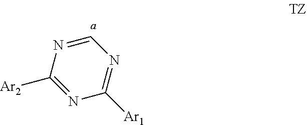

Herein, the first substituent is linked to the first nitrogen atom of the first compound, and accordingly, the spatial overlap between HOMO (highest occupied molecular orbital) and LUMO (lowest unoccupied molecular orbital) of the first compound may be minimized or reduced to improve multiple resonance effects. Referring to the following structure C1, in the fused ring core structure centered on the boron atom, the first nitrogen atom, and the first hetero atom, the first nitrogen atom may correspond to a position with high electron density. In the fused ring core centered on the boron atom, the first nitrogen atom having a high electron density is linked to the “a” carbon of the triazine moiety, which has electron withdrawing properties, to effectively separate HOMO and LUMO, leading to improvements in the multi-resonance effects. Therefore, the first compound of one or more embodiments into which the first substituent is introduced may exhibit high luminous efficiency. Meanwhile, the same descriptions as in Formula 1 may apply to Rₐ and X₁ in C1. In addition, for convenience of description, a substituent linked to the fused ring core is not provided in the structure C1.

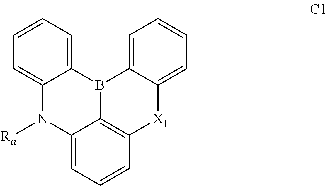

The fused polycyclic compound of one or more embodiments represented by Formula 1 includes the first substituent, thereby increasing intramolecular rigidity. As a result, structural changes in intramolecular is suppressed or reduced and Stoke's shift is reduced, which may increase photoluminescence quantum yield (PLQY) and intermolecular fluorescence resonance energy transfer (FRET). Herein, the Stoke's shift may indicate a difference between the maximum wavelength at which a compound absorbs energy and the maximum wavelength at which a compound emits energy.

In one or more embodiments, when the fused polycyclic compound includes the first substituent, the intramolecular rigidity increases to prevent or reduce significant structural changes in the excited state and in the ground state, and accordingly, the Stoke's shift may be greatly reduced to allow blue light having high color purity to be emitted. Accordingly, when the fused polycyclic compound according to one or more embodiments of the present disclosure is introduced as a dopant for an emission layer, luminous efficiency and color purity may be improved.

Table 1 shows measured dihedral angles of Example compounds and Comparative Example compounds. In the measuring of dihedral angles, Example Compound 309 and Comparative Example Compound C1 sharing a similar structure were utilized as follows. Comparative Example Compound C1 differs from Example Compound 309 in that the Compound C1 does not include the triazine moiety and has a structure in which the phenyl moiety is bonded to the nitrogen atom of the fused ring core. In the structures of Example Compound 309 and Comparative Example Compound C1, “a”, “b”, “c”, “d”, “1”, “2”, “3”, and “4” are utilized for convenience of description.

In Table 1, θ₁ to θ₄ each indicate a dihedral angle between a triazine core or a phenyl core and a terminal substituent linked thereto in Example compounds or Comparative Example compounds. In Example 1, θ₁ indicates a dihedral angle between the “a” triazine core and the “1” phenyl group, θ₂ indicates the dihedral angle between the “a” triazine core and the “2” phenyl group, θ₃ indicates a dihedral angle between the “b” triazine core and the “3” phenyl group, and θ₄ indicates a dihedral angle between the “b” triazine core and the “4” phenyl group. In addition, in Comparative Example 1, θ₁ indicates a dihedral angle between the “c” phenyl core and the “1” phenyl group, θ₂ indicates a dihedral angle between the “c” phenyl core and the “2” phenyl group, θ₃ indicates a dihedral angle between the “d” phenyl core and the “3” phenyl group, and θ₄ indicates a dihedral angle between the “d” phenyl core and the “4” phenyl group.

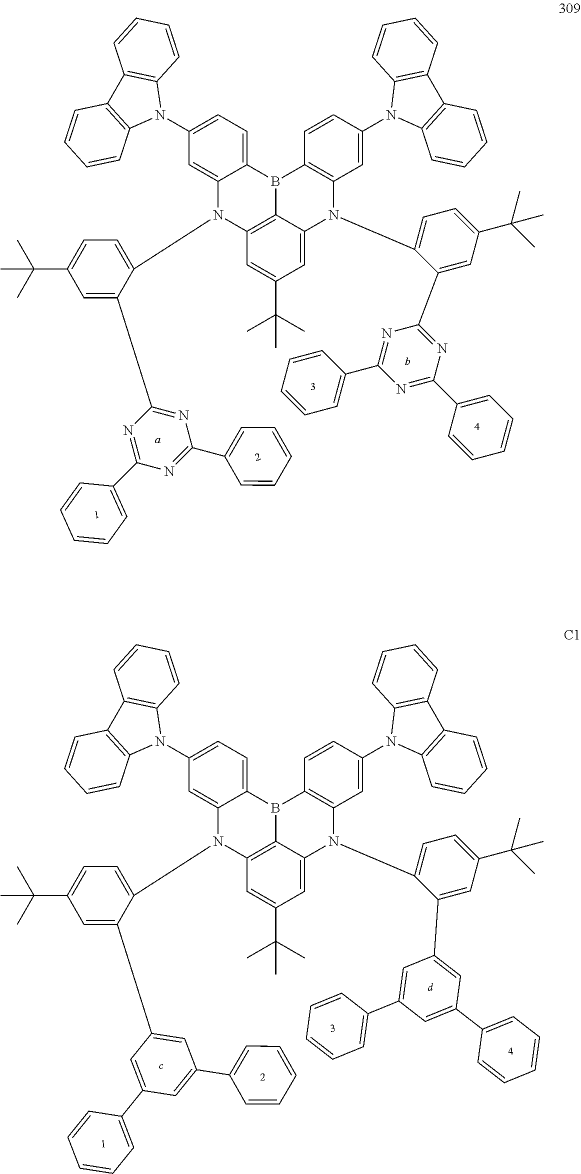

TABLE 1

| Item | Compound | θ₁ | θ₂ | θ₃ | θ₄ |
|---|---|---|---|---|---|
| Example 1 | Compound 309 | 3.18 | 19.29 | 3.21 | 20.47 |
| Comparative | Comparative | | | | |
| Example 1 | Example | 43.56 | 50.32 | 50.07 | 45.50 |
| | Compound C1 | | | | |

Referring to Table 1, it is seen that the dihedral angles of θ₁ to θ₄ in Example 1 were reduced compared to Comparative Example 1. Example compounds include the triazine moiety, and may thus reduce the dihedral angle between the triazine moiety and the terminal substituent linked thereto. Accordingly, intramolecular movement in the Example compounds may be suppressed or reduced compared to the Comparative Example compounds, and Stoke's shift may be reduced to increase photoluminescence quantum yield (PLQY) and intermolecular fluorescence resonance energy transfer (FRET).

In one or more embodiments of the fused polycyclic compound represented by Formula 1, the triazine moiety may be linked to the nitrogen atom of the fused ring core through a phenyl moiety. Any one of the six carbon atoms constituting the phenyl moiety may be linked to the triazine moiety, and among the other five carbons, the carbon positioned ortho to the carbon atom to which the triazine moiety is linked may be linked to the nitrogen atom. For example, the triazine moiety and the nitrogen atom may be linked to the phenyl moiety to be positioned ortho. Due to this specific linkage relationship, the fused polycyclic compound of one or more embodiments has a structure in which the first substituent covers the boron atom at the top and bottom with respect to a plate-like structure of the fused ring core, thereby achieving the effect of effectively protecting the boron atom. In addition, as described above in Table 1, the fused polycyclic compound of one or more embodiments may have minimal movement in the form in which the first substituent covers the boron atom as the dihedral angle between the triazine core and the terminal substituent linked thereto is reduced, and may maintain a bulkiness structure compared to the Comparative Example compound having a phenyl core instead of a triazine core.

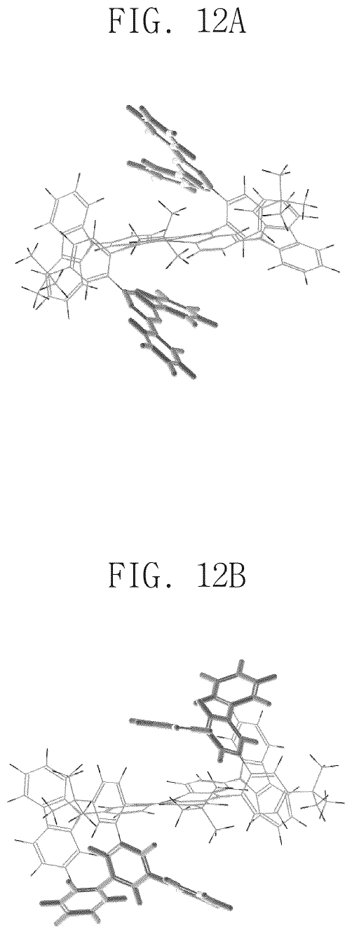

FIG. 12A and FIG. 12B are views showing three-dimensional molecular models of Example compounds and Comparative Example compounds, respectively. FIG. 12A is a view showing a three-dimensional molecular model of Example compound 309, and FIG. 12B is a view showing a three-dimensional molecular model of Comparative Example compound C1.

Referring to FIG. 12A and FIG. 12B, Example Compound 309 has a structure in which the first substituent including a triazine moiety covers the boron atom at the top and bottom with respect to a plate-like structure of the fused ring core, making it hard for external nucleophiles, radicals, and/or decomposition products in the light-emitting element to access and having a steric hindrance effect that interferes with Dexter energy transfer to increase service life and efficiency. On the other hand, compared to the structure of Example Compound 309, Comparative Example Compound C1 has a structure in which the triazine moiety is not included and the phenyl moiety is bonded to the nitrogen atom of the fused ring core, and thus Comparative Example Compound C1 may have a greater dihedral angle between the phenyl moiety and the terminal substituent than Example Compound 309. Accordingly, Comparative Example Compound C1 may have a reduced effect in the boron atom protection compared to the Example compounds, and may have a reduced effect of reducing intermolecular interactions or a reduced effect of lowering the triplet energy concentration by inhibiting Dexter energy transfer. Therefore, the Example compounds have a structure in which the triazine moiety is included, and the triazine moiety and the nitrogen atom are linked to the phenyl moiety be positioned ortho, and may thus exhibit excellent or suitable luminous efficiency and improved element characteristics.

An emission spectrum of the fused polycyclic compound represented by Formula 1 has a full width at half maximum of about 10 nm to about 50 nm, or about 20 nm to about 40 nm. As the emission spectrum of the polycyclic compound of one or more embodiments represented by Formula 1 has a full width at half maximum in the above range, luminous efficiency may be improved when the fused polycyclic compound of one or more embodiments is applied to a light-emitting element. In one or more embodiments, element service life may be improved when the fused polycyclic compound of one or more embodiments is utilized as a blue light emitting element material for a light emitting element.

In one or more embodiments, the fused polycyclic compound represented by Formula 1 may be a thermally activated delayed fluorescence emitting material. In one or more embodiments, the fused polycyclic compound represented by Formula 1 may be a thermally activated delayed fluorescence dopant having a difference ΔE_{ST} between a lowest triplet excitation energy level (T1 level) and a lowest singlet excitation energy level (S1 level) of 0.6 eV or less. In one or more embodiments, the fused polycyclic compound represented by Formula 1 may be a thermally activated delayed fluorescence dopant having a difference ΔE_{ST} between a lowest triplet excitation energy level (T1 level) and a lowest singlet excitation energy level (S1 level) of 0.2 eV or less. However, embodiments of the present disclosure are not limited thereto.

In one or more embodiments, the fused polycyclic compound represented by Formula 1 may include a first substituent and a second substituent in the compound. By adjusting the number and substitution positions of the first and second substituents, the singlet energy level and triplet energy level of the overall compound may be appropriately adjusted. Accordingly, the fused polycyclic compound according to one or more embodiments of the present disclosure may exhibit improved thermally activated delayed fluorescence properties.

In one or more embodiments, the fused polycyclic compound represented by Formula 1 may have a small difference (ΔE_{T1T2}) between a lowest triplet excitation energy level (T1 level) and a second triplet excitation energy level (T2 level). In one or more embodiments, the difference (ΔE_{T1T2}) between the lowest triplet excitation energy level (T1 level) and the second triplet excitation energy level (T2 level) of the fused polycyclic compound represented by Formula 1 may be 0.2 eV or less. When the difference (ΔE_{T1T2}) between the lowest triplet excitation energy level (T1 level) and the second triplet excitation energy level (T2 level) of the fused polycyclic compound satisfies the range described above, reverse inter system crossing (RISC) rate may be increased.

In a compound that exhibit thermally activated delayed fluorescence properties, inter system crossing (ICS), in which energy is transferred from a lowest singlet energy level to a triplet energy level takes place, and then the reverse inter system crossing (RISC) takes place from the triplet energy level to the singlet energy level with higher energy, and finally, delayed fluorescence is shown with transitions from the singlet energy level to a ground state. In this case, the thermally activated delayed fluorescence mechanism may also include passing through a higher triplet energy level (Tn level) in the inter system crossing (ICS) and reverse inter system crossing (RISC). When the difference (ΔE_{T1T2}) between the lowest triplet excitation energy level (T1 level) and the second triplet excitation energy level (T2 level) of the fused polycyclic compound is small, the exciton that has undergone inter system crossing (ICS) from the lowest singlet energy level (S1 level) to the lowest triplet energy level (T1 level) may easily move to the second triplet energy level (T2 level) through reverse internal conversion (RIC), and finally, the rate of reverse inter system crossing (RISC) from the second triplet energy level (T2 level) to the lowest singlet energy level (S1 level) may be increased, resulting in improved luminous efficiency.

In one or more embodiments, the fused polycyclic compound represented by Formula 1 may include a first substituent and a second substituent in the compound. The difference (ΔE_{T1T2}) between the lowest triplet energy level (T1 level) and the second triplet energy level (T2 level) throughout the compound may be appropriately regulated by adjusting the number and substitution positions of the first and second substituents. The relationship between the lowest triplet energy level (T1 level) and the second excitation triplet energy level (T2 level) of the fused polycyclic compound according to one or more embodiments may satisfy Equation 1.

$$Δ {E}_{T 1 T 2} = T 2 - T 1 \leq 0.2 eV \qquad Equation 1$$

The fused polycyclic compound of one or more embodiments represented by Formula 1 may be a light emitting material having a central emission wavelength in a wavelength range of about 430 nm to about 490 nm. For example, in one or more embodiments, the fused polycyclic compound of one or more embodiments represented by Formula 1 may be a blue thermally activated delayed fluorescence (TADF) dopant. However, embodiments of the present disclosure are not limited thereto, and when the fused polycyclic compound of one or more embodiments is utilized as a light emitting material, the fused polycyclic compound may be utilized as a dopant material emitting light in one or more suitable wavelength ranges, such as a red light emitting dopant or a green light emitting dopant.

In the light emitting element ED of one or more embodiments, the emission layer EML may be to emit delayed fluorescence. For example, in one or more embodiments, the emission layer EML may be to emit light of thermally activated delayed fluorescence (TADF).

In one or more embodiments, the emission layer EML of the light emitting element ED may be to emit blue light. For example, in one or more embodiments, the emission layer EML of the light emitting element ED may be to emit blue light in a wavelength range of about 490 nm or less. However, embodiments of the present disclosure are not limited thereto, and the emission layer EML may be to emit green light or red light.

In one or more embodiments, the fused polycyclic compound of one or more embodiments may be included in the emission layer EML. The fused polycyclic compound of one or more embodiments may be included in the emission layer EML as a dopant material. The fused polycyclic compound of one or more embodiments may be a thermally activated delayed fluorescence material. The fused polycyclic compound of one or more embodiments may be utilized as a thermally activated delayed fluorescence dopant. For example, in the light emitting element ED of one or more embodiments, the emission layer EML may include at least one selected from among the fused polycyclic compounds shown in Compound Group 1 described herein as a thermally activated delayed fluorescence dopant. However, the utilization of the fused polycyclic compound of one or more embodiments is not limited thereto.

In one or more embodiments, the emission layer EML may include multiple compounds. In some embodiments, the emission layer EML may include the fused polycyclic compound represented by Formula 1, i.e., the first compound, and at least one selected from among a second compound represented by Formula HT-1, a third compound represented by Formula ET-1, and a fourth compound represented by Formula D-1.

In one or more embodiments, the emission layer EML may include the first compound represented by Formula 1 and further include at least one selected from among a second compound represented by Formula HT-1 and a third compound represented by Formula ET-1.

In one or more embodiments, the emission layer EML may include a second compound represented by Formula HT-1. In some embodiments, the second compound may be utilized as a hole transport host material in the emission layer EML.

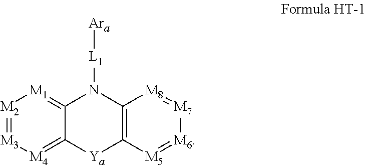

In Formula HT-1, M₁ to M₈ may each independently be N or CR₅₁. For example, in some embodiments, all M₁ to M₈ may be CR₅₁. In some embodiments, any one among M₁ to M₈ may be N, and the remainder may be CR₅₁.

In Formula HT-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, in some embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, it may refer to that two benzene rings connected with the nitrogen atom of Formula HT-1 may be connected via a direct linkage,

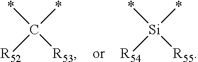

In Formula HT-1, when Yₐ is a direct linkage, the compound represented by Formula HT-1 may include a carbazole moiety.

In Formula HT-1, Arₐ may be a substituted or unsubstituted aryl group of 6 to 30 ring-forming carbon atoms or a substituted or unsubstituted heteroaryl group of 2 to 30 ring-forming carbon atoms. For example, in one or more embodiments, Arₐ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, one or more selected from among R₅₁ to R₅₅ may be combined with an adjacent group to form a ring. For example, in some embodiments, R₅₁ to R₅₅ may each independently be hydrogen or deuterium. In some embodiments, R₅₁ to R₅₅ may each independently be an unsubstituted methyl group or an unsubstituted phenyl group.

In one or more embodiments, the second compound represented by Formula HT-1 may be represented by any one selected from among compounds represented in Compound Group 2. The emission layer EML may include at least one selected from among the compounds represented in Compound Group 2 as a hole transport host material.

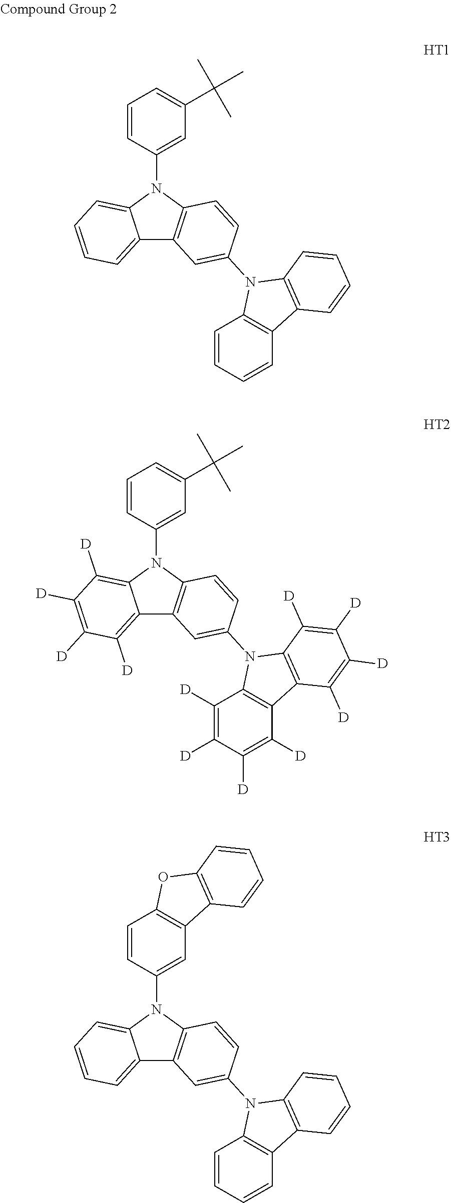 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

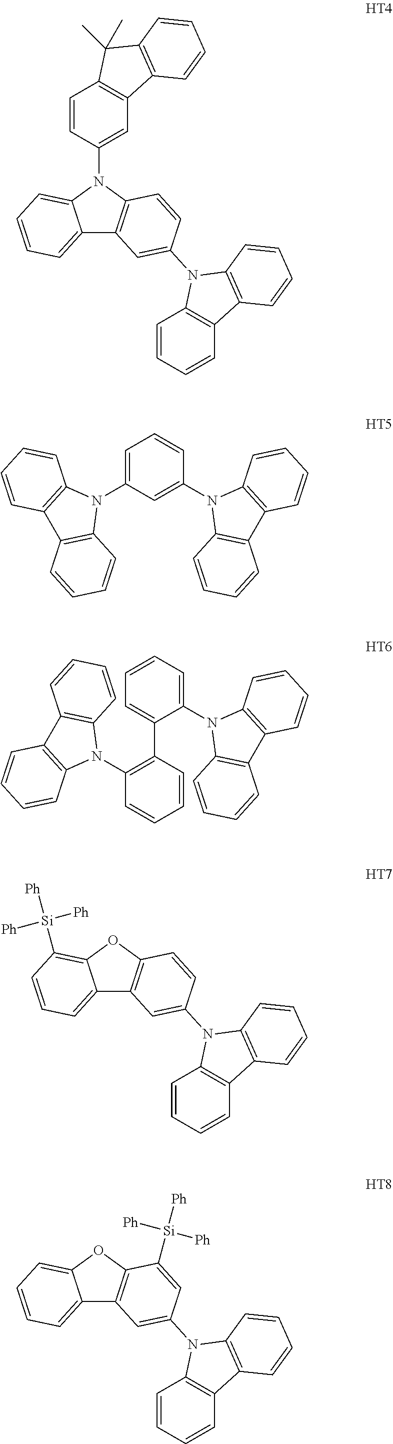 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

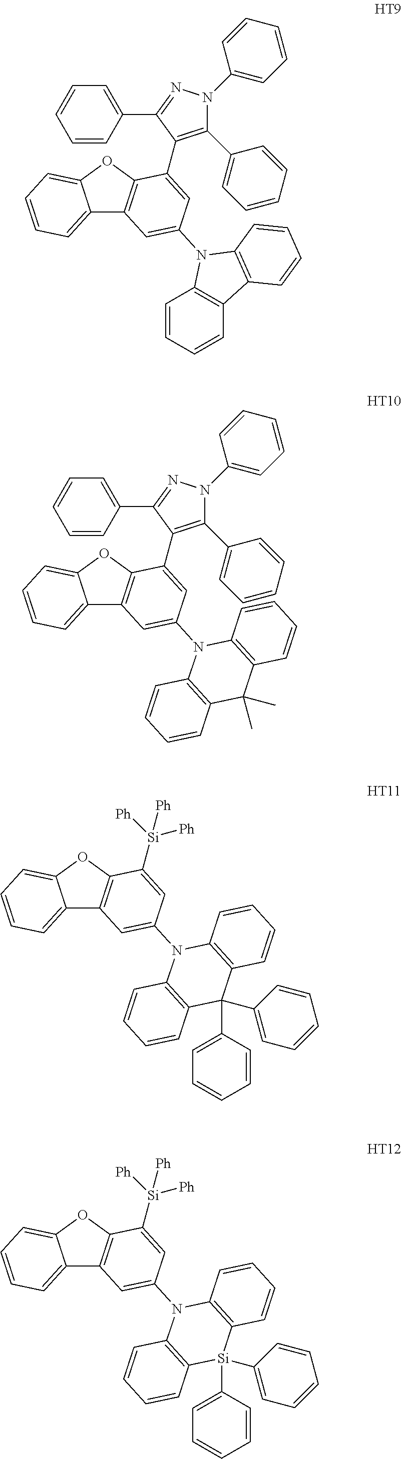 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

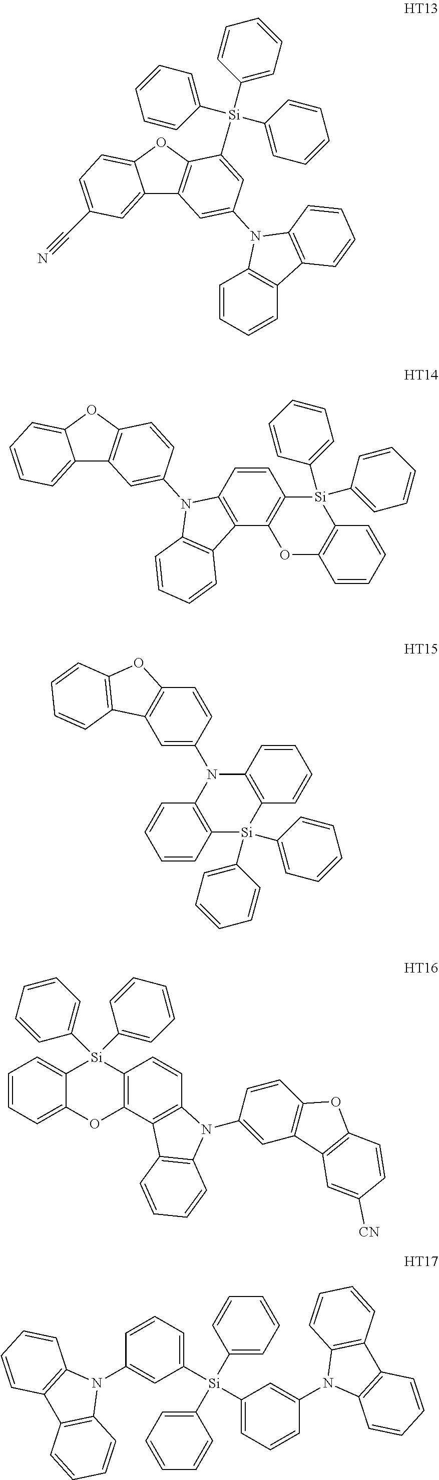 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

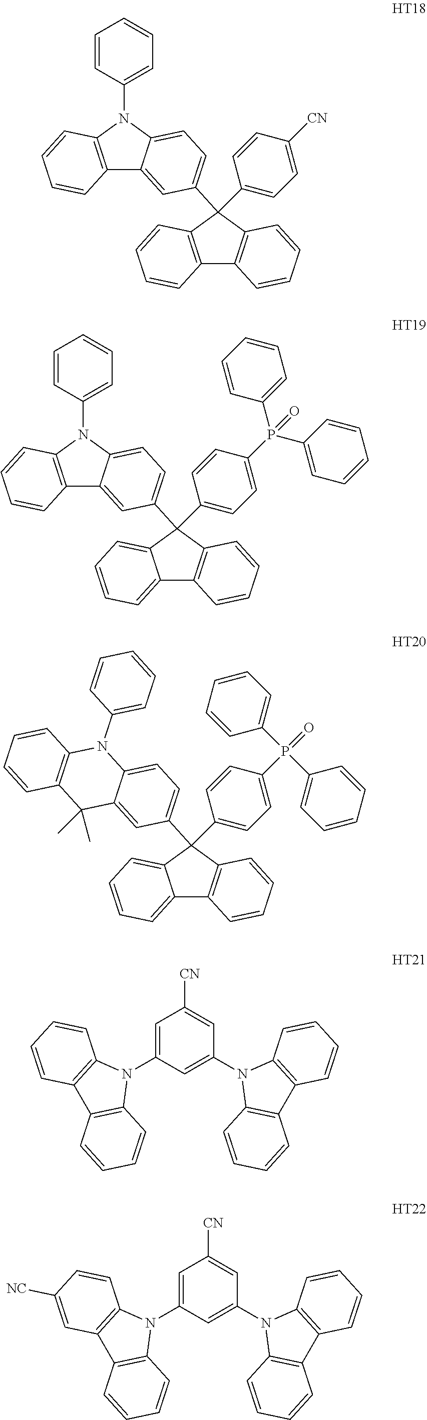 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

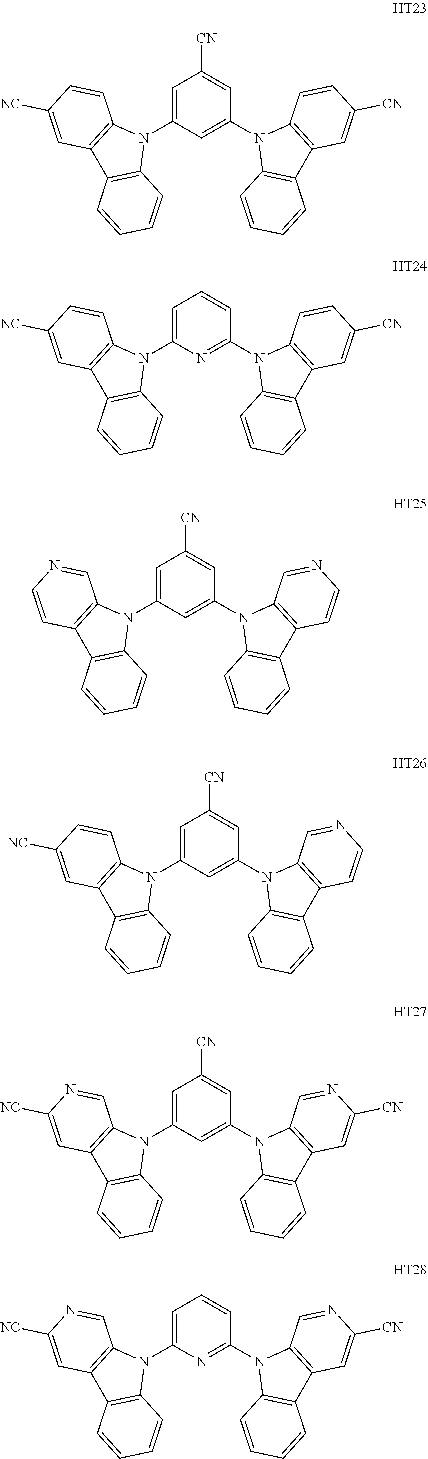 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

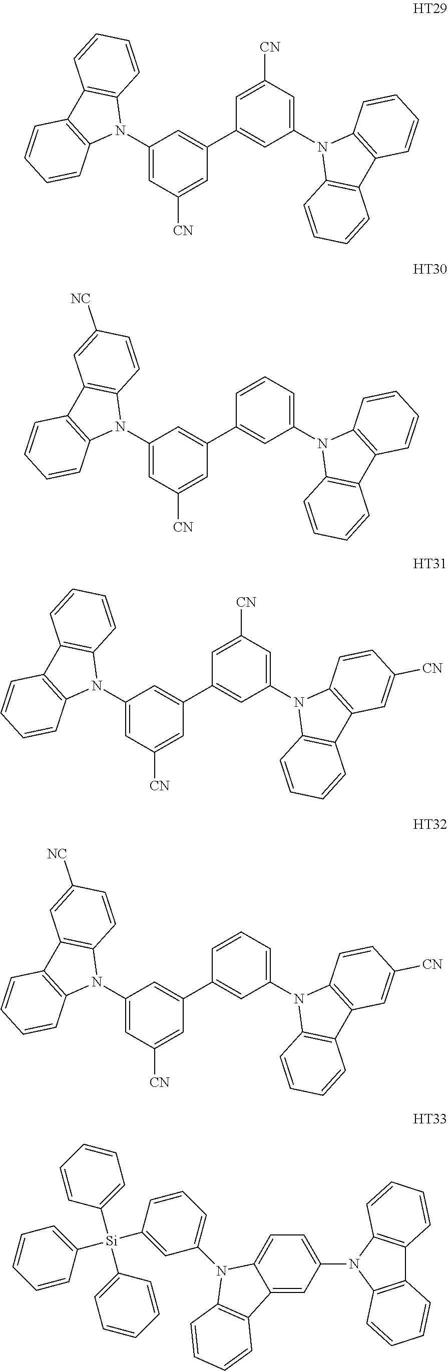 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cc(C#N)cc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

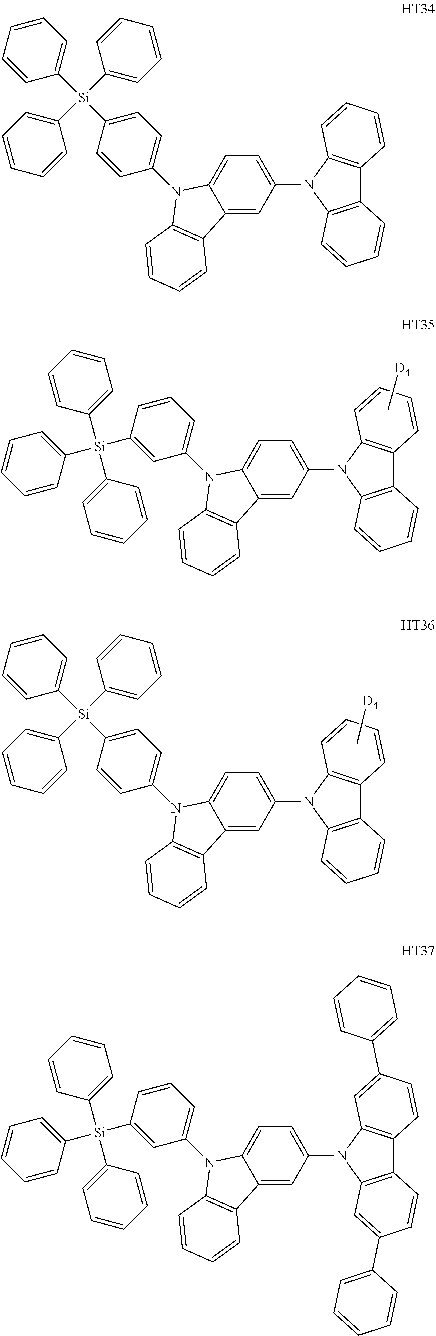

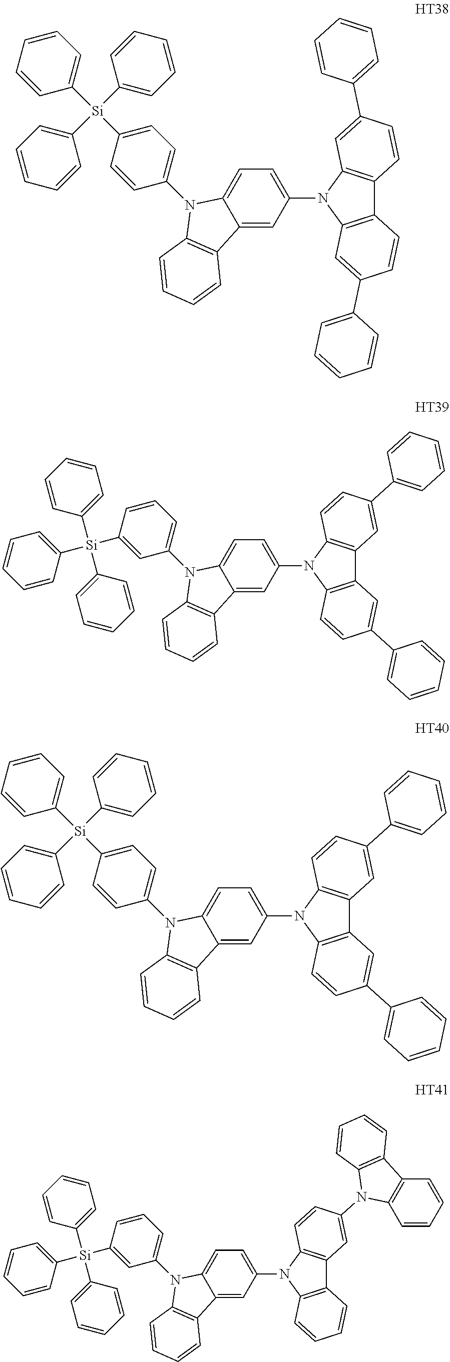 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

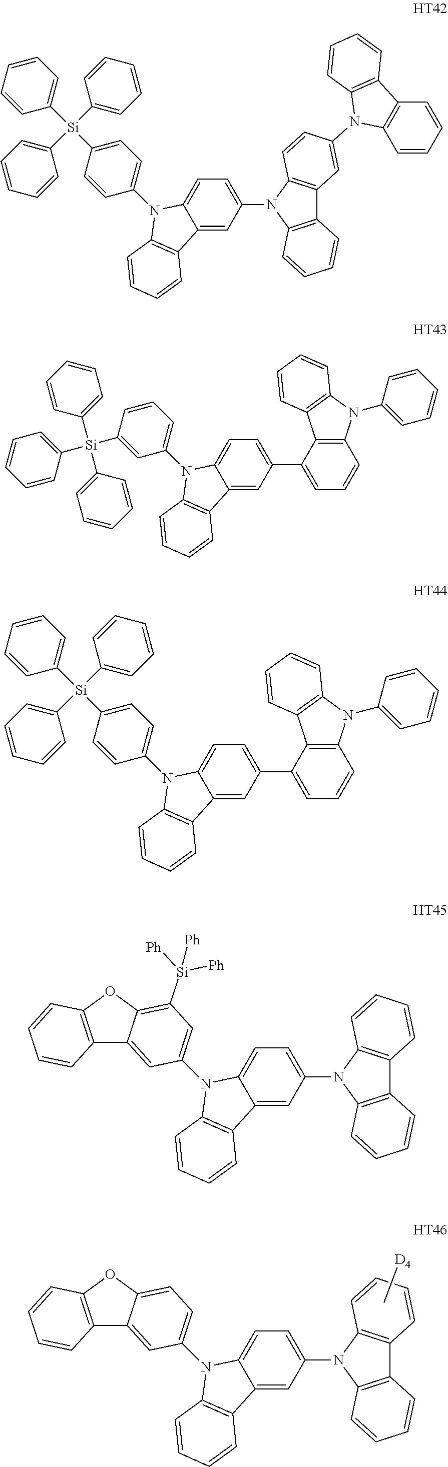

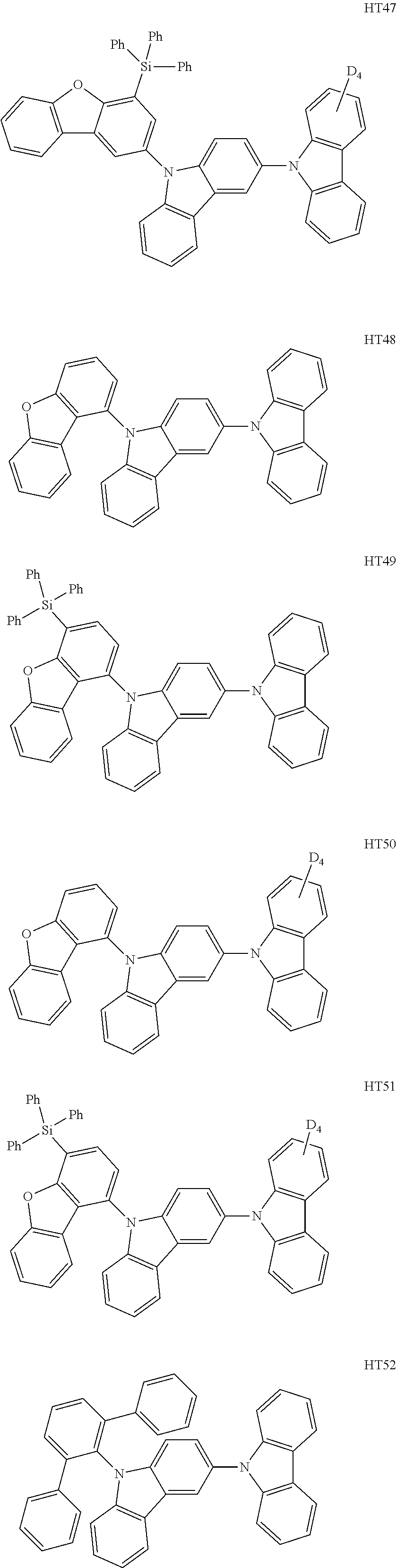

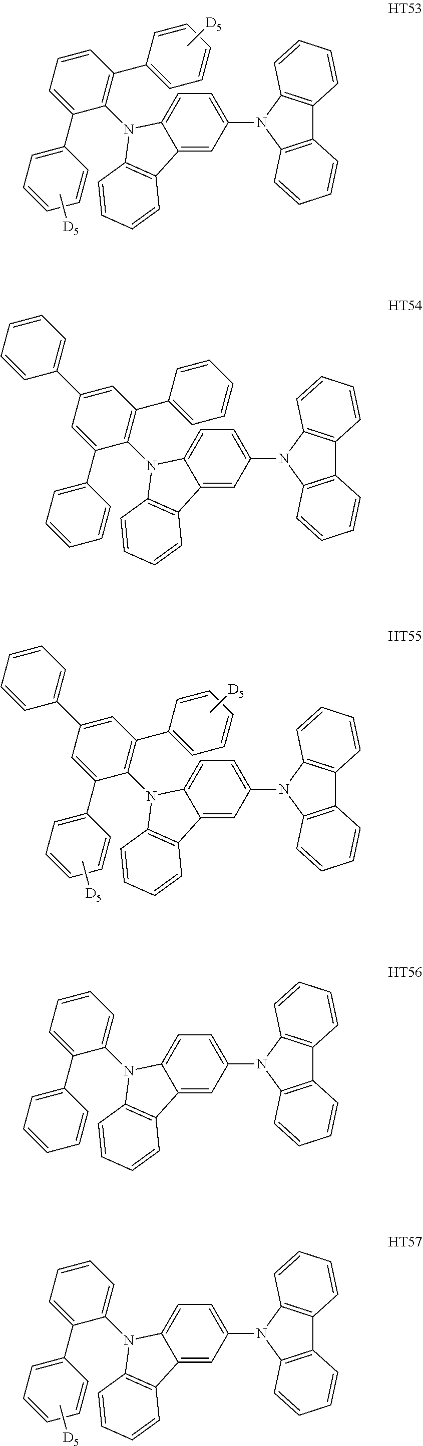

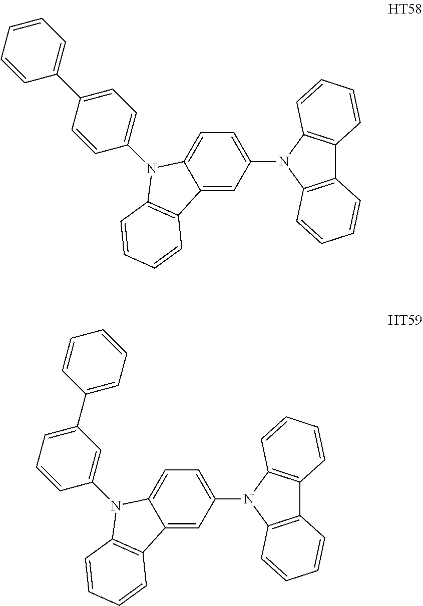 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the example compounds in Compound Group 2, “D” refers to deuterium, and “Ph” may refer to a substituted or unsubstituted phenyl group. For example, in the example compounds in Compound Group 2, “Ph” may be an unsubstituted phenyl group.

In one or more embodiments, the emission layer EML may include a third compound represented by Formula ET-1. For example, in one or more embodiments, the third compound may be utilized as an electron transport host material in the emission layer EML.

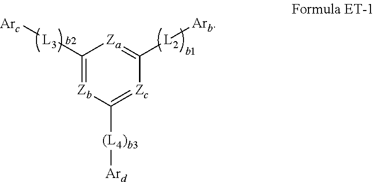

In Formula ET-1, at least one selected from among Zₐ to Z_{c} may be N, and the remainder may be CR₅₆. For example, in some embodiments, one selected from among Zₐ to Z_{c} may be N, and the remainder two may each independently be CR₅₆. In these embodiments, the third compound represented by Formula ET-1 may include a pyridine moiety. In some embodiments, two selected from among Zₐ to Z_{c} may be N, and the remainder may be CR₅₆. In these embodiments, the third compound represented by Formula ET-1 may include a pyrimidine moiety. In some embodiments, Zₐ to Z_{c} may be all N. In these embodiments, the third compound represented by Formula ET-1 may include a triazine moiety.

In Formula ET-1, R₅₆ may be hydrogen, deuterium, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms.

In Formula ET-1, b1 to b3 may each independently be an integer of 0 to 10.

In Formula ET-1, Ar_{b} to Ar_{d} may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, in some embodiments, Ar_{b} to Ar_{d} may be substituted or unsubstituted phenyl groups or substituted or unsubstituted carbazole groups.

In Formula ET-1, L₂ to L₄ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when each of b1 to b3 is an integer of 2 or more, L₂'s to L₄'s may each independently be a substituted or unsubstituted arylene group of 6 to 30 ring-forming carbon atoms or a substituted or unsubstituted heteroarylene group of 2 to 30 ring-forming carbon atoms.

In one or more embodiments, the third compound may be represented by any one selected from among compounds in Compound Group 3. The light emitting element ED of one or more embodiments may include any one selected from among the compounds in Compound Group 3.

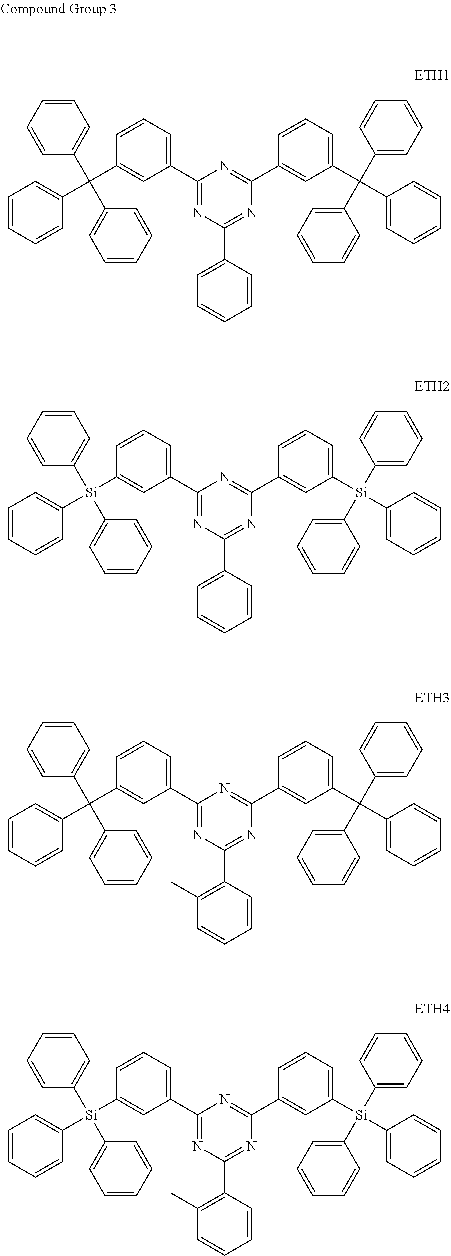 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

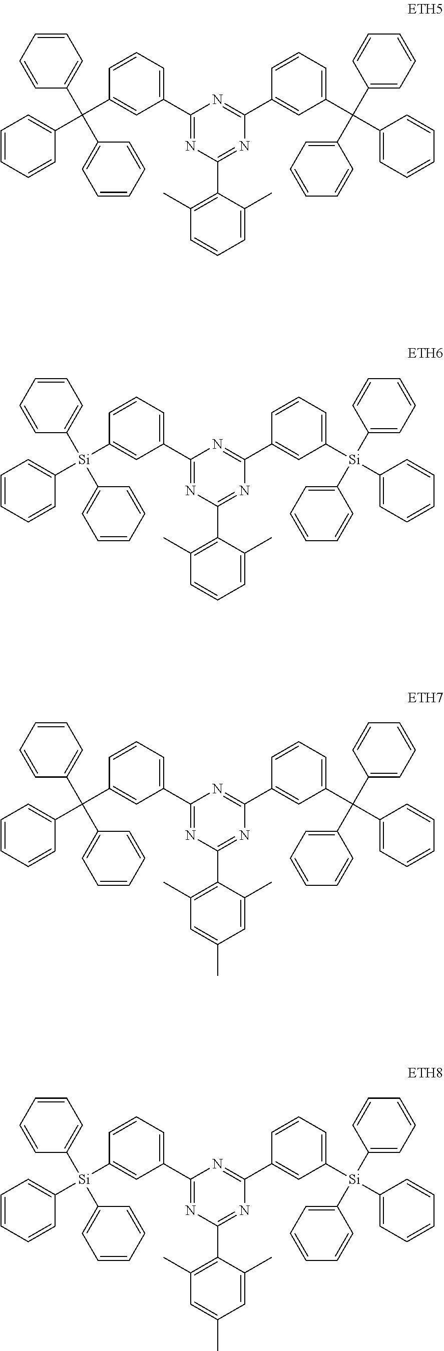 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

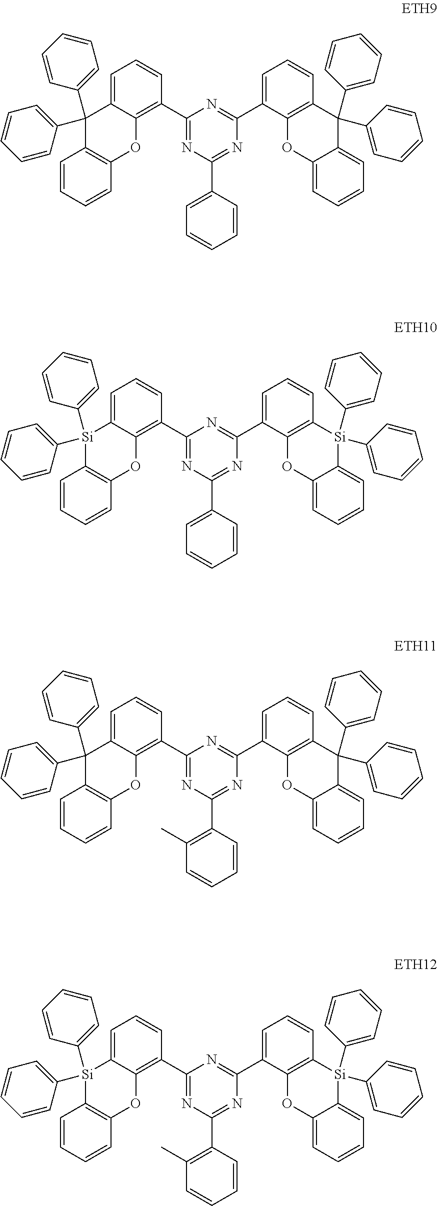 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

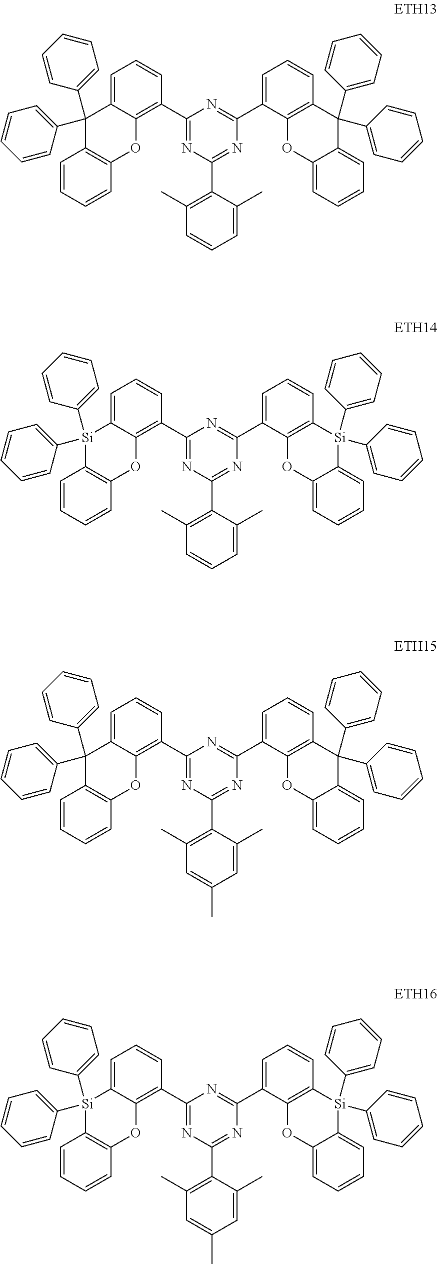 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

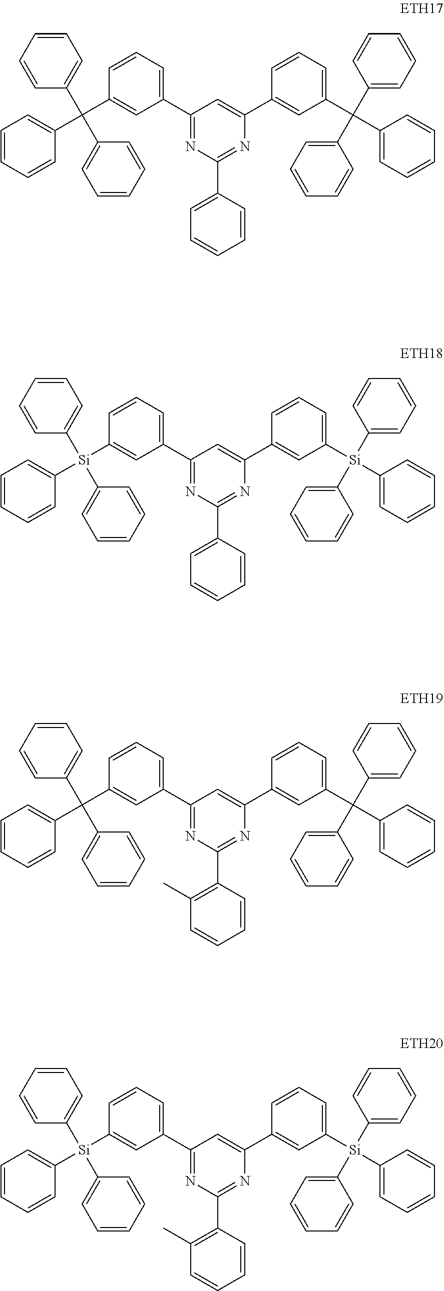 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

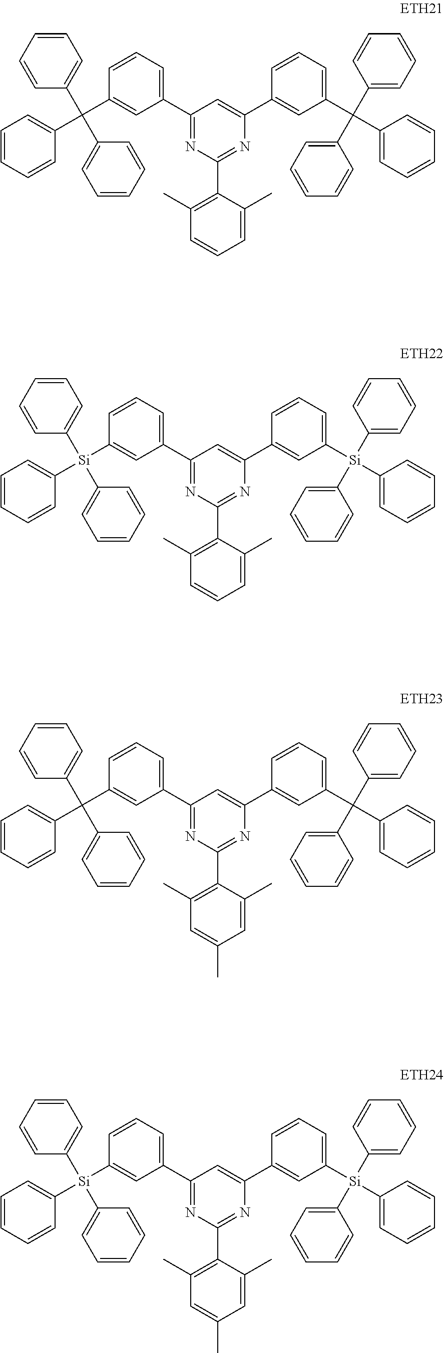 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

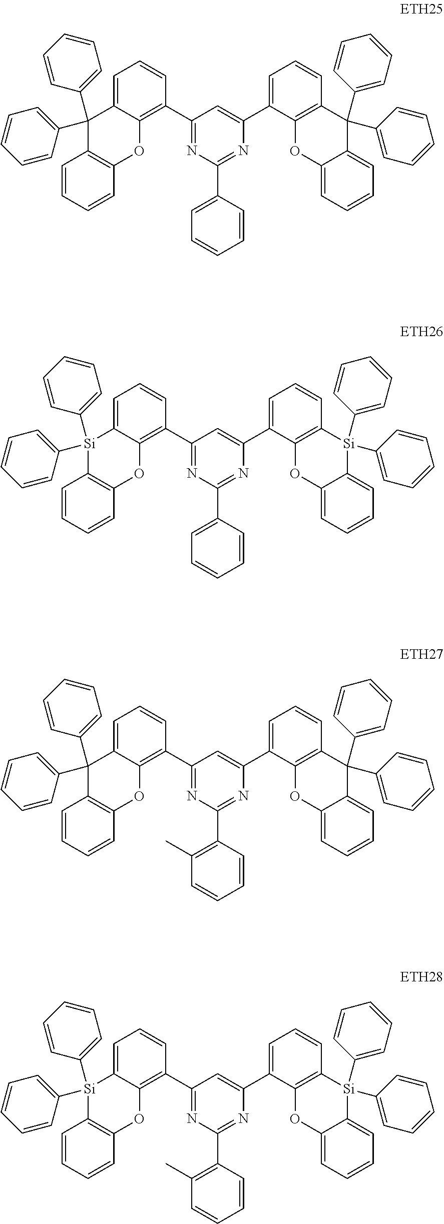 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

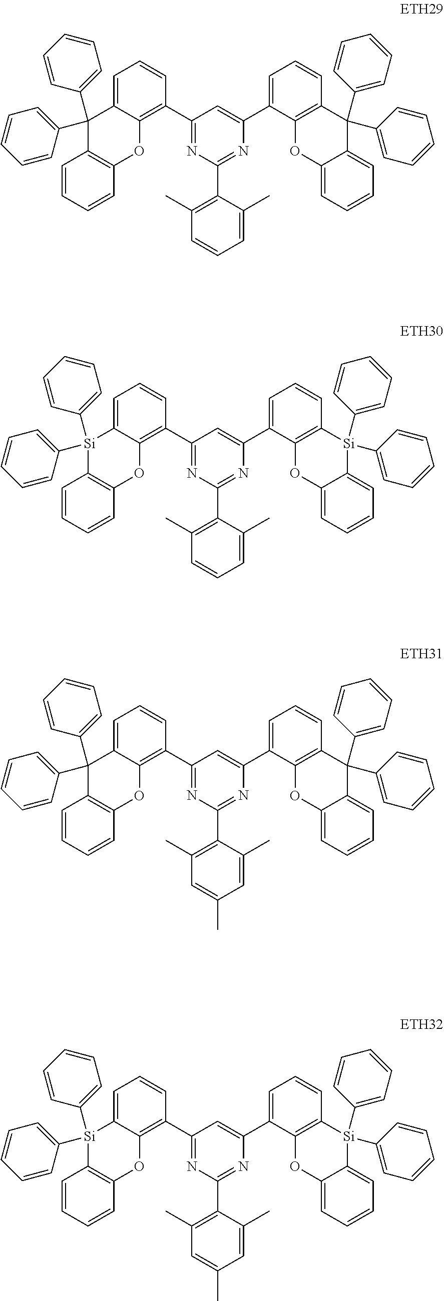 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

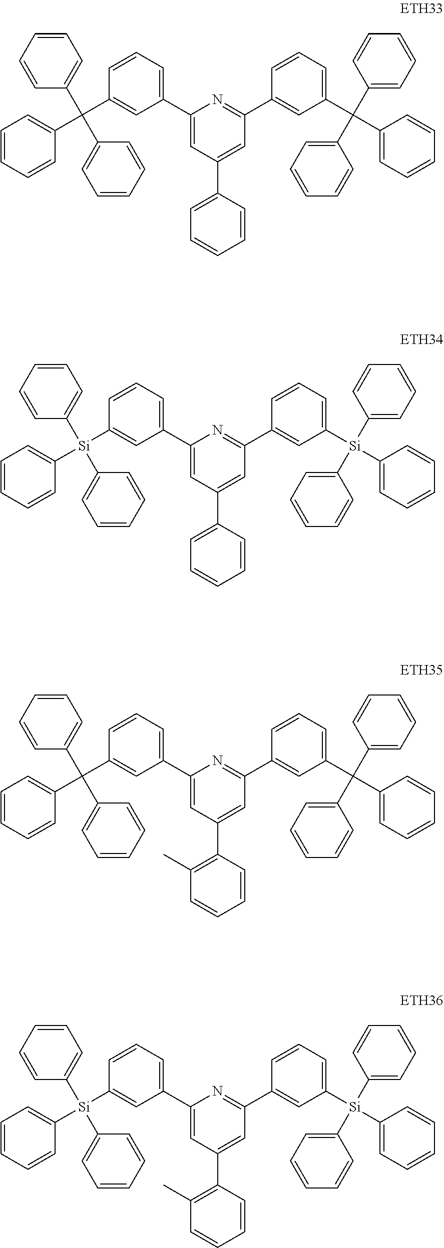 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

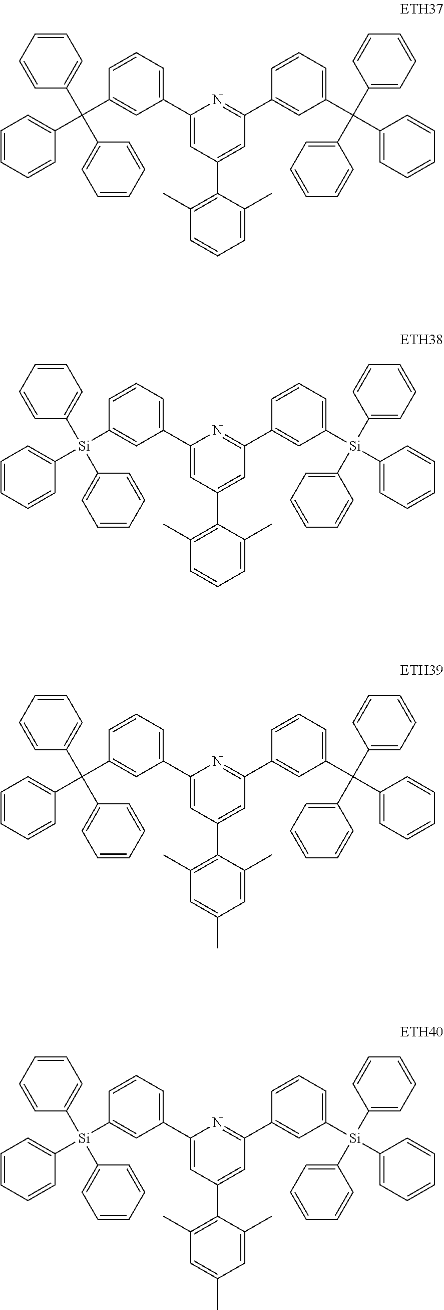 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

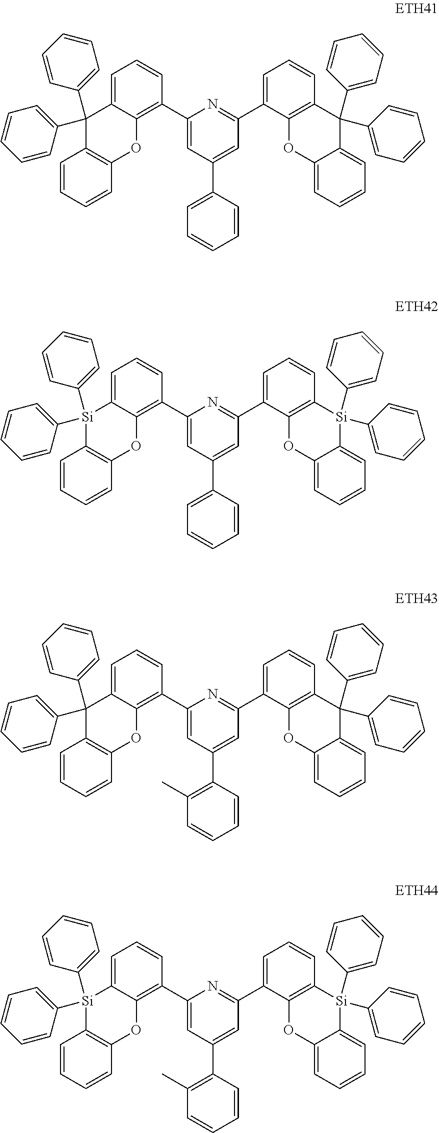 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

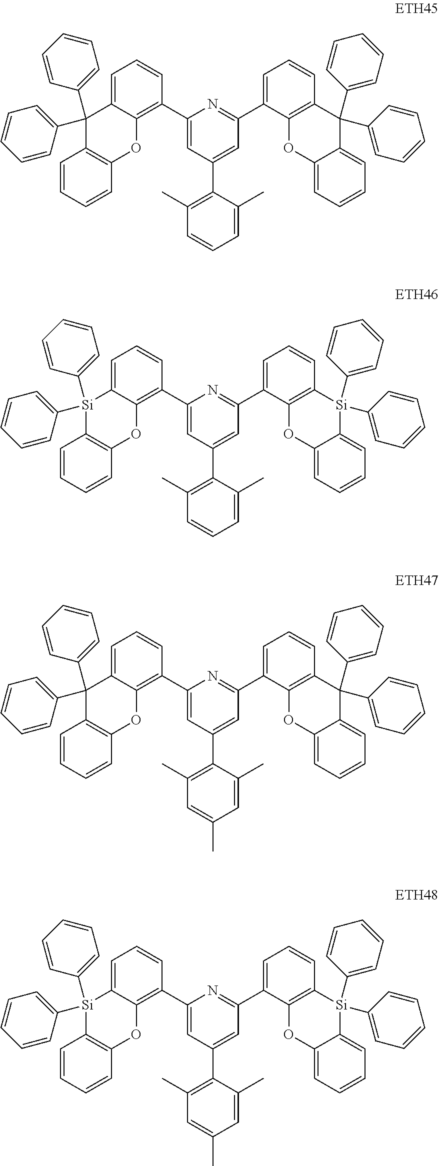 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

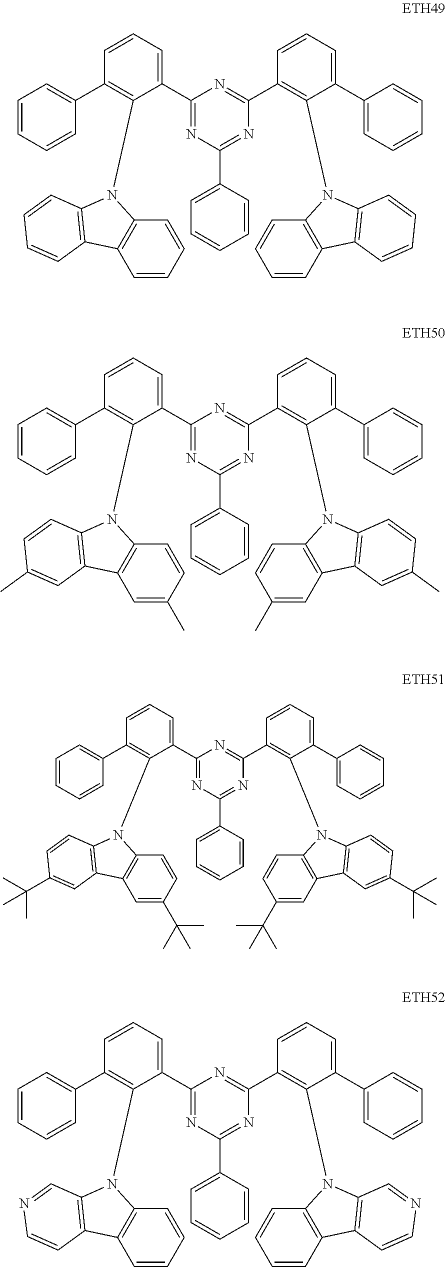

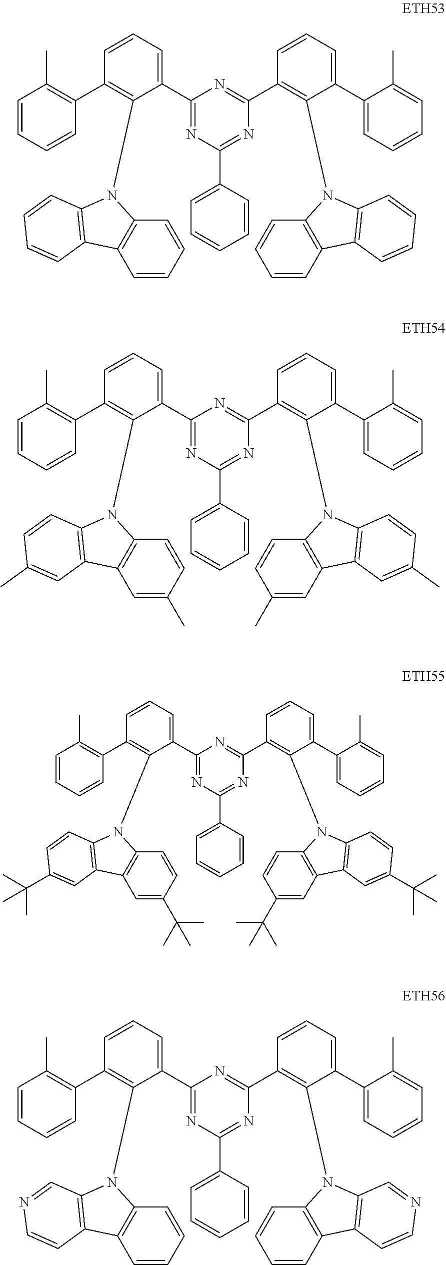

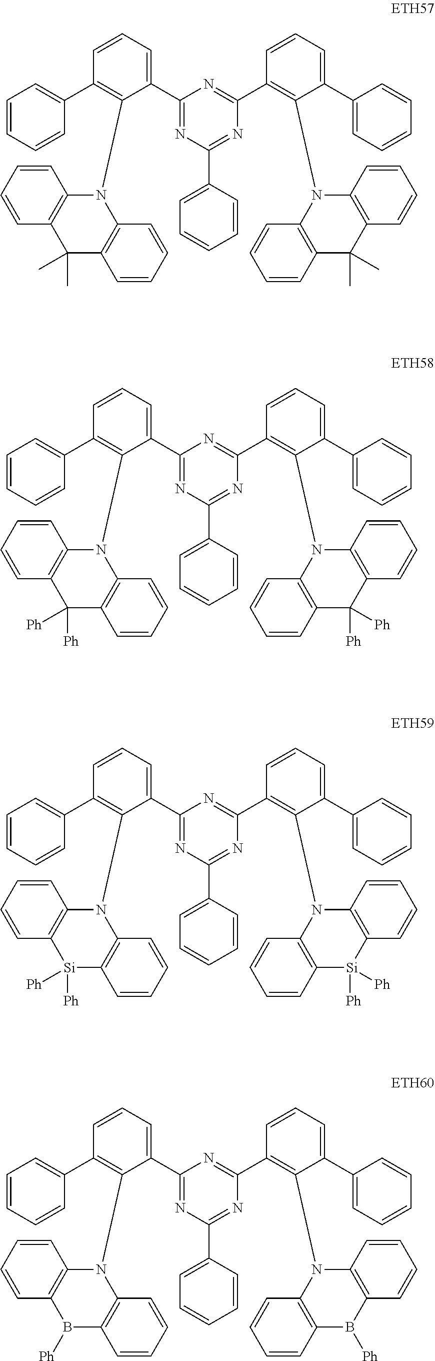

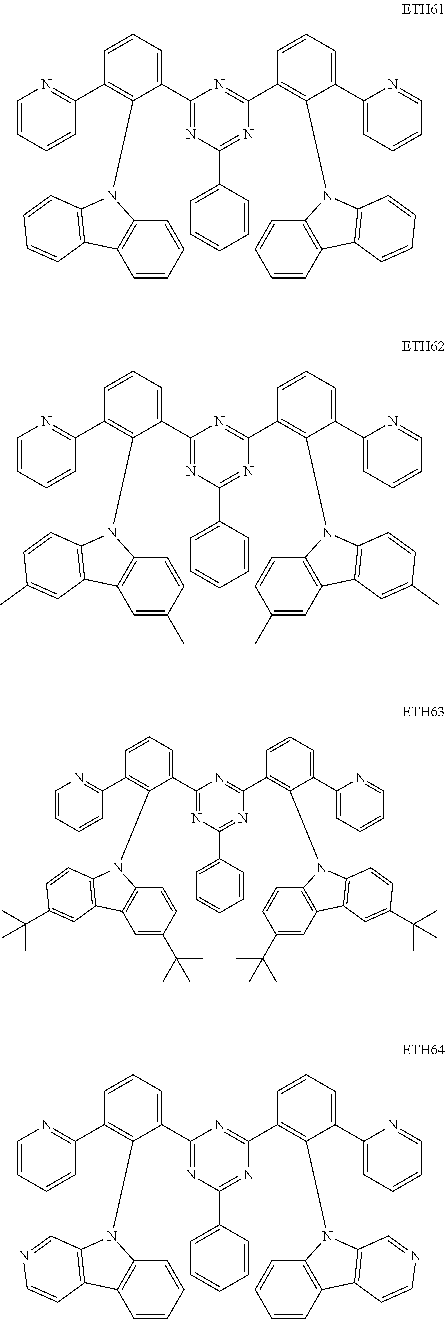

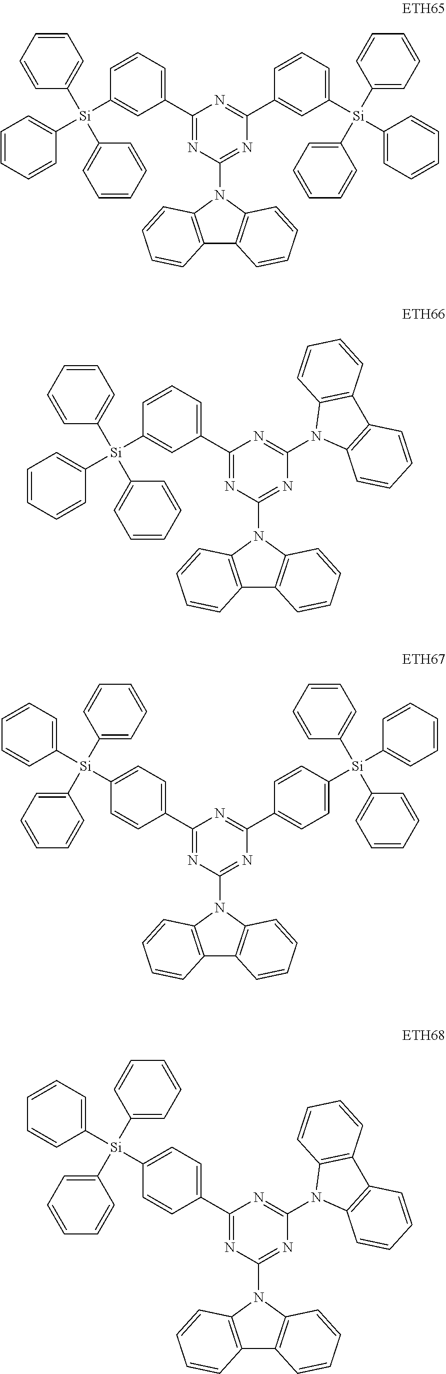 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

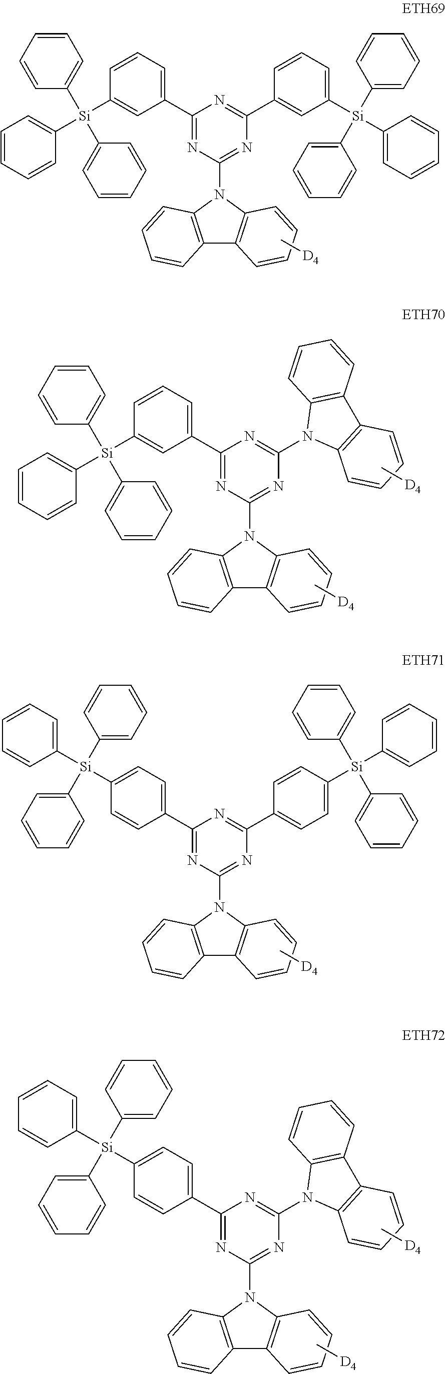

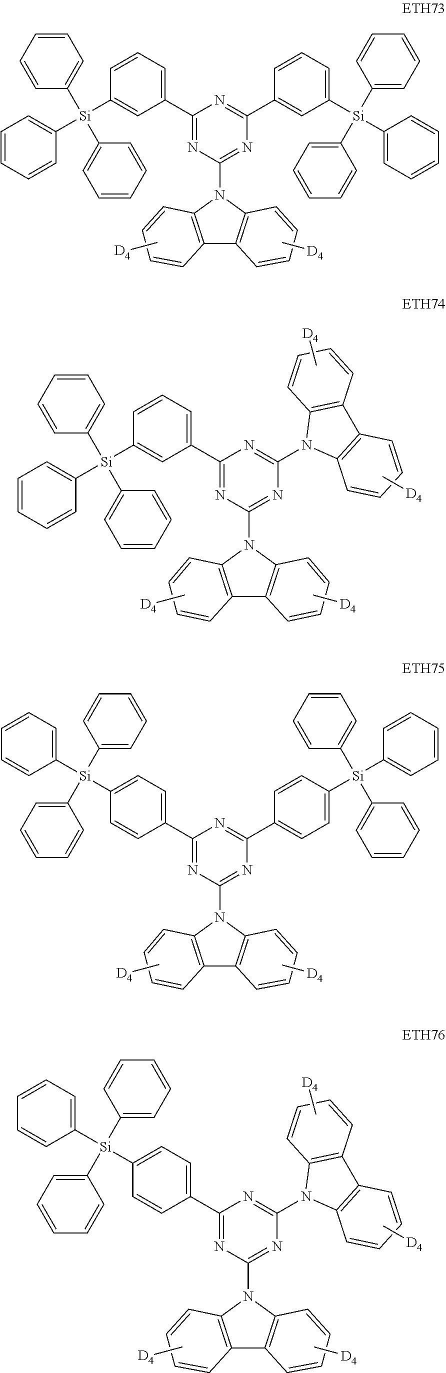

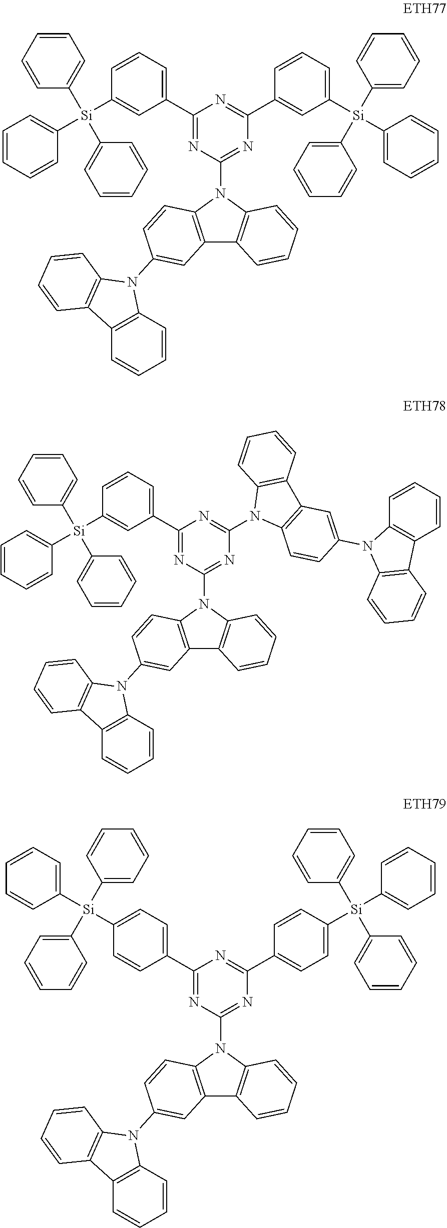 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

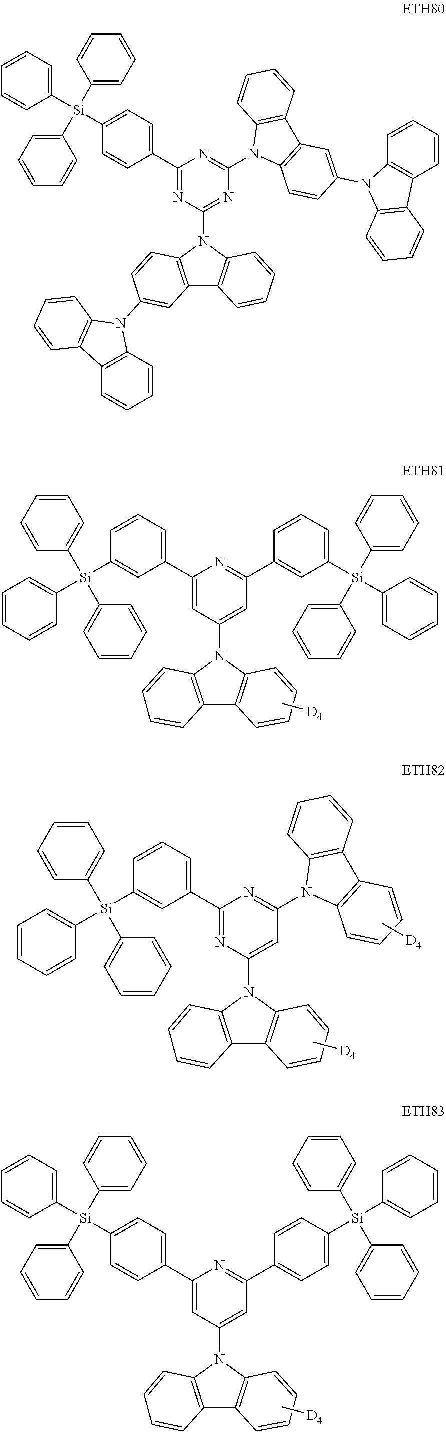

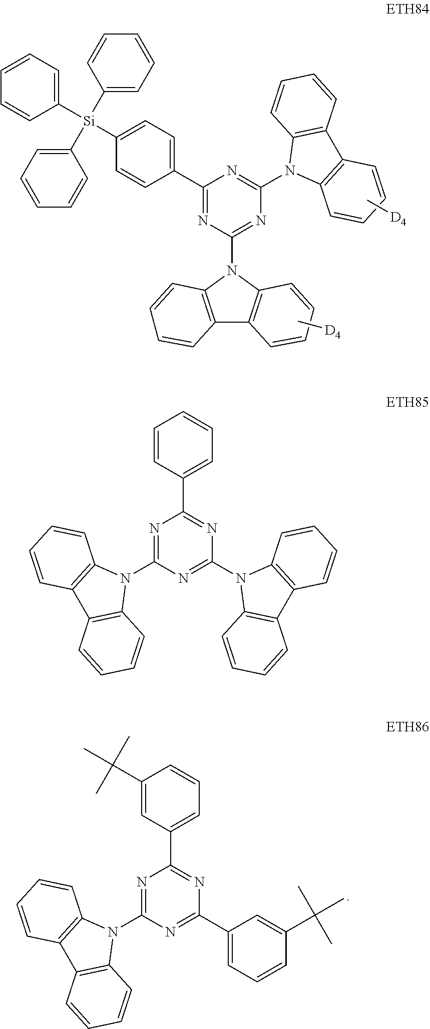

In the example compounds in Compound Group 3, “D” refers to deuterium, and “Ph” refers to an unsubstituted phenyl group.

In one or more embodiments, the emission layer EML may include the second compound and the third compound, and the second compound and the third compound may form exciplex. In the emission layer EML, exciplex may be formed by a hole transport host and an electron transport host. In this case, the triplet energy of the exciplex formed by the hole transport host and the electron transport host may correspond to a difference between a lowest unoccupied molecular orbital (LUMO) energy level of the electron transport host and a highest occupied molecular orbital (HOMO) energy level of the hole transport host.

For example, in one or more embodiments, an absolute value of a triplet energy level (T1) of the exciplex formed by the hole transport host and the electron transport host may be about 2.4 eV to about 3.0 eV. In some embodiments, the triplet energy of the exciplex may be a smaller value than the energy gap of each host material. The exciplex may have a triplet energy of about 3.0 eV or less, that is the energy gap between the hole transport host and the electron transport host.

In one or more embodiments, the emission layer EML may include a fourth compound in addition to the first compound to the third compound. The fourth compound may be utilized as a phosphorescence sensitizer of the emission layer EML. Because energy may transfer from the fourth compound to the first compound, light emission may arise.

For example, in one or more embodiments, the emission layer EML may include an organometallic complex including platinum (Pt) as a central metal atom and ligands bonded to the central metal atom, as the fourth compound. In the light emitting element ED of one or more embodiments, the emission layer EML may include a compound represented by Formula D-1 as the fourth compound.

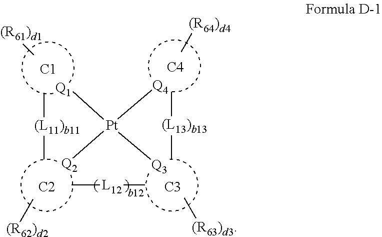

In Formula D-1, Q₁ to Q₄ may each independently be C or N.

In Formula D-1, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In Formula D-1, L₁₁ to L₁₃ may each independently be a direct linkage,

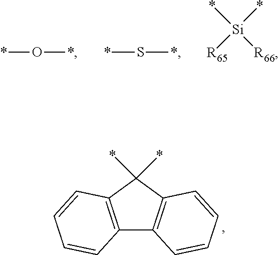

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, [symbol] refers to a part connected with C1 to C4.

In Formula D-1, b11 to b13 may each independently be 0 or 1. When b11 is 0, C1 and C2 may be unconnected. When b12 is 0, C2 and C3 may be unconnected. When b3 is 0, C3 and C4 may be unconnected.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, one or more selected from among R₆₁ to R₆₆ may independently be combined with an adjacent group to form a ring. In some embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, when d1 to d4 are each 0, the fourth compound may be unsubstituted with corresponding R₆₁ to R₆₄. An embodiment in which d1 to d4 are each 4, and R₆₁'s to R₆₄'s are each hydrogen, may be the same as an embodiment in which d1 to d4 are each 0. When d1 to d4 are each an integer of 2 or more, each of multiple R₆₁'s to R₆₄'s may be all the same, or at least one selected from among multiple R₆₁'s to R₆₄'s may be different.

In Formula D-1, C1 to C4 may each independently be a substituted or unsubstituted hydrocarbon ring or a substituted or unsubstituted heterocycle, represented by any one selected from among C-1 to C-4.

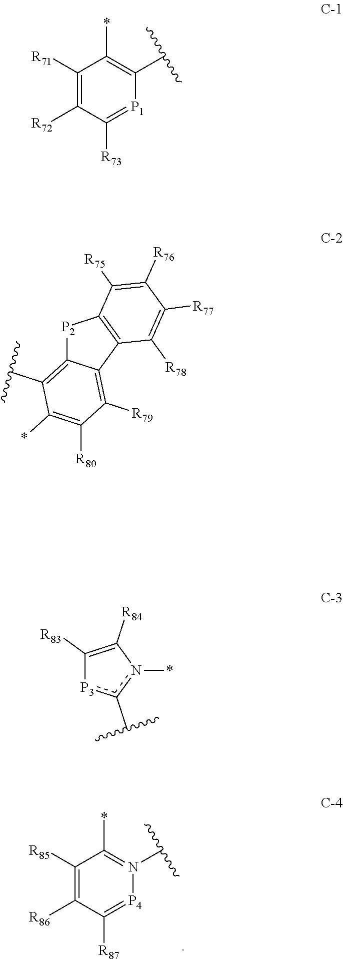

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In C-1 to C-4,

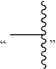

is a part connected with a central metal atom of Pt, and “ [symbol] ” corresponds to a part connected with an adjacent ring group (C1 to C4) or linker (L₁₁ to L₁₃).

The emission layer EML of one or more embodiments may include the first compound that is a fused polycyclic compound of the present disclosure, and at least one selected from among the second to fourth compounds. For example, in one or more embodiments, the emission layer EML may include the first compound, the second compound, and the third compound. In the emission layer EML, the second compound and the third compound may form exciplex, and via the exciplex, energy transfer to the first compound may arise, and light emission may arise.

In one or more embodiments, the emission layer EML may include the first compound, the second compound, the third compound, and the fourth compound. In the emission layer EML, the second compound and the third compound may form exciplex, and via the exciplex, energy transfer to the fourth compound and the first compound may arise, and light emission may arise. In some embodiments, the fourth compound may be a sensitizer. In the light emitting element ED of one or more embodiments, the fourth compound included in the emission layer EML may act as a sensitizer and may play the role of transferring energy from a host to the first compound that is a light-emitting dopant. For example, in some embodiments, the fourth compound that plays the role of an auxiliary dopant may accelerate energy transfer to the first compound that is a light emitting dopant and increase the light emitting ratio of the first compound. Accordingly, the emission efficiency of the emission layer EML of one or more embodiments may be improved. In some embodiments, when the energy transfer to the first compound increases, excitons formed in the emission layer EML may not be accumulated but rapidly emit light, and the deterioration of a device may be reduced. As a result, the lifetime of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may include the second compound and the third compound, which are two different hosts, the first compound which emits delayed fluorescence, and the fourth compound including an organometallic complex, concurrently (e.g., simultaneously), and may show excellent or suitable emission efficiency properties.

In one or more embodiments, the fourth compound represented by Formula D-1 may be represented by at least one selected from among compounds represented in Compound Group 4. In some embodiments, the emission layer EML may include at least one selected from among the compounds represented in Compound Group 4 as a sensitizer material.

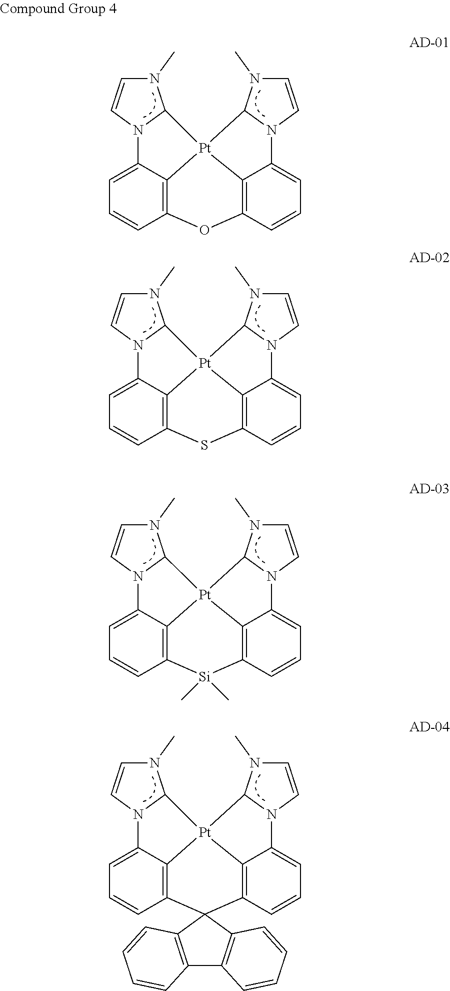

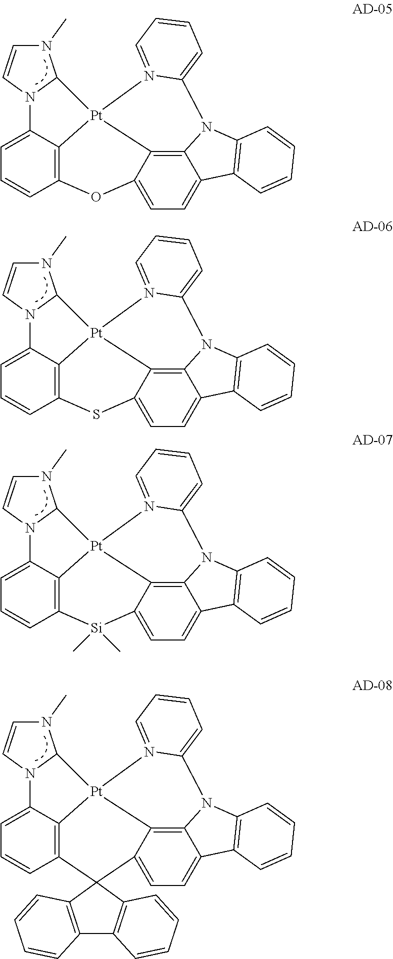

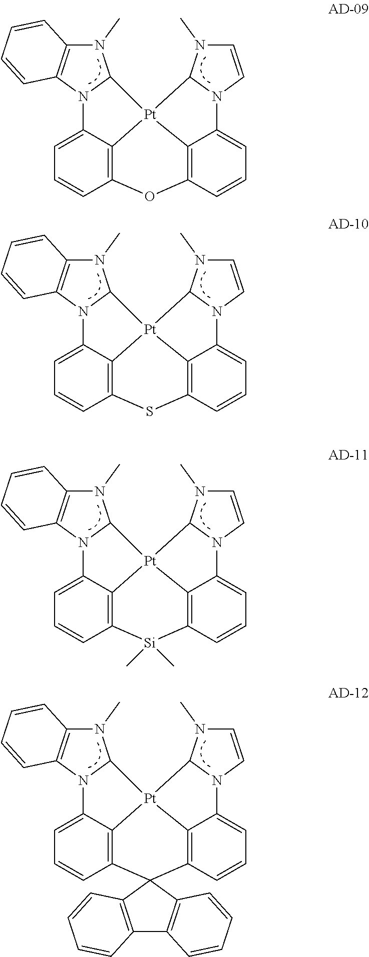

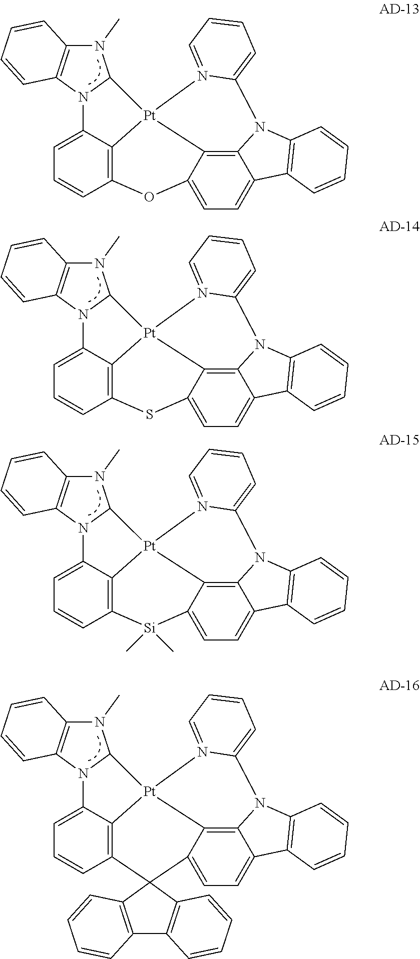

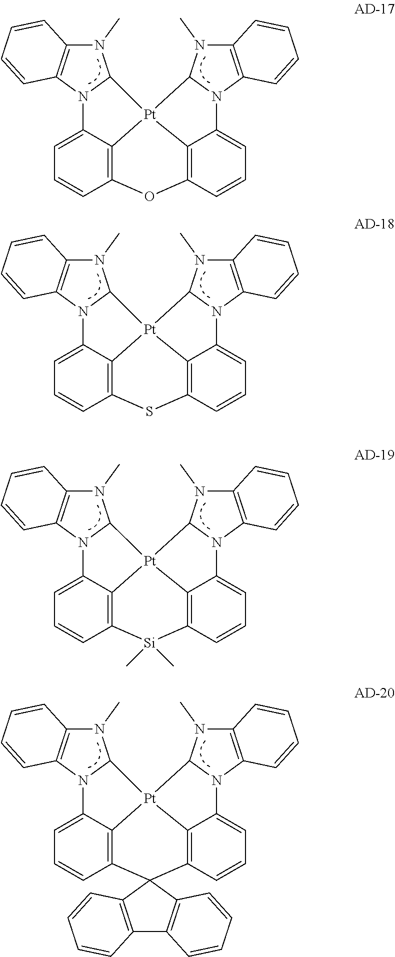

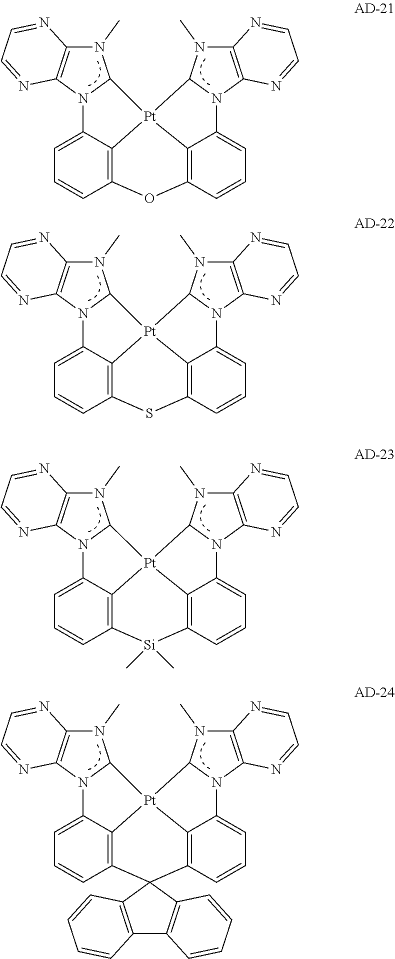

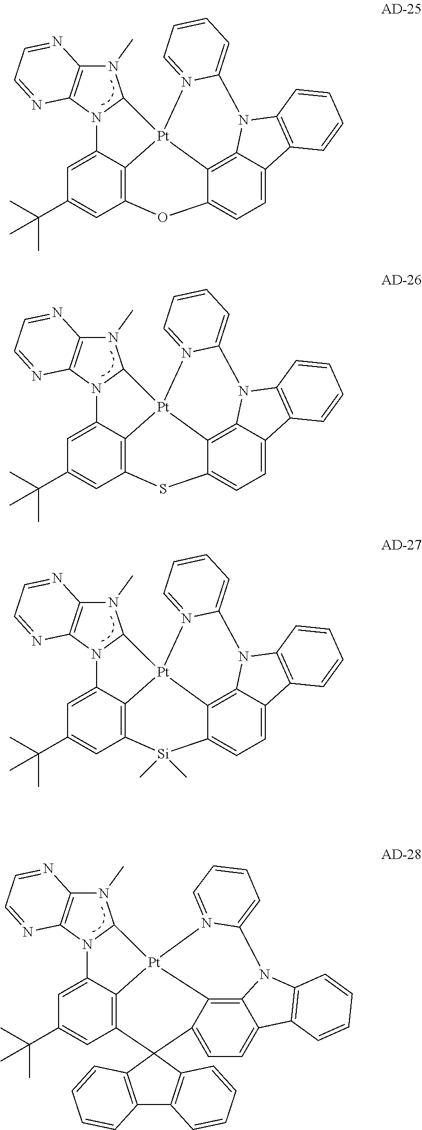

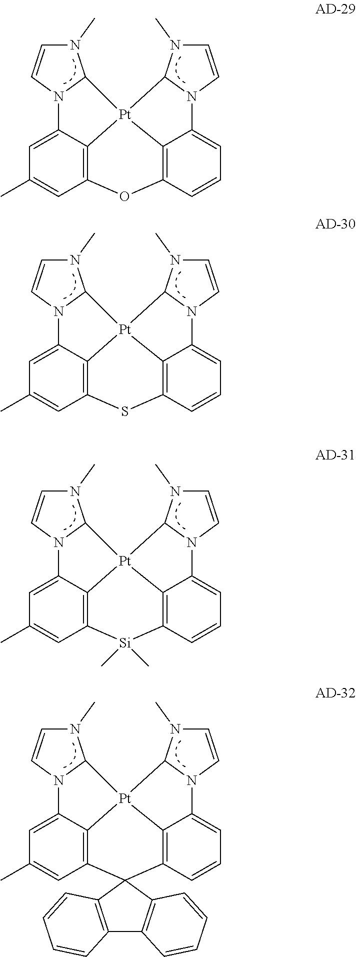

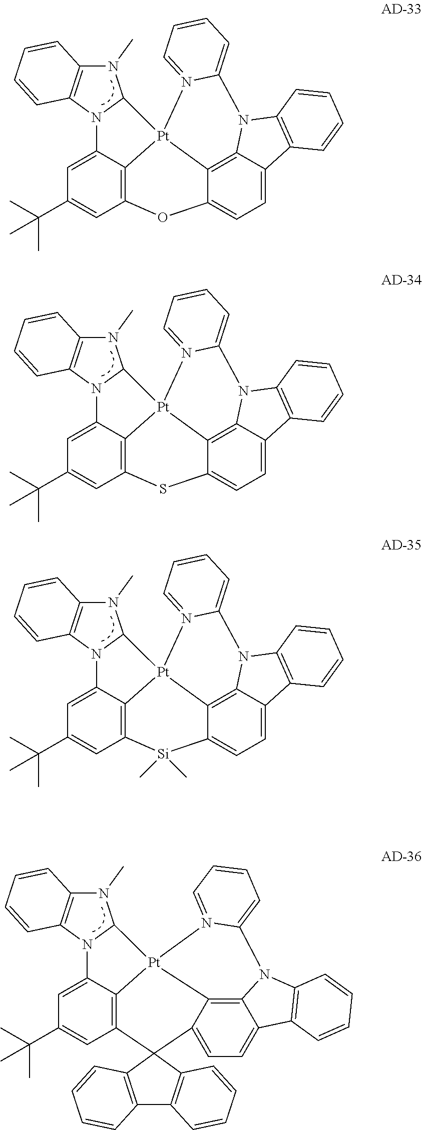

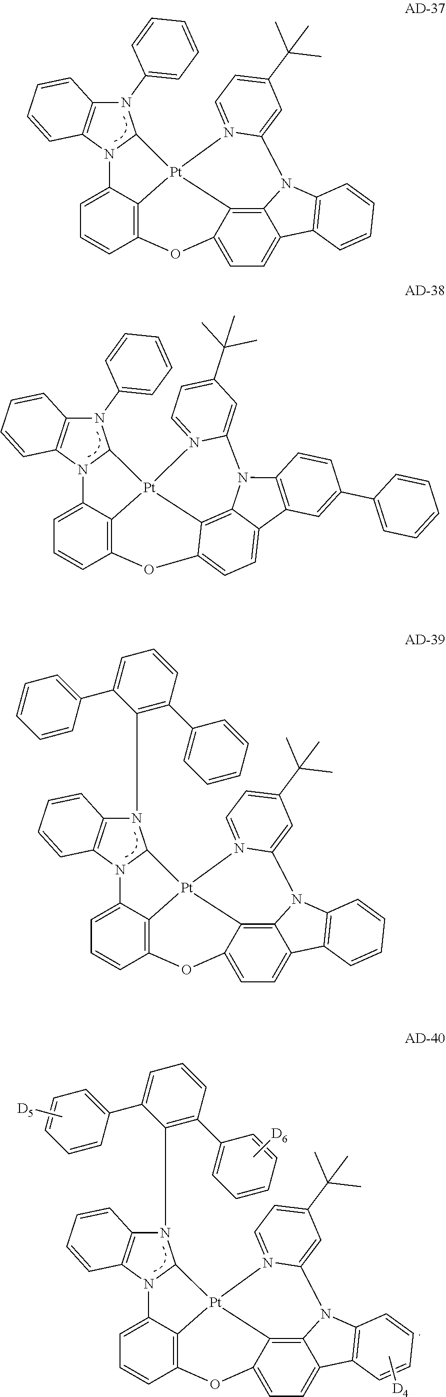

In the example compounds in Compound Group 4, “D” refers to deuterium.

In one or more embodiments, the light emitting element ED of one or more embodiments may include multiple emission layers. Multiple emission layers may be stacked in order and provided, and for example, a light emitting element ED including multiple emission layers may be to emit white light (e.g., combined white light). The light emitting element including multiple emission layers may be a light emitting element of a tandem structure. When the light emitting element ED includes multiple emission layers, at least one emission layer EML may include the first compound represented by Formula 1 of one or more embodiments. In some embodiments, when the light emitting element ED includes multiple emission layers, at least one emission layer EML may include all of the first compound, the second compound, the third compound, and the fourth compound.

In the light emitting element ED of one or more embodiments, when the emission layer EML includes all of the first compound, the second compound, the third compound, and the fourth compound, an amount of the first compound may be about 0.1 wt % to about 5 wt % based on the total weight of the first compound, the second compound, the third compound, and the fourth compound. However, embodiments of the present disclosure are not limited thereto. When the amount of the first compound satisfies the above-described ratio, energy transfer from the second compound and the third compound to the first compound may increase, and accordingly, the emission efficiency and device lifetime may increase.

In the emission layer EML, the total amount of the second compound and the third compound may be the remaining amount excluding the amount of the first compound and the fourth compound. For example, the total amount of the second compound and the third compound may be about 65 wt % to about 95 wt % based on the total weight of the first compound, the second compound, the third compound, and the fourth compound.

In the total amount of the second compound and the third compound, a weight ratio of the second compound and the third compound may be about 3:7 to about 7:3.

When the total amount of the second compound and the third compound satisfies the above-described ratio, charge balance properties in the emission layer EML may be improved, and emission efficiency and device lifetime may be improved and/or increased. When the total amount of the second compound and the third compound deviates from the above-described ratio range, charge balance in the emission layer EML may be broken, emission efficiency may be degraded and/or decreased, and the device may be easily deteriorated.

In one or more embodiments, when the emission layer EML includes the fourth compound, an amount of the fourth compound may be about 4 wt % to 30 wt % based on the total weight of the first compound, the second compound, the third compound, and the fourth compound in the emission layer EML. However, embodiments of the present disclosure are not limited thereto. When the amount of the fourth compound satisfies the above-described amount, energy transfer from a host to the first compound that is a light emitting dopant may increase, and emission ratio may be improved. Accordingly, the emission efficiency of the emission layer EML may be improved. When the amount ratio of the first compound, the second compound, the third compound, and the fourth compound, included in the emission layer EML satisfies the above-described amount ratio, excellent or suitable emission efficiency and long lifetime of the light emitting element may be achieved.

In the light emitting element ED of one or more embodiments, the emission layer EML may further include at least one of anthracene derivatives, pyrene derivatives, fluoranthene derivatives, chrysene derivatives, dihydrobenzanthracene derivatives, or triphenylene derivatives. For example, in some embodiments, the emission layer EML may include one or more anthracene derivatives and/or one or more pyrene derivatives.

In the light emitting elements ED of one or more embodiments, shown in FIG. 3 to FIG. 6, the emission layer EML may further include suitable hosts and dopants in addition to the above-described host and dopant. For example, in some embodiments, the emission layer EML may include a compound represented by Formula E-1. The compound represented by Formula E-1 may be utilized as a fluorescence host material.

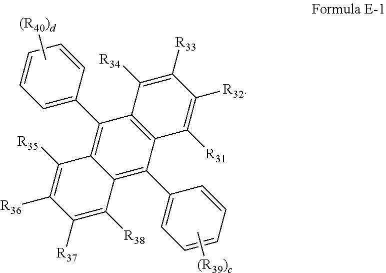

In Formula E-1, R₃₁ to R₄₀ may each independently be hydrogen, deuterium, a halogen, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, one or more selected from among R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one selected from among Compound E1 to Compound E19.

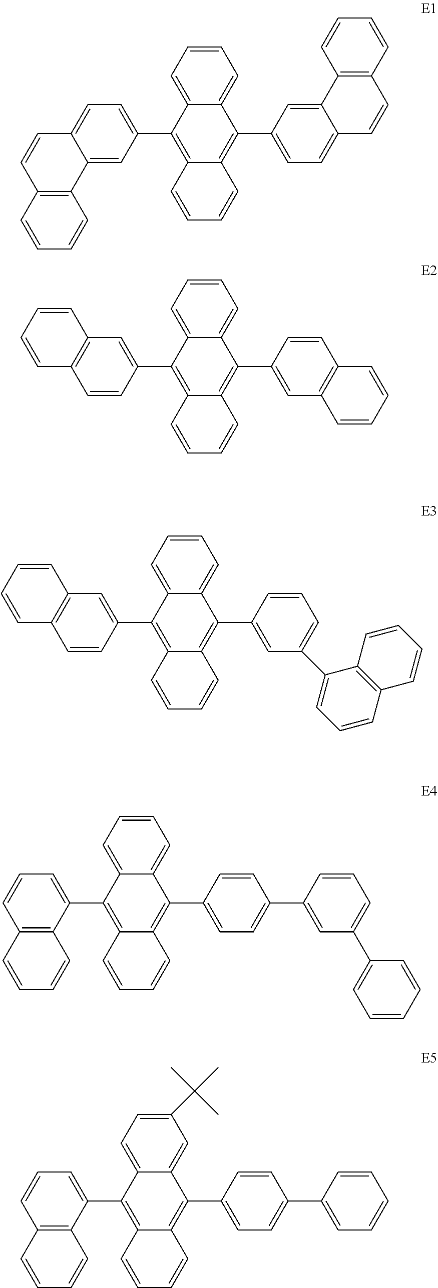

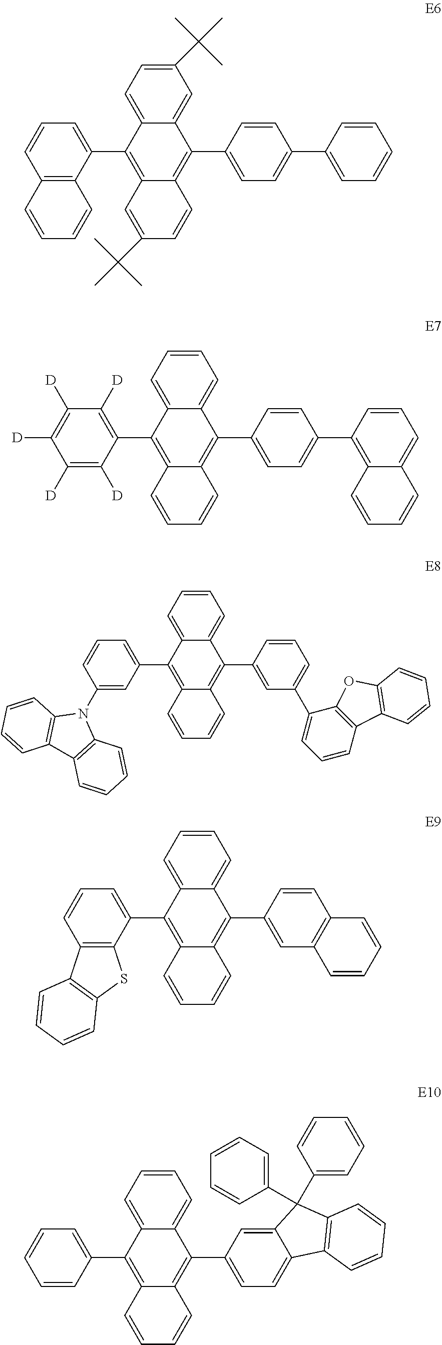

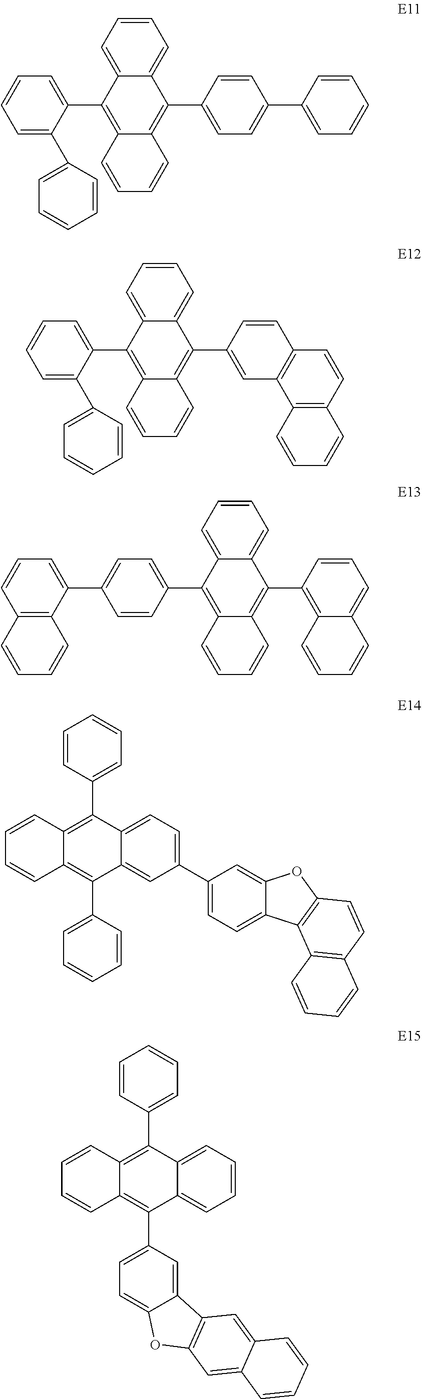

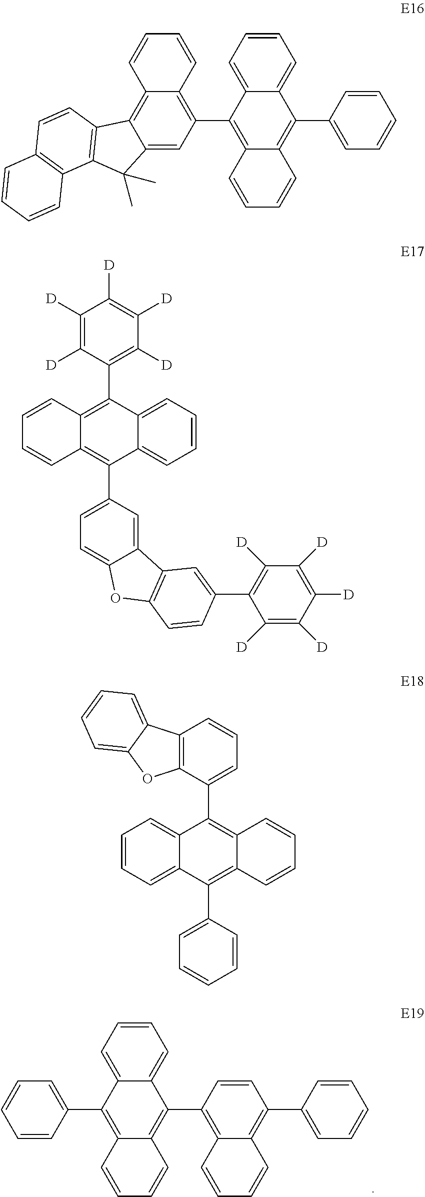

In one or more embodiments, the emission layer EML may include a compound represented by Formula E-2a or Formula E-2b. The compound represented by Formula E-2a or Formula E-2b may be utilized as a phosphorescence host material.

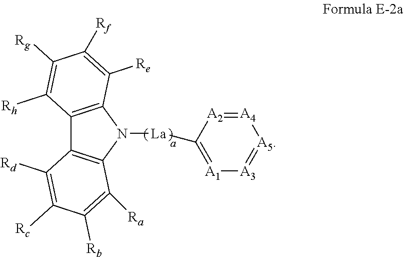

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La's may each independently be a substituted or unsubstituted arylene group of 6 to 30 ring-forming carbon atoms or a substituted or unsubstituted heteroarylene group of 2 to 30 ring-forming carbon atoms.

In some embodiments, in Formula E-2a, A₁ to A₅ may each independently be N or CRᵢ. Rₐ to Rᵢ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In some embodiments, one or more selected from among Rₐ to Rᵢ may be combined with an adjacent group to form a hydrocarbon ring or a heterocycle including N, O, S, etc. as a ring-forming atom.

In some embodiments, in Formula E-2a, two or three selected from A₁ to A₅ may be N, and the remainder may be CRᵢ.

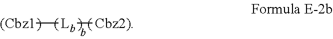

In Formula E-2b, Cb_{z1} and Cb_{z2} may each independently be an unsubstituted carbazole group or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer of 0 to 10, and when “b” is an integer of 2 or more, multiple L_{b}'s may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any one selected from among compounds in Compound Group E-2. However, the compounds shown in Compound Group E-2 are only examples, and the compound represented by Formula E-2a or Formula E-2b is not limited to the compounds represented in Compound Group E-2.

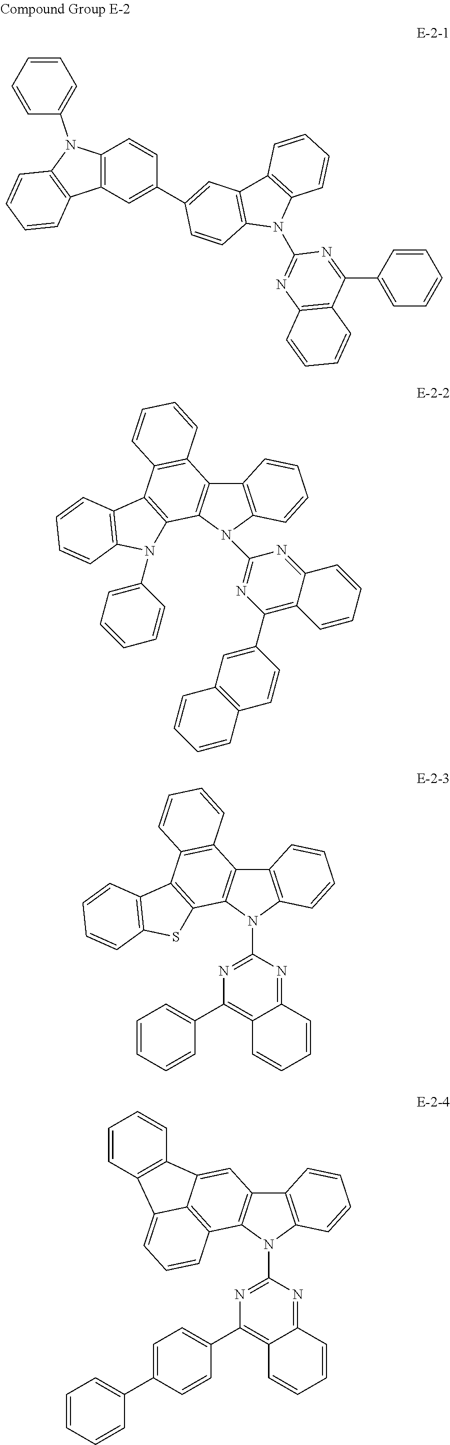

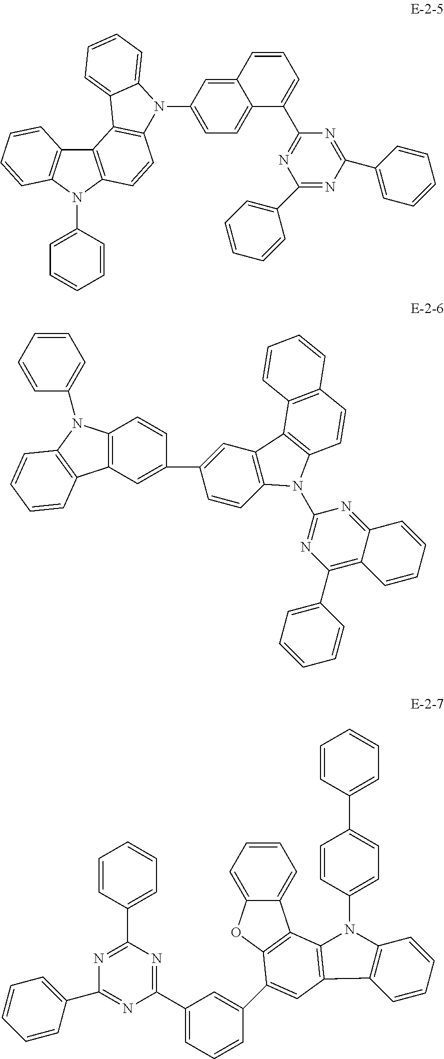

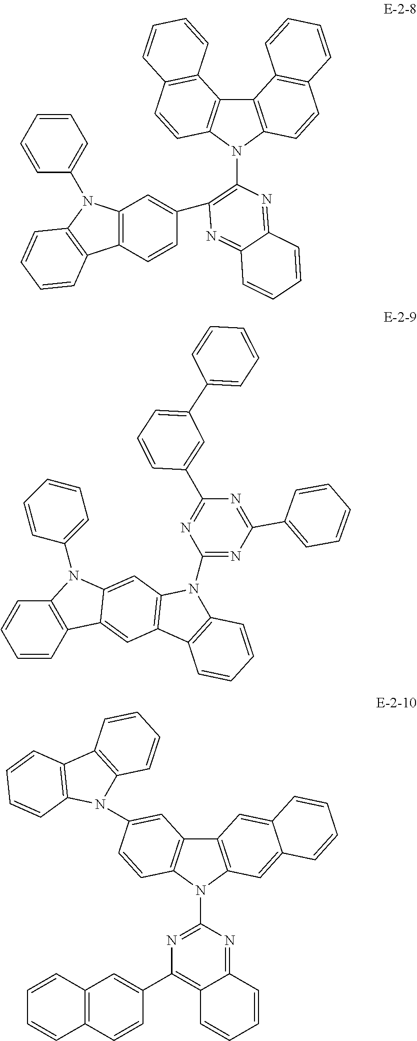

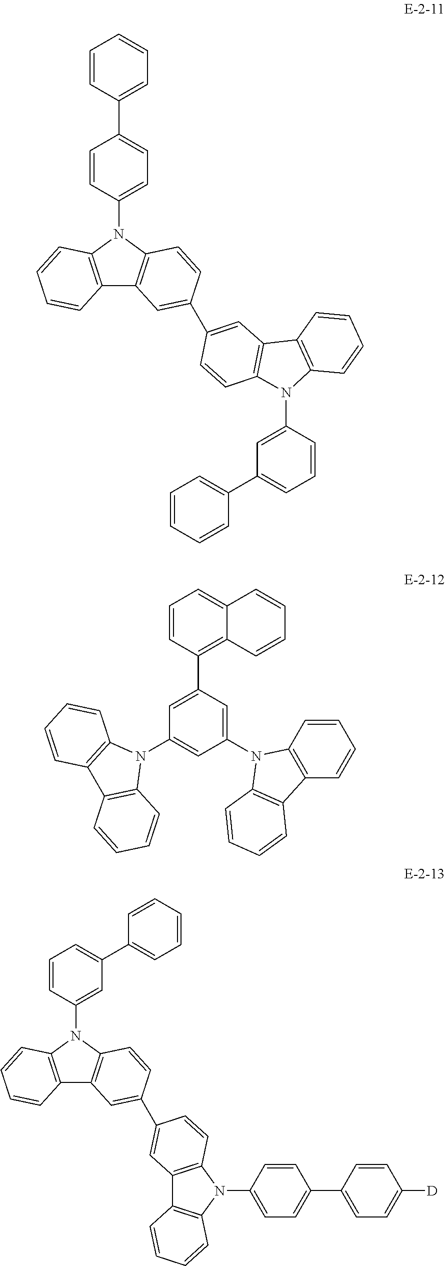

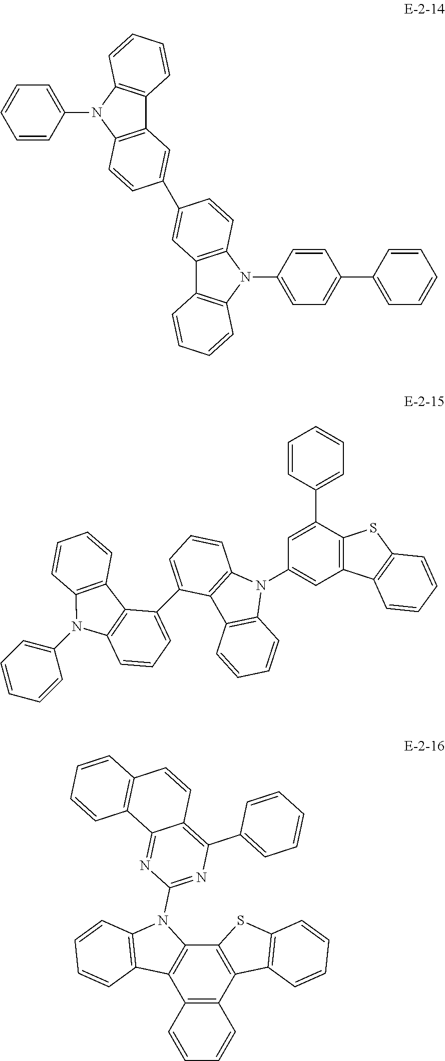 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

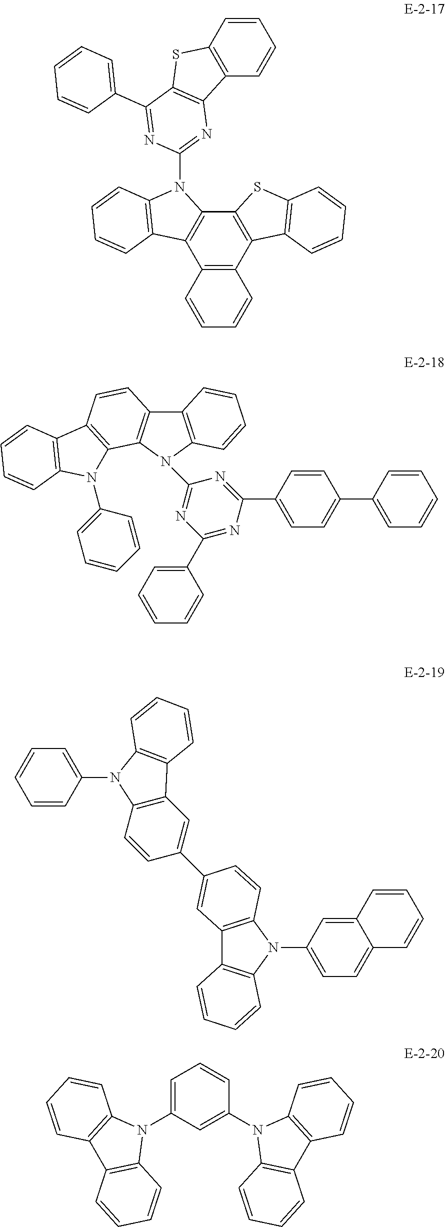

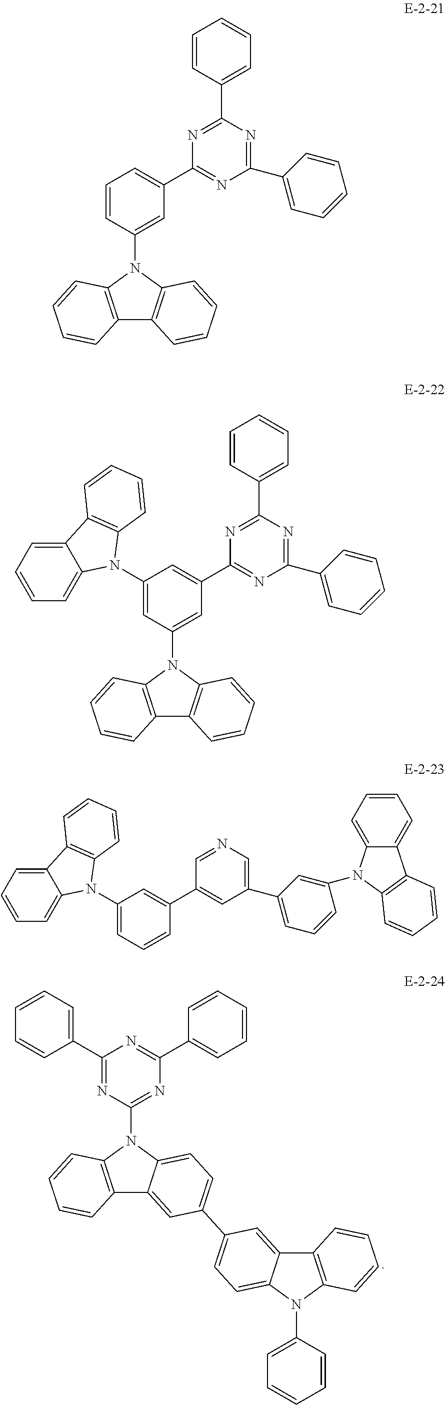 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a material well-suitable in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto. For example, in some embodiments, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

In one or more embodiments, the emission layer EML may include a compound represented by Formula M-a. The compound represented by Formula M-a may be utilized as a phosphorescence dopant material.

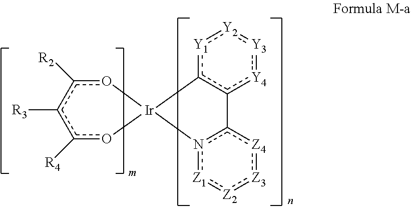

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” is 0 or 1, and “n” is 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be any one selected from among Compounds M-a1 to M-a25. However, Compounds M-a1 to M-a25 are mere examples, and the compound represented by Formula M-a is not limited to the compounds represented by Compounds M-a1 to M-a25.

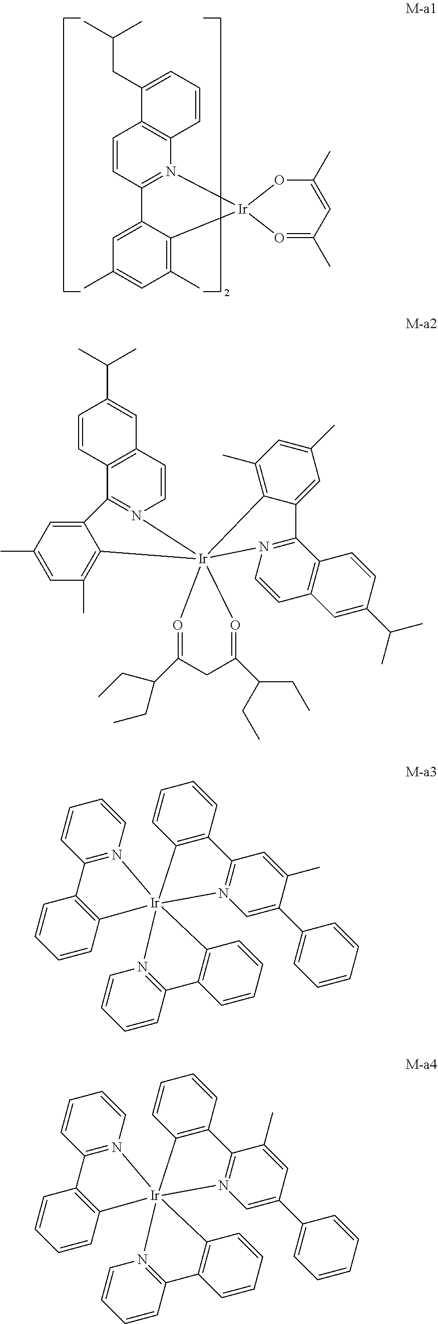

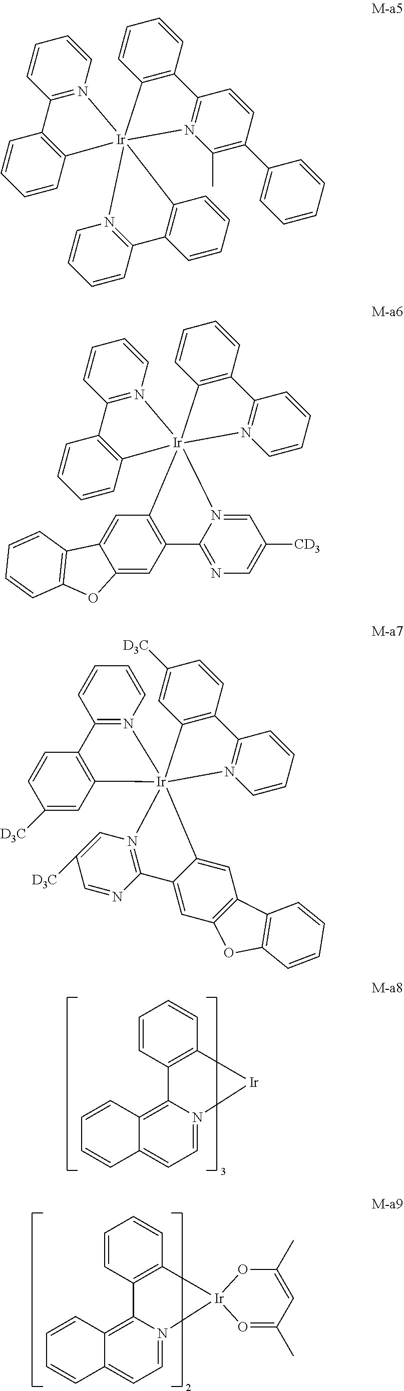

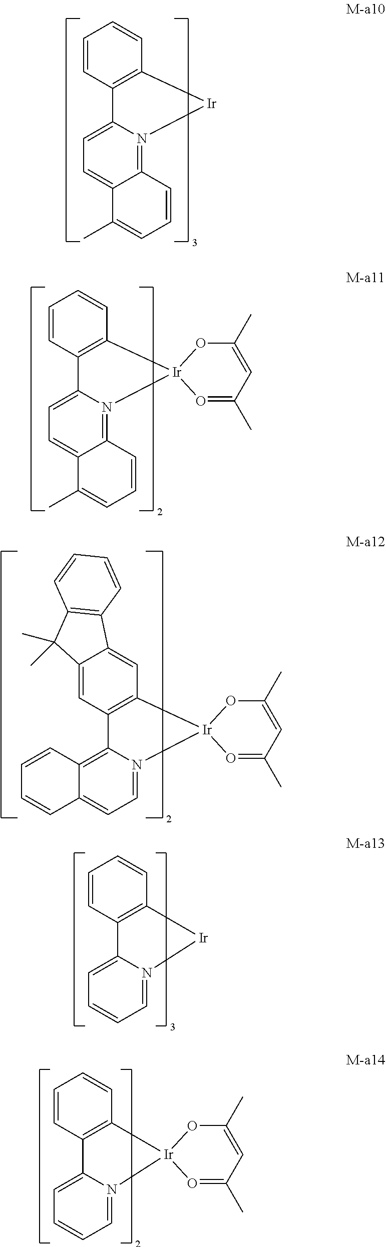

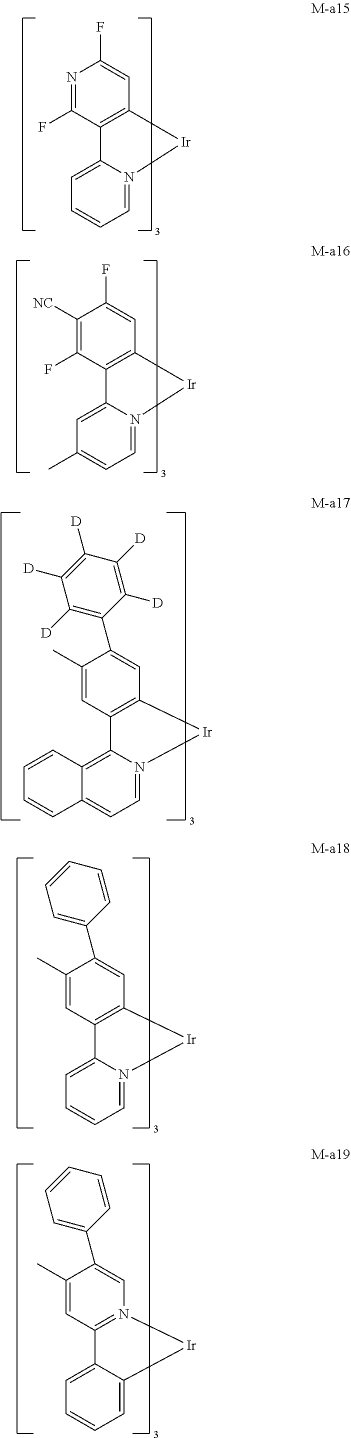

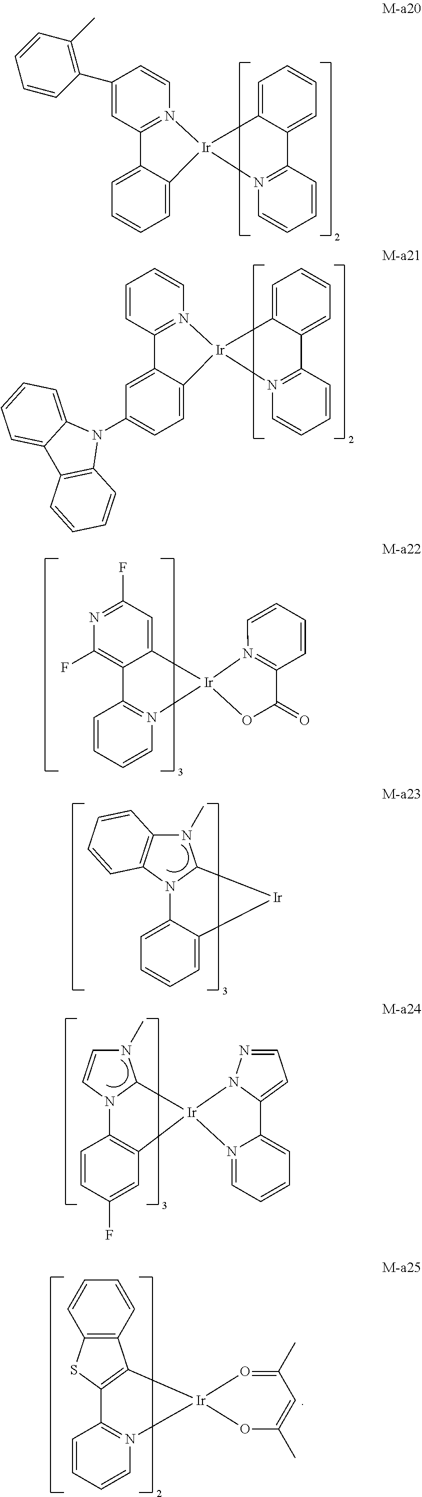

In one or more embodiments, the emission layer EML may further include a compound represented by any one selected from among Formula F-a to Formula F-c. The compounds represented by Formula F-a to Formula F-c may be utilized as fluorescence dopant materials.

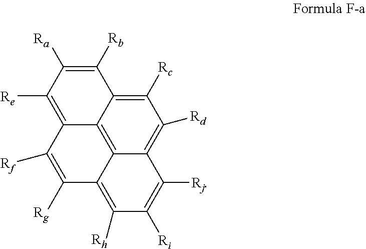

In Formula F-a, two selected from among Rₐ to Rⱼ may each independently be substituted with *—NAr₁Ar₂. The remainder not substituted with *—NAr₁Ar₂ among Rₐ to Rⱼ may each independently be hydrogen, deuterium, a halogen, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, in some embodiments, at least one selected from among Ar₁ and Ar₂ may be a heteroaryl group including O or S as a ring-forming atom.

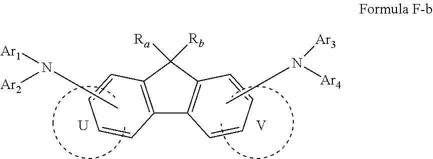

In Formula F-b, Rₐ and R_{b} may each independently be hydrogen, deuterium, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms. In some embodiments, at least one selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

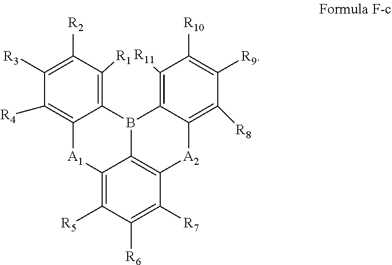

In Formula F-c, A₁ and A₂ may each independently be O, S, Se, or NRₘ, and Rₘ may be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In one or more embodiments, the emission layer EML may include as a suitable dopant material, one or more selected from styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino)pyrene), etc.

In one or more embodiments, the emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb), or thulium (Tm). For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, embodiments of the present disclosure are not limited thereto.

In one or more embodiments, the emission layer may include a quantum dot.

In the present disclosure, the quantum dot refers to the crystal of a semiconductor compound. The quantum dot may be to emit light in one or more suitable emission wavelengths according to the size of the crystal. The quantum dot may be to emit light in one or more suitable emission wavelengths by controlling the element ratio in the quantum dot compound.

The diameter of the quantum dot may be, for example, about 1 nm to about 10 nm.

The quantum dot may be synthesized by a chemical bath deposition, a metal organic chemical vapor deposition, a molecular beam epitaxy, or a similar process therewith.

The chemical bath deposition is a method of mixing an organic solvent and a precursor material of a quantum dot and then, growing a quantum dot particle crystal. During growing the crystal, the organic solvent may naturally play the role of a dispersant which is coordinated on the surface of the quantum dot crystal and may control the growth of the crystal. Accordingly, the chemical bath deposition is more advantageous when compared to a vapor deposition method including a metal organic chemical vapor deposition (MOCVD) and/or molecular beam epitaxy (MBE), and the growth of the quantum dot particle may be controlled or selected through a low-cost process.

In one or more embodiments, the emission layer EML may include a quantum dot material. In one or more embodiments, the quantum dot material may have a core/shell structure. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In some embodiments, the Group II-VI compound may further include a Group I metal and/or a Group IV element. The Group I-II-VI compound may be selected from CuSnS and/or CuZnS, and the Group II-IV-VI compound may be selected from ZnSnS and/or the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The III-VI group compound may include a binary compound such as In₂S₃ and/or In₂Se₃, a ternary compound such as InGaS₃ and/or InGaSe₃, or one or more combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂, and mixtures thereof, and/or a quaternary compound such as AgInGaS₂ and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and mixtures thereof. In some embodiments, the III-V group compound may further include a II group metal. For example, InZnP, etc. may be selected as a III-II-V group compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a substantially uniform concentration or a non-substantially uniform concentration. For example, Formula above indicates the types (kinds) of elements included in a compound, and element ratios in the compound may be different. For example, AgInGaS₂ may indicate AgInₓGa₁₋ₓS₂ (x is a real number between 0 and 1).

In one or more embodiments, constituting elements of the binary compound, the ternary compound, or the quaternary compound may be present at substantially uniform concentration in a particle or may be present at a partially different concentration distribution within the same particle. In some embodiments, a core/shell structure in which one quantum dot wraps another quantum dot may be desirable. The interface of the core and the shell may have a concentration gradient in which the concentration of an element present in the shell is decreased toward the center.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal or non-metal oxide, a semiconductor compound, or combinations thereof.

For example, the metal or non-metal oxide for the shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of emission spectrum of about 45 nm or less, about 40 nm or less, or, about 30 nm or less. Within this range, the color purity or color reproducibility of the light emitting element may be improved. In some embodiments, light emitted via such quantum dot is emitted in all directions, and light view angle properties may be improved.

In addition, the shape of the quantum dot may be generally utilized shapes in the art, without specific limitation. More particularly, the shape of spherical nanoparticle, pyramidal nanoparticle, multi-arm nanoparticle, or cubic nanoparticle, nanotube, nanowire, nanofiber, nanoplate particle, etc. may be utilized.

As the size of the quantum dot or the ratio of elements in the quantum dot compound is regulated, the energy band gap of the quantum dot may be accordingly controlled or selected to obtain light of one or more suitable wavelengths from a quantum dot emission layer. Therefore, by utilizing the quantum dots as described above (utilizing quantum dots of different sizes or having different element ratios in the quantum dot compound), a light emitting device emitting light of one or more suitable wavelengths may be obtained. For example, the size of the quantum dots and/or the ratio of elements in the quantum dot compound may be regulated to emit red, green, and/or blue light. In some embodiments, the quantum dots may be configured to emit white light by combining light of one or more suitable colors.

In the light emitting elements ED of one or more embodiments, as shown in FIG. 3 to FIG. 6, the electron transport region ETR may be provided on the emission layer EML. The electron transport region ETR may include at least one of an electron blocking layer HBL, an electron transport layer ETL, or an electron injection layer EIL. However, embodiments of the present disclosure are not limited thereto.

The electron transport region ETR may have a single layer formed utilizing a single material, a single layer formed utilizing multiple different materials, or a multilayer structure having multiple layers formed utilizing multiple different materials.

For example, in one or more embodiments, the electron transport region ETR may have a single layer structure of an electron injection layer EIL or an electron transport layer ETL, or a single layer structure formed utilizing an electron injection material and an electron transport material. Further, in some embodiments, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. A thickness of the electron transport region ETR may be, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2.

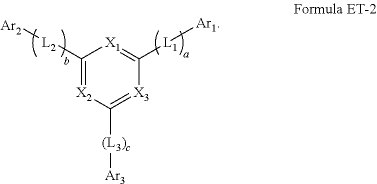

In Formula ET-2, at least one selected from among X₁ to X₃ may be N, and the remainder are CRₐ. Rₐ may be hydrogen, deuterium, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be hydrogen, deuterium, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may each independently be an integer of 0 to 10. In Formula ET-2, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” each are integers of 2 or more, L₁'s to L₃'s may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the electron transport region ETR may include an anthracene-based compound. However, embodiments of the present disclosure are not limited thereto, for example, in some embodiments, the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalen-2-yl)anthracene (ADN), 1,3-bis[3,5-di(pyridin-3-yl)phenyl]benzene (BmPyPhB), CNNPTRZ(4′-(4-(4-(4,6-diphenyl-1,3,5-triazin-2-yl)phenyl)naphthalen-1-yl)-[1,1′-biphenyl]-4-carbonitrile), and mixtures thereof, without limitation.

In one or more embodiments, electron transport region ETR may include any one selected from among the compounds in Compound Group 3.

In one or more embodiments, the electron transport region ETR may include at least one selected from among Compounds ET1 to ET36.

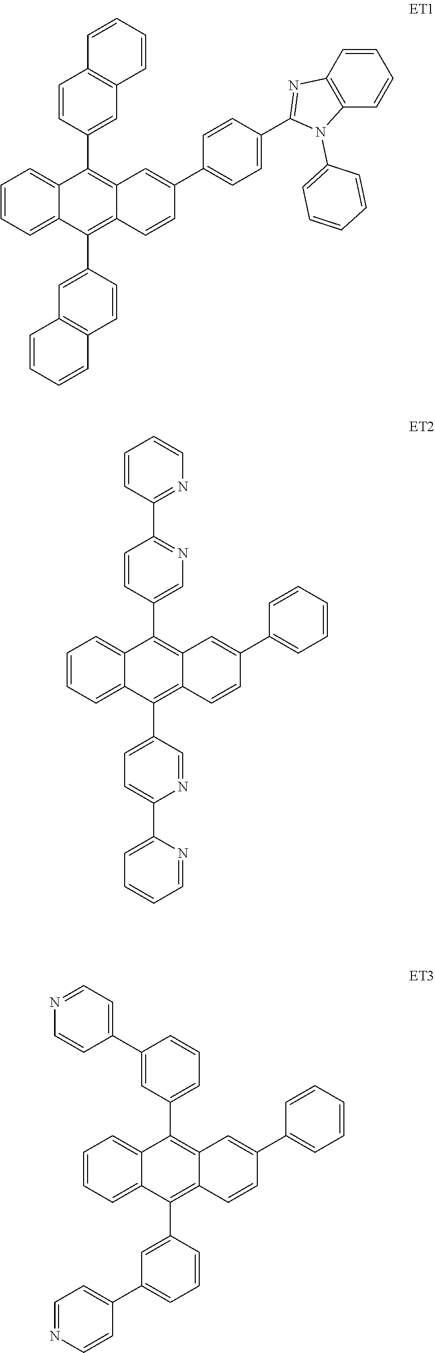 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

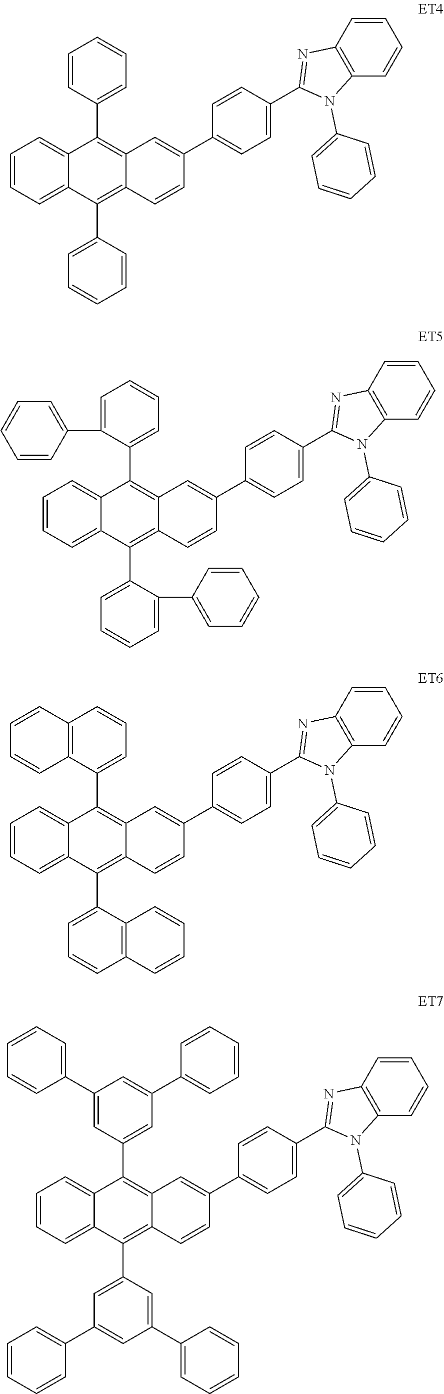 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

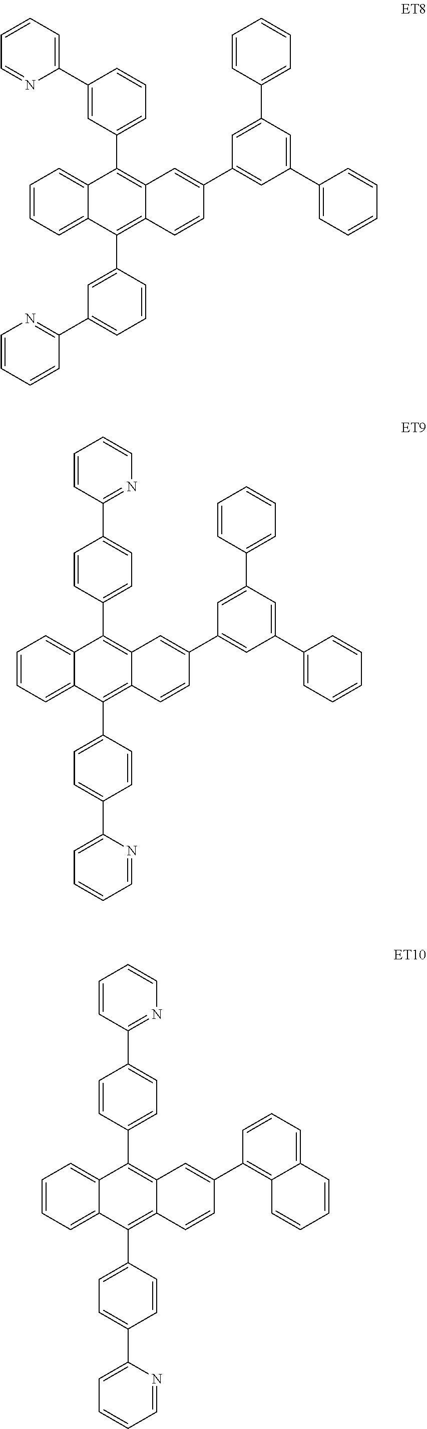 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

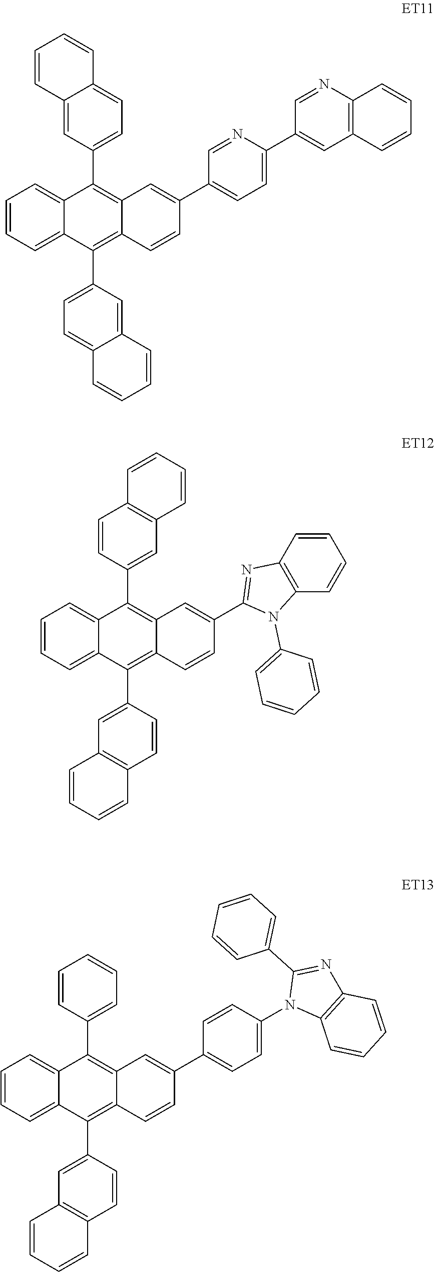 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

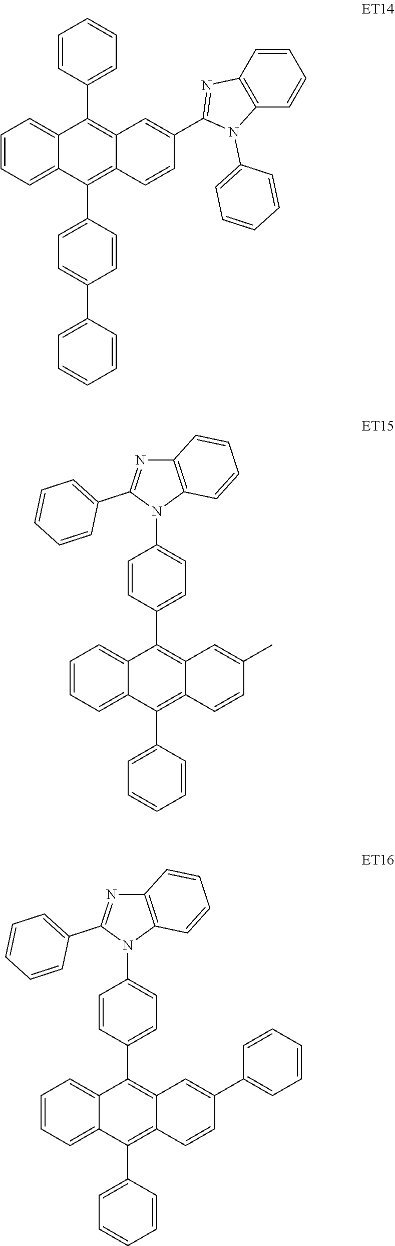 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

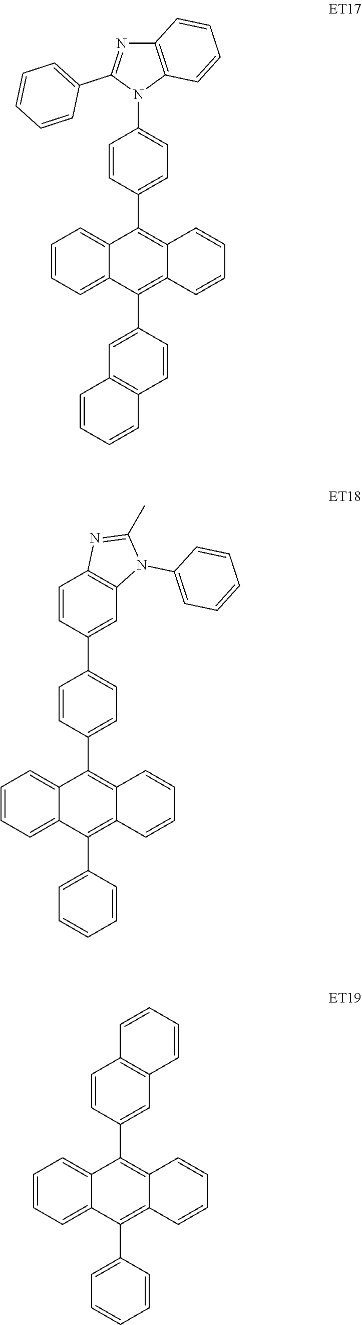

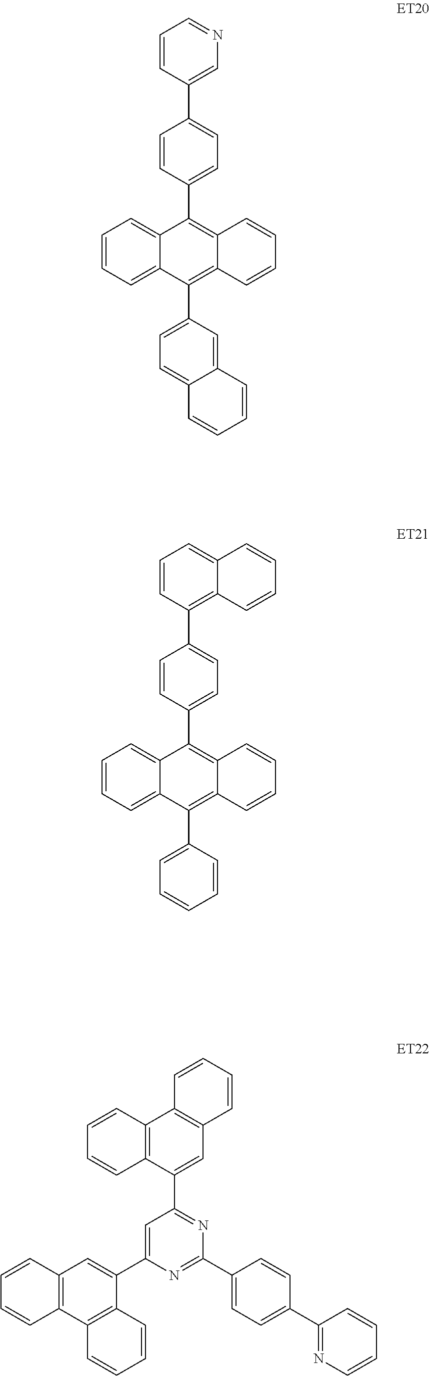

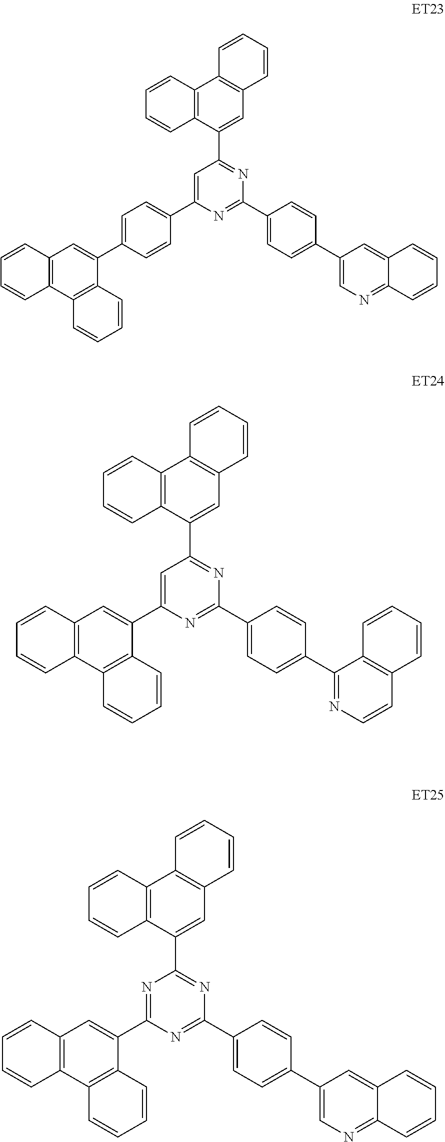 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

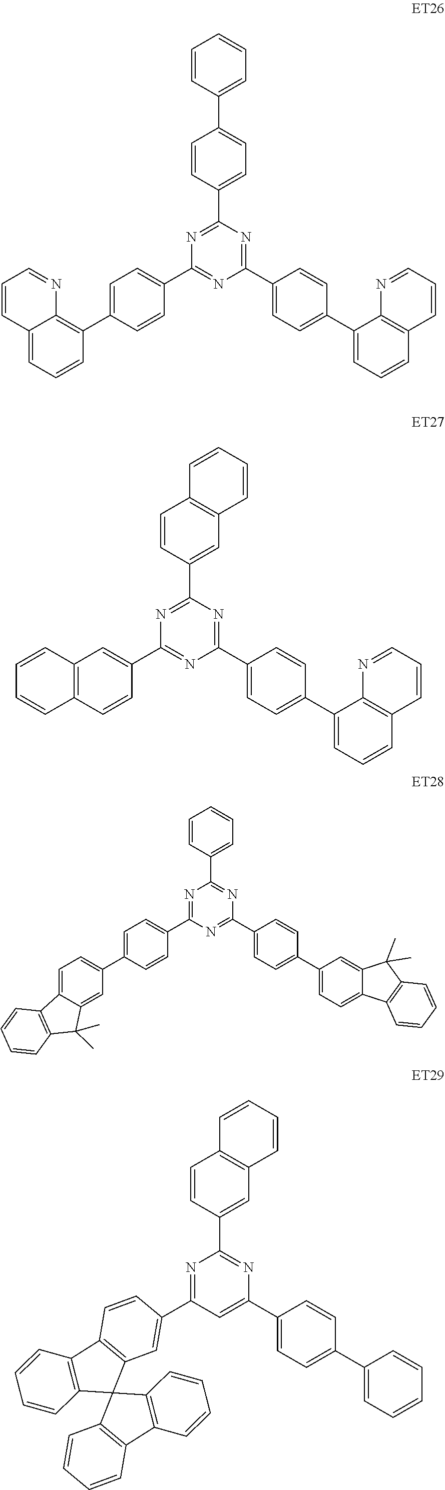 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

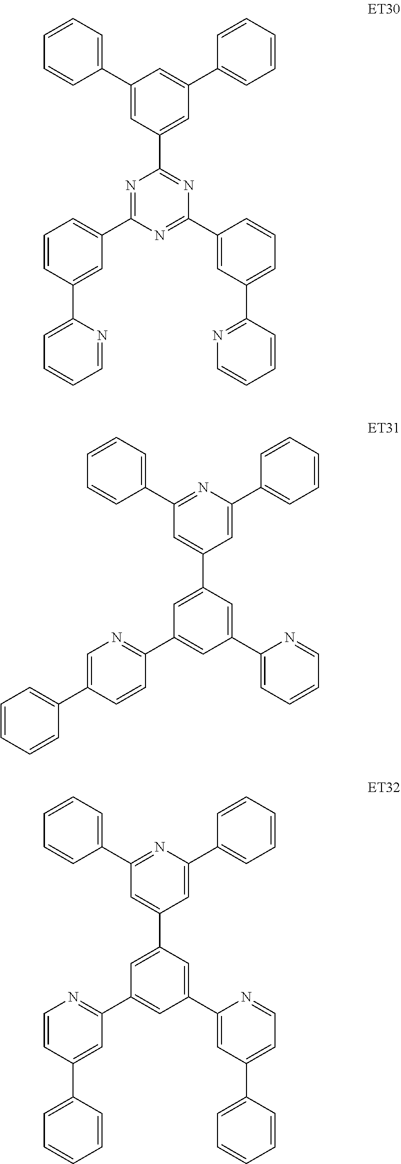 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

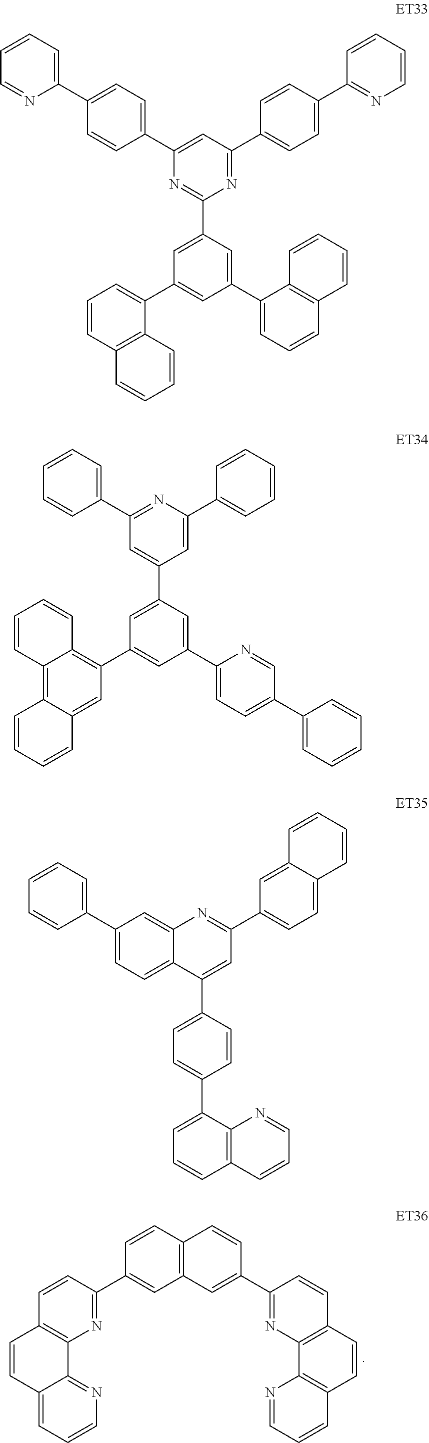 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and/or KI, a lanthanide metal such as Yb, or a co-depositing material of the metal halide and the lanthanide metal. For example, in some embodiments, the electron transport region ETR may include KI:Yb, RbI:Yb, LiF:Yb, etc., as the co-depositing material. In some embodiments, the electron transport region ETR may utilize a metal oxide such as Li₂O and/or BaO, or 8-hydroxy-lithium quinolate (Liq). However, embodiments of the present disclosure are not limited thereto. In some embodiments, the electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

In one or more embodiments, the electron transport region ETR may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the aforementioned materials. However, embodiments of the present disclosure are not limited thereto.

The electron transport region ETR may include the compounds of the electron transport region in at least one selected from among an electron injection layer EIL, an electron transport layer ETL, and a hole blocking layer HBL.

When the electron transport region ETR includes an electron transport layer ETL, a thickness of the electron transport layer ETL may be from about 100 Å to about 1,000 Å, for example, from about 150 Å to about 500 Å. When the thickness of the electron transport layer ETL satisfies the above-described range, satisfactory electron transport properties may be obtained without a substantial increase in driving voltage. When the electron transport region ETR includes an electron injection layer EIL, a thickness of the electron injection layer EIL may be from about 1 Å to about 100 Å, or from about 3 Å to about 90 Å. When the thickness of the electron injection layer EIL satisfies the above described range, satisfactory electron injection properties may be obtained without inducing a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, one or more compounds thereof, or one or more mixtures thereof (for example, AgMg, AgYb, or MgYb). In some embodiments, the second electrode EL2 may have a multilayered structure including a reflective layer or a transflective layer formed utilizing one or more selected from among the above-described materials and a transparent conductive layer formed utilizing ITO, IZO, ZnO, ITZO, etc. For example, the second electrode EL2 may include one or more selected from among the aforementioned metal materials, combinations of two or more metal materials selected from the aforementioned metal materials, or oxides of the aforementioned metal materials.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED, a capping layer CPL may be further disposed. The capping layer CPL may include a multilayer or a single layer.

In one or more embodiments, the capping layer CPL may be an organic layer or an inorganic layer. For example, in some embodiments, when the capping layer CPL includes an inorganic material, the inorganic material may include an alkali metal compound such as LiF, an alkaline earth metal compound such as MgF₂, SiON, SiNₓ, SiO_{y}, etc.

For example, in some embodiments, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or may include an epoxy resin, and/or acrylate such as methacrylate. In some embodiments, the capping layer CPL may include at least one selected from among Compounds P1 to P5, but embodiments of the present disclosure are not limited thereto.

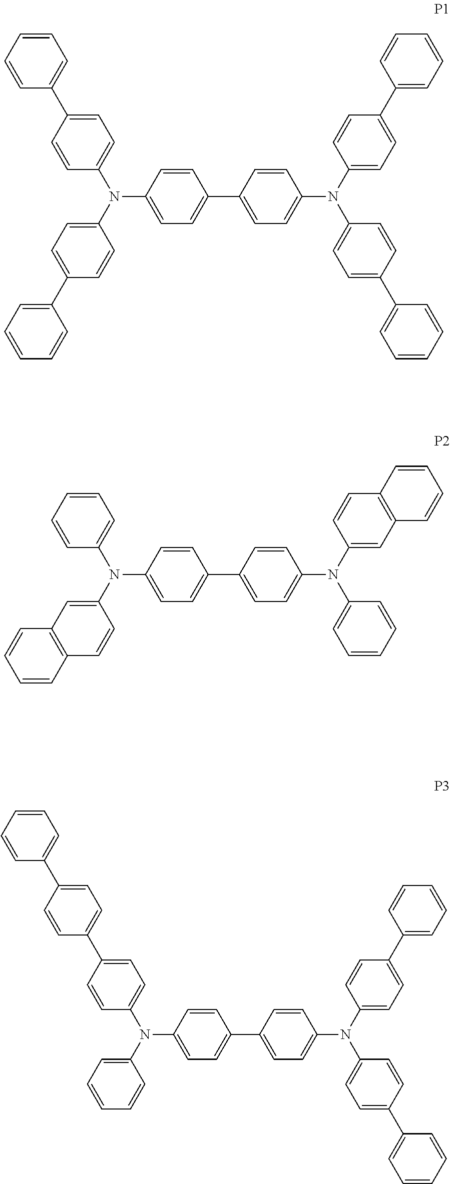 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

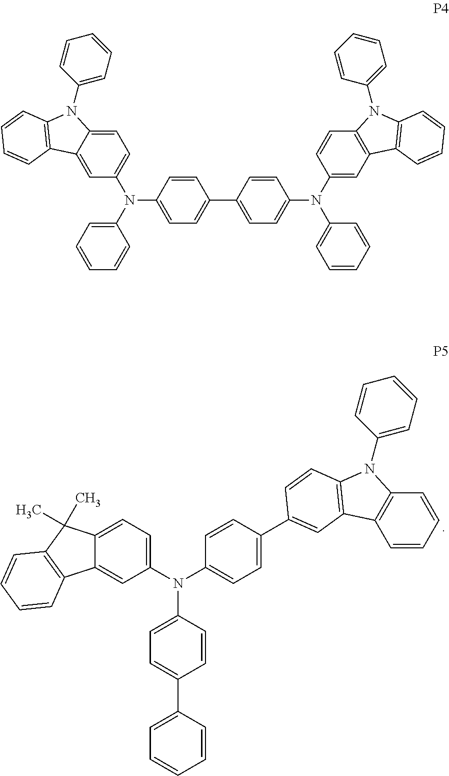 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, in some embodiments, the refractive index of the capping layer CPL with respect to light in a wavelength range of about 550 nm to about 660 nm may be about 1.6 or more.

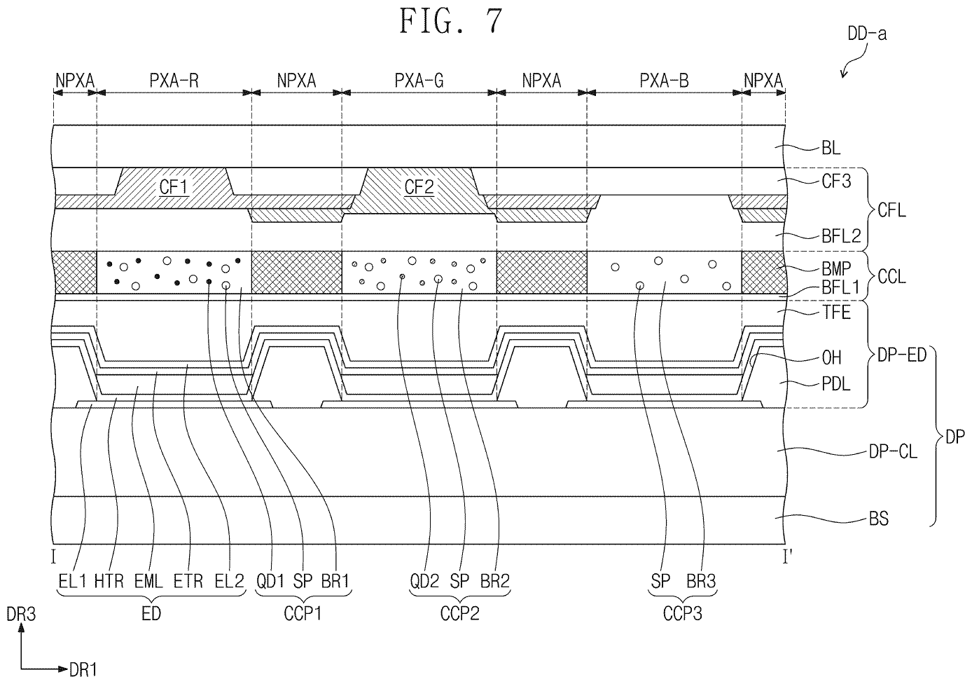

FIG. 7 to FIG. 10 are each a cross-sectional view on a display apparatus according to one or more embodiments of the present disclosure. In the explanation on the display apparatuses of embodiments by referring to FIG. 7 to FIG. 10, the overlapping parts with the explanation on FIG. 1 to FIG. 6 will not be explained/described again for conciseness, and only different features will be explained chiefly and mainly.

Referring to FIG. 7, the display apparatus DD-a according to one or more embodiments may include a display panel DP including a display device layer DP-ED, a light controlling layer CCL disposed on the display panel DP, and a color filter layer CFL. In one or more embodiments shown in FIG. 7, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In one or more embodiments, the same structure as any one of the light emitting elements of FIG. 3 to FIG. 6 may be applied to the structure of the light emitting device ED shown in FIG. 7.

The emission layer EML of the light emitting device ED included in the display device DD-a according to one or more embodiments may include the fused polycyclic compound of one or more embodiments described above.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G, and PXA-B may be to emit light in substantially the same wavelength region. In the display apparatus DD-a of one or more embodiments, the emission layer EML may be to emit blue light. In some embodiments, the emission layer EML may be provided as a common layer for all luminous areas PXA-R, PXA-G, and PXA-B.

The light controlling layer CCL may be disposed on the display panel DP. The light controlling layer CCL may include a light converter. The light converter may be a quantum dot and/or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2, and CCP3. The light controlling parts CCP1, CCP2, and CCP3 may be separated and apart from one another.

Referring to FIG. 7, a partition pattern BMP may be disposed between the separated light controlling parts CCP1, CCP2, and CCP3, but embodiments of the present disclosure are not limited thereto. In FIG. 7, the partition pattern BMP is shown not to be overlapped with the light controlling parts CCP1, CCP2, and CCP3, but, in some embodiments, at least a portion of the edges of the light controlling parts CCP1, CCP2, and CCP3 may be overlapped with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting first color light into third color light, and a third light controlling part CCP3 transmitting first color light. In one or more embodiments, the first light controlling part CCP1 may provide red light which is the second color light, and the second light controlling part CCP2 may provide green light which is the third color light. The third color controlling part CCP3 may be to transmit and provide blue light which is the first color light provided from the light emitting device ED. For example, in some embodiments, the first quantum dot QD1 may be a red quantum dot to emit red light, and the second quantum dot QD2 may be a green quantum dot to emit green light. On the quantum dots QD1 and QD2, the same content as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) any quantum dot but include the scatterer SP.

The scatterer SP may be an inorganic particle. For example, the scatterer SP may include at least one selected from among TiO₂, ZnO, Al₂O₃, SiO₂, and hollow silica. In one or more embodiments, the scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light controlling part CCP1, the second light controlling part CCP2, and the third light controlling part CCP3 may respectively include base resins BR1, BR2, and BR3 dispersing the quantum dots QD1 and QD2 and the scatterer SP. In one or more embodiments, the first light controlling part CCP1 may include the first quantum dot QD1 and the scatterer SP dispersed in a first base resin BR1, the second light controlling part CCP2 may include the second quantum dot QD2 and the scatterer SP dispersed in a second base resin BR2, and the third light controlling part CCP3 may include the scatterer particle SP dispersed in a third base resin BR3.

The base resins BR1, BR2, and BR3 are mediums in which the quantum dots QD1 and QD2 and the scatterer SP are dispersed, and may be composed of one or more suitable resin compositions which may be generally referred to as a binder. For example, the base resins BR1, BR2, and BR3 may each independently be acrylic resins, urethane-based resins, silicone-based resins, epoxy-based resins, etc. The base resins BR1, BR2, and BR3 may be transparent resins. In one or more embodiments, the first base resin BR1, the second base resin BR2, and the third base resin BR3 may be the same or different from each other.

In one or more embodiments, the light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may block or reduce the exposure of the light controlling parts CCP1, CCP2, and CCP3 to humidity/oxygen. In some embodiments, the barrier layer BFL1 may cover the light controlling parts CCP1, CCP2, and CCP3. In some embodiments, a color filter layer CFL, which will be explained later, may include a barrier layer BFL2 disposed on the light controlling parts CCP1, CCP2, and CCP3.

The barrier layers BFL1 and BFL2 may include at least one inorganic layer. For example, in some embodiments, the barrier layers BFL1 and BFL2 may be formed by including an inorganic material. For example, the barrier layers BFL1 and BFL2 may be formed by including one or more selected from silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and a metal thin film securing light transmittance. In some embodiments, the barrier layers BFL1 and BFL2 may further include an organic layer. The barrier layers BFL1 and BFL2 may be composed of a single layer or multiple layers.

In the display apparatus DD-a of one or more embodiments, the color filter layer CFL may be disposed on the light controlling layer CCL. For example, the color filter layer CFL may be disposed directly on the light controlling layer CCL. In these embodiments, the barrier layer BFL2 may not be provided.

The color filter layer CFL may include filters CF1, CF2, and CF3. Each of the first to third filters CF1, CF2, and CF3 may be disposed corresponding to a red luminous area PXA-R, a green luminous area PXA-G, and a blue luminous area PXA-B, respectively.

The color filter layer CFL may include a first filter CF1 transmitting the second color light, a second filter CF2 transmitting the third color light, and a third filter CF3 transmitting the first color light. For example, in some embodiments, the first filter CF1 may be a red filter, the second filter CF2 may be a green filter, and the third filter CF3 may be a blue filter. Each of the filters CF1, CF2, and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye.

In some embodiments, the third filter CF3 may not include (e.g., may exclude) any pigment and/or dye. The third filter CF3 may include a polymer photosensitive resin and not include any pigment and/or dye. The third filter CF3 may be transparent. The third filter CF3 may be formed utilizing a transparent photosensitive resin.

In some embodiments, the first filter CF1 and the second filter CF2 may each be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material including a black pigment and/or black dye. The light blocking part may prevent or reduce light leakage phenomenon and divide the boundaries among adjacent filters CF1, CF2, and CF3.

On the color filter layer CFL, a base substrate BL may be disposed/provided. The base substrate BL may be a member providing a base surface on which the color filter layer CFL, the light controlling layer CCL, etc. are disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

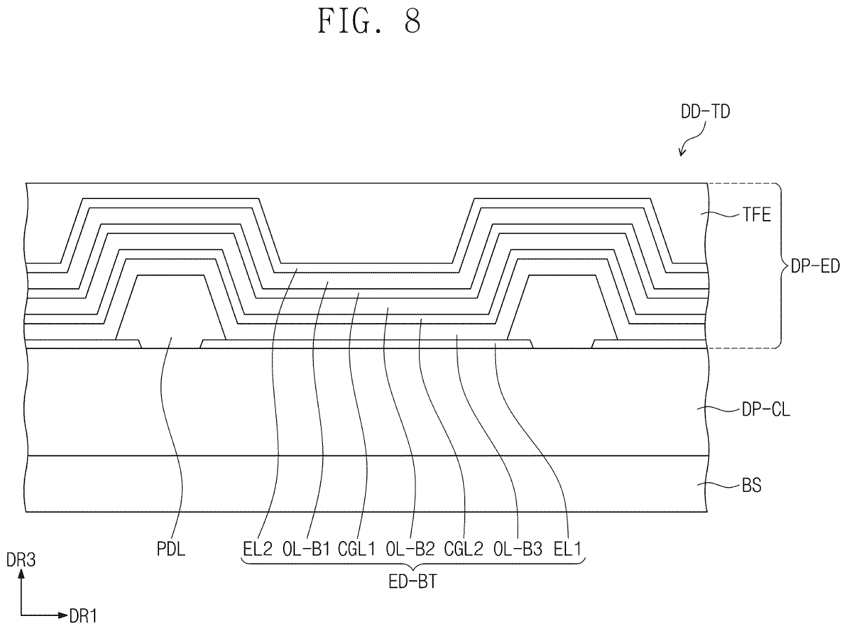

FIG. 8 is a cross-sectional view showing a portion of a display apparatus according to one or more embodiments. In a display apparatus DD-TD, a light emitting device ED-BT may include multiple light emitting structures OL-B1, OL-B2, and OL-B3. The light emitting device ED-BT may include oppositely disposed first electrode EL1 and second electrode EL2, and the multiple light emitting structures OL-B1, OL-B2, and OL-B3 stacked in order in a thickness direction and provided between the first electrode EL1 and the second electrode EL2. Each of the light emitting structures OL-B1, OL-B2, and OL-B3 may include an emission layer EML (FIG. 7), and a hole transport region HTR and an electron transport region ETR disposed with the emission layer EML (FIG. 7) therebetween.

For example, in some embodiments, the light emitting device ED-BT included in the display apparatus DD-TD may be a light emitting device of a tandem structure including multiple emission layers.

In one or more embodiments shown in FIG. 8, light emitted from the light emitting structures OL-B1, OL-B2, and OL-B3 may be all blue light. However, embodiments of the present disclosure are not limited thereto, and the wavelength regions of light emitted from the light emitting structures OL-B1, OL-B2, and OL-B3 may be different from each other. For example, in one or more embodiments, the light emitting device ED-BT including the multiple light emitting structures OL-B1, OL-B2, and OL-B3 each emitting light in different wavelength regions may be to emit white light (e.g., combined white light).

Between neighboring light emitting structures OL-B1, OL-B2, and OL-B3, charge generating layers CGL1 and CGL2 may be disposed. The charge generating layers CGL1 and CGL2 may include a p-type or kind charge (e.g., P-charge) generating layer and/or an n-type or kind charge (e.g., N-charge) generating layer.

At least one selected from among the light emitting structures OL-B1, OL-B2, and OL-B3 included in the display device DD-TD of one or more embodiments may include the fused polycyclic compound of one or more embodiments described above. For example, in one or more embodiments, at least one of (e.g., at least one selected from among) the plurality of emission layers included in the light emitting device ED-BT may include the fused polycyclic compound of one or more embodiments.

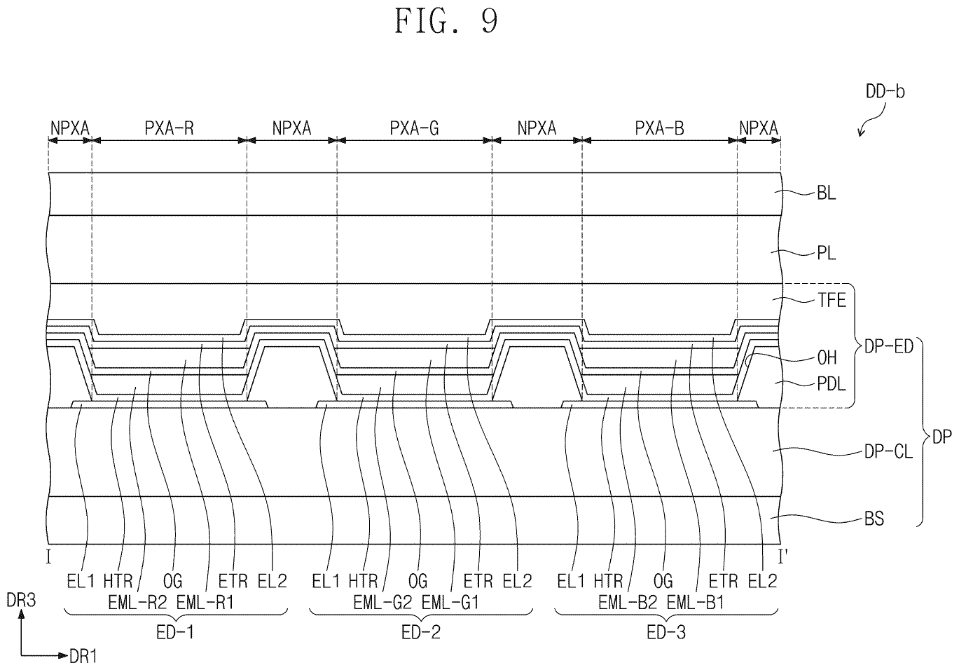

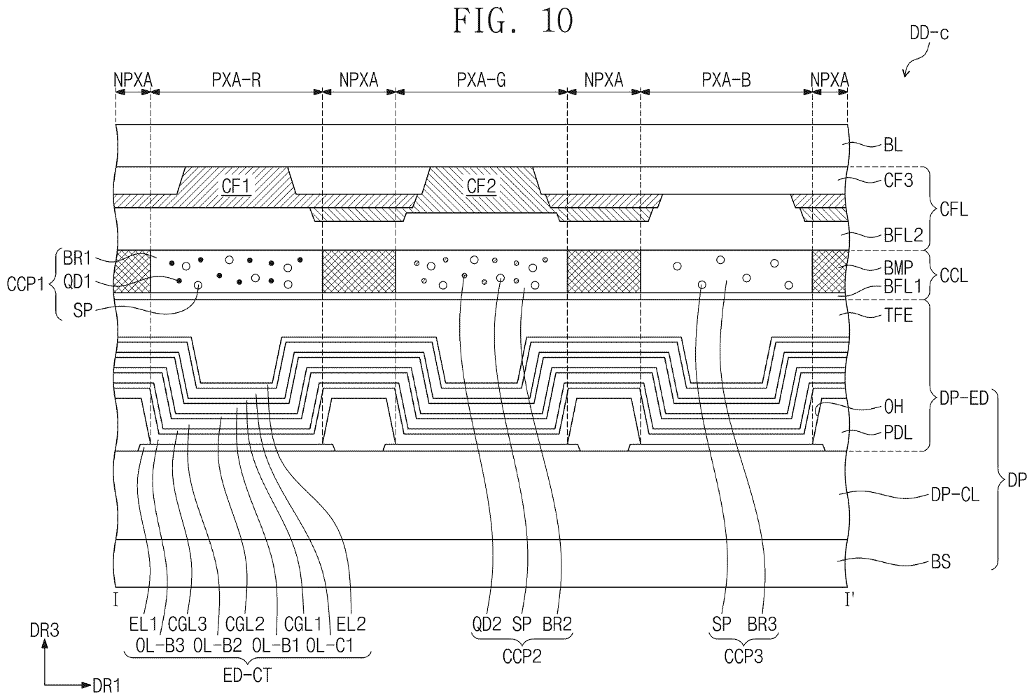

FIG. 9 is a cross-sectional view showing a display apparatus according to one or more embodiments of the present disclosure. FIG. 10 is a cross-sectional view showing a display apparatus according to one or more embodiments of the present disclosure.

Referring to FIG. 9, a display apparatus DD-b according to one or more embodiments may include light emitting devices ED-1, ED-2, and ED-3, formed by stacking two emission layers. Compared to the display apparatus DD shown in FIG. 2, the display apparatus DD-b shown in FIG. 9 is different in that first to third light emitting devices ED-1, ED-2, and ED-3 each include two emission layers stacked in a thickness direction. In the first to third light emitting devices ED-1, ED-2, and ED-3, the two emission layers may be to emit light in substantially the same wavelength region.

In one or more embodiments, the first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. In one or more embodiments, the emission auxiliary part OG may include an electron transport region, a charge generating layer, and a hole transport region stacked in order (e.g., in the stated order). The emission auxiliary part OG may be provided as a common layer in all of the first to third light emitting devices ED-1, ED-2, and ED-3. However, embodiments of the present disclosure are not limited thereto, and the emission auxiliary part OG may be patterned and provided in an opening part OH defined in a pixel definition layer PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, in one or more embodiments, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2, stacked in order (e.g., in the stated order). The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order (e.g., in the stated order). The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order (e.g., in the stated order).

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. In some embodiments, the optical auxiliary layer PL may not be provided from the display apparatus.

In one or more embodiments, at least one emission layer included in the display device DD-b shown in FIG. 9 may include the fused polycyclic compound of one or more embodiments described above. For example, in some embodiments, at least one of the first blue emission layer EML-B1 or the second blue emission layer EML-B2 may include the fused polycyclic compound of one or more embodiments.

Different from FIG. 8 and FIG. 9, a display apparatus DD-c in FIG. 10 is shown to include four light emitting structures OL-B1, OL-B2, OL-B3, and OL-C1. A light emitting device ED-CT may include oppositely disposed first electrode EL1 and second electrode EL2, and first to fourth light emitting structures OL-B1, OL-B2, OL-B3, and OL-C1 stacked in a thickness direction between the first electrode EL1 and the second electrode EL2. The third light emitting structures OL-B3, the second light emitting structures OL-B2, the first light emitting structures OL-B1, and the fourth light emitting structures OL-C1 are stacked in order (e.g., in the stated order) in a thickness direction. Between the first to fourth light emitting structures OL-B1, OL-B2, OL-B3, and OL-C1, charge generating layers CGL1, CGL2, and CGL3 may be disposed. For example, A first charge generating layer CGL1 is disposed between the first light emitting structures OL-B1 and the fourth light emitting structures OL-C1. A second charge generating layer CGL2 is disposed between the first light emitting structures OL-B1 and the second light emitting structures OL-B2. A third charge generating layer CGL3 is disposed between the second light emitting structures OL-B2 and the third light emitting structures OL-B3.

Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit different wavelengths of light.

Charge generating layers CGL1, CGL2, and CGL3 disposed among neighboring light emitting structures OL-B1, OL-B2, OL-B3, and OL-C1 may include a p-type or kind charge (e.g., P-charge) generating layer and/or an n-type or kind charge (e.g., N-charge) generating layer.

At least one selected from among the light emitting structures OL-B1, OL-B2, OL-B3, and OL-C1 included in the display device DD-c according to one or more embodiments may include the fused polycyclic compound of one or more embodiments described above. For example, in one or more embodiments, at least one selected from among the first to third light emitting structures OL-B1, OL-B2, and OL-B3 may include the fused polycyclic compound of one or more embodiments described above.

The light emitting device/element ED described above according to one or more embodiments of the present disclosure may include the fused polycyclic compound of one or more embodiments in at least one functional layer disposed between the first electrode EL1 and the second electrode EL2, and may thus exhibit excellent or suitable light emitting efficiency and improved lifespan. For example, the fused polycyclic compound according to one or more embodiments may be included in the emission layer EML of the light emitting element ED of one or more embodiments, and the light emitting element of one or more embodiments may exhibit long lifespan.

In one or more embodiments, an electronic apparatus may include a display apparatus including multiple light emitting devices and a control part controlling the display apparatus. The electronic apparatus of one or more embodiments may be an apparatus activated according to electrical signals. The electronic apparatus may include display apparatuses of one or more suitable embodiments. For example, the electronic apparatus may include at least one selected from televisions, monitors, large-size display apparatuses such as outside billboards, personal computers, laptop computers, personal digital terminals, display apparatuses for automobiles, game consoles, portable electronic devices, and medium- and small-size display apparatuses such as cameras.

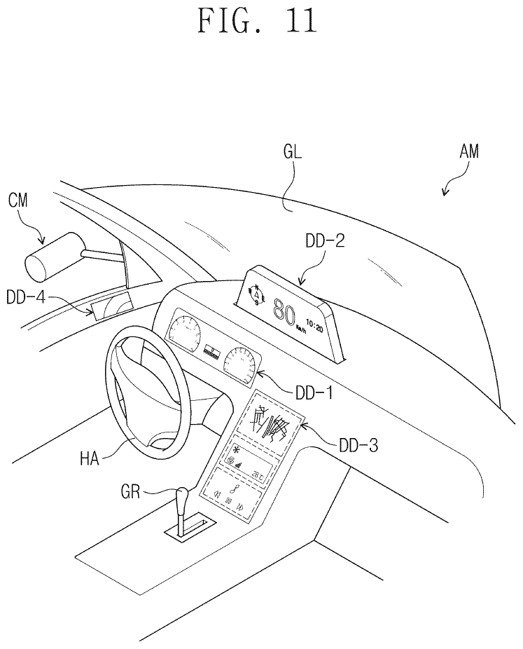

FIG. 11 is a diagram showing an automobile AM in which first to fourth display apparatuses DD-1, DD-2, DD-3, and DD-4 are disposed. At least one selected from among the first to fourth display apparatuses DD-1, DD-2, DD-3, and DD-4 may include substantially the same configurations of the display apparatuses DD, DD-TD, DD-a, DD-b, and/or DD-c, explained referring to FIGS. 1, 2, and 7 to 10.

In FIG. 11, a vehicle is shown as an automobile AM, but this is a mere example. The first to fourth display apparatuses DD-1, DD-2, DD-3, and DD-4 may be disposed on other transport apparatuses such as bicycles, motorcycles, trains, ships, and/or airplanes. In some embodiments, at least one selected from among the first to fourth display apparatuses DD-1, DD-2, DD-3, and DD-4 including substantially the same configurations of the display apparatuses DD, DD-TD, DD-a, DD-b, and/or DD-c may be introduced in personal computers, laptop computers, personal digital terminals, game consoles, portable electronic devices, televisions, monitors, external billboards, and/or the like. These are mere examples, and the display apparatus may be introduced in other electronic devices as long as not deviated from the present disclosure.

In one or more embodiments, at least one selected from among the first to fourth display devices DD-1, DD-2, DD-3, and DD-4 may include the light emitting element ED of one or more embodiments described with reference to FIGS. 3 to 6. The light emitting element ED according to one or more embodiments may include the fused polycyclic compound of one or more embodiments. In one or more embodiments, at least one selected from among the first to fourth display devices DD-1, DD-2, DD-3, and DD-4 may include a light emitting element ED containing the fused polycyclic compound of one or more embodiments, thereby increasing lifespan.

Referring to FIG. 11, an automobile AM may include a steering wheel HA for the operation of the automobile AM and a gear GR. In addition, the automobile AM may include a front window GL disposed to face a driver.

A first display apparatus DD-1 may be disposed in a first region overlapping with the steering wheel HA. For example, the first display apparatus DD-1 may be a digital cluster displaying first information of the automobile AM. The first information may include a first graduation showing the travel speed of the automobile AM, a second graduation showing the number of revolution of an engine (i.e., revolutions per minute (RPM)), and images showing a fuel state. The first graduation and second graduation may be represented by digital images.

A second display apparatus DD-2 may be disposed in a second region facing a driver seat and overlapping with the front window GL. The driver seat may be a seat where the steering wheel HA faces. For example, the second display apparatus DD-2 may be a head up display (HUD) showing second information of the automobile AM. The second display apparatus DD-2 may be optically clear. The second information may include digital numbers showing the travel speed of the automobile AM and may further include information including the current time. In some embodiments, the second information of the second display apparatus DD-2 may be projected and displayed on the front window GL.

A third display apparatus DD-3 may be disposed in a third region adjacent to the gear GR. For example, the third display apparatus DD-3 may be a center information display (CID) for the automobile, disposed between a driver seat and a passenger seat and showing third information. The passenger seat may be a seat separated from the driver seat with the gear GR therebetween. The third information may include information on road conditions (for example, navigation information), on playing music or radio, on playing a dynamic image (or image), on the temperature in the automobile AM, and/or the like.

A fourth display apparatus DD-4 may be disposed in a fourth region separated from the steering wheel HA and the gear GR and adjacent to a side of the automobile AM. For example, the fourth display apparatus DD-4 may be a digital wing mirror displaying fourth information. The fourth display apparatus DD-4 may display external images of the automobile AM, taken by a camera module CM disposed at the outside of the automobile AM. The fourth information may include the external images of the automobile AM.

The above-described first to fourth information are mere examples, and the first to fourth display apparatuses DD-1, DD-2, DD-3, and DD-4 may further display information on the inside and outside of the automobile. The first to fourth information may include different information from each other. However, embodiments of the present disclosure are not limited thereto, for example, in some embodiments, a portion of the first to fourth information may include the same information.

Hereinafter, with reference to Examples and Comparative Examples, a fused polycyclic compound and a light emitting element of one or more embodiments of the present disclosure will be specifically described. In addition, Examples described herein are shown only for the understanding of the present disclosure, and the scope of the present disclosure is not limited thereto.

### EXAMPLES

### 1. Synthesis of Fused Polycyclic Compounds

First, a process of synthesizing fused polycyclic compounds according to one or more embodiments of the present disclosure will be described in more detail by presenting a process of synthesizing Compounds 54, 118, 187, and 267 as an example. In addition, the process of synthesizing fused polycyclic compounds, which will be described hereinafter, is provided as a mere example, and thus a process of synthesizing fused polycyclic compounds according to one or more embodiments of the present disclosure is not limited to Examples.

### 1 Synthesis of Compound 54

### Synthesis of Intermediate 54-1

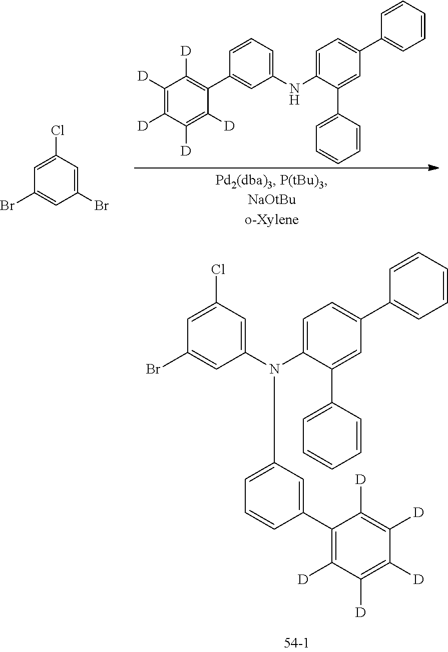 [SMILES: Clc1cc(Br)cc(Br)c1 ; [2H]c1c([2H])c([2H])c(-c2cccc(Nc3ccc(-c4ccccc4)cc3-c3ccccc3)c2)c([2H])c1[2H] ; [2H]c1c([2H])c([2H])c(-c2cccc(N(c3cc(Cl)cc(Br)c3)c3ccc(-c4ccccc4)cc3-c3ccccc3)c2)c([2H])c1[2H]]

1,3-dibromo-5-chlorobenzene (1 eq), N-([1,1′-biphenyl]-3-yl-2′,3′,4′,5′,6′-d5)-[1, 1′:3′,1″-terphenyl]-4′-amine (1 eq), tris(dibenzylideneacetone)dipalladium(0) (0.05 eq), tri-tert-butylphosphine (P(tBu)₃, 0.10 eq), and sodium tert-butoxide (3 eq) were dissolved in o-xylene and stirred at 150° C. for 20 hours in a nitrogen atmosphere. After cooling, the resulting product was dried under reduced pressure to remove o-xylene. Thereafter, the resultant was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 54-1. (Yield: 59%)

### Synthesis of Intermediate 54-2

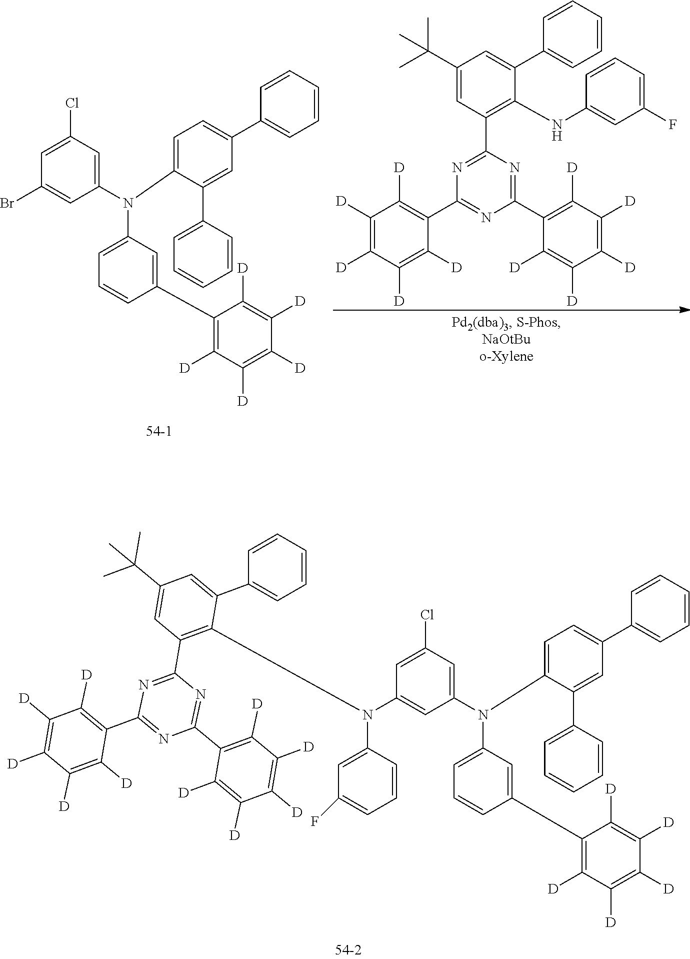 [SMILES: [2H]c1c([2H])c([2H])c(-c2cccc(N(c3cc(Cl)cc(Br)c3)c3ccc(-c4ccccc4)cc3-c3ccccc3)c2)c([2H])c1[2H] ; [2H]c1c([2H])c([2H])c(-c2nc(-c3cc(C(C)(C)C)cc(-c4ccccc4)c3Nc3cccc(F)c3)nc(-c3c([2H])c([2H])c([2H])c([2H])c3[2H])n2)c([2H])c1[2H] ; [2H]c1c([2H])c([2H])c(-c2cccc(N(c3cc(Cl)cc(N(c4cccc(F)c4)c4c(-c5ccccc5)cc(C(C)(C)C)cc4-c4nc(-c5c([2H])c([2H])c([2H])c([2H])c5[2H])nc(-c5c([2H])c([2H])c([2H])c([2H])c5[2H])n4)c3)c3ccc(-c4ccccc4)cc3-c3ccccc3)c2)c([2H])c1[2H]]

Intermediate 54-1 (1 eq), 5-(tert-butyl)-N-(3-fluorophenyl)-3-(4-(phenyl-d5)-6-(phenyl-d5)-1,3,5-triazin-2-yl)-[1,1′-biphenyl]-2-amine (1.2 eq), tris(dibenzylideneacetone)dipalladium(0) (0.05 eq), 2-dicyclohexylphosphino-2′,6′-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 54-2. (Yield: 63%)

### Synthesis of Intermediate 54-3

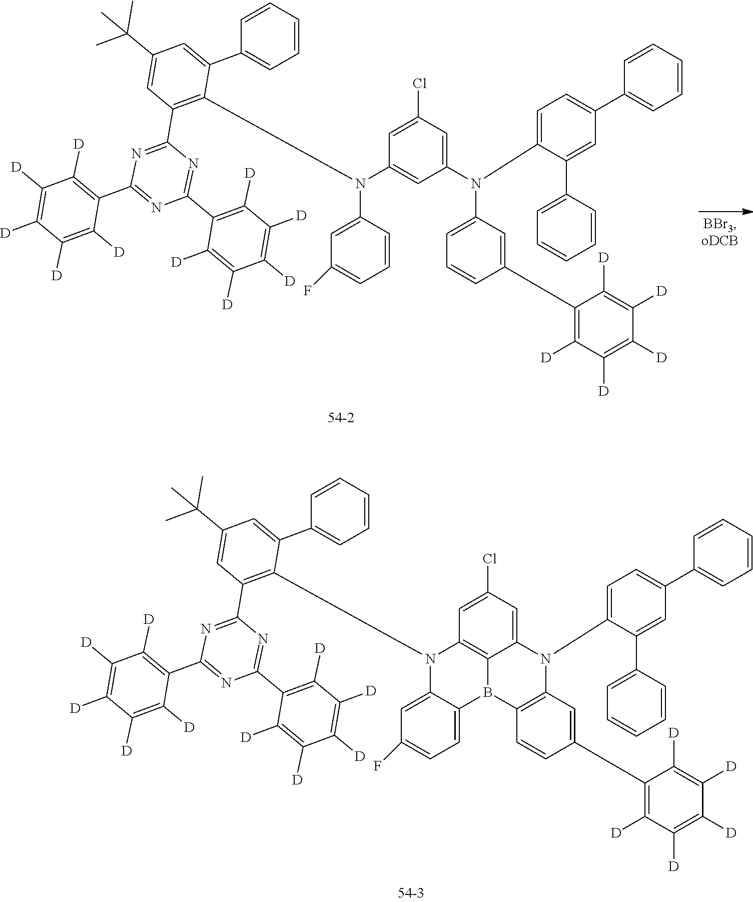 [SMILES: [2H]c1c([2H])c([2H])c(-c2cccc(N(c3cc(Cl)cc(N(c4cccc(F)c4)c4c(-c5ccccc5)cc(C(C)(C)C)cc4-c4nc(-c5c([2H])c([2H])c([2H])c([2H])c5[2H])nc(-c5c([2H])c([2H])c([2H])c([2H])c5[2H])n4)c3)c3ccc(-c4ccccc4)cc3-c3ccccc3)c2)c([2H])c1[2H] ; [2H]c1c([2H])c([2H])c(-c2ccc3c(c2)N(c2ccc(-c4ccccc4)cc2-c2ccccc2)c2cc(Cl)cc4c2B3c2ccc(F)cc2N4c2c(-c3ccccc3)cc(C(C)(C)C)cc2-c2nc(-c3c([2H])c([2H])c([2H])c([2H])c3[2H])nc(-c3c([2H])c([2H])c([2H])c([2H])c3[2H])n2)c([2H])c1[2H]]

Intermediate 54-2 (1 eq) was dissolved in ortho dichlorobenzene in a flask, and the flask was cooled to 0° C. in a nitrogen atmosphere, and then BBr₃ (5 eq) dissolved in ortho dichlorobenzene was slowly injected thereto. After the injection was completed, the temperature was raised to 190° C. to stir the resulting product for 24 hours. After cooling the resulting product to 1° C., triethylamine was slowly dropped into the flask until the exotherm stopped to complete the reaction, and then n-hexane and methanol were added for precipitation to obtain a solid content through filtration. The obtained solid content was purified through silica filtration and then purified through methylene chloride and hexane recrystallization, thereby obtaining Intermediate 54-3. Thereafter, the resulting product was purified through column chromatography and recrystallized (dichloromethane:n-hexane) for final purification. (Yield: 9%)

### Synthesis of Intermediate 54-4

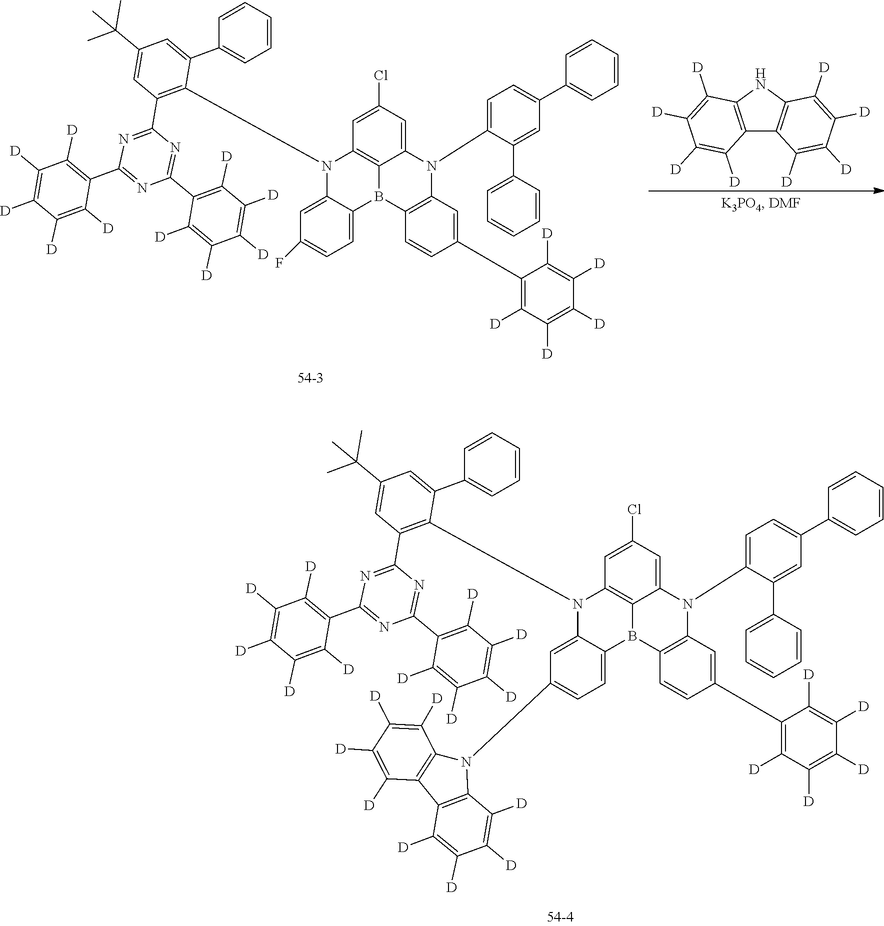

Intermediate 54-3 (1 eq), 9H-carbazole-1,2,3,4,5,6,7,8-d8 (1 eq), and tripotassium phosphate (K₃PO₄, 3 eq) were dissolved in N,N-dimethylformamide anhydrous, and then stirred under high pressure at 150° C. for 24 hours. After cooling, the resulting product was dried under reduced pressure to remove N,N-dimethylformamide. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 54-4 (yield: 55%).

### Synthesis of Compound 54

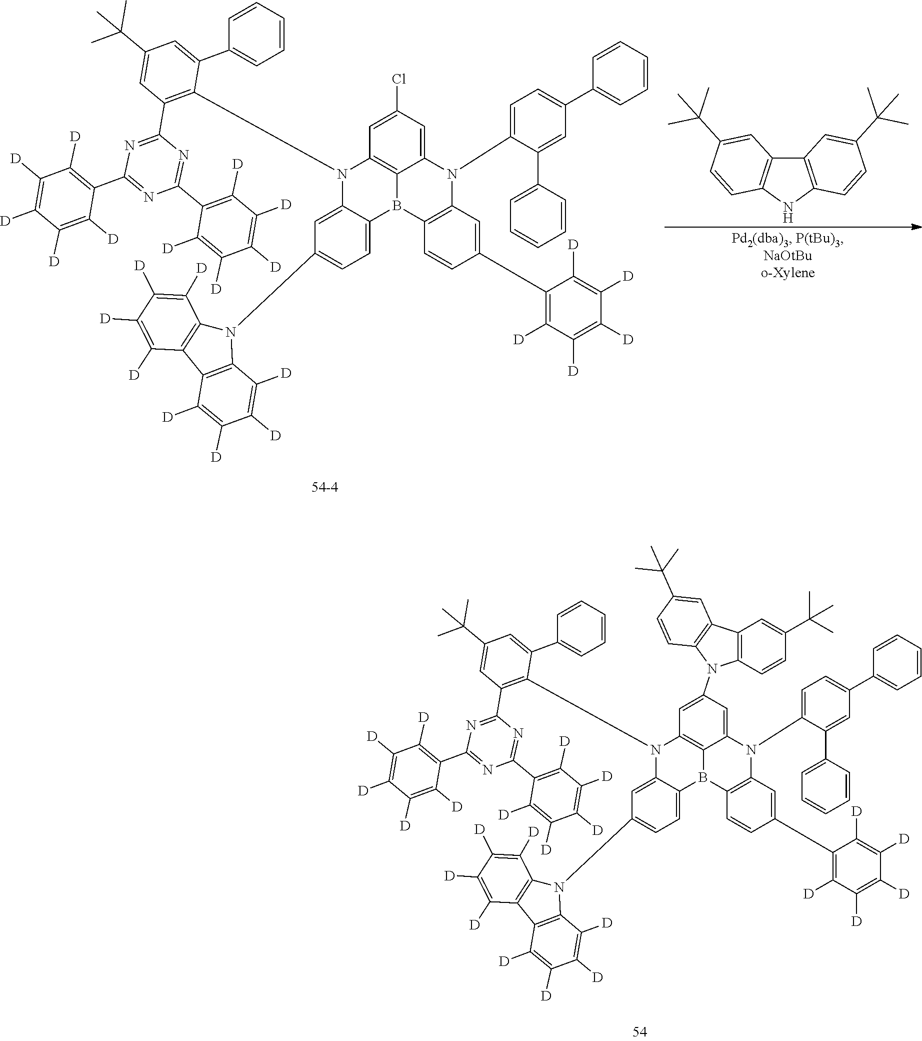

Intermediate 54-4 (1 eq), 3,6-di-tert-butyl-9H-carbazole (1.1 eq), tris(dibenzylideneacetone)dipalladium(0) (0.05 eq), tri-tert-butylphosphine (P(tBu)₃, 0.10 eq), and sodium tert-butoxide (3 eq) were dissolved in o-xylene and stirred at 150° C. for 24 hours in a nitrogen atmosphere. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Compound 54 (yield: 53%). Thereafter, the resulting product was further purified through sublimation purification, and the obtained compound was confirmed to be Compound 54 through electrospray ionisation-liquid chromatography mass spectrometry (ESI-LCMS). ESI-LCMS: [M]+: 1477.3

### 2 Synthesis of Compound 118

### Synthesis of Intermediate 118-1

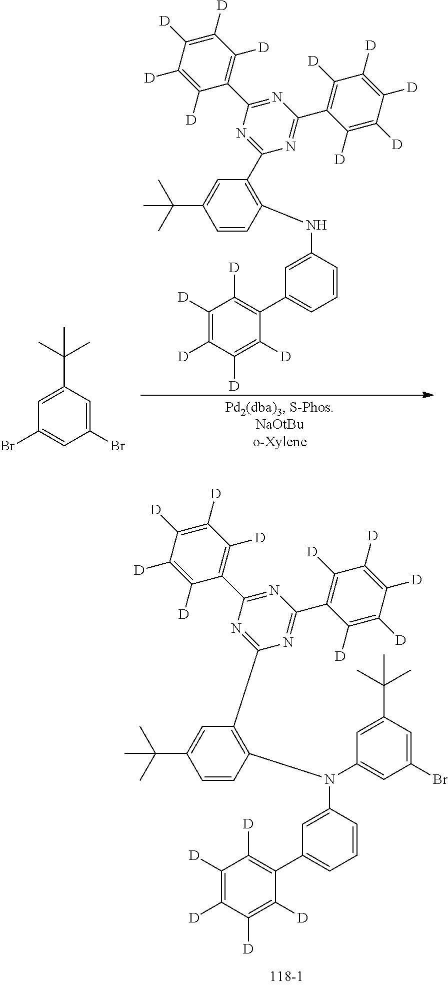

1,3-dibromo-5-(tert-butyl)benzene (1 eq), N-(4-(tert-butyl)-2-(4-(phenyl-d5)-6-(phenyl-d5)-1,3,5-triazin-2-yl)phenyl)-[1,1′-biphenyl]-2′,3′,4′,5′,6′-d5-3-amine (1 eq), tris(dibenzylideneacetone)dipalladium(0) (0.05 eq), 2-dicyclohexylphosphino-2′,6′-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 118-1. (Yield: 67%)

### Synthesis of Intermediate 118-2

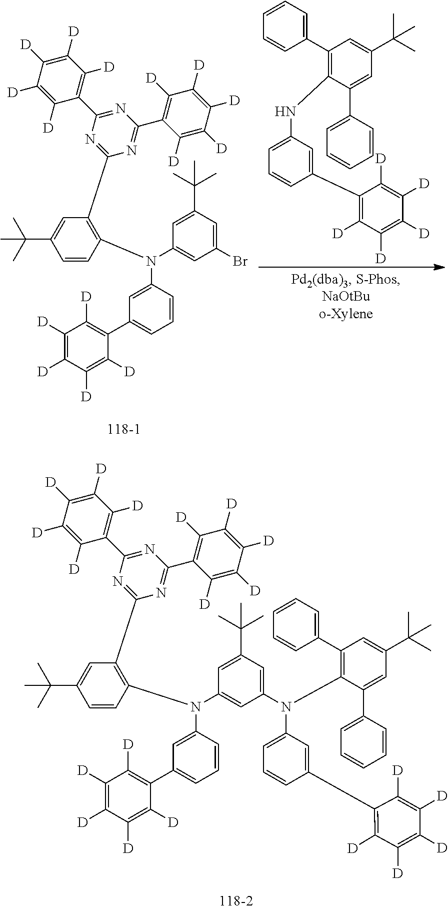

Intermediate 118-1 (1 eq), N-([1,1′-biphenyl]-3-yl-2′,3′,4′,5′,6′-d5)-5′-(tert-butyl)-[1,1′:3′,1″-terphenyl]-2′-amine (1 eq), tris(dibenzylideneacetone)dipalladium(0) (0.05 eq), 2-dicyclohexylphosphino-2′,6′-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 118-2. (Yield: 58%)

### Synthesis of Compound 118

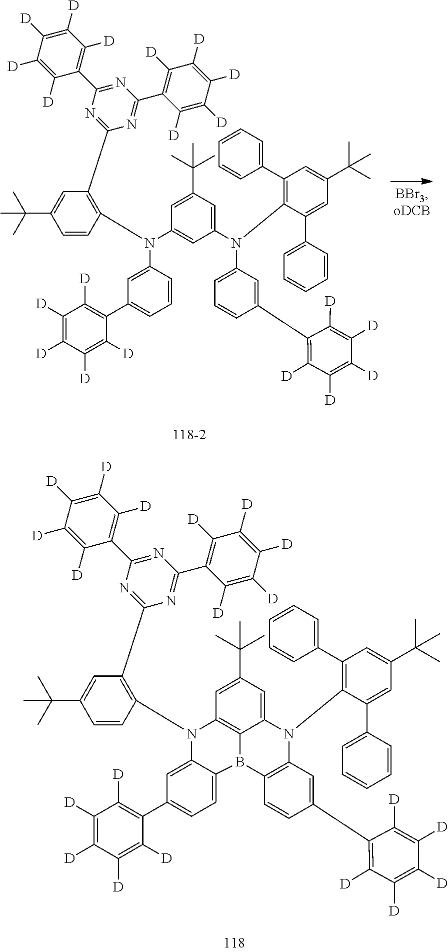

Intermediate 118-2 (1 eq) was dissolved in ortho dichlorobenzene in a flask, and the flask was cooled to 0° C. in a nitrogen atmosphere, and then BBr₃ (5 eq) dissolved in ortho dichlorobenzene was slowly injected thereto. After the injection was completed, the temperature was raised to 190° C. to stir the resulting product for 24 hours. After cooling the resulting product to 0° C., triethylamine was slowly dropped into the flask until the exotherm stopped to complete the reaction, and then n-hexane and methanol were added for precipitation to obtain a solid content through filtration. The obtained solid content was purified through silica filtration and then purified through methylene chloride and hexane recrystallization, thereby obtaining Compound 118. Thereafter, the resulting product was purified through column chromatography and recrystallized (dichloromethane:n-hexane) for final purification. (Yield: 12%), Thereafter, the resulting product was further purified through sublimation purification, and the obtained compound was confirmed to be Compound 118 through ESI-LCMS. ESI-LCMS: [M]+: 1143.7

### 3 Synthesis of Compound 187 Synthesis of Intermediate 187-1

### NH

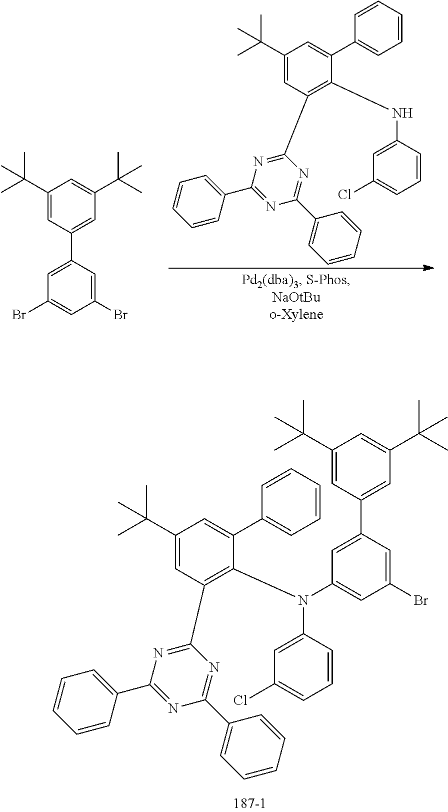

3,5-dibromo-3′,5′-di-tert-butyl-1,1′-biphenyl (1 eq), 5-(tert-butyl)-N-(3-chlorophenyl)-3-(4,6-diphenyl-1,3,5-triazin-2-yl)-[1,1′-biphenyl]-2-amine (1 eq), tris(dibenzylideneacetone)dipalladium(0) (0.05 eq), 2-dicyclohexylphosphino-2′,6′-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 187-1. (Yield: 71%)

### Synthesis of Intermediate 187-2

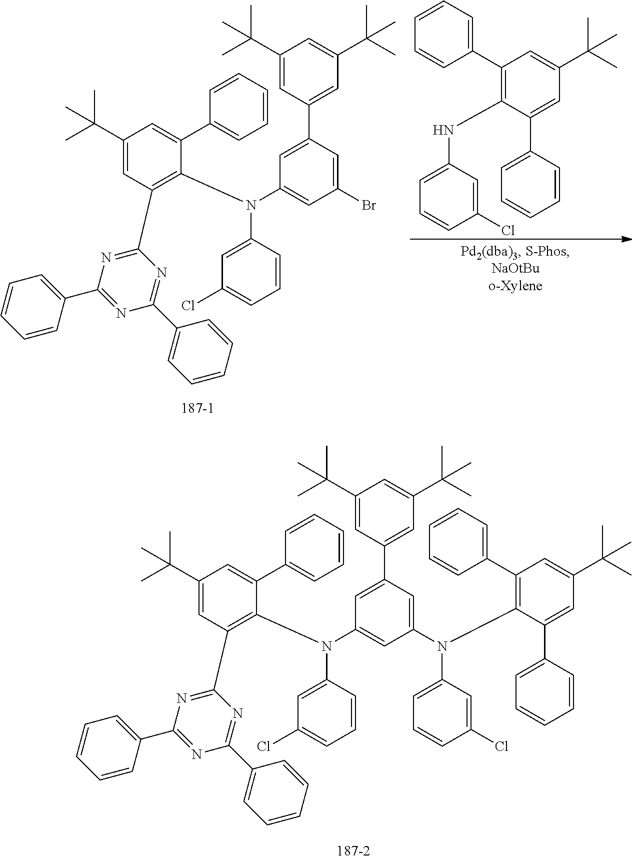

Intermediate 187-1 (1 eq), 5′-(tert-butyl)-N-(3-chlorophenyl)-[1,1′:3′,1″-terphenyl]-2′-amine (1 eq), tris(dibenzylideneacetone)dipalladium(0) (0.05 eq), 2-dicyclohexylphosphino-2′,6″-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 187-2. (Yield: 75%)

### Synthesis of Intermediate 187-3

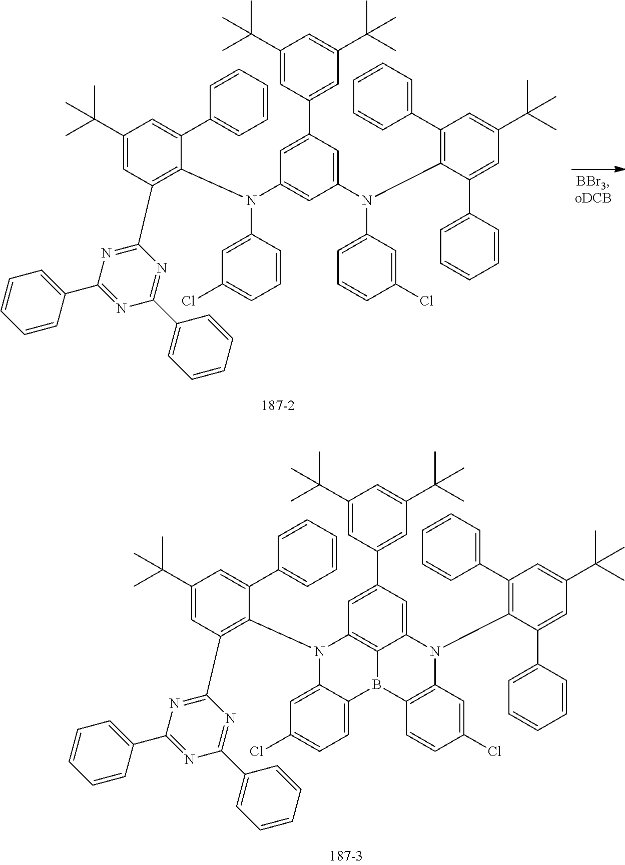 [SMILES: CC(C)(C)c1cc(-c2cc(N(c3cccc(Cl)c3)c3c(-c4ccccc4)cc(C(C)(C)C)cc3-c3ccccc3)cc(N(c3cccc(Cl)c3)c3c(-c4ccccc4)cc(C(C)(C)C)cc3-c3nc(-c4ccccc4)nc(-c4ccccc4)n3)c2)cc(C(C)(C)C)c1 ; CC(C)(C)c1cc(-c2cc3c4c(c2)N(c2c(-c5ccccc5)cc(C(C)(C)C)cc2-c2nc(-c5ccccc5)nc(-c5ccccc5)n2)c2cc(Cl)ccc2B4c2ccc(Cl)cc2N3c2c(-c3ccccc3)cc(C(C)(C)C)cc2-c2ccccc2)cc(C(C)(C)C)c1]

Intermediate 187-2 (1 eq) was dissolved in ortho dichlorobenzene in a flask, and the flask was cooled to 0° C. in a nitrogen atmosphere, and then BBr₃ (5 eq) dissolved in ortho dichlorobenzene was slowly injected thereto. After the injection was completed, the temperature was raised to 190° C. to stir the resulting product for 24 hours. After cooling the resulting product to 0° C., triethylamine was slowly dropped into the flask until the exotherm stopped to complete the reaction, and then n-hexane and methanol were added for precipitation to obtain a solid content through filtration. The obtained solid content was purified through silica filtration and then purified through methylene chloride and hexane recrystallization, thereby obtaining Intermediate 187-3. (Yield: 12%)

### Synthesis of Compound 187

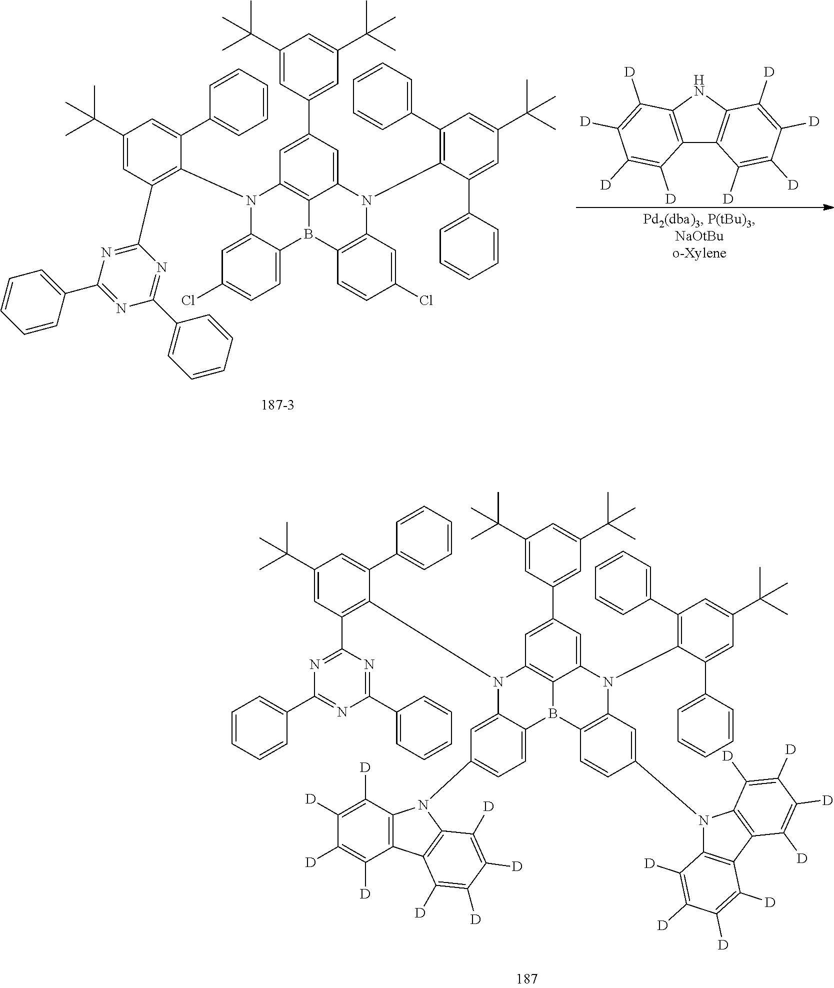

Intermediate 187-3 (1 eq), 9H-carbazole-1,2,3,4,5,6,7,8-d8 (1.1 eq), tris(dibenzylideneacetone)dipalladium(0) (0.05 eq), tri-tert-butylphosphine (P(tBu)₃, 0.10 eq), and sodium tert-butoxide (3 eq) were dissolved in o-xylene and stirred at 150° C. for 24 hours in a nitrogen atmosphere. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Compound 187 (yield: 57%). Thereafter, the resulting product was further purified through sublimation purification, and the obtained compound was confirmed to be Compound 187 through ESI-LCMS. ESI-LCMS: [M]+: 1527.3

### 4 Synthesis of Compound 267

### Synthesis of Intermediate 267-1

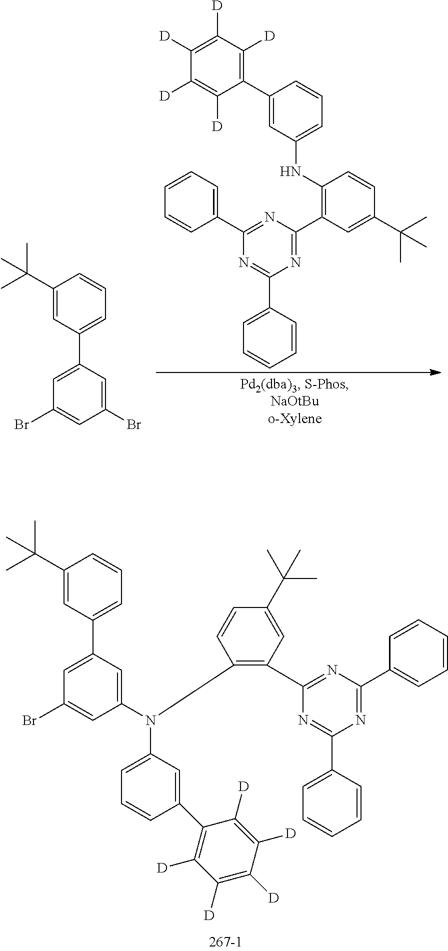 [SMILES: CC(C)(C)c1cccc(-c2cc(Br)cc(Br)c2)c1 ; [2H]c1c([2H])c([2H])c(-c2cccc(Nc3ccc(C(C)(C)C)cc3-c3nc(-c4ccccc4)nc(-c4ccccc4)n3)c2)c([2H])c1[2H] ; [2H]c1c([2H])c([2H])c(-c2cccc(N(c3cc(Br)cc(-c4cccc(C(C)(C)C)c4)c3)c3ccc(C(C)(C)C)cc3-c3nc(-c4ccccc4)nc(-c4ccccc4)n3)c2)c([2H])c1[2H]]

3,5-dibromo-3′-(tert-butyl)-1,1′-biphenyl (1 eq), N-(4-(tert-butyl)-2-(4,6-diphenyl-1,3,5-triazin-2-yl)phenyl)-[1,1′-biphenyl]-2′,3′,4′,5′,6′-d5-3-amine (1 eq), tris(dibenzylideneacetone)dipalladium(0) (0.05 eq), tri-tert-butylphosphine (P(tBu)₃, 0.10 eq), and sodium tert-butoxide (3 eq) were dissolved in o-xylene and stirred in a high pressure reactor at 150° C. for 24 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 267-1 (yield: 64%).

### Synthesis of Intermediate 267-2

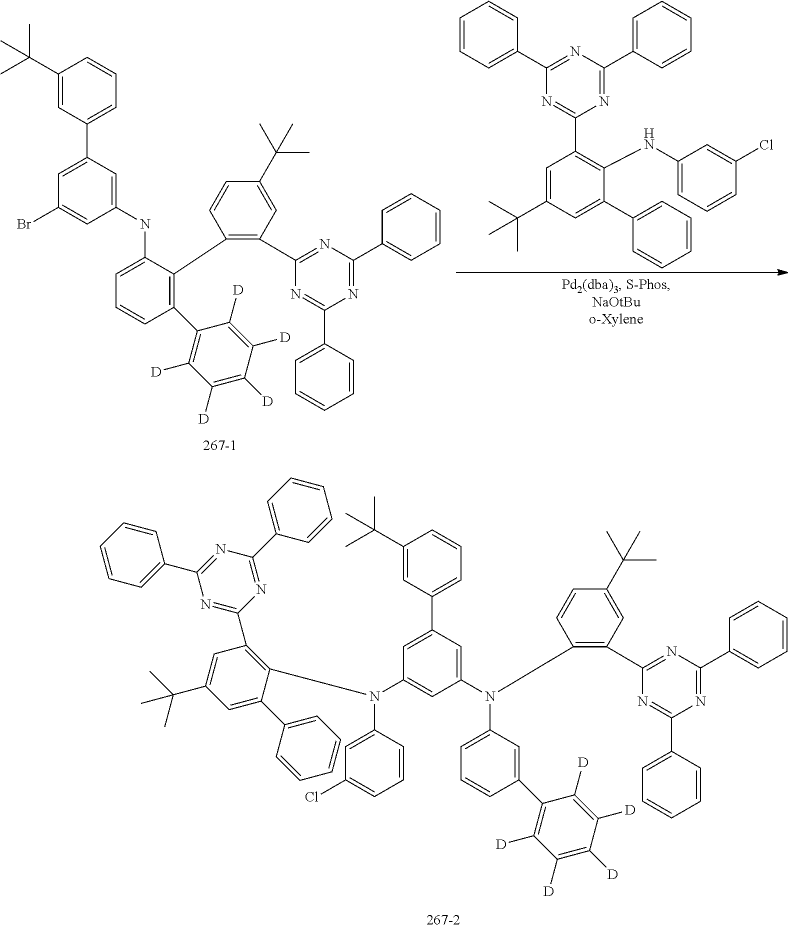 [SMILES: [2H]c1c([2H])c([2H])c(-c2cccc(Nc3cc(Br)cc(-c4cccc(C(C)(C)C)c4)c3)c2-c2ccc(C(C)(C)C)cc2-c2nc(-c3ccccc3)nc(-c3ccccc3)n2)c([2H])c1[2H] ; CC(C)(C)c1cc(-c2ccccc2)c(Nc2cccc(Cl)c2)c(-c2nc(-c3ccccc3)nc(-c3ccccc3)n2)c1 ; [2H]c1c([2H])c([2H])c(-c2cccc(N(c3cc(-c4cccc(C(C)(C)C)c4)cc(N(c4cccc(Cl)c4)c4c(-c5ccccc5)cc(C(C)(C)C)cc4-c4nc(-c5ccccc5)nc(-c5ccccc5)n4)c3)c3ccc(C(C)(C)C)cc3-c3nc(-c4ccccc4)nc(-c4ccccc4)n3)c2)c([2H])c1[2H]]

Intermediate 267-1 (1 eq), 5-(tert-butyl)-N-(3-chlorophenyl)-3-(4,6-diphenyl-1,3,5-triazin-2-yl)-[1,1′-biphenyl]-2-amine (1 eq), tris(dibenzylideneacetone)dipalladium(0) (0.05 eq), 2-dicyclohexylphosphino-2′,6′-dimethoxybiphenyl (S-Phos, 0.10 eq), and sodium tert-butoxide (3 eq) were dissolved in o-xylene and stirred in a high pressure reactor at 150° C. for 20 hours. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Intermediate 267-2. (Yield: 72%)

### Synthesis of Intermediate 267-3

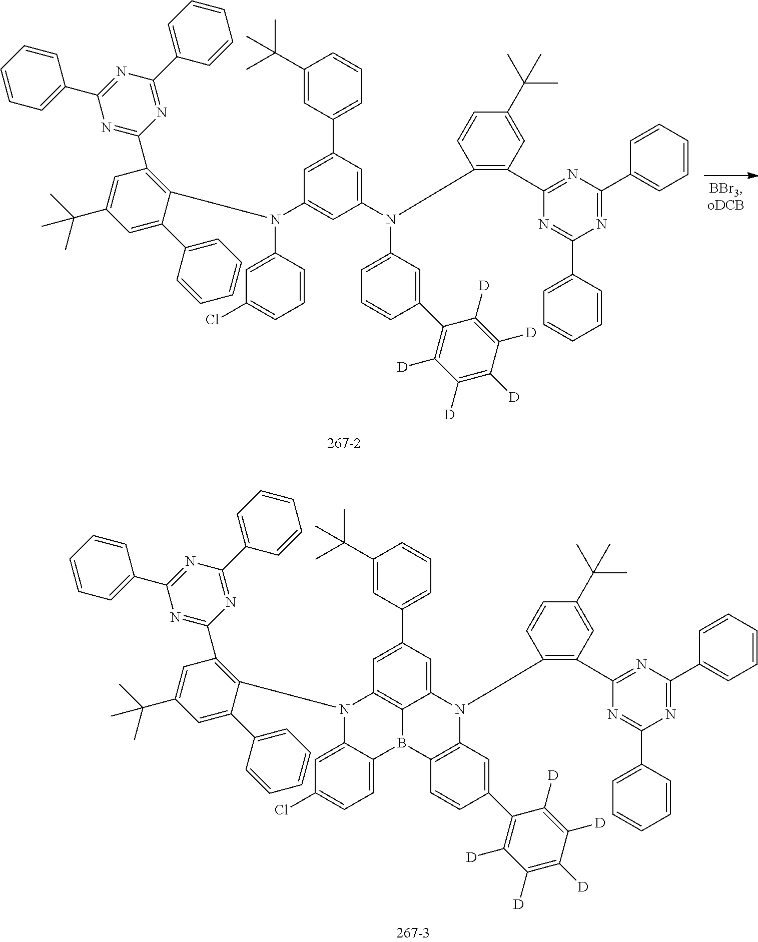 [SMILES: [2H]c1c([2H])c([2H])c(-c2cccc(N(c3cc(-c4cccc(C(C)(C)C)c4)cc(N(c4cccc(Cl)c4)c4c(-c5ccccc5)cc(C(C)(C)C)cc4-c4nc(-c5ccccc5)nc(-c5ccccc5)n4)c3)c3ccc(C(C)(C)C)cc3-c3nc(-c4ccccc4)nc(-c4ccccc4)n3)c2)c([2H])c1[2H] ; [2H]c1c([2H])c([2H])c(-c2ccc3c(c2)N(c2ccc(C(C)(C)C)cc2-c2nc(-c4ccccc4)nc(-c4ccccc4)n2)c2cc(-c4cccc(C(C)(C)C)c4)cc4c2B3c2ccc(Cl)cc2N4c2c(-c3ccccc3)cc(C(C)(C)C)cc2-c2nc(-c3ccccc3)nc(-c3ccccc3)n2)c([2H])c1[2H]]

Intermediate 267-2 (1 eq) was dissolved in ortho dichlorobenzene in a flask, and the flask was cooled to 0° C. in a nitrogen atmosphere, and then BBr₃ (5 eq) dissolved in ortho dichlorobenzene was slowly injected thereto. After the injection was completed, the temperature was raised to 190° C. to stir the resulting product for 24 hours. After cooling the resulting product to 0° C., triethylamine was slowly dropped into the flask until the exotherm stopped to complete the reaction, and then n-hexane and methanol were added for precipitation to obtain a solid content through filtration. The obtained solid content was purified through silica filtration and then purified through methylene chloride and hexane recrystallization, thereby obtaining Intermediate 267-3. (Yield: 10%)

### Synthesis of Compound 267

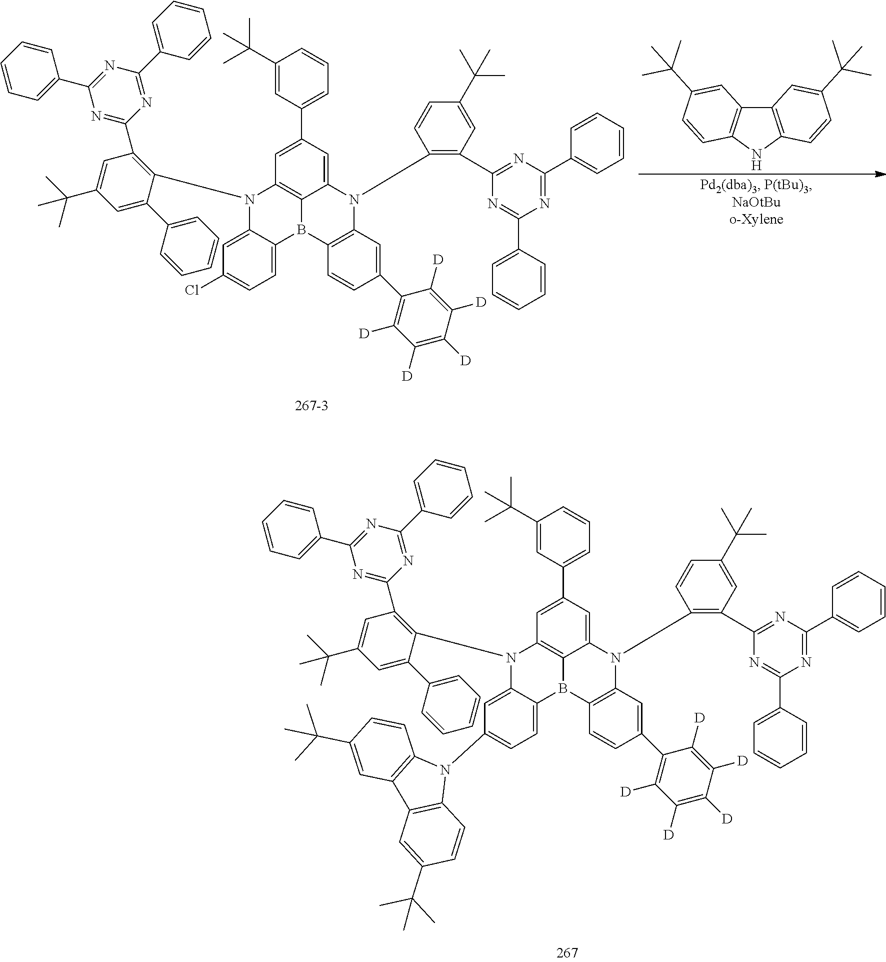 [SMILES: [2H]c1c([2H])c([2H])c(-c2ccc3c(c2)N(c2ccc(C(C)(C)C)cc2-c2nc(-c4ccccc4)nc(-c4ccccc4)n2)c2cc(-c4cccc(C(C)(C)C)c4)cc4c2B3c2ccc(Cl)cc2N4c2c(-c3ccccc3)cc(C(C)(C)C)cc2-c2nc(-c3ccccc3)nc(-c3ccccc3)n2)c([2H])c1[2H] ; CC(C)(C)c1ccc2[nH]c3ccc(C(C)(C)C)cc3c2c1 ; [2H]c1c([2H])c([2H])c(-c2ccc3c(c2)N(c2ccc(C(C)(C)C)cc2-c2nc(-c4ccccc4)nc(-c4ccccc4)n2)c2cc(-c4cccc(C(C)(C)C)c4)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)c([2H])c1[2H]]

Intermediate 267-3 (1 eq), 3,6-di-tert-butyl-9H-carbazole (1.1 eq), tris(dibenzylideneacetone)dipalladium(0) (0.05 eq), tri-tert-butylphosphine (P(tBu)₃, 0.10 eq), and sodium tert-butoxide (3 eq) were dissolved in o-xylene and stirred at 120° C. for 24 hours in a nitrogen atmosphere. After cooling, the resulting product was dried under reduced pressure to remove o-xylene. Thereafter, the resulting product was washed with ethyl acetate and water three times to obtain an organic layer, which was then dried over MgSO₄ and then dried under reduced pressure. The resulting product was purified through column chromatography and recrystallized (dichloromethane:n-hexane), thereby obtaining Compound 267 (yield: 62%). Thereafter, the resulting product was further purified through sublimation purification, and the obtained compound was confirmed to be Compound 267 through ESI-LCMS. ESI-LCMS: [M]+: 1562.3

### 2. Preparation and Evaluation of Light Emitting Elements

Light emitting elements of one or more embodiments including a fused polycyclic compound of one or more embodiments in an emission layer were each prepared utilizing a method described herein. Light emitting elements of Examples 1 to 4 were respectively prepared utilizing fused polycyclic compounds of 54, 118, 187, and 267, which are Example Compounds described above, as a dopant material of an emission layer. Comparative Examples 1 to 5 correspond to light emitting elements prepared utilizing Comparative Example Compound C1 to C5 as a dopant material of an emission layer, respectively.

### Example Compound

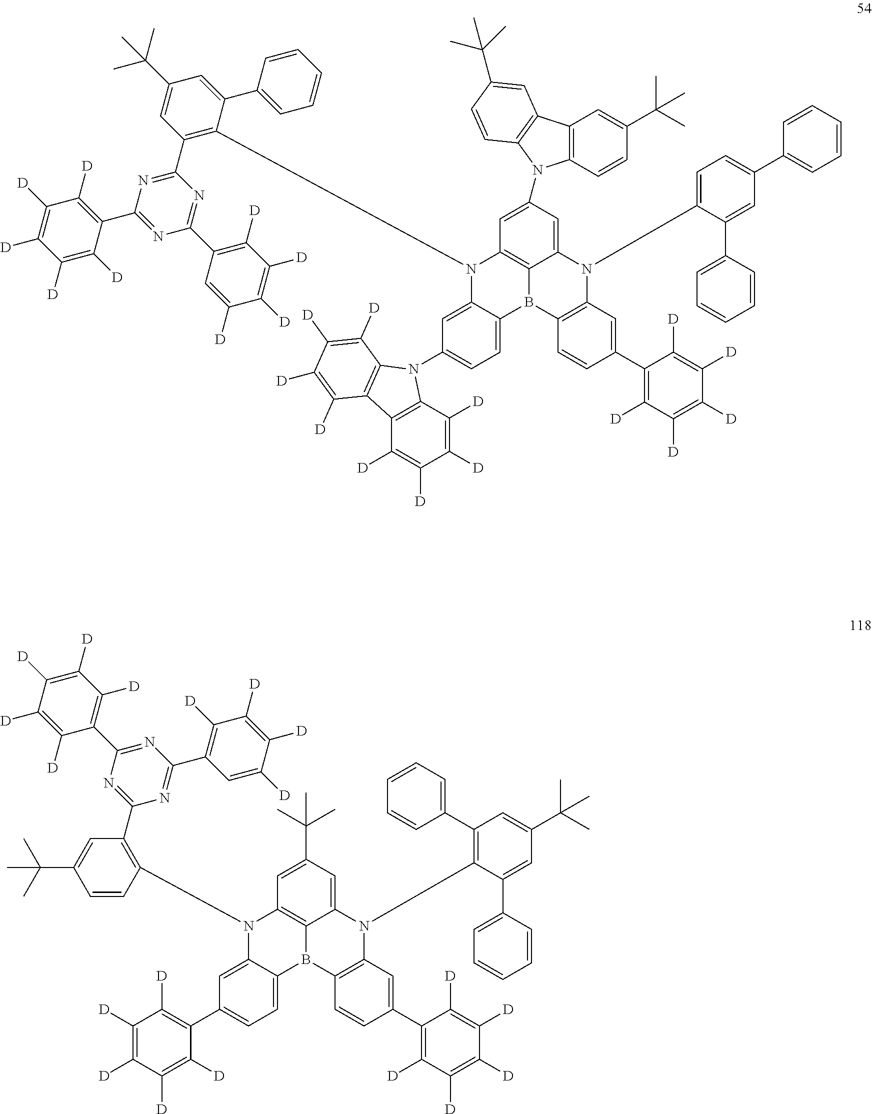

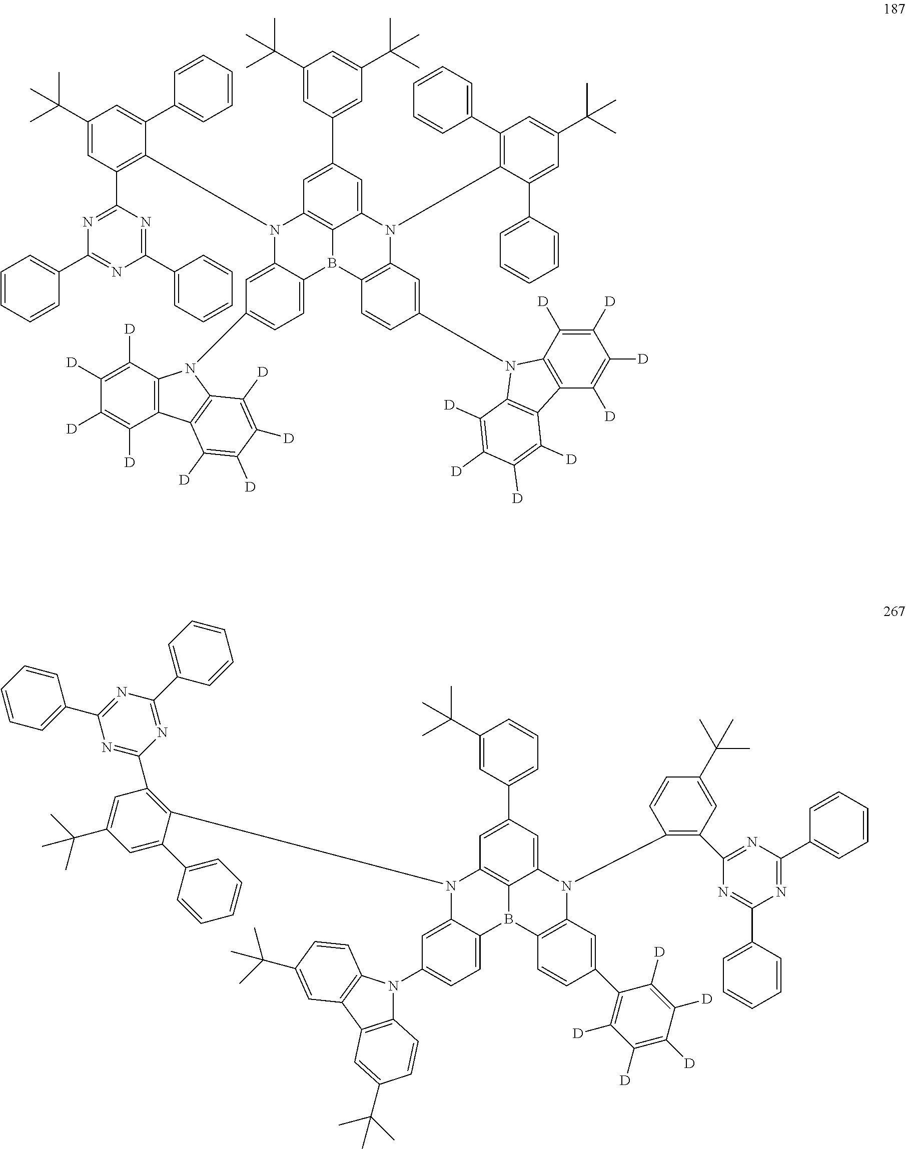

### Comparative Example Compound

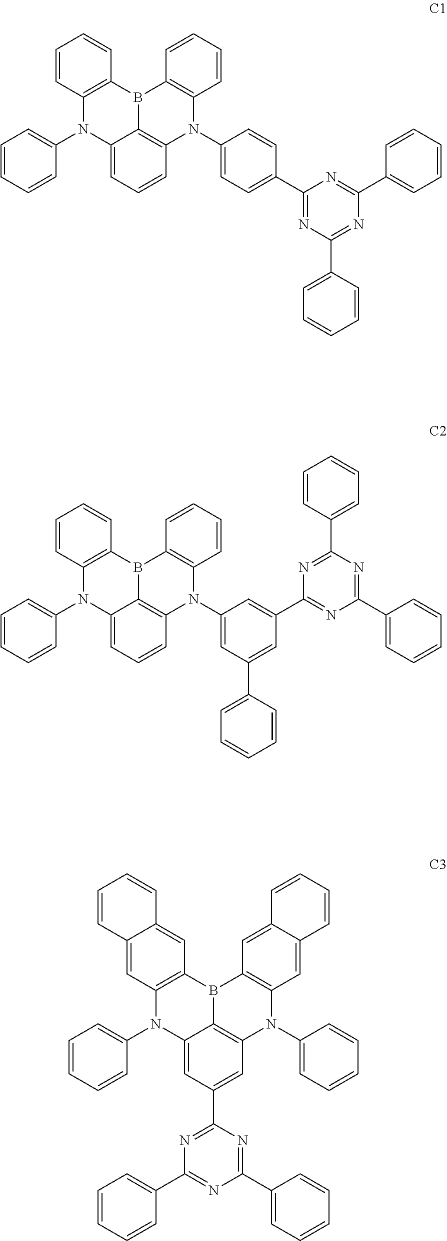 [SMILES: c1ccc(-c2nc(-c3ccccc3)nc(-c3ccc(N4c5ccccc5B5c6ccccc6N(c6ccccc6)c6cccc4c65)cc3)n2)cc1 ; c1ccc(-c2cc(-c3nc(-c4ccccc4)nc(-c4ccccc4)n3)cc(N3c4ccccc4B4c5ccccc5N(c5ccccc5)c5cccc3c54)c2)cc1 ; c1ccc(-c2nc(-c3ccccc3)nc(-c3cc4c5c(c3)N(c3ccccc3)c3cc6ccccc6cc3B5c3cc5ccccc5cc3N4c3ccccc3)n2)cc1]

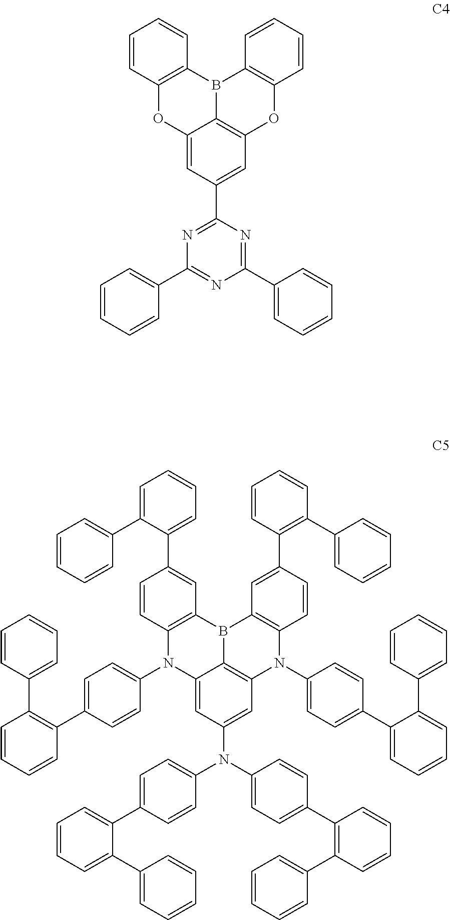 [SMILES: c1ccc(-c2nc(-c3ccccc3)nc(-c3cc4c5c(c3)Oc3ccccc3B5c3ccccc3O4)n2)cc1 ; c1ccc(-c2ccccc2-c2ccc(N(c3ccc(-c4ccccc4-c4ccccc4)cc3)c3cc4c5c(c3)N(c3ccc(-c6ccccc6-c6ccccc6)cc3)c3ccc(-c6ccccc6-c6ccccc6)cc3B5c3cc(-c5ccccc5-c5ccccc5)ccc3N4c3ccc(-c4ccccc4-c4ccccc4)cc3)cc2)cc1]

### Preparation of Light Emitting Elements

For each of light emitting elements of Examples and Comparative Examples, as an anode, a glass substrate having an ITO electrode (Corning, 15 Ω/cm², 1200 Å) formed thereon was cut to a size of about 50 mm×50 mm×0.7 mm, subjected to ultrasonic cleaning in isopropyl alcohol and pure water for 5 minutes respectively and to ultraviolet irradiation for 30 minutes, then exposed to ozone for cleaning, and then mounted on a vacuum deposition apparatus.

On the anode, a hole injection layer having a thickness of 300 Å was formed through deposition of NPD, and on the hole injection layer, a hole transport layer having a thickness of 200 Å was formed through deposition of H-1-1, and then on the hole transport layer, a light emitting auxiliary layer having a thickness of 100 Å was formed through deposition of CzSi.

Thereafter, an emission layer having a thickness of 200 Å was formed through the co-deposition of a host mixture in which a second compound and a third compound according to one or more embodiments were mixed in a weight ratio of 1:1, a fourth compound, and Example Compound or Comparative Example Compound in a weight ratio of 85:14:1, and on the emission layer, a hole blocking layer having a thickness of 200 Å was formed through the deposition of TSPO1. Then, on the hole blocking layer, an electron transport layer having a thickness of 300 Å was formed through the deposition of TPBi, and then on the electron transport layer, an electron injection layer having a thickness of 10 Å was formed through the deposition of LiF. Then, on the electron injection layer, a cathode having a thickness of 800 Å was formed through the deposition of Al to prepare a light emitting element.

Each layer was formed through vacuum evaporation. In one or more embodiments, HT2 selected from among the compounds of Compound Group 2 was utilized as the second compound, ETH66 selected from among the compounds of Compound Group 3 were utilized as the third compound, and AD-37 selected from among the compounds of Compound Group 4 were utilized as the fourth compound.

The compounds utilized in the preparation of the light emitting elements of Examples and Comparative Examples are disclosed below. The following materials were each utilized for the preparation of the elements after sublimation-purifying commercially available products.

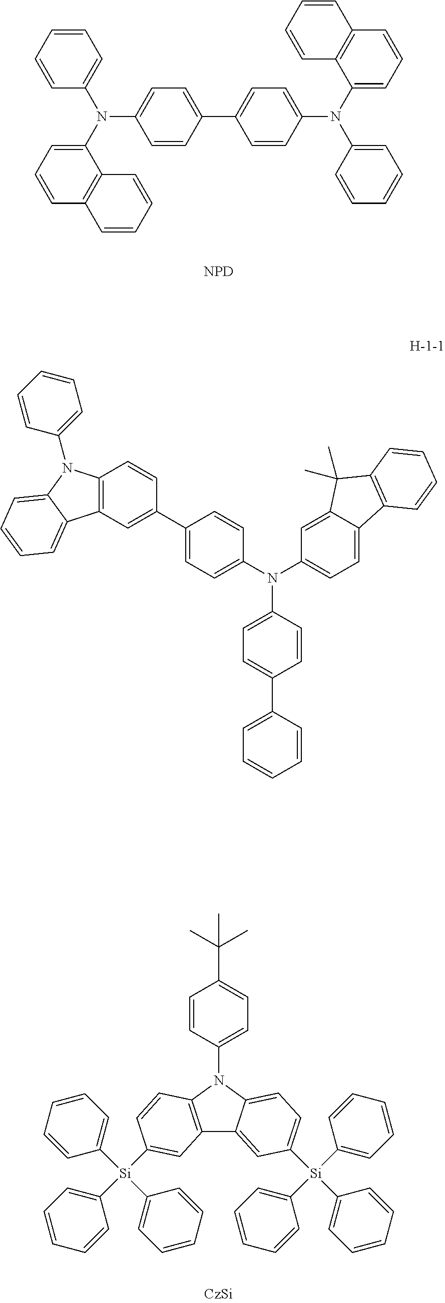 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

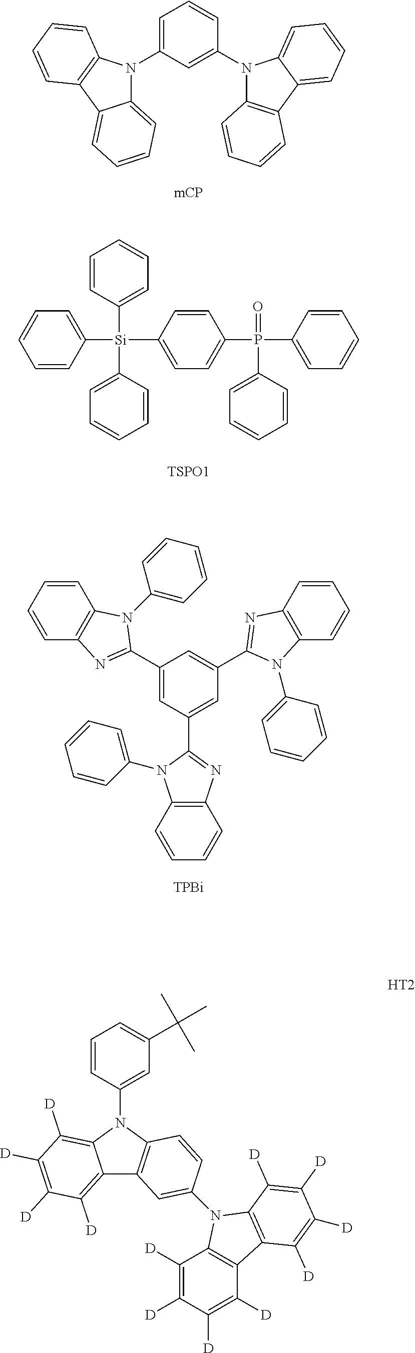

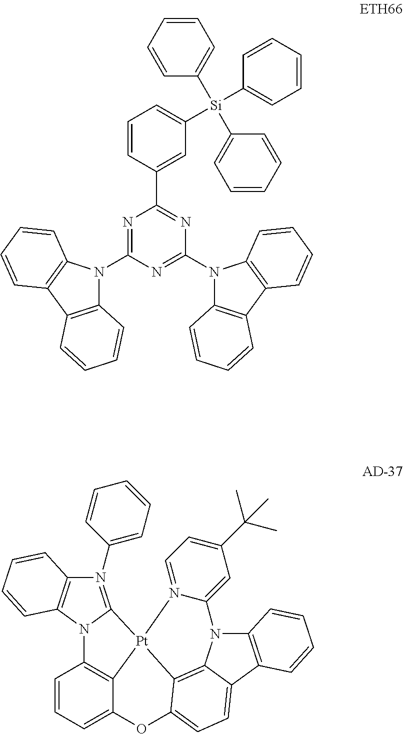

### Property Evaluation of Light Emitting Elements

Element efficiency and element lifespan of each of the light emitting elements prepared utilizing Example Compounds 54, 118, 187, and 267, and Comparative Example Compounds C1 to C5 described above were evaluated. Table 2 shows results of evaluation on each of light emitting elements for Examples 1 to 4 and Comparative Examples 1 to 5. In the characteristic evaluation of each of light emitting elements prepared in Examples 1 to 4 and Comparative Examples 1 to 5, driving voltage (V) at a current density of 1000 cd/m², luminous efficiency (Cd/A), and light emission wavelengths were each measured utilizing Keithley MU 236 and a luminance meter PR650, and a time taken for luminance to reach 95% with respect to an initial luminance was measured as lifetime T95, and relative lifetime was calculated with respect to the element of Comparative Example 4, and the results are shown in Table 2.

TABLE 2

| | Host | | | | | | |
|---|---|---|---|---|---|---|---|
| | (2nd compound:3rd | | | Driving | | Color of | Lifetime |
| | compound = | 4th | 1st | voltage | Efficiency | emitting | ratio |
| | 5:5) | compound | compound | (V) | (cd/A) | light | (T95) |
| Example 1 | HT2/ETH66 | AD-37 | 54 | 4.2 | 25.8 | Blue | 410 |
| Example 2 | HT2/ETH66 | AD-37 | 118 | 4.4 | 26.3 | Blue | 495 |
| Example 3 | HT2/ETH66 | AD-37 | 187 | 4.3 | 27.1 | Blue | 460 |
| Example 4 | HT2/ETH66 | AD-37 | 267 | 4.3 | 26.7 | Blue | 430 |
| Comparative | HT2/ETH66 | AD-37 | Comparative | 5.3 | 17.9 | Green | 180 |
| Example 1 | | | Example | | | | |
| | | | Compound | | | | |
| | | | C1 | | | | |
| Comparative | HT2/ETH66 | AD-37 | Comparative | 5.4 | 16.4 | Green | 140 |
| Example 2 | | | Example | | | | |
| | | | Compound | | | | |
| | | | C2 | | | | |
| Comparative | HT2/ETH66 | AD-37 | Comparative | 5.3 | 14.2 | Green | 210 |
| Example 3 | | | Example | | | | |
| | | | Compound | | | | |
| | | | C3 | | | | |
| Comparative | HT2/ETH66 | AD-37 | Comparative | 5.5 | 12.6 | Blue | 100(ref) |
| Example 4 | | | Example | | | | |
| | | | Compound | | | | |
| | | | C4 | | | | |
| Comparative | HT2/ETH66 | AD-37 | Comparative | 4.8 | 23.1 | Blue | 250 |
| Example 5 | | | Example | | | | |
| | | | Compound | | | | |
| | | | C5 | | | | |

Referring to the results of Table 2, it is seen that the light emitting elements, of Examples utilizing the fused polycyclic compound according to one or more embodiments of the present disclosure as light emitting materials each had lower driving voltage and greater luminous efficiency and lifetime than the light emitting elements of Comparative Examples. It is seen that when applied to a light emitting element, each of Example Compounds has a structure in which a first substituent is introduced into a fused ring core and thus exhibit greater luminous efficiency and longer lifespan than Comparative Examples. Example compounds include the first substituent, and may thus effectively protect the boron atom to improve chemical stability, and suppress or reduce intermolecular interactions to control aggregation, excimer formation, or exciplex formation, and accordingly, luminous efficiency may be increased. In addition, in the Example compounds, a distance between adjacent molecules increases due to the structure with great steric hindrance, and accordingly, the Dexter energy transfer may be suppressed or reduced to prevent or reduce lifespan deterioration caused by an increase in triplet concentration.

The first substituent may include a structure in which the phenyl moiety and the triazine moiety are linked, and may be linked to the nitrogen atom of the fused ring core through the phenyl moiety. In the first substituent, any one of carbon 2, carbon 4, and carbon 6 of the triazine moiety may be linked to the nitrogen atom of the fused ring core through the phenyl moiety, and a substituted or unsubstituted phenyl group may be linked to the other two carbons. In the fused ring core, the nitrogen atom having a high electron density is linked to the carbon of the triazine moiety, which has electron withdrawing properties, to effectively separate HOMO and LUMO, leading to improvements in the multi-resonance effects. In addition, as the triazine moiety and the nitrogen atom of the fused ring core are linked to the phenyl moiety to be positioned ortho, the boron atom may be effectively protected by a structure in which the first substituent covers the boron atom with respect to the plate-like structure of the fused ring core. In one or more embodiments, as the first substituent includes the triazine moiety, the dihedral angle between the triazine moiety and the terminal substituent linked thereto is reduced, so that the movement in the form that the first substituent covers the boron atom may be suppressed or reduced, and Stoke's shift may be reduced to increase photoluminescence quantum yield (PLQY) and intermolecular fluorescence resonance energy transfer (FRET).

Comparative Examples 1 and 2 each showed high driving voltage and decreased luminous efficiency and element service life compared to Examples. Comparative Example Compound C1 and Comparative Example Compound C2 respectively utilized in Comparative Examples 1 and 2 are compounds having a structure in which the triazine moiety is linked to be positioned para or meta to the nitrogen atom, and accordingly, it is believed that the compounds have a reduced effect in the boron atom protection, the intermolecular interaction suppression, and Dexter energy transfer suppression, compared to Example compounds in which the triazine moiety and the nitrogen atom are linked to be positioned ortho.

Comparative Examples 3 and 4 each showed high driving voltage and decreased element service life and efficiency compared to Examples. Comparative Example Compound C3 and Comparative Example Compound C4 respectively utilized in Comparative Examples 3 and 4 have a structure in which the triazine moiety is linked to the benzene ring of the fused ring core, instead of the nitrogen atom. Accordingly, the multiple resonance effects may be reduced compared to Example compounds in which the triazine moiety is linked to the nitrogen atom of the fused ring core. In addition, in Comparative Example Compound C3 and Comparative Example Compound C4, the triazine moiety is directly bonded to the fused ring core, and accordingly, a structure that sterically covers the boron atom in the plate-like structure of the fused ring core is hardly obtained, making it difficult to expect the effect of protecting the molecular boron atom and suppressing intermolecular interactions.

Referring to Comparative Example 5, Comparative Example Compound C5 includes the fused ring core centered on the boron atom and the nitrogen atom, but does not include the first substituent, and thus it is seen that when applied to a light emitting element, the light emitting element has high driving voltage and reduced luminous efficiency and element service life compared to Examples. Comparative Example Compound C5 shows higher material stability than other Comparative Example Compounds C1 to C4, but may have reduced thermal stability with an increase in the deposition temperature due to increased planarity.

A light emitting element of one or more embodiments of the present disclosure may exhibit improved element characteristics of high efficiency and long service life.

A fused polycyclic compound of one or more embodiments of the present disclosure is included in an emission layer of a light emitting element, and may thus contribute to high efficiency and long service life.

An electronic device of one or more embodiments of the present disclosure may exhibit high display quality.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In present disclosure, “not include a or any ‘component’” “exclude a or any ‘component’”, “‘component’-free”, and/or the like refers to that the “component” not being added, selected or utilized as a component in a composition, but the “component” of less than a suitable amount may still be included due to other impurities and/or external factors.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting element/device, the display device, the display apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. A light emitting element comprising:
a first electrode;
a second electrode on the first electrode; and
an emission layer between the first electrode and the second electrode and comprising a first compound represented by Formula 1: 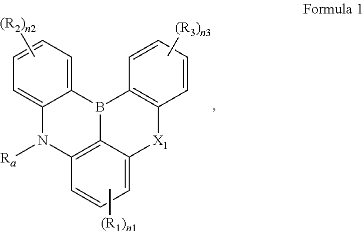
wherein in Formula 1,
X₁ is O, S, NR₄, CR₅R₆, or SiR₇R₈,
R₁ to R₈ are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
Rₐ is represented by Formula S,
n1 is an integer of 0 to 3, and
n2 and n3 are each independently an integer of 0 to 4, 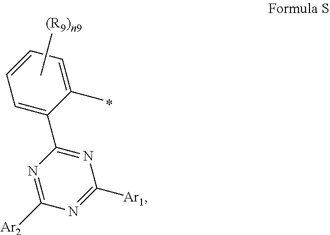
and
wherein in Formula S,
Ar₁ and Ar₂ are each independently a substituted or unsubstituted aryl group having 6 to 30 ring-forming carbon atoms or a substituted or unsubstituted heteroaryl group having 2 to 30 ring-forming carbon atoms,
R₉ is hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9 is an integer of 0 to 4, and [symbol]
is a site linked to Formula 1.

2. The light emitting element of claim 1, wherein the first compound represented by Formula 1 is represented by Formula 2: 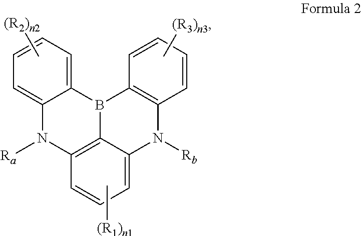
wherein in Formula 2,
R_{b} is represented by any one selected from among Formulas A-1 to A-3: 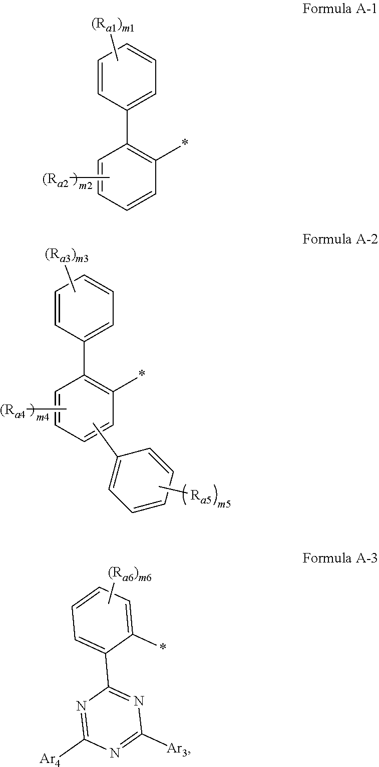
wherein in Formulas A-1 to A-3,
Rₐ₁ to Rₐ₆ are each independently hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
Ar₃ and Ar₄ are each independently a substituted or unsubstituted aryl group having 6 to 30 ring-forming carbon atoms or a substituted or unsubstituted heteroaryl group having 2 to 30 ring-forming carbon atoms,
m1, m3, and m5 are each independently an integer of 0 to 5,
m2 and m6 are each independently an integer of 0 to 4,
m4 is an integer of 0 to 3, and [symbol]
is a site linked to Formula 2, and
wherein in Formula 2,
R₁ to R₃, Rₐ, and n1 to n3 are each independently the same as defined in Formula 1.

3. The light emitting element of claim 1, wherein the first compound represented by Formula 1 is represented by Formula 3: 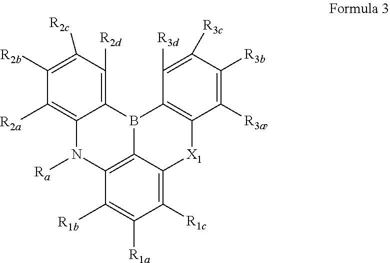
wherein in Formula 3,
R₁ₐ to R_{1c}, R₂ₐ to R₂ₐ, and R₃ₐ to R_{3d} are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and
at least one selected from among R₁ₐ to R_{1c}, R₂ₐ to R₂ₐ, and R₃ₐ to R_{3d} is a substituted or unsubstituted alkyl group having 1 to 10 carbon atoms, or is represented by any one selected from among Formulas B-1 to B-4: 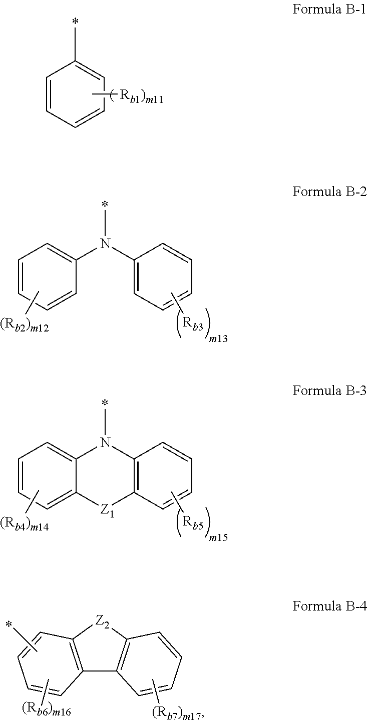
wherein in Formulas B-1 to B-4,
Z₁ is a direct linkage, O, S, or CR_{b8}R_{b9},
Z₂ is O, S, NR_{b10}, or CR_{b11}R_{b12},
R_{b1} to R_{b12} are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
m11 to m13 are each independently an integer of 0 to 5,
m14, m15, and m17 are each independently an integer of 0 to 4, and
m16 is an integer of 0 to 3, and
wherein in Formula 3,
X₁ and Rₐ are each independently the same as defined in Formula 1.

4. The light emitting element of claim 3, wherein the first compound represented by Formula 3 is represented by any one selected from among Formulas 4-1 to 4-4: 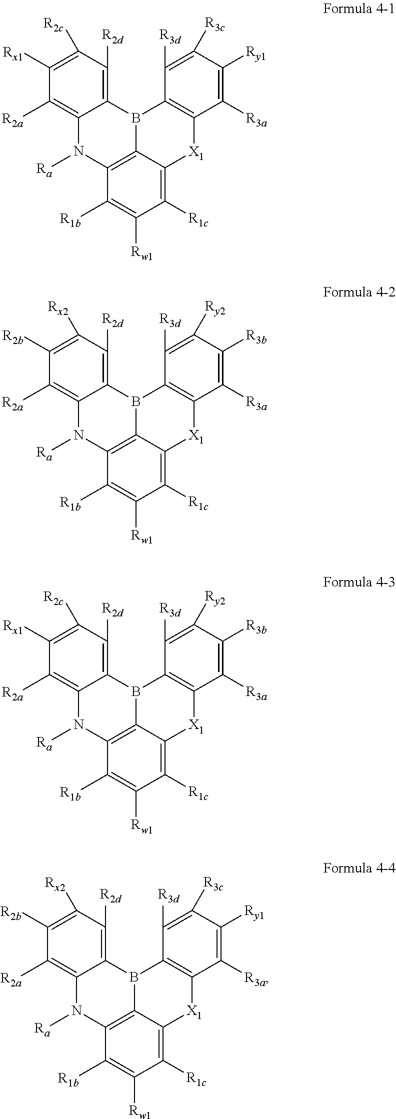
wherein in Formulas 4-1 to 4-4,
R_{w1} is hydrogen or a substituted or unsubstituted alkyl group having 1 to 10 carbon atoms, or is represented by any one among Formulas B-1 to B-4,
Rₓ₁, Rₓ₂, R_{y1}, and R_{y2} are each independently represented by any one selected from among Formulas B-1 to B-4, and
X₁, Rₐ, R_{1b}, R_{1c}, R₂ₐ to R₂ₐ, and R₃ₐ to R_{3d} are each independently the same as defined in Formula 1 and Formula 3.

5. The light emitting element of claim 1, wherein the first compound represented by Formula 1 is represented by any one selected from among Formulas 5-1 to 5-3: 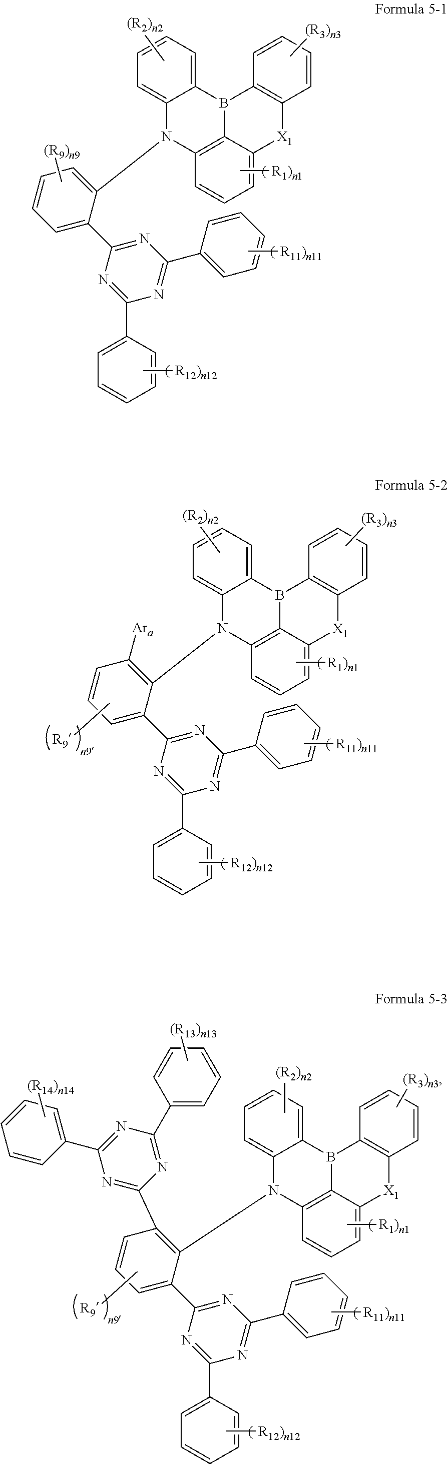
and
wherein in Formulas 5-1 to 5-3,
Arₐ is a substituted or unsubstituted aryl group having 6 to 30 ring-forming carbon atoms or a substituted or unsubstituted heteroaryl group having 2 to 30 ring-forming carbon atoms,
R₉′ and R₁ to R₁₄ are each independently hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9′ is an integer of 0 to 3,
n11 to n14 are each independently an integer of 0 to 5, and
X₁, R₁ to R₃, R₉, n1 to n3, and n9 are each independently the same as defined in Formula 1 and Formula S.

6. The light emitting element of claim 1, wherein the first compound represented by Formula 1 is represented by any one selected from among Formulas 6-1 to 6-3: 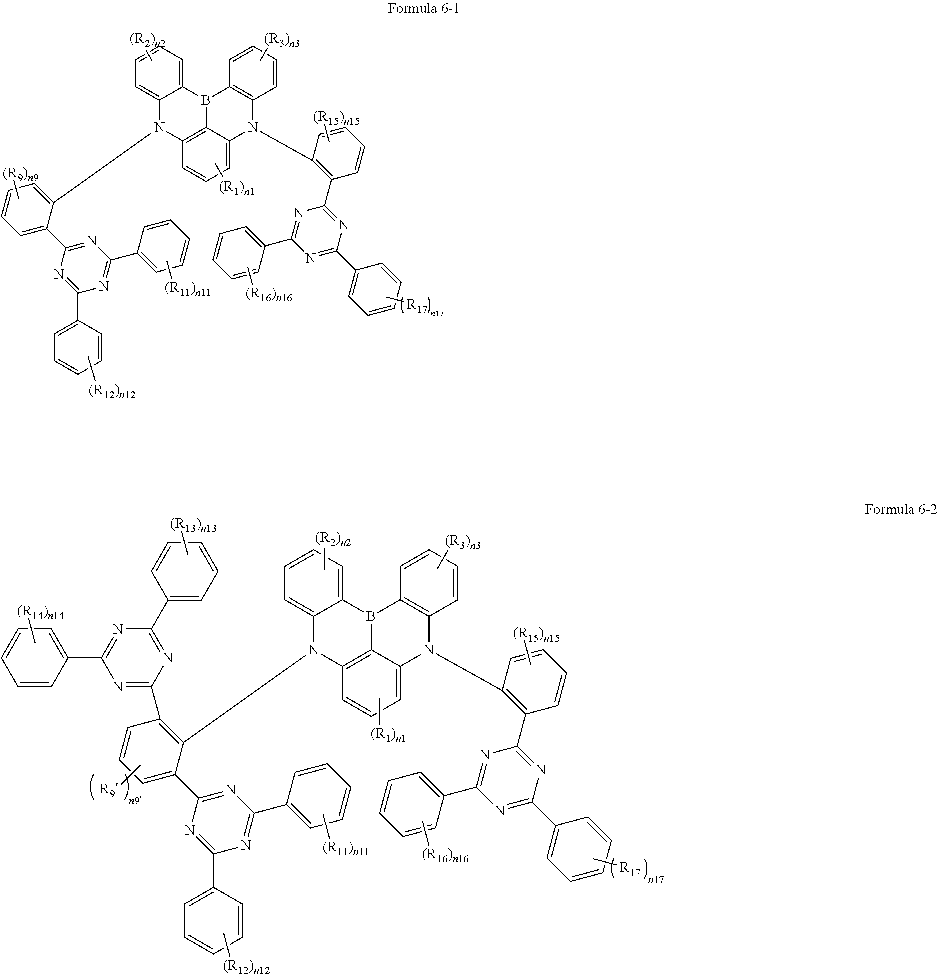 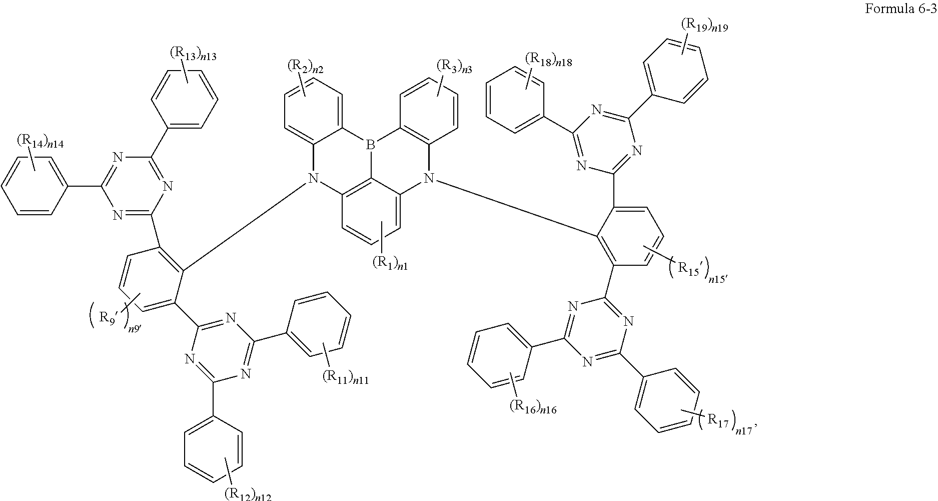
and
wherein in Formulas 6-1 to 6-3,
R₉′, R₁₅′, and R₁₁ to R₁₉ are each independently hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9′ and n15′ are each independently an integer of 0 to 3,
n11 to n14, and n16 to n19 are each independently an integer of 0 to 5,
n15 is an integer of 0 to 4, and
R₁ to R₃, R₉, n1 to n3, and n9 are the same as defined in Formula 1 and Formula S.

7. The light emitting element of claim 1, wherein the first compound represented by Formula 1 is represented by any one selected from among Formulas 7-1 to 7-4: 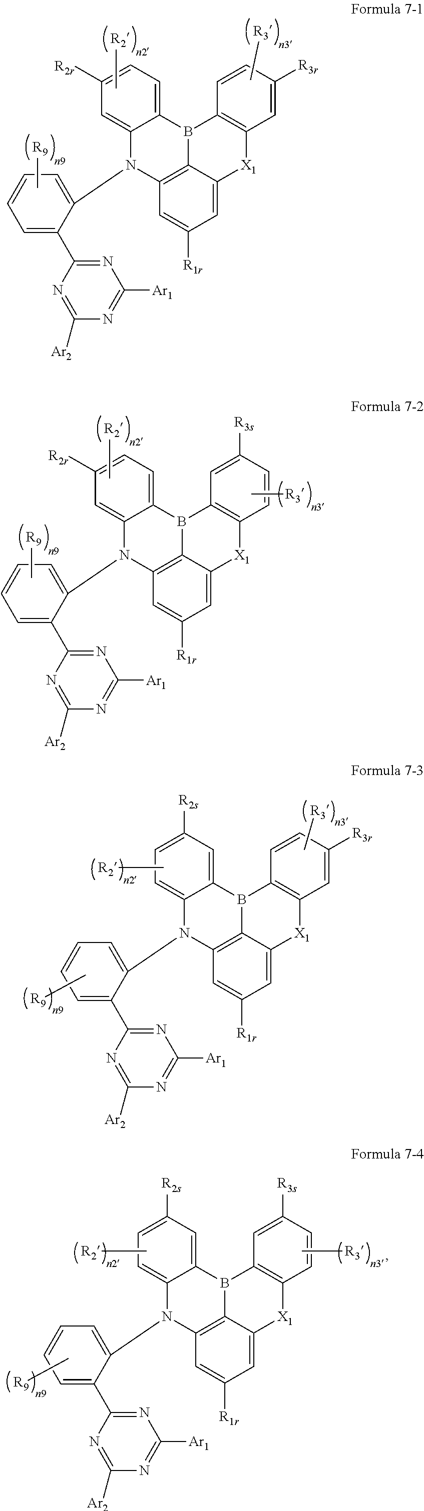
and
wherein in Formulas 7-1 to 7-4,
R₂′ and R₃′ are each independently hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₂ᵣ, R₂ₛ, R₃ᵣ, and R₃ₛ are each independently a substituted or unsubstituted amine group, a substituted or unsubstituted phenyl group, a substituted or unsubstituted carbazole group, a substituted or unsubstituted dibenzofuran group, or a substituted or unsubstituted dibenzothiophene group,
R₁ᵣ is hydrogen, deuterium, a substituted or unsubstituted amine group, a substituted or unsubstituted alkyl group having 1 to 10 carbon atoms, a substituted or unsubstituted phenyl group, a substituted or unsubstituted carbazole group, a substituted or unsubstituted dibenzofuran group, or a substituted or unsubstituted dibenzothiophene group, and
X₁, Ar₁, Ar₂, R₉, and n9 are each independently the same as defined in Formula 1 and Formula S.

8. The light emitting element of claim 1, wherein the first compound represented by Formula 1 is represented by Formula 8-1 or Formula 8-2: 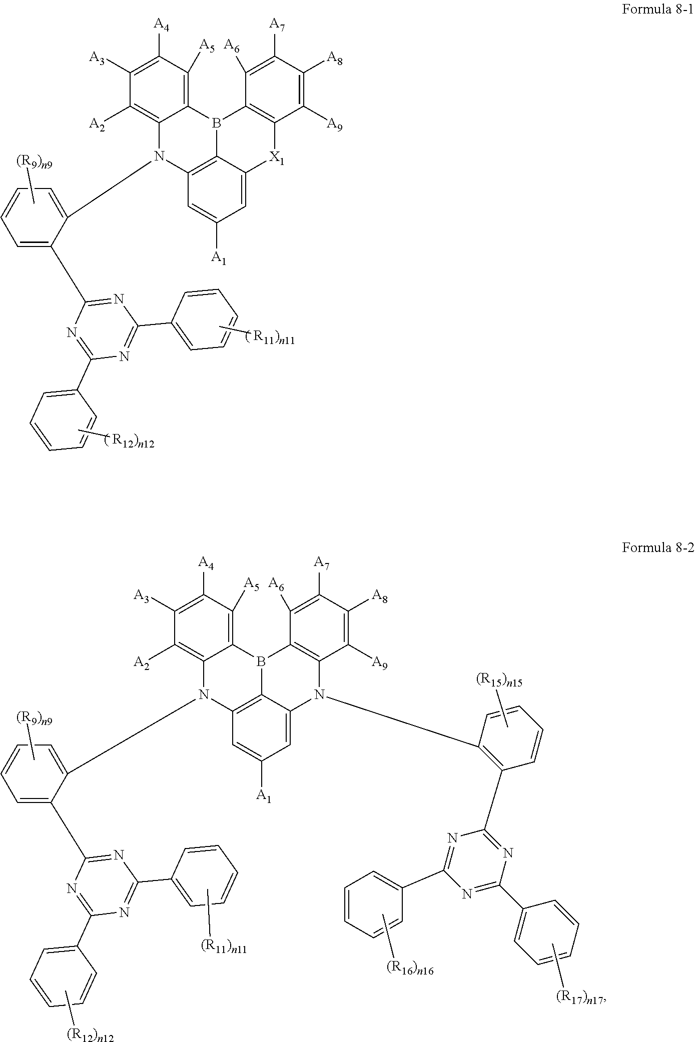
wherein in Formulas 8-1 and 8-2,
R₁₁, R₁₂, R₁₅ to R₁₇, and A₁ to A₉ are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least one selected from among A₁ to A₉ is selected from Substituent Group 1,
n11, n12, n16, and n17 are each independently an integer of 0 to 5, and
n15 is an integer of 0 to 4, 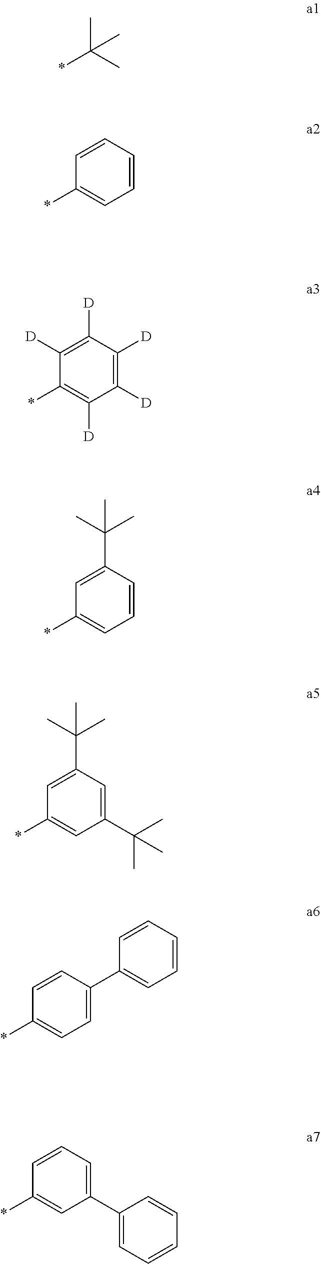 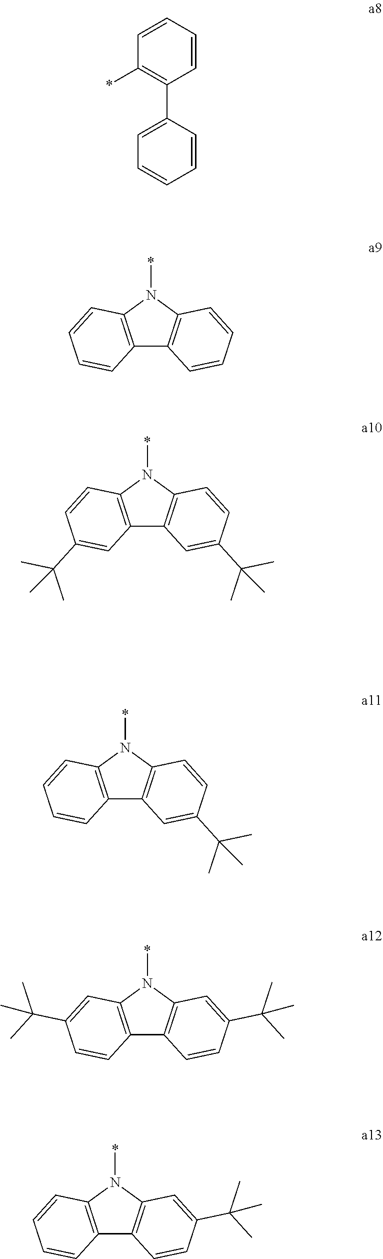 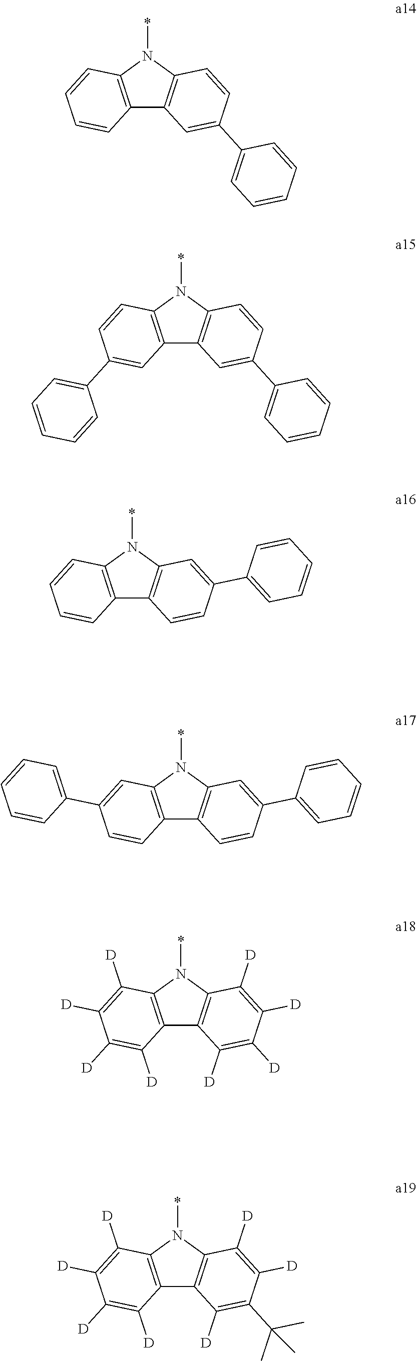 [SMILES: *n1c2ccccc2c2cc(-c3ccccc3)ccc21 ; *n1c2ccc(-c3ccccc3)cc2c2cc(-c3ccccc3)ccc21 ; *n1c2ccccc2c2ccc(-c3ccccc3)cc21 ; *n1c2cc(-c3ccccc3)ccc2c2ccc(-c3ccccc3)cc21 ; *n1c2c([2H])c([2H])c([2H])c([2H])c2c2c([2H])c([2H])c([2H])c([2H])c21 ; *n1c2c([2H])c([2H])c([2H])c([2H])c2c2c([2H])c(C(C)(C)C)c([2H])c([2H])c21] 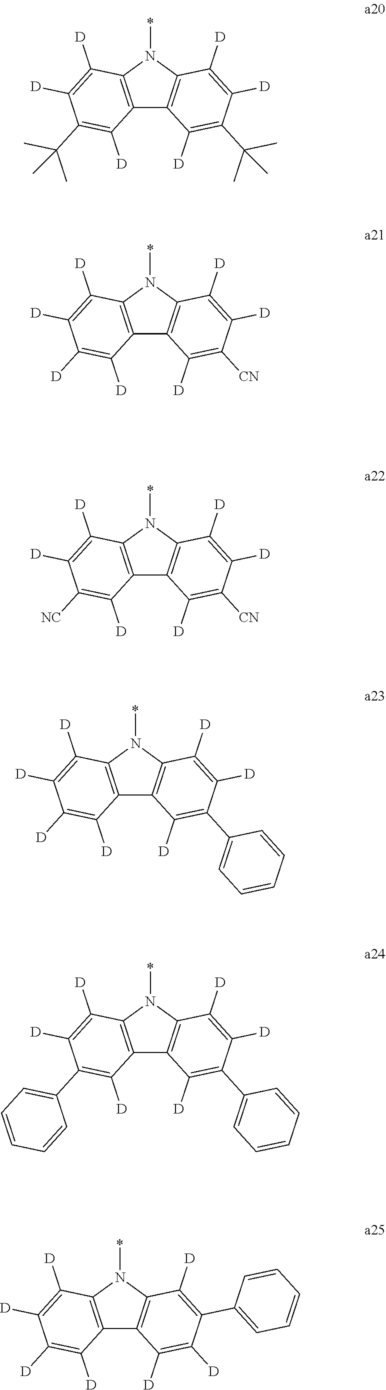 [SMILES: *n1c2c([2H])c([2H])c(C(C)(C)C)c([2H])c2c2c([2H])c(C(C)(C)C)c([2H])c([2H])c21 ; *n1c2c([2H])c([2H])c([2H])c([2H])c2c2c([2H])c(C#N)c([2H])c([2H])c21 ; *n1c2c([2H])c([2H])c(C#N)c([2H])c2c2c([2H])c(C#N)c([2H])c([2H])c21 ; *n1c2c([2H])c([2H])c([2H])c([2H])c2c2c([2H])c(-c3ccccc3)c([2H])c([2H])c21 ; *n1c2c([2H])c([2H])c(-c3ccccc3)c([2H])c2c2c([2H])c(-c3ccccc3)c([2H])c([2H])c21 ; *n1c2c([2H])c([2H])c([2H])c([2H])c2c2c([2H])c([2H])c(-c3ccccc3)c([2H])c21] 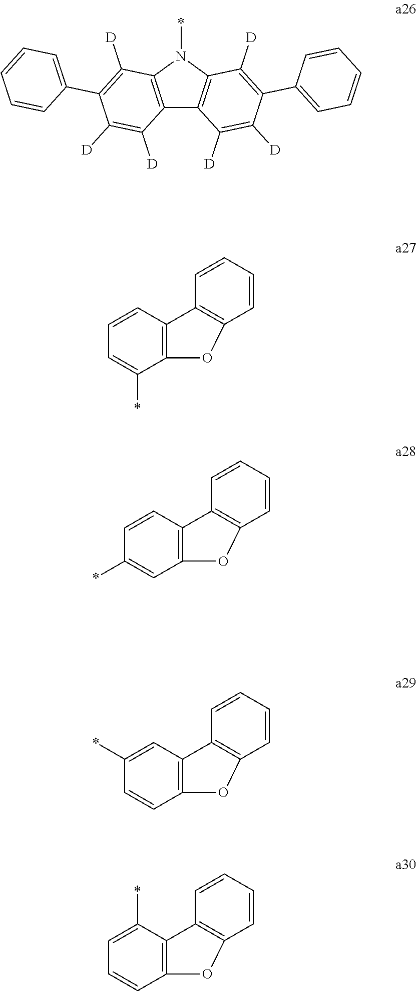 [SMILES: *n1c2c([2H])c(-c3ccccc3)c([2H])c([2H])c2c2c([2H])c([2H])c(-c3ccccc3)c([2H])c21 ; *c1cccc2c1oc1ccccc12 ; *c1ccc2c(c1)oc1ccccc12 ; *c1ccc2oc3ccccc3c2c1 ; *c1cccc2oc3ccccc3c12] 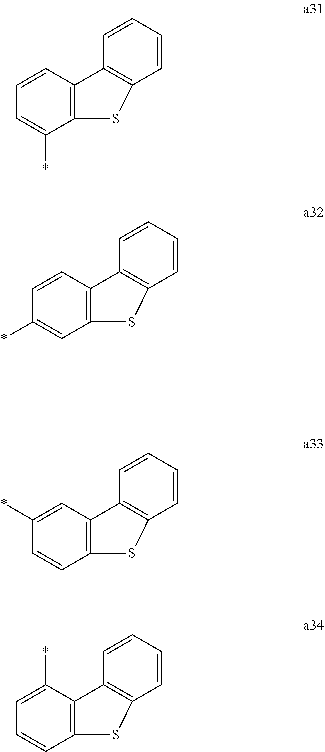 [SMILES: *c1cccc2c1sc1ccccc12 ; *c1ccc2c(c1)sc1ccccc12 ; *c1ccc2sc3ccccc3c2c1 ; *c1cccc2sc3ccccc3c12] 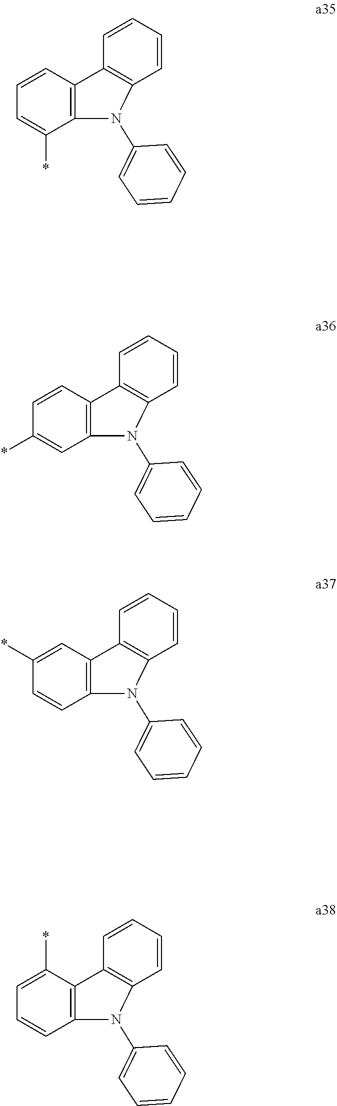 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1] 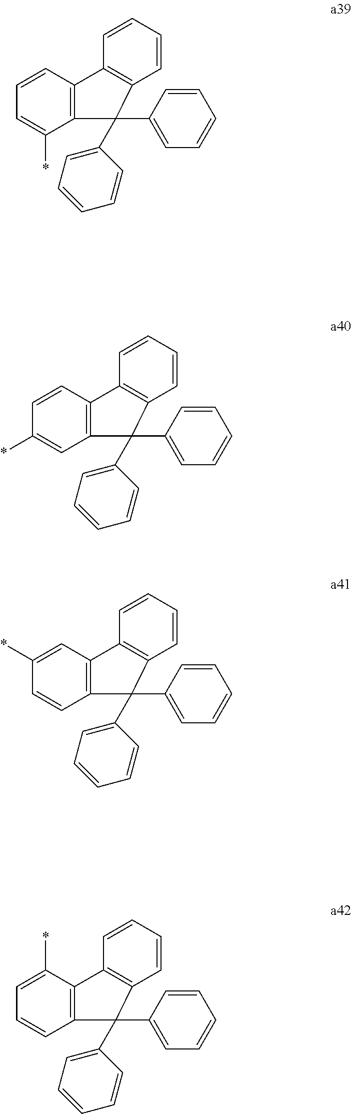 [SMILES: *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1] 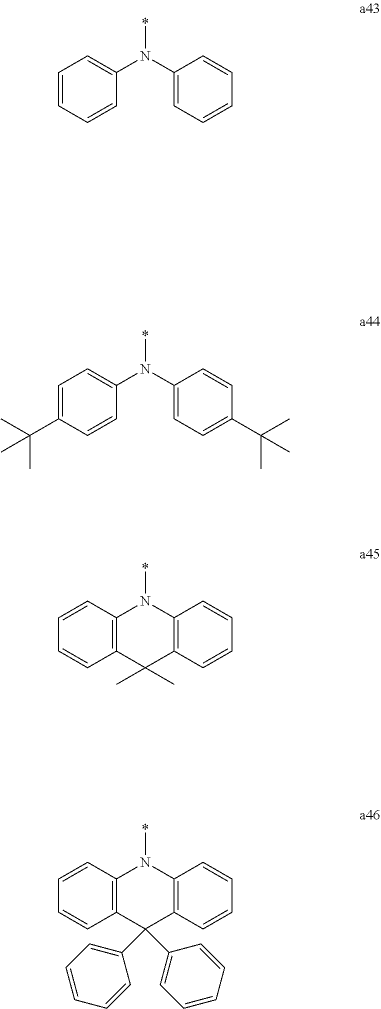 [SMILES: *N(c1ccccc1)c1ccccc1 ; *N(c1ccc(C(C)(C)C)cc1)c1ccc(C(C)(C)C)cc1 ; *N1c2ccccc2C(C)(C)c2ccccc21 ; *N1c2ccccc2C(c2ccccc2)(c2ccccc2)c2ccccc21] 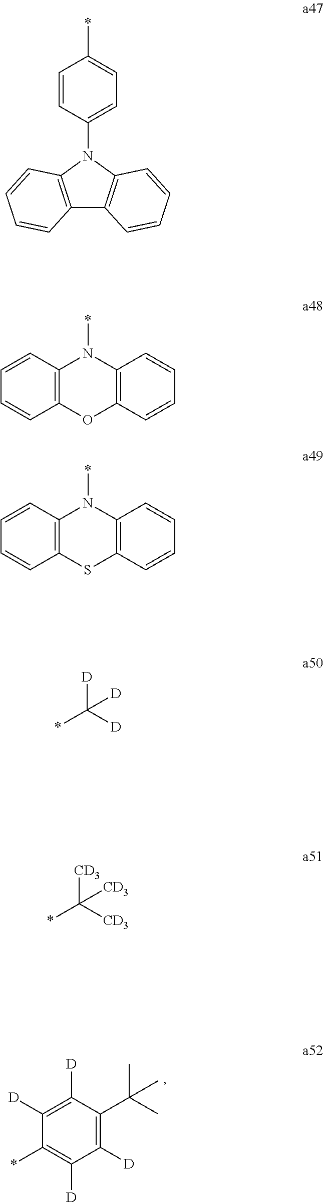 [SMILES: *c1ccc(-n2c3ccccc3c3ccccc32)cc1 ; *N1c2ccccc2Oc2ccccc21 ; *N1c2ccccc2Sc2ccccc21 ; *C([2H])([2H])[2H] ; *C(C([2H])([2H])[2H])(C([2H])([2H])[2H])C([2H])([2H])[2H] ; *c1c([2H])c([2H])c(C(C)(C)C)c([2H])c1[2H]]
and
wherein in Formulas 8-1 and 8-2,
X₁, R₉, and n9 are the same as defined in Formula 1 and Formula S.

9. The light emitting element of claim 1, wherein the emission layer further comprises at least one of a second compound represented by Formula HT-1, a third compound represented by Formula ET-1, or a fourth compound represented by Formula D-1: 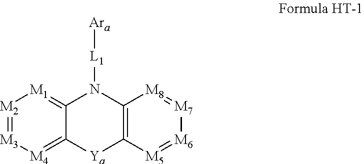
wherein in Formula HT-1,
M₁ to M₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Arₐ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, 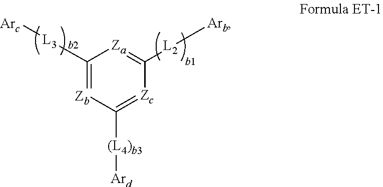
wherein in Formula ET-1,
at least one selected from among Zₐ to Z_{c} is N and the remainder are CR₅₆,
R₅₆ is hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer of 0 to 10,
Ar_{b} to Arₐ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms, and 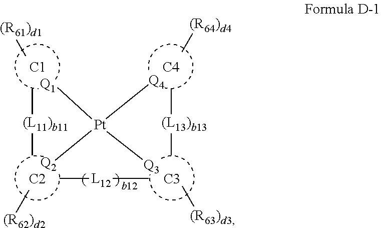
and
wherein in Formula D-1
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 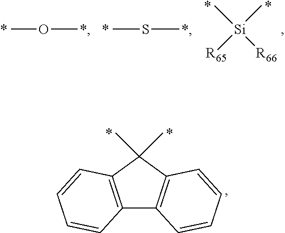
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer of 0 to 4.

10. An electronic device, the electronic device being at least one selected from among large-sized display devices including televisions, monitors, and outdoor billboards, and small- and medium-sized display devices including personal computers, laptop computers, personal digital terminals, vehicle display devices, game consoles, portable electronic devices, and cameras, and
the electronic device comprising at least one light emitting element,
wherein the at least one light emitting element comprises a fused polycyclic compound represented by Formula 1: 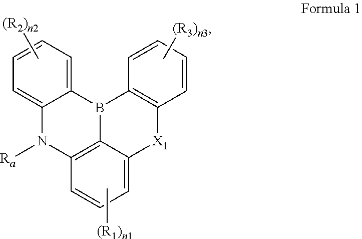
wherein in Formula 1,
X₁ is O, S, NR₄, CR₅R₆, or SiR₇R₈,
R₁ to R₈ are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
Rₐ is represented by Formula S,
n1 is an integer of 0 to 3, and
n2 and n3 are each independently an integer of 0 to 4, 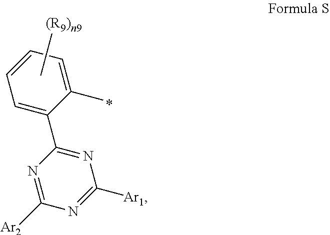
and
wherein in Formula S,
Ar₁ and Ar₂ are each independently a substituted or unsubstituted aryl group having 6 to 30 ring-forming carbon atoms or a substituted or unsubstituted heteroaryl group having 2 to 30 ring-forming carbon atoms,
R₉ is hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9 is an integer of 0 to 4, and [symbol]
is a site linked to Formula 1.

11. The electronic device of claim 10, wherein the electronic device comprises:
a base layer;
a circuit layer on the base layer; and
a display element layer on the circuit layer and comprising the at least one light emitting element and an encapsulation layer on the at least one light emitting element,
the at least one light emitting element comprising:
a first electrode;
a second electrode on the first electrode; and
an emission layer between the first electrode and the second electrode and comprising the fused polycyclic compound represented by Formula 1.

12. The electronic device of claim 11, wherein the at least one light emitting element further comprises a capping layer on the second electrode,
the capping layer having a refractive index of about 1.6 or greater in a wavelength range of about 550 nm to about 660 nm.

13. The electronic device of claim 11, further comprising a light control layer on the encapsulation layer and comprising quantum dots,
wherein the at least one light emitting element is to emit first color light, and
the light control layer comprises:
a first light control portion comprising a first quantum dot that converts the first color light into second color light having a longer wavelength than the first color light;
a second light control portion comprising a second quantum dot that converts the first color light into third color light having a longer wavelength than the first color light and the second color light; and
a third light control portion that transmits the first color light.

14. The electronic device of claim 13, further comprising a color filter layer on the light control layer,
wherein the color filter layer comprises:
a first filter that is to transmit the second color light;
a second filter that is to transmit the third color light; and
a third filter that is to transmit the first color light.

15. A fused polycyclic compound represented by Formula 1: 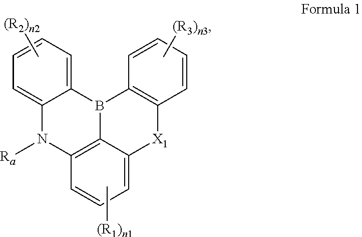
wherein in Formula 1,
X₁ is O, S, NR₄, CR₅R₆, or SiR₇R₈,
R₁ to R₈ are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
Rₐ is represented by Formula S,
n1 is an integer of 0 to 3, and
n2 and n3 are each independently an integer of 0 to 4, 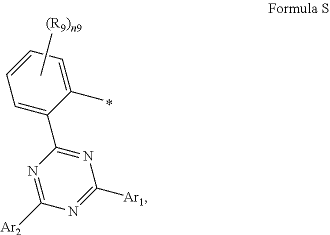
and
wherein in Formula S,
Ar₁ and Ar₂ are each independently a substituted or unsubstituted aryl group having 6 to 30 ring-forming carbon atoms or a substituted or unsubstituted heteroaryl group having 2 to 30 ring-forming carbon atoms,
R₉ is hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9 is an integer of 0 to 4, and [symbol]
is a site linked to Formula 1.

16. The fused polycyclic compound of claim 15, wherein the fused polycyclic compound represented by Formula 1 is represented by Formula 2: 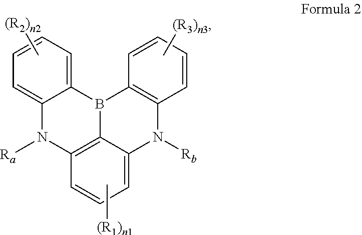
and
wherein in Formula 2,
R_{b} is represented by any one selected from among Formulas A-1 to A-3: 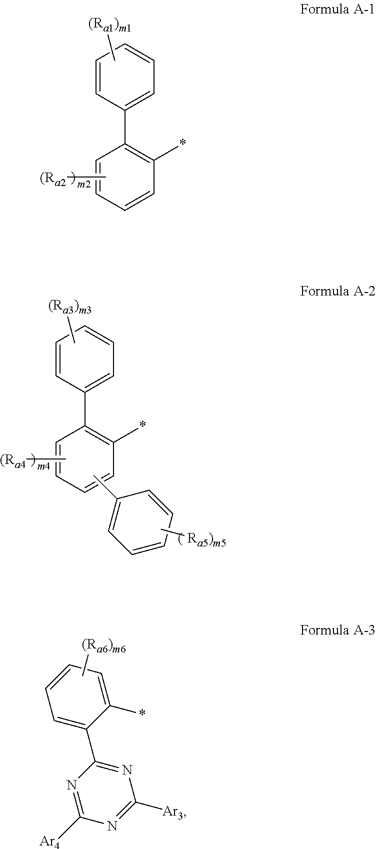
wherein in Formulas A-1 to A-3,
Rₐ₁ to Rₐ₆ are each independently hydrogen, deuterium, a halogen, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
Ar₃ and Ar₄ are each independently a substituted or unsubstituted aryl group having 6 to 30 ring-forming carbon atoms or a substituted or unsubstituted heteroaryl group having 2 to 30 ring-forming carbon atoms,
m1, m3, and m5 are each independently an integer of 0 to 5,
m2 and m6 are each independently an integer of 0 to 4,
m4 is an integer of 0 to 3, and [symbol]
is a site linked to Formula 2, and
wherein in Formula 2,
R₁ to R₃, Rₐ, and n1 to n3 are each independently the same as defined in Formula 1.

17. The fused polycyclic compound of claim 15, wherein the fused polycyclic compound represented by Formula 1 is represented by Formula 3: 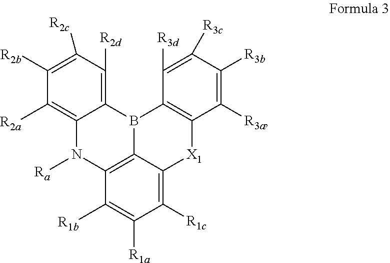
wherein in Formula 3,
R₁ₐ to R_{1c}, R₂ₐ to R₂ₐ, and R₃ₐ to R_{3d} are each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and
at least one selected from among R₁ₐ to R_{1c}, R₂ₐ to R₂ₐ, and R₃ₐ to R_{3d} is a substituted or unsubstituted alkyl group having 1 to 10 carbon atoms, or is represented by any one selected from among Formulas B-1 to B-4: 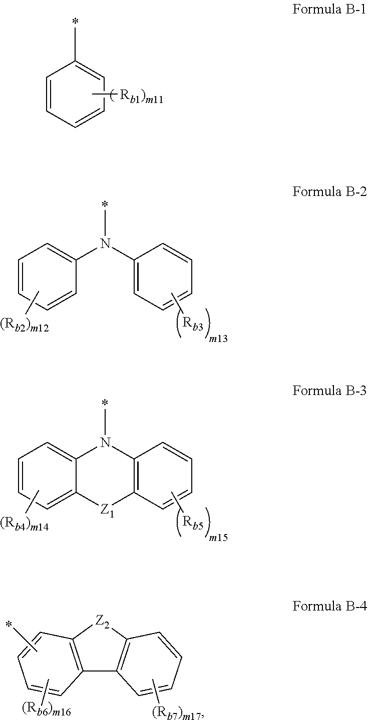
wherein in Formulas B-1 to B-4,
Z₁ is a direct linkage, O, S, or CR_{b8}R_{b9},
Z₂ is O, S, NR_{b10}, or CR_{b11}R_{b12},
R_{b1} to R_{b12} are each independently hydrogen, deuterium, a halogen, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
m11 to m13 are each independently an integer of 0 to 5,
m14, m15, and m17 are each independently an integer of 0 to 4, and
m16 is an integer of 0 to 3, and
wherein in Formula 3,
X₁ and Rₐ are the same as defined in Formula 1.

18. The fused polycyclic compound of claim 15, wherein the fused polycyclic compound represented by Formula 1 is represented by any one selected from among Formulas 5-1 to 5-3: 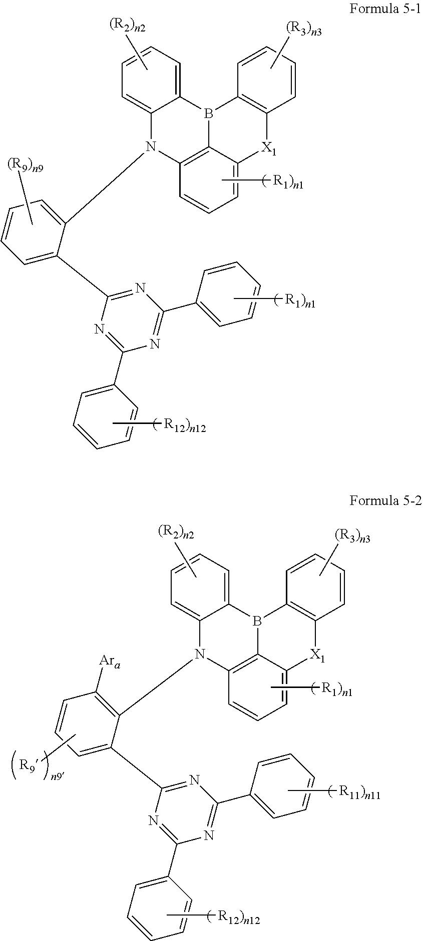 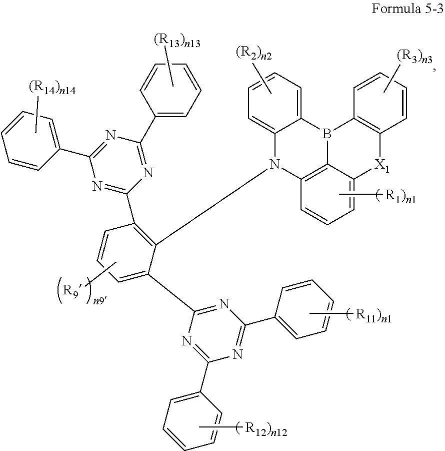
and
wherein in Formulas 5-1 to 5-3 an
Arₐ is a substituted or unsubstituted aryl group having 6 to 30 ring-forming carbon atoms or a substituted or unsubstituted heteroaryl group having 2 to 30 ring-forming carbon atoms,
R₉′ and R₁₁ to R₁₄ are each independently hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9′ is an integer of 0 to 3,
n11 to n14 are each independently an integer of 0 to 5, and
X₁, R₁ to R₃, R₉, n1 to n3, and n9 are each independently the same as defined in Formula 1 and Formula S.

19. The fused polycyclic compound of claim 15, wherein the fused polycyclic compound represented by Formula 1 is represented by any one selected from among Formulas 6-1 to 6-3: 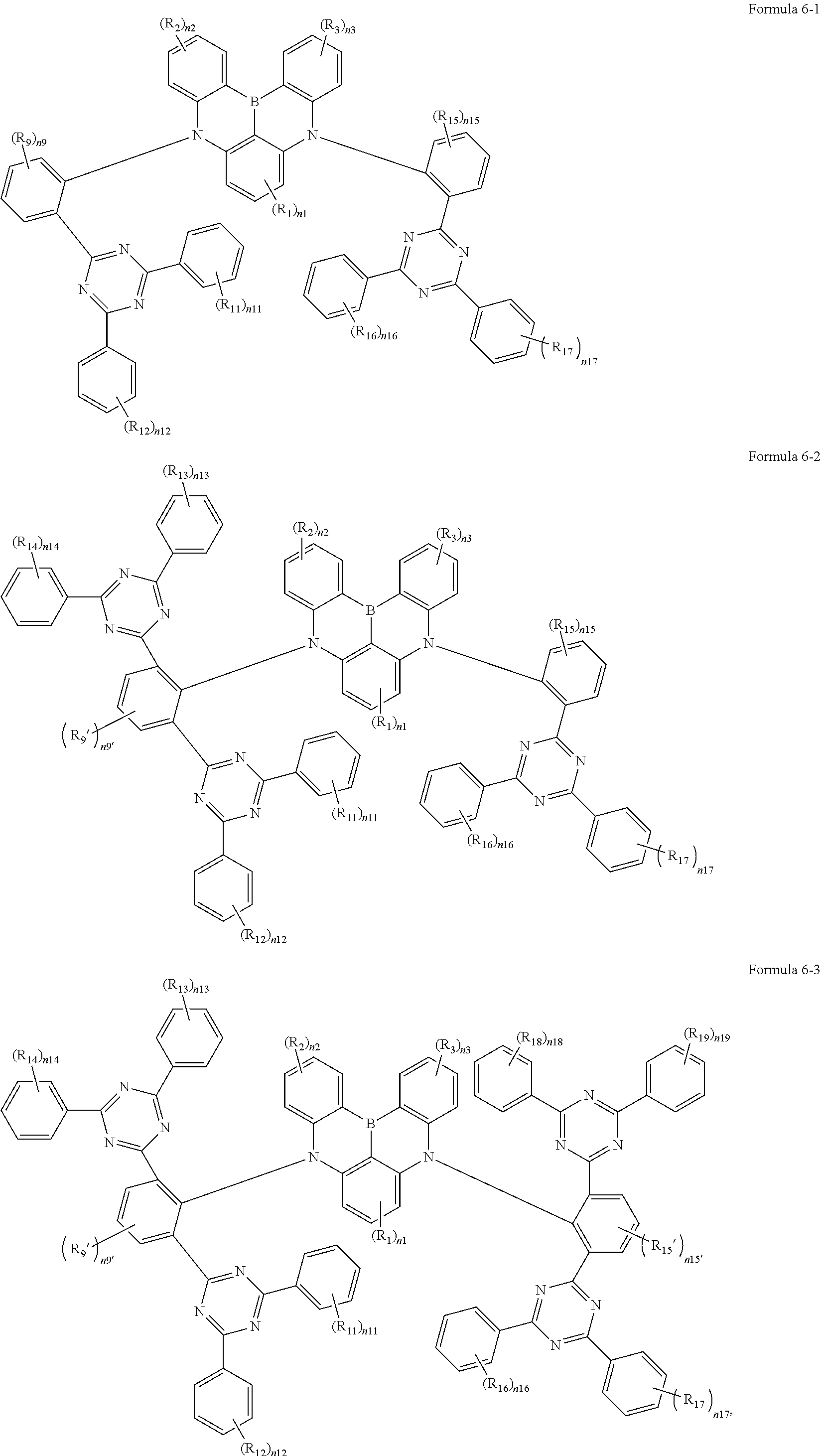
and
wherein in Formulas 6-1 to 6-3,
R₉′, R₁₅′, and R₁₁ to R₁₉ are each independently hydrogen, deuterium, a halogen, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring,
n9′ and n15′ are each independently an integer of 0 to 3,
n11 to n14, and n16 to n19 are each independently an integer of 0 to 5,
n15 is an integer of 0 to 4, and
R₁ to R₃, n1 to n3, and n9 are each independently the same as defined in Formula 1 and Formula S.

20. The fused polycyclic compound of claim 15, wherein the fused polycyclic compound represented by Formula 1 comprises at least one selected from among compounds of Compound Group 1: 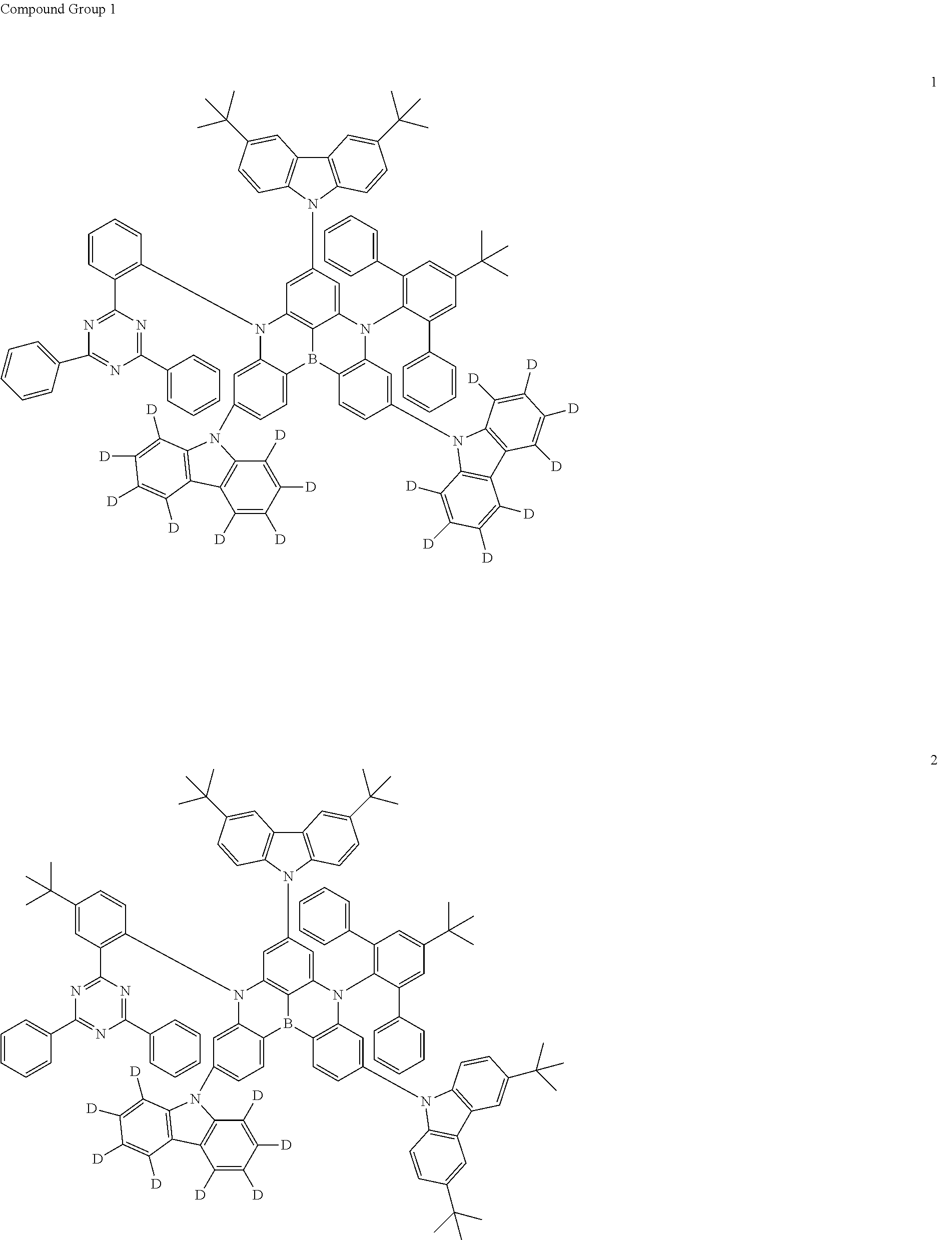 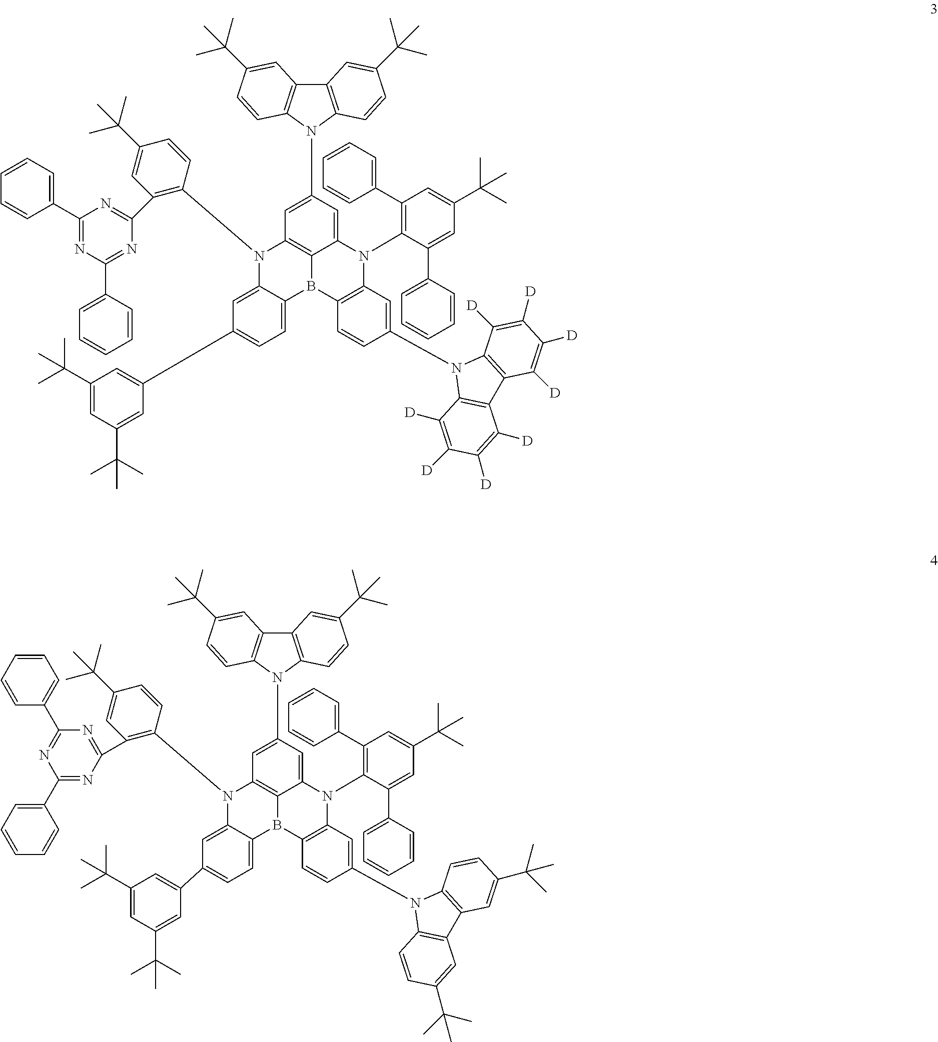 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-n3c4ccc(C(C)(C)C)cc4c4cc(C(C)(C)C)ccc43)cc3c1B2c1ccc(-c2cc(C(C)(C)C)cc(C(C)(C)C)c2)cc1N3c1ccc(C(C)(C)C)cc1-c1nc(-c2ccccc2)nc(-c2ccccc2)n1 ; CC(C)(C)c1cc(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2ccccc2)cc(C(C)(C)C)c1] 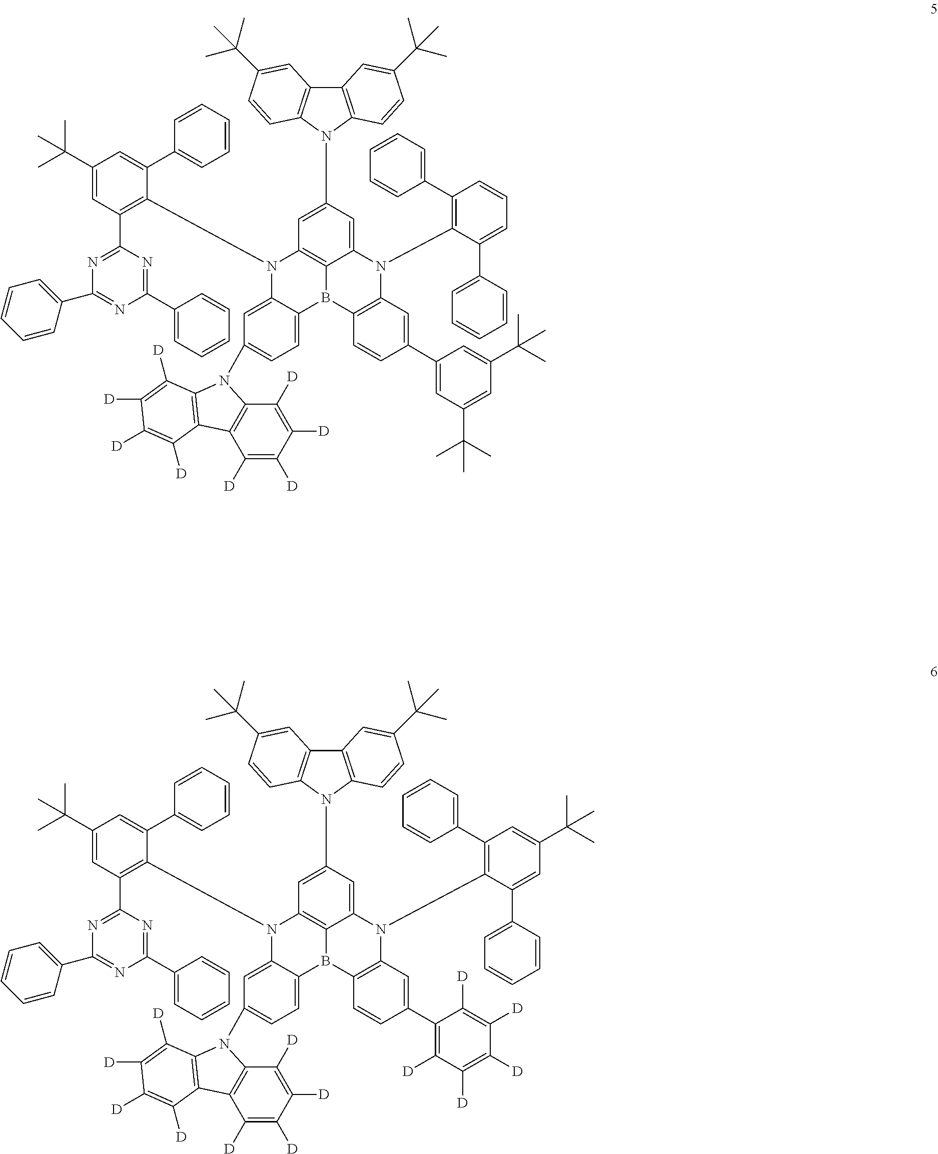 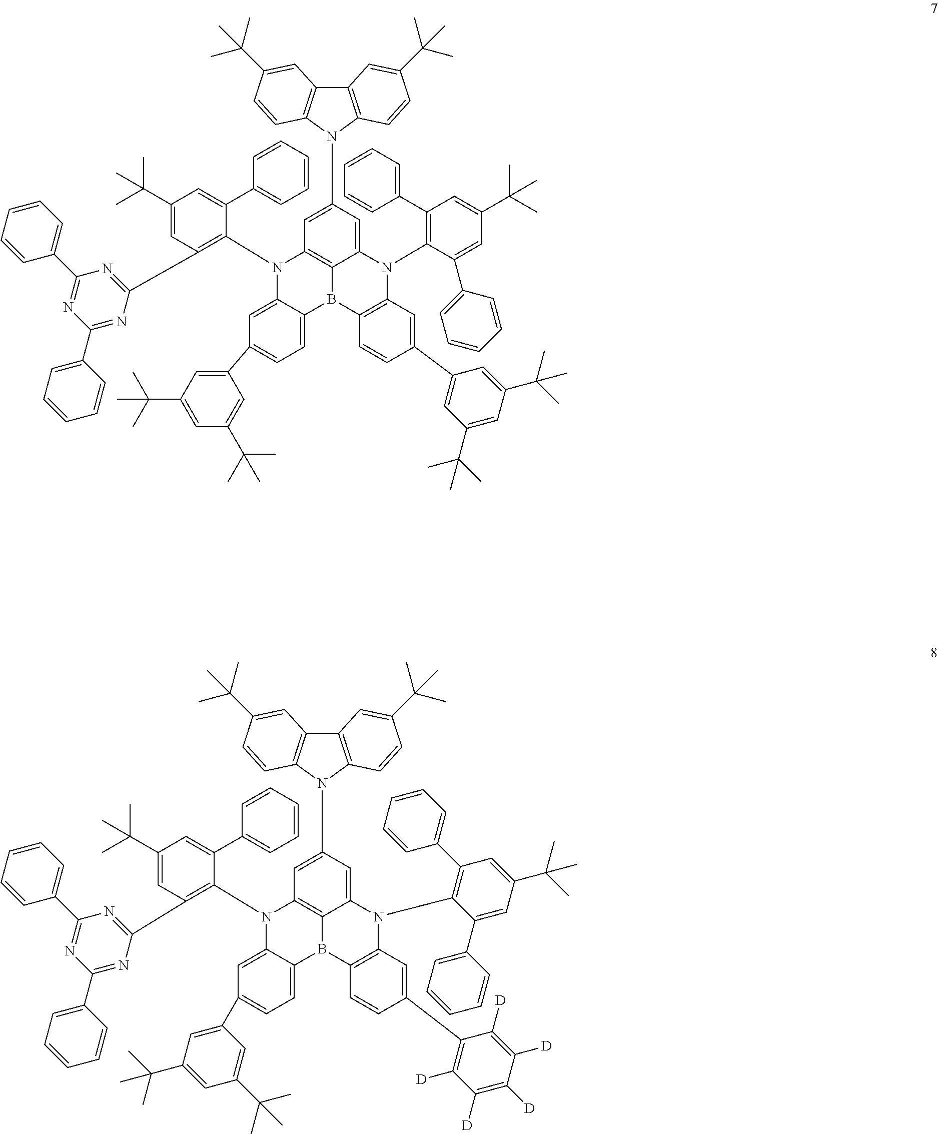 [SMILES: CC(C)(C)c1cc(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)c([2H])c1[2H]] 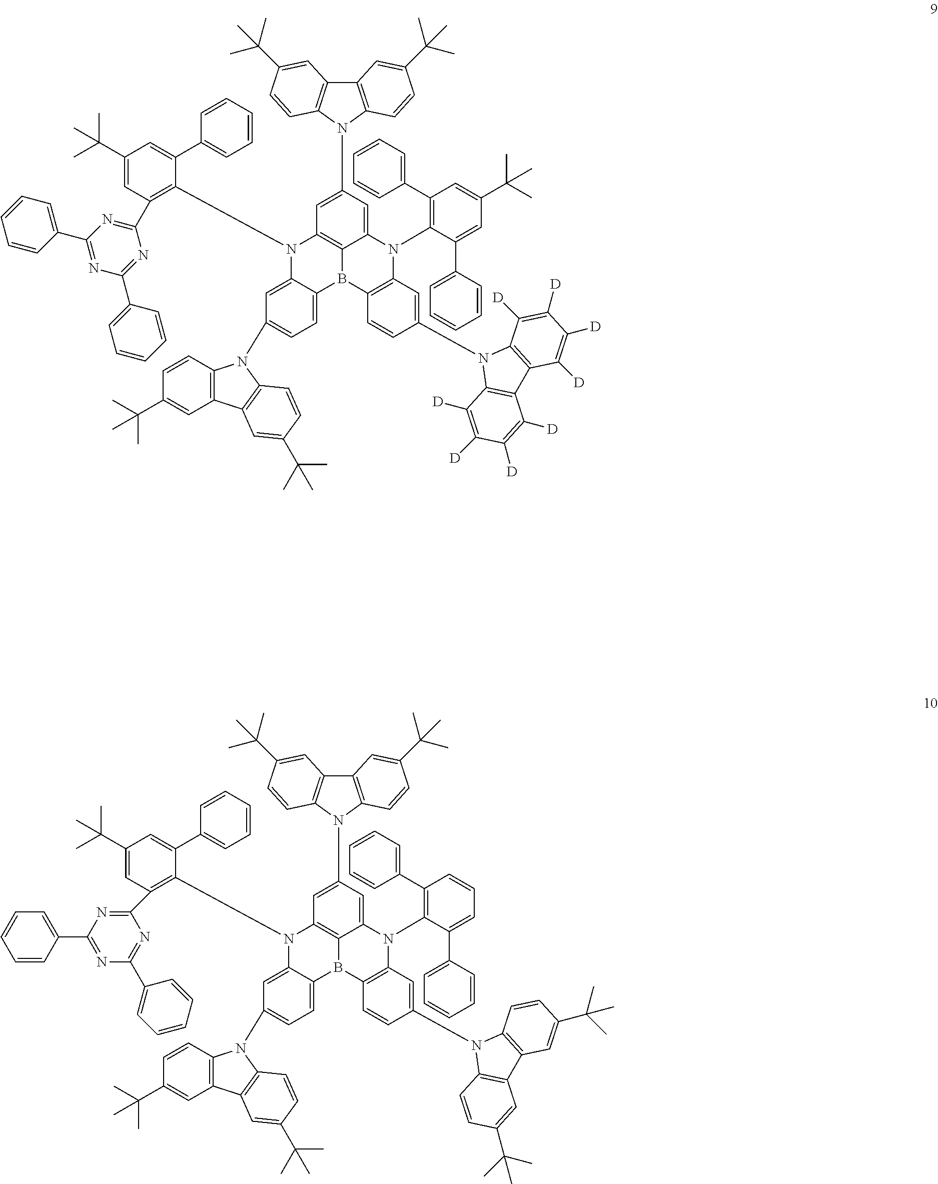 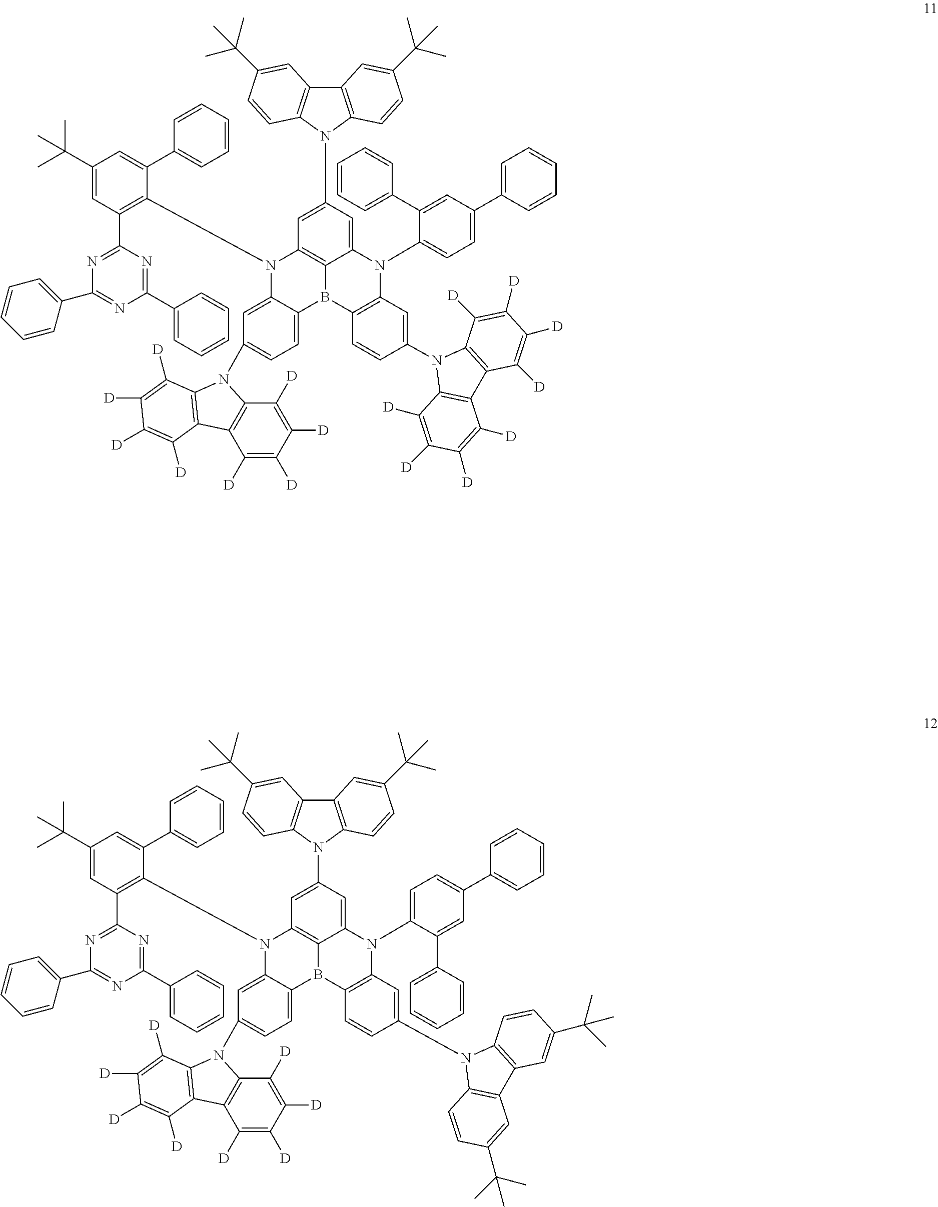 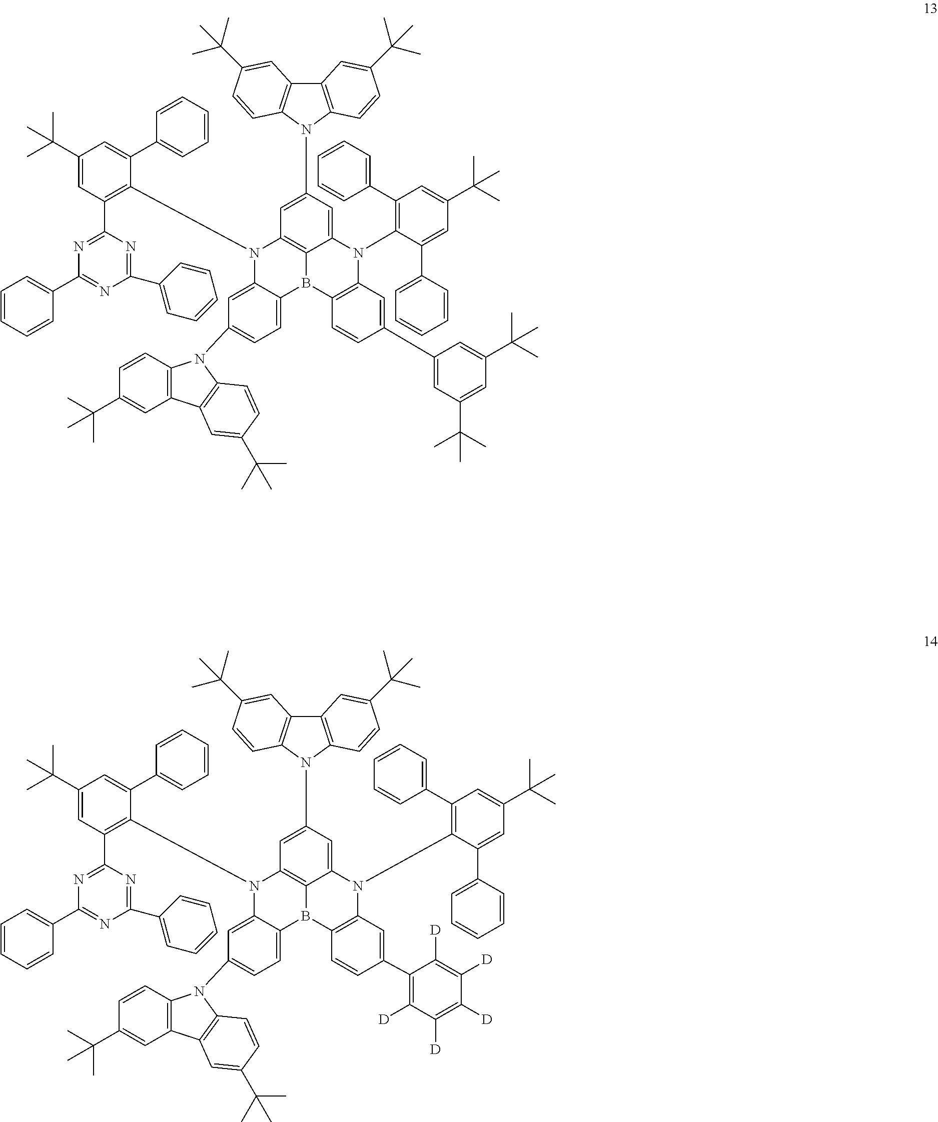 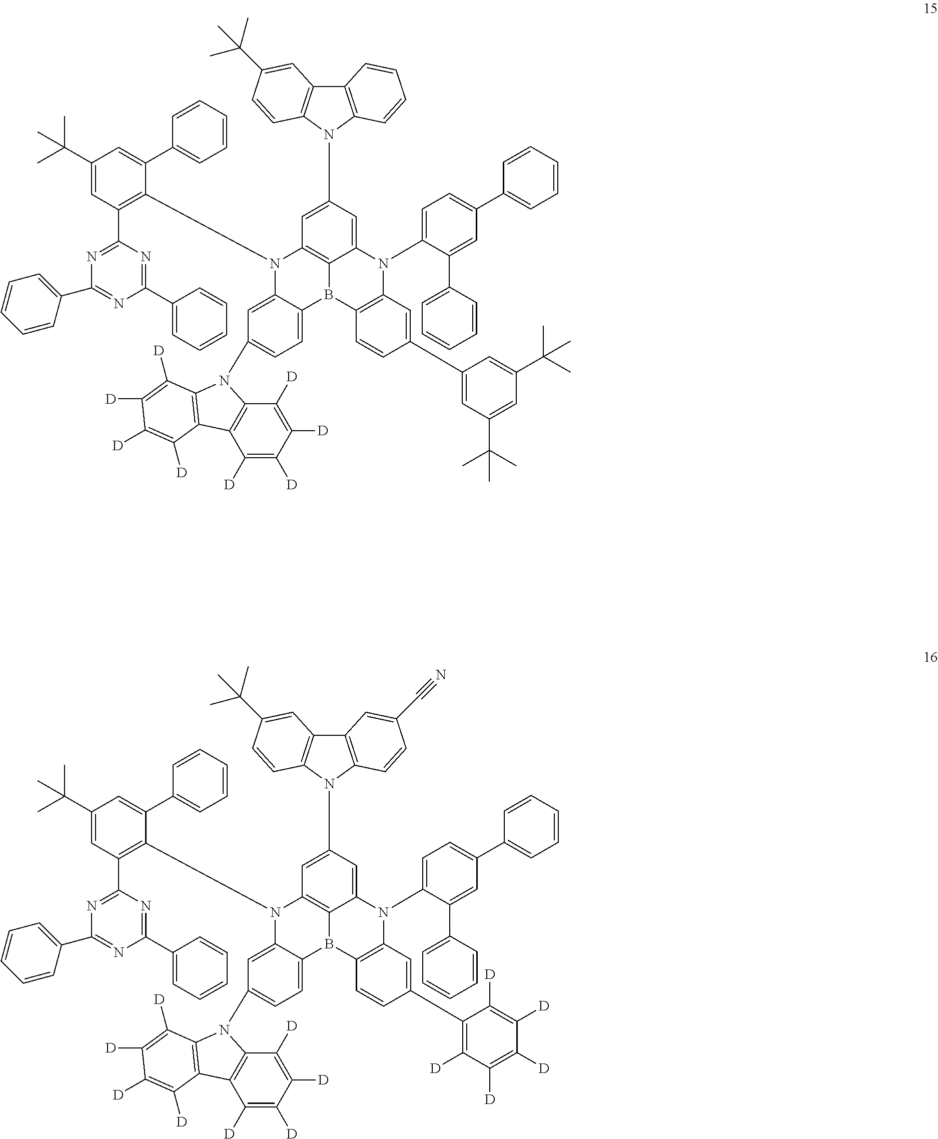 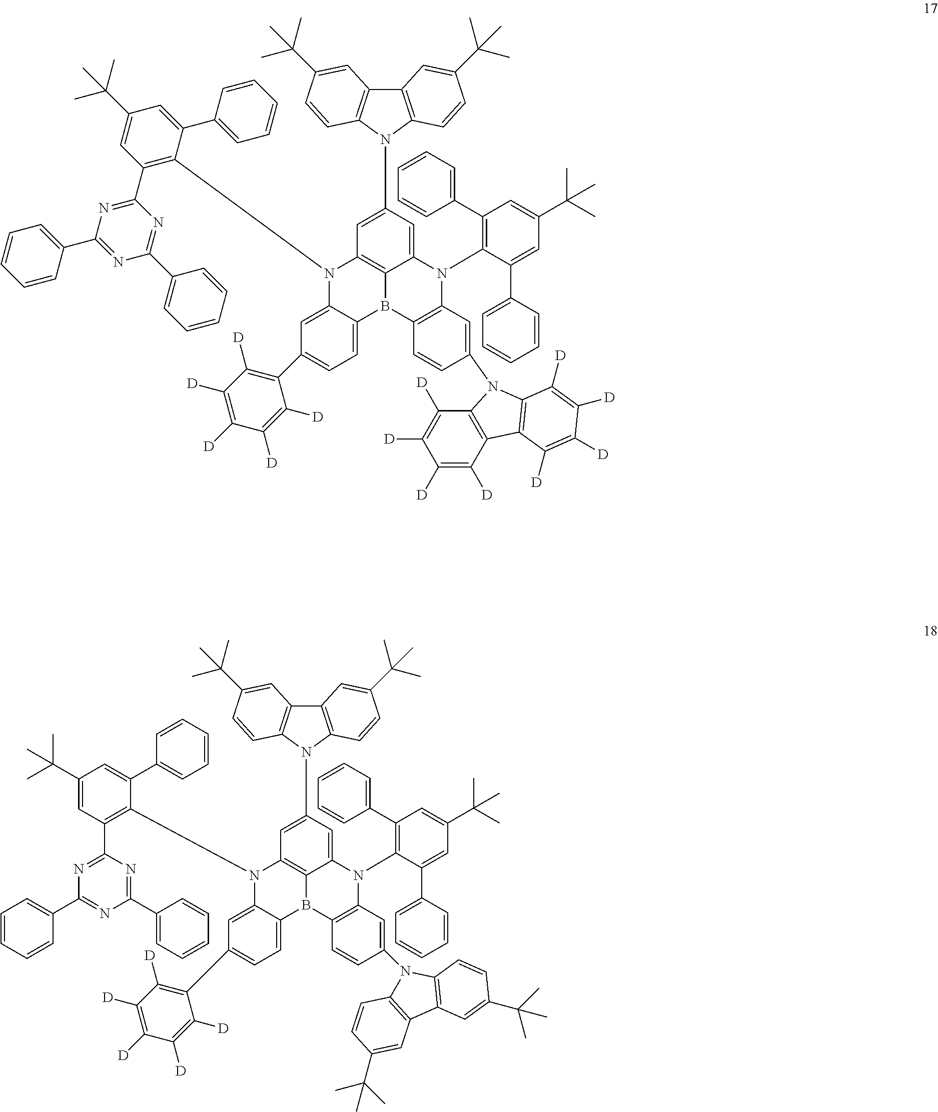 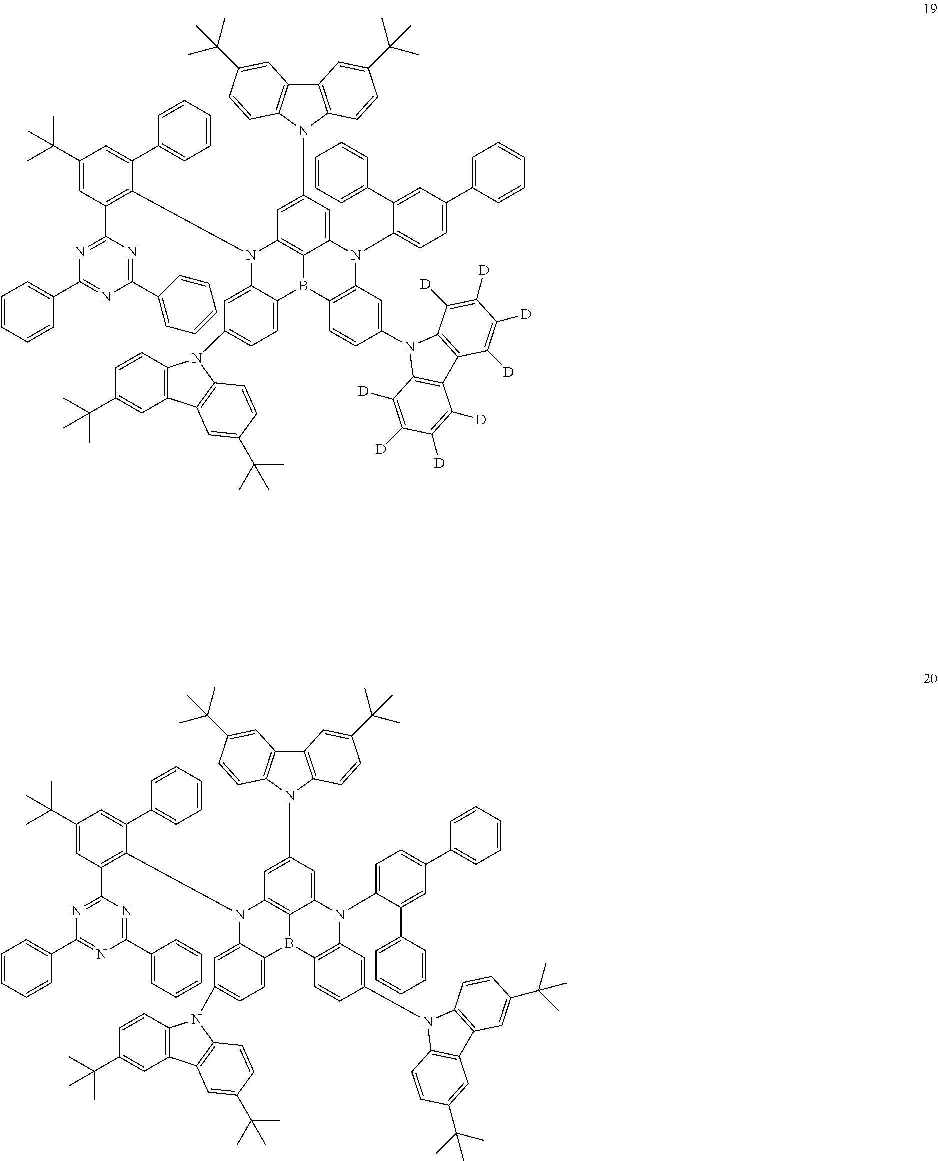 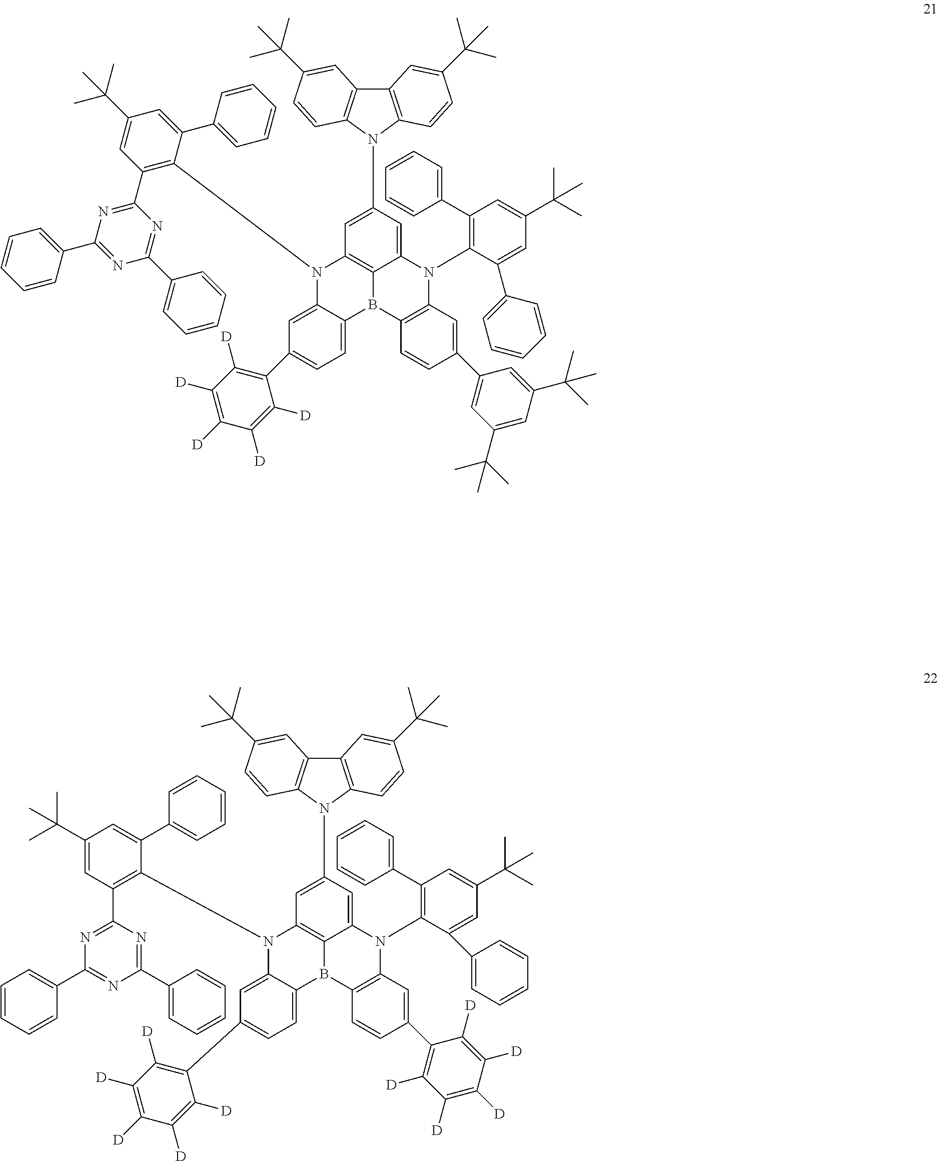 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2ccccc2)c([2H])c1[2H] ; [2H]c1c([2H])c([2H])c(-c2ccc3c(c2)N(c2c(-c4ccccc4)cc(C(C)(C)C)cc2-c2ccccc2)c2cc(-n4c5ccc(C(C)(C)C)cc5c5cc(C(C)(C)C)ccc54)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H]] 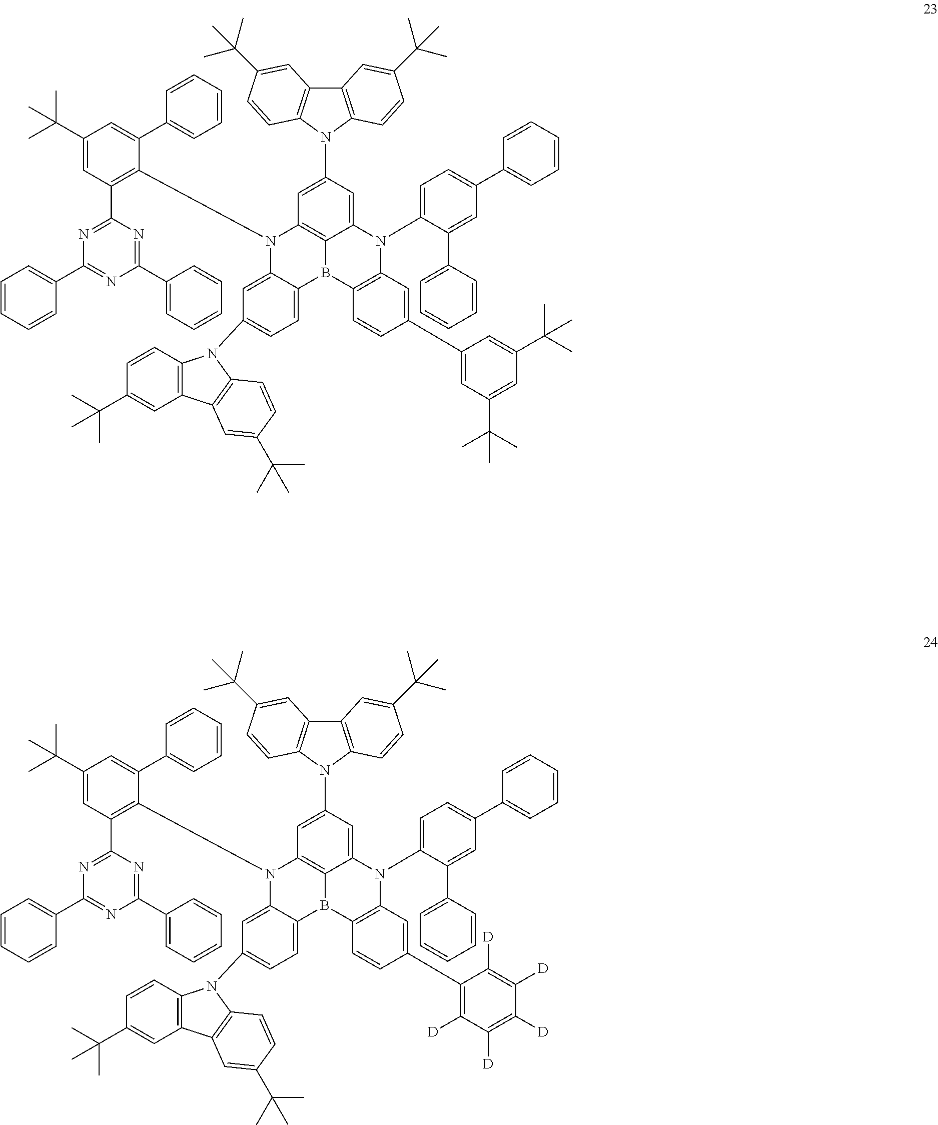 [SMILES: CC(C)(C)c1cc(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)c([2H])c1[2H]] 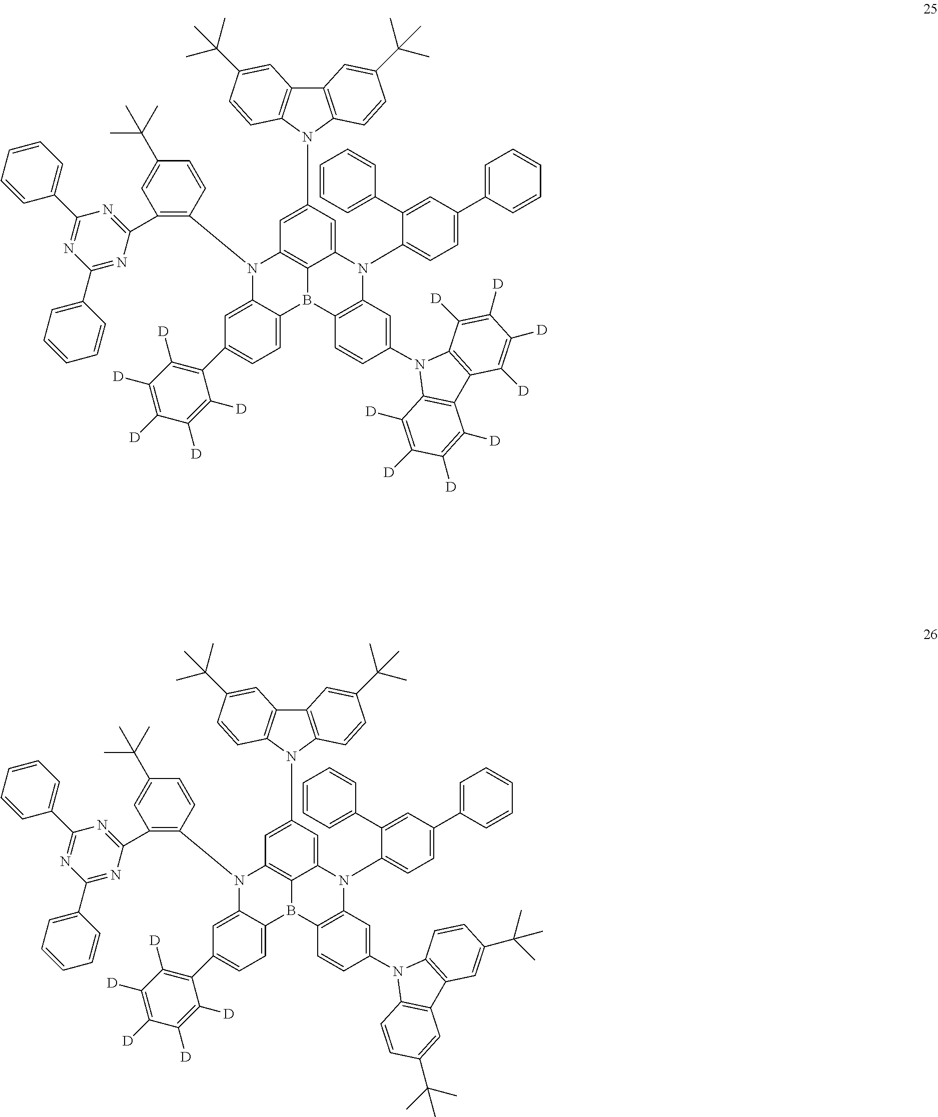 [SMILES: [2H]c1c([2H])c([2H])c(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5c([2H])c([2H])c([2H])c([2H])c5c5c([2H])c([2H])c([2H])c([2H])c53)cc2N4c2ccc(-c3ccccc3)cc2-c2ccccc2)c([2H])c1[2H] ; [2H]c1c([2H])c([2H])c(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(-c3ccccc3)cc2-c2ccccc2)c([2H])c1[2H]] 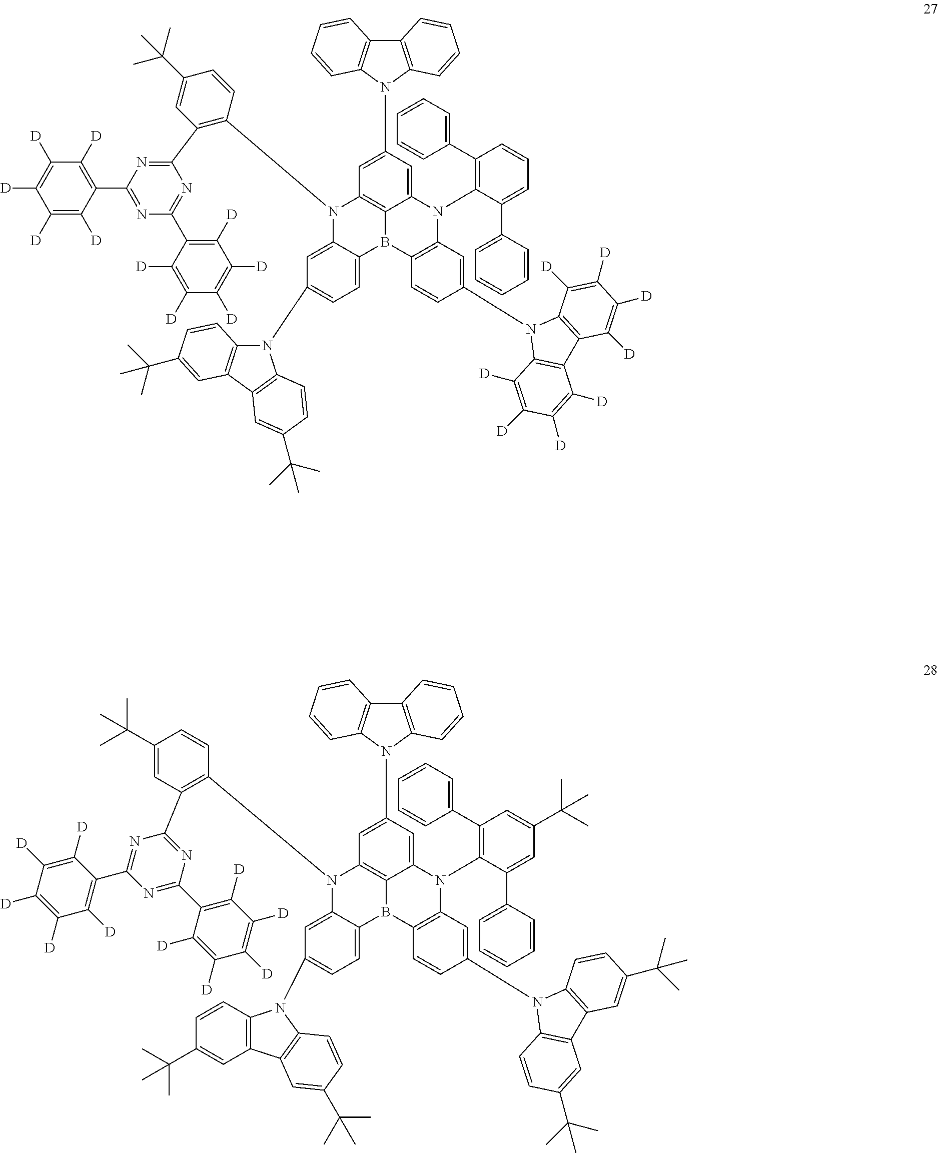 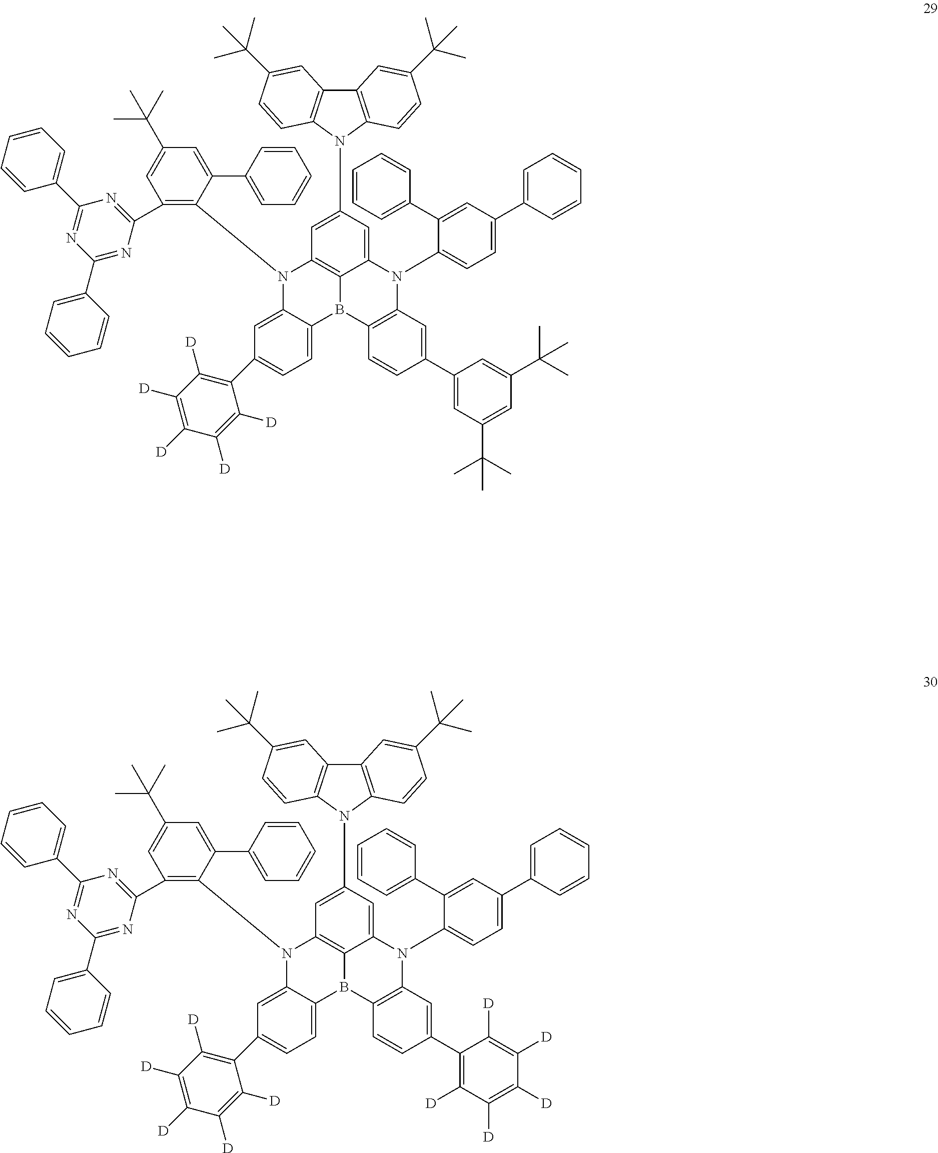 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2ccc(-c3ccccc3)cc2-c2ccccc2)c([2H])c1[2H] ; [2H]c1c([2H])c([2H])c(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H]] 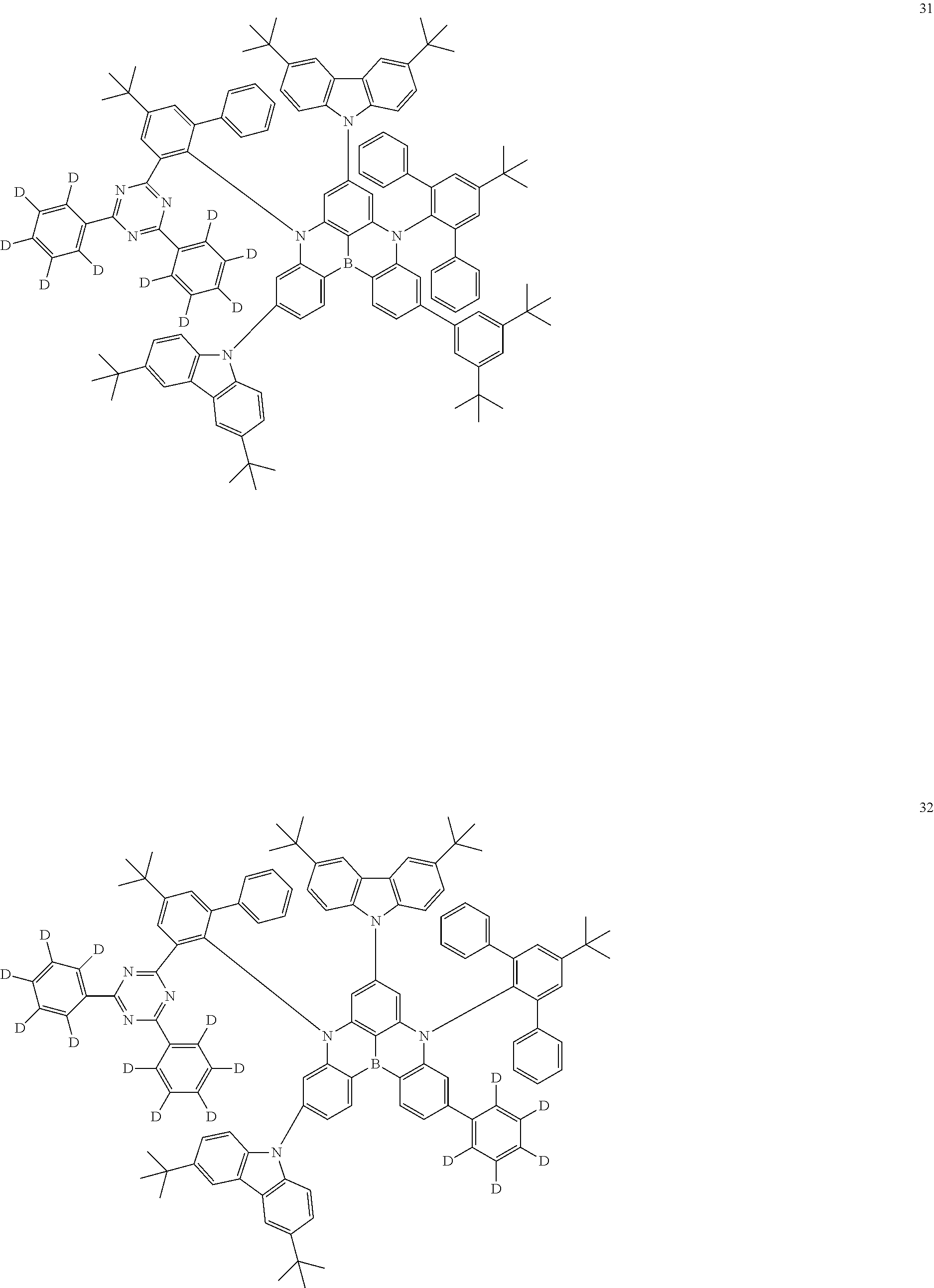 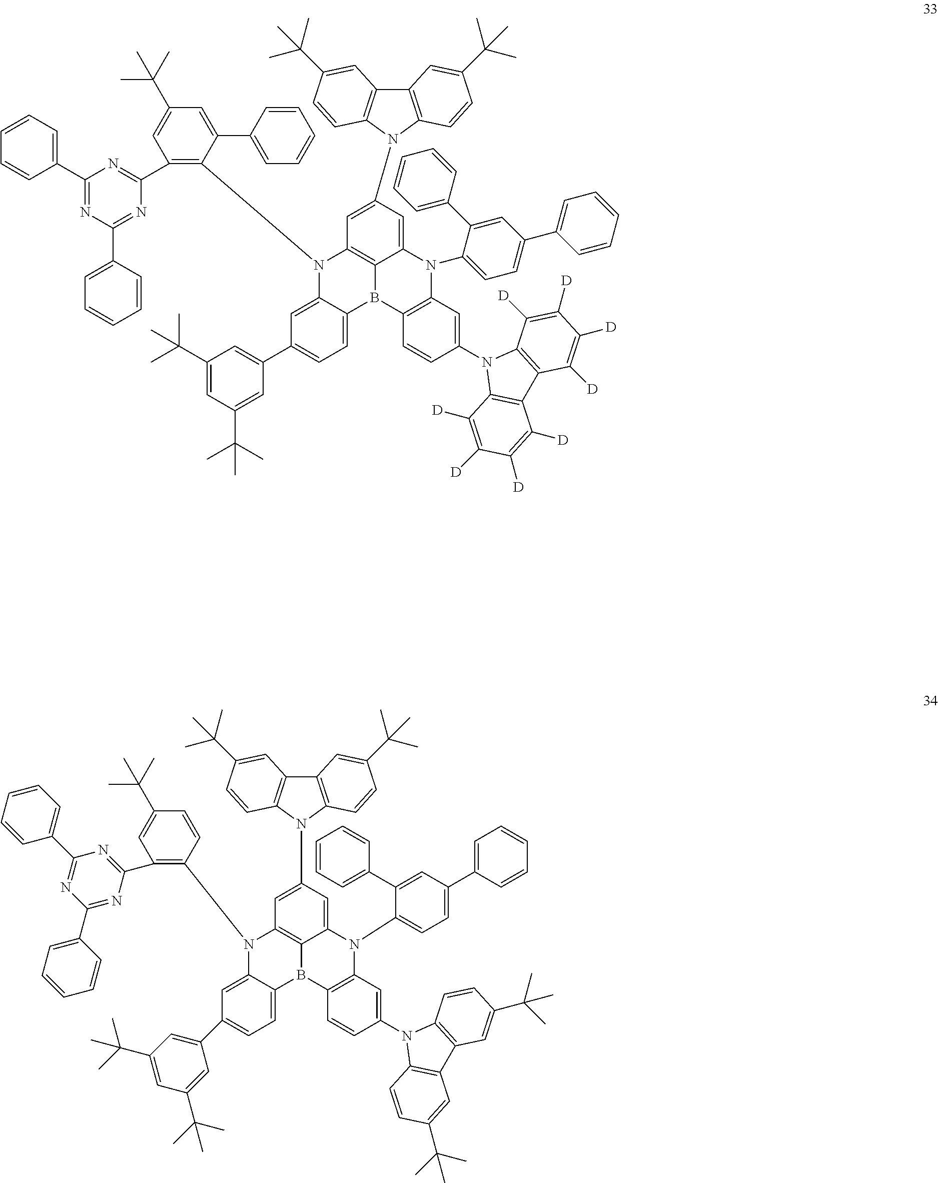 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(-n3c4ccc(C(C)(C)C)cc4c4cc(C(C)(C)C)ccc43)cc3c1B2c1ccc(-c2cc(C(C)(C)C)cc(C(C)(C)C)c2)cc1N3c1c(-c2ccccc2)cc(C(C)(C)C)cc1-c1nc(-c2ccccc2)nc(-c2ccccc2)n1 ; CC(C)(C)c1cc(-c2ccc3c(c2)N(c2ccc(C(C)(C)C)cc2-c2nc(-c4ccccc4)nc(-c4ccccc4)n2)c2cc(-n4c5ccc(C(C)(C)C)cc5c5cc(C(C)(C)C)ccc54)cc4c2B3c2ccc(-n3c5ccc(C(C)(C)C)cc5c5cc(C(C)(C)C)ccc53)cc2N4c2ccc(-c3ccccc3)cc2-c2ccccc2)cc(C(C)(C)C)c1] 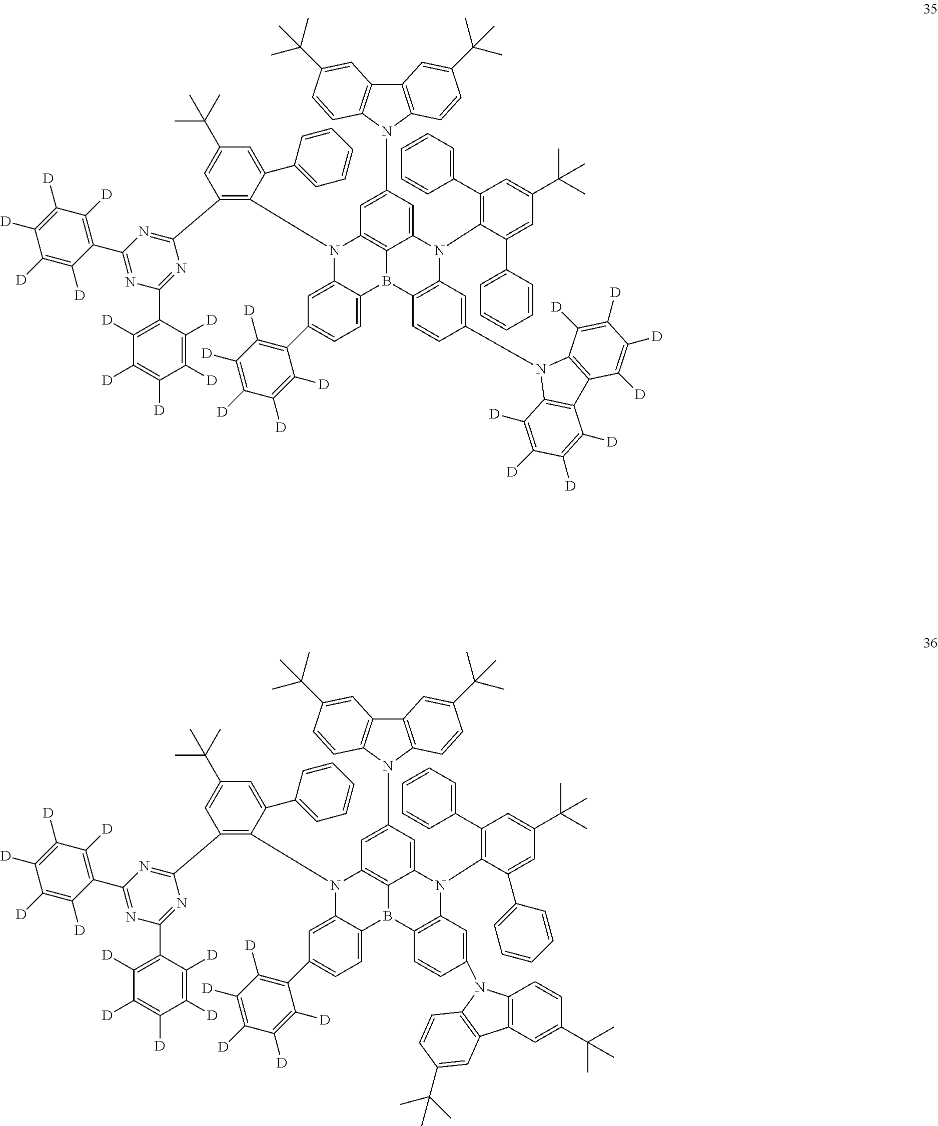 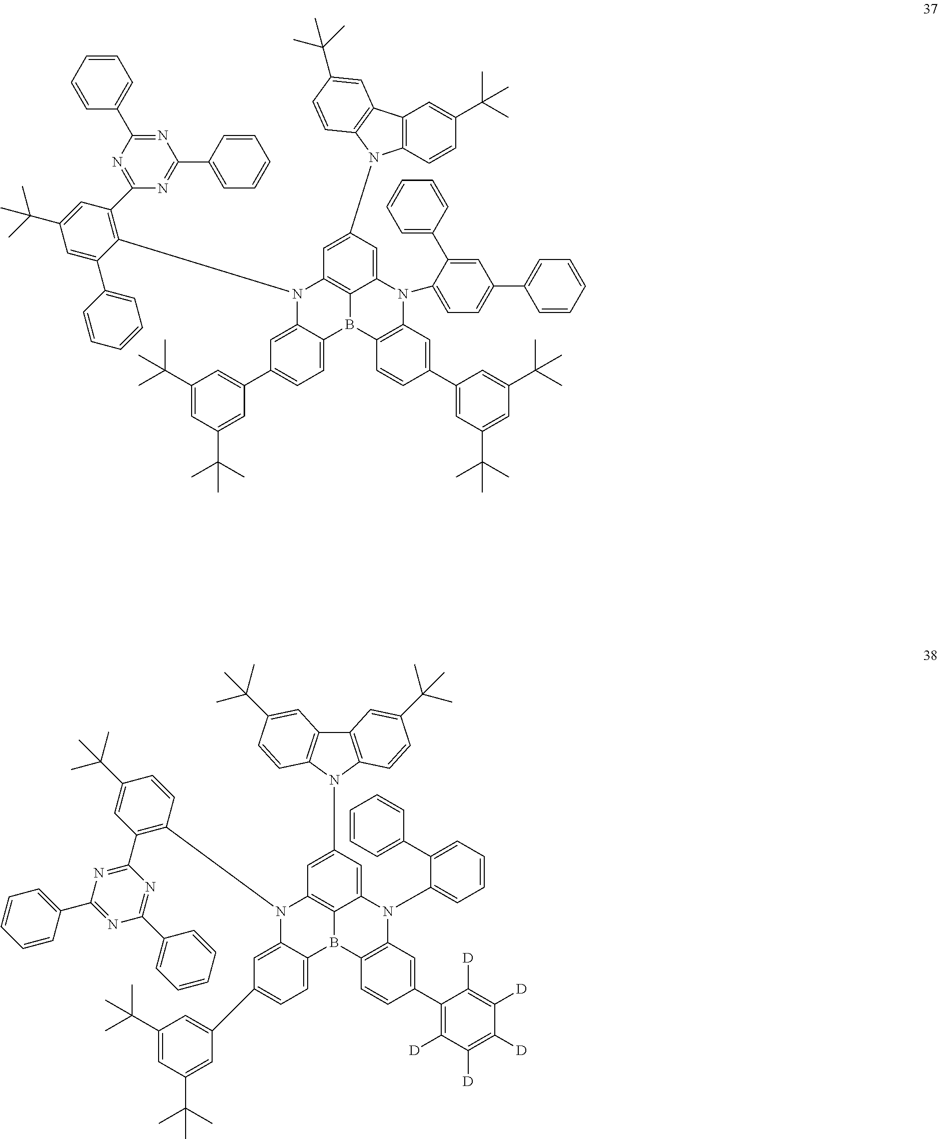 [SMILES: CC(C)(C)c1cc(-c2ccc3c(c2)N(c2ccc(-c4ccccc4)cc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccccc2-c2ccccc2)c2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2ccc(C(C)(C)C)cc2-c2nc(-c3ccccc3)nc(-c3ccccc3)n2)c([2H])c1[2H]] 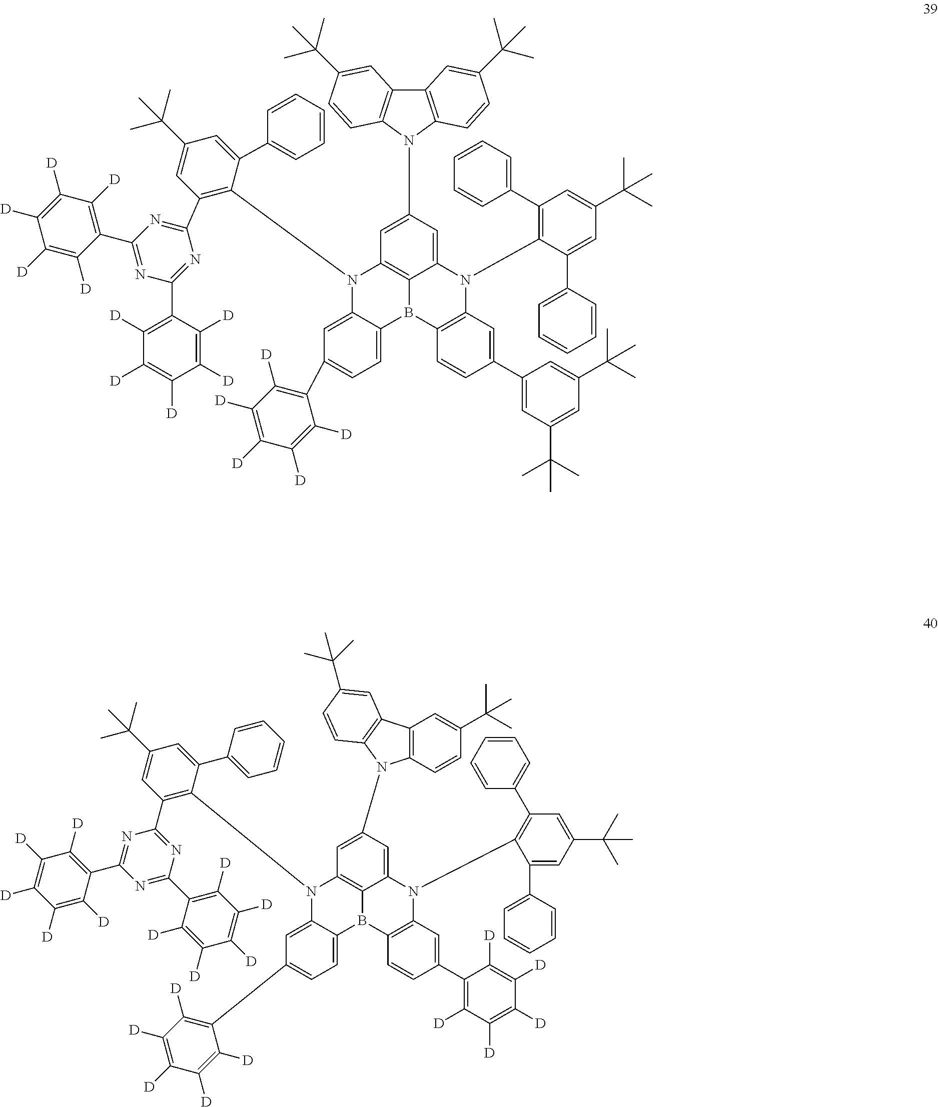 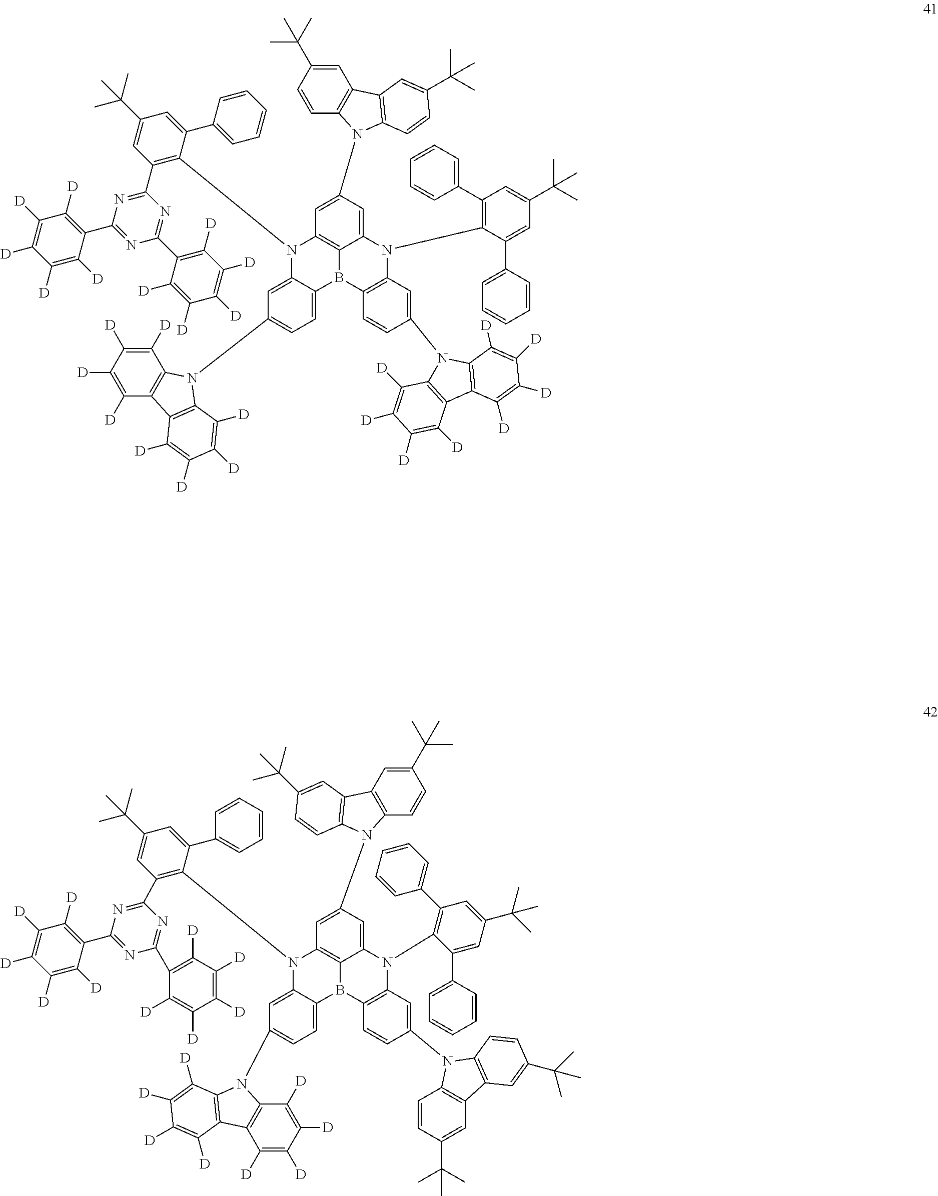 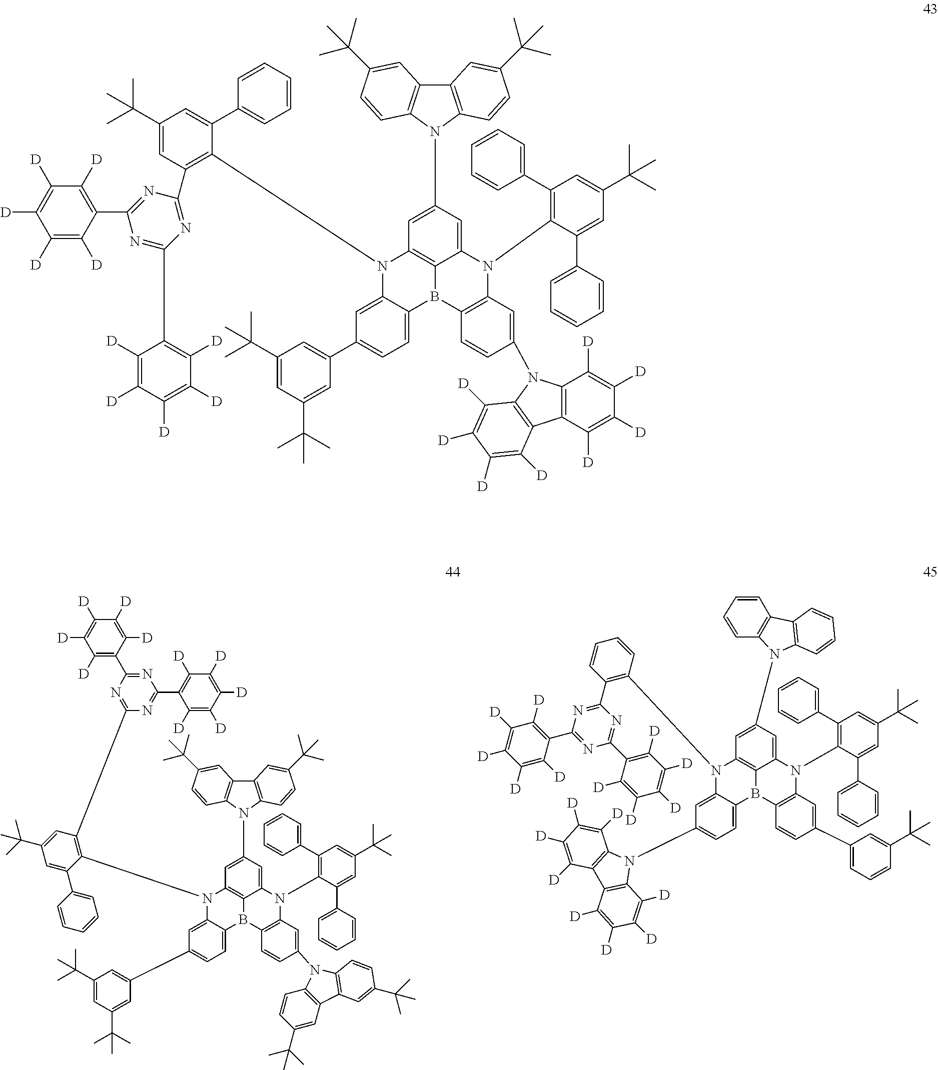 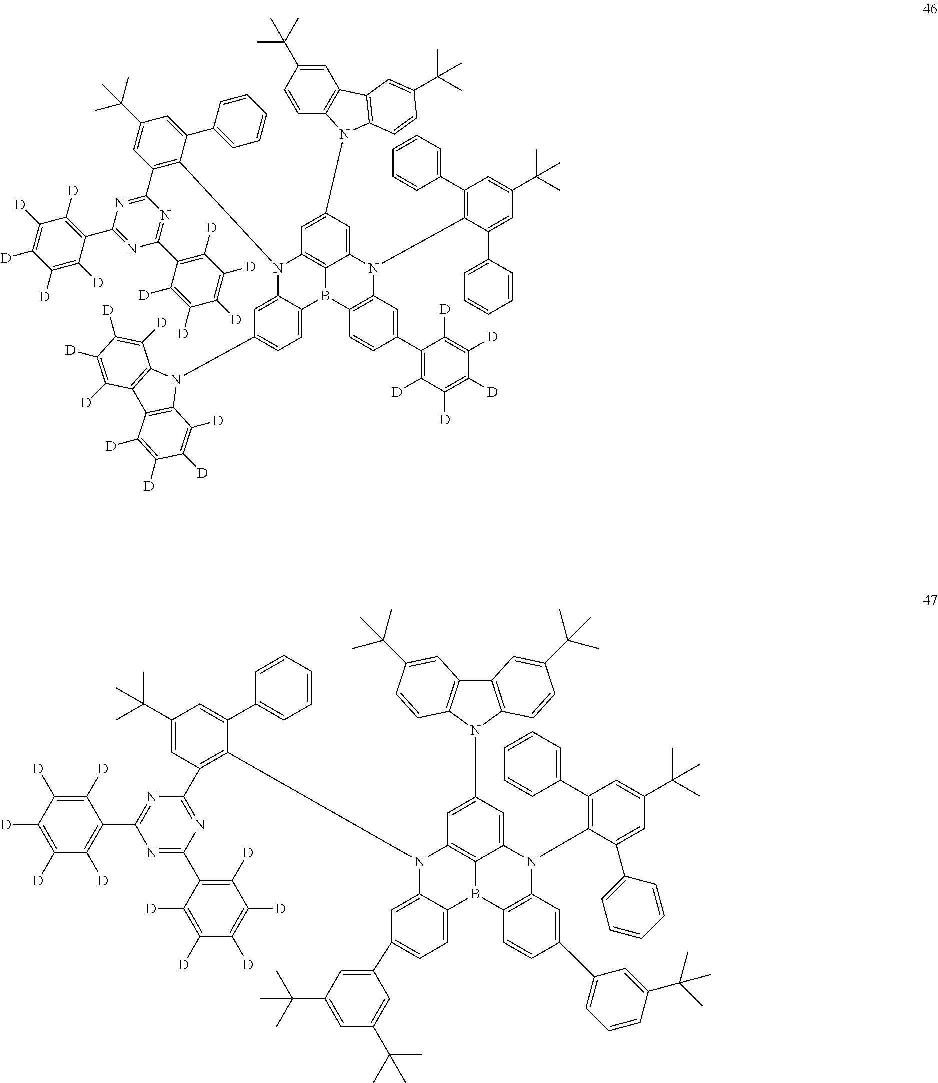 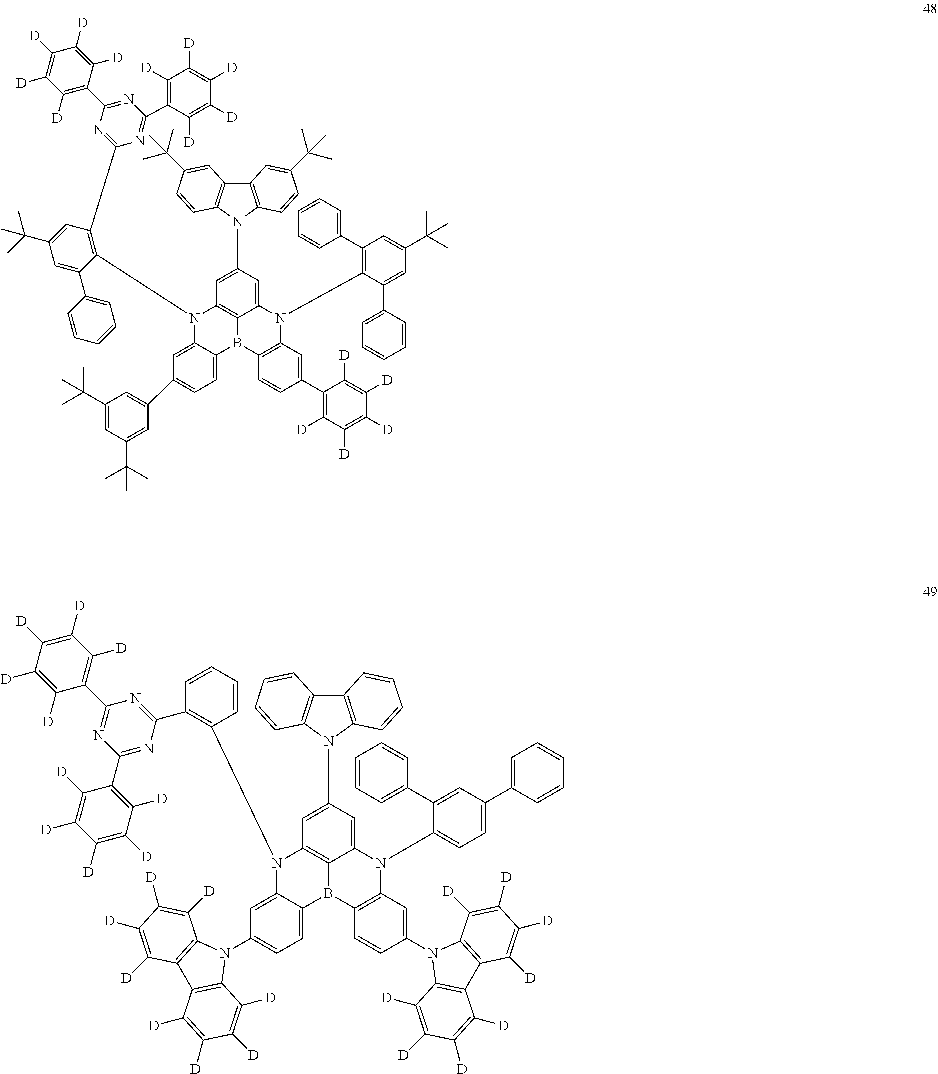 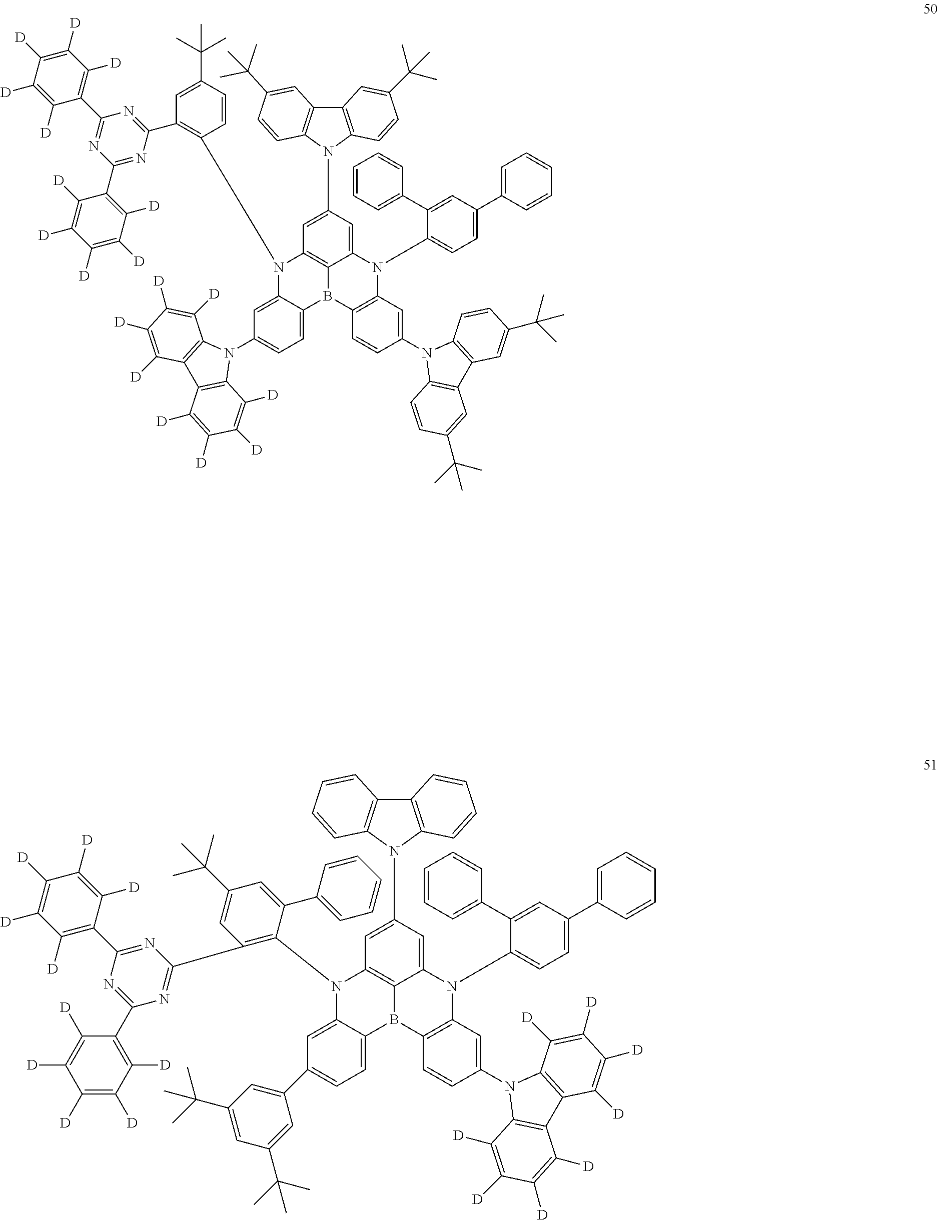 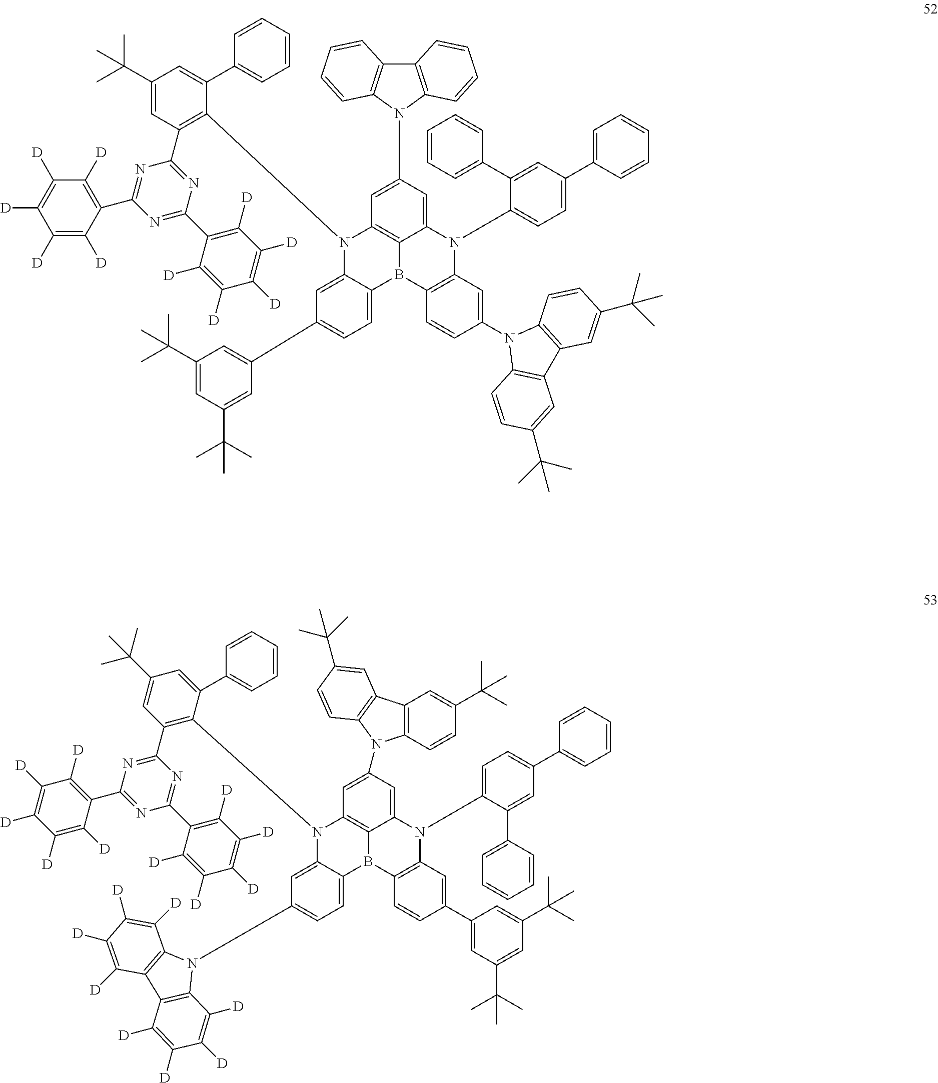 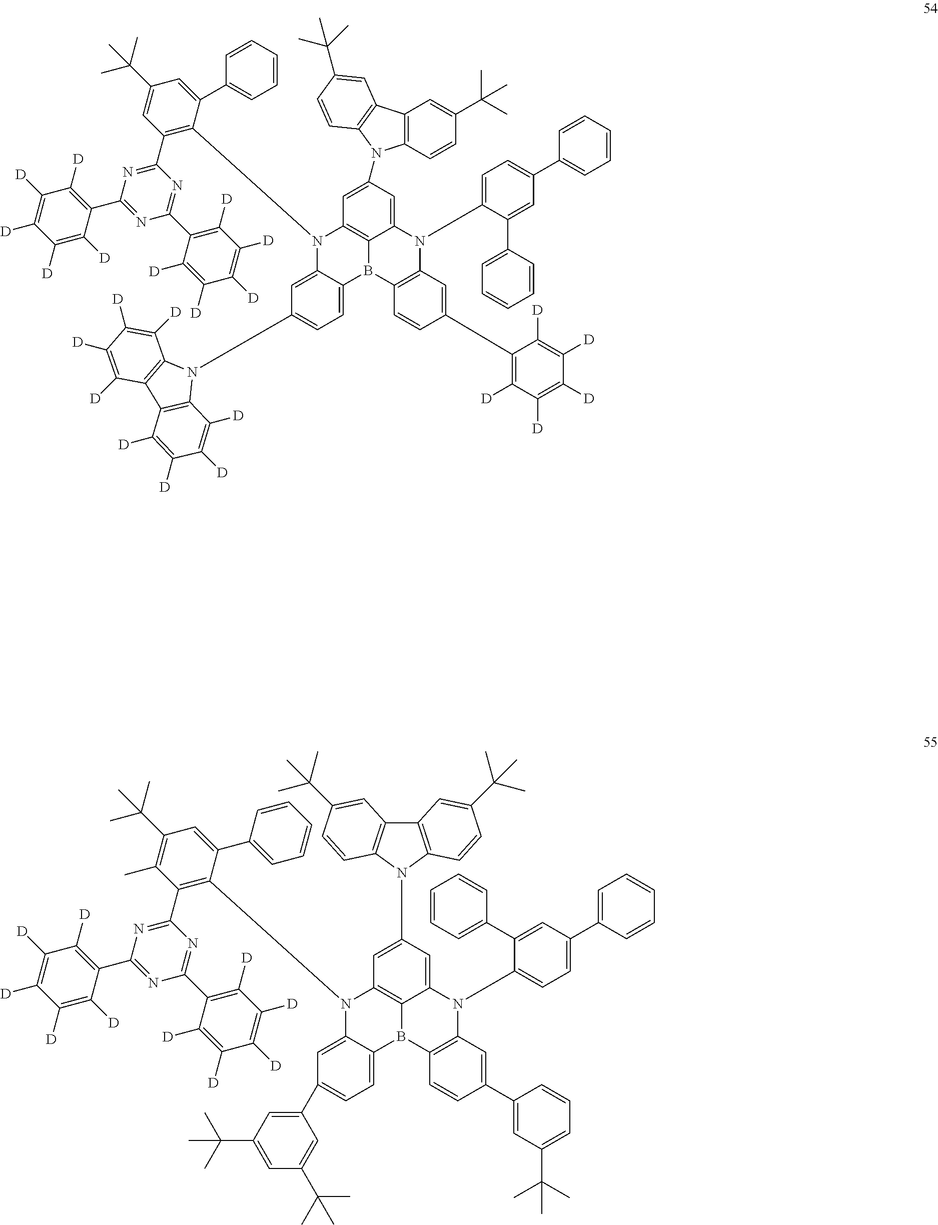 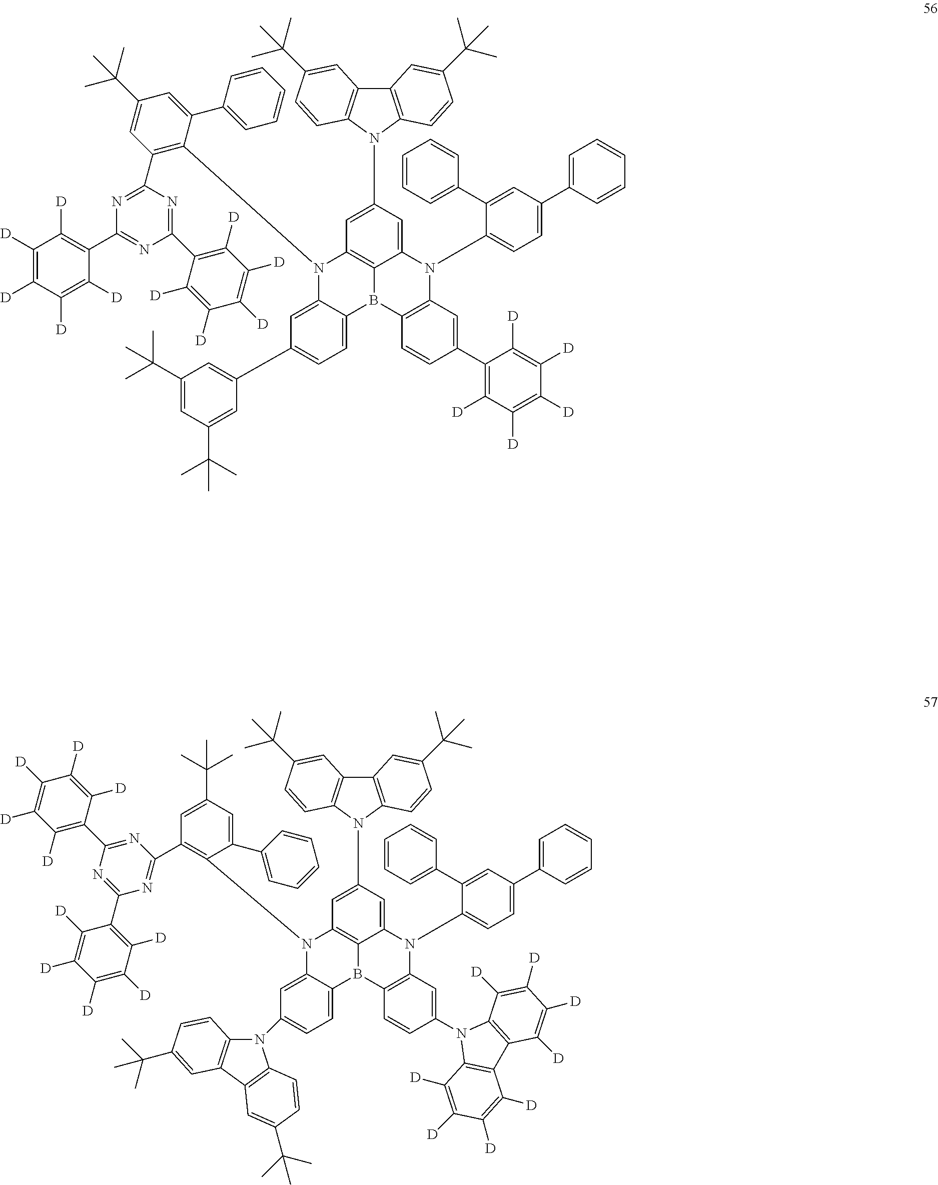 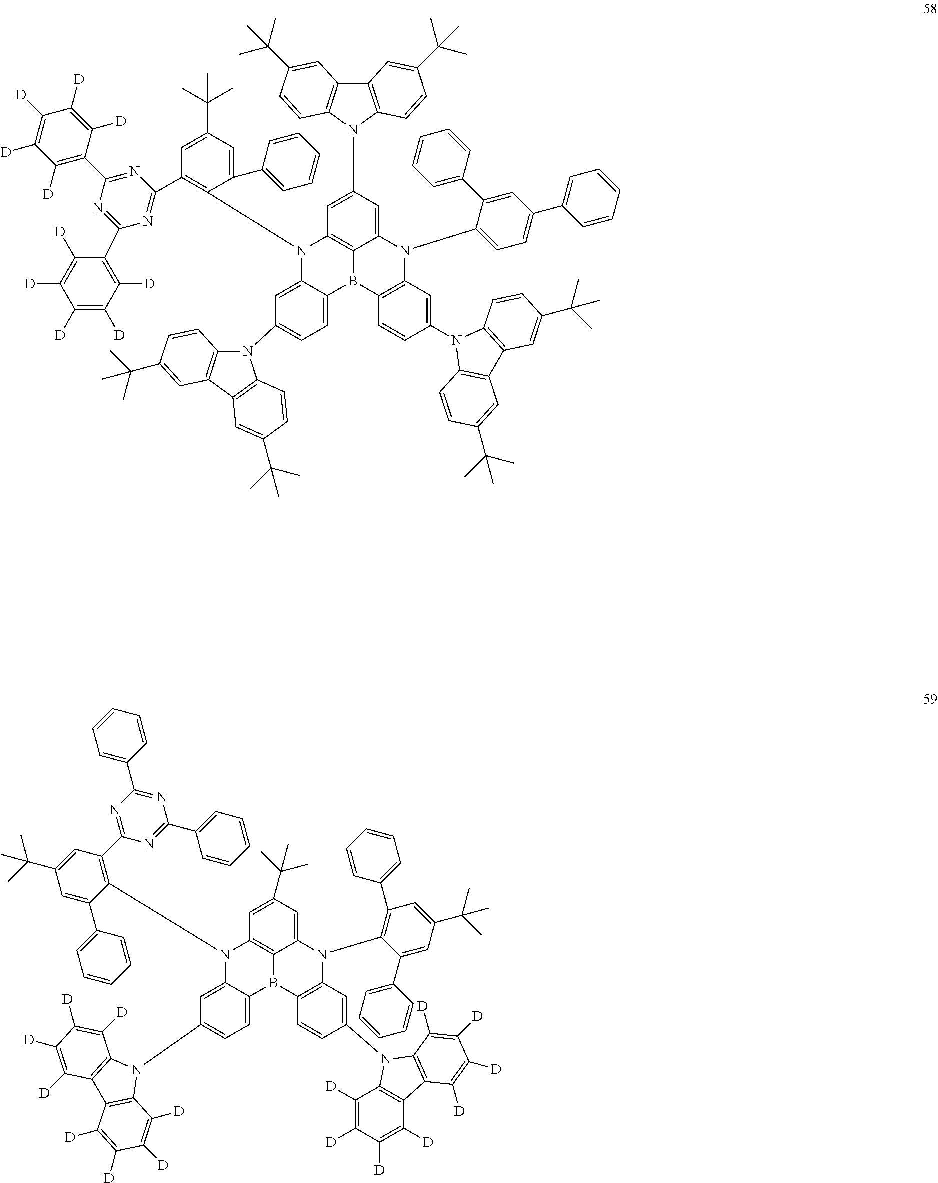 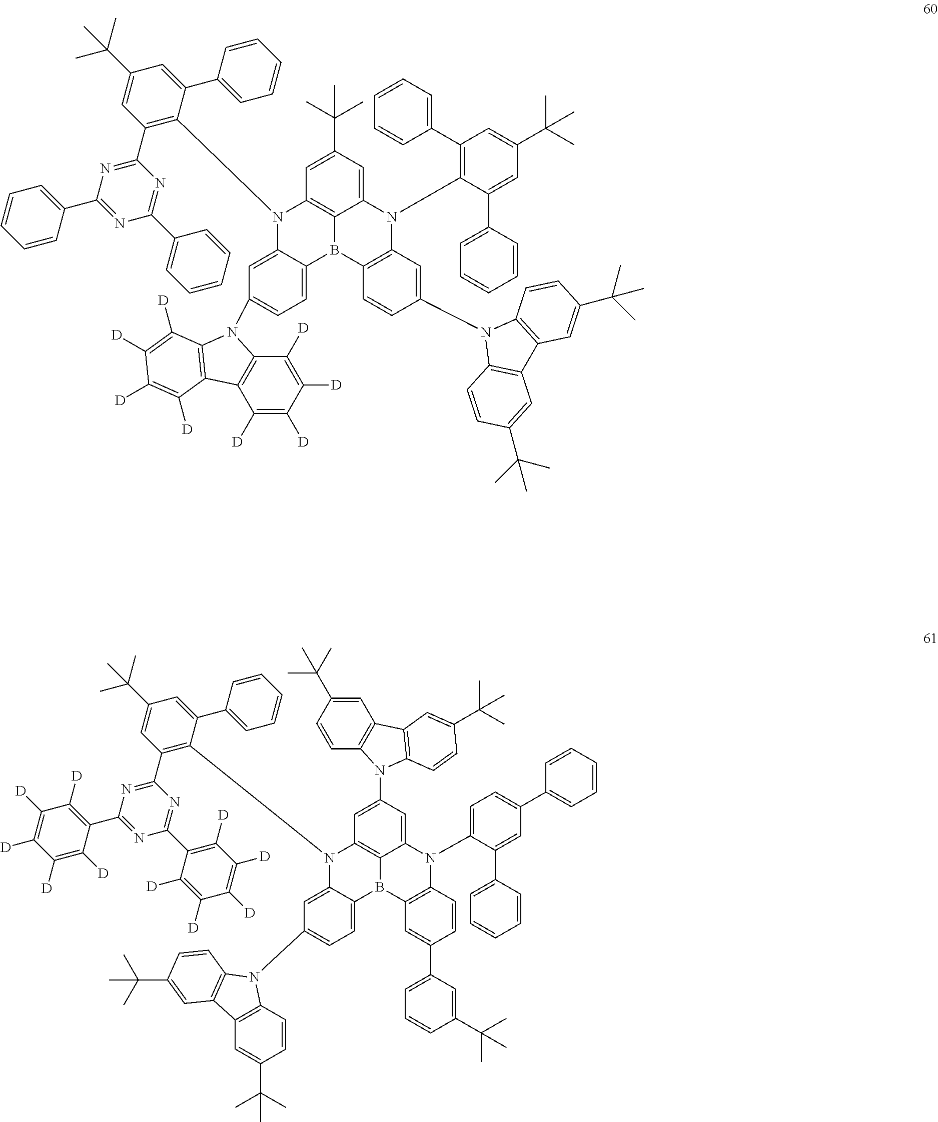 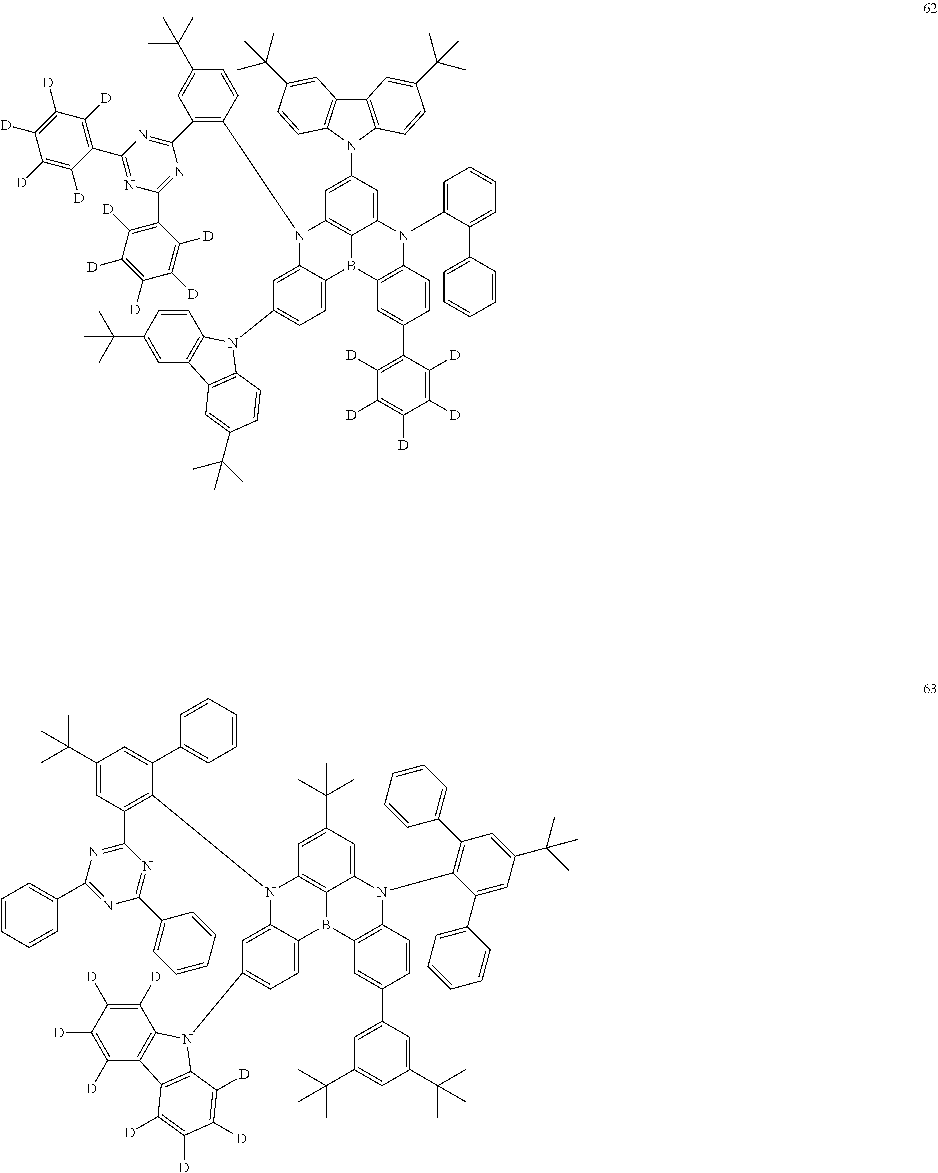 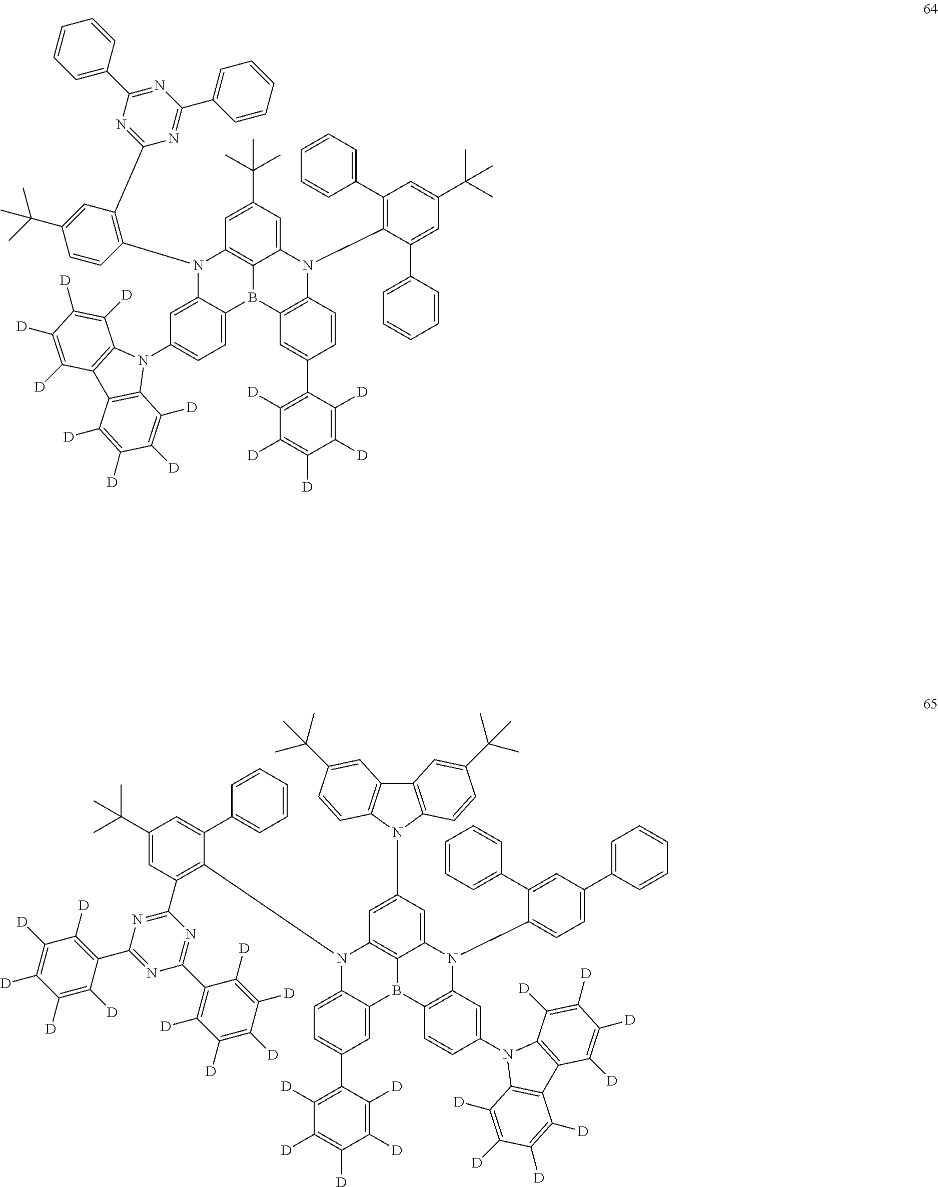 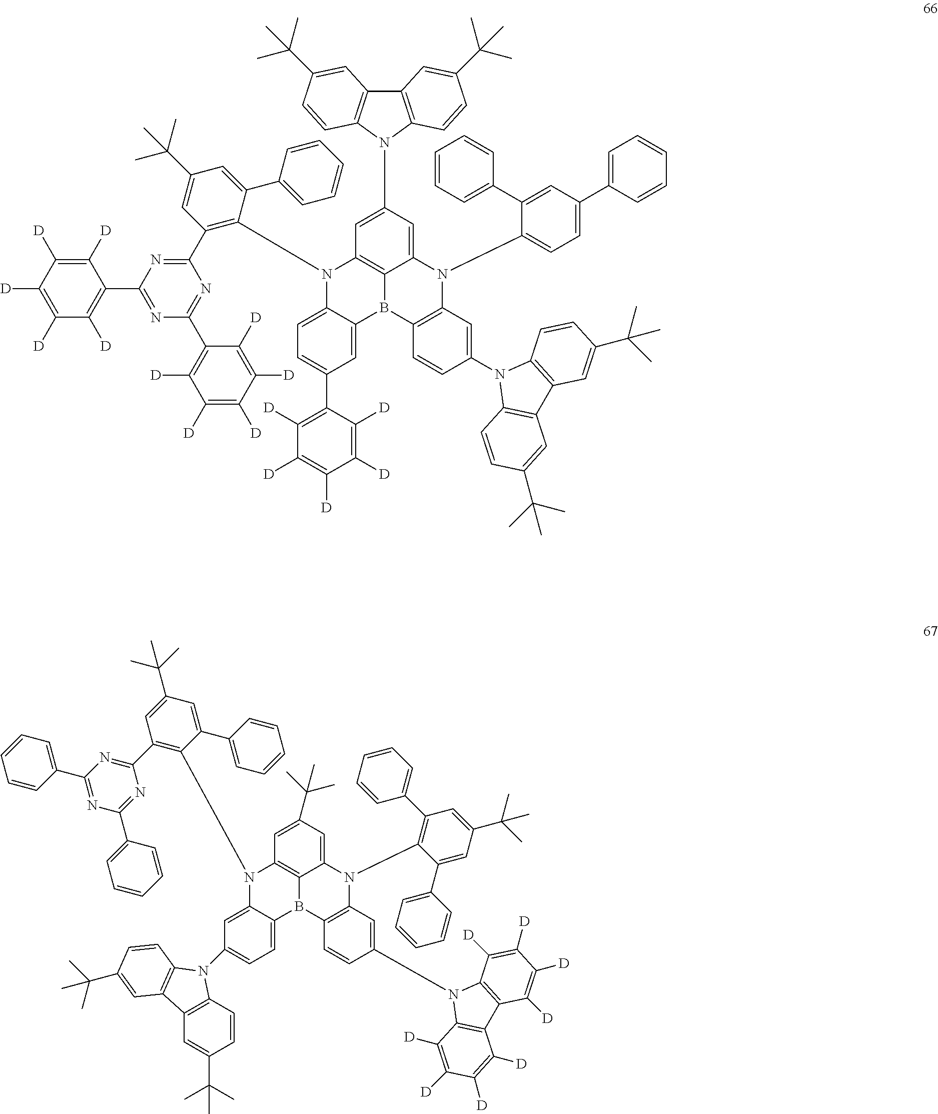 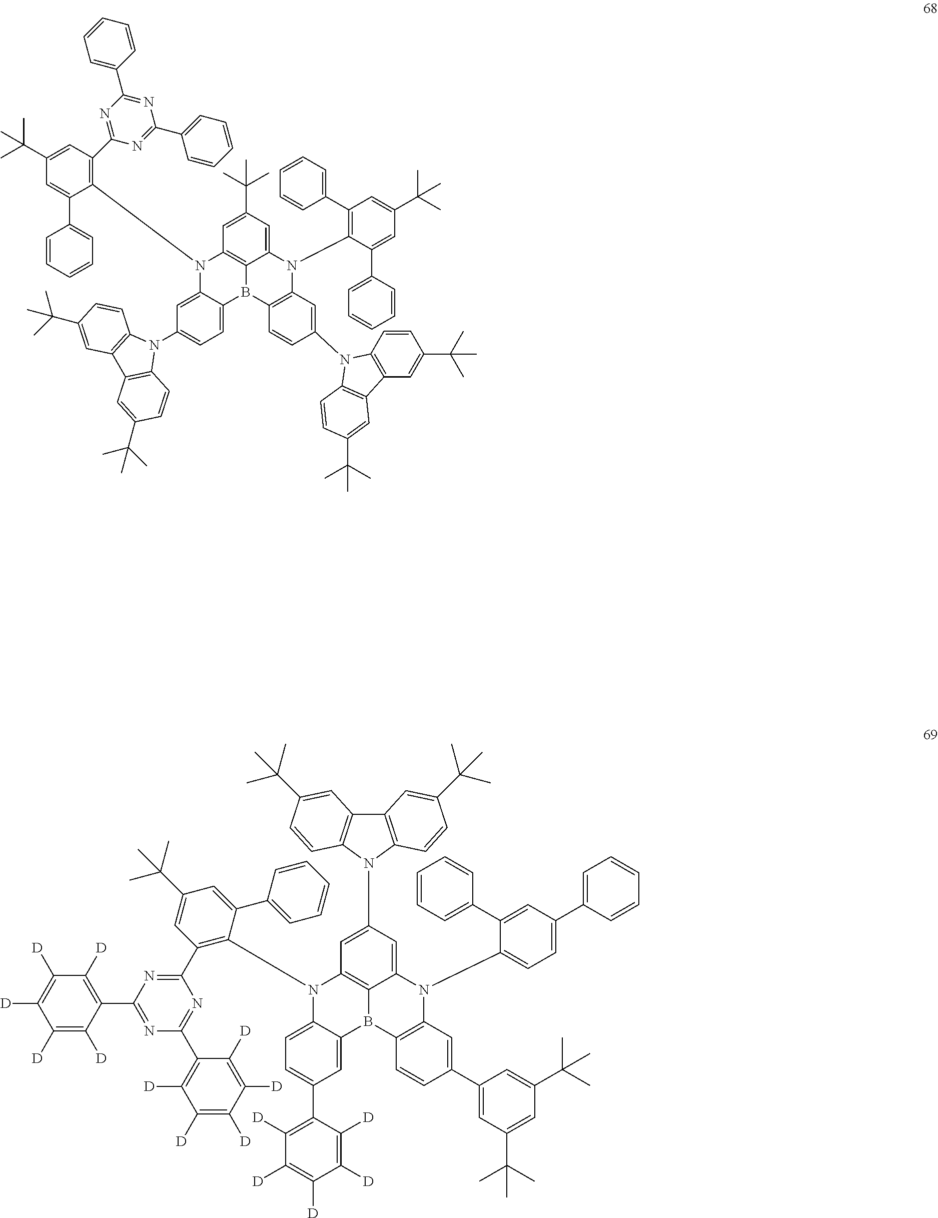 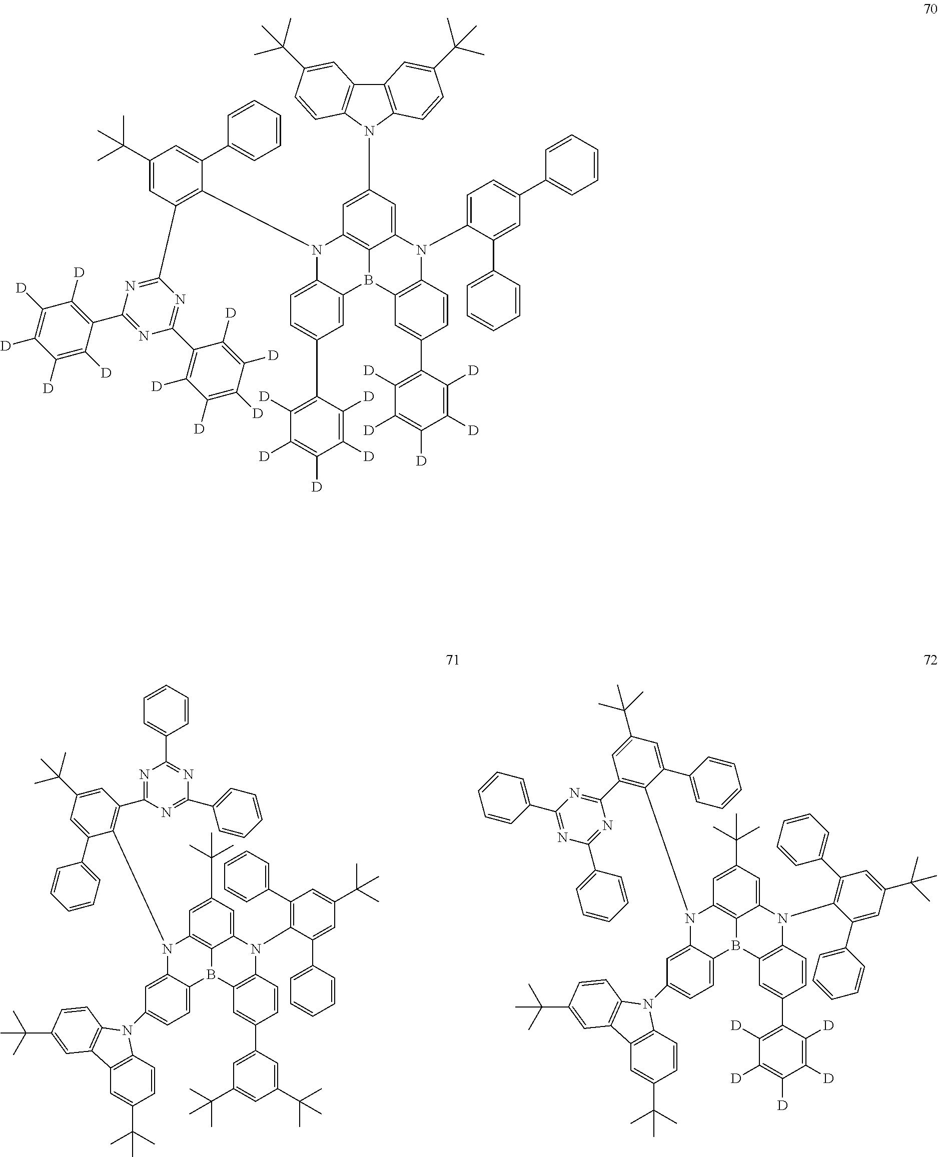 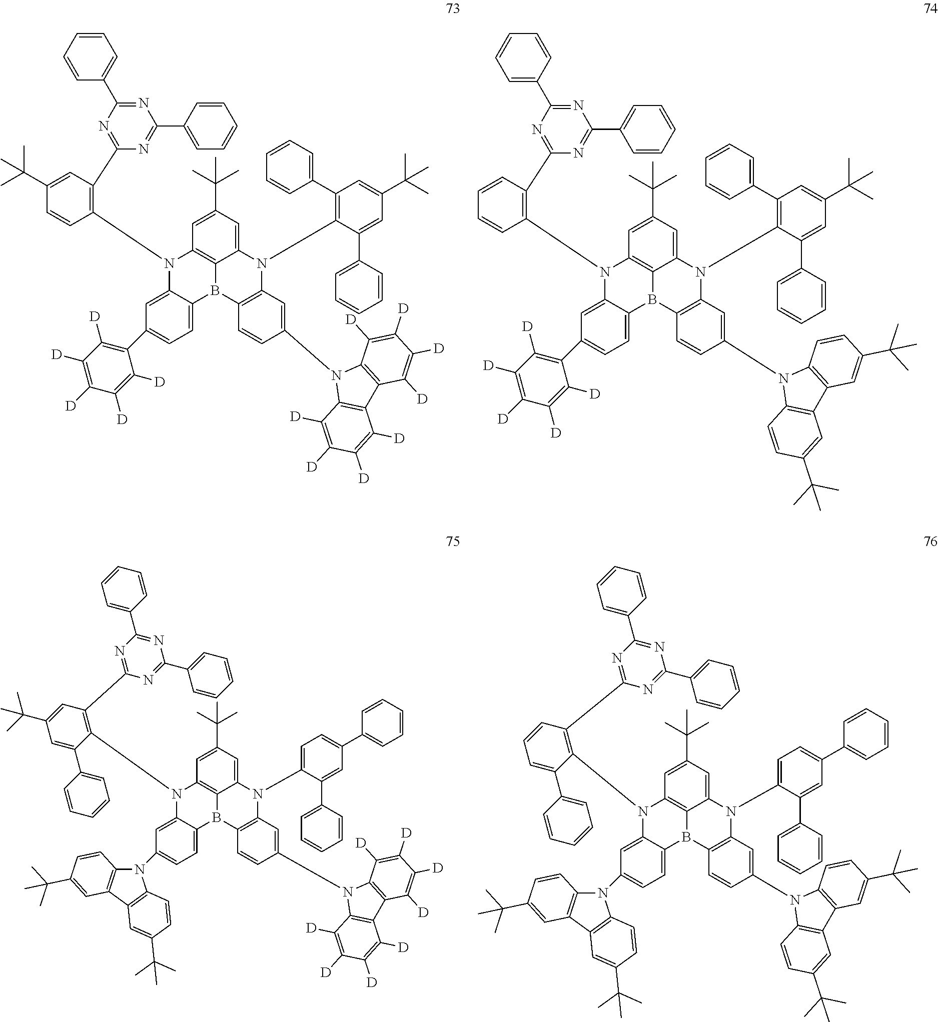 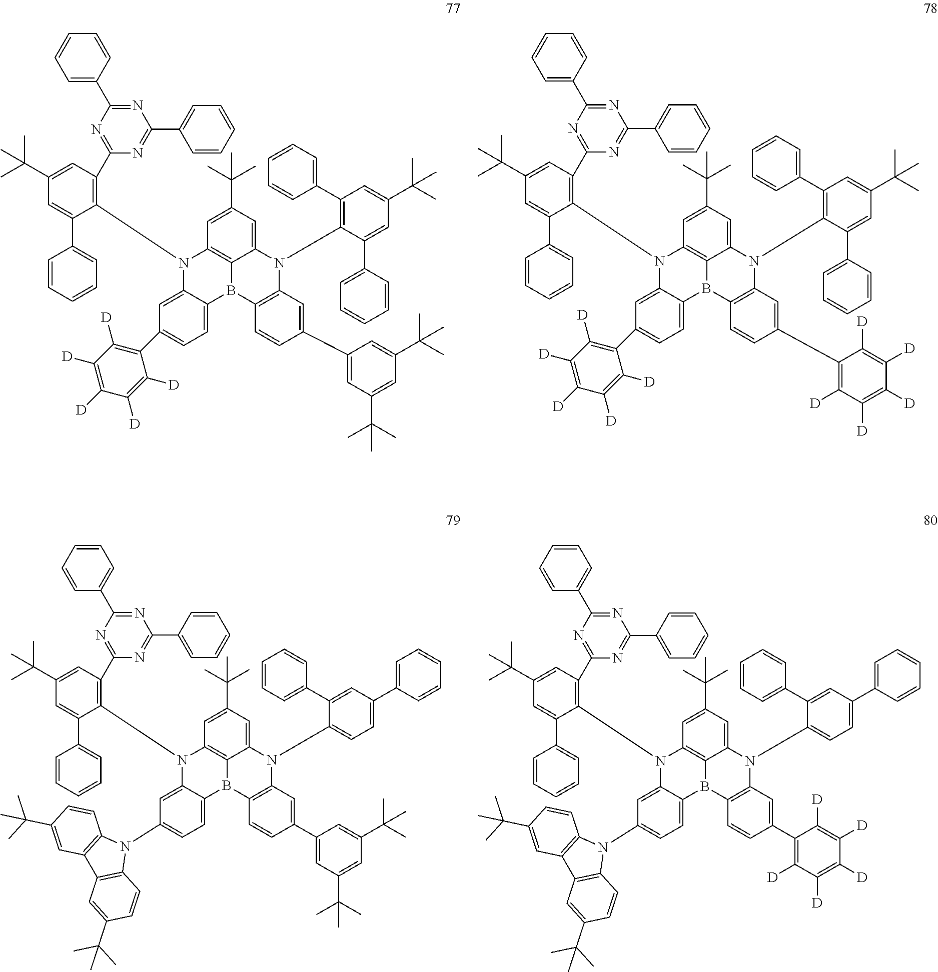 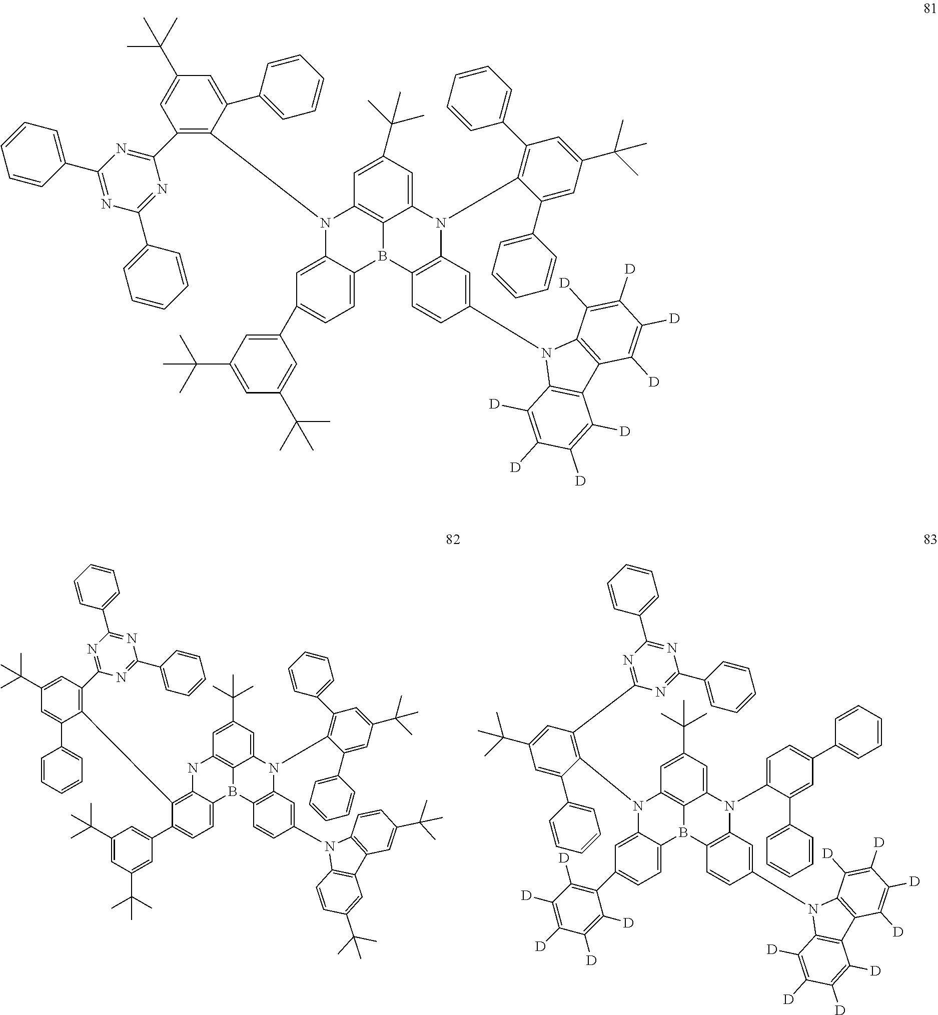 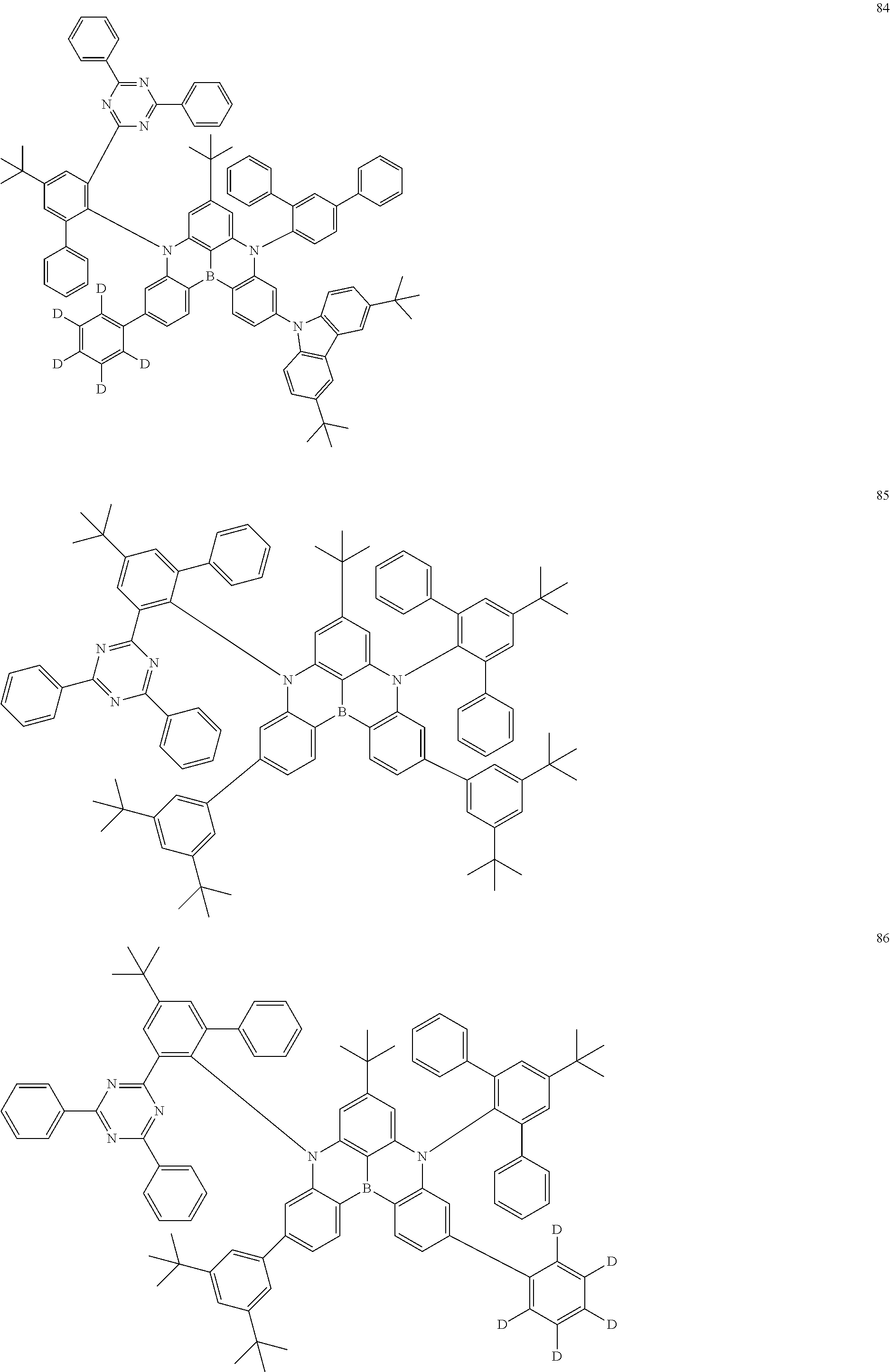 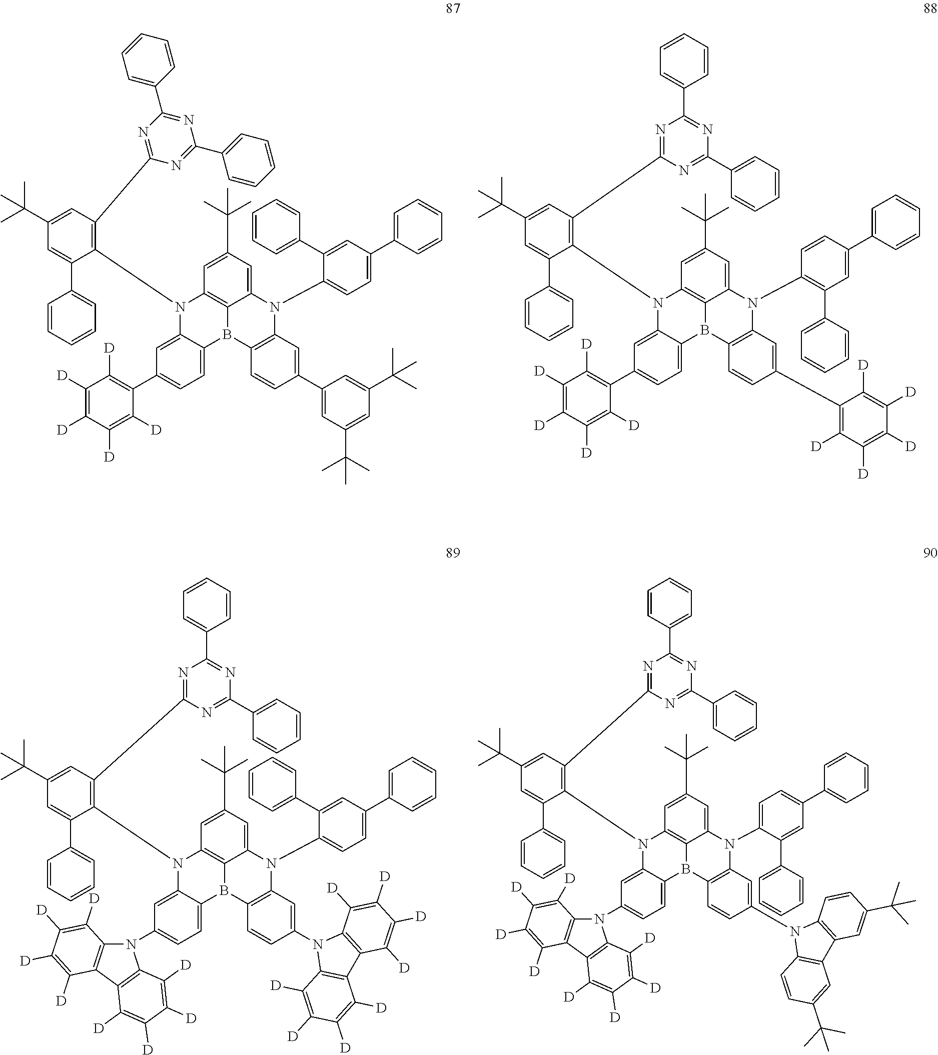 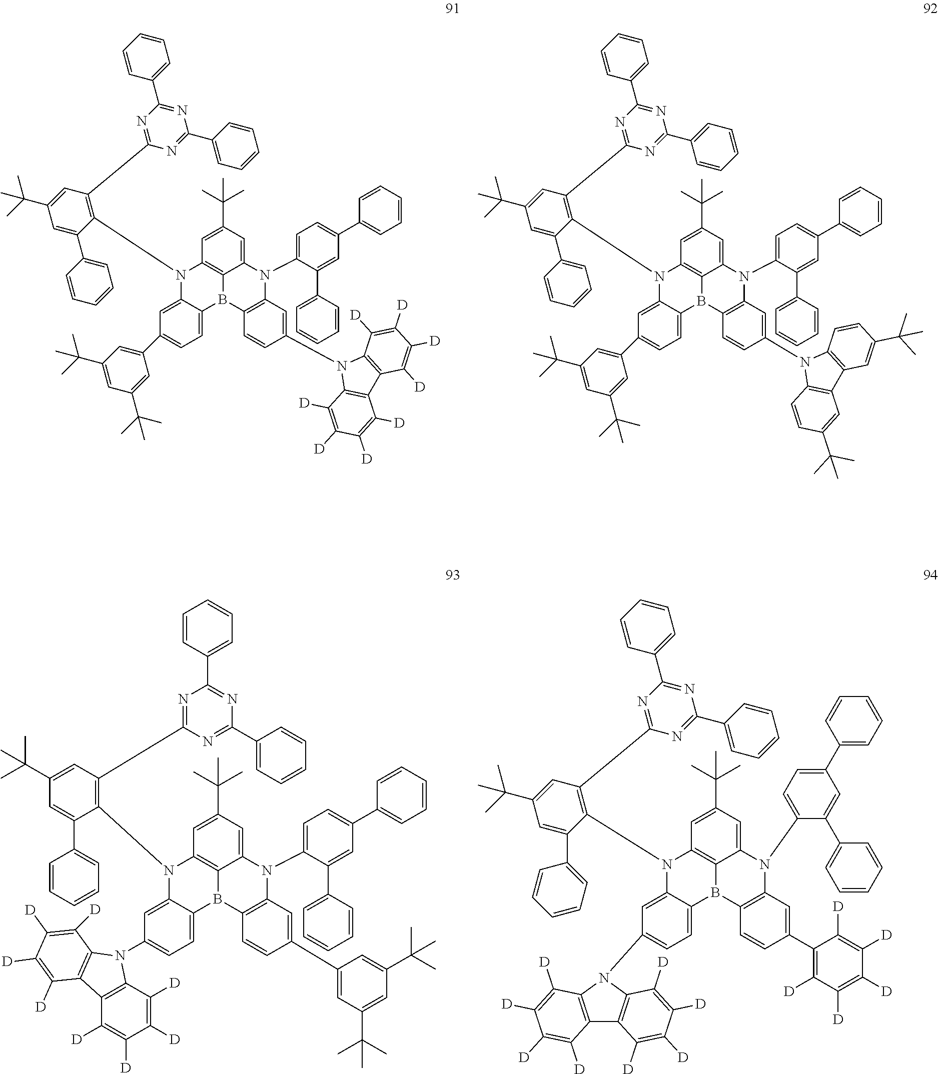 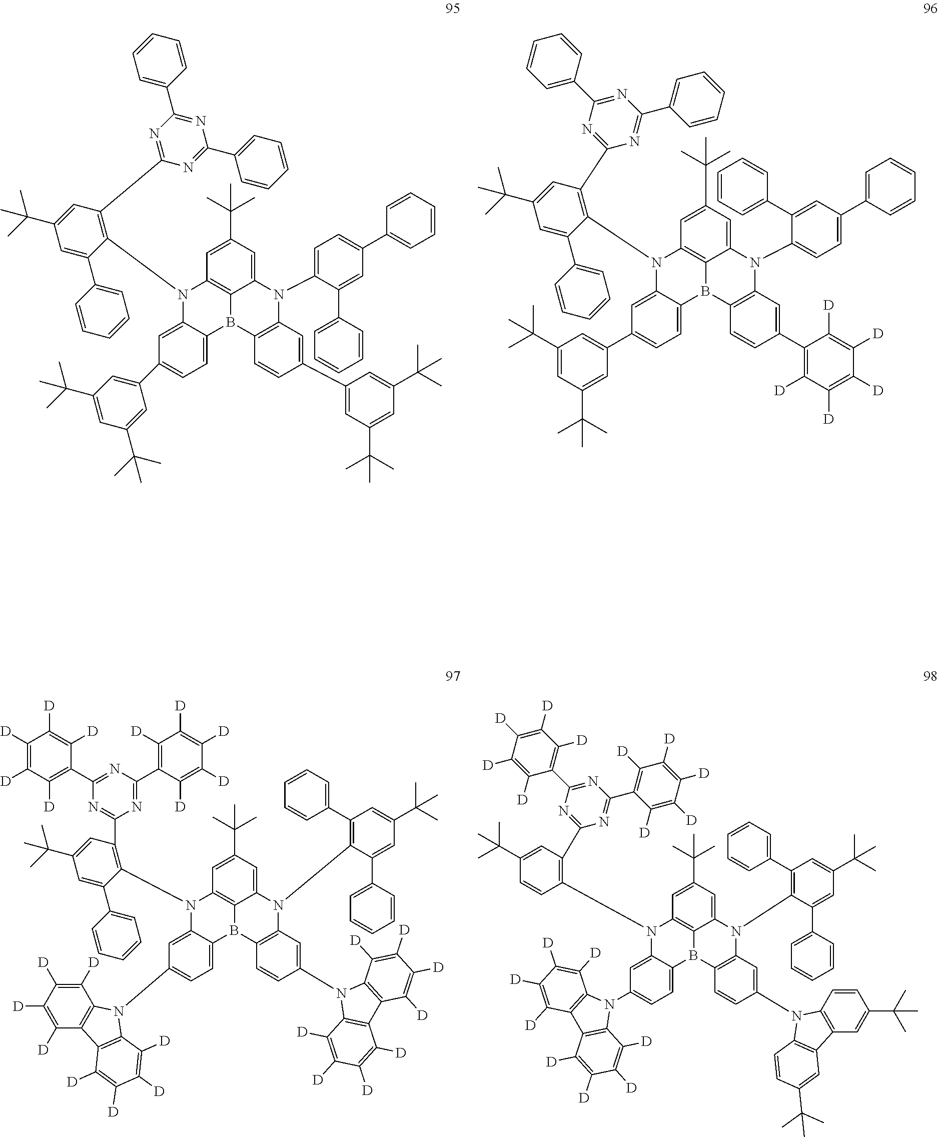 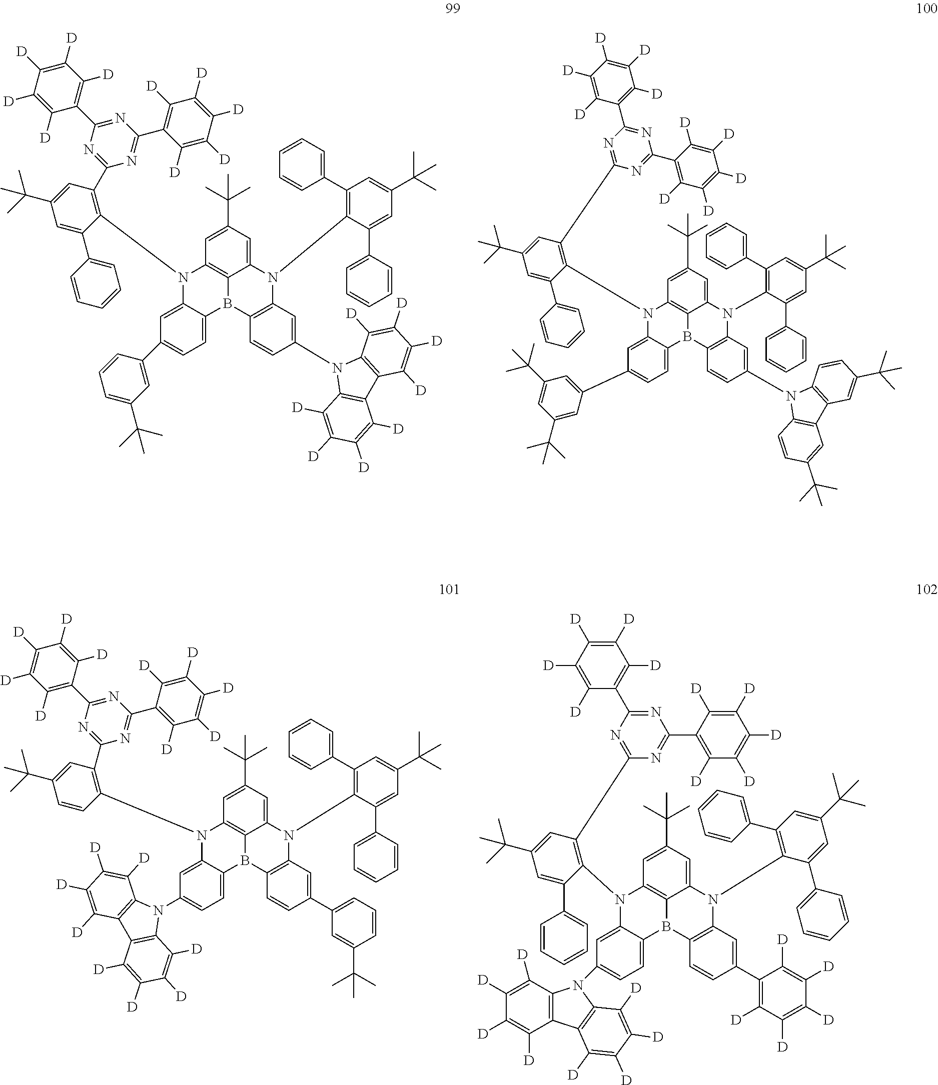 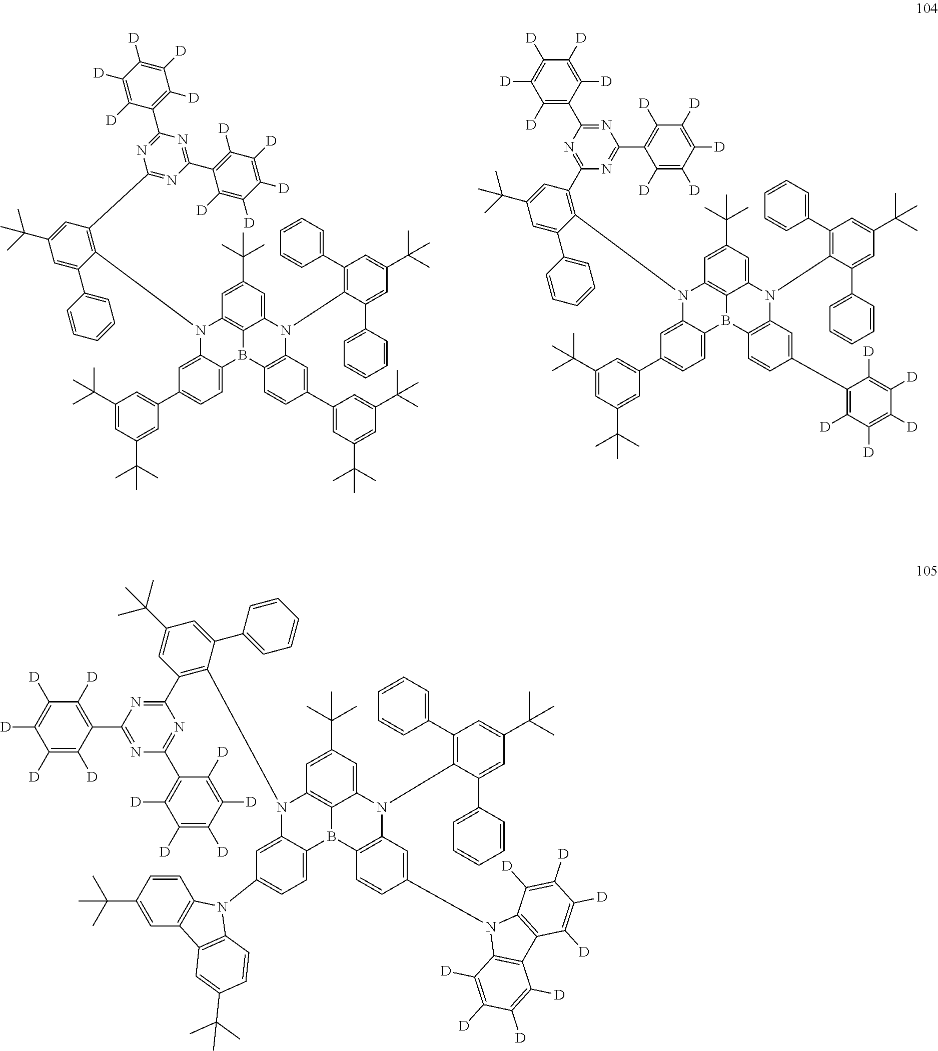 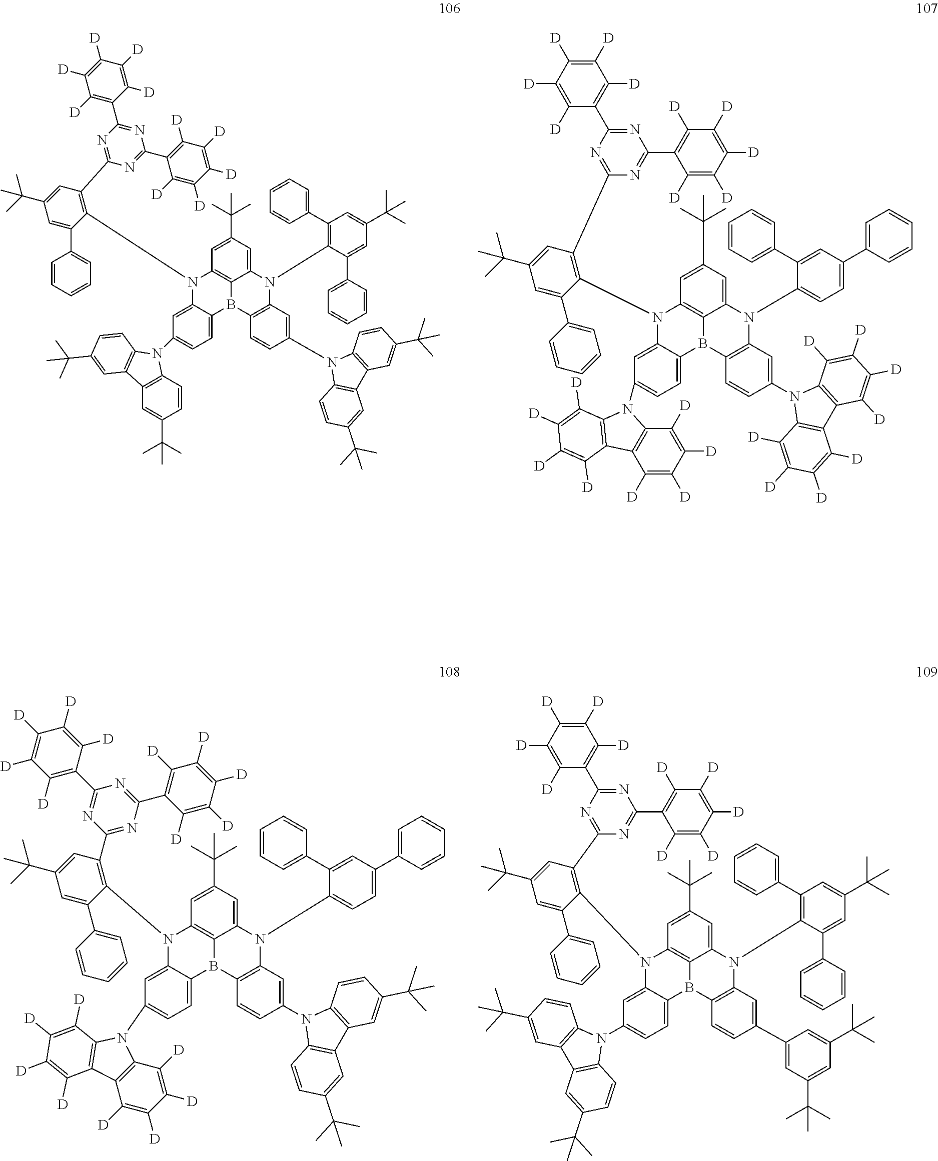 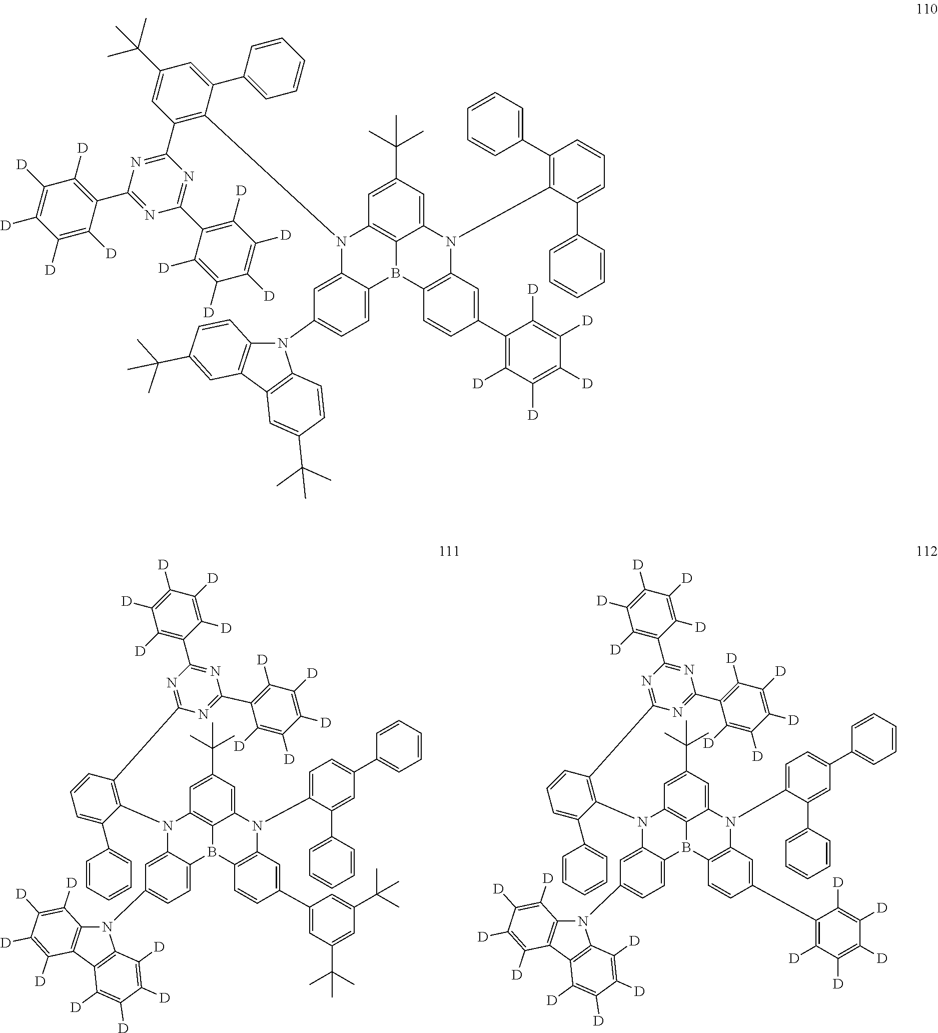 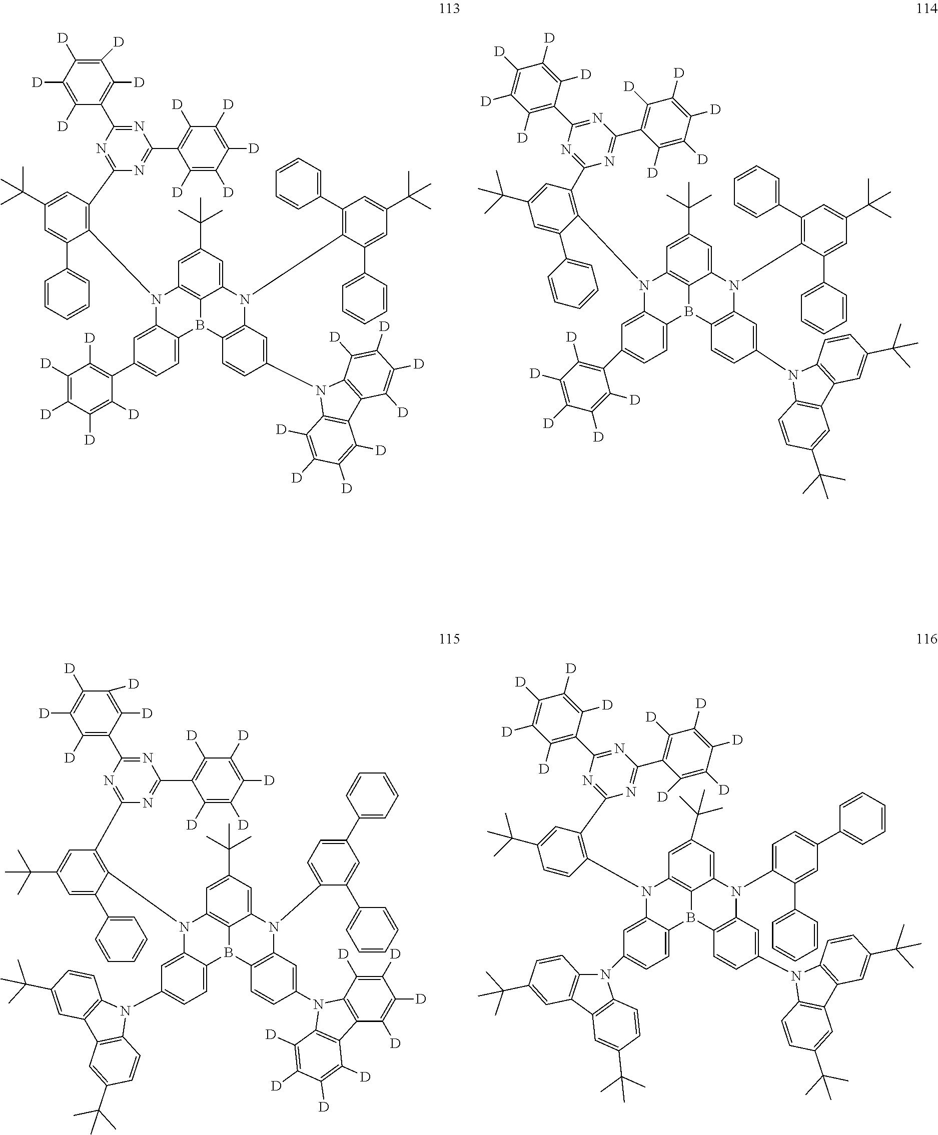 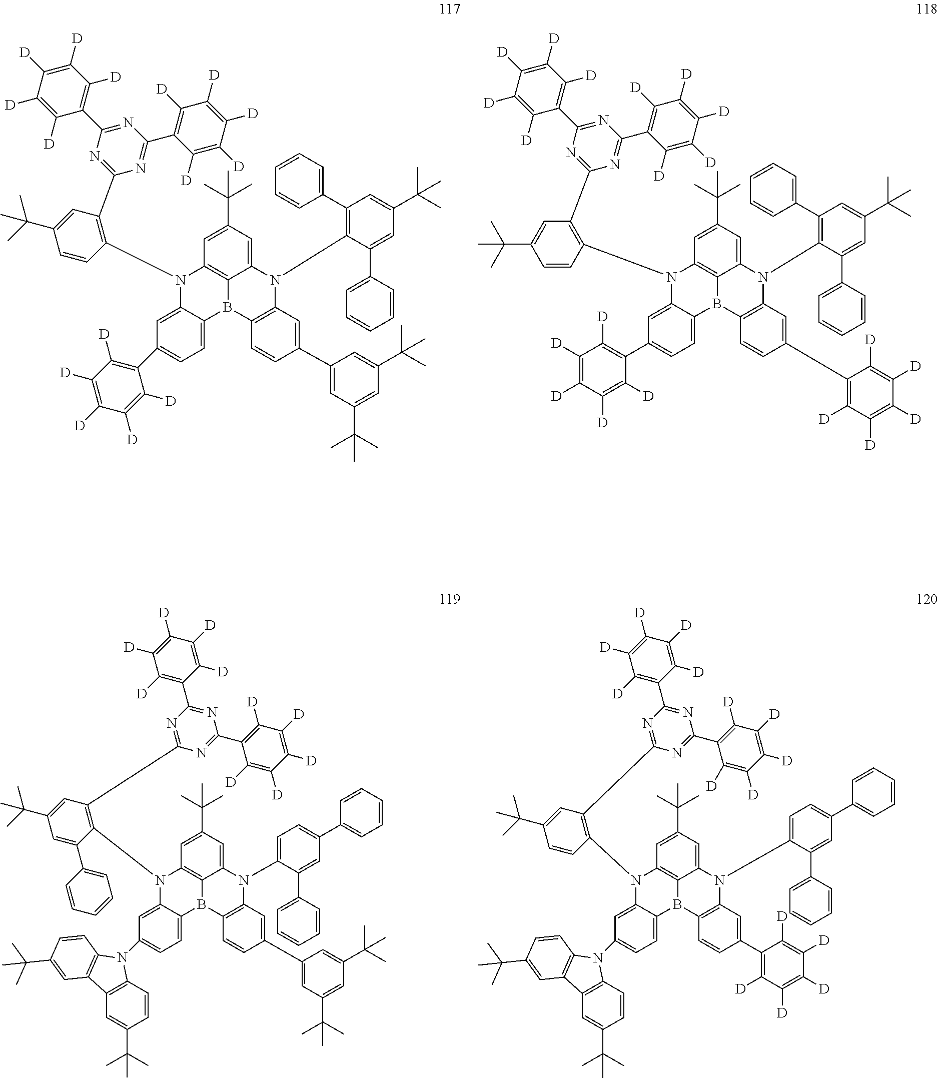 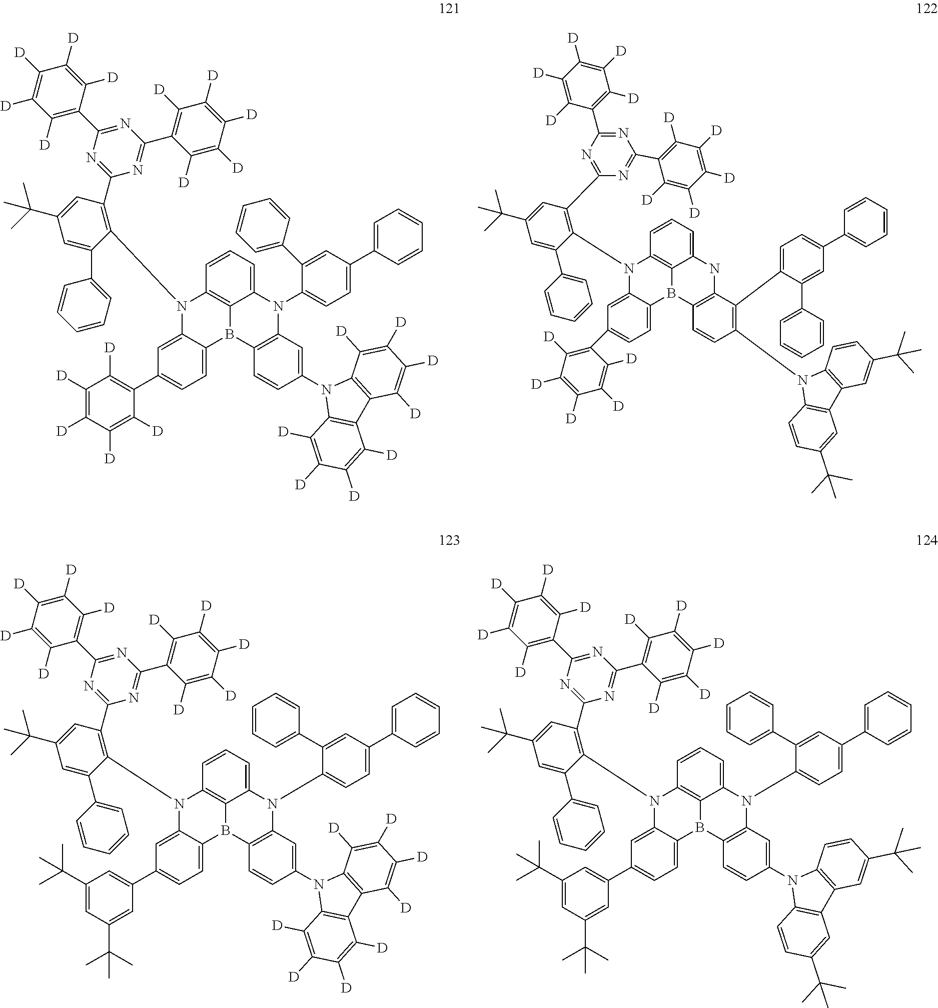 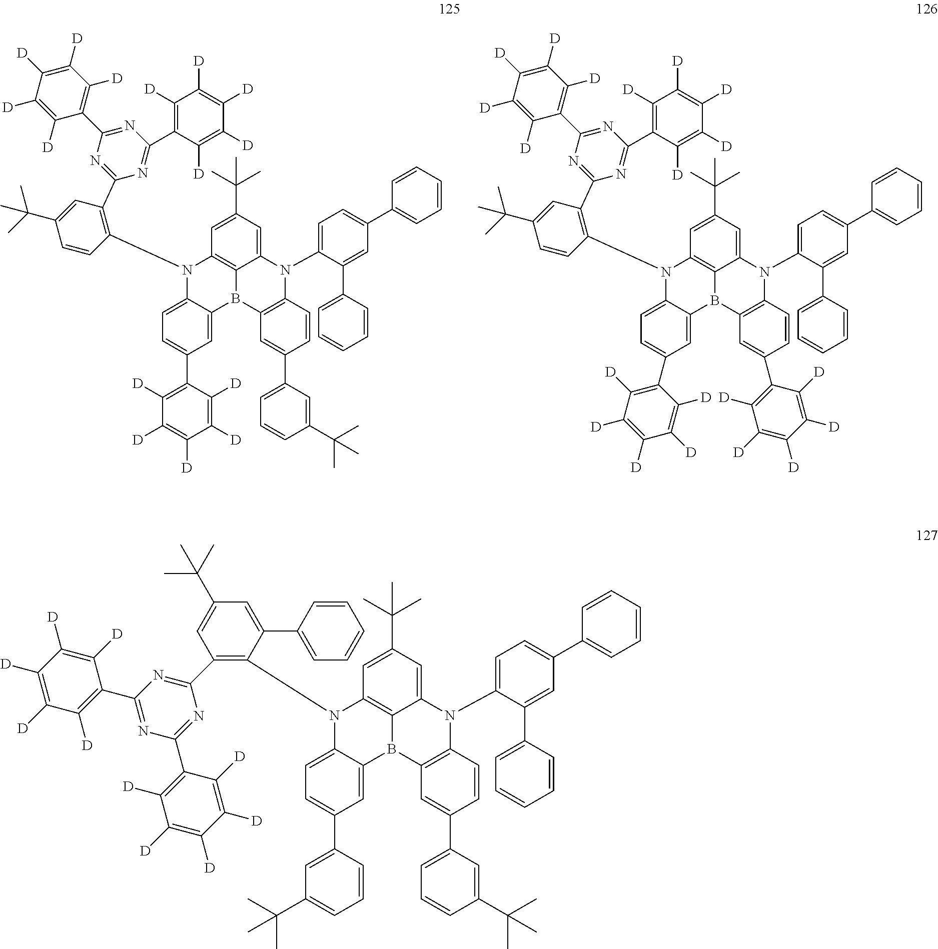 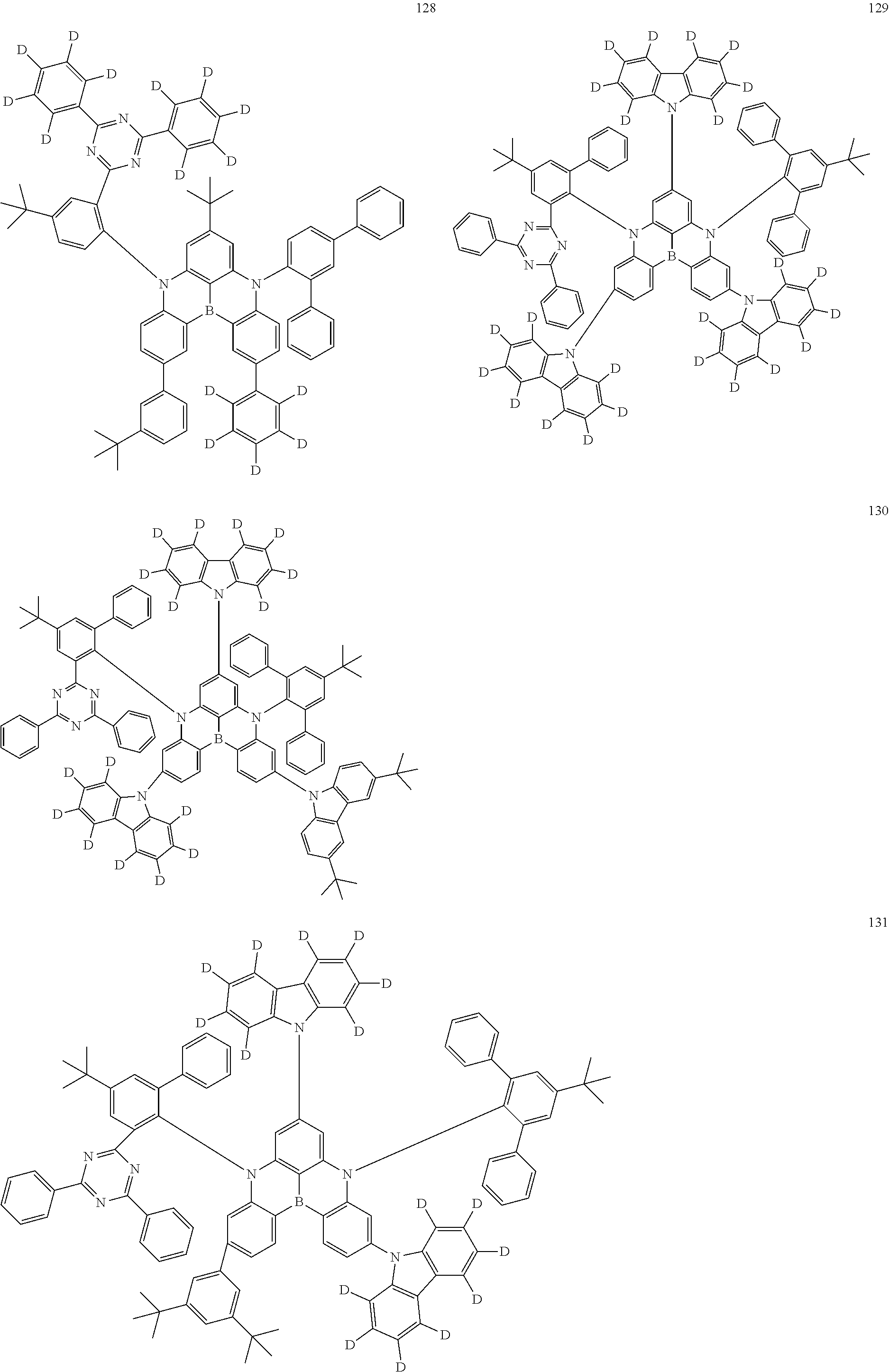 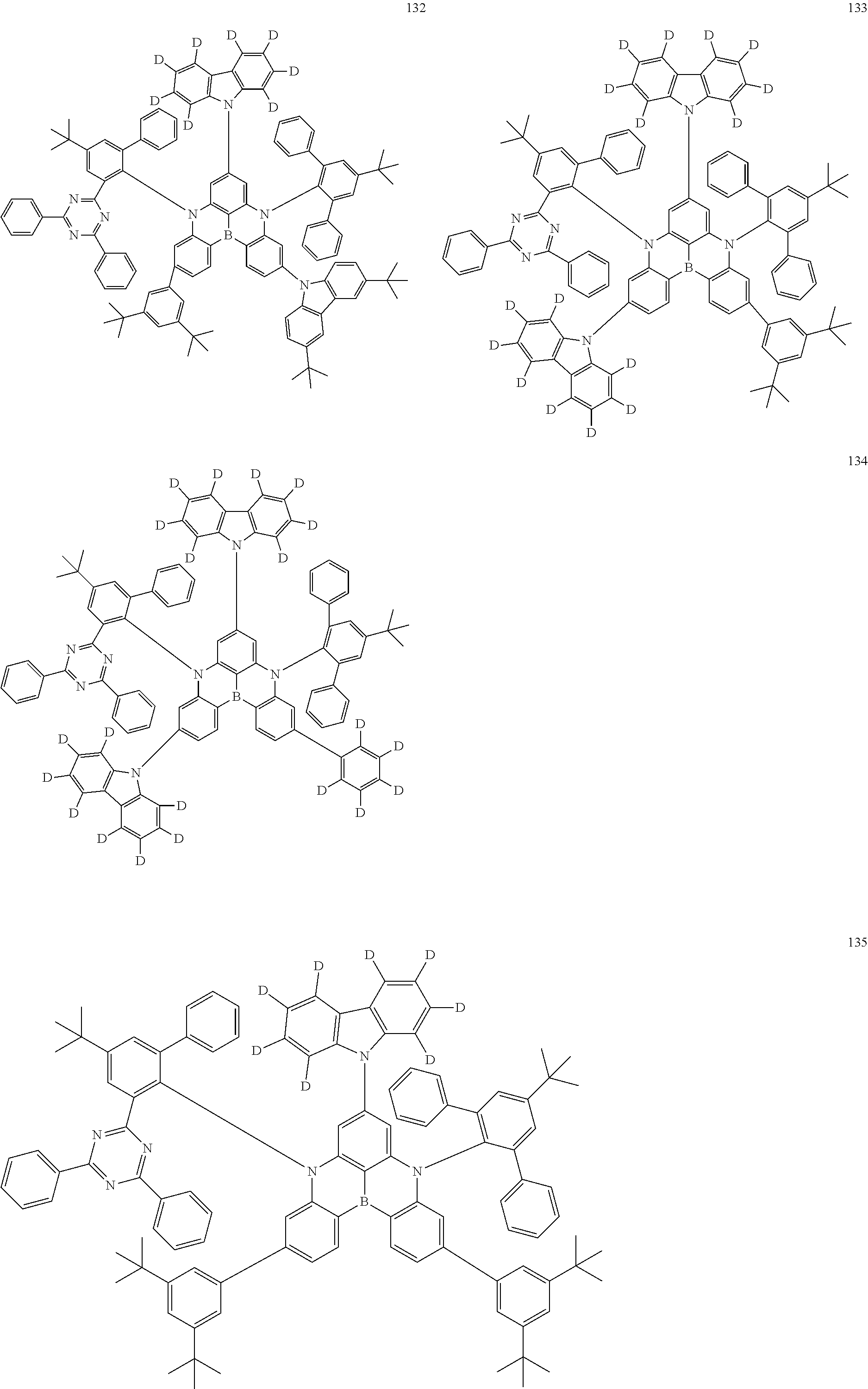 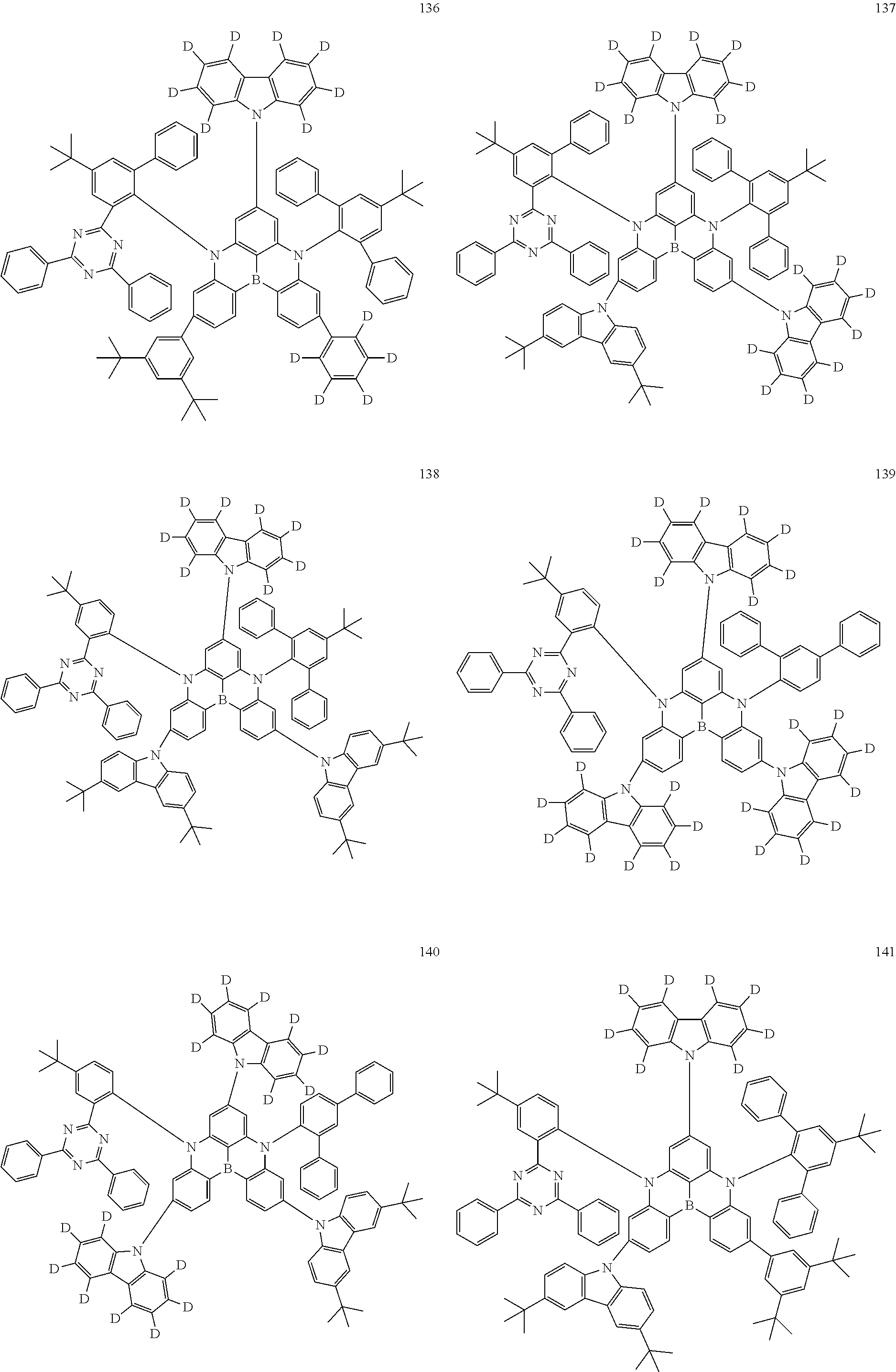 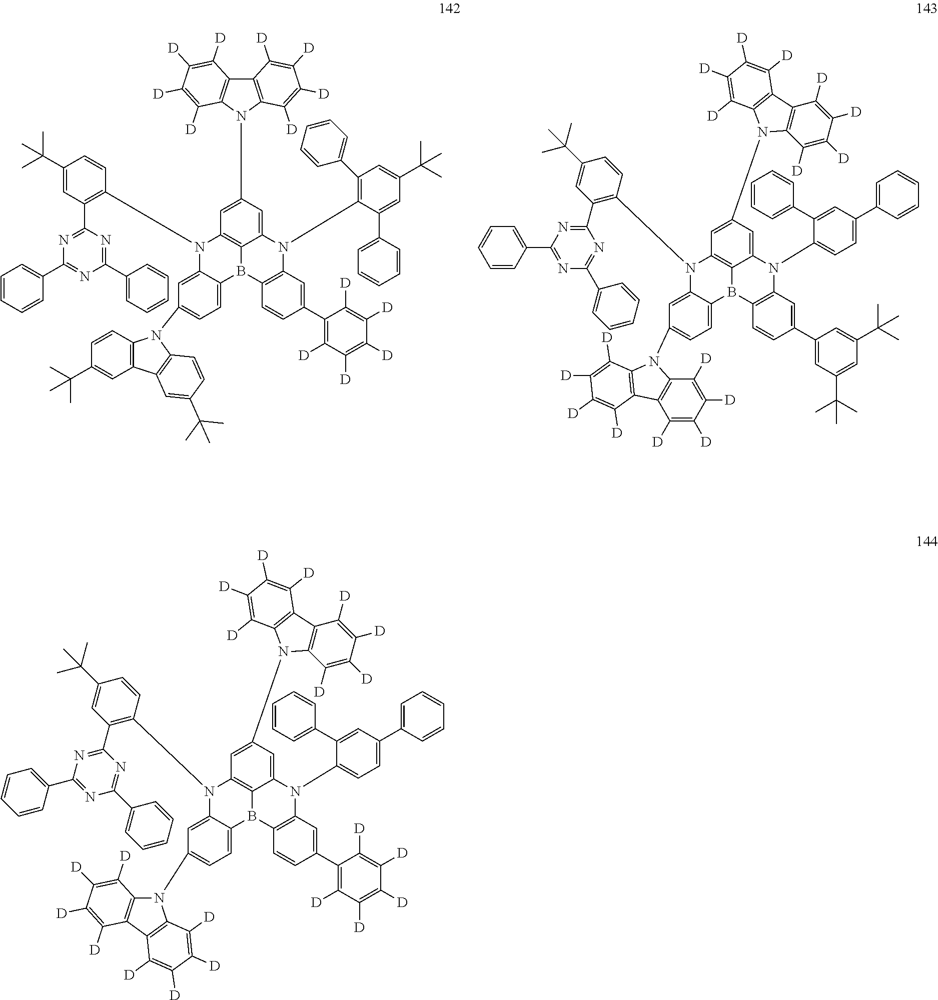 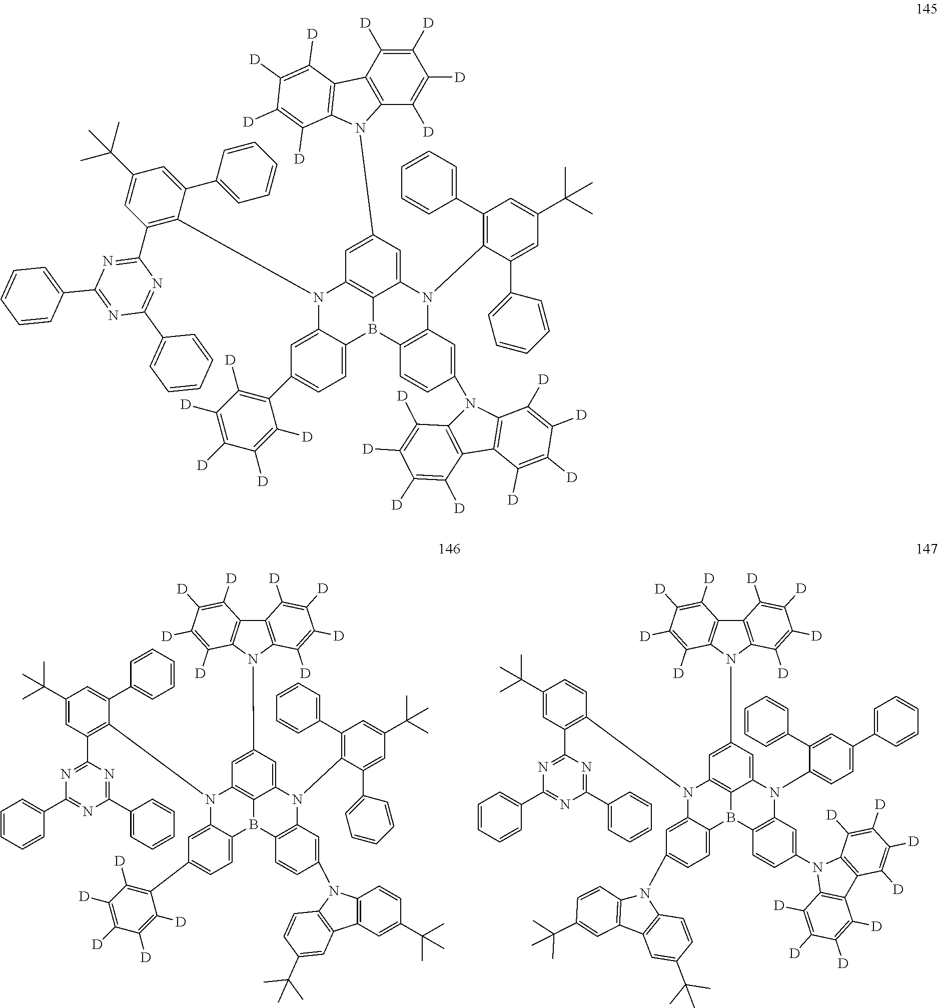 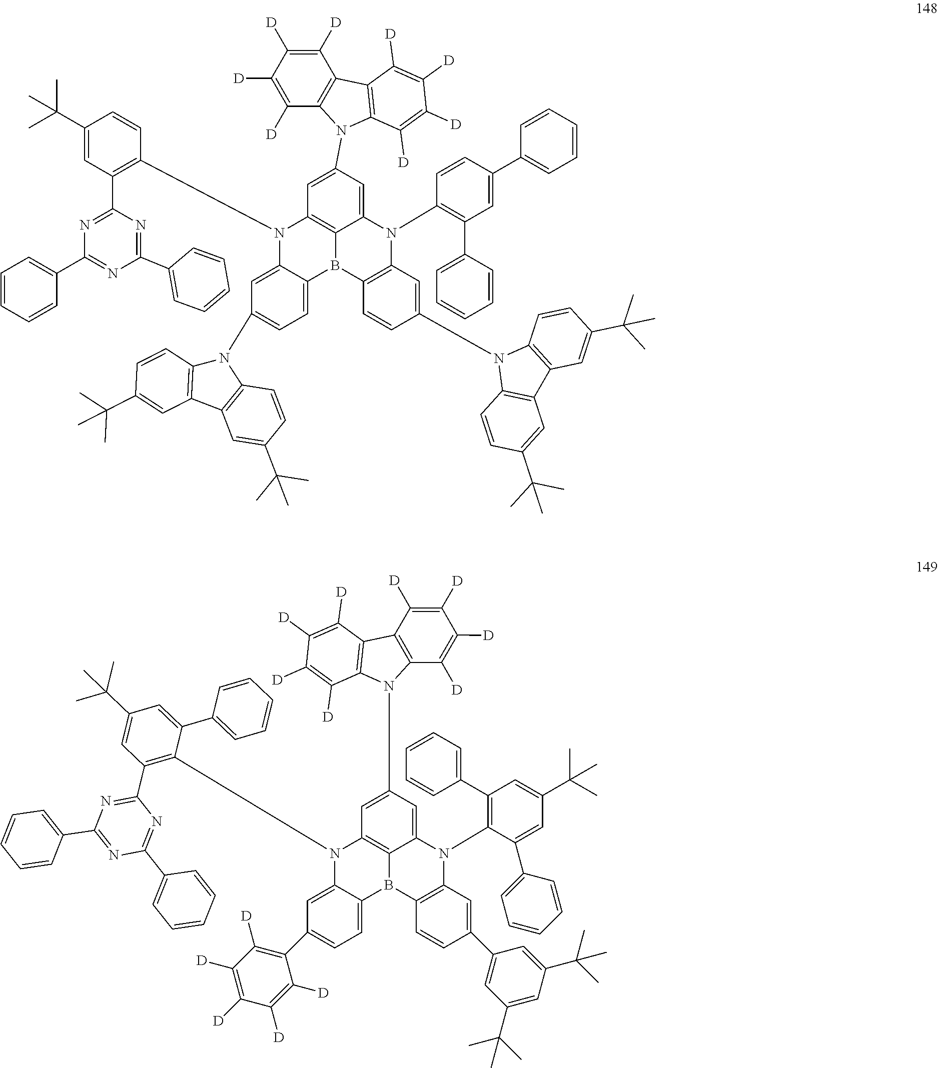 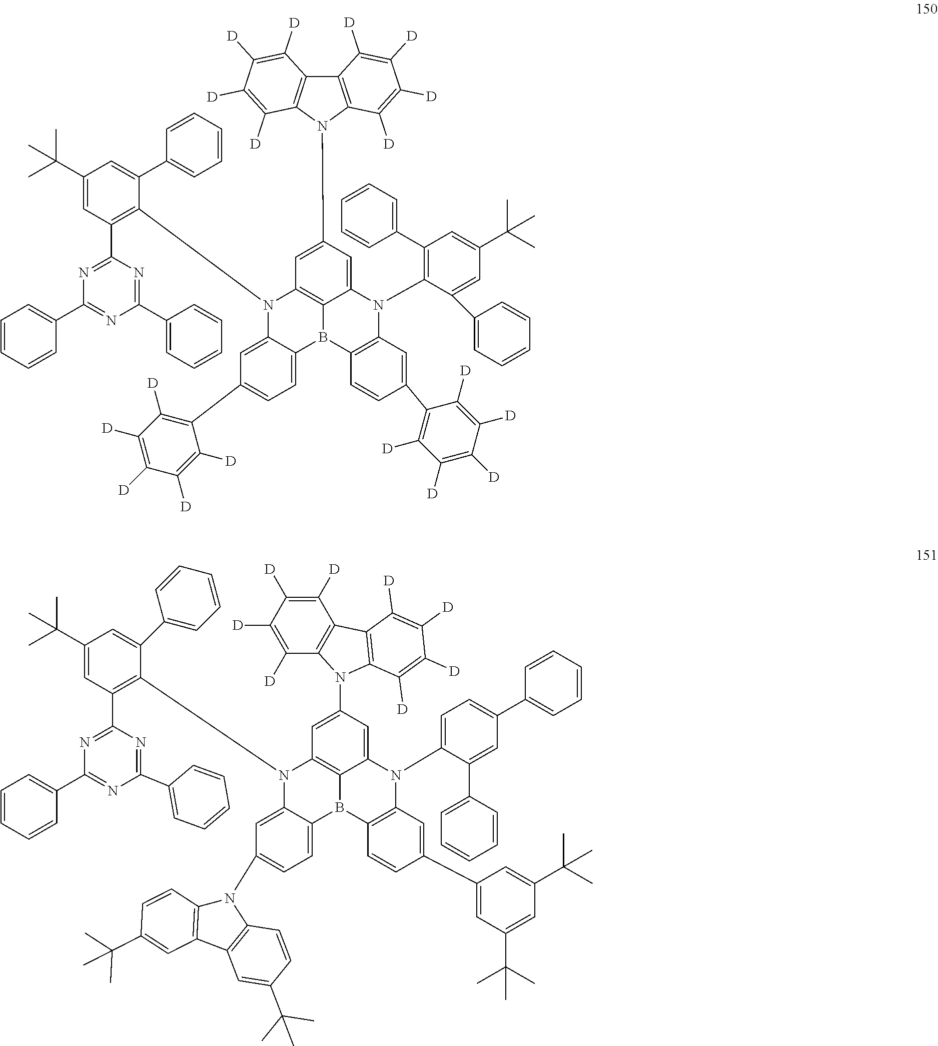 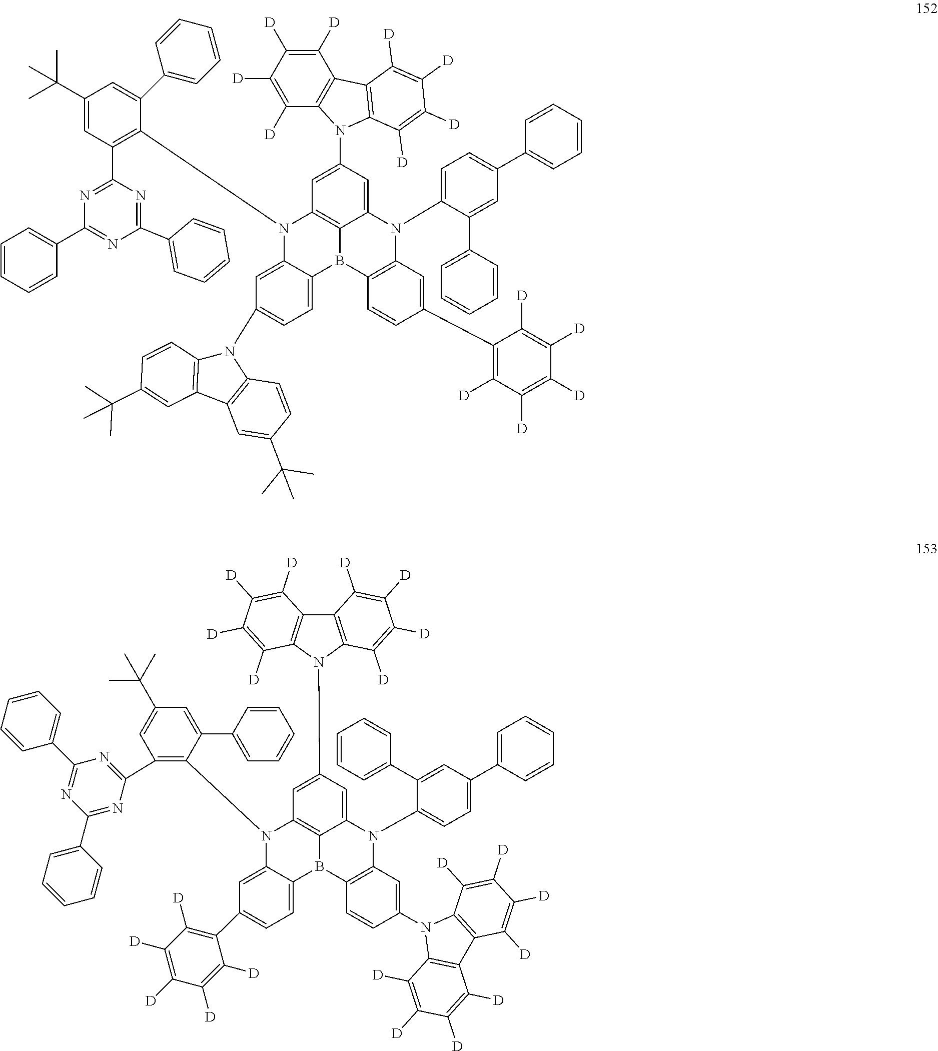 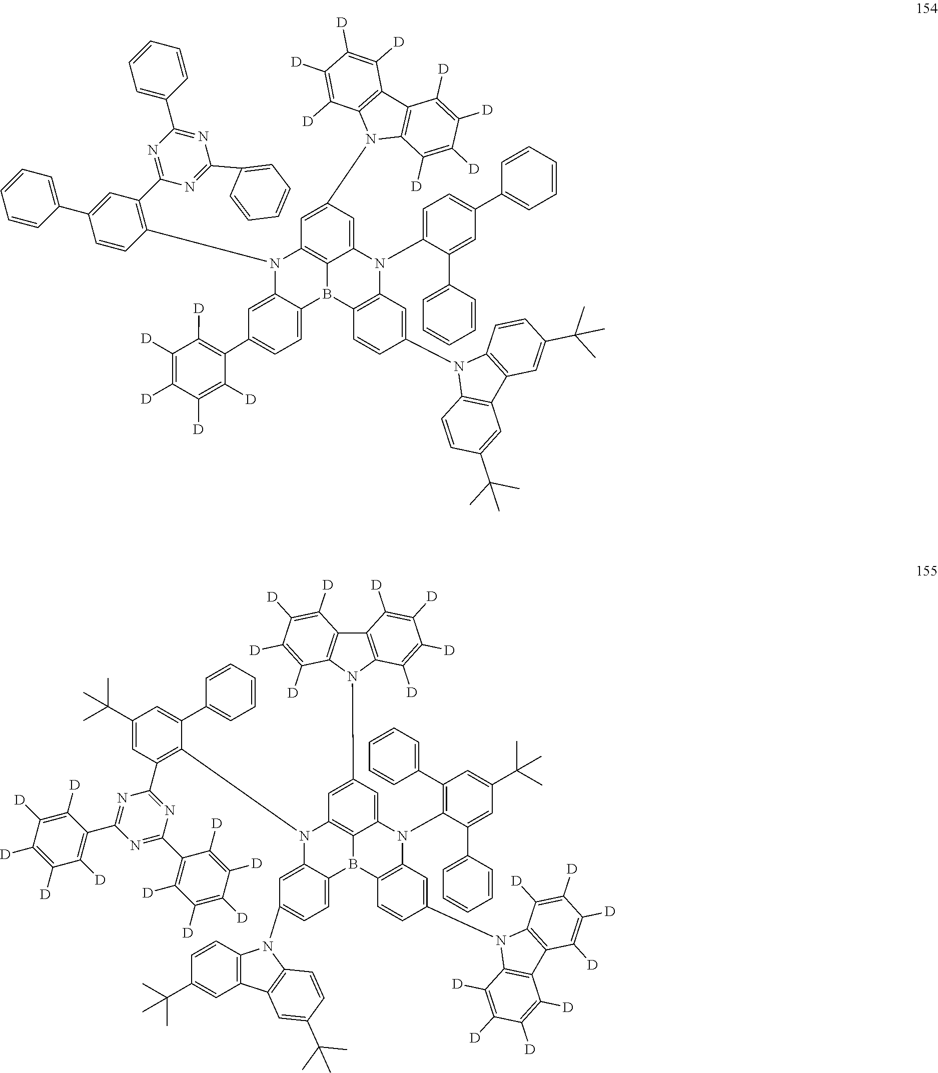 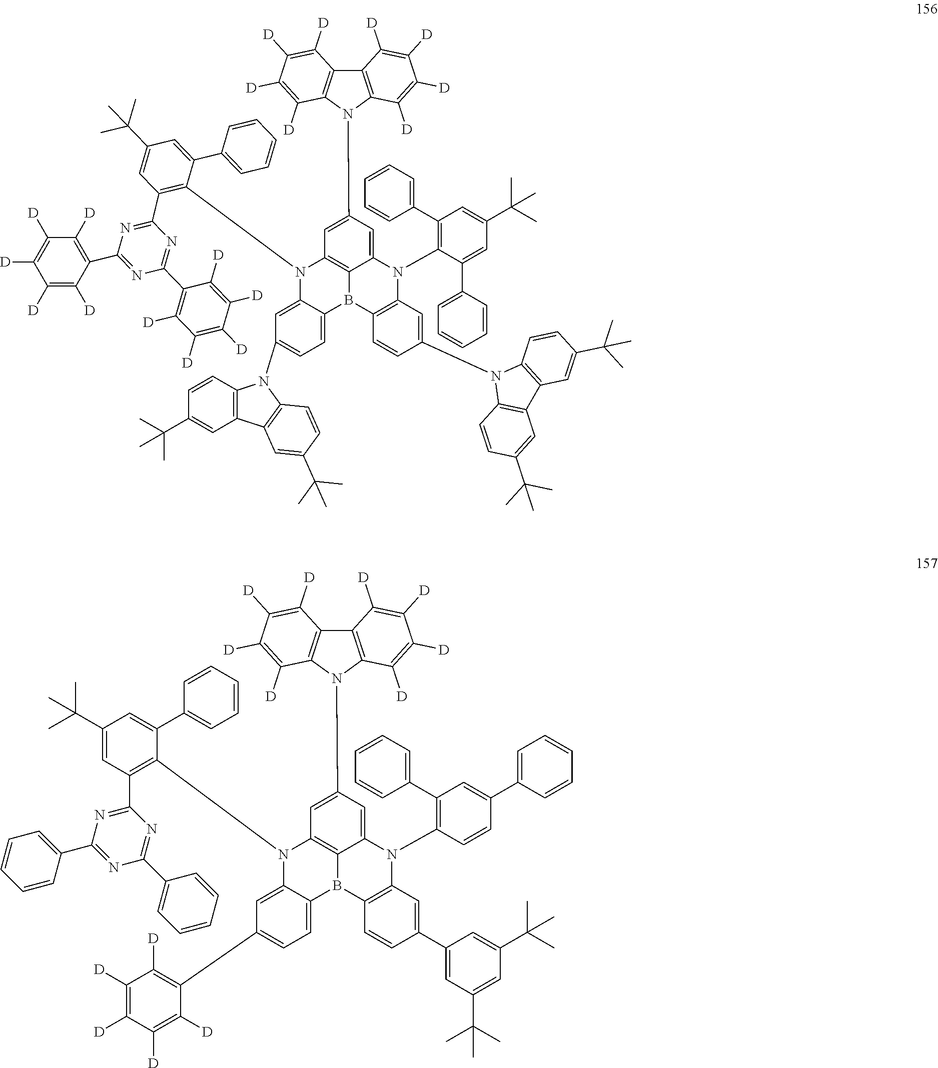 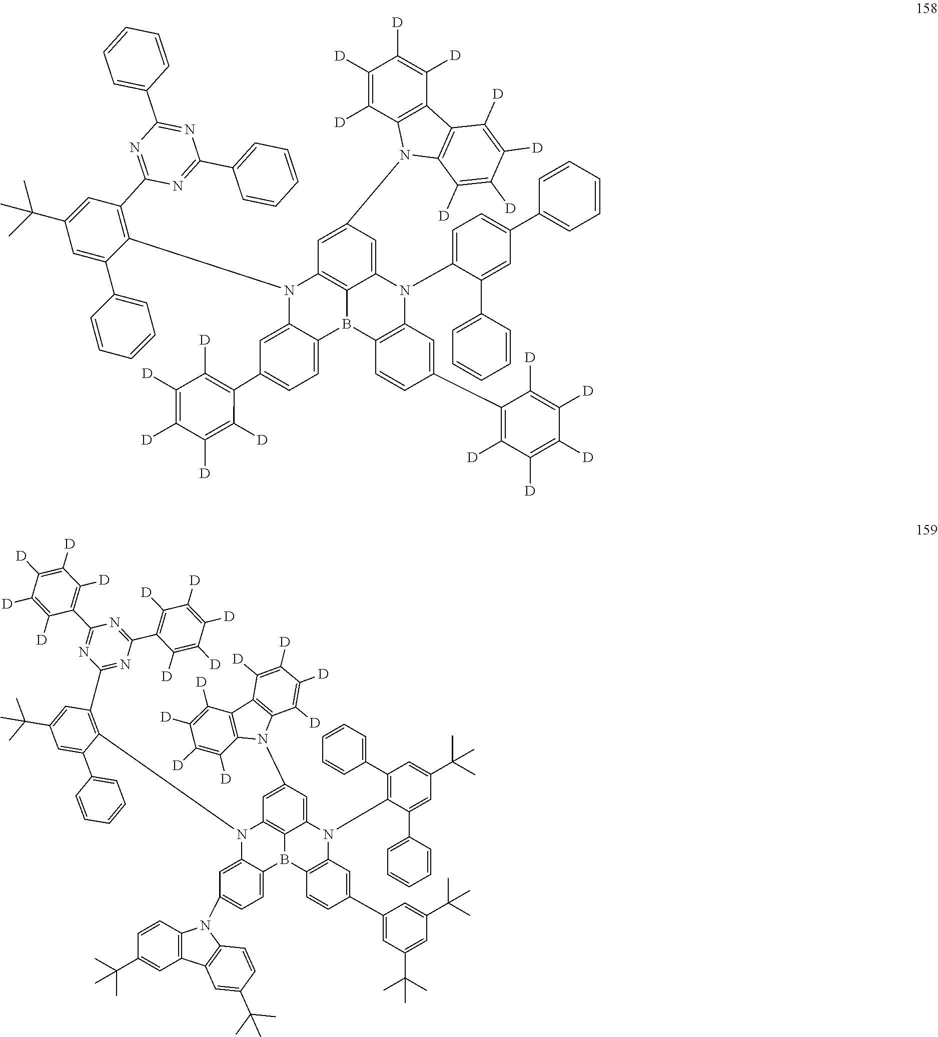 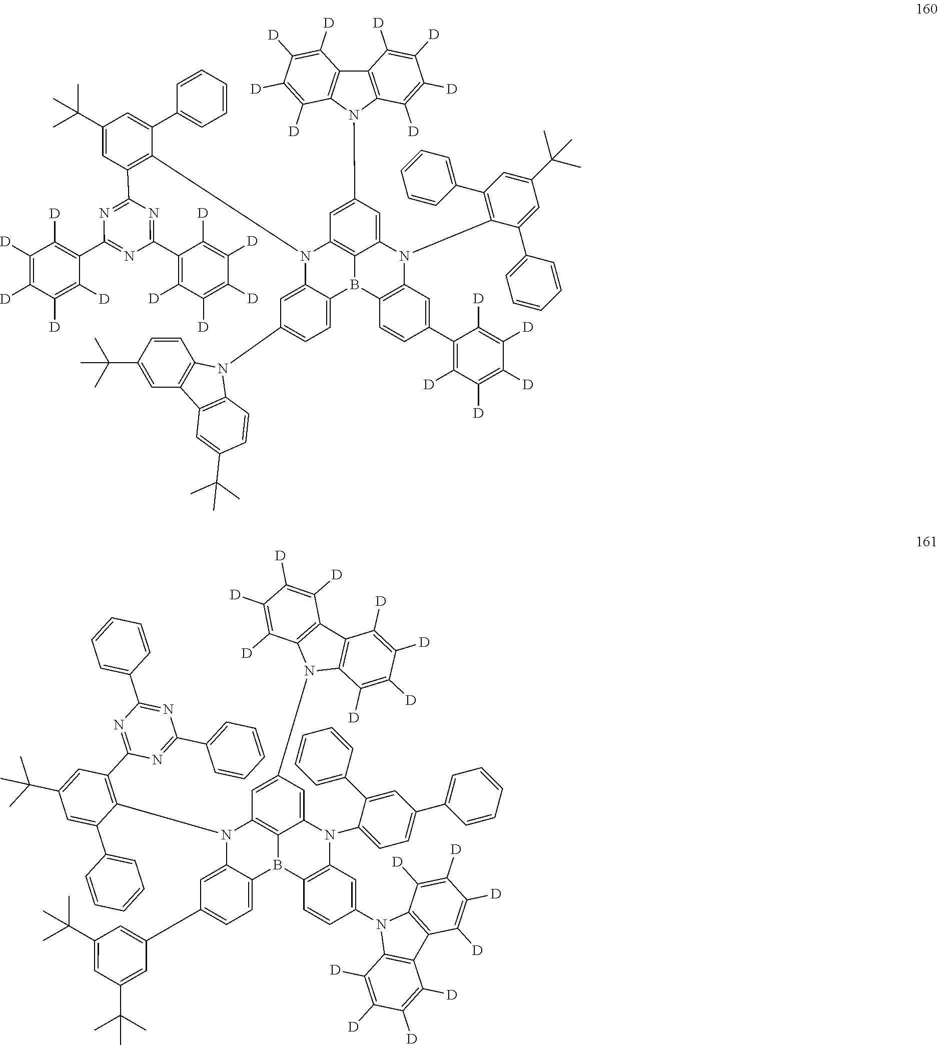 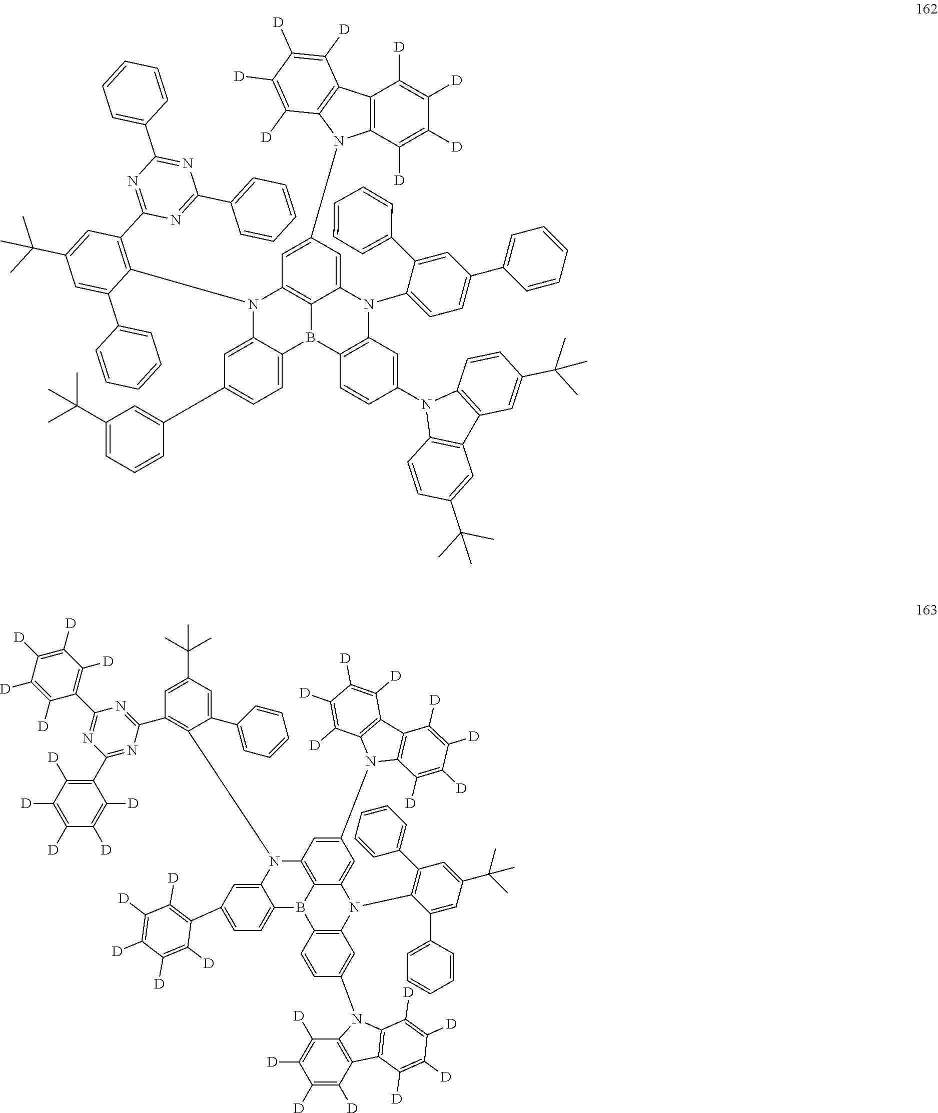 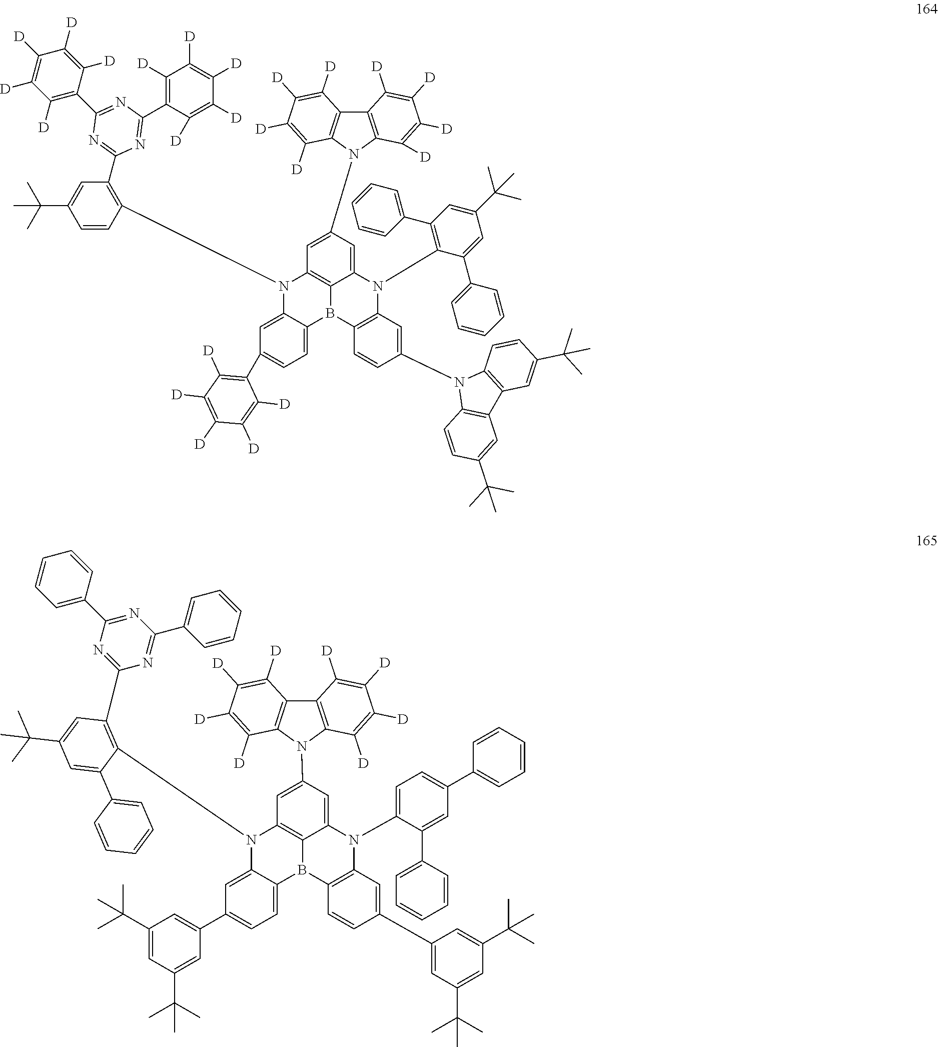 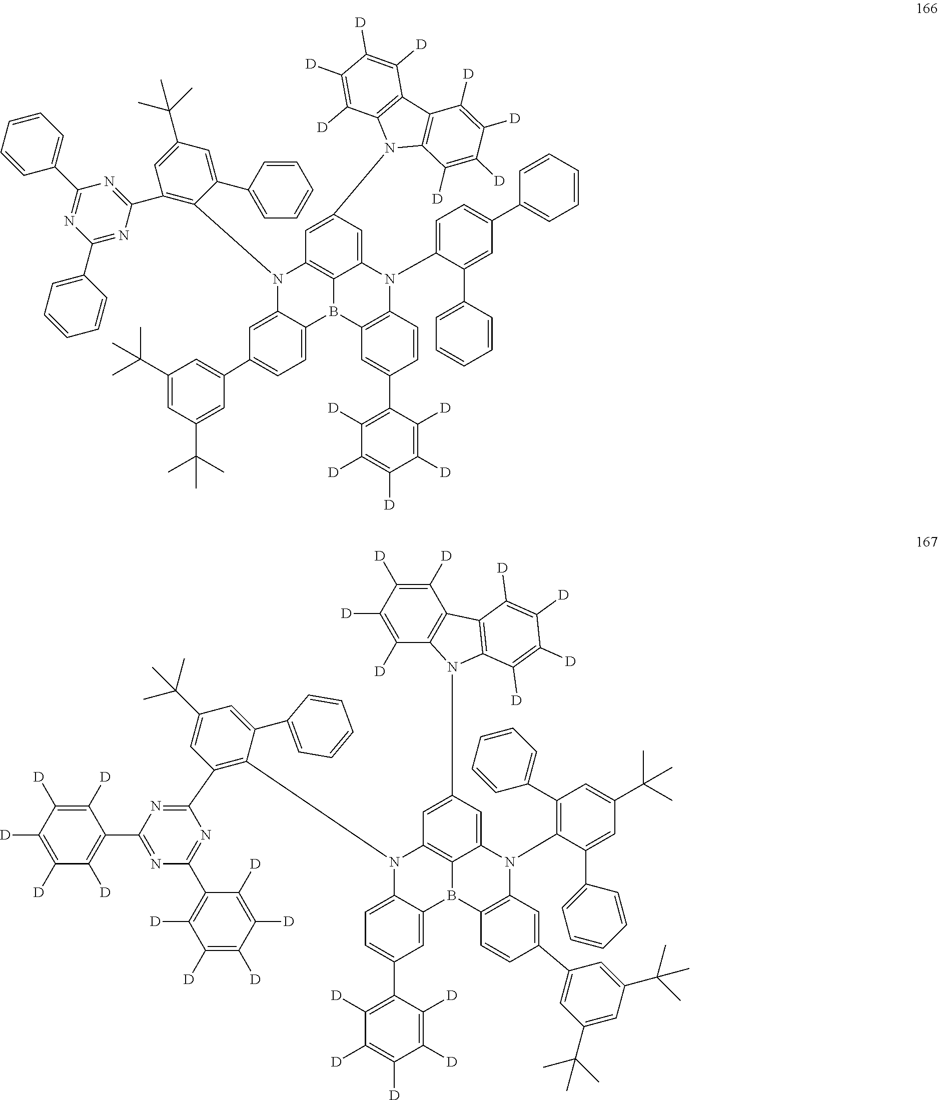 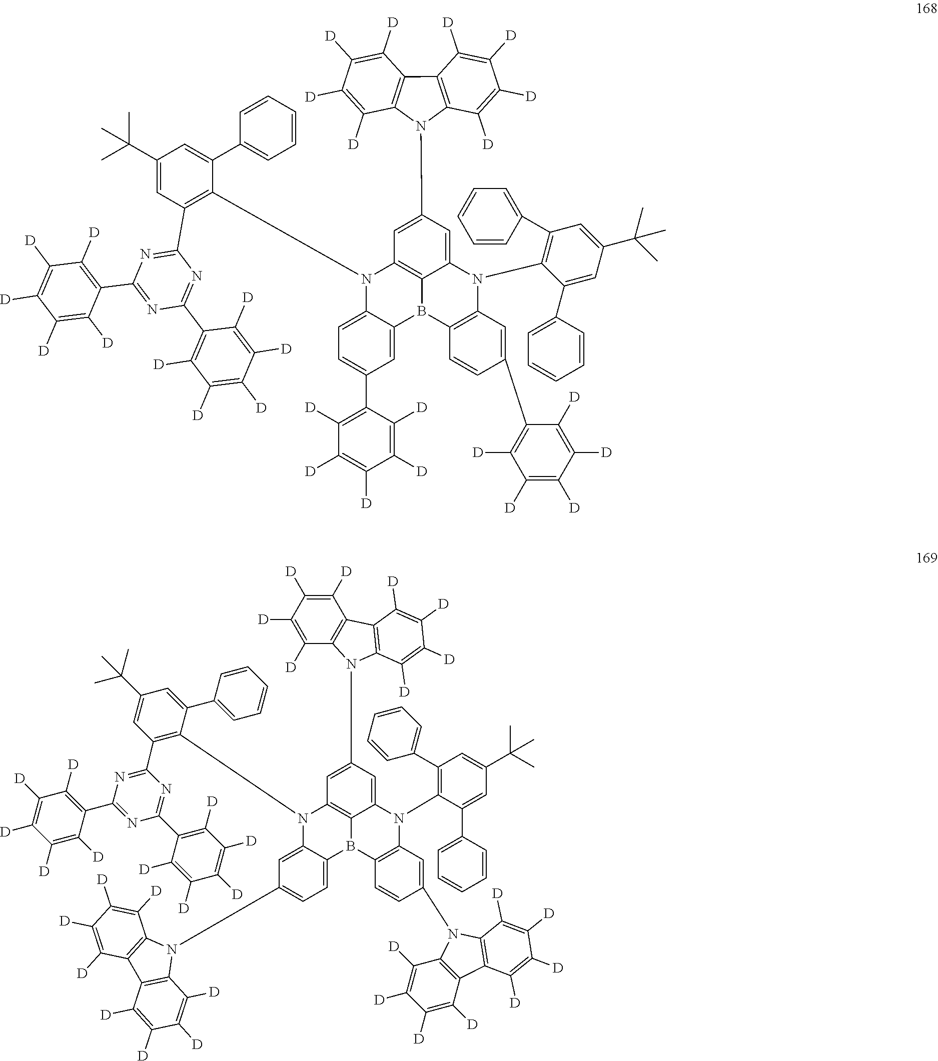 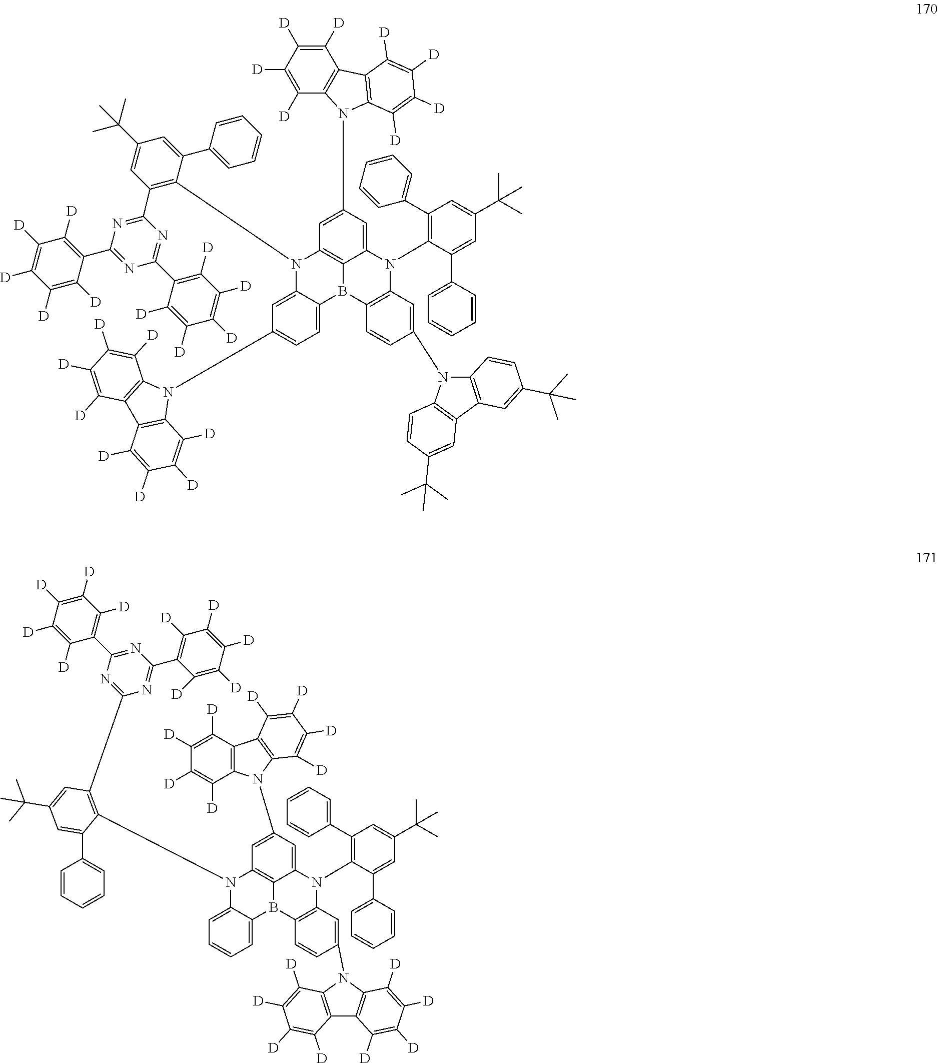 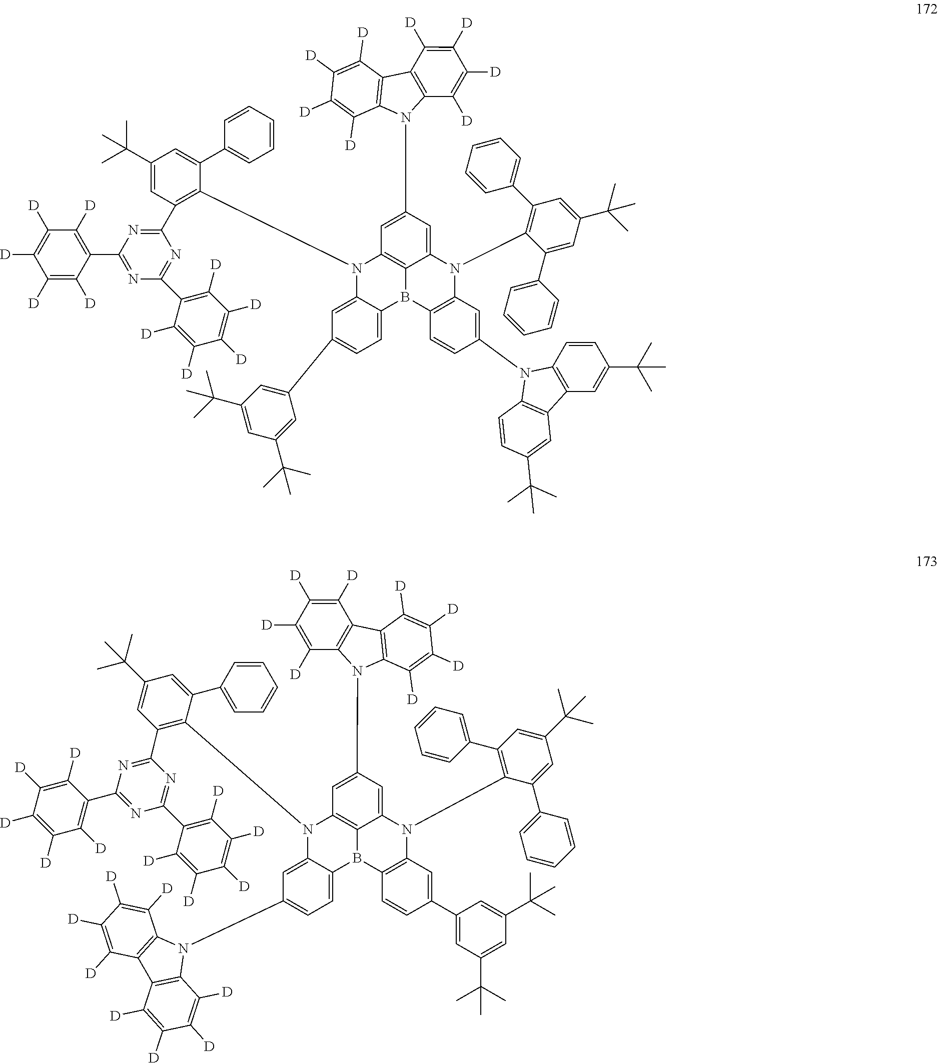 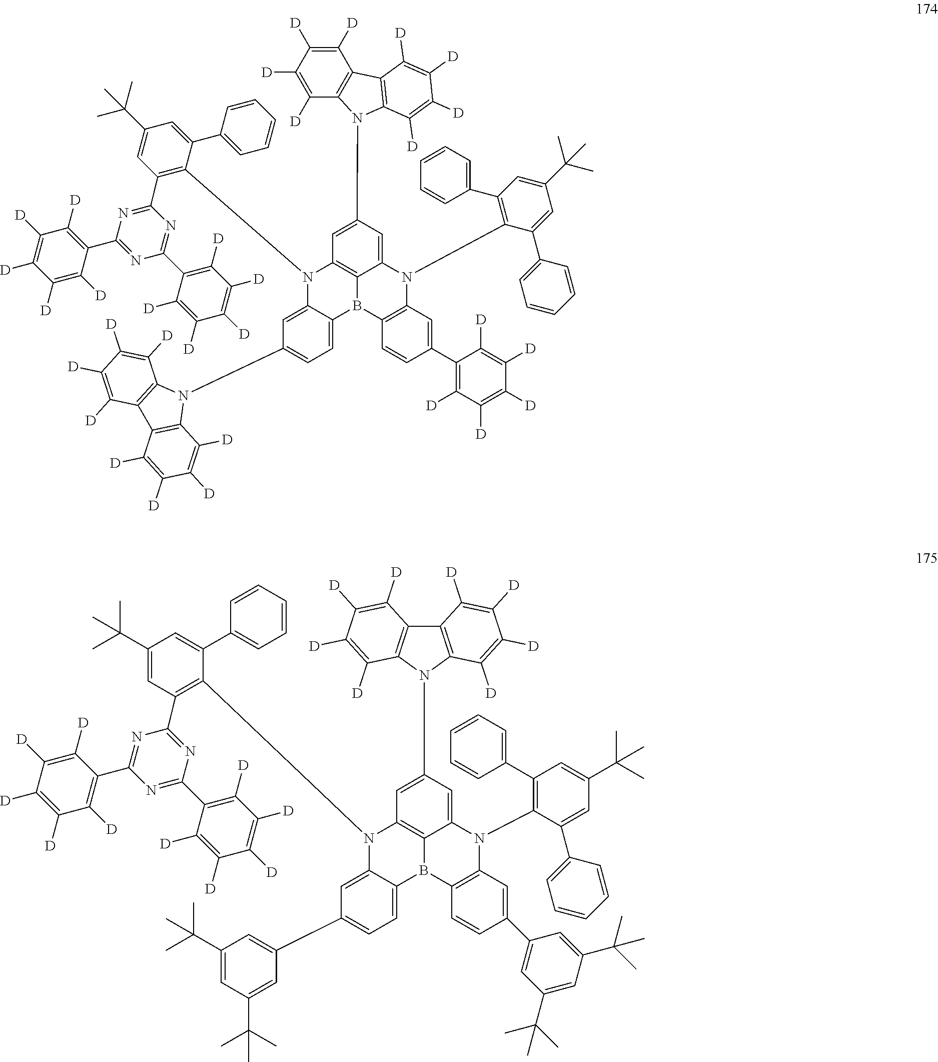 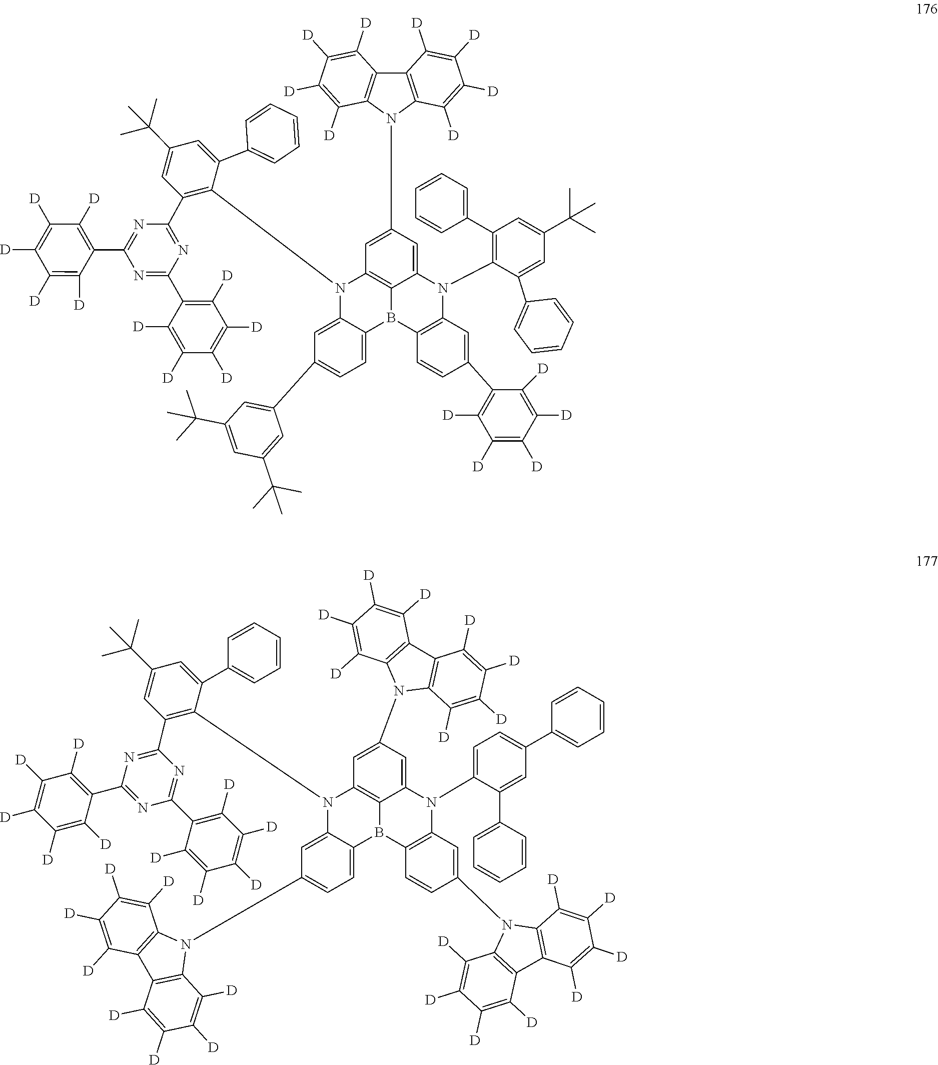 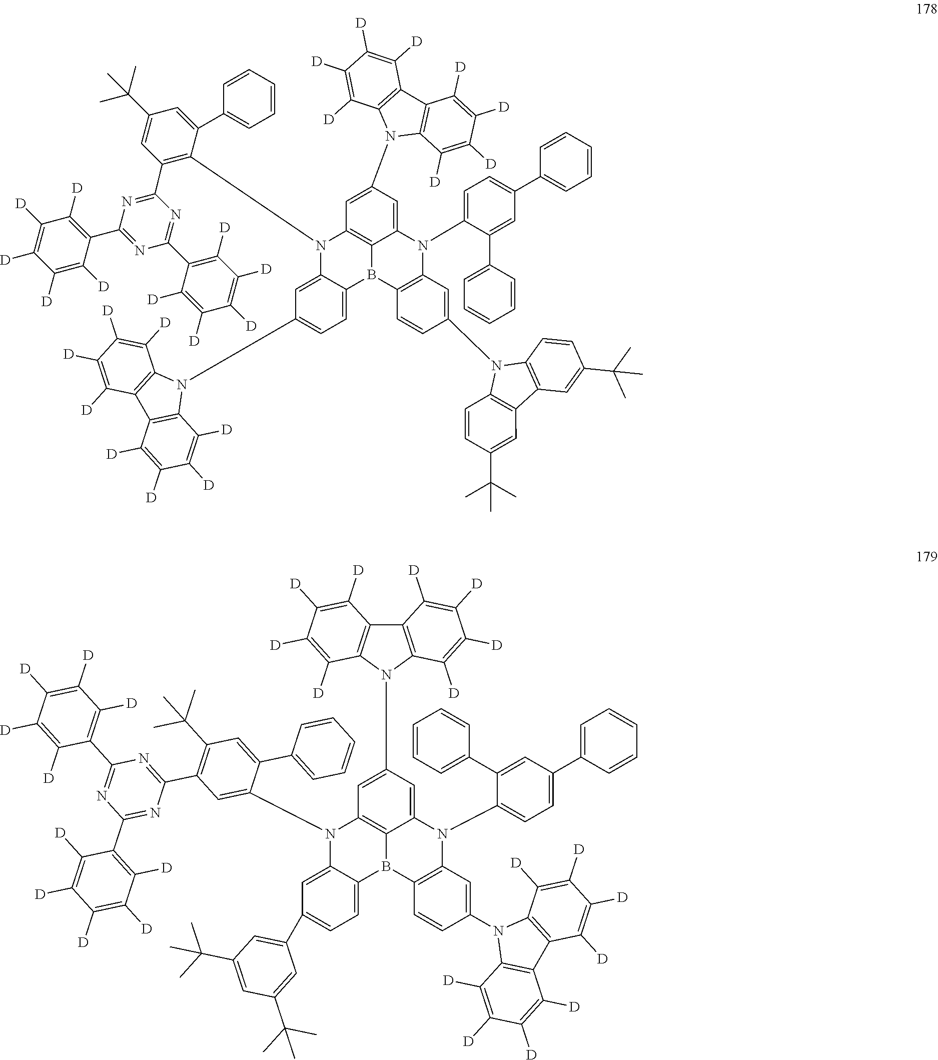 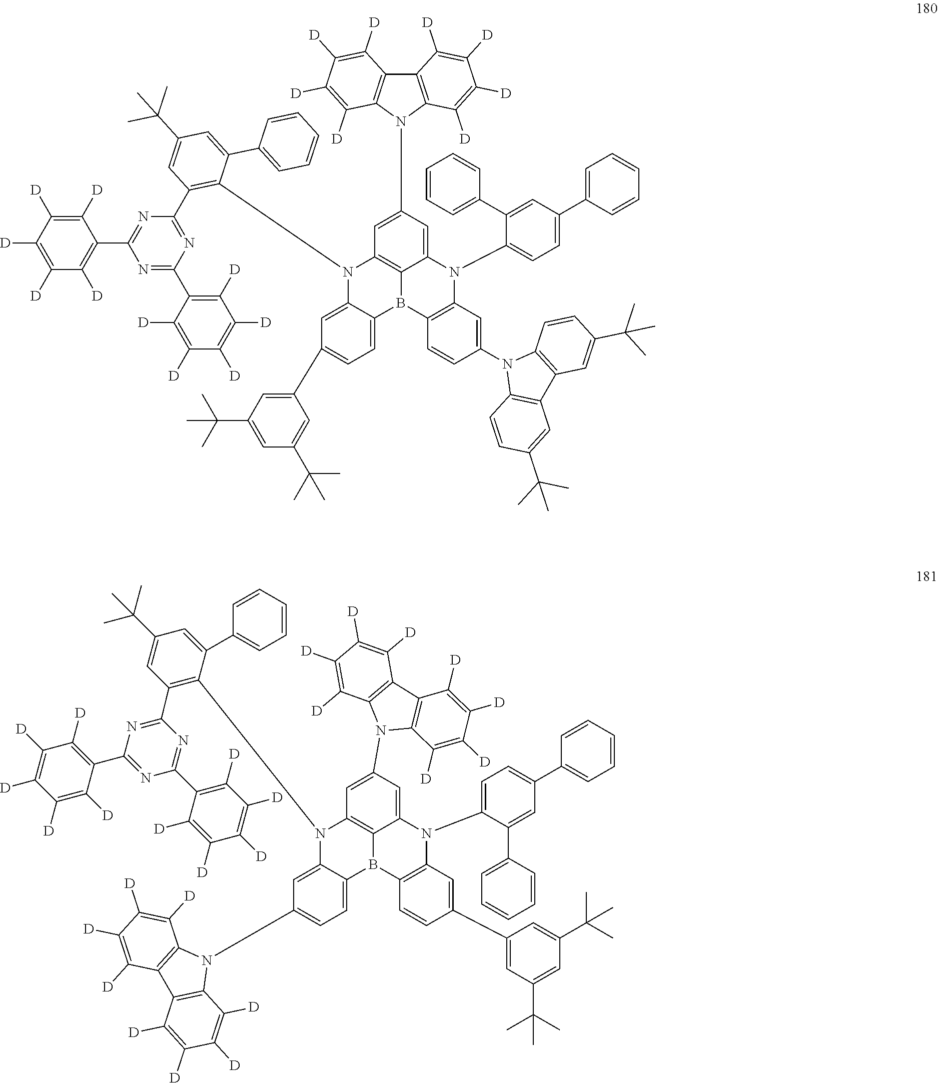 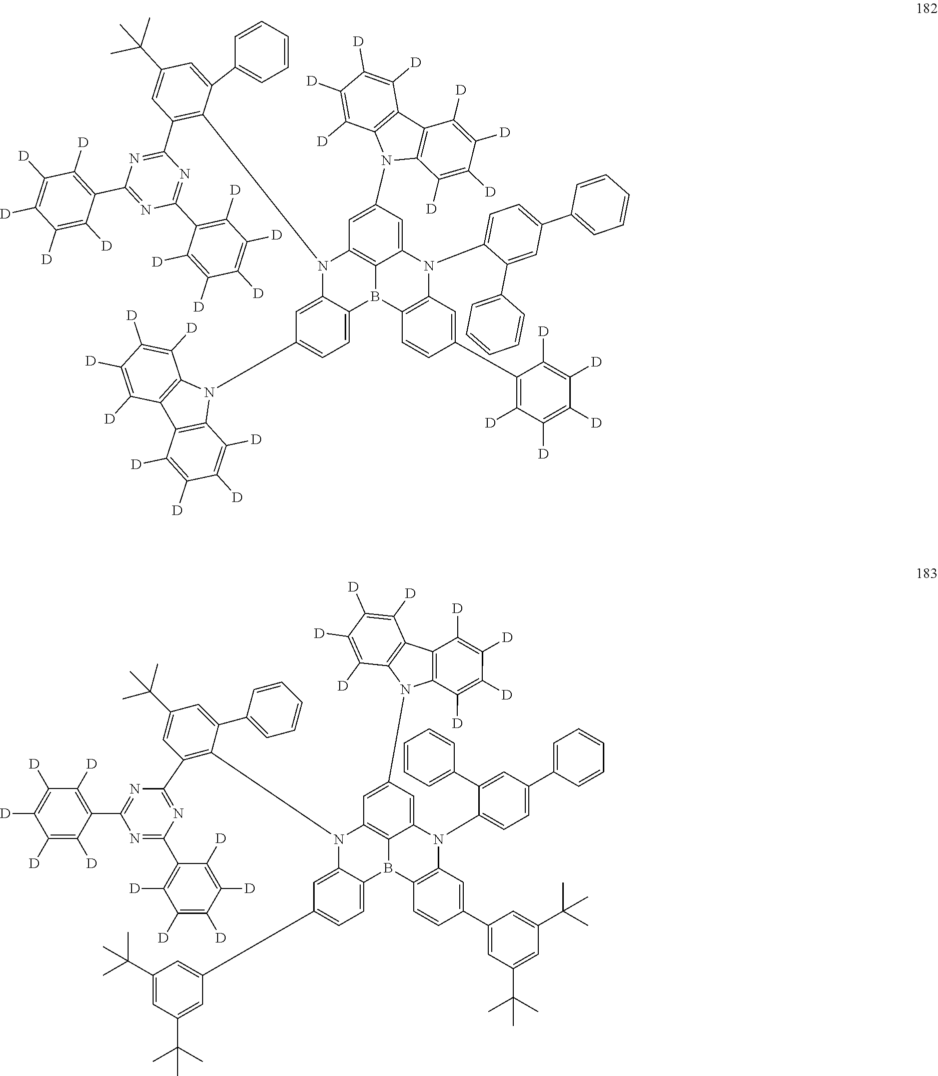 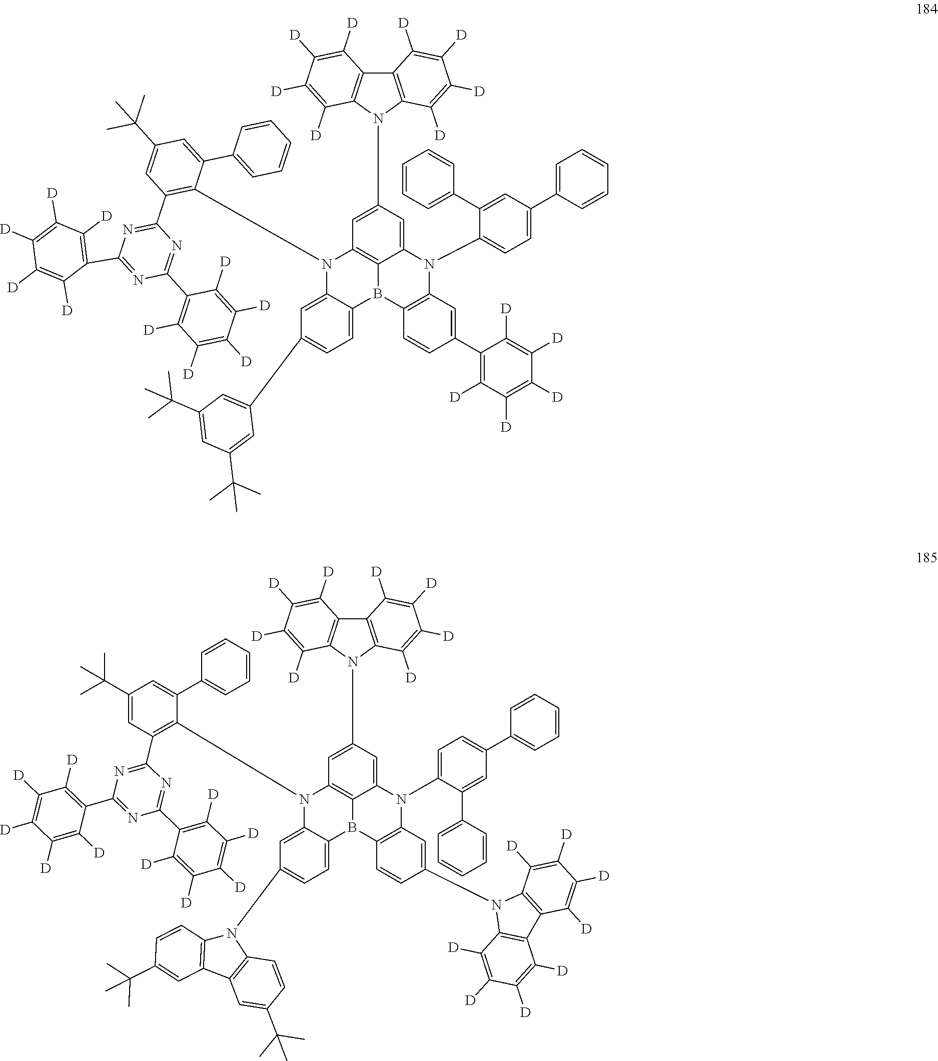 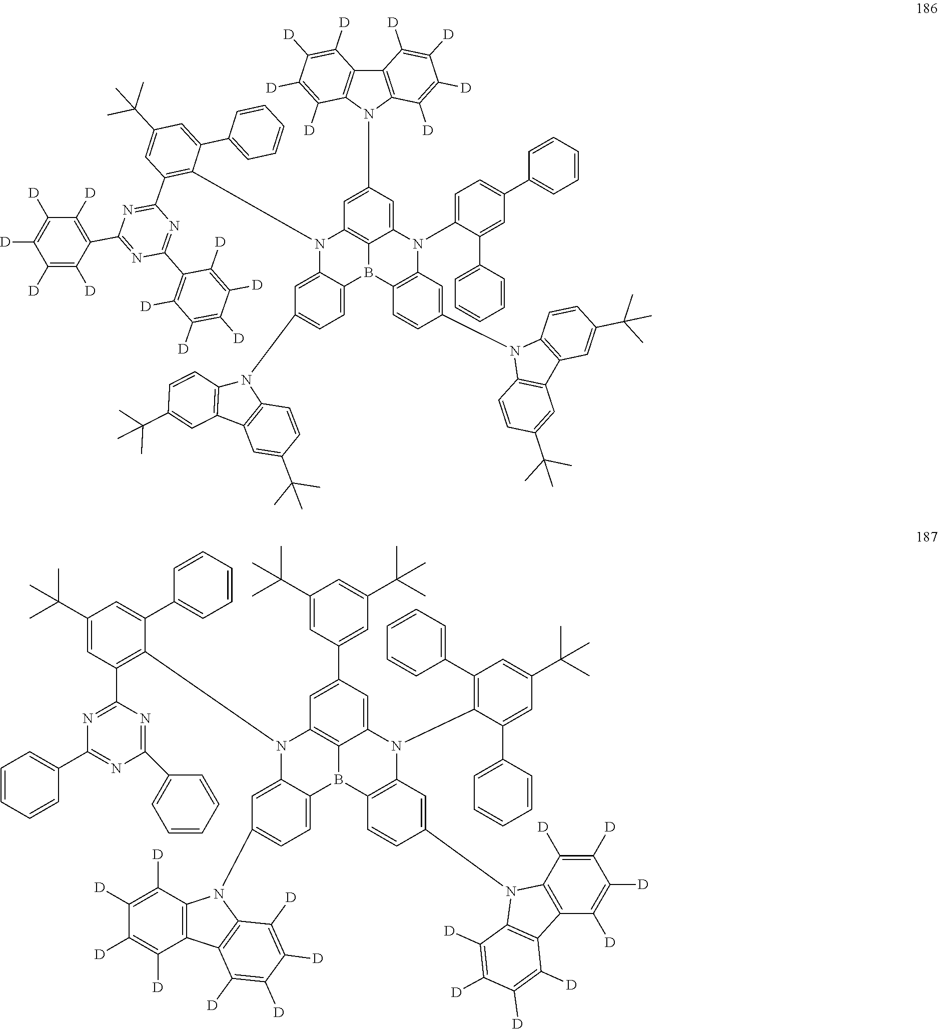 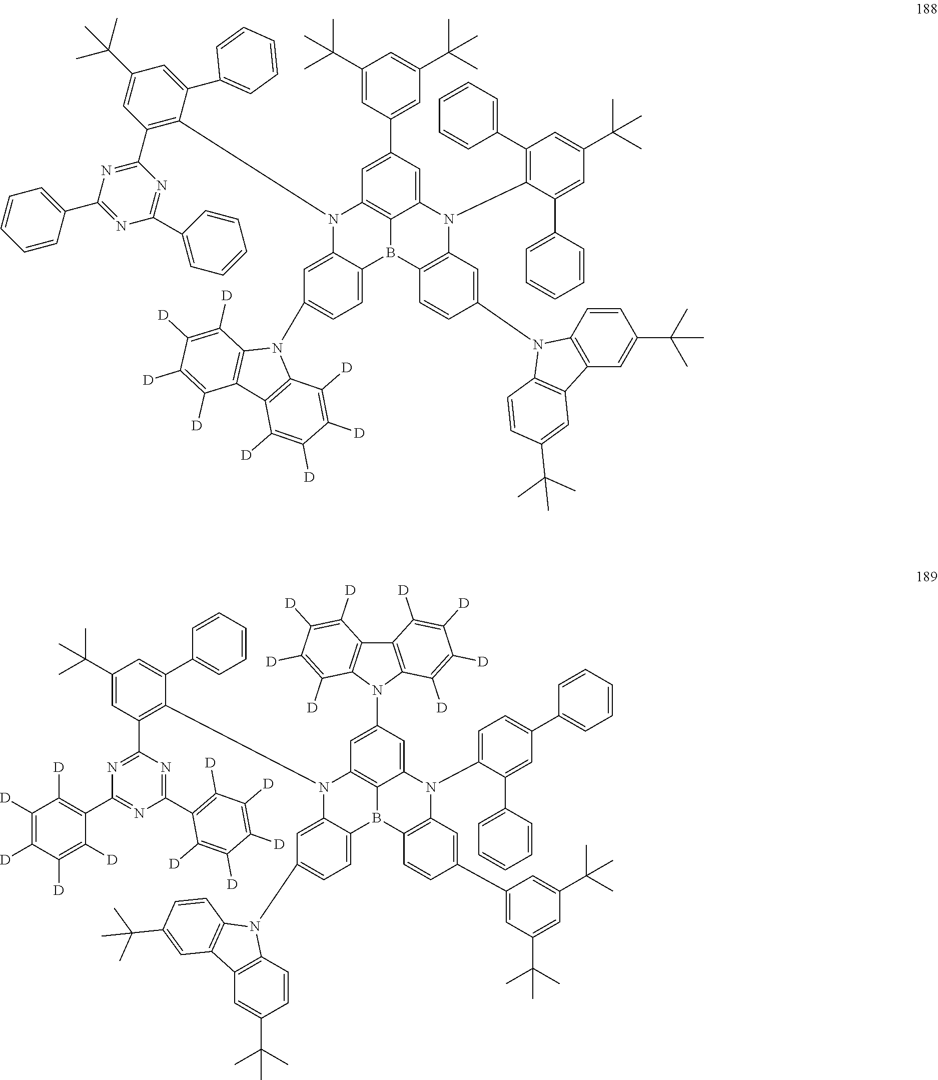 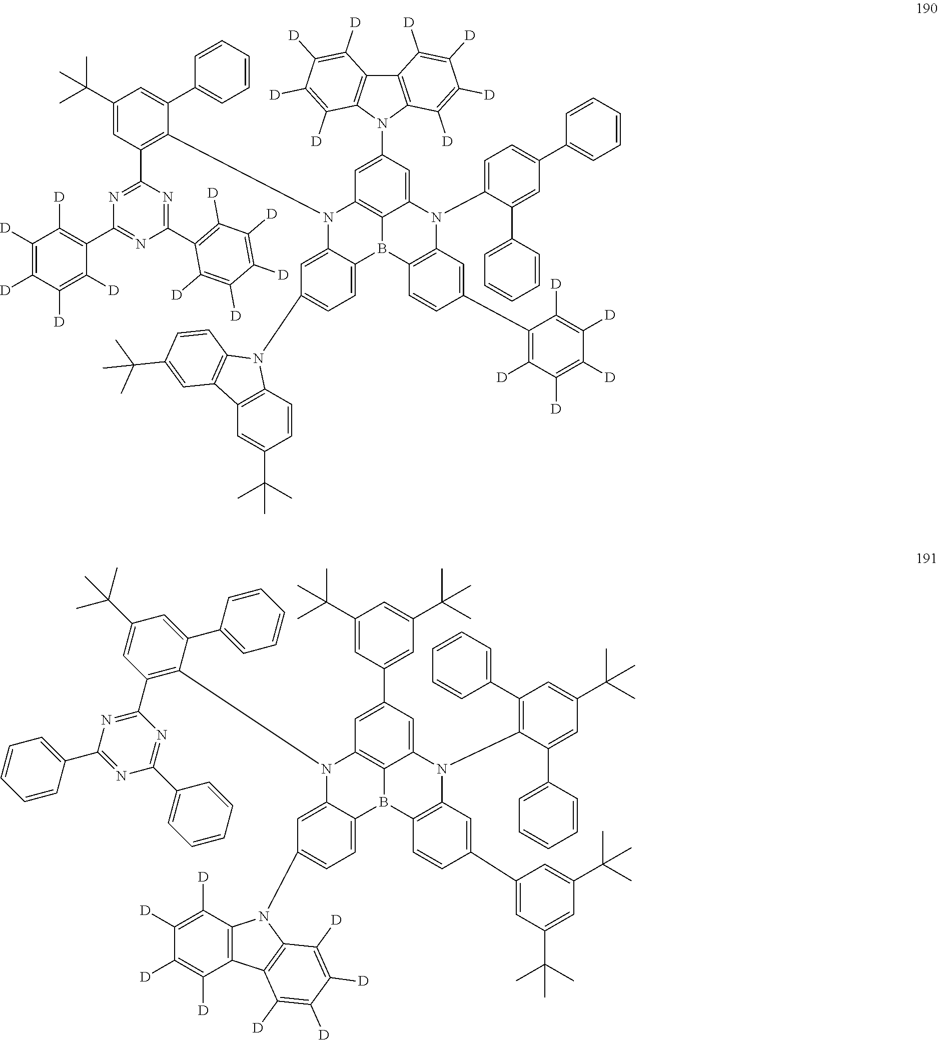 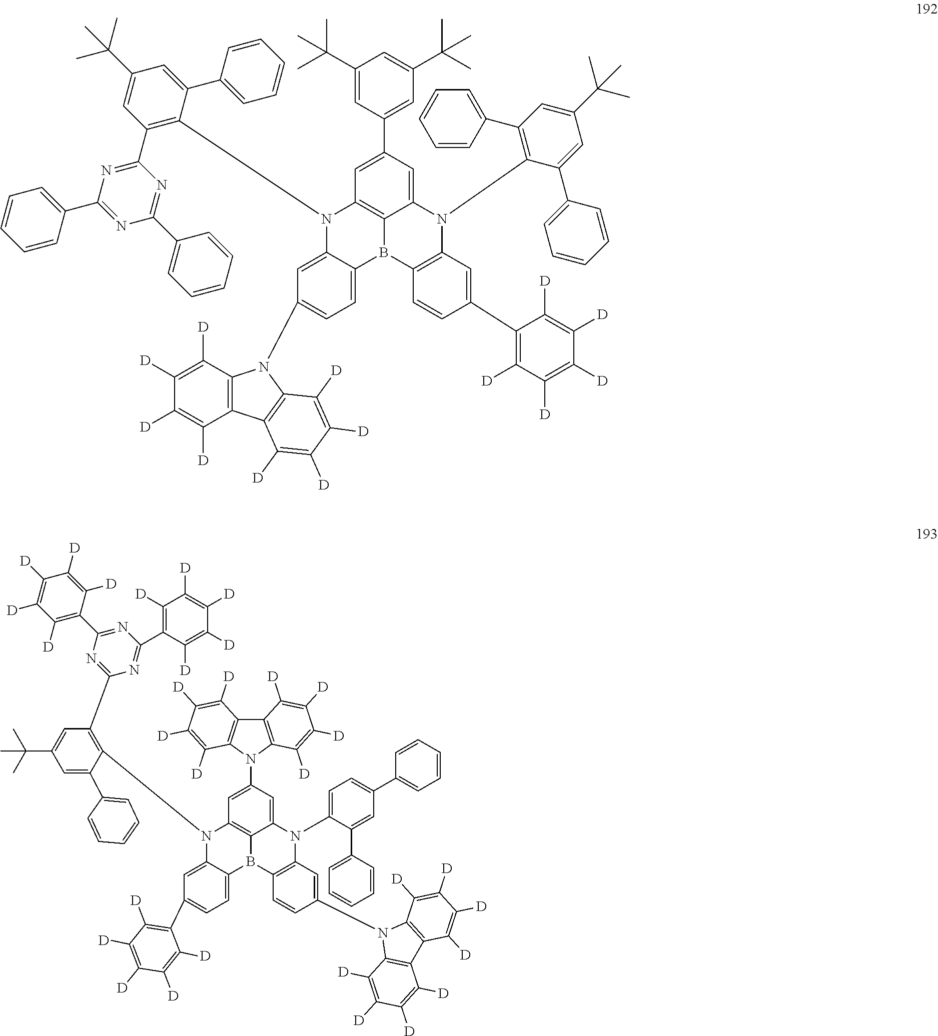 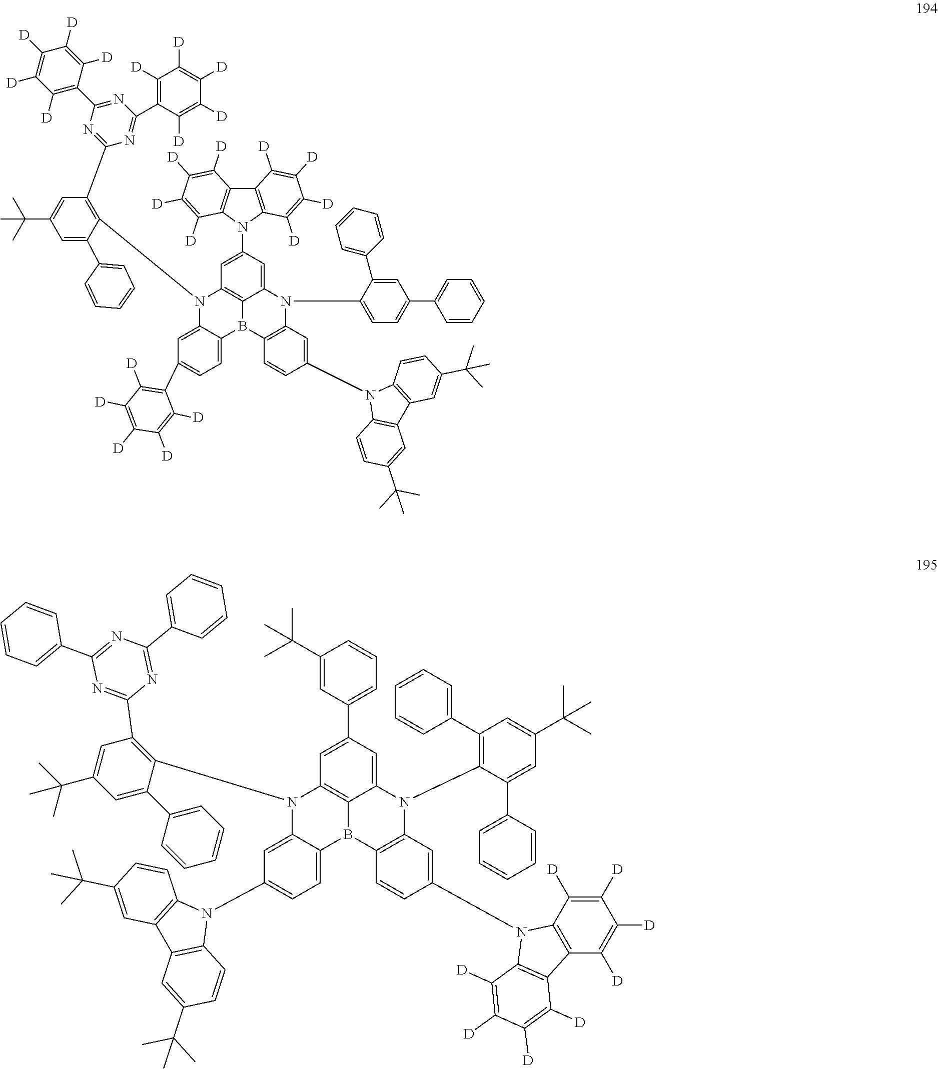 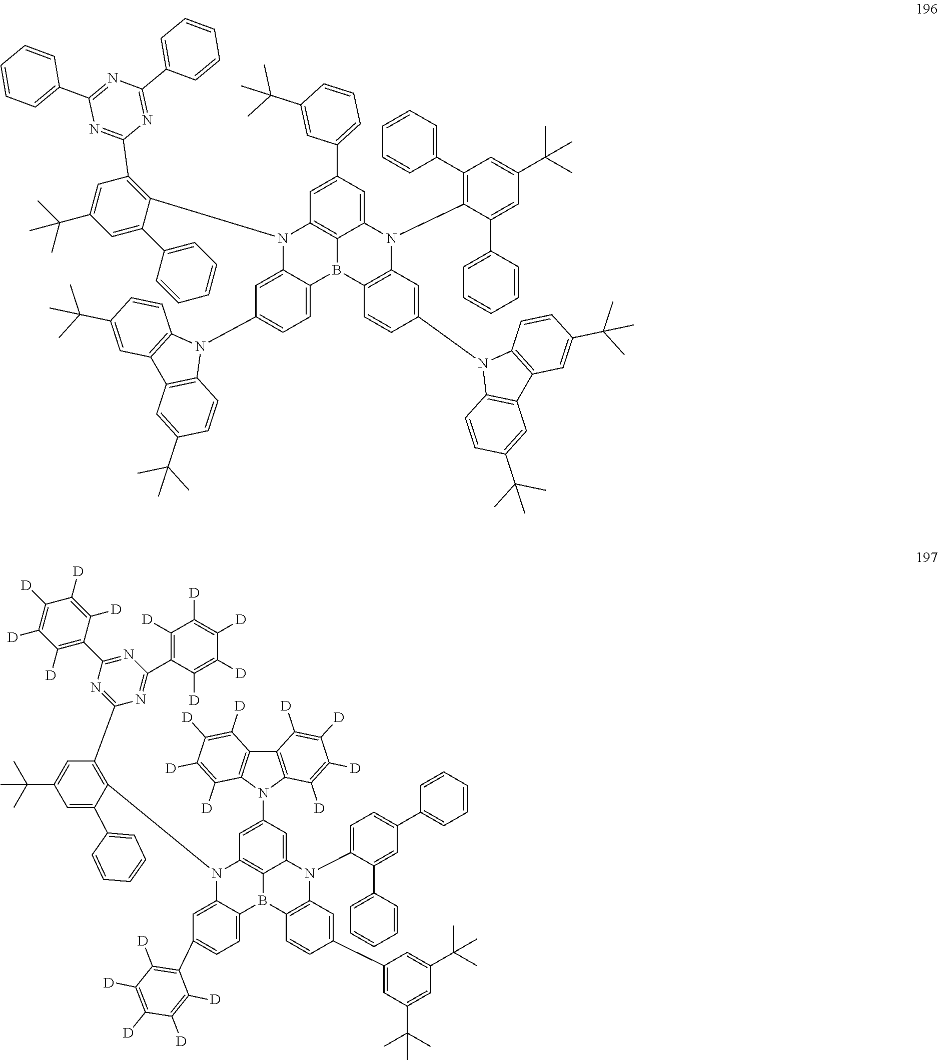 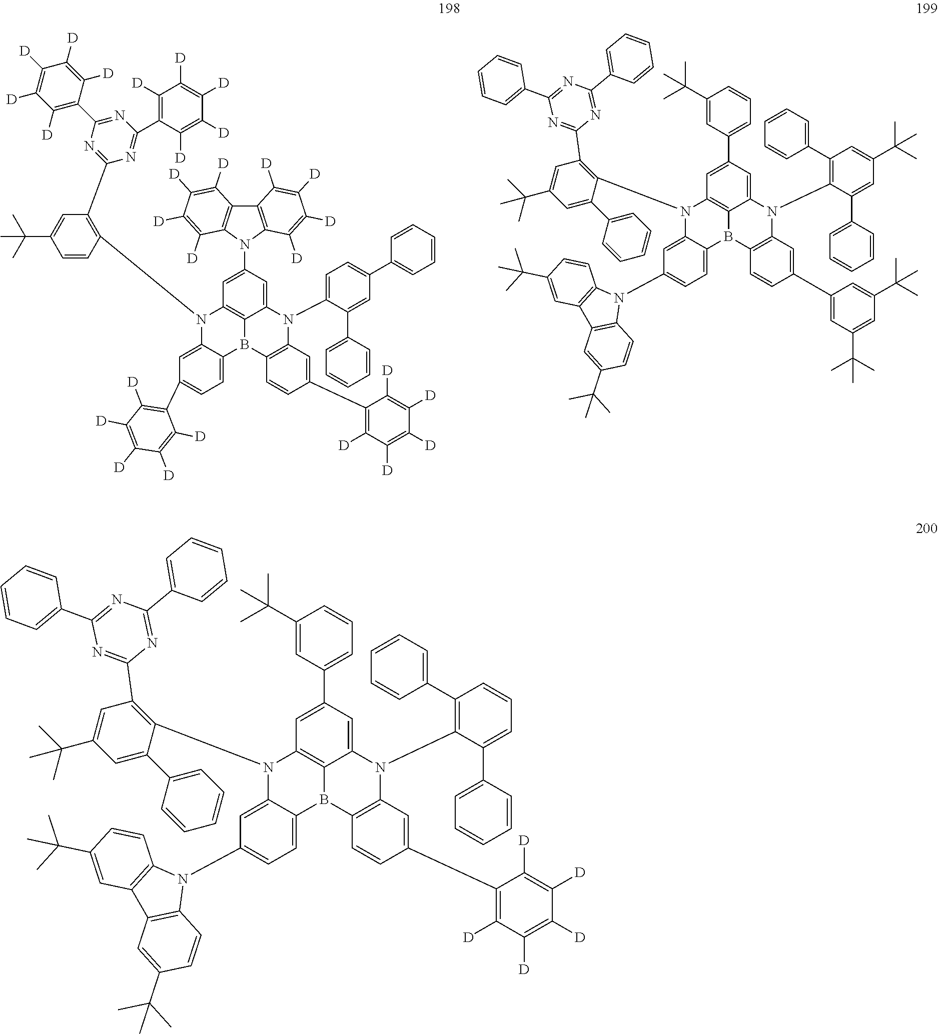 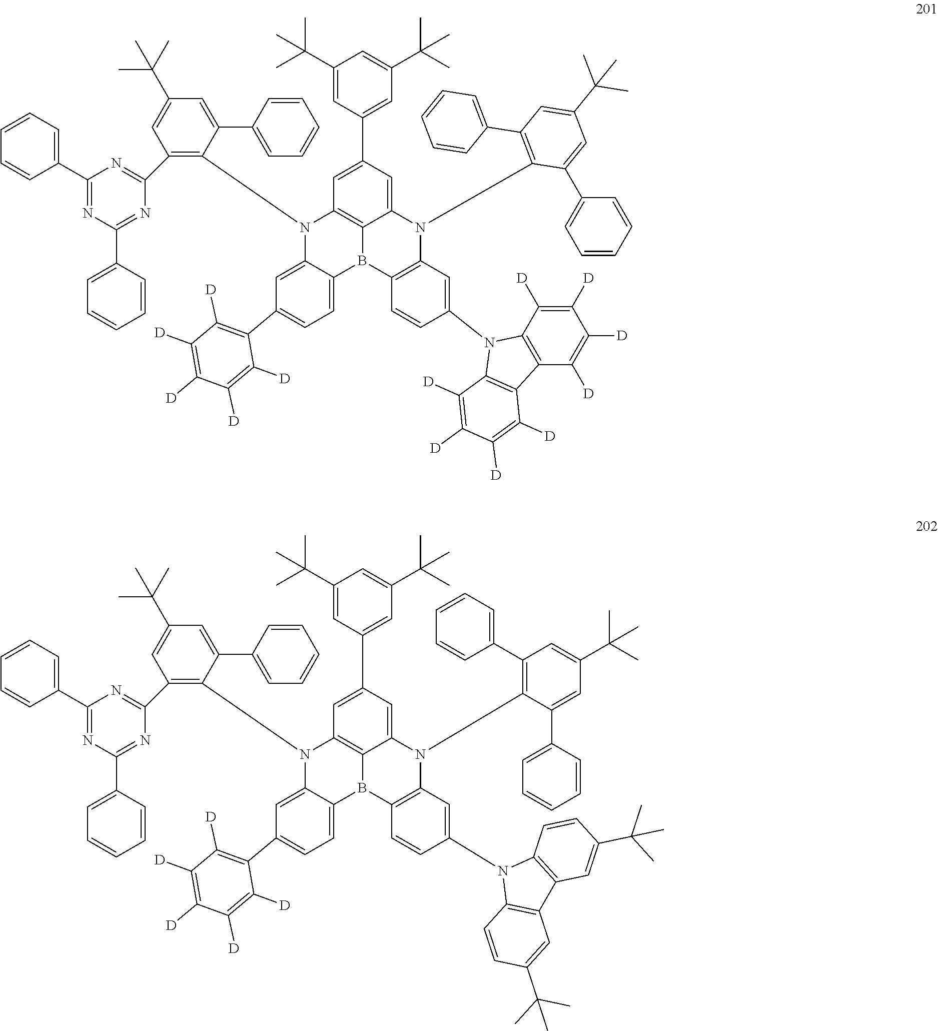 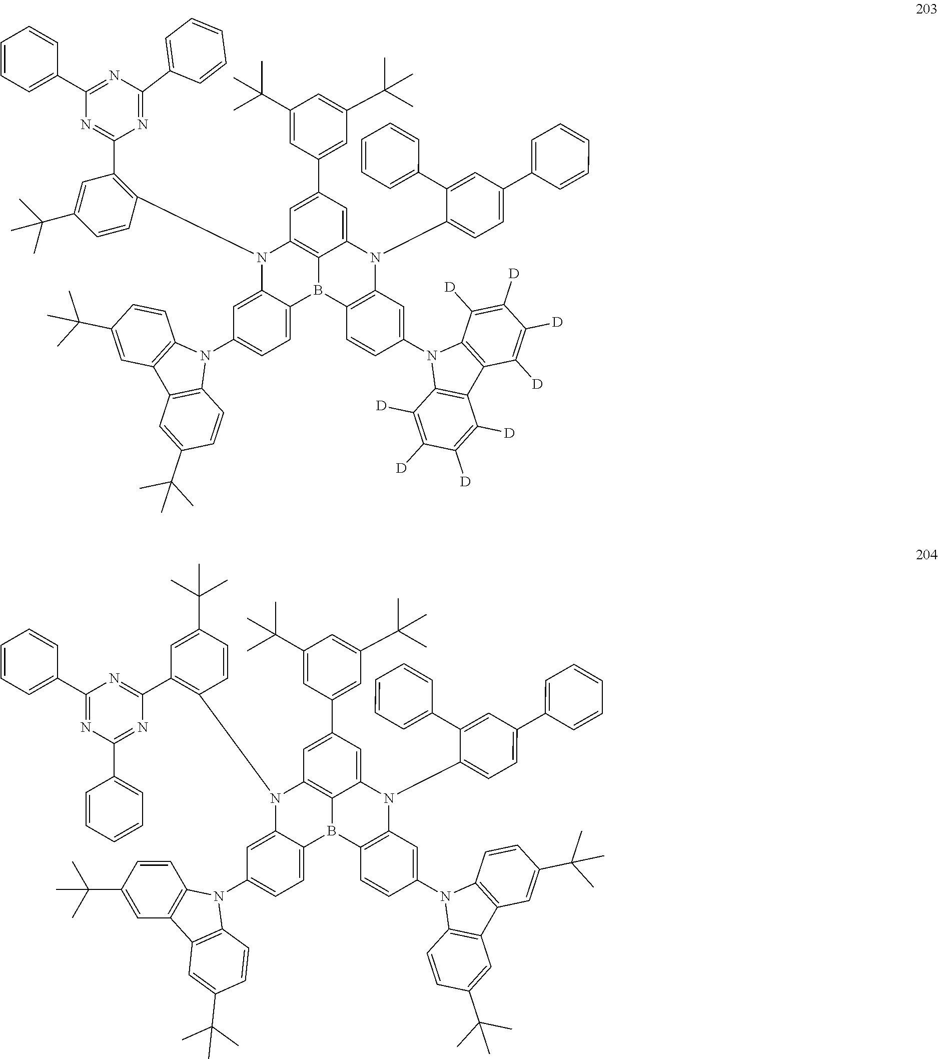 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(-c3cc(C(C)(C)C)cc(C(C)(C)C)c3)cc3c1B2c1ccc(-n2c4ccc(C(C)(C)C)cc4c4cc(C(C)(C)C)ccc42)cc1N3c1ccc(C(C)(C)C)cc1-c1nc(-c2ccccc2)nc(-c2ccccc2)n1 ; CC(C)(C)c1cc(-c2cc3c4c(c2)N(c2ccc(C(C)(C)C)cc2-c2nc(-c5ccccc5)nc(-c5ccccc5)n2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2N3c2ccc(-c3ccccc3)cc2-c2ccccc2)cc(C(C)(C)C)c1] 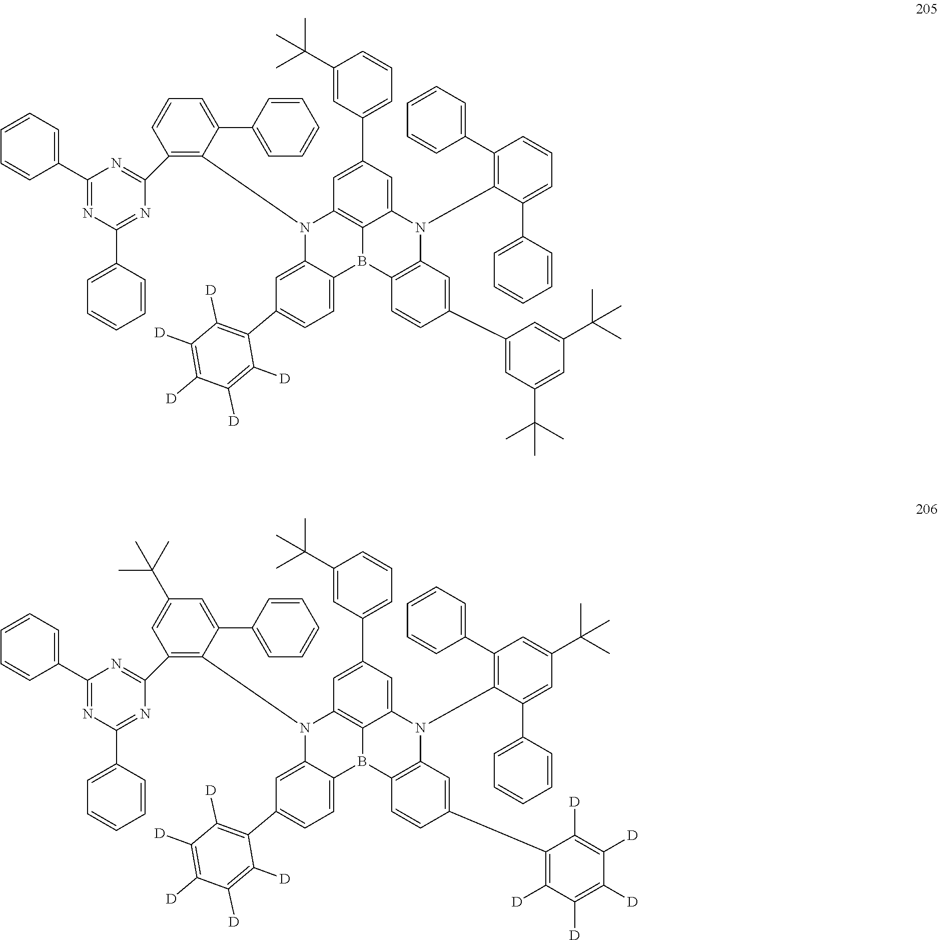 [SMILES: [2H]c1c([2H])c([2H])c(-c2ccc3c(c2)N(c2c(-c4ccccc4)cccc2-c2nc(-c4ccccc4)nc(-c4ccccc4)n2)c2cc(-c4cccc(C(C)(C)C)c4)cc4c2B3c2ccc(-c3cc(C(C)(C)C)cc(C(C)(C)C)c3)cc2N4c2c(-c3ccccc3)cccc2-c2ccccc2)c([2H])c1[2H] ; [2H]c1c([2H])c([2H])c(-c2ccc3c(c2)N(c2c(-c4ccccc4)cc(C(C)(C)C)cc2-c2ccccc2)c2cc(-c4cccc(C(C)(C)C)c4)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H]] 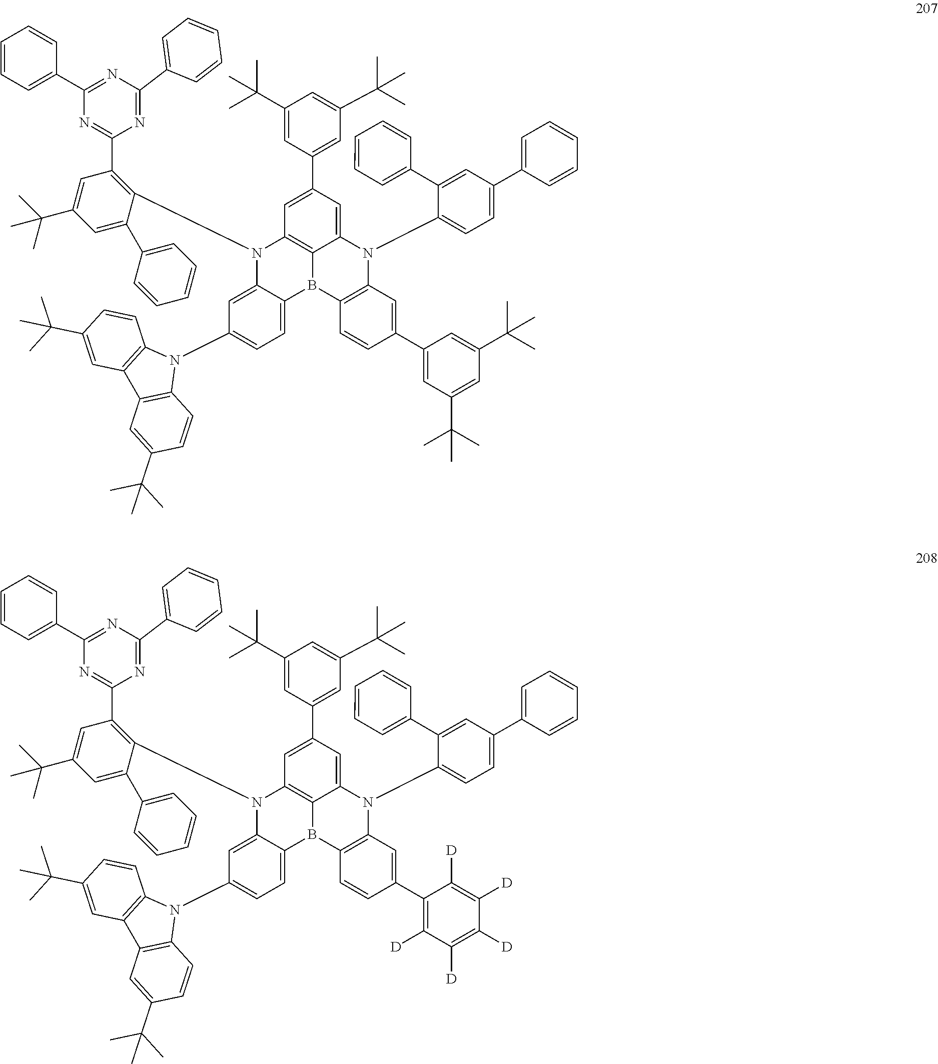 [SMILES: CC(C)(C)c1cc(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2c(-c3ccccc3)cc(C(C)(C)C)cc2-c2nc(-c3ccccc3)nc(-c3ccccc3)n2)c([2H])c1[2H]] 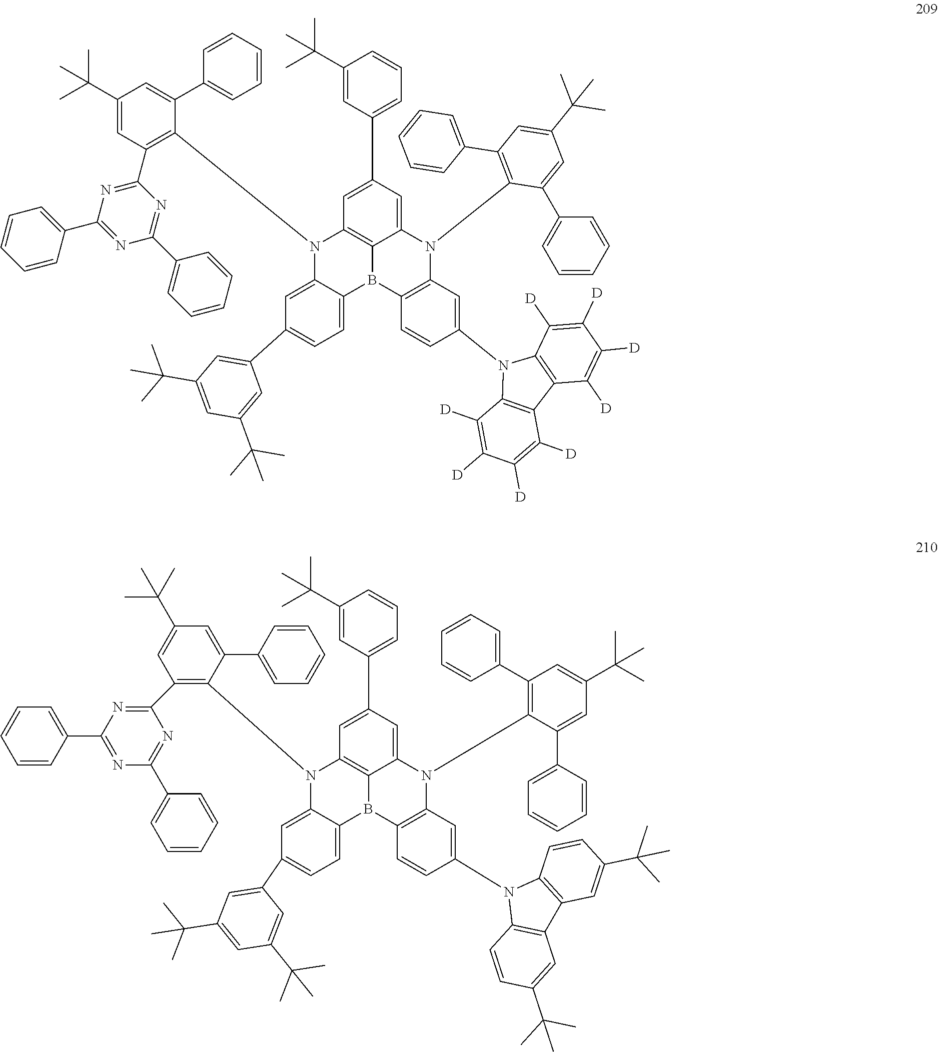 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(-c3cccc(C(C)(C)C)c3)cc3c1B2c1ccc(-c2cc(C(C)(C)C)cc(C(C)(C)C)c2)cc1N3c1c(-c2ccccc2)cc(C(C)(C)C)cc1-c1nc(-c2ccccc2)nc(-c2ccccc2)n1 ; CC(C)(C)c1cccc(-c2cc3c4c(c2)N(c2c(-c5ccccc5)cc(C(C)(C)C)cc2-c2nc(-c5ccccc5)nc(-c5ccccc5)n2)c2cc(-c5cc(C(C)(C)C)cc(C(C)(C)C)c5)ccc2B4c2ccc(-n4c5ccc(C(C)(C)C)cc5c5cc(C(C)(C)C)ccc54)cc2N3c2c(-c3ccccc3)cc(C(C)(C)C)cc2-c2ccccc2)c1] 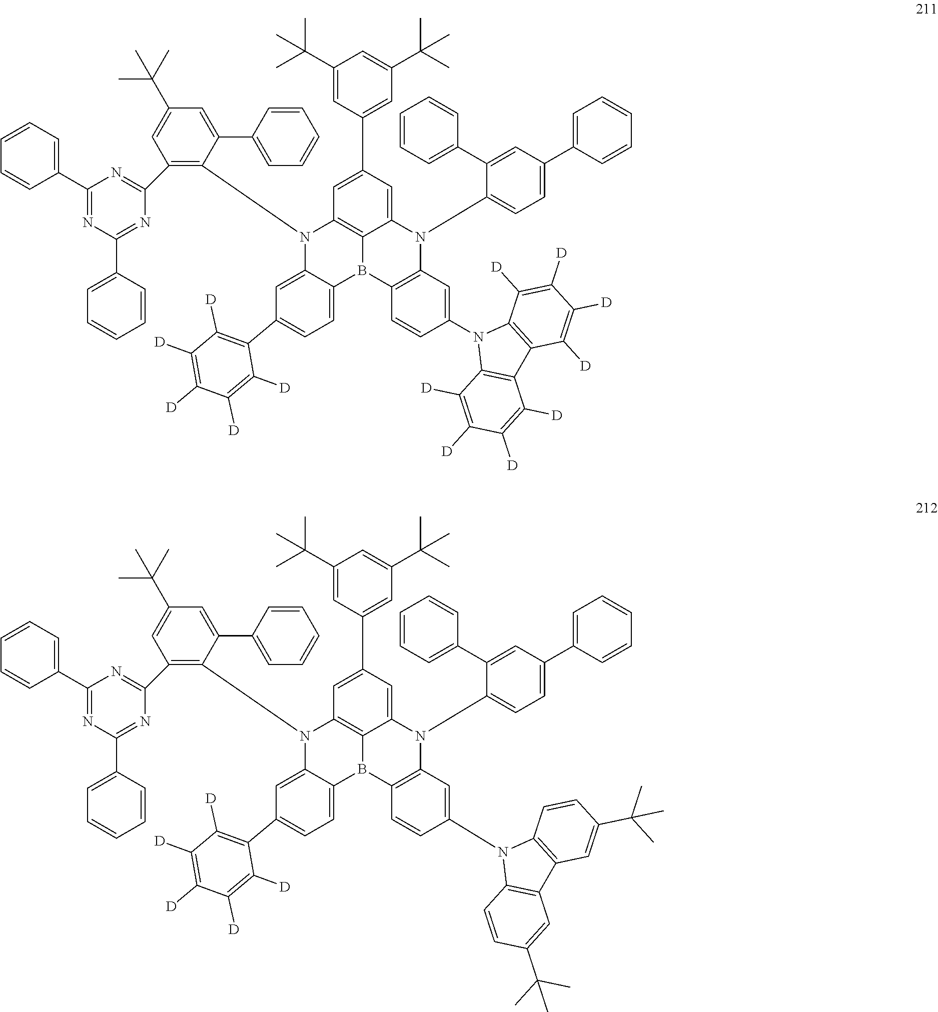 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-c4cc(C(C)(C)C)cc(C(C)(C)C)c4)cc4c2B3c2ccc(-n3c5c([2H])c([2H])c([2H])c([2H])c5c5c([2H])c([2H])c([2H])c([2H])c53)cc2N4c2ccc(-c3ccccc3)cc2-c2ccccc2)c([2H])c1[2H] ; [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2ccc(-c3ccccc3)cc2-c2ccccc2)c([2H])c1[2H]] 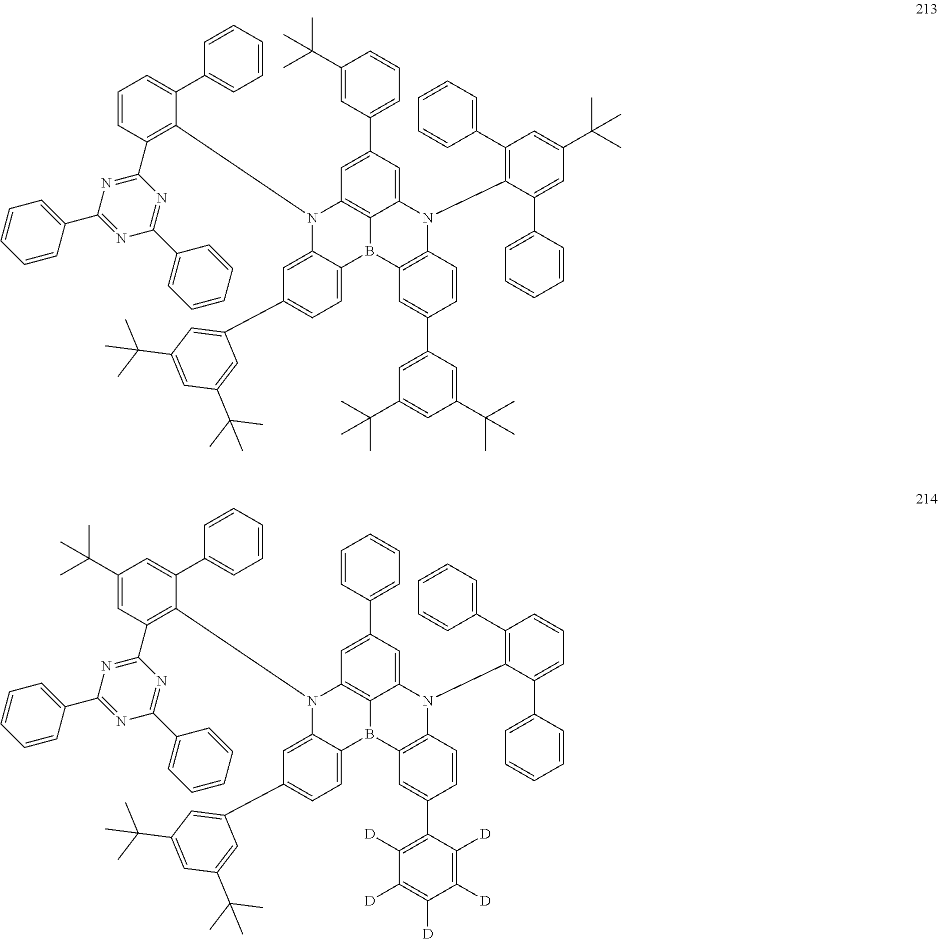 [SMILES: CC(C)(C)c1cccc(-c2cc3c4c(c2)N(c2c(-c5ccccc5)cccc2-c2nc(-c5ccccc5)nc(-c5ccccc5)n2)c2cc(-c5cc(C(C)(C)C)cc(C(C)(C)C)c5)ccc2B4c2cc(-c4cc(C(C)(C)C)cc(C(C)(C)C)c4)ccc2N3c2c(-c3ccccc3)cc(C(C)(C)C)cc2-c2ccccc2)c1 ; [2H]c1c([2H])c([2H])c(-c2ccc3c(c2)B2c4ccc(-c5cc(C(C)(C)C)cc(C(C)(C)C)c5)cc4N(c4c(-c5ccccc5)cc(C(C)(C)C)cc4-c4nc(-c5ccccc5)nc(-c5ccccc5)n4)c4cc(-c5ccccc5)cc(c42)N3c2c(-c3ccccc3)cccc2-c2ccccc2)c([2H])c1[2H]] 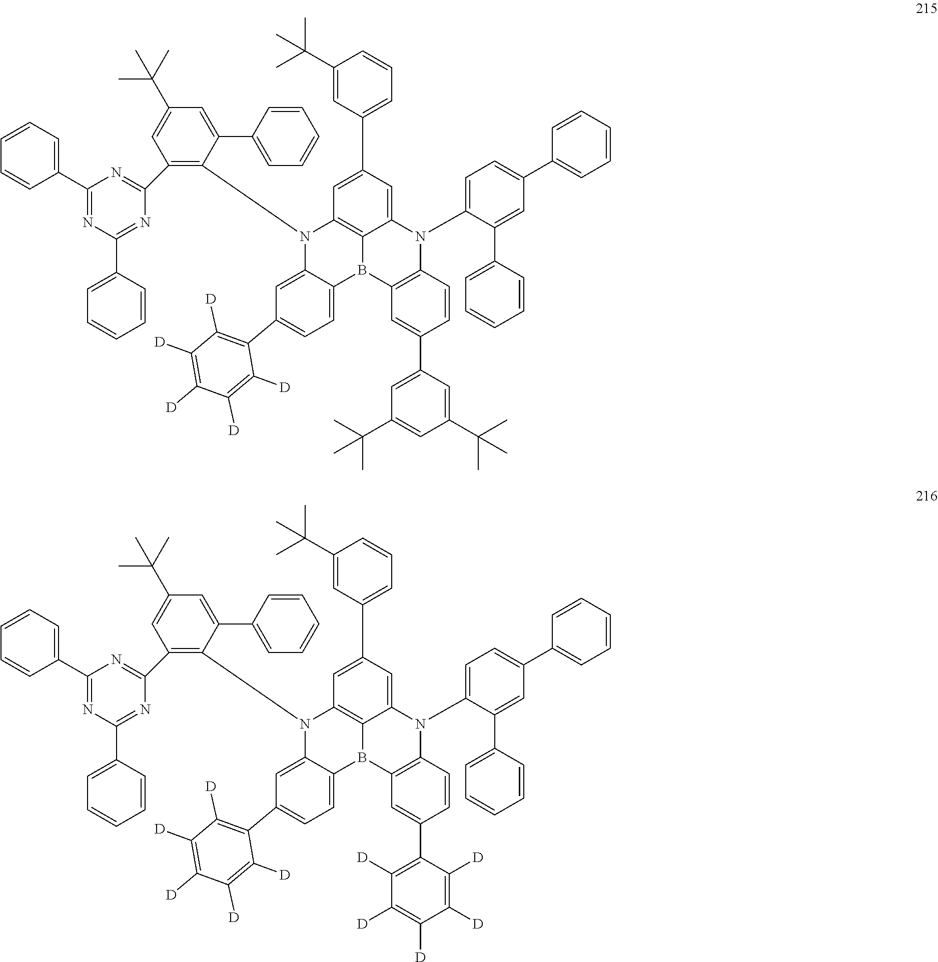 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-c4cccc(C(C)(C)C)c4)cc4c2B3c2cc(-c3cc(C(C)(C)C)cc(C(C)(C)C)c3)ccc2N4c2ccc(-c3ccccc3)cc2-c2ccccc2)c([2H])c1[2H] ; [2H]c1c([2H])c([2H])c(-c2ccc3c(c2)B2c4ccc(-c5c([2H])c([2H])c([2H])c([2H])c5[2H])cc4N(c4c(-c5ccccc5)cc(C(C)(C)C)cc4-c4nc(-c5ccccc5)nc(-c5ccccc5)n4)c4cc(-c5cccc(C(C)(C)C)c5)cc(c42)N3c2ccc(-c3ccccc3)cc2-c2ccccc2)c([2H])c1[2H]] 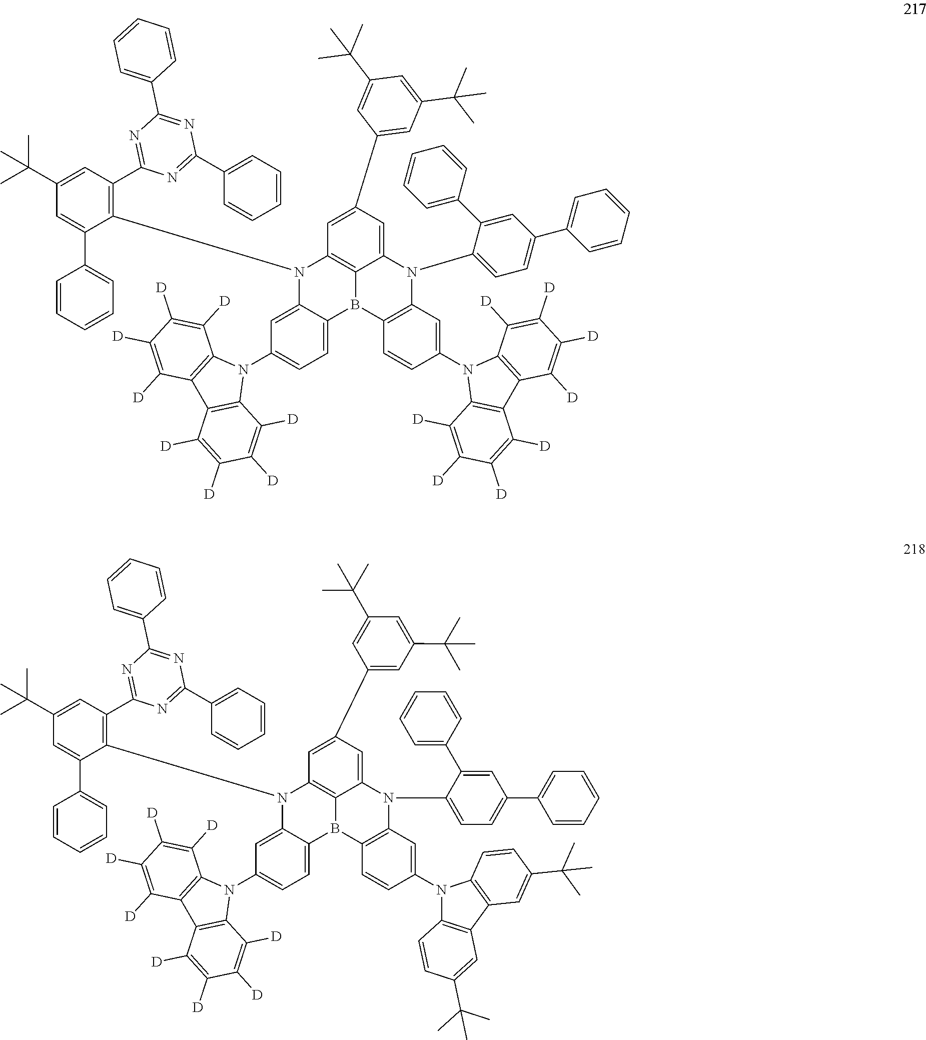 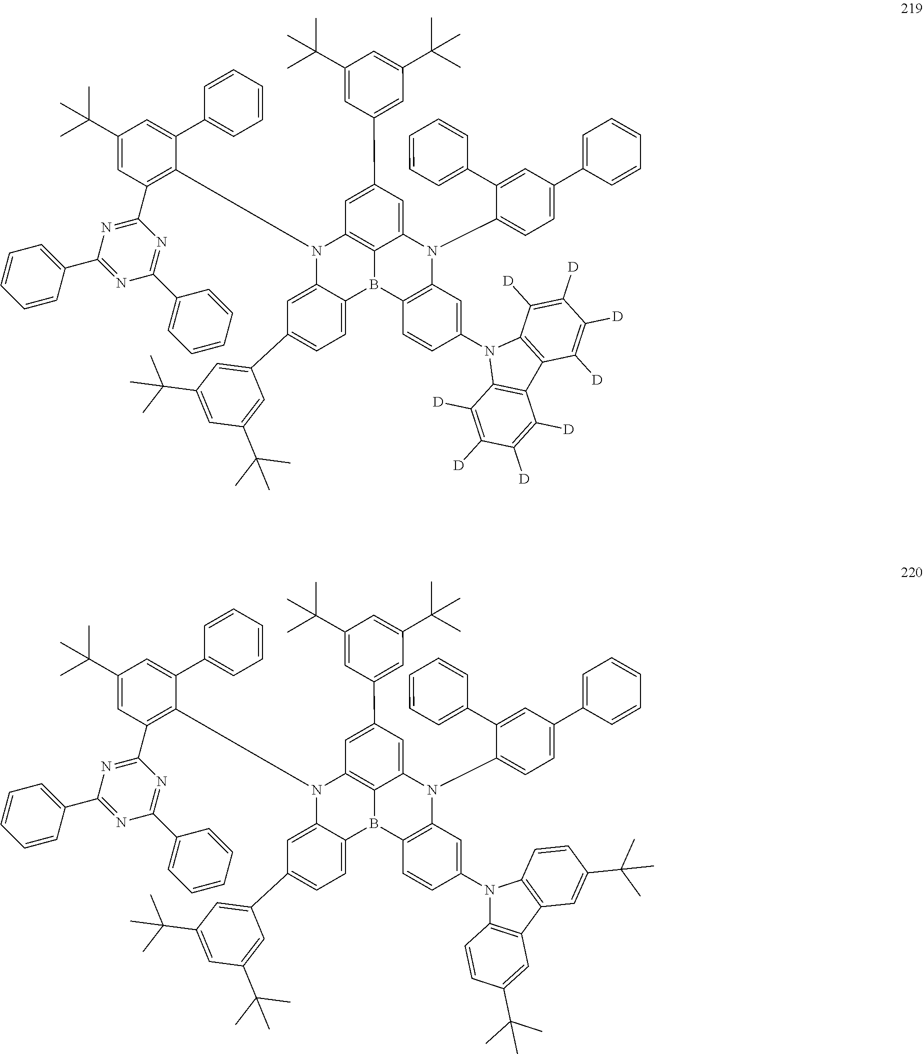 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(-c3cc(C(C)(C)C)cc(C(C)(C)C)c3)cc3c1B2c1ccc(-c2cc(C(C)(C)C)cc(C(C)(C)C)c2)cc1N3c1c(-c2ccccc2)cc(C(C)(C)C)cc1-c1nc(-c2ccccc2)nc(-c2ccccc2)n1 ; CC(C)(C)c1cc(-c2ccc3c(c2)N(c2c(-c4ccccc4)cc(C(C)(C)C)cc2-c2nc(-c4ccccc4)nc(-c4ccccc4)n2)c2cc(-c4cc(C(C)(C)C)cc(C(C)(C)C)c4)cc4c2B3c2ccc(-n3c5ccc(C(C)(C)C)cc5c5cc(C(C)(C)C)ccc53)cc2N4c2ccc(-c3ccccc3)cc2-c2ccccc2)cc(C(C)(C)C)c1] 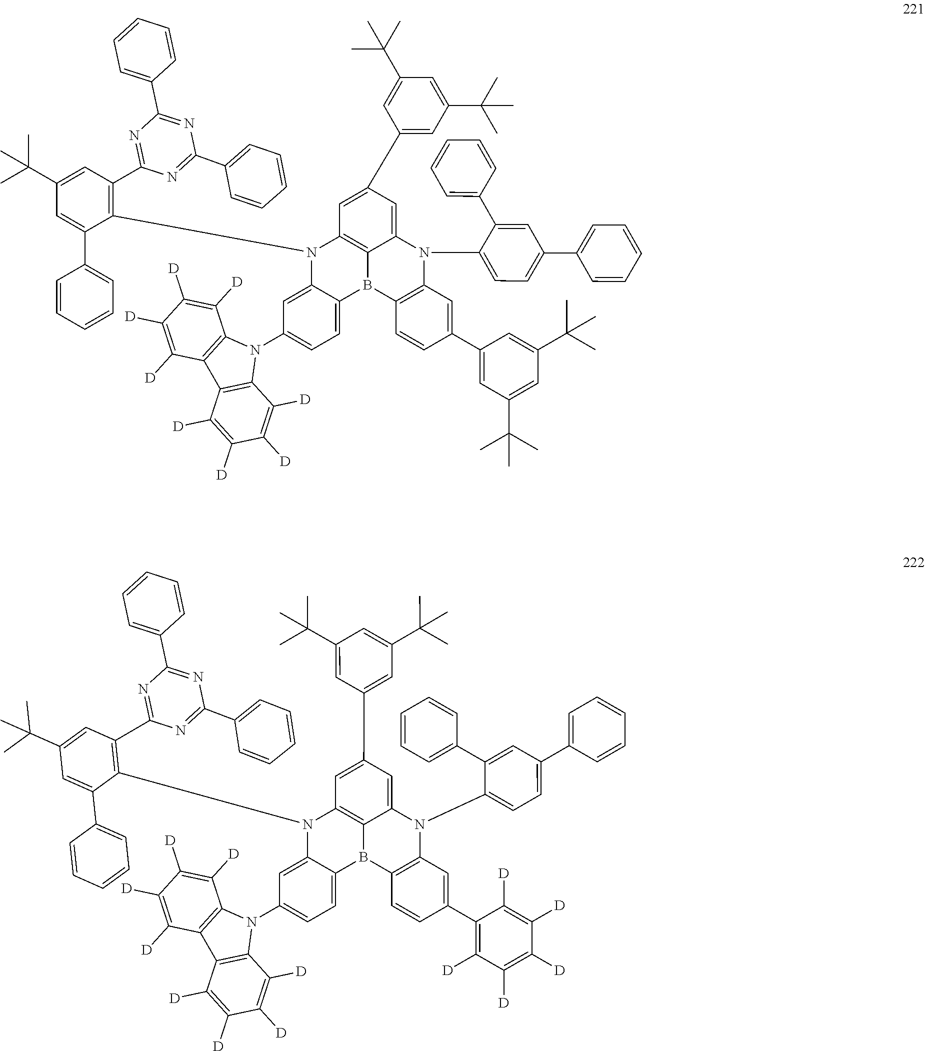 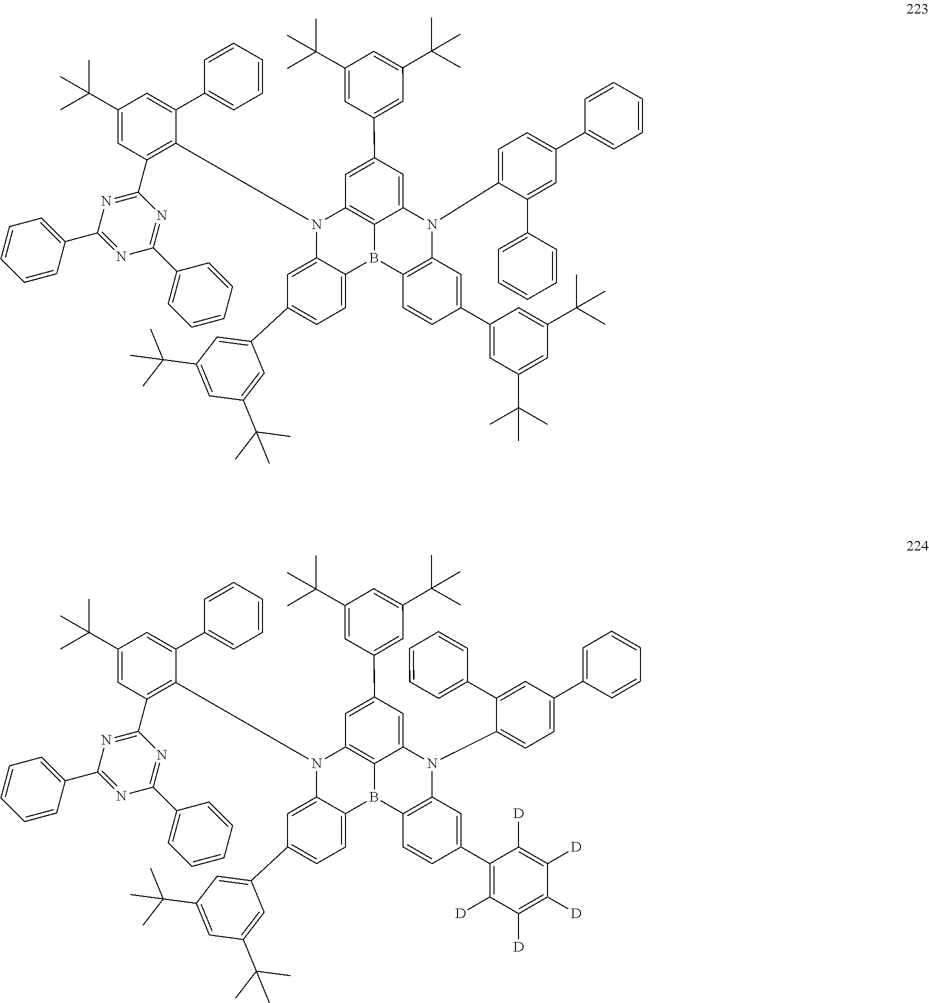 [SMILES: CC(C)(C)c1cc(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)cc(C(C)(C)C)c1 ; [2H]c1c([2H])c([2H])c(-c2ccc3c(c2)N(c2ccc(-c4ccccc4)cc2-c2ccccc2)c2cc(-c4cc(C(C)(C)C)cc(C(C)(C)C)c4)cc4c2B3c2ccc(-c3cc(C(C)(C)C)cc(C(C)(C)C)c3)cc2N4c2c(-c3ccccc3)cc(C(C)(C)C)cc2-c2nc(-c3ccccc3)nc(-c3ccccc3)n2)c([2H])c1[2H]] 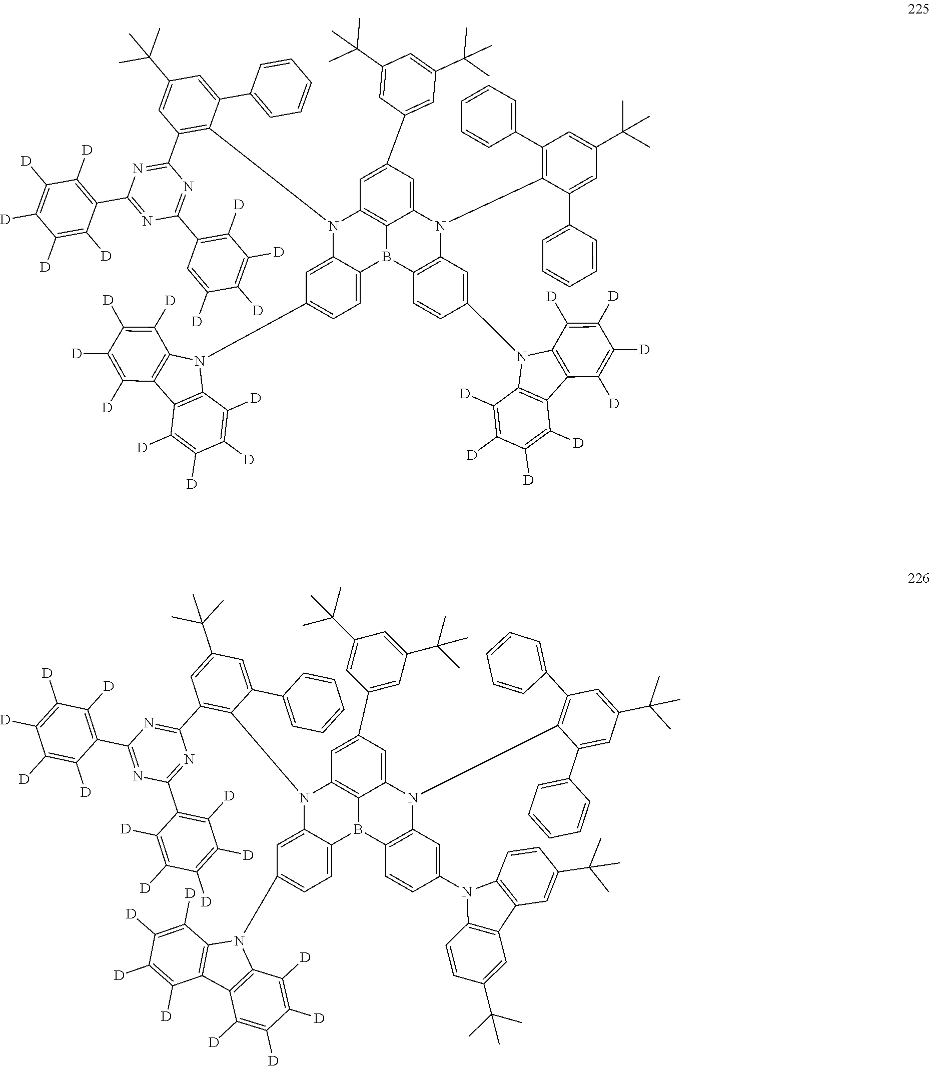 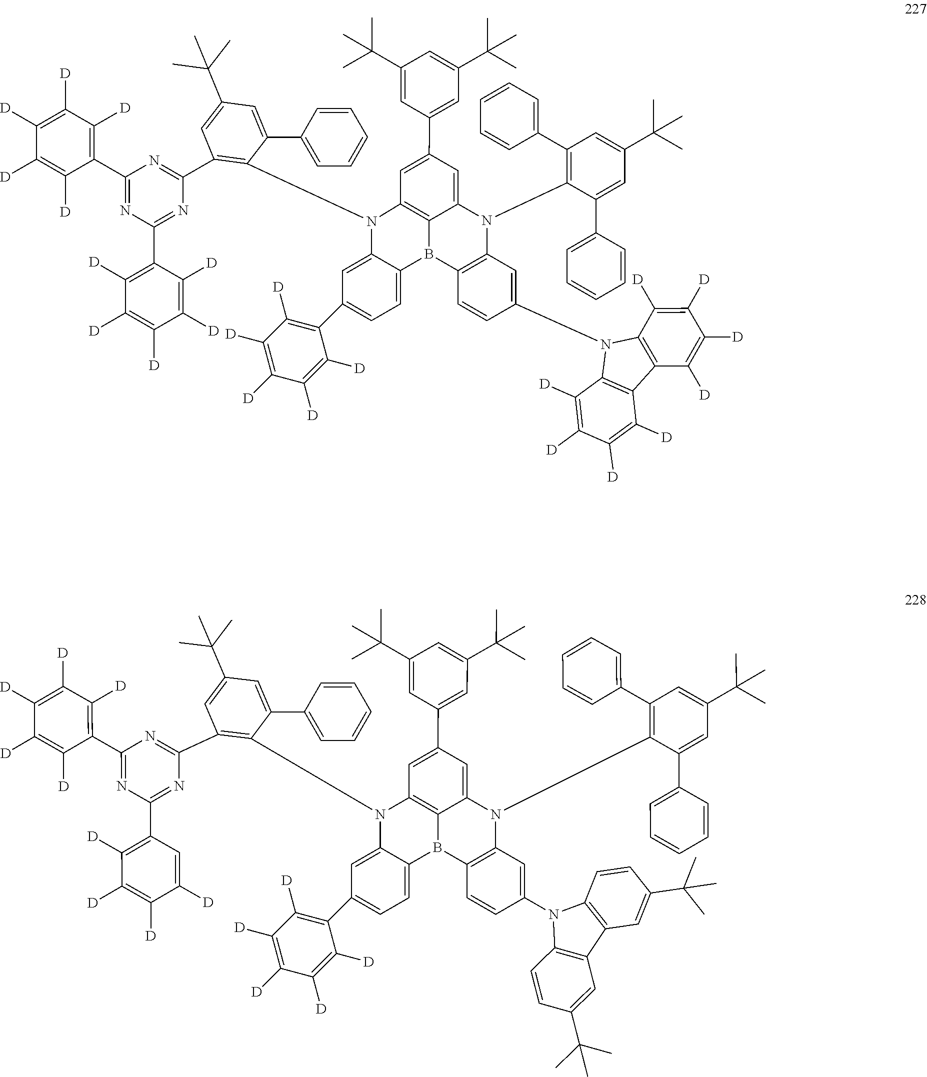 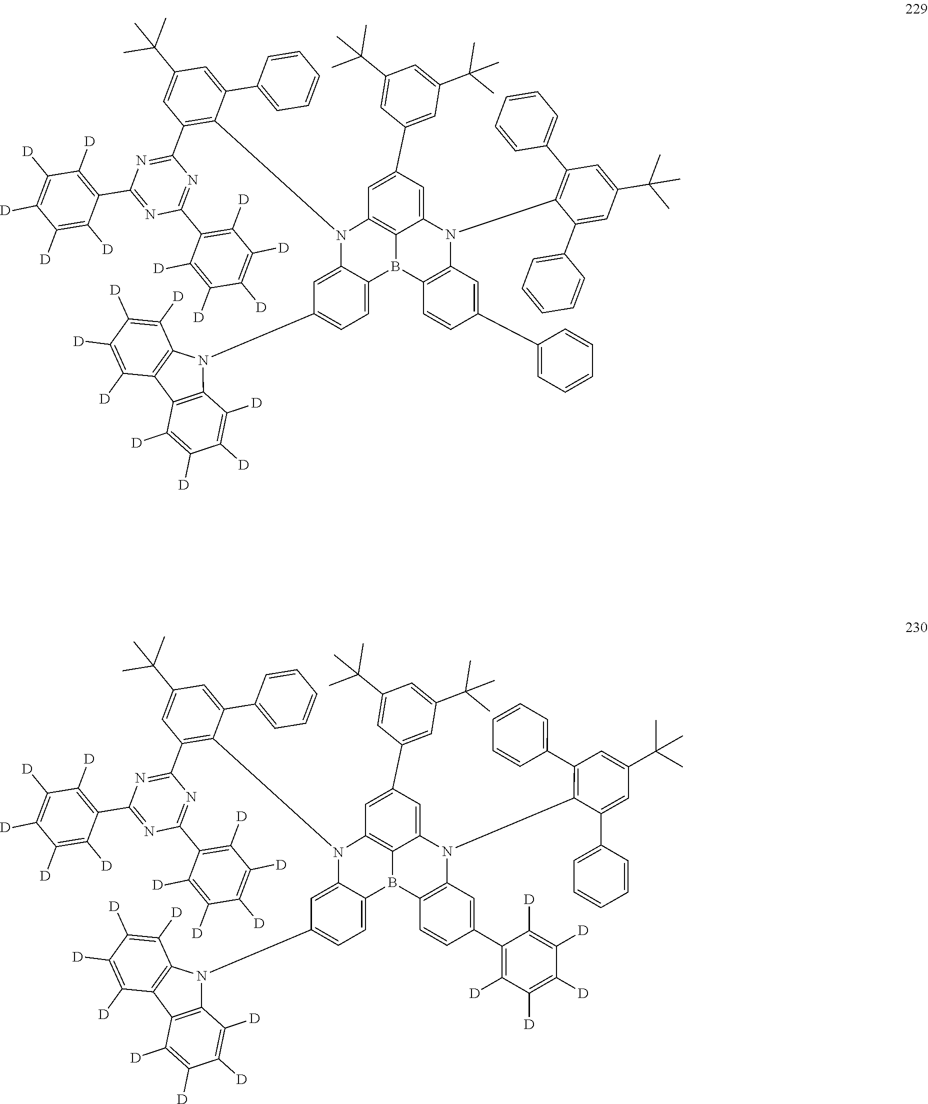 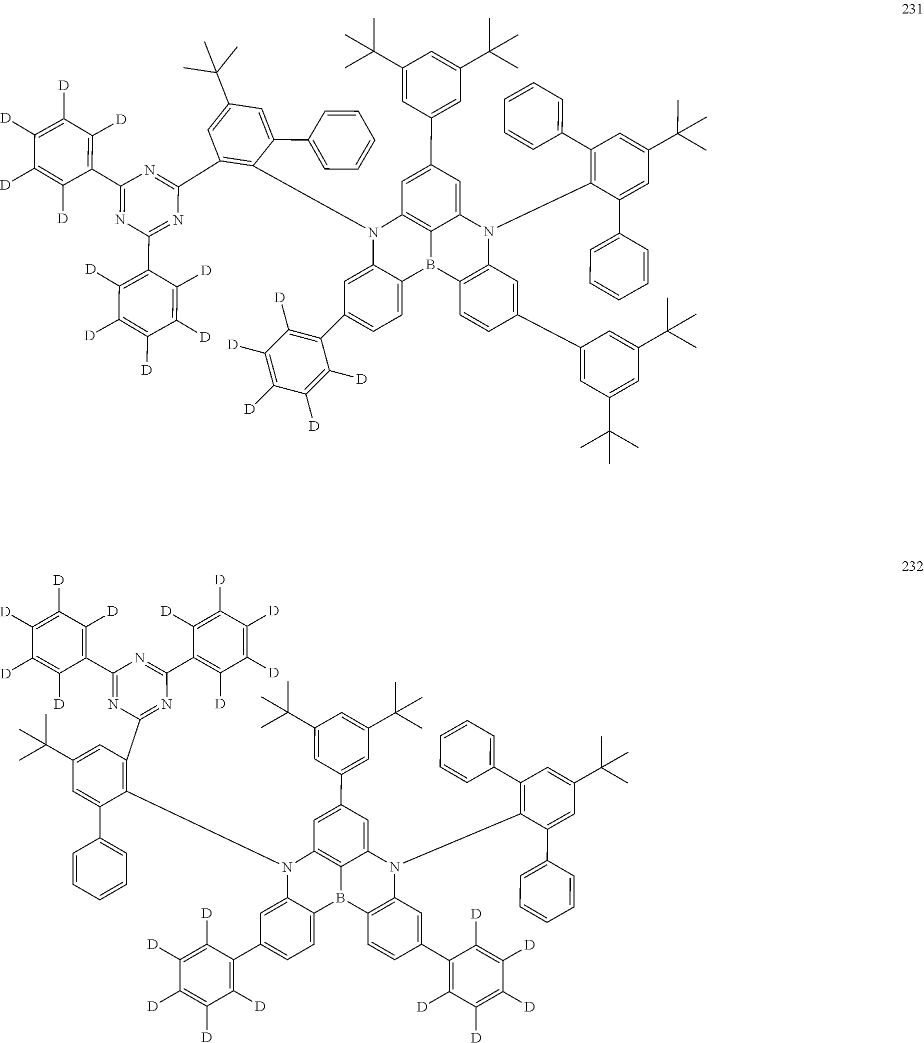 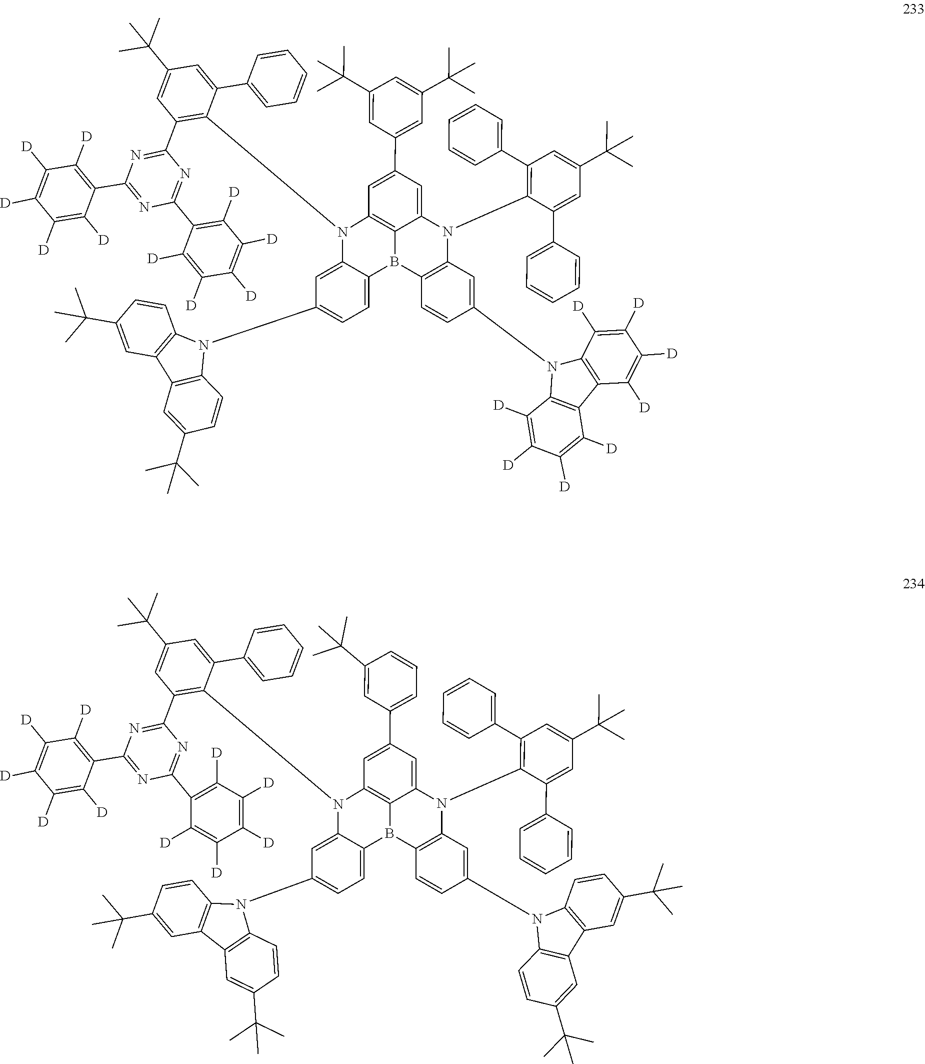 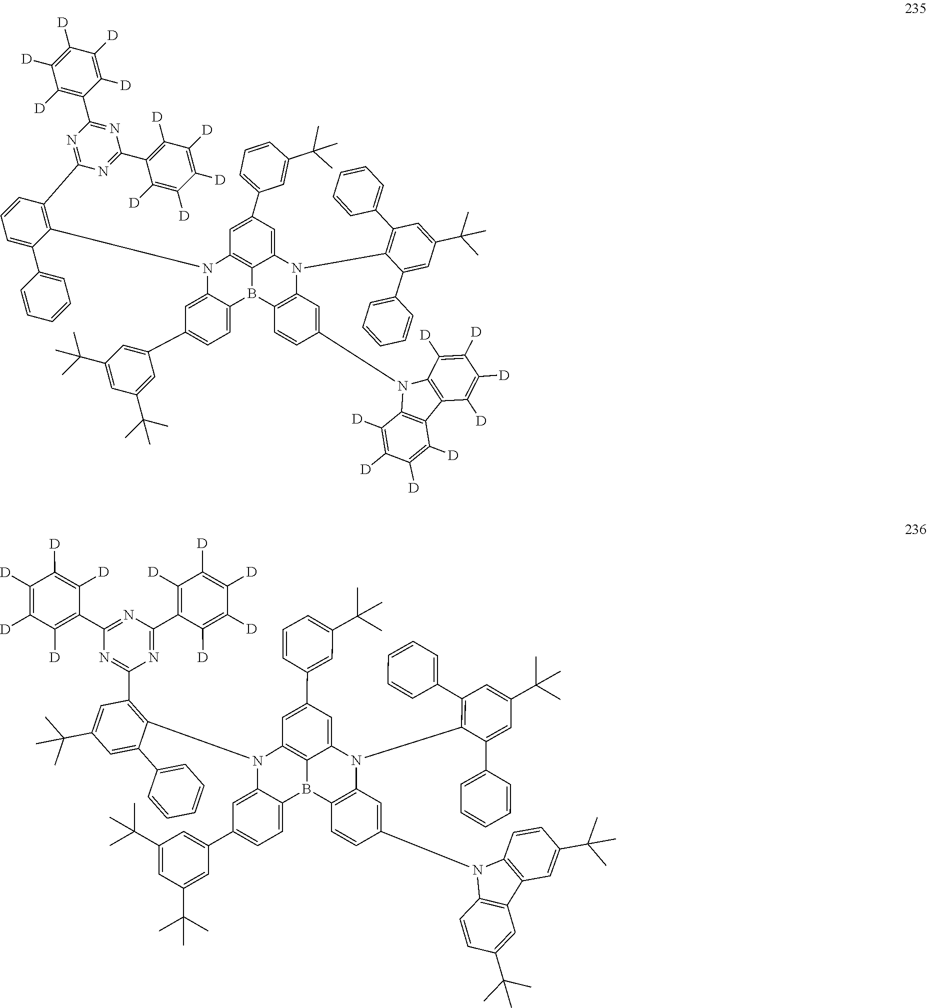 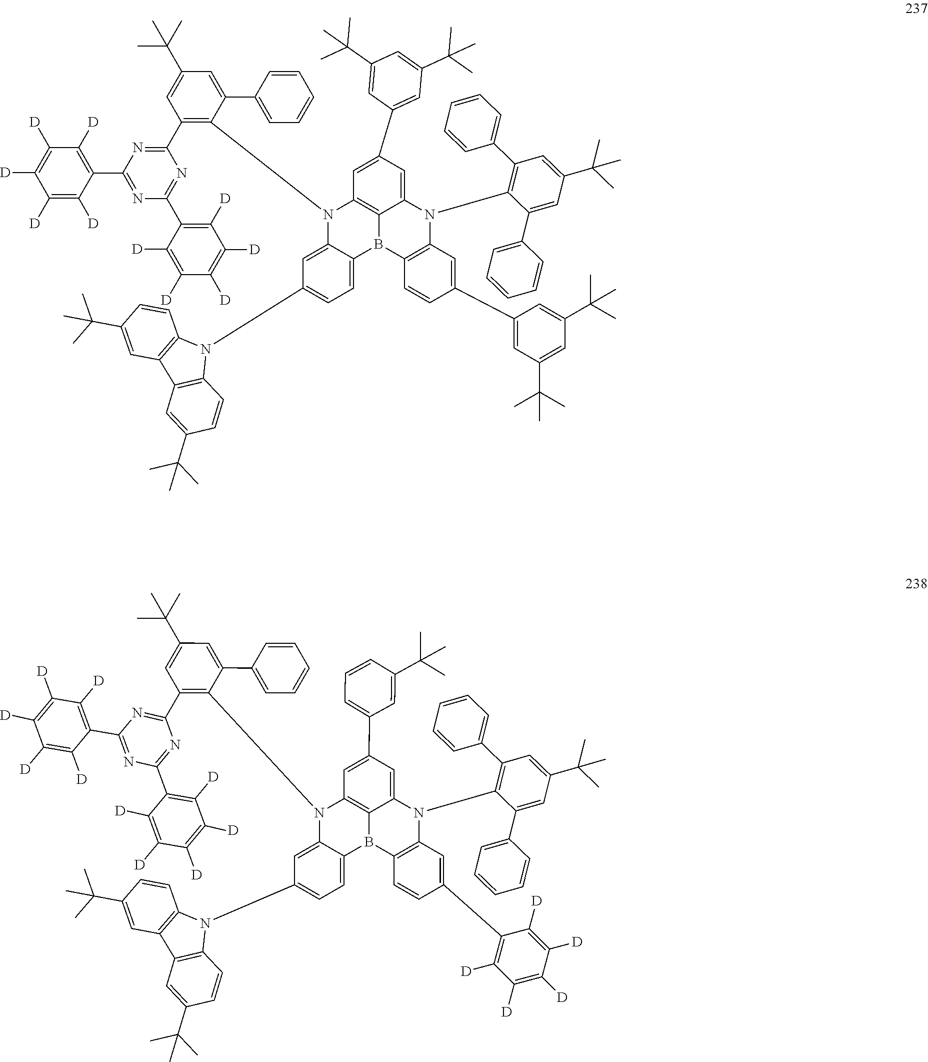 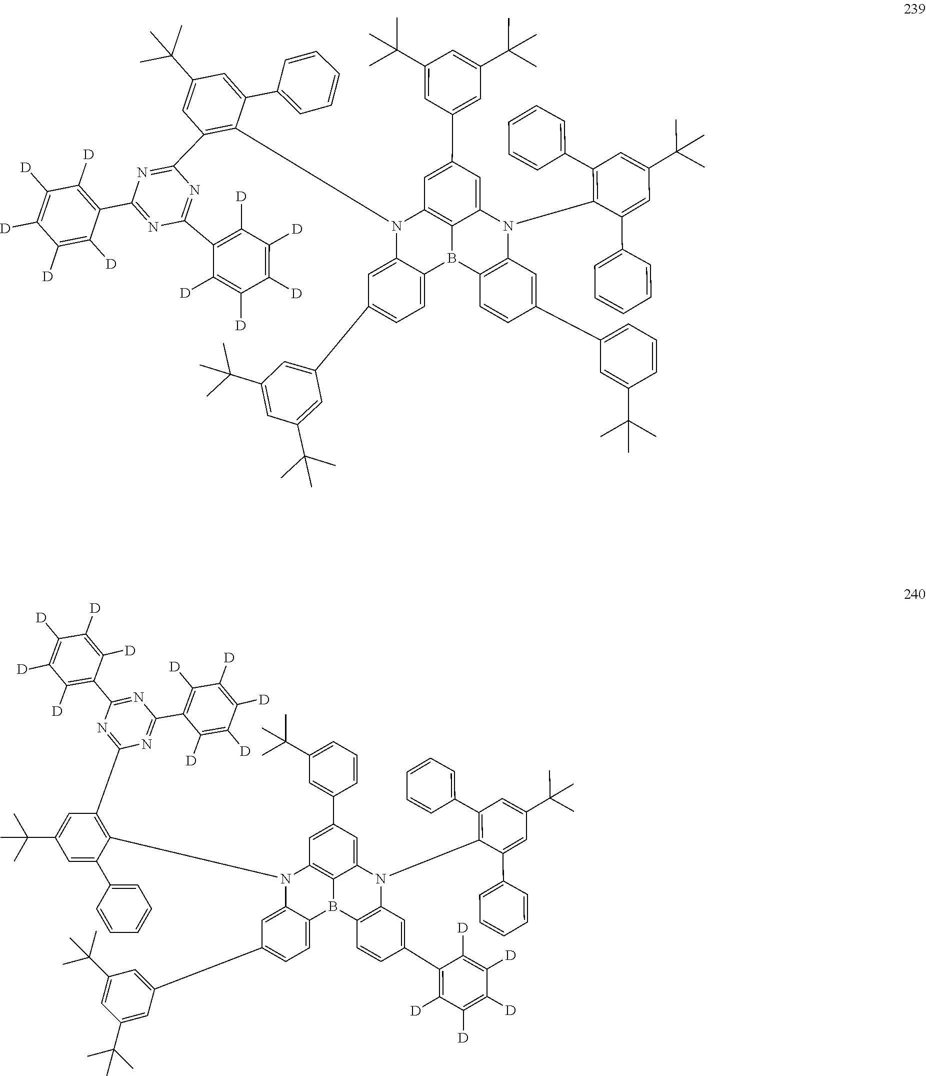 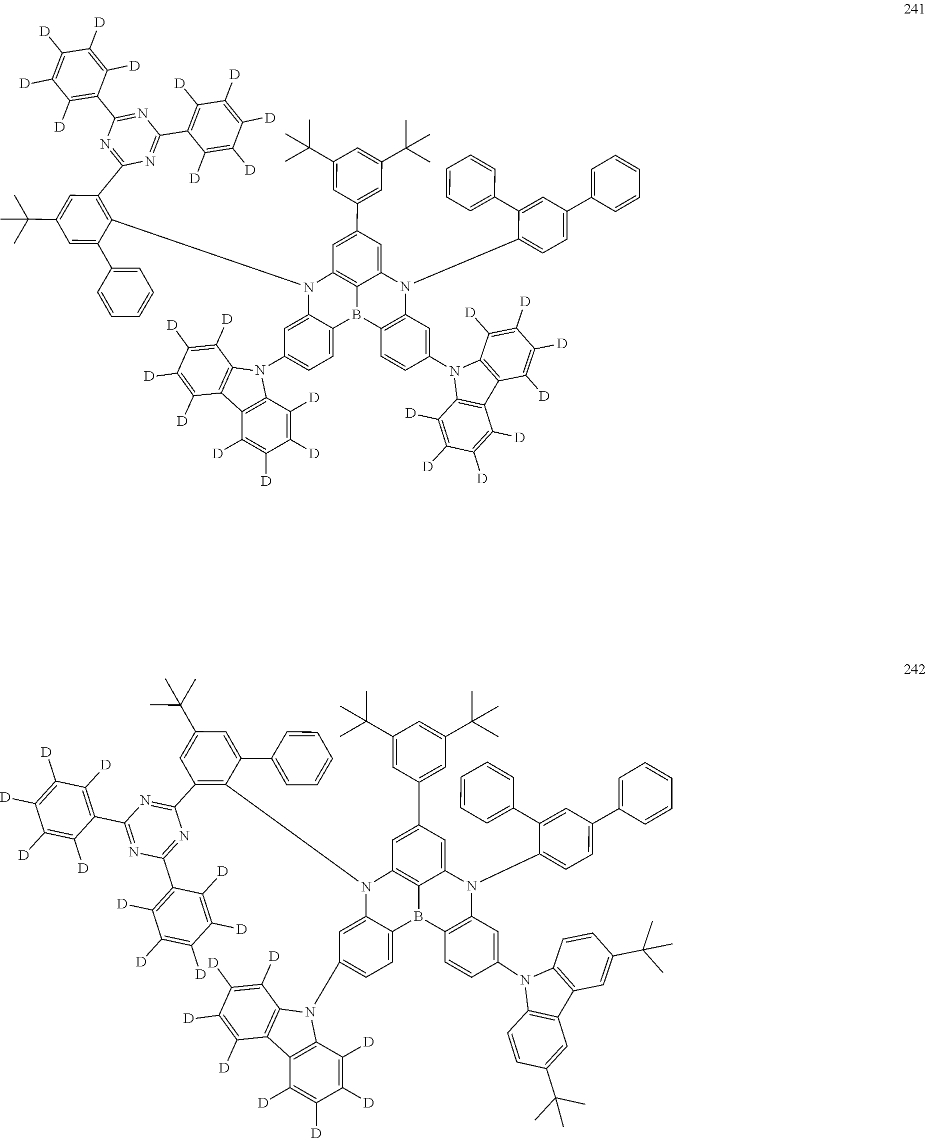 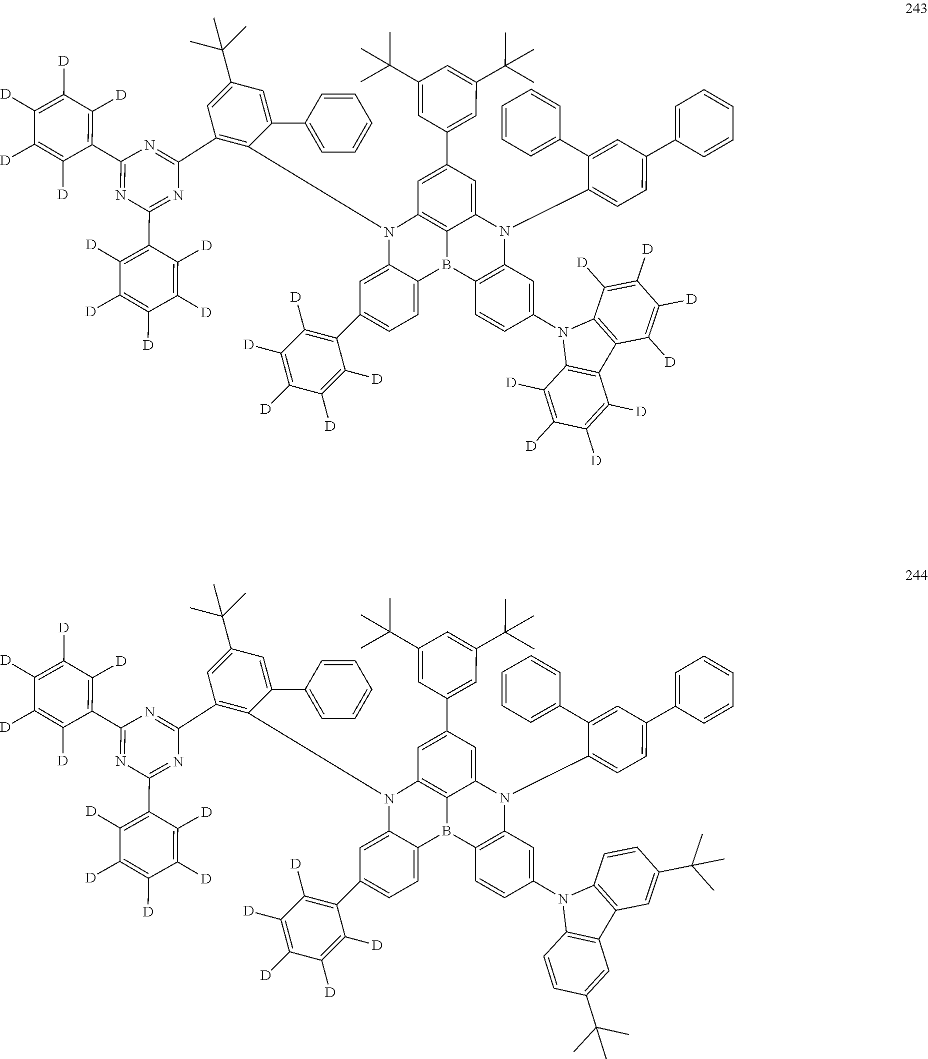 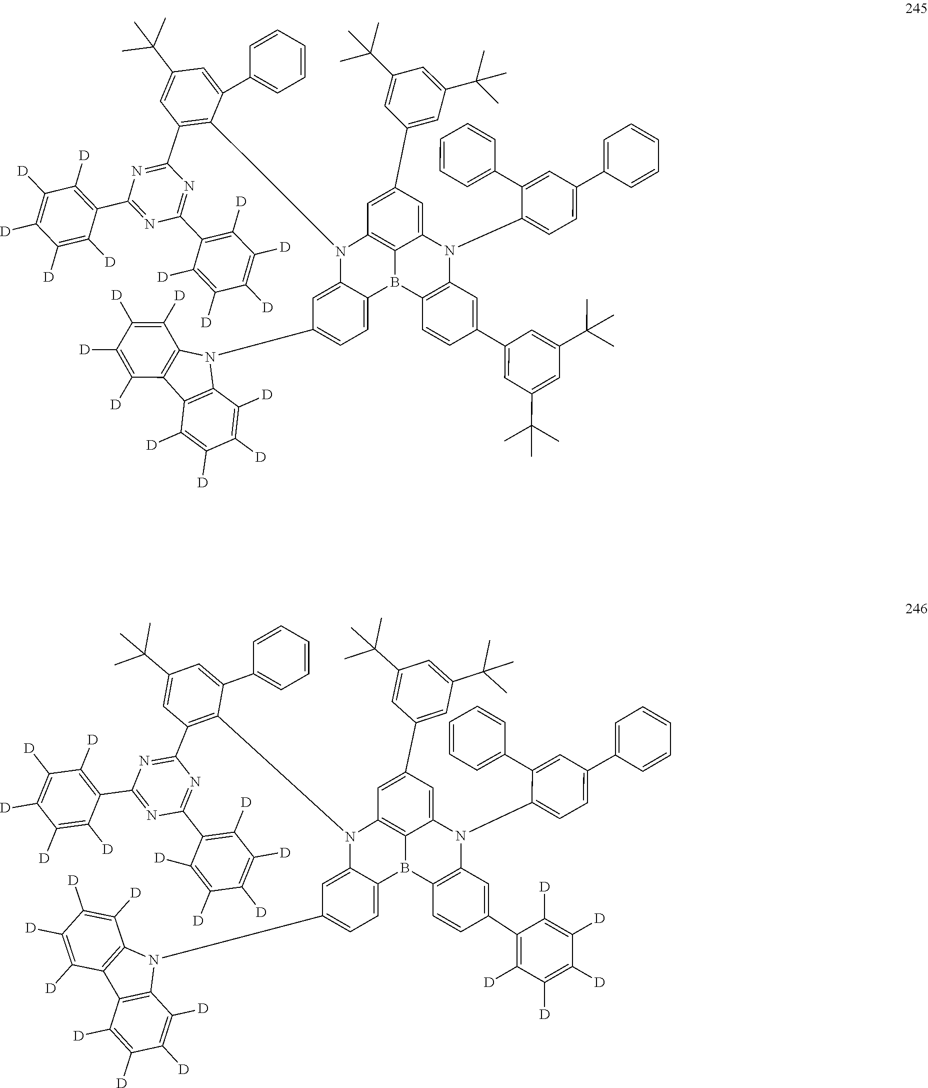 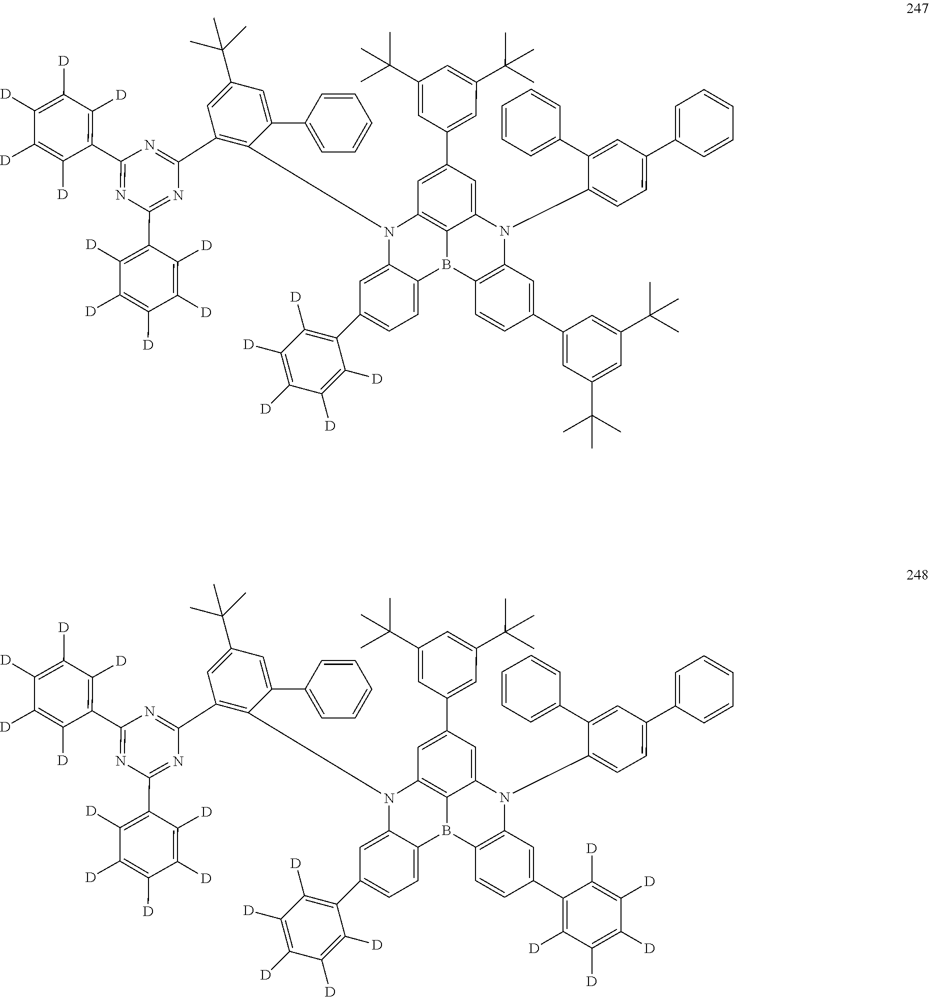 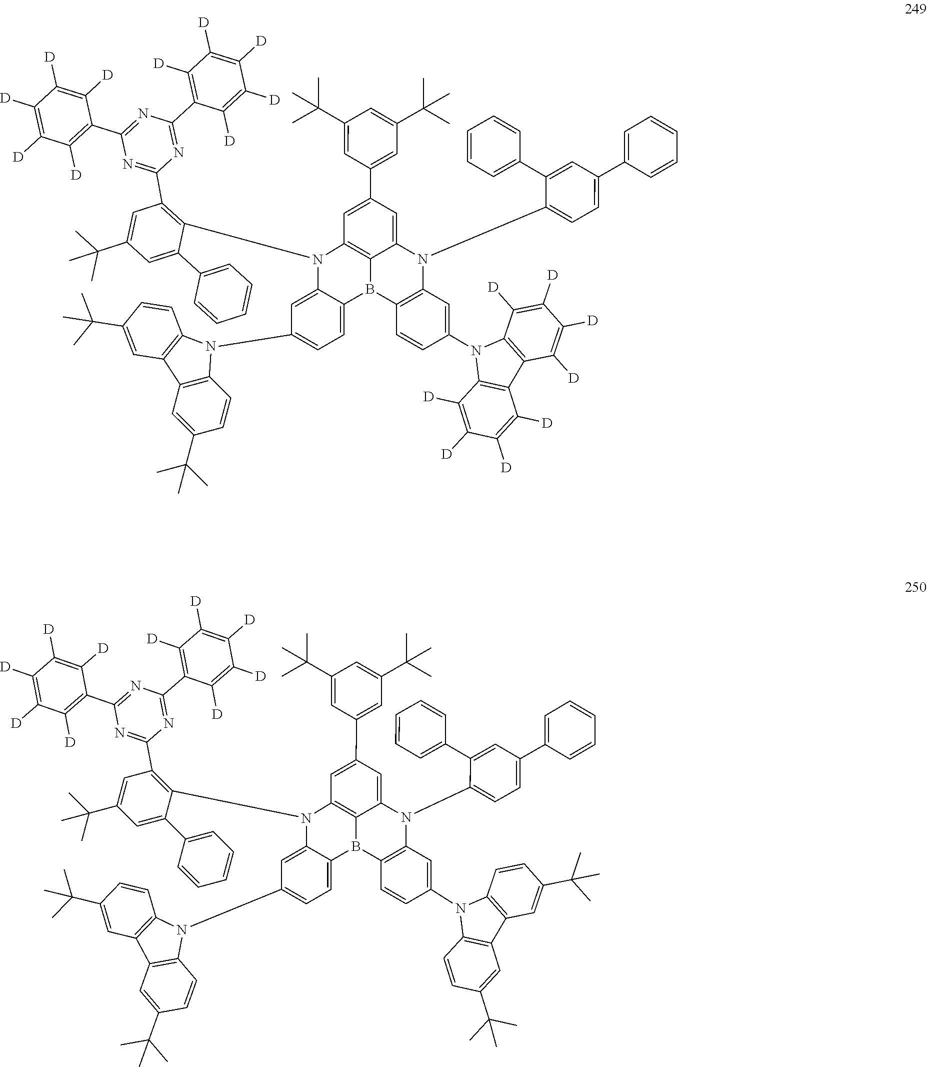 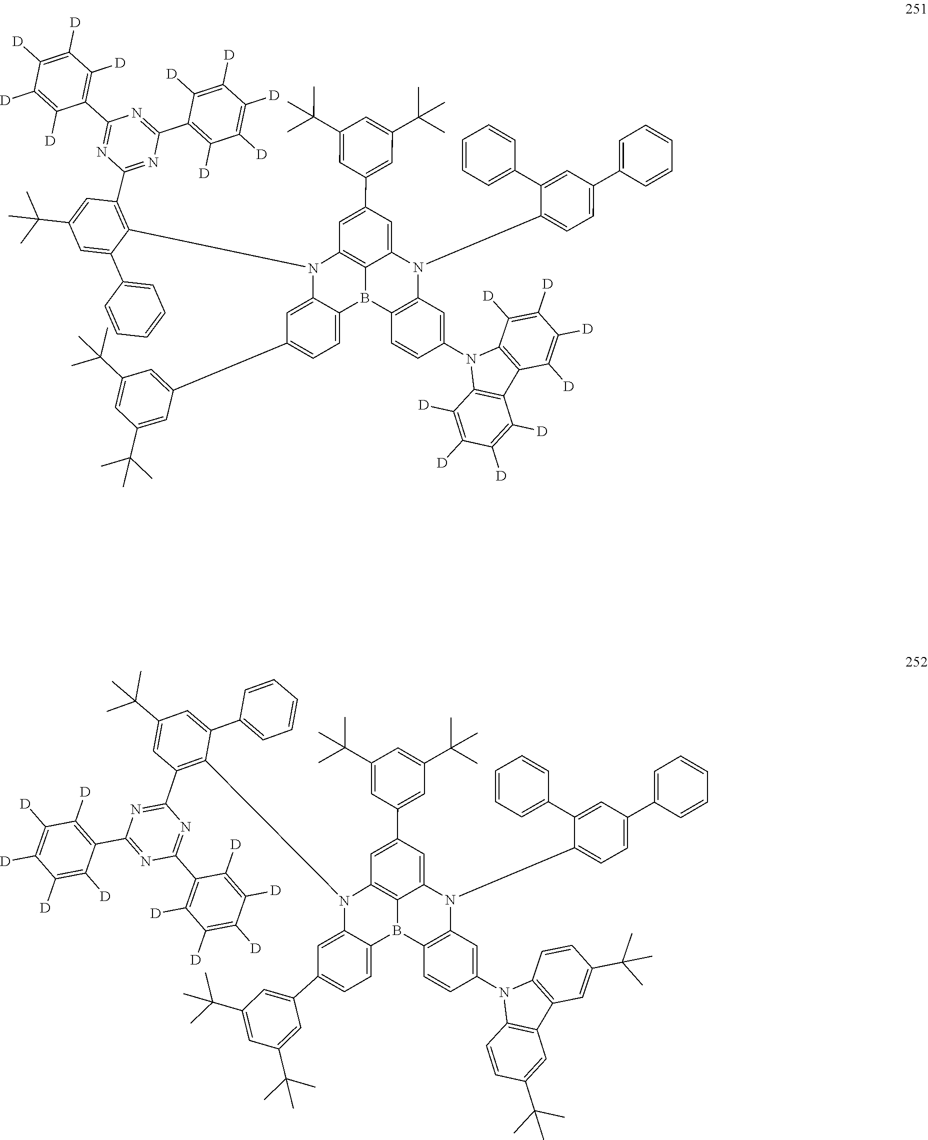 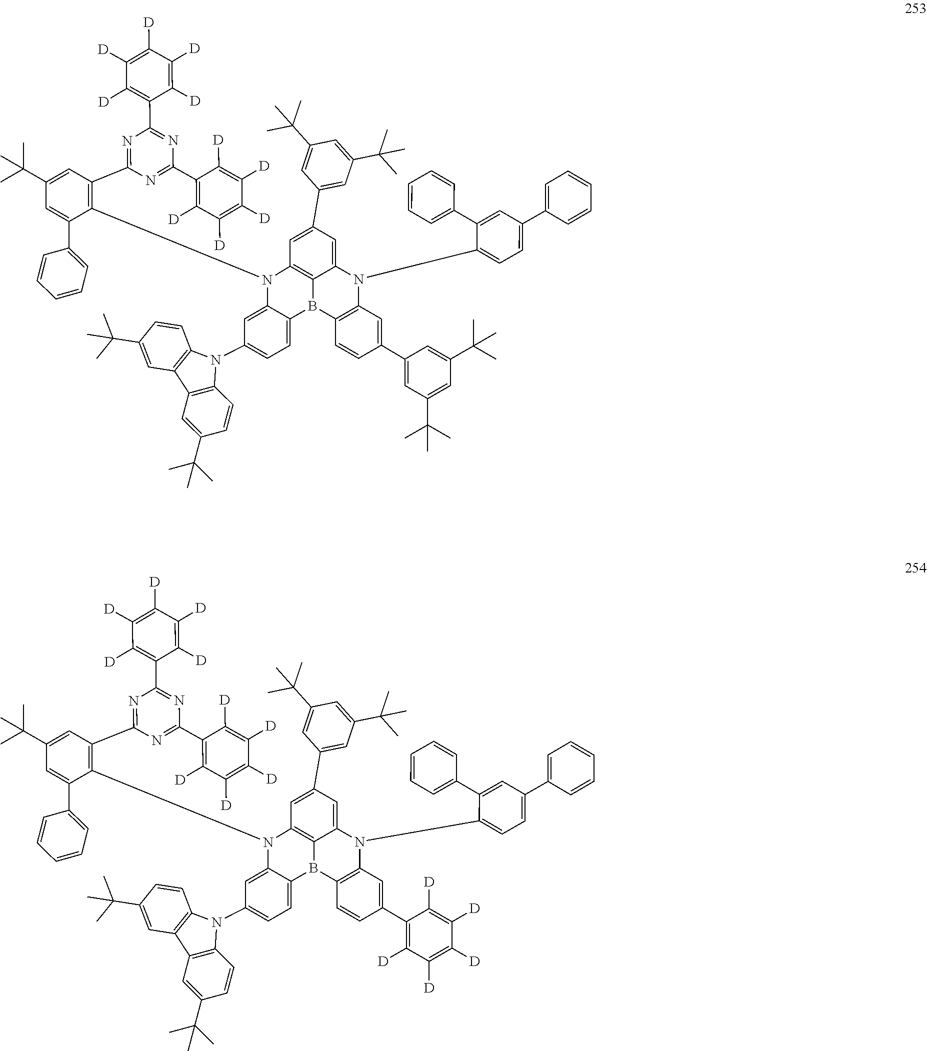 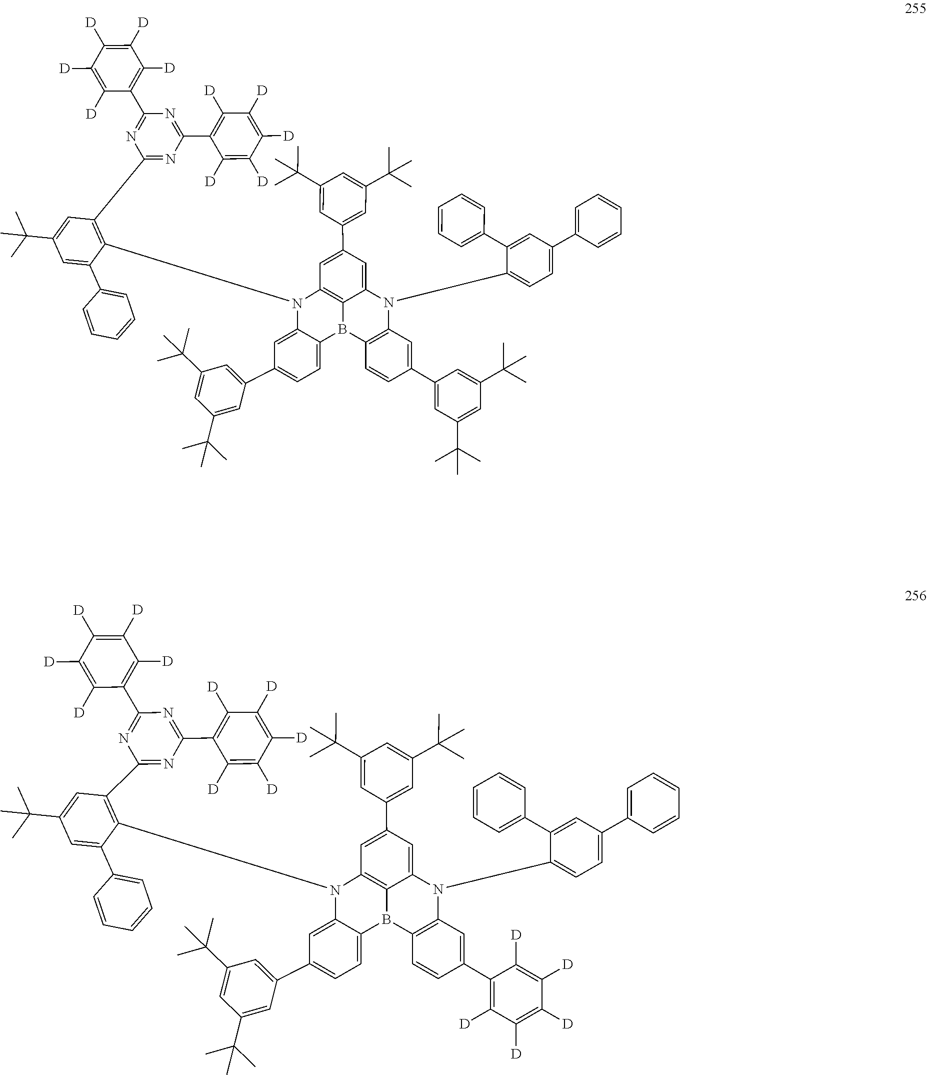 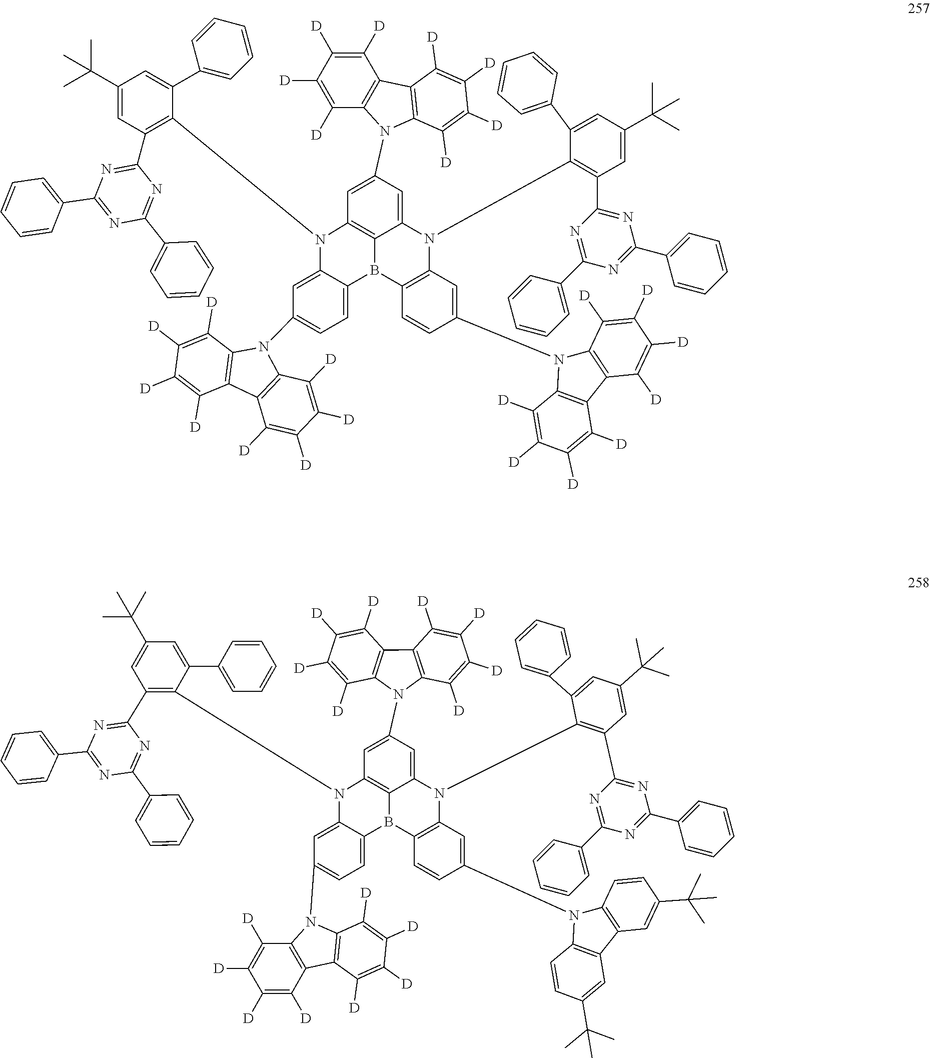 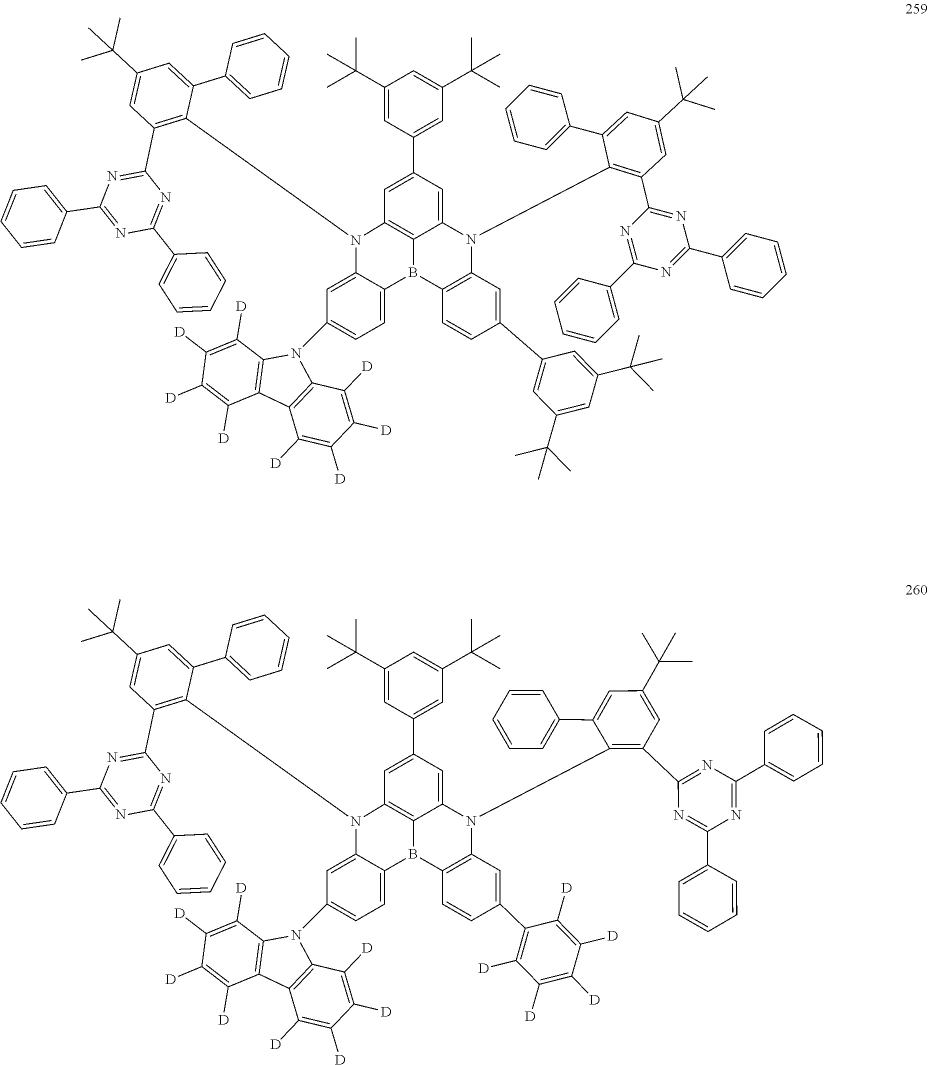 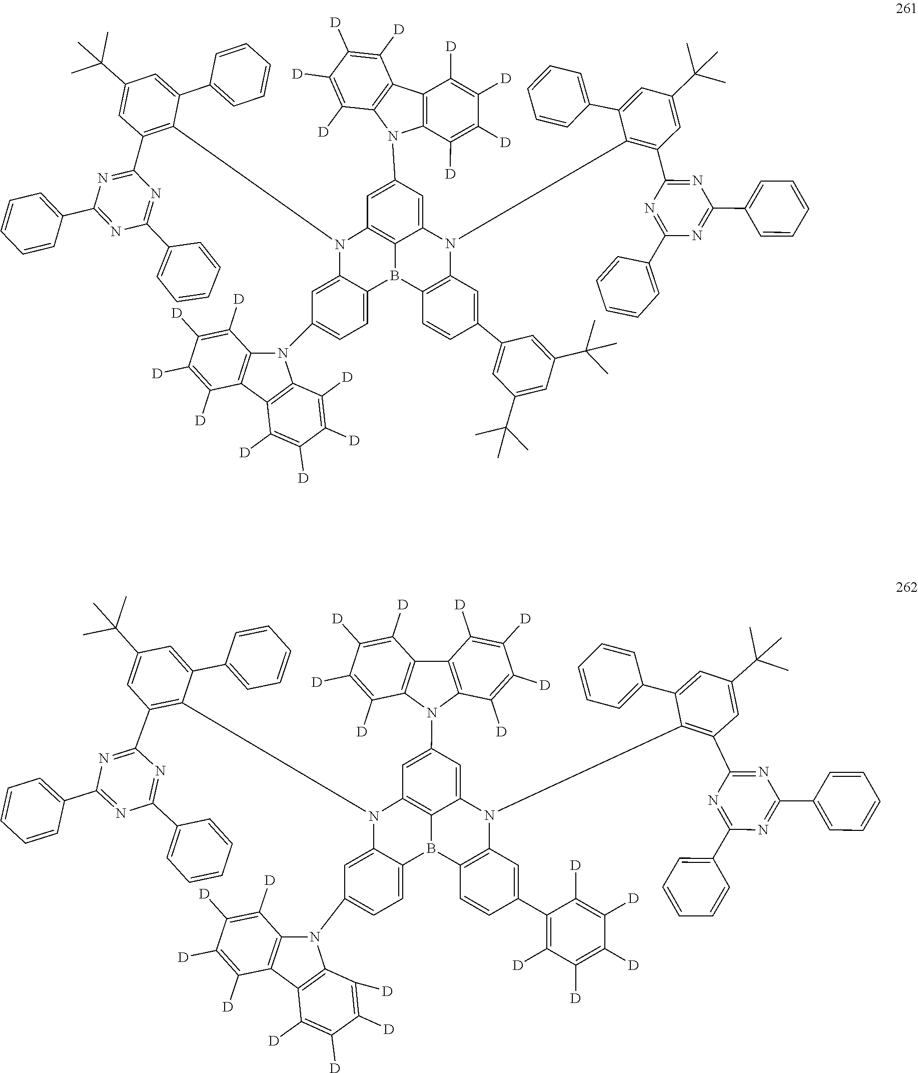 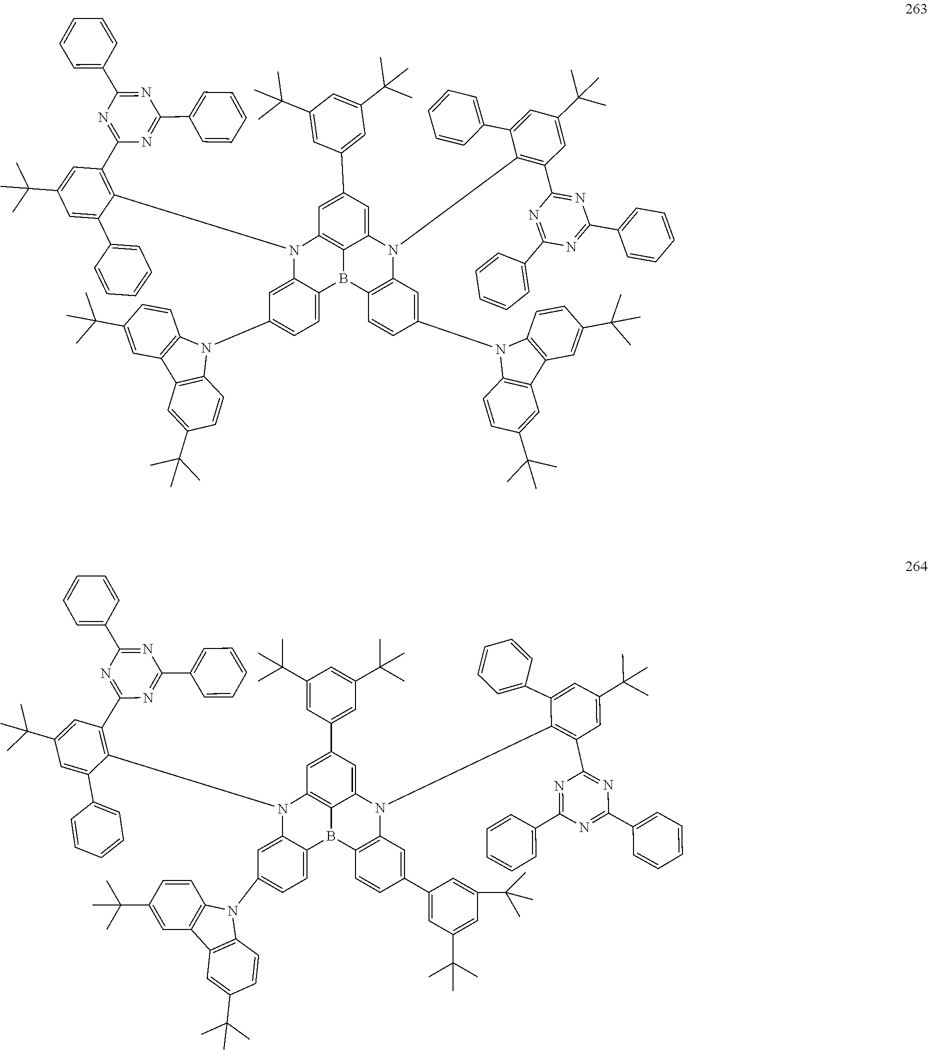 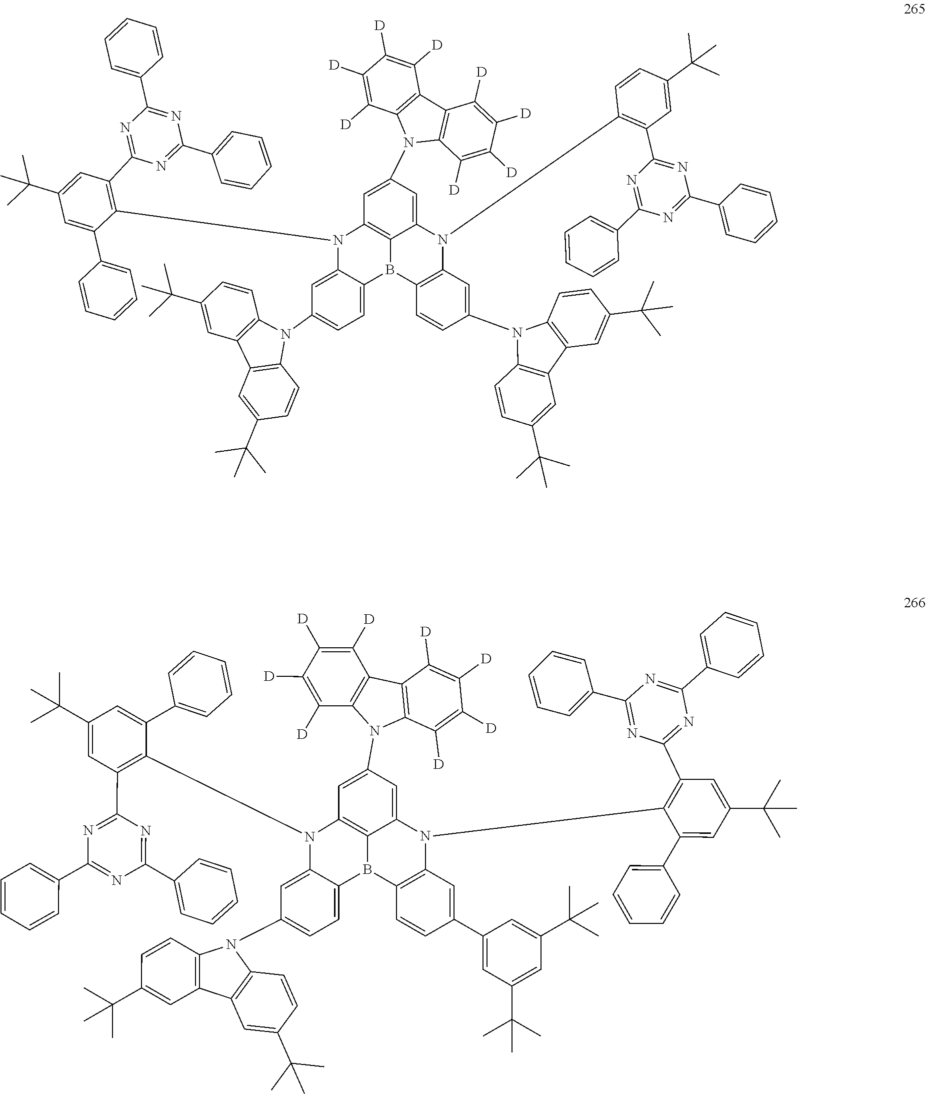 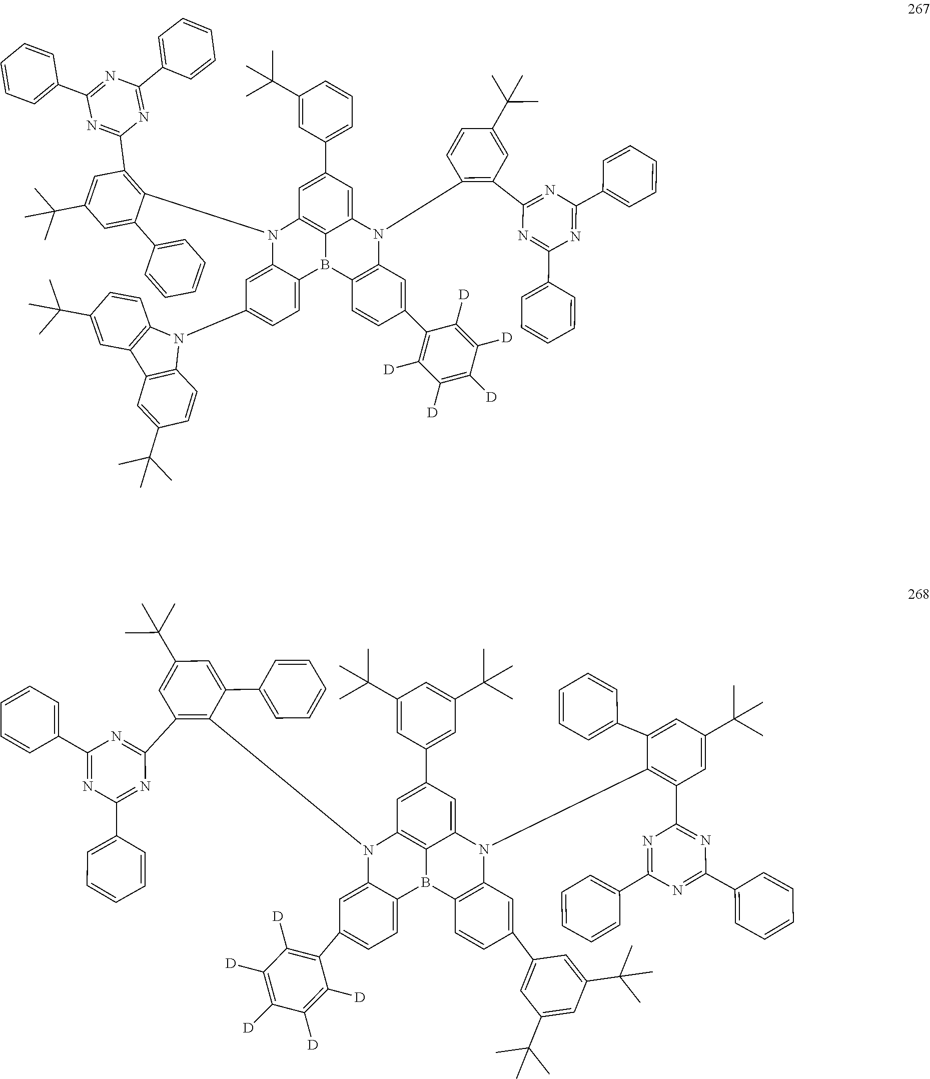 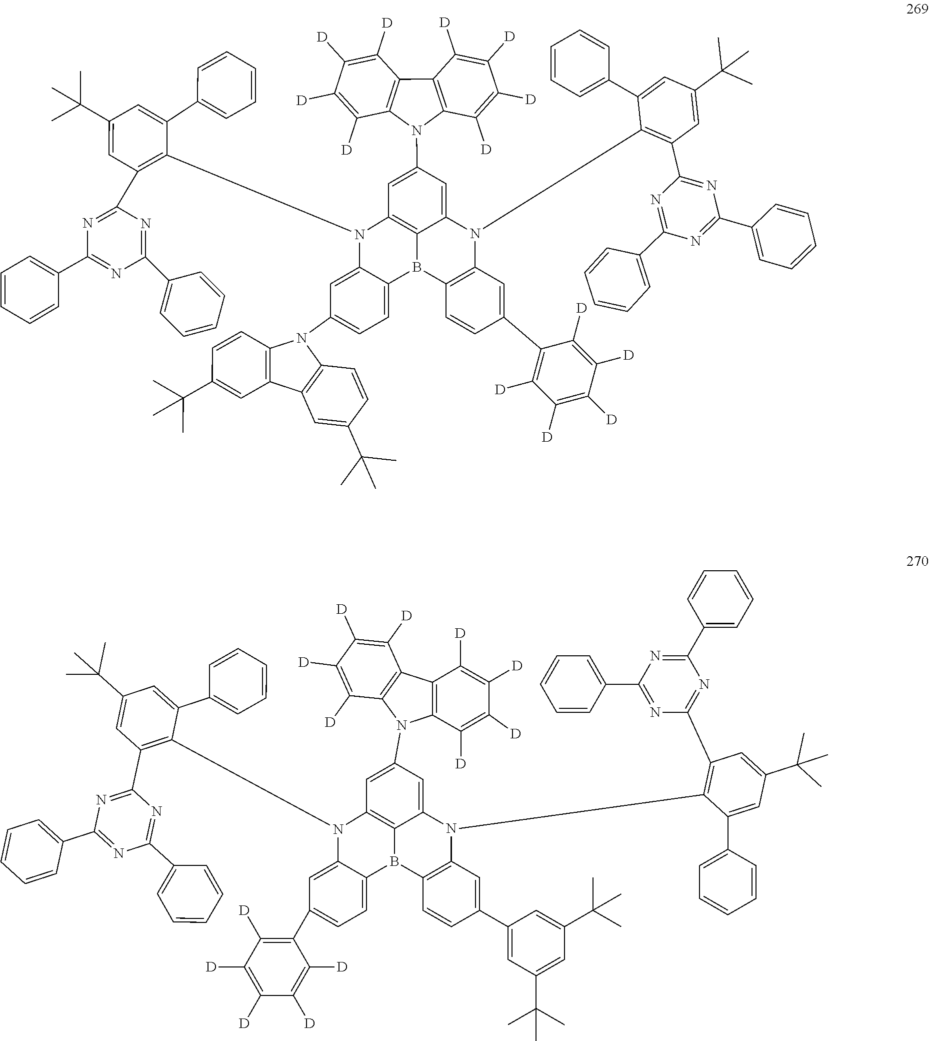 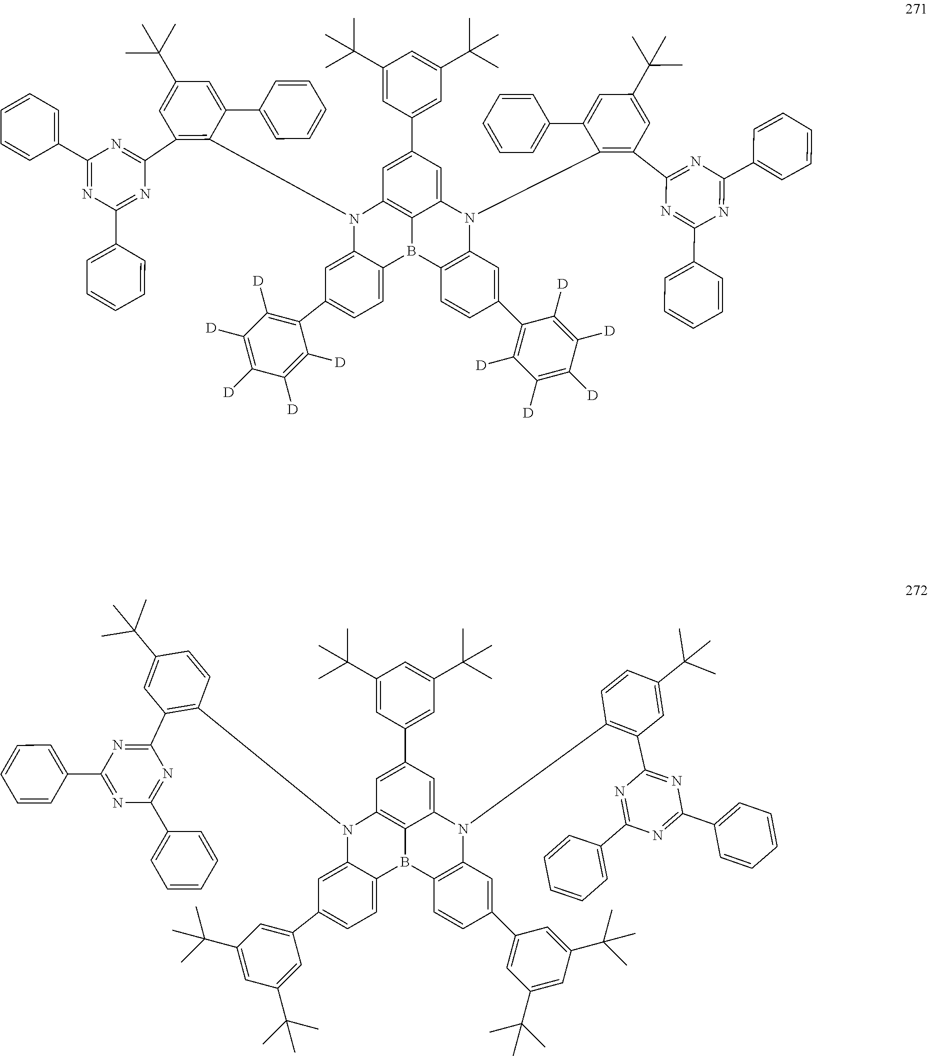 [SMILES: [2H]c1c([2H])c([2H])c(-c2ccc3c(c2)N(c2c(-c4ccccc4)cc(C(C)(C)C)cc2-c2nc(-c4ccccc4)nc(-c4ccccc4)n2)c2cc(-c4cc(C(C)(C)C)cc(C(C)(C)C)c4)cc4c2B3c2ccc(-c3c([2H])c([2H])c([2H])c([2H])c3[2H])cc2N4c2c(-c3ccccc3)cc(C(C)(C)C)cc2-c2nc(-c3ccccc3)nc(-c3ccccc3)n2)c([2H])c1[2H] ; CC(C)(C)c1cc(-c2ccc3c(c2)N(c2ccc(C(C)(C)C)cc2-c2nc(-c4ccccc4)nc(-c4ccccc4)n2)c2cc(-c4cc(C(C)(C)C)cc(C(C)(C)C)c4)cc4c2B3c2ccc(-c3cc(C(C)(C)C)cc(C(C)(C)C)c3)cc2N4c2ccc(C(C)(C)C)cc2-c2nc(-c3ccccc3)nc(-c3ccccc3)n2)cc(C(C)(C)C)c1] 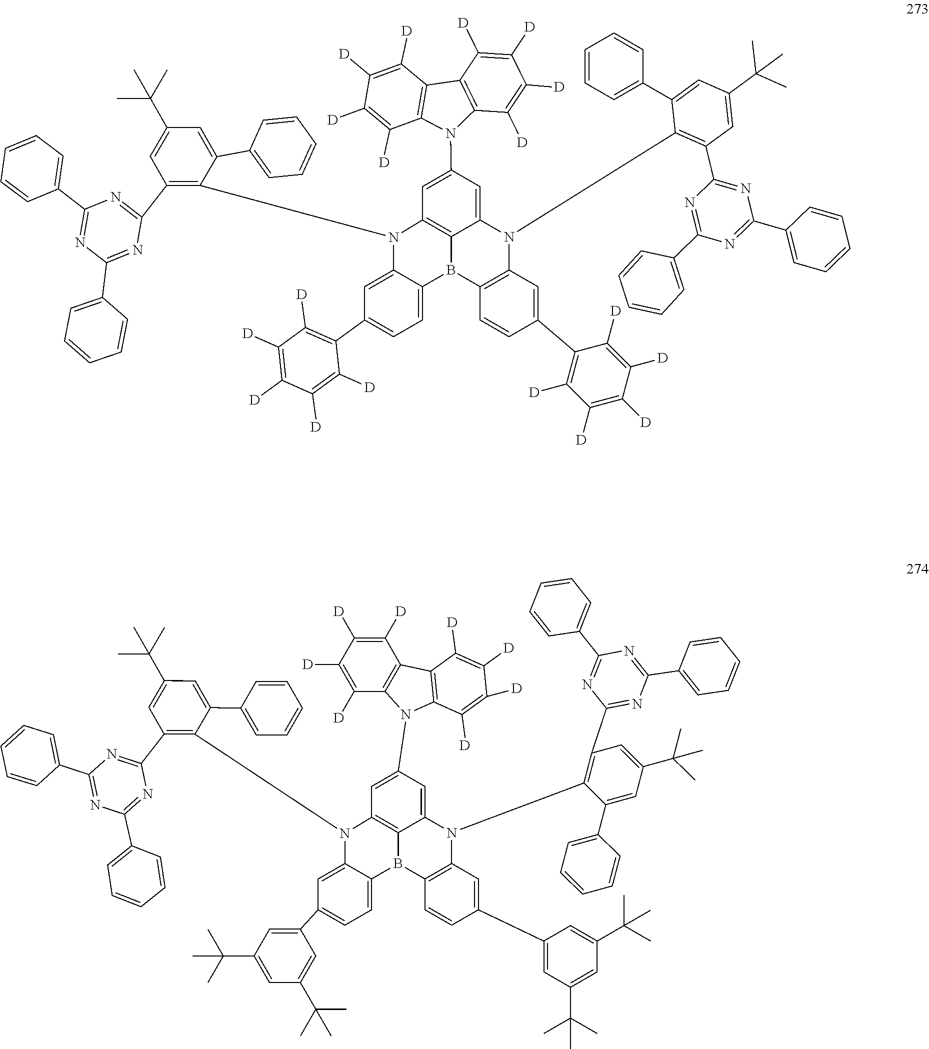 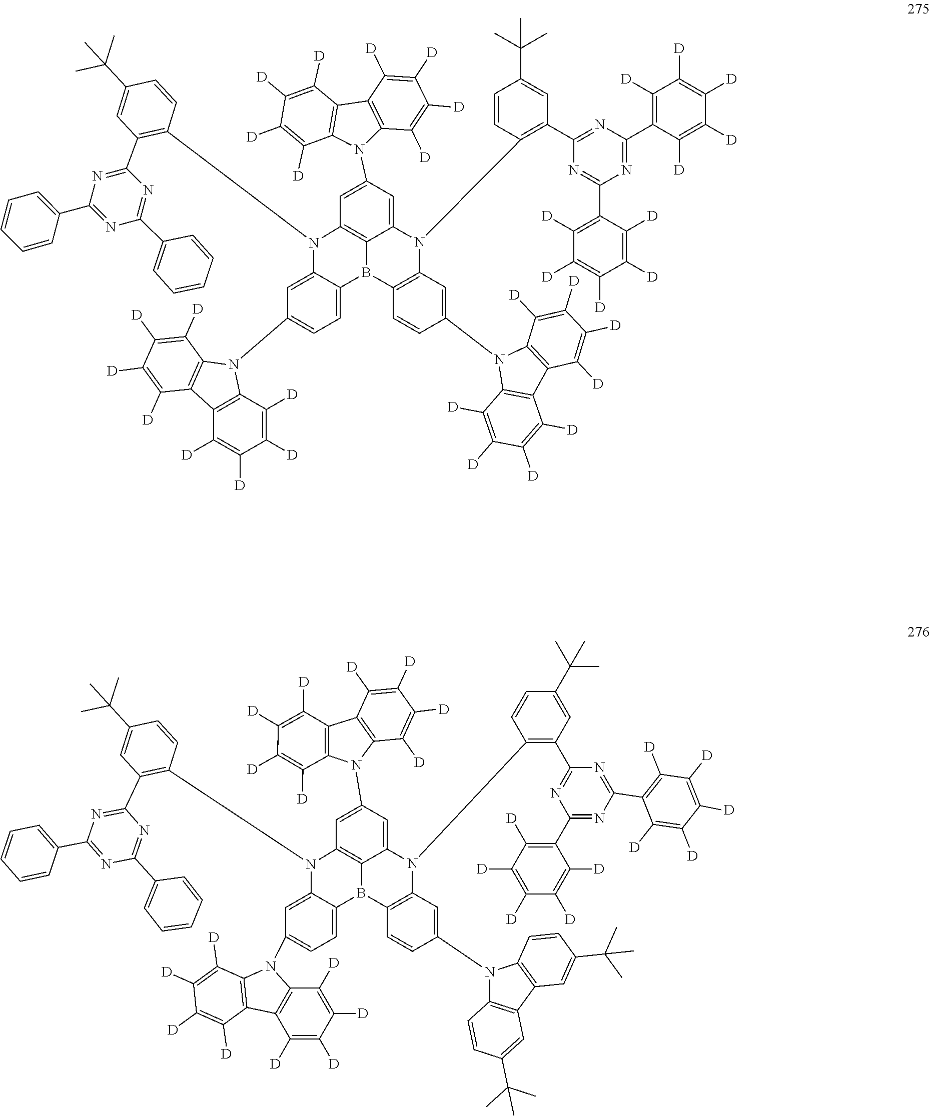 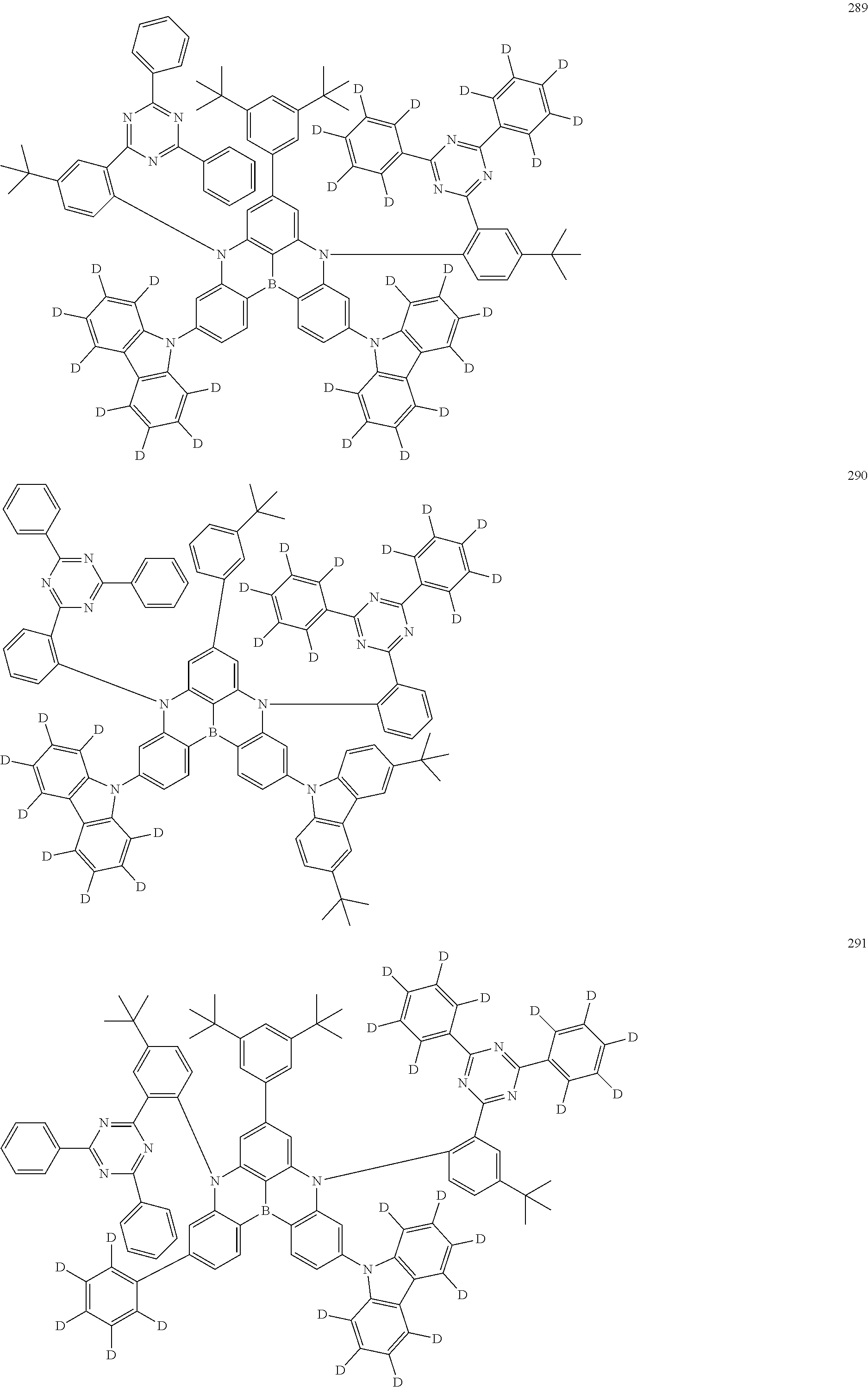 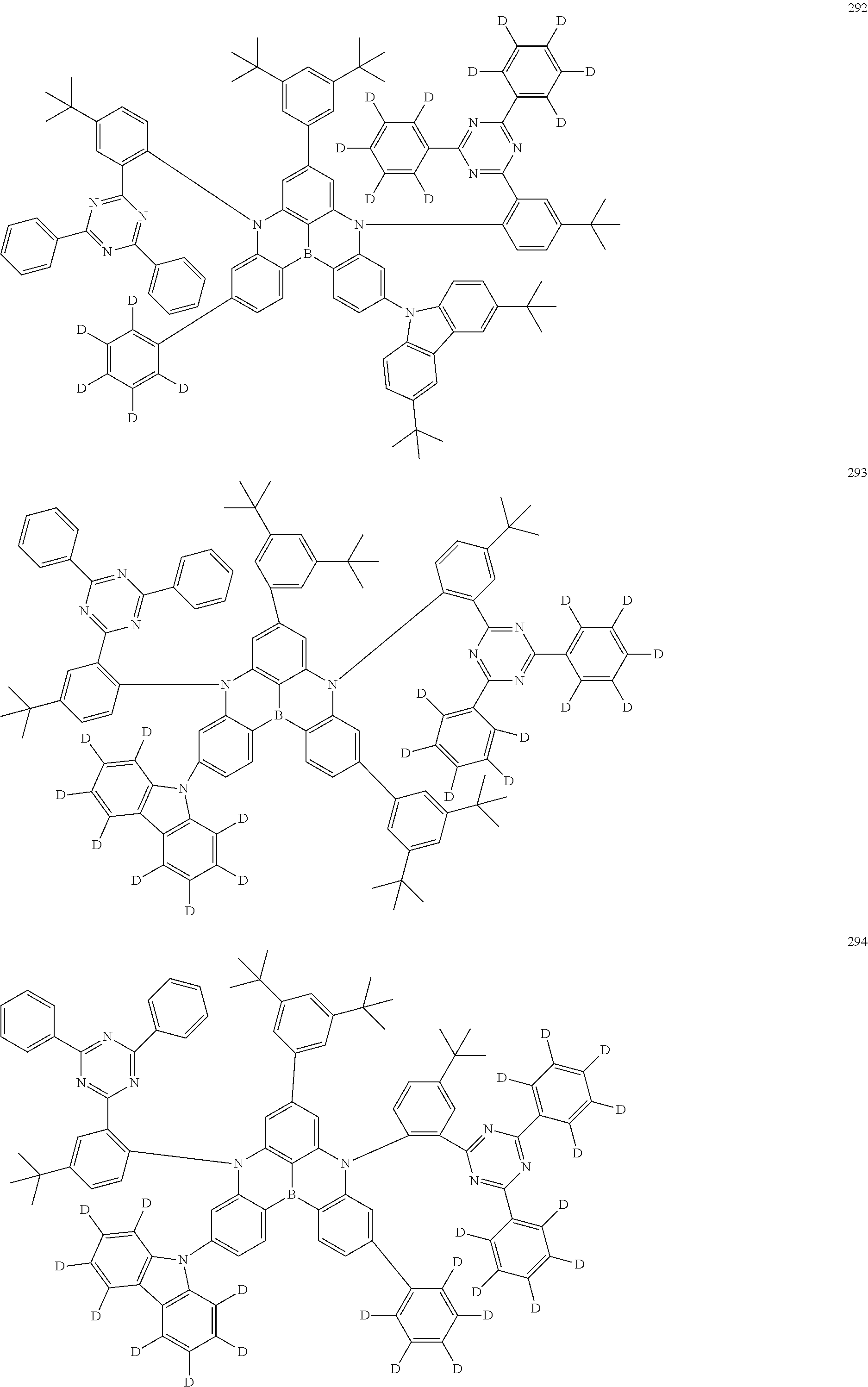 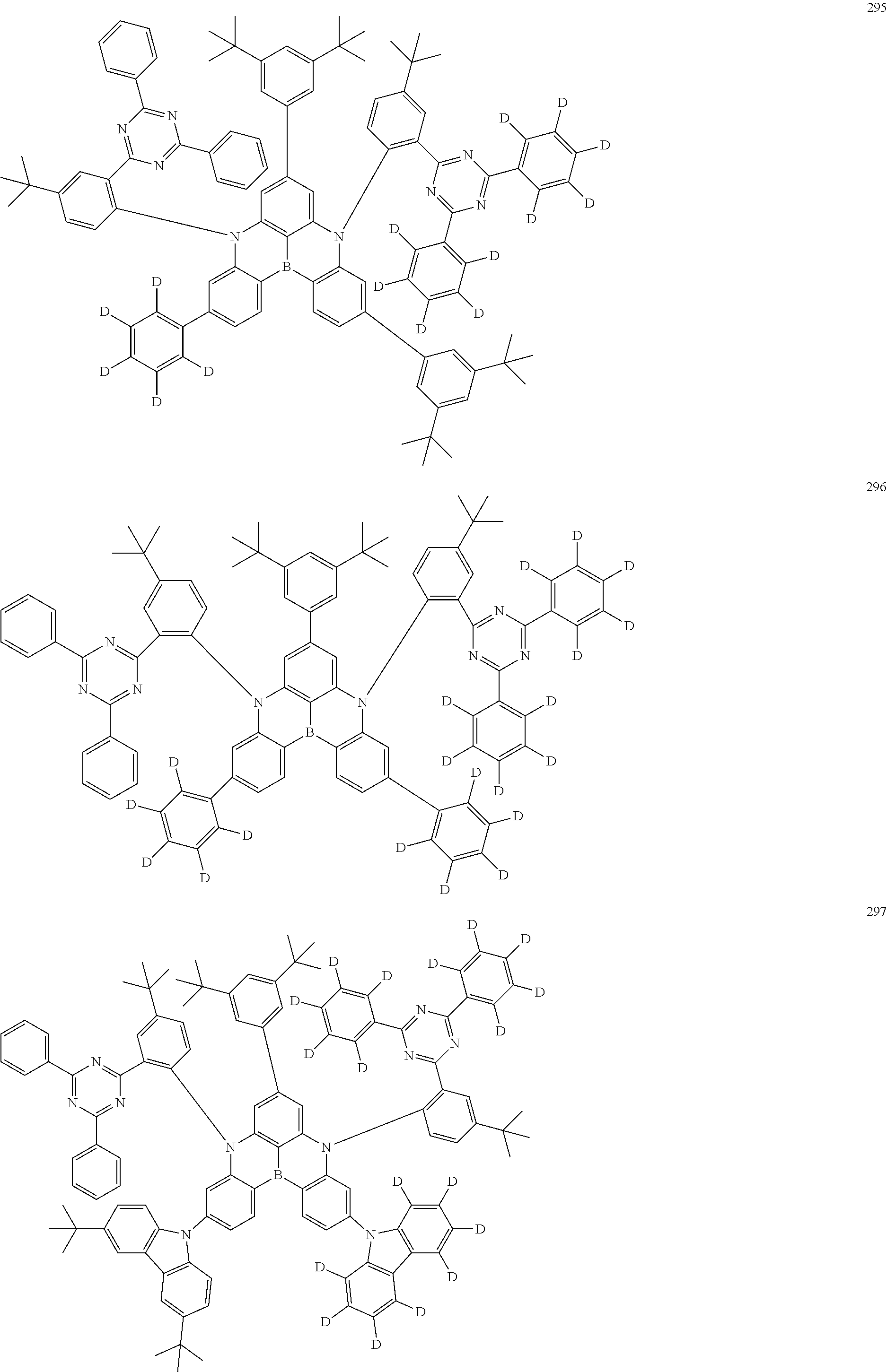 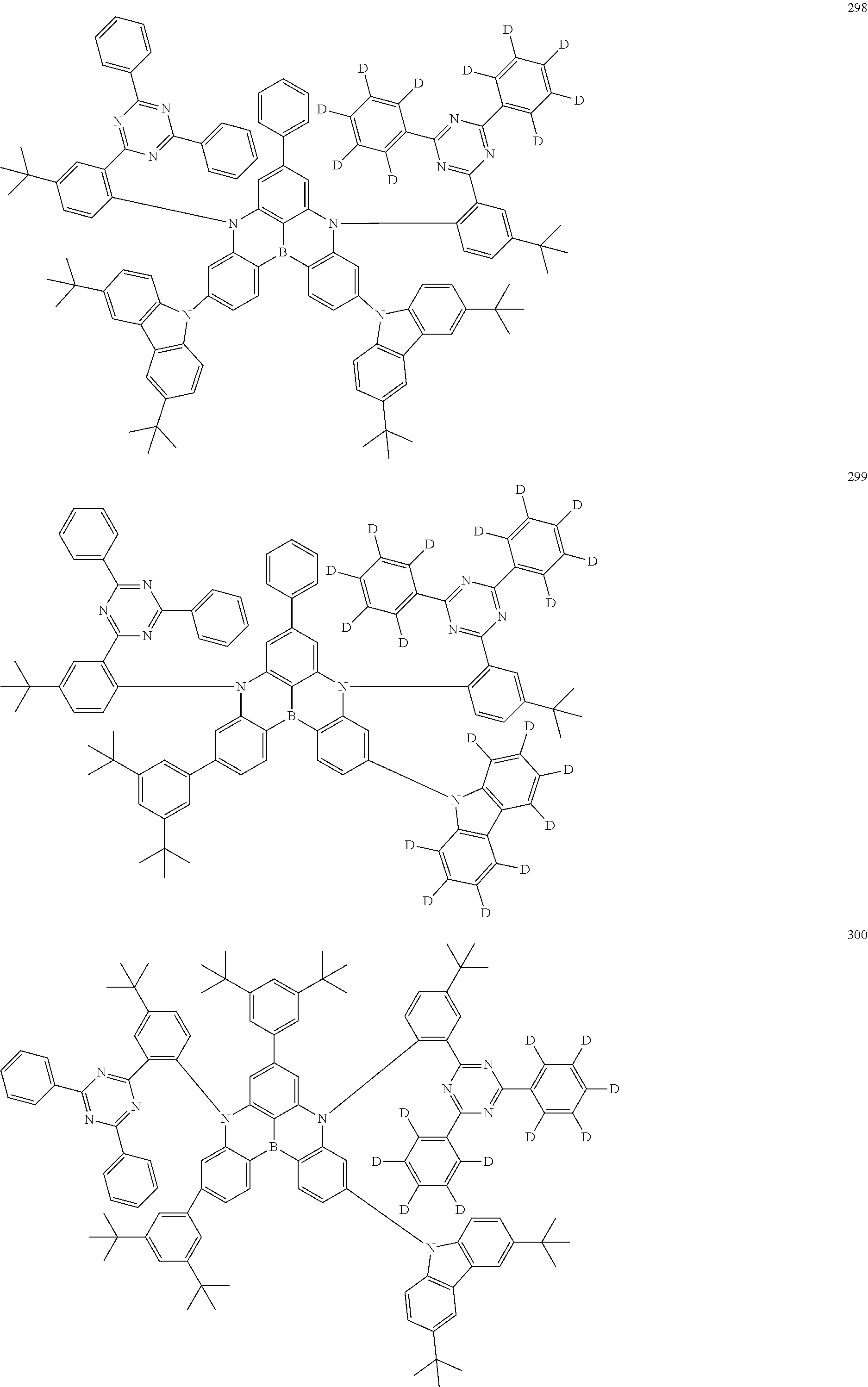 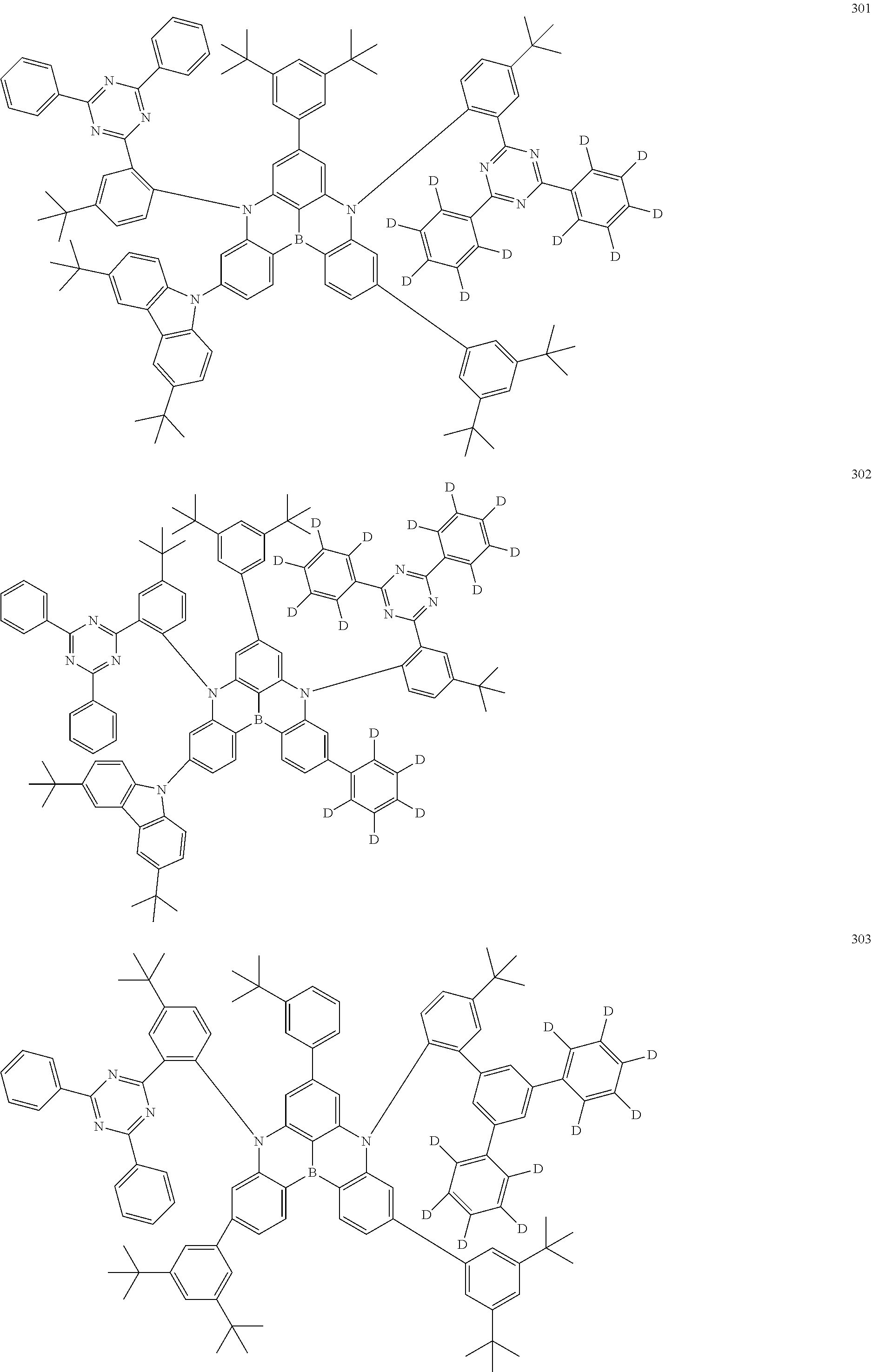 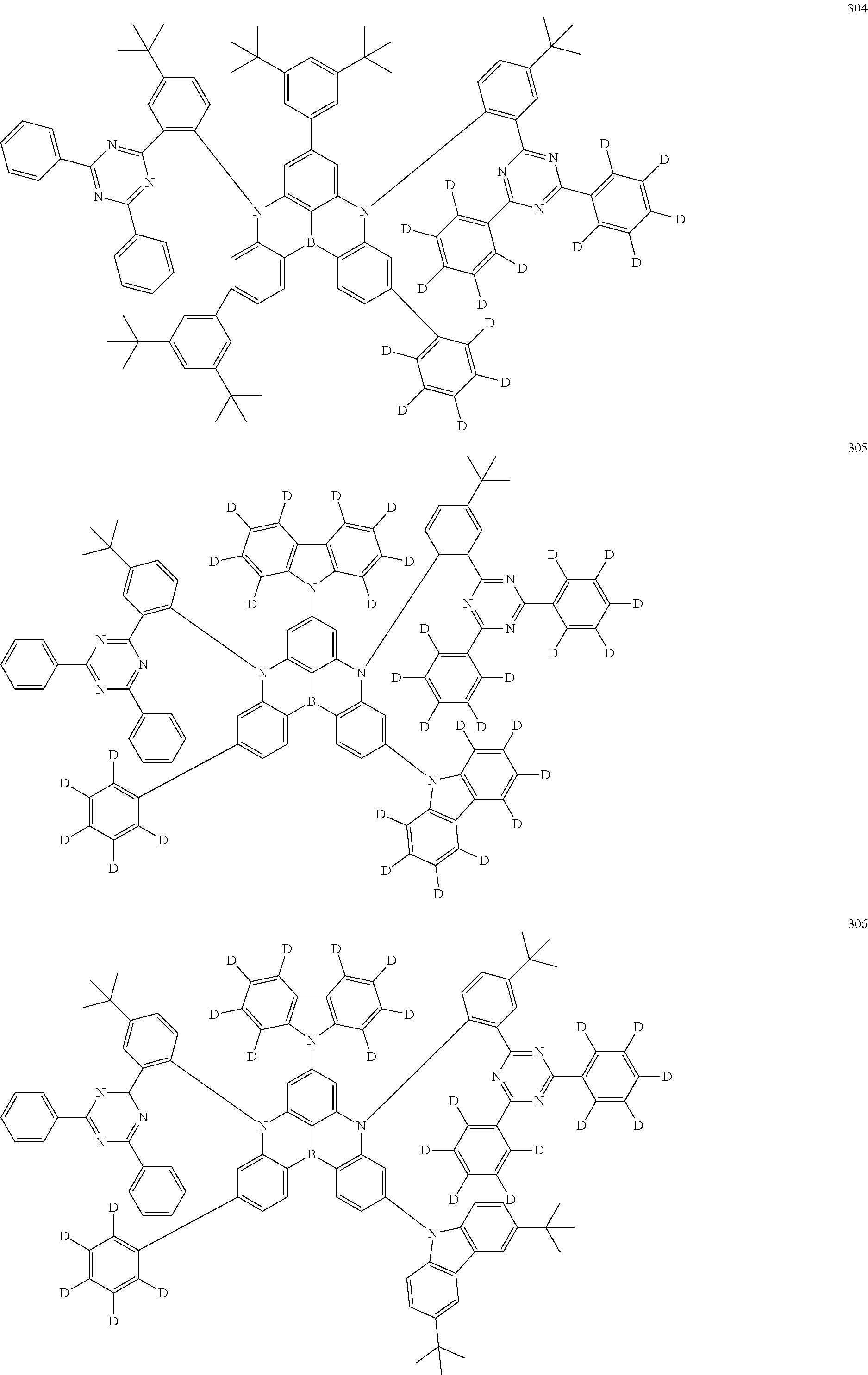 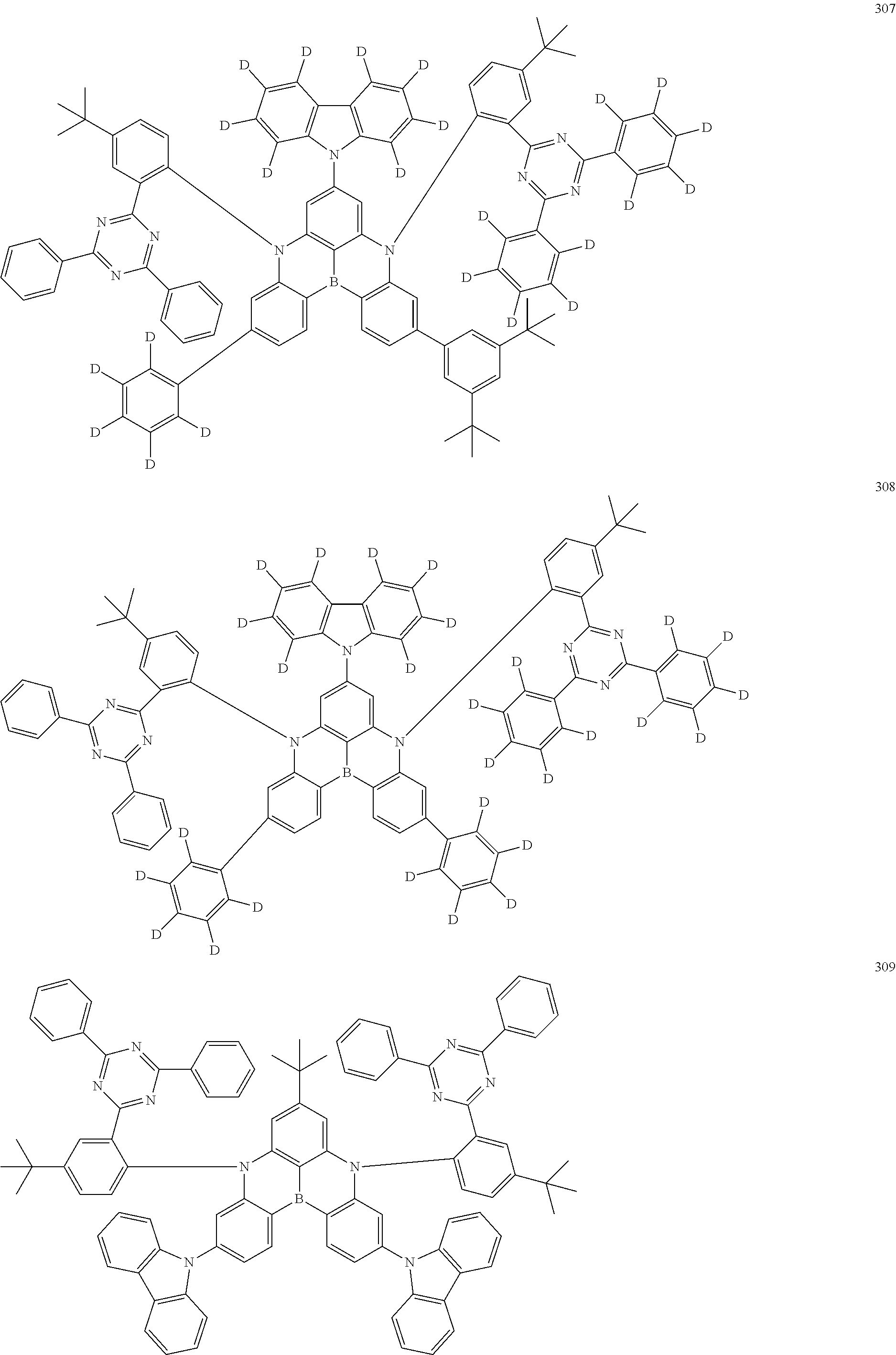 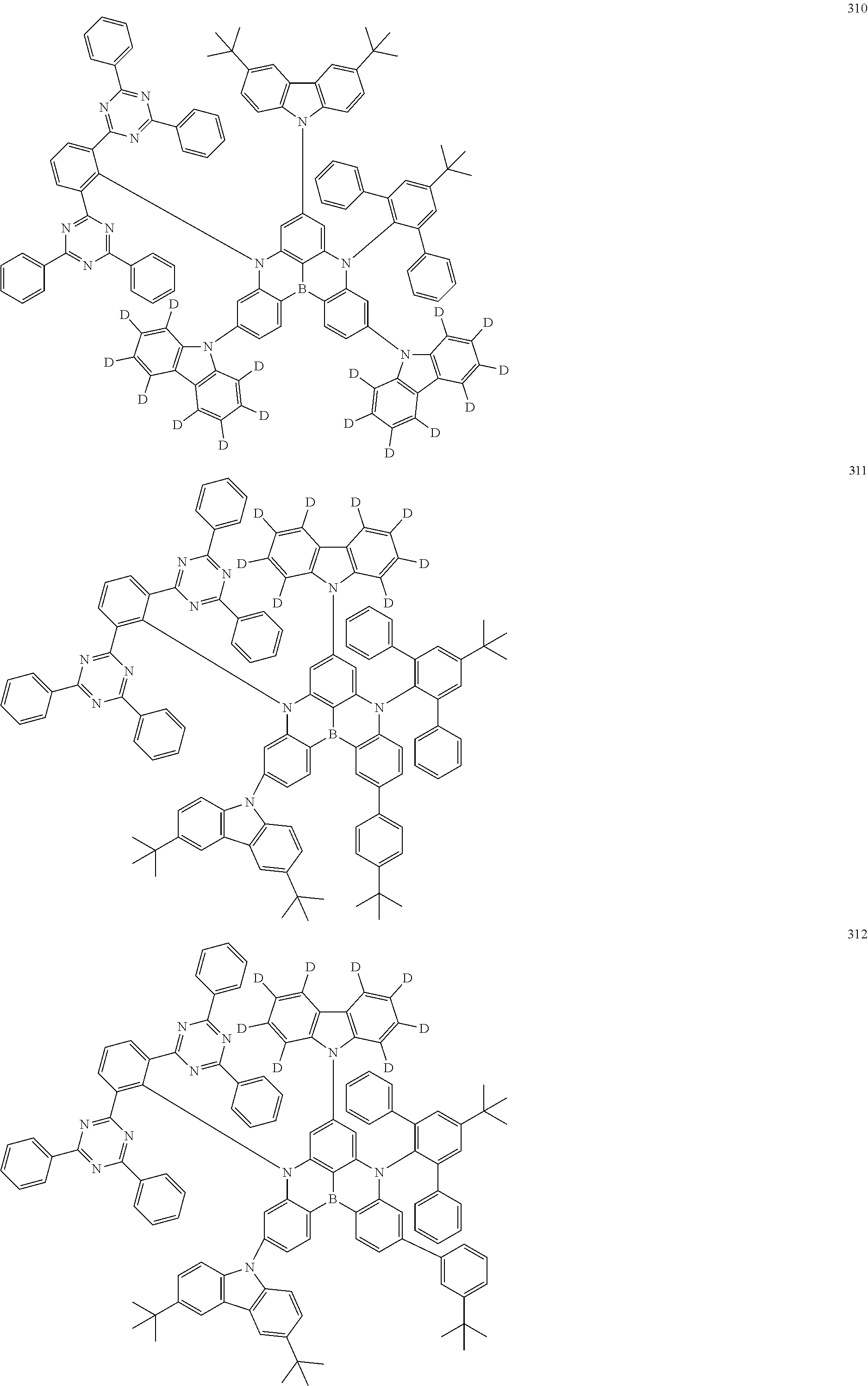 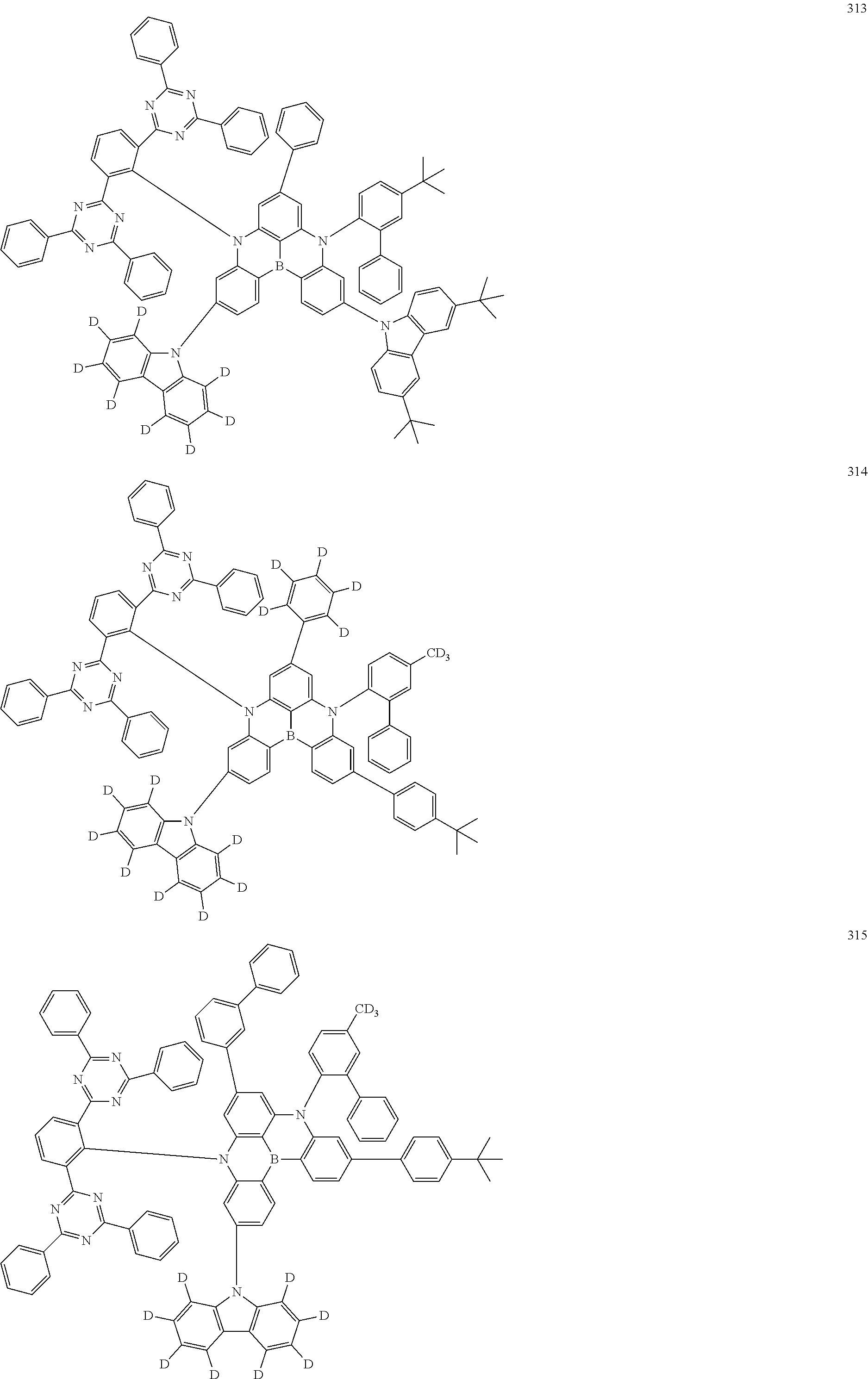 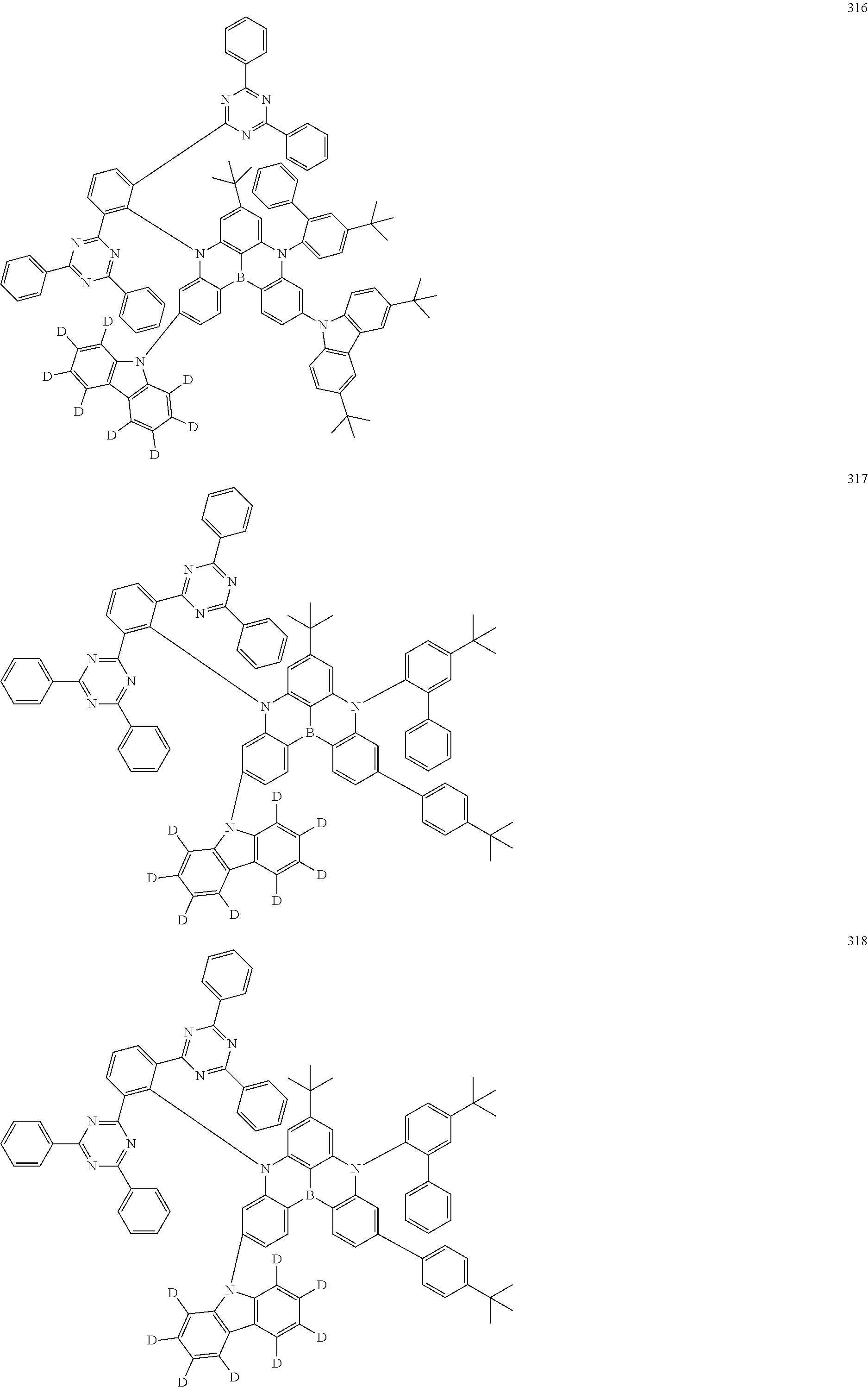 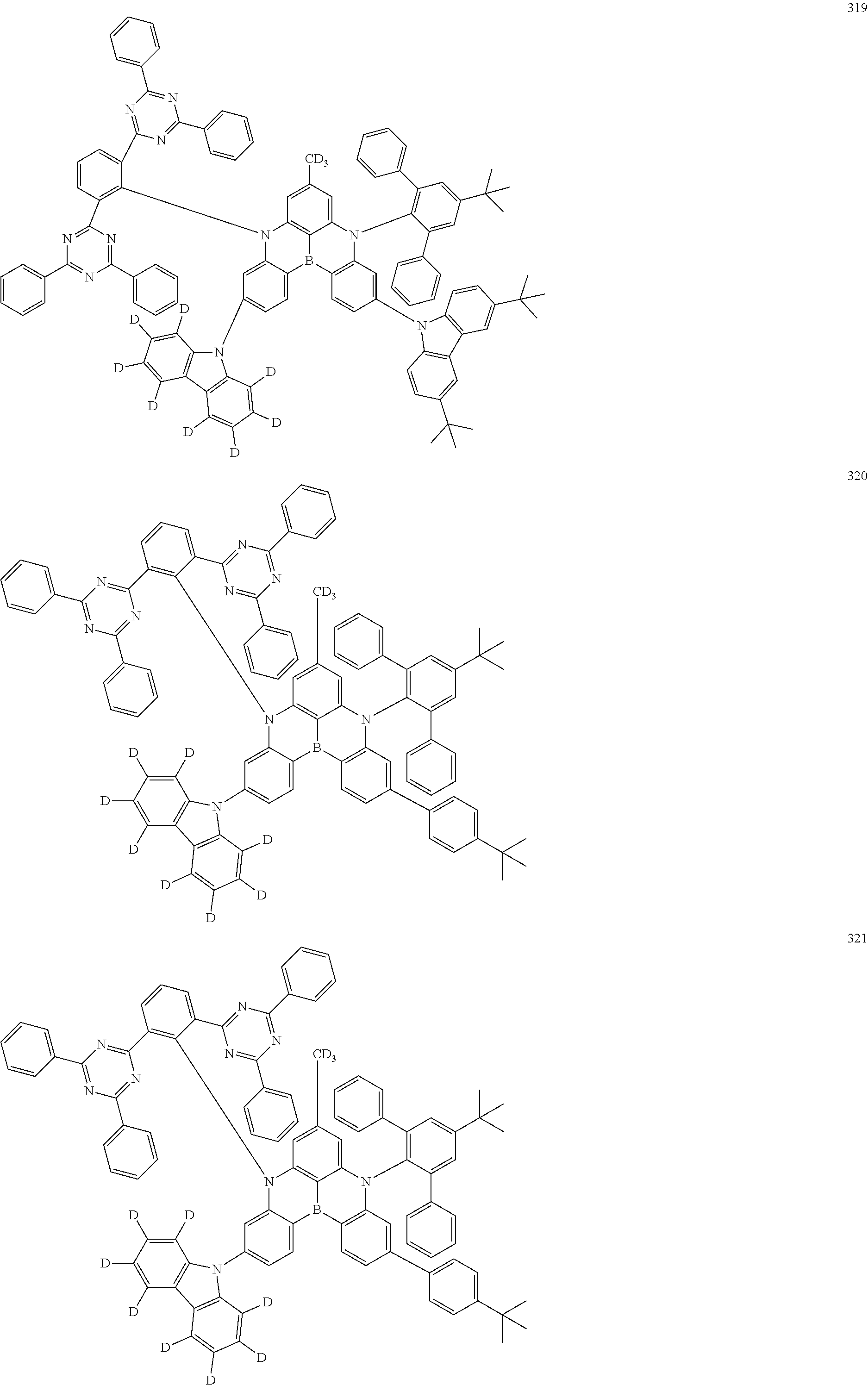 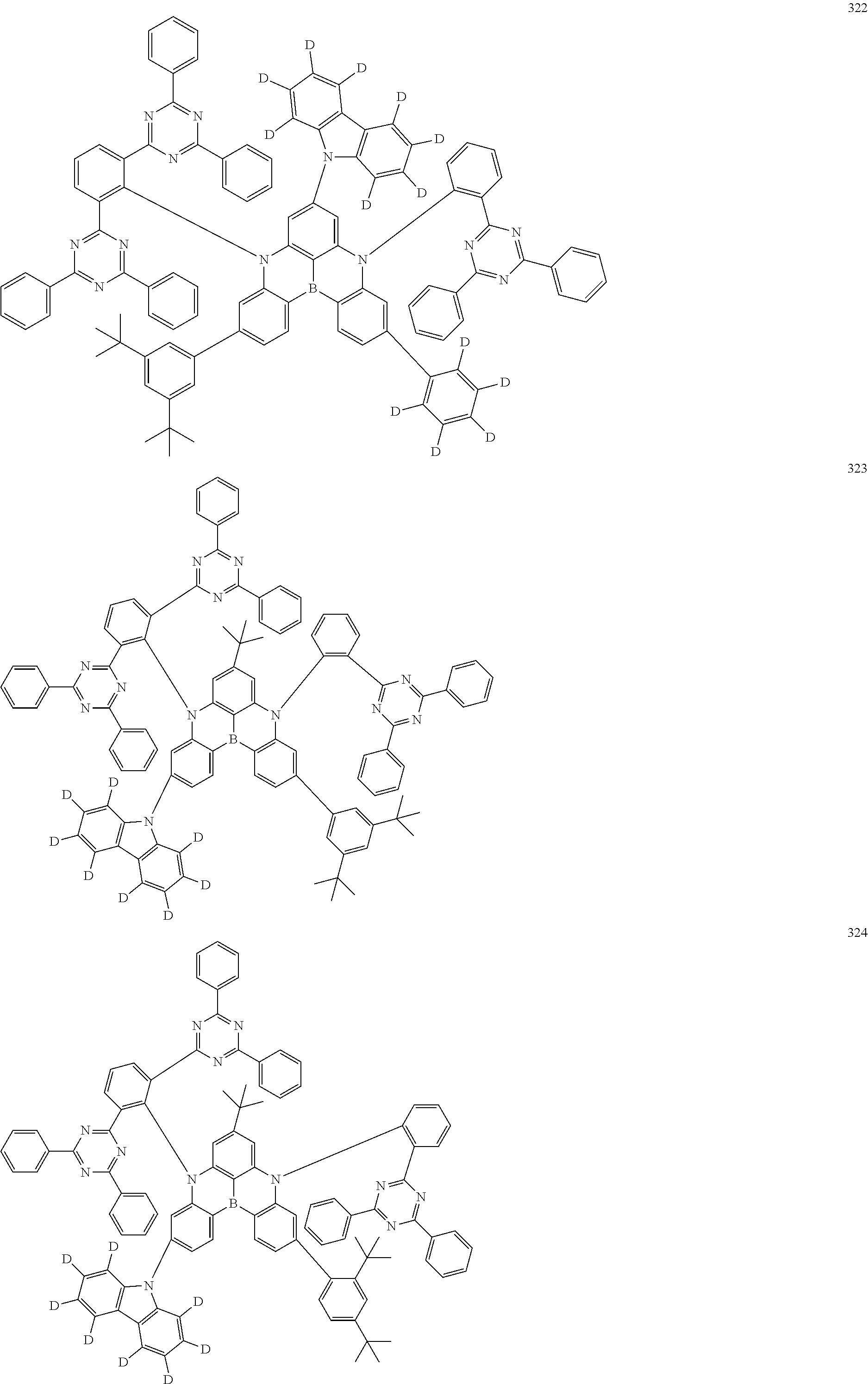 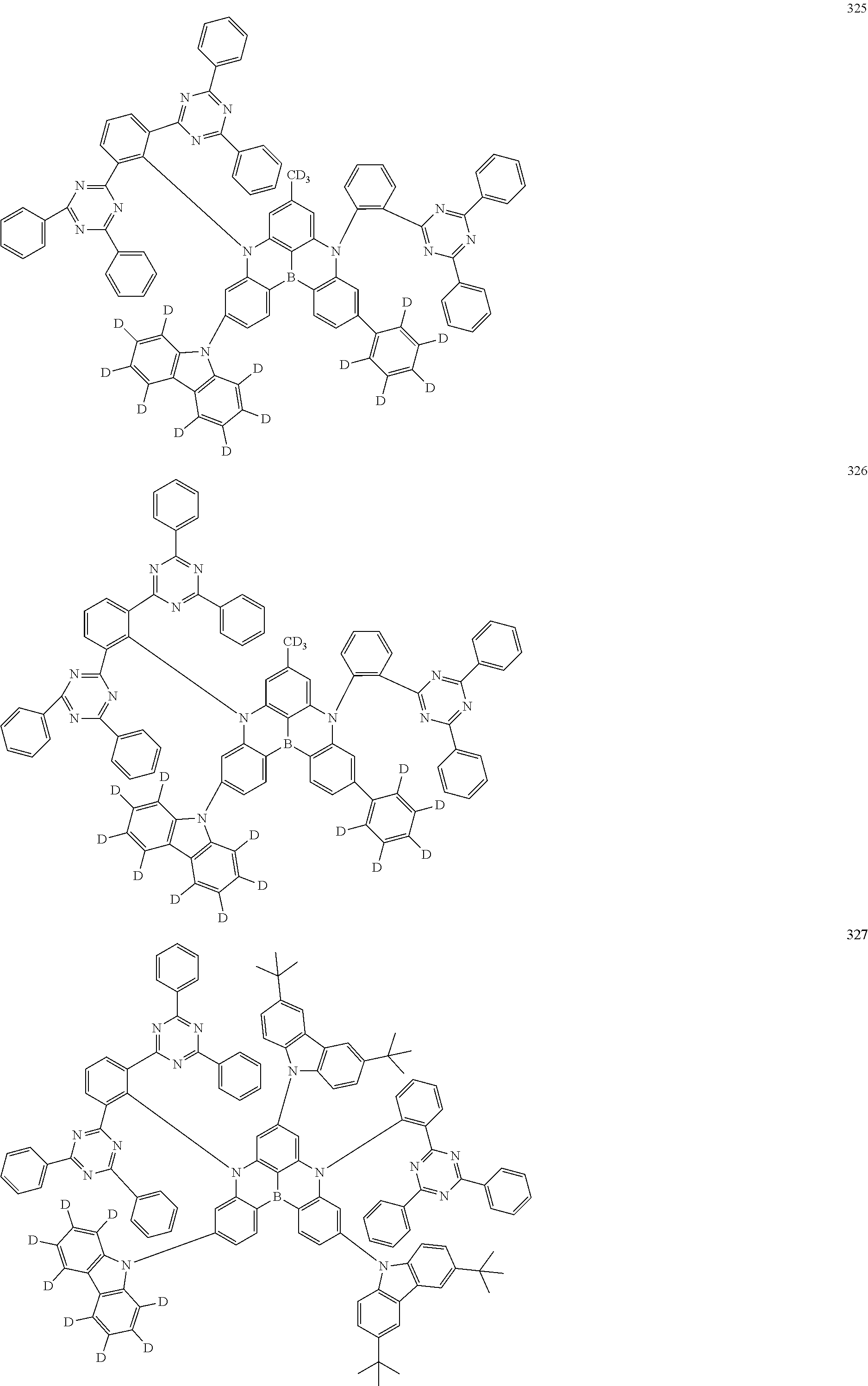 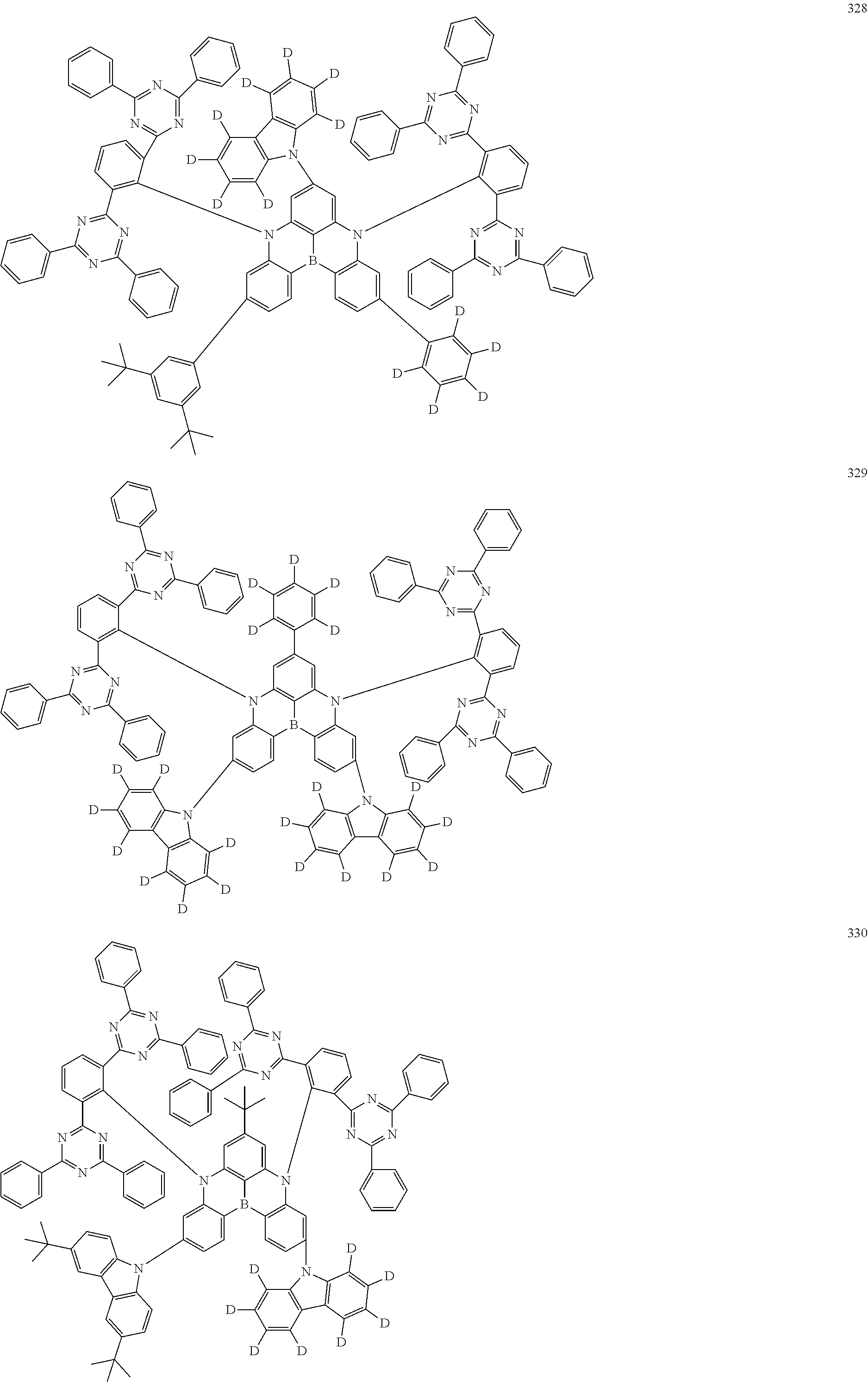 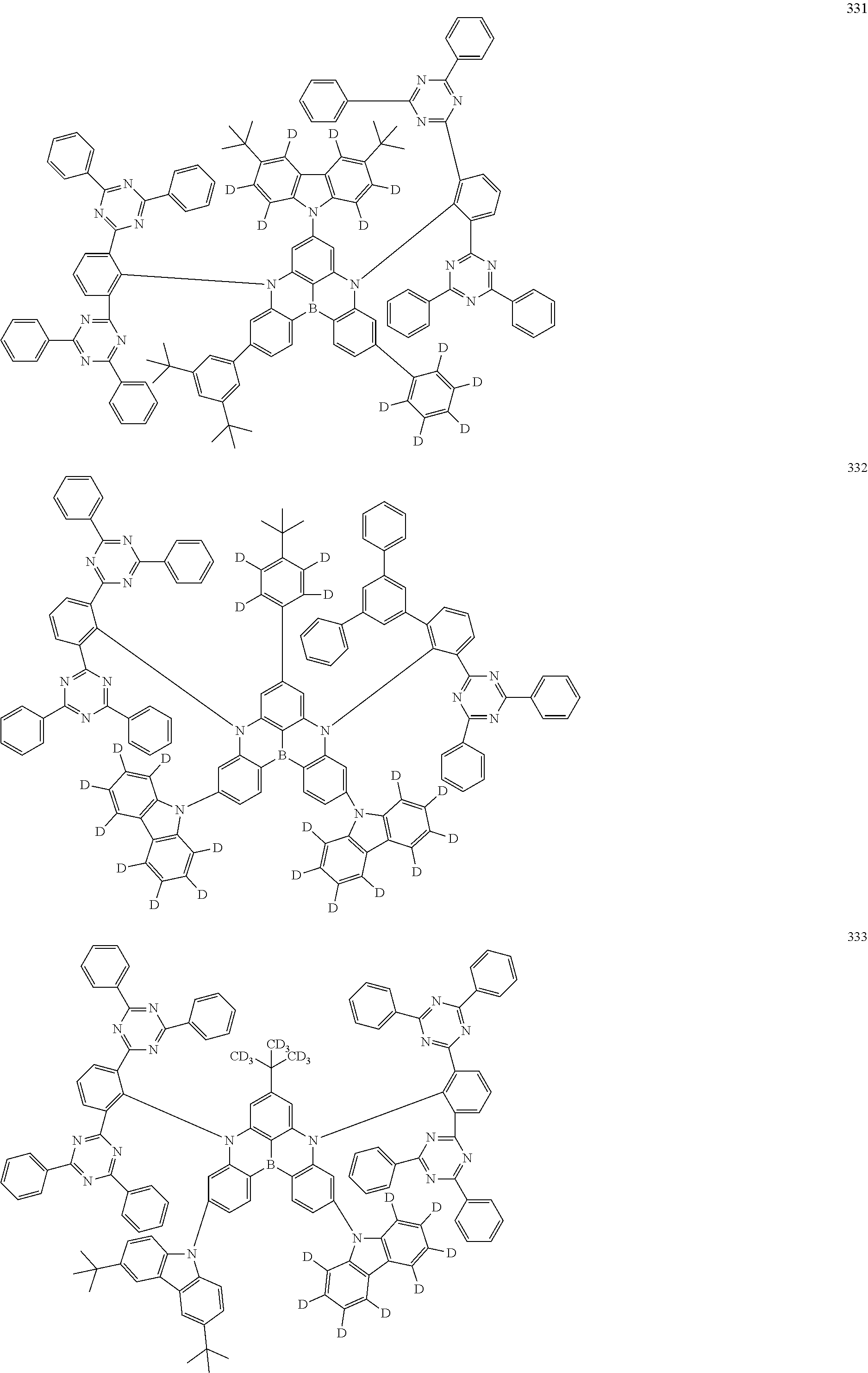 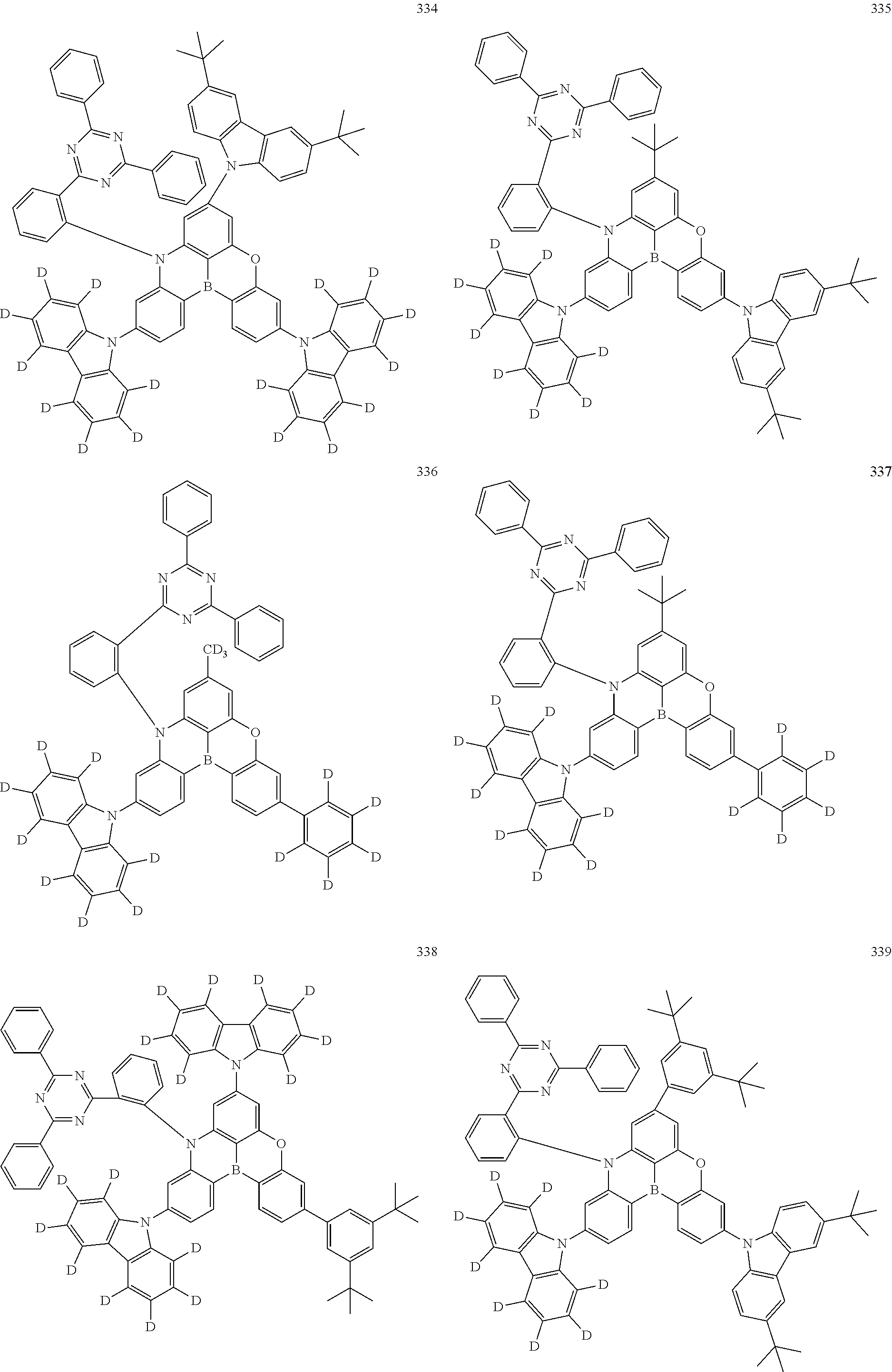 [chemical structure]
